(19) United States
(12) Patent Application Publication
(10) Pub. No.: US 2024/0417413 A1
(43) Pub. Date: Dec. 19, 2024

(54) COMPOUND, MATERIAL FOR ORGANIC ELECTROLUMINESCENT ELEMENTS, ORGANIC ELECTROLUMINESCENT ELEMENT, AND ELECTRONIC DEVICE

(71) Applicant: IDEMITSU KOSAN CO., LTD., Tokyo (JP)

(72) Inventors: Daniela SUSTAC-ROMAN, Basel (CH); Pierre BOUFFLET, Basel (CH); Peter MURER, Basel (CH)

(73) Assignee: IDEMITSU KOSAN CO., LTD., Tokyo (JP)

(21) Appl. No.: 18/703,271

(22) PCT Filed: Oct. 13, 2022
(86) PCT No.: PCT/JP2022/038199

§ 371 Date: Apr. 19, 2024

(30) Foreign Application Priority Data
Oct. 22, 2021 (JP) 2021-173280

(51) Int. Cl. C07F 5/02; C07B 59/00; C09K 11/06; H10K 85/20; H10K 85/60

(52) U.S. Cl. CPC C07F 5/027; C07B 59/004; C09K 11/06; H10K 85/20; H10K 85/622; H10K 85/623; H10K 85/633; H10K 85/653; H10K 85/656; H10K 85/6572; H10K 85/6574; C07B 2200/05

(57) ABSTRACT

A compound represented by a formula (1).

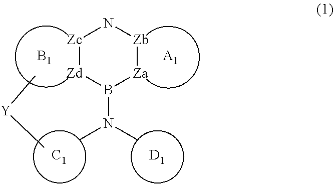

In the formula (1): a ring A₁, a ring B₁, a ring C₁, and a ring D₁ are each independently a substituted or unsubstituted ring; Za, Zb, Zc, and Zd are each independently a nitrogen atom or a carbon atom; the ring C₁ and the ring D₁ are mutually bonded to form a ring or not mutually bonded; R₁ is a hydrogen atom, substituent, or the like; R₁ is mutually bonded to the ring A₁ to form a ring or not mutually bonded; R₁ is mutually bonded to the ring B₁ to form a ring or not mutually bonded; and at least one of R₁, the ring A₁, the ring B₁, the ring C₁, or the ring D₁ has a group represented by —N(R_{1A})(R_{2A}).

### TECHNICAL FIELD

The present invention relates to a compound, an organic-electroluminescence-device material, an organic electroluminescence device, and an electronic device.

### BACKGROUND ART

When a voltage is applied to an organic electroluminescence device (hereinafter, occasionally referred to as “organic EL device”), holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

A fluorescent organic EL device using light emission from singlet excitons has been applied to a full-color display such as a mobile phone and a television set, but an internal quantum efficiency is said to be at a limit of 25%. Studies have thus been made to improve performance of the organic EL device.

For instance, Patent Literatures 1 to 3 disclose, as a compound usable for an organic electroluminescence device, a fused ring compound containing a nitrogen atom and a boron atom.

### CITATION LIST

### Patent Literature(s)

Patent Literature 1: US Patent Application Publication No. 2019/0067577
Patent Literature 2: International Publication No. WO 2020/135953
Patent Literature 3: JP 2021-095342 A

### SUMMARY OF THE INVENTION

### Problem(s) to be Solved by the Invention

Further improvement in performance of the organic EL device is desired for improving performance of an electronic device such as a display. The performance of the organic EL device is evaluable in terms of, for instance, luminance, emission wavelength, full width at half maximum, chromaticity, luminous efficiency, drive voltage, and lifetime. For instance, as a blue emitting material, there is a demand for a compound expressing an emission peak wavelength in a desired wavelength zone in a fluorescence spectrum waveform.

An object of the invention is to provide a compound having an emission peak wavelength in a desired wavelength zone in a fluorescence spectrum waveform. Another object of the invention is to provide an organic-electroluminescence-device material and an organic electroluminescence device each containing a compound having an emission peak wavelength in a desired wavelength zone in a fluorescence spectrum waveform, and an electronic device including the organic electroluminescence device.

### Means for Solving the Problem(s)

According to an aspect of the invention, there is provided a compound represented by a formula (1) below.

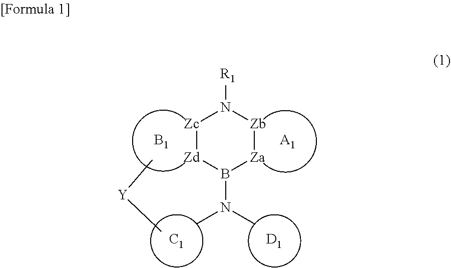

In the formula (1):
a ring A₁, a ring B₁, a ring C₁, and a ring D₁ are each independently a substituted or unsubstituted ring having 5 to 60 ring atoms;
Za and Zb are atoms forming the ring A₁;
Zc and Zd are atoms forming the ring B₁;
Za, Zb, Zc, and Zd are each independently a nitrogen atom or a carbon atom;
the ring C₁ and the ring D₁ are mutually bonded to form a substituted or unsubstituted monocyclic ring, mutually bonded to form a substituted or unsubstituted fused ring, or not mutually bonded;
R₁ is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆);
when R₁ is a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms, R₁ is bonded with the ring A₁ to form a substituted or unsubstituted monocyclic ring, bonded with the ring A₁ to form a substituted or unsubstituted fused ring, or not bonded with the ring A₁, or bonded with the ring B₁ to form a substituted or unsubstituted monocyclic ring, bonded with the ring B₁ to form a substituted or unsubstituted fused ring, or not bonded with the ring B₁;
at least one of R₁, the ring A₁, the ring B₁, the ring C₁, or the ring D₁ has a group represented by —N(R_{1A})(R_{2A}) as a substituent;
a combination of R_{1A} and R_{2A} are mutually bonded to form a substituted or unsubstituted monocyclic ring, mutually bonded to form a substituted or unsubstituted fused ring, or not mutually bonded;
when R₁ has a group represented by —N(R_{1A})(R_{2A}) as a substituent, R_{1A} and R_{2A} are each independently bonded with R₁ to form a substituted or unsubstituted monocyclic ring, bonded with R₁ to form a substituted or unsubstituted fused ring, or not bonded with R₁;
when the ring A₁ has a group represented by —N(R_{1A})(R_{2A}) as a substituent, R_{1A} and R_{2A} are each independently bonded with the ring A₁ to form a substituted or unsubstituted monocyclic ring, bonded with the ring A₁ to form a substituted or unsubstituted fused ring, or not bonded with the ring A₁;
when the ring B₁ has a group represented by —N(R_{1A})(R_{2A}) as a substituent, R_{1A} and R_{2A} are each independently bonded with the ring B₁ to form a substituted or unsubstituted monocyclic ring, bonded with the ring B₁ to form a substituted or unsubstituted fused ring, or not bonded with the ring B₁;
when the ring C₁ has a group represented by —N(R_{1A})(R_{2A}) as a substituent, R_{1A} and R_{2A} are each independently bonded with the ring C₁ to form a substituted or unsubstituted monocyclic ring, bonded with the ring C₁ to form a substituted or unsubstituted fused ring, or not bonded with the ring C₁;
when the ring D₁ has a group represented by —N(R_{1A})(R_{2A}) as a substituent, R_{1A} and R_{2A} are each independently bonded with the ring D₁ to form a substituted or unsubstituted monocyclic ring, bonded with the ring D₁ to form a substituted or unsubstituted fused ring, or not bonded with the ring D₁;
R_{1A} and R_{2A} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one of a monocyclic ring having a bond between Za and Zb in the ring A1, or a monocyclic ring closest to a bond between a boron atom and a nitrogen atom in the ring C₁ is a substituted or unsubstituted monocyclic ring having 5 ring atoms;
Y is a single bond bonding an atom forming the ring B₁ and an atom forming the ring C₁, an oxygen atom, a sulfur atom, NR_{21A}, CR_{22A}R_{23A}, or SiR_{24A}R_{25A};
a combination of R_{22A} and R_{23A} are mutually bonded to form a substituted or unsubstituted monocyclic ring, mutually bonded to form a substituted or unsubstituted fused ring, or not mutually bonded;
a combination of R_{24A} and R_{25A} are mutually bonded to form a substituted or unsubstituted monocyclic ring, mutually bonded to form a substituted or unsubstituted fused ring, or not mutually bonded;
R_{21A}, and R_{22A}, R_{23A}, R_{24A} and R_{25A} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when R₁, the ring A₁, the ring B₁, the ring C₁, and the ring D₁ have substituents, the substituents are each independently a group represented by —N(R_{1A})(R_{2A}), a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₁₃₃)(R₁₃₄)(R₁₃₅), a group represented by —O—(R₁₃₆), a group represented by —S—(R₁₃₇), a substituted or unsubstituted aralkyl group having 7 to 50 carbon atoms, a group represented by —C(═O)R₁₃₈, a group represented by —COOR₁₃₉, a halogen atom, a cyano group, a nitro group, a group represented by —P(═O)(R₁₄₀)(R₁₄₁), a group represented by —Ge(R₁₄₂)(R₁₄₃)(R₁₄₄), a group represented by —B(R₁₄₅)(R₁₄₆), a substituted or unsubstituted aryl group having 6 to 50 ring carbon atoms, or a substituted or unsubstituted heterocyclic group having 5 to 50 ring atoms; R₁₃₃ to R₁₄₆ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{1A} are present, the plurality of R_{1A} are mutually the same or different;
when a plurality of R_{2A} are present, the plurality of R_{2A} are mutually the same or different;
when a plurality of R₁₃₃ are present, the plurality of R₁₃₃ are mutually the same or different;
when a plurality of R₁₃₄ are present, the plurality of R₁₃₄ are mutually the same or different;
when a plurality of R₁₃₅ are present, the plurality of R₁₃₅ are mutually the same or different;
when a plurality of R₁₃₆ are present, the plurality of R₁₃₆ are mutually the same or different;
when a plurality of R₁₃₇ are present, the plurality of R₁₃₇ are mutually the same or different;
when a plurality of R₁₃₈ are present, the plurality of R₁₃₈ are mutually the same or different;
when a plurality of R₁₃₉ are present, the plurality of R₁₃₉ are mutually the same or different;
when a plurality of R₁₄₀ are present, the plurality of R₁₄₀ are mutually the same or different;
when a plurality of R₁₄₁ are present, the plurality of R₁₄₁ are mutually the same or different;
when a plurality of R₁₄₂ are present, the plurality of R₁₄₂ are mutually the same or different;
when a plurality of R₁₄₃ are present, the plurality of R₁₄₃ are mutually the same or different;
when a plurality of R₁₄₄ are present, the plurality of R₁₄₄ are mutually the same or different;
when a plurality of R₁₄₅ are present, the plurality of R₁₄₅ are mutually the same or different; and when a plurality of R₁₄₆ are present, the plurality of R₁₄₆ are mutually the same or different.

According to another aspect of the invention, there is provided an organic-electroluminescence-device material containing the compound according to the above aspect of the invention.

According to still another aspect of the invention, there is provided an organic electroluminescence device including a cathode, an anode, and an organic layer provided between the cathode and the anode, in which at least one layer of the organic layer contains the compound according to the above aspect of the invention.

According to a further aspect of the invention, there is provided an electronic device including the organic electroluminescence device according to the above aspect of the invention.

According to the above aspects of the invention, there can be provided a compound having an emission peak wavelength in a desired wavelength zone in a fluorescence spectrum waveform. According to the above aspects of the invention, there can be provided an organic-electroluminescence-device material and an organic electroluminescence device each containing a compound having an emission peak wavelength in a desired wavelength zone in a fluorescence spectrum waveform, and an electronic device including the organic electroluminescence device.

### BRIEF EXPLANATION OF DRAWING(S)

FIG. 1 schematically illustrates an exemplary arrangement of an organic electroluminescence device according to a third exemplary embodiment of the invention.

FIG. 2 schematically illustrates an exemplary arrangement of an organic electroluminescence device according to a fourth exemplary embodiment of the invention.

FIG. 3 schematically illustrates another exemplary arrangement of the organic electroluminescence device according to the fourth exemplary embodiment of the invention.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring 4 ring carbon atoms. For instance, a 9,9-diphenylfluorenyl group has 13 ring carbon atoms and 9,9′-spirobifluorenyl group has 25 ring carbon atoms.

When a benzene ring is substituted by, for instance, an alkyl group as a substituent, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted in the number of the ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Mentioned Herein

Substituents mentioned herein will be described below.

An “unsubstituted aryl group” mentioned herein has, unless otherwise specified herein, 6 to 50, preferably 6 to 30, and more preferably 6 to 18 ring carbon atoms.

An “unsubstituted heterocyclic group” mentioned herein has, unless otherwise specified herein, 5 to 50, preferably 5 to 30, and more preferably 5 to 18 ring atoms.

An “unsubstituted alkyl group” mentioned herein has, unless otherwise specified herein, 1 to 50, preferably 1 to 20, and more preferably 1 to 6 carbon atoms.

An “unsubstituted alkenyl group” mentioned herein has, unless otherwise specified herein, 2 to 50, preferably 2 to 20, and more preferably 2 to 6 carbon atoms.

An “unsubstituted alkynyl group” mentioned herein has, unless otherwise specified herein, 2 to 50, preferably 2 to 20, and more preferably 2 to 6 carbon atoms.

An “unsubstituted cycloalkyl group” mentioned herein has, unless otherwise specified herein, 3 to 50, preferably 3 to 20, and more preferably 3 to 6 ring carbon atoms.

An “unsubstituted arylene group” mentioned herein has, unless otherwise specified herein, 6 to 50, preferably 6 to 30, and more preferably 6 to 18 ring carbon atoms.

An “unsubstituted divalent heterocyclic group” mentioned herein has, unless otherwise specified herein, 5 to 50, preferably 5 to 30, and more preferably 5 to 18 ring atoms.

An “unsubstituted alkylene group” mentioned herein has, unless otherwise specified herein, 1 to 50, preferably 1 to 20, and more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G11B). (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

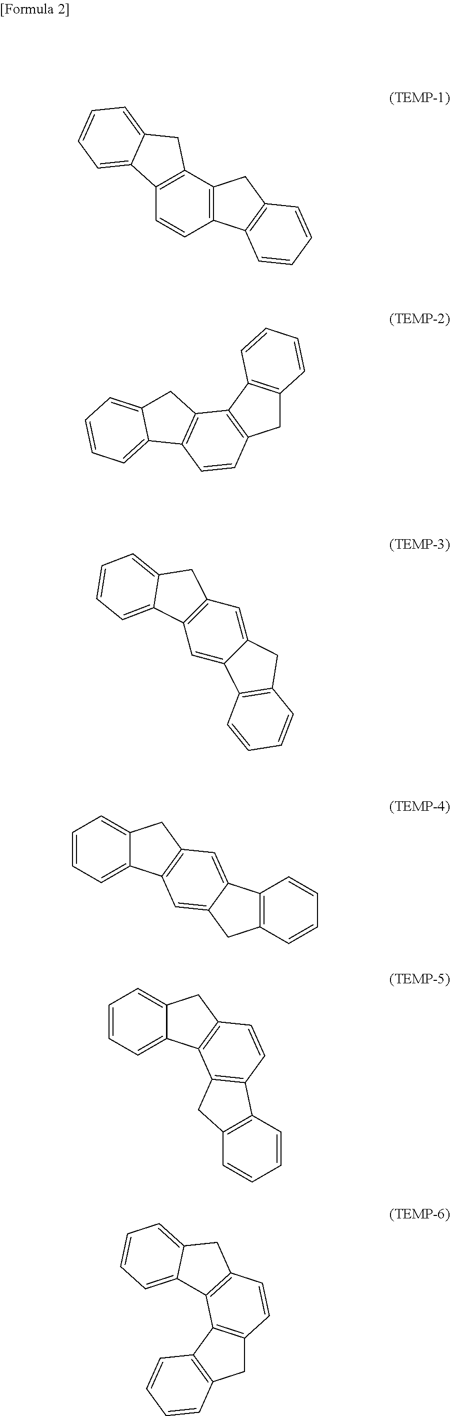

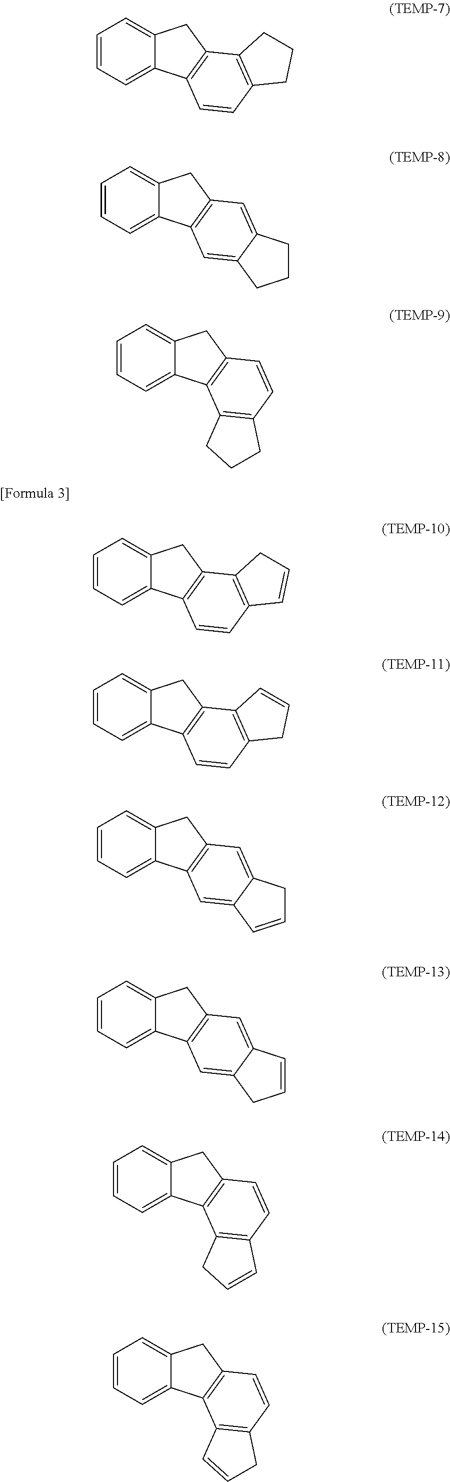

Substituted Aryl Group (Specific Example Group G1B):
an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

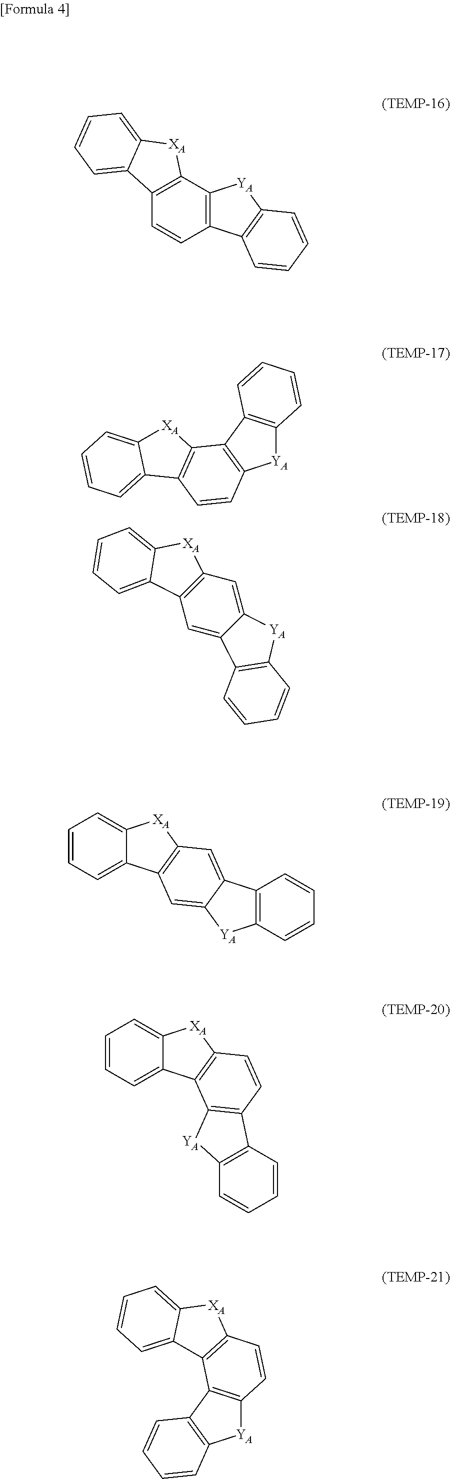

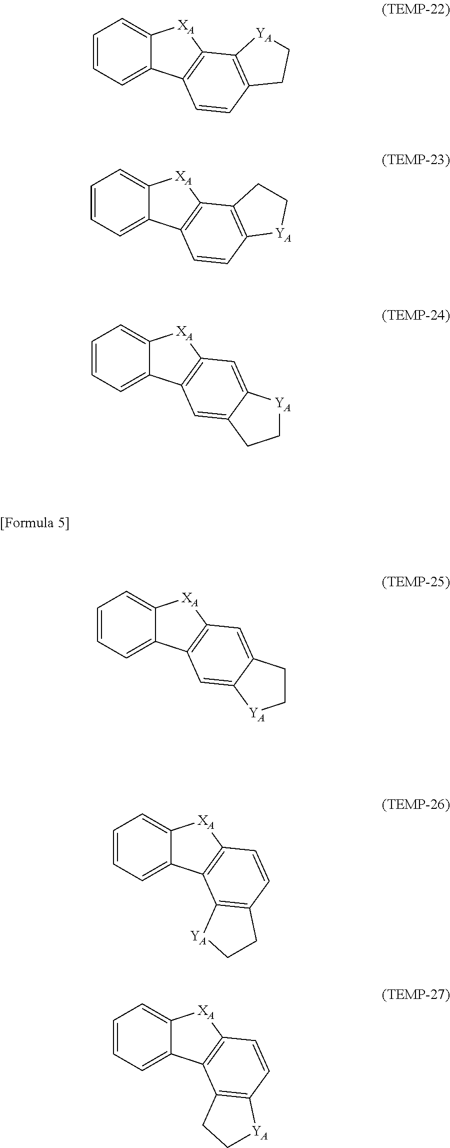

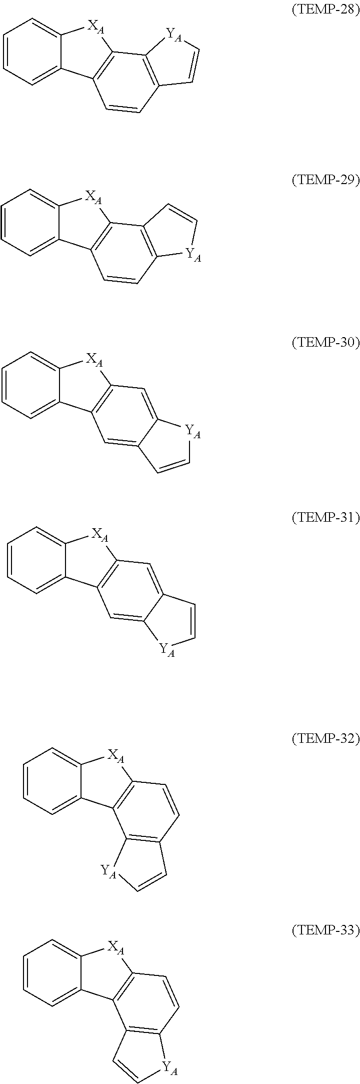

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.” A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. Herein, an unsubstituted alkynyl group refers to an “unsubstituted alkynyl group” in a “substituted or unsubstituted alkynyl group.” A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.” A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include:
—Si(G1)(G1)(G1); —Si(G1)(G2)(G2); —Si(G1)(G1)(G2); —Si(G2)(G2)(G2);
—Si(G3)(G3)(G3); and —Si(G6)(G6)(G6);
where:
   G1 represents a “substituted or unsubstituted aryl group” in the specific example group G1;
   G2 represents a “substituted or unsubstituted heterocyclic group” in the specific example group G2;
   G3 represents a “substituted or unsubstituted alkyl group” in the specific example group G3;
   G6 represents a “substituted or unsubstituted cycloalkyl group” in the specific example group G6;
   a plurality of G1 in —Si(G1)(G1)(G1) are mutually the same or different;
   a plurality of G2 in —Si(G1)(G2)(G2) are mutually the same or different;
   a plurality of G1 in —Si(G1)(G1)(G2) are mutually the same or different;
   a plurality of G2 in —Si(G2)(G2)(G2) are mutually the same or different;
   a plurality of G3 in —Si(G3)(G3)(G3) are mutually the same or different; and
   a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

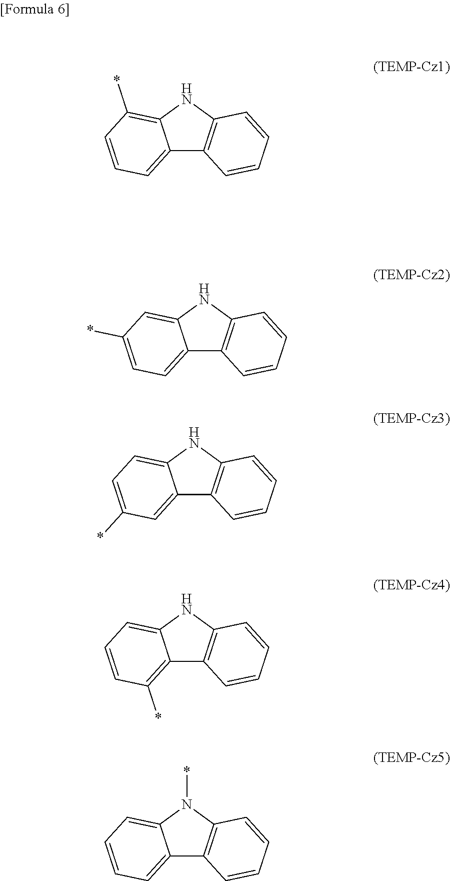 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

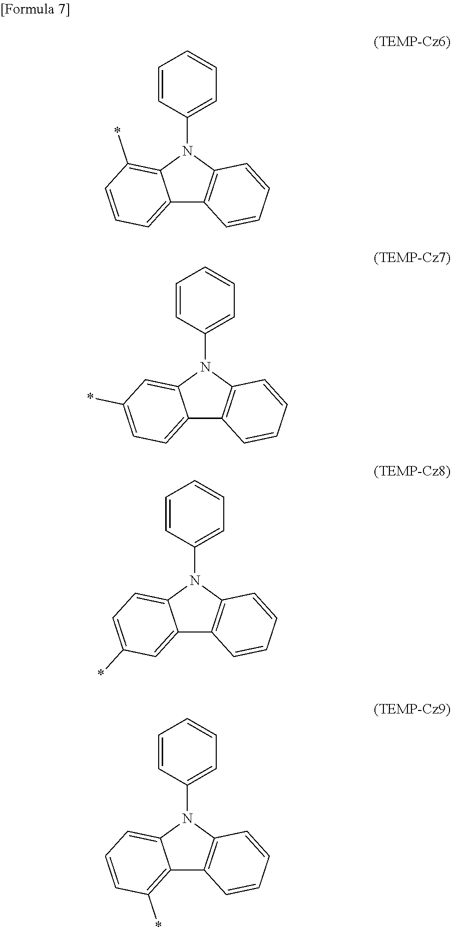

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

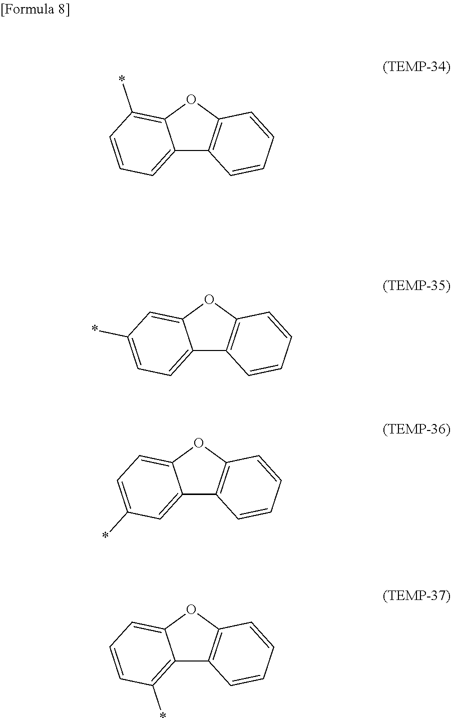 [SMILES: *c1cccc2c1oc1ccccc12 ; *c1ccc2c(c1)oc1ccccc12 ; *c1ccc2oc3ccccc3c2c1 ; *c1cccc2oc3ccccc3c12]

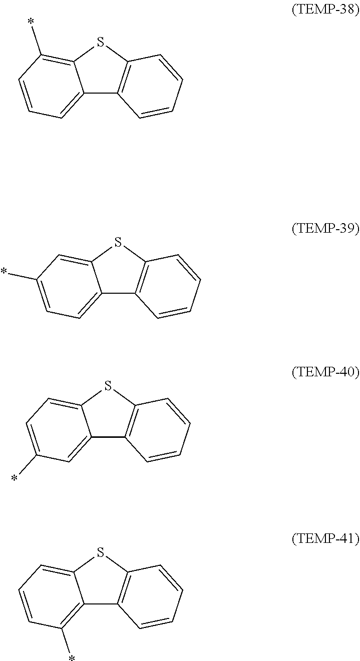 [SMILES: *c1cccc2c1sc1ccccc12 ; *c1ccc2c(c1)sc1ccccc12 ; *c1ccc2sc3ccccc3c2c1 ; *c1cccc2sc3ccccc3c12]

In the formulae (TEMP-34) to (TEMP-41), * each represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocyclic ring of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

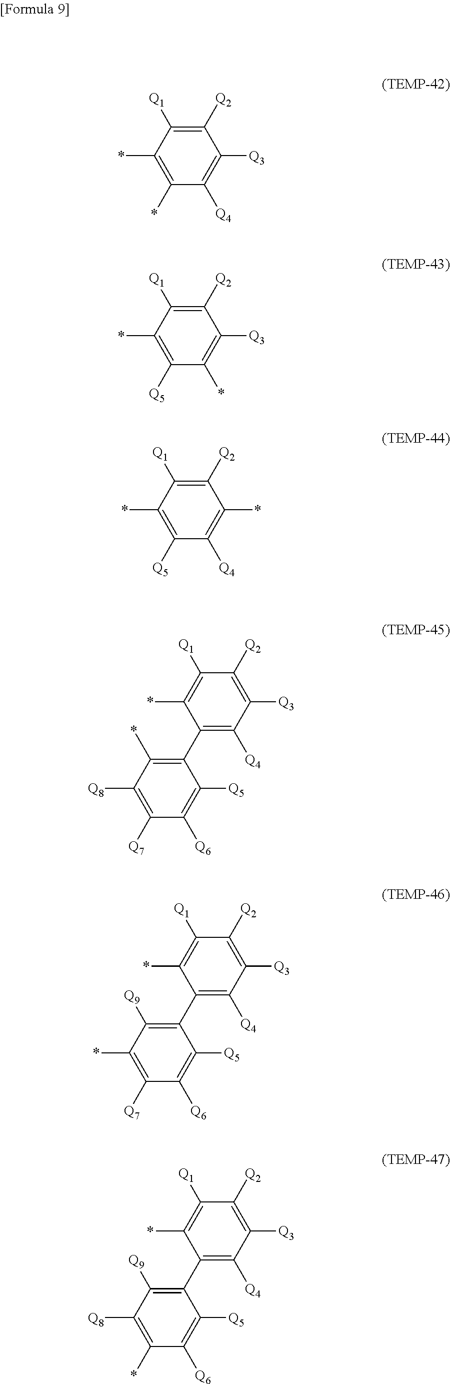

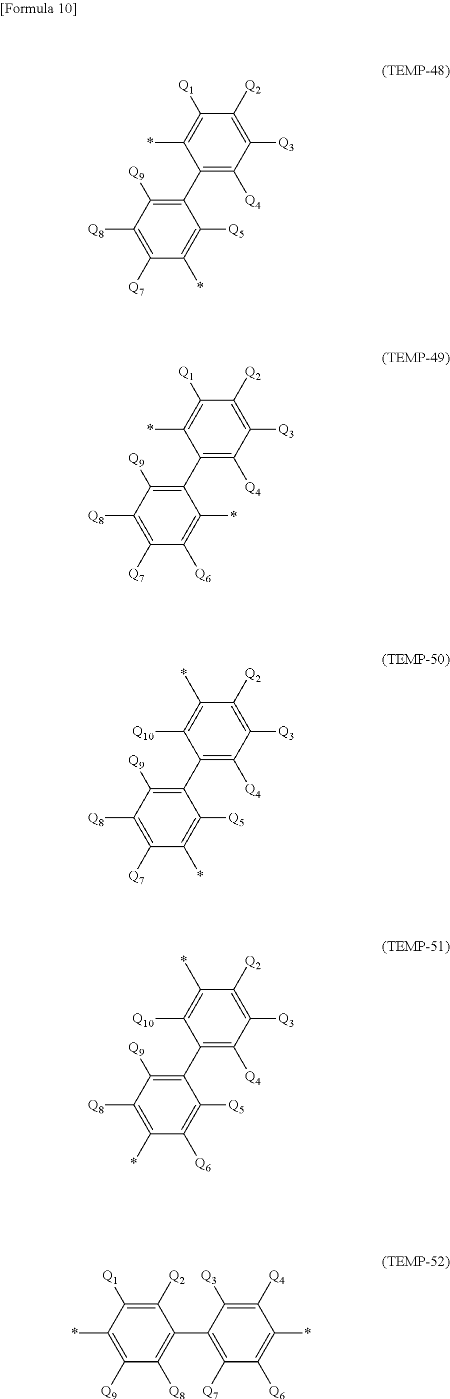

In the formulae (TEMP-42) to (TEMP-52), Q₁ to Q₁₀ are each independently a hydrogen atom or a substituent.

In the formulae (TEMP-42) to (TEMP-52), * each represents a bonding position.

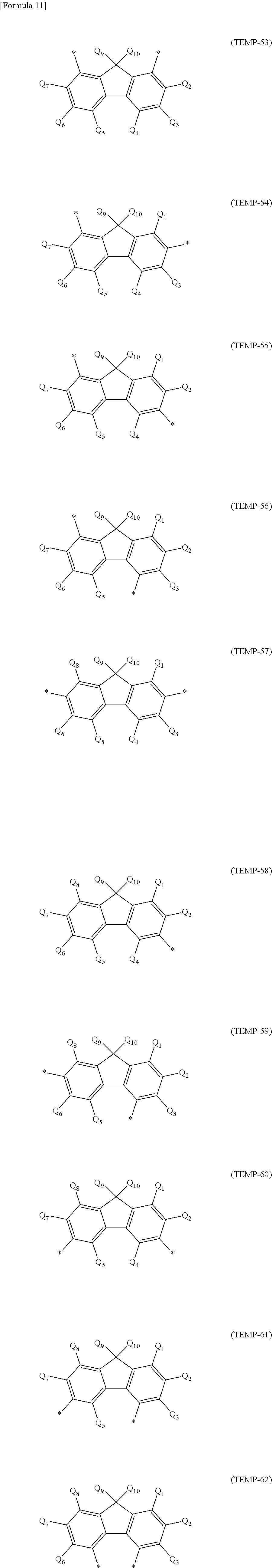

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * each represents a bonding position.

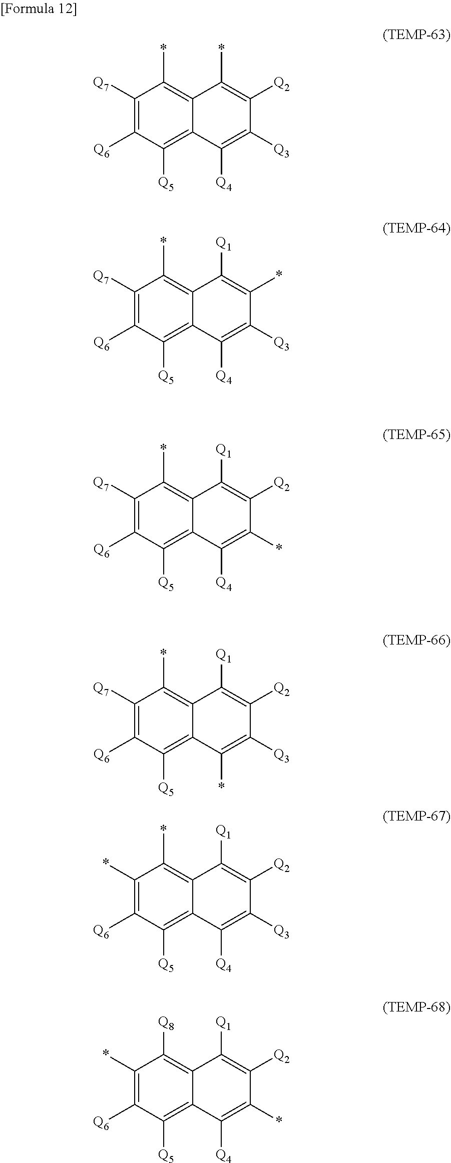

In the formulae (TEMP-63) to (TEMP-68), Q₁ to Q₈ are each independently a hydrogen atom or a substituent.

In the formulae (TEMP-63) to (TEMP-68), * each represents a bonding position.

The substituted or unsubstituted divalent heterocyclic group mentioned herein is, unless otherwise specified herein, preferably a group represented by any one of formulae (TEMP-69) to (TEMP-102) below.

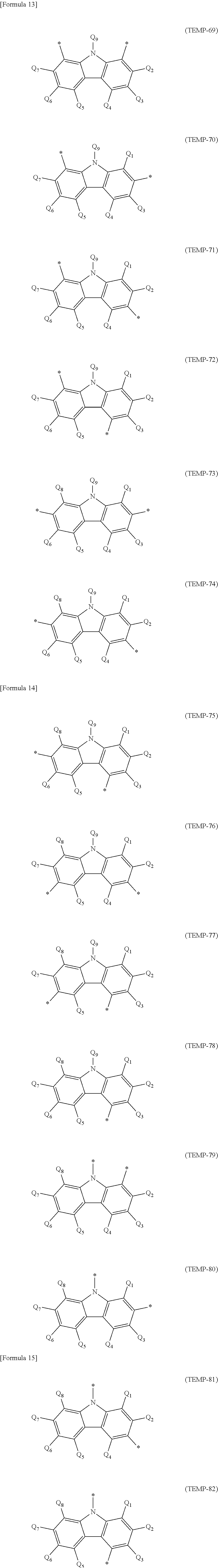

In the formulae (TEMP-69) to (TEMP-82), Q₁ to Q₈ are each independently a hydrogen atom or a substituent.

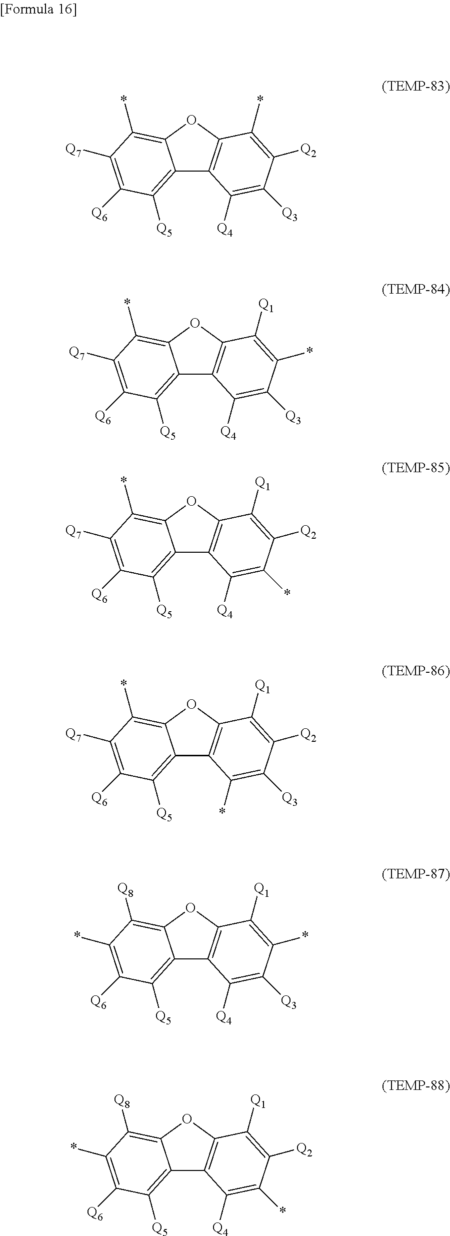

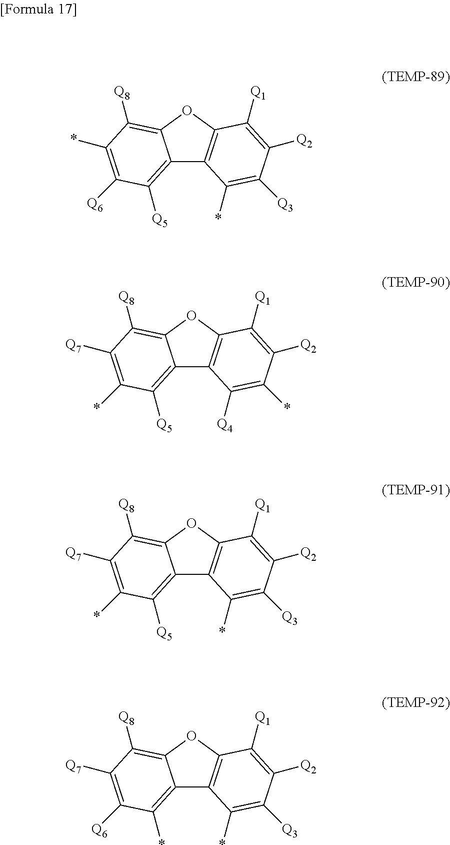

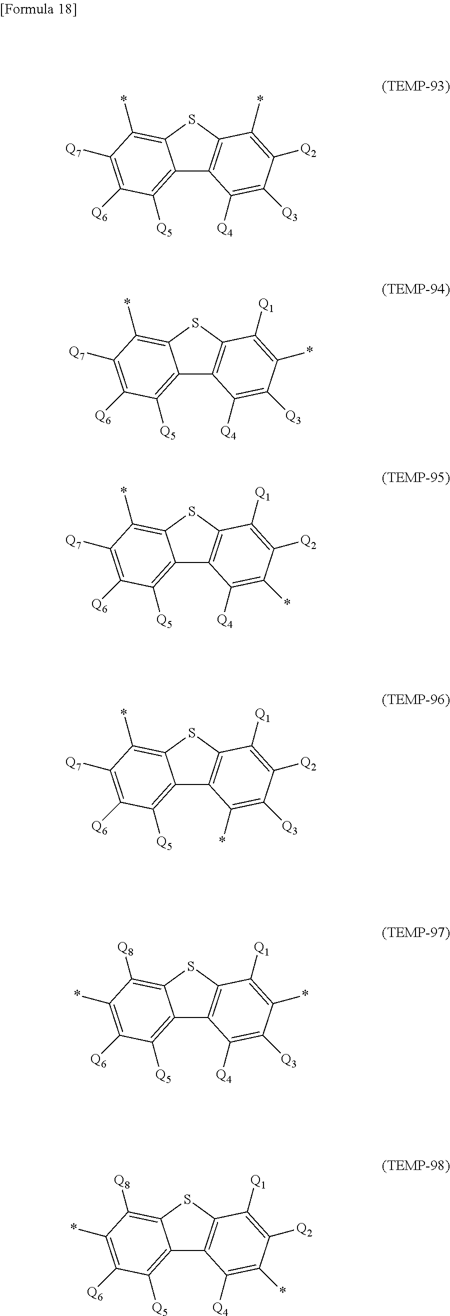

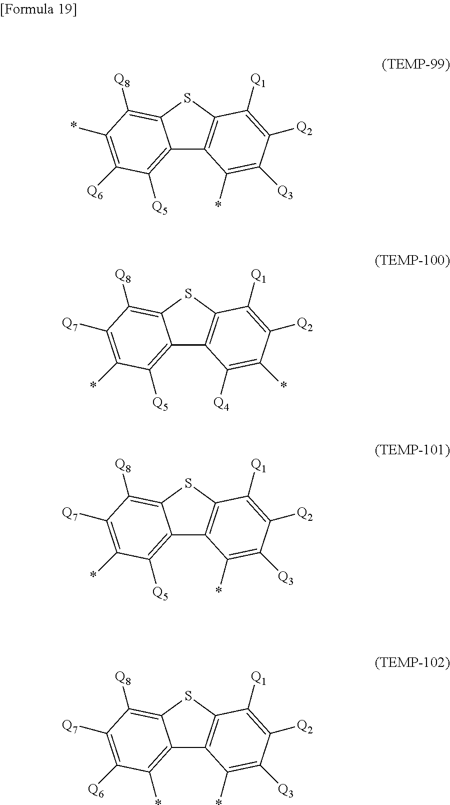

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

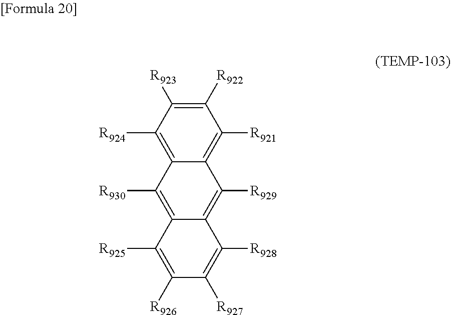

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

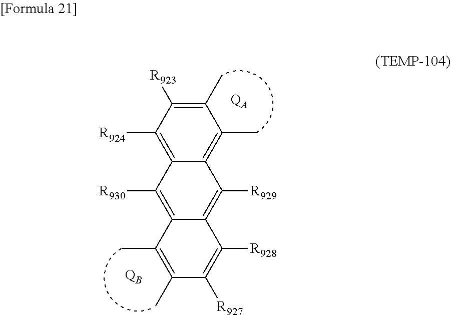

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

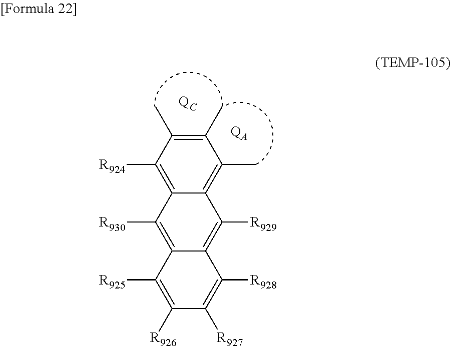

The formed monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocyclic ring include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more Rsos are present, the two or more Rsos are mutually the same or different; and when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Compounds

A compound according to the exemplary embodiment is represented by a formula (1) below.

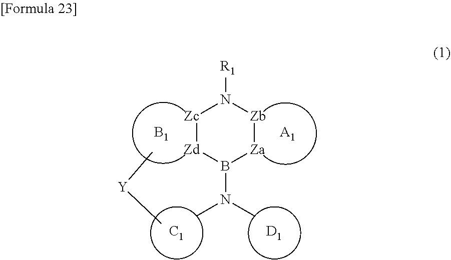

In the formula (1):
a ring A₁, a ring B₁, a ring C₁, and a ring D₁ are each independently a substituted or unsubstituted ring having 5 to 60 ring atoms;
Za and Zb are atoms forming the ring A₁;
Zc and Zd are atoms forming the ring B₁;
Za, Zb, Zc, and Zd are each independently a nitrogen atom or a carbon atom;
the ring C₁ and the ring D₁ are mutually bonded to form a substituted or unsubstituted monocyclic ring, mutually bonded to form a substituted or unsubstituted fused ring, or not mutually bonded;
R₁ is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆);
   when R₁ is a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms, R₁ is bonded with the ring A₁ to form a substituted or unsubstituted monocyclic ring, bonded with the ring A₁ to form a substituted or unsubstituted fused ring, or not bonded with the ring A₁, or bonded with the ring B₁ to form a substituted or unsubstituted monocyclic ring, bonded with the ring B₁ to form a substituted or unsubstituted fused ring, or not bonded with the ring B₁;
at least one of R₁, the ring A₁, the ring B₁, the ring C₁, or the ring D₁ has a group represented by —N(R_{1A})(R_{2A}) as a substituent;
a combination of R_{1A} and R_{2A} are mutually bonded to form a substituted or unsubstituted monocyclic ring, mutually bonded to form a substituted or unsubstituted fused ring, or not mutually bonded;
when R₁ has a group represented by —N(R_{1A})(R_{2A}) as a substituent, R_{1A} and R_{2A} are each independently bonded with R₁ to form a substituted or unsubstituted monocyclic ring, bonded with R₁ to form a substituted or unsubstituted fused ring, or not bonded with R₁;
when the ring A₁ has a group represented by —N(R_{1A})(R_{2A}) as a substituent, R_{1A} and R_{2A} are each independently bonded with the ring A₁ to form a substituted or unsubstituted monocyclic ring, bonded with the ring A₁ to form a substituted or unsubstituted fused ring, or not bonded with the ring A₁;
when the ring B₁ has a group represented by —N(R_{1A})(R_{2A}) as a substituent, R_{1A} and R_{2A} are each independently bonded with the ring B₁ to form a substituted or unsubstituted monocyclic ring, bonded with the ring B₁ to form a substituted or unsubstituted fused ring, or not bonded with the ring B₁;
when the ring C₁ has a group represented by —N(R_{1A})(R_{2A}) as a substituent, R_{1A} and R_{2A} are each independently bonded with the ring C₁ to form a substituted or unsubstituted monocyclic ring, bonded with the ring C₁ to form a substituted or unsubstituted fused ring, or not bonded with the ring C₁;
when the ring D₁ has a group represented by —N(R_{1A})(R_{2A}) as a substituent, R_{1A} and R_{2A} are each independently bonded with the ring D₁ to form a substituted or unsubstituted monocyclic ring, bonded with the ring D₁ to form a substituted or unsubstituted fused ring, or not bonded with the ring D₁;
R_{1A} and R_{2A} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one of a monocyclic ring having a bond between Za and Zb in the ring A1, or a monocyclic ring closest to a bond between a boron atom and a nitrogen atom in the ring C₁ is a substituted or unsubstituted monocyclic ring having 5 ring atoms;
Y is a single bond bonding an atom forming the ring B₁ and an atom forming the ring C₁, an oxygen atom, a sulfur atom, NR_{21A}, CR_{22A}R_{23A}, or SiR_{24A}R_{25A};
a combination of R_{22A} and R_{23A} are mutually bonded to form a substituted or unsubstituted monocyclic ring, mutually bonded to form a substituted or unsubstituted fused ring, or not mutually bonded;
a combination of R_{24A} and R_{25A} are mutually bonded to form a substituted or unsubstituted monocyclic ring, mutually bonded to form a substituted or unsubstituted fused ring, or not mutually bonded;
R_{21A}, and R_{22A}, R_{23A}, R_{24A} and R_{25A} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when R₁, the ring A₁, the ring B₁, the ring C₁, and the ring D₁ have substituents, the substituents are each independently a group represented by —N(R_{1A})(R_{2A}), a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₁₃₃)(R₁₃₄)(R₁₃₅), a group represented by —O—(R₁₃₆), a group represented by —S—(R₁₃₇), a substituted or unsubstituted aralkyl group having 7 to 50 carbon atoms, a group represented by —C(═O)R₁₃₈, a group represented by —COOR₁₃₉, a halogen atom, a cyano group, a nitro group, a group represented by —P(═O)(R₁₄₀)(R₁₄₁), a group represented by —Ge(R₁₄₂)(R₁₄₃)(R₁₄₄), a group represented by —B(R₁₄₅)(R₁₄₆), a substituted or unsubstituted aryl group having 6 to 50 ring carbon atoms, or a substituted or unsubstituted heterocyclic group having 5 to 50 ring atoms;
R₁₃₃ to R₁₄₆ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{1A} are present, the plurality of R_{1A} are mutually the same or different;
when a plurality of R_{2A} are present, the plurality of R_{2A} are mutually the same or different;
when a plurality of R₁₃₃ are present, the plurality of R₁₃₃ are mutually the same or different;
when a plurality of R₁₃₄ are present, the plurality of R₁₃₄ are mutually the same or different;
when a plurality of R₁₃₅ are present, the plurality of R₁₃₅ are mutually the same or different;
when a plurality of R₁₃₆ are present, the plurality of R₁₃₆ are mutually the same or different;
when a plurality of R₁₃₇ are present, the plurality of R₁₃₇ are mutually the same or different;
when a plurality of R₁₃₈ are present, the plurality of R₁₃₈ are mutually the same or different;
when a plurality of R₁₃₉ are present, the plurality of R₁₃₉ are mutually the same or different;
when a plurality of R₁₄₀ are present, the plurality of R₁₄₀ are mutually the same or different;
when a plurality of R₁₄₁ are present, the plurality of R₁₄₁ are mutually the same or different;
when a plurality of R₁₄₂ are present, the plurality of R₁₄₂ are mutually the same or different;
when a plurality of R₁₄₃ are present, the plurality of R₁₄₃ are mutually the same or different;
when a plurality of R₁₄₄ are present, the plurality of R₁₄₄ are mutually the same or different;
when a plurality of R₁₄₅ are present, the plurality of R₁₄₅ are mutually the same or different; and
when a plurality of R₁₄₆ are present, the plurality of R₁₄₆ are mutually the same or different.

According to the exemplary embodiment, a compound having an emission peak wavelength in a desired wavelength zone in a fluorescence spectrum waveform can be provided. A compound according to an exemplary embodiment emits light having a narrow full width at half maximum of a fluorescence spectrum. A compound according to an exemplary embodiment exhibits a high value of PLQY.

Using a compound according to an exemplary embodiment for a material of an organic EL device causes the organic EL device to emit light having a narrow full width at half maximum of a fluorescence spectrum. As a result, luminous efficiency of the organic EL device is improvable.

Herein, the maximum peak wavelength of fluorescence is occasionally referred to as a maximum fluorescence peak wavelength or a maximum peak wavelength.

The compound according to the exemplary embodiment preferably has a maximum fluorescence peak wavelength of 445 nm or more. The compound according to the exemplary embodiment preferably has the maximum fluorescence peak wavelength of 480 nm or less, more preferably 465 nm or less. When the maximum fluorescence peak wavelength of the compound according to the exemplary embodiment is 445 nm or more, an electronic device (e.g., display) including the organic EL device including the compound according to the exemplary embodiment easily emits target moderate blue light. When the maximum fluorescence peak wavelength of the compound according to the exemplary embodiment is 480 nm or less, an electronic device (e.g., display) including the organic EL device including the compound according to the exemplary embodiment easily emits target moderate blue light.

Herein, the maximum fluorescence peak wavelength means a peak wavelength of a fluorescence spectrum exhibiting a maximum luminous intensity among fluorescence spectra measured in a toluene solution in which a measurement target compound is dissolved at a concentration ranging from 10⁻⁶ mol/l to 10⁻⁵ mol/l. A fluorescence spectrum measurement apparatus (apparatus name: FP-8300, produced by JASCO Corporation) is usable as a measurement apparatus. It should be noted that the fluorescence spectrum measurement apparatus is not limited to the apparatus listed herein.

The lowest singlet energy level (hereinafter, sometimes referred to as S1 energy level) of the compound according to the exemplary embodiment is preferably estimated to be low. For instance, the S1 energy level of the compound according to the exemplary embodiment is preferably in a range from 2.6 eV to 3.1 eV, more preferably from 2.6 eV to 3.0 eV. Thus, according to an exemplary embodiment, it is considered that an electronic device (e.g., display) including the organic EL device including the compound according to the exemplary embodiment easily emits target moderate blue light.

The S1 energy level can be calculated by TD-DFT calculation through B3LYP as hybrid functional and 6-31 g* as a basis function using the Gaussian 16 software program available from Gaussian Inc.

The compound according to the exemplary embodiment preferably has a high photoluminescence quantum yield (PLQY).

The PLQY of the compound according to the exemplary embodiment is preferably 80% or more, more preferably 85% or more.

A method of measuring PLQY is exemplified by a method below.

A measurement target compound is dissolved in toluene to prepare a solution at 5.0×10⁻⁶ mol/L. The solution is frozen and degassed and then saturated with argon to prepare an argon saturated solution. The obtained solution is transferred to a quartz cell (light path length: 1.0 cm). Photoluminescence quantum yield (PLQY) is measured using an absolute PL quantum yield measuring apparatus “Hamamatsu Quantaurus-QY C11347” (manufactured by Hamamatsu Photonics Co., Ltd.).

When a compound EX-1 and a compound EX-2 are taken as examples, “a monocyclic ring having a bond between Za and Zb in the ring A₁” and “a monocyclic ring closest to a bond between a boron atom and a nitrogen atom in the ring C₁” respectively correspond to monocyclic rings below.

In a case of the compound EX-1, “a monocyclic ring having a bond between Za and Zb in the ring A₁” corresponds to a benzene ring A₁ that is a monocyclic ring, and “a monocyclic ring closest to a bond between a boron atom and a nitrogen atom in the ring C₁” corresponds to a pyrrole ring C₁ that is a monocyclic ring.

In a case of the compound EX-2, “a monocyclic ring having a bond between Za and Zb in the ring A₁” corresponds to a benzene ring A₁ that is a monocyclic ring. The ring C₁ is a benzofuran ring, which is formed by a furan ring C11 (i.e., monocyclic ring) and a benzene ring C21. “A monocyclic ring closest to a bond between a boron atom and a nitrogen atom in the ring C₁” corresponds to the furan ring C11.

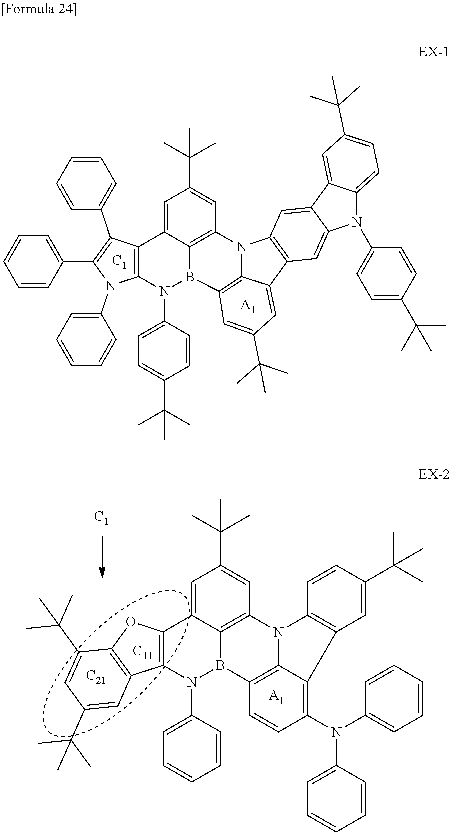

An exemplary arrangement that “R₁ is a benzene ring and the R₁ is bonded to the ring A₁ to form a substituted or unsubstituted monocyclic ring” of the compound according to the exemplary embodiment will be described using a compound EX-3 below as an example.

In the compound EX-3, R₁ is a benzene ring having a group represented by —N(R_{1A})(R_{2A}) (in which R_{1A} and R_{2A} are phenyl groups) as a substituent, the ring A₁ is a benzene ring having a tertiary butyl group as a substituent, and a carbon atom at a position 3* of the benzene ring as R₁ and a carbon atom at a position 4* of the benzene ring as the ring A₁ are bonded to each other to form a monocyclic pyrrole ring C₁₂.

An exemplary arrangement that “R₁ is a benzene ring having a group represented by —N(R_{1A})(R_{2A}) as a substituent and R_{1A} and R_{2A} are not bonded to R₁” of the compound according to the exemplary embodiment will be described using the compound EX-3 below as an example.

In the compound EX-3, R₁ is a benzene ring having a group represented by —N(R_{1A})(R_{2A}) (in which R_{1A} and R_{2A} are phenyl groups) as a substituent, and R_{1A} and R_{2A} are not bonded to R₁.

An exemplary arrangement that “when R₁ is a benzene ring having a group represented by —N(R_{1A})(R_{2A}) as a substituent, R_{1A} and R_{2A} are each independently bonded to R₁ to form a substituted or unsubstituted monocyclic ring” of the compound according to the exemplary embodiment will be described using the compound EX-3 and a compound EX-4 below as examples.

The compound EX-4 is a compound obtained by bonding R_{1A} (phenyl group) to R₁ to form a monocyclic pyrrole ring C13 in the compound EX-3. Specifically, the monocyclic pyrrole ring C13 in the compound EX-4 is formed by bonding a carbon atom at a position 2* of the benzene ring as R_{1A} to a carbon atom at a position 1* of the benzene ring as R₁ in the compound EX-3.

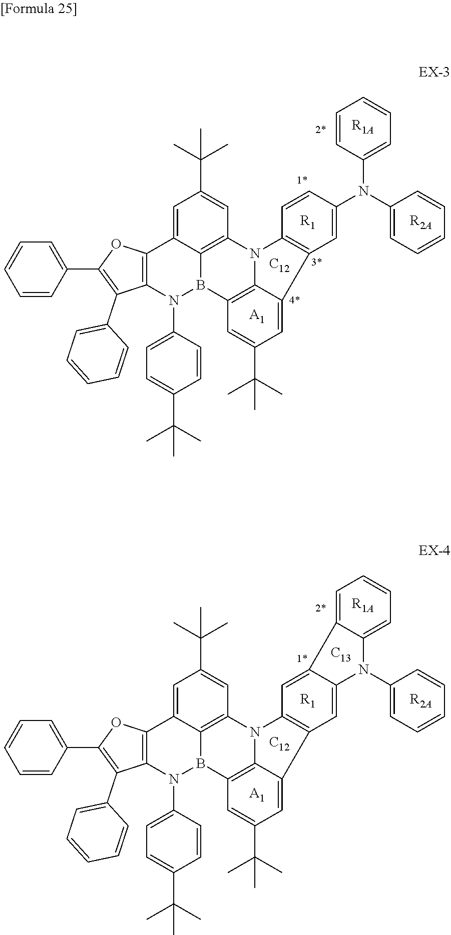

An exemplary arrangement that “when the ring C₁ is a benzene ring having a group represented by —N(R_{1A})(R_{2A}) as a substituent, R_{1A} and R_{2A} are each independently bonded to the ring C₁ to form a substituted or unsubstituted monocyclic ring” of the compound according to the exemplary embodiment and an exemplary arrangement that “when the ring D₁ is a benzene ring having a group represented by —N(R_{1A})(R_{2A}) as a substituent, R_{1A} and R_{2A} are each independently bonded to the ring D₁ to form a substituted or unsubstituted monocyclic ring” of the compound according to the exemplary embodiment will be described using a compound EX-5 and a compound EX-6 below, respectively, as examples.

In the compound EX-5, the ring C₁ is a benzene ring having a group represented by —N(R_{1A})(R_{2A}) (in which R_{1A} and R_{2A} are phenyl groups) as a substituent, and a carbon atom at a position 6* of the benzene ring as R_{1A} and a carbon atom at a position 5* of the benzene ring as the ring C₁ are bonded to each other to form a monocyclic pyrrole ring C₁₄.

In the compound EX-6, the ring D₁ is a benzene ring having a group represented by —N(R_{1A})(R_{2A}) (in which R_{1A} and R_{2A} are phenyl groups) as a substituent, and a carbon atom at a position 8* of the benzene ring as R_{1A} and a carbon atom at a position 7* of the benzene ring as the ring D₁ are bonded to each other to form a monocyclic pyrrole ring C₁₅.

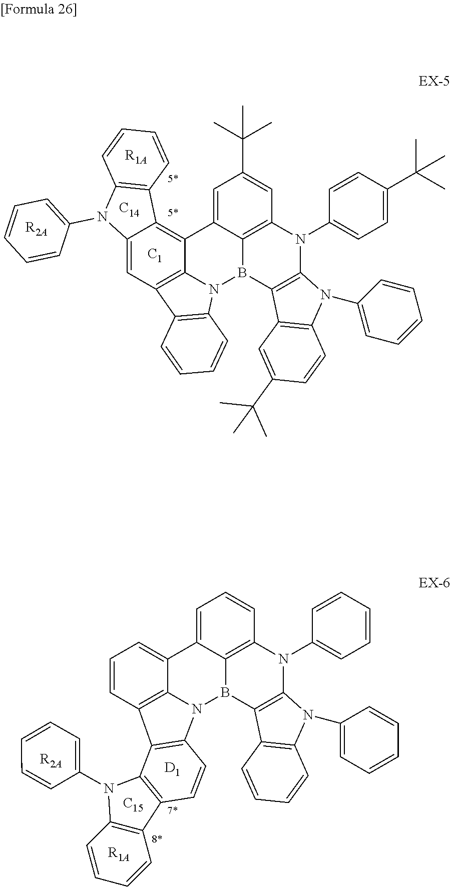

The compound represented by the formula (1) is preferably a compound represented by a formula (11) below.

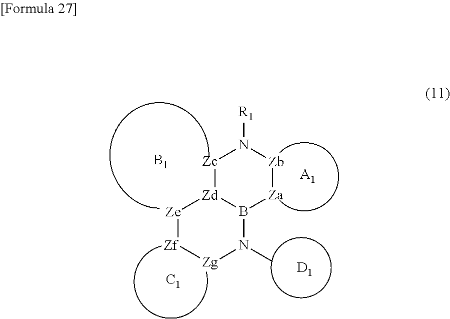

In the formula (11):
R₁, a ring A₁, a ring B₁, a ring C₁, a ring D₁, Za, Zb, Zc, and Zd each independently represent the same as R₁, the ring A₁, the ring B₁, the ring C₁, the ring D₁, Za, Zb, Zc, and Zd in the formula (1);
Zc, Zd, and Ze are atoms forming the ring B₁;
Zf and Zg are atoms forming the ring C₁; and
Ze, Zf, and Zg are each independently a nitrogen atom or a carbon atom.

In the compound according to the exemplary embodiment, Ze, Zf, and Zg are each preferably a carbon atom.

In the compound according to the exemplary embodiment, Za, Zb, Zc, Zd, Ze, Zf, and Zg are each preferably a carbon atom.

In the compound according to the exemplary embodiment, the ring A₁, the ring B₁, the ring C₁, and the ring D₁ in a form of a substituted or unsubstituted ring having 5 to 60 ring atoms are preferably each independently a substituted or unsubstituted aryl ring having 6 to 60 ring carbon atoms, a substituted or unsubstituted heterocyclic ring having 5 to 60 ring atoms, or a substituted or unsubstituted alicyclic hydrocarbon ring having 5 to 60 ring atoms.

In the compound according to the exemplary embodiment, when R₁, the ring A₁, the ring B₁, the ring C₁, and the ring D₁ each have a substituent, the substituent is preferably each independently a group represented by —N(R_{1A})(R_{2A}), a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, —CN, or a group represented by —O—(R₁₃₆).

In the compound according to the exemplary embodiment, the compound represented by the formula (1) is preferably represented by a formula (12) or (13) below.

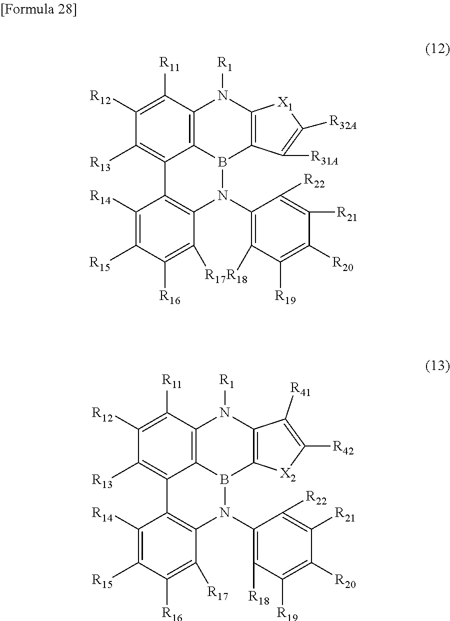

In the formulae (12) and (13):
R₁ represents the same as R₁ in the formula (1);
X₁ and X₂ are each independently an oxygen atom, a sulfur atom, NRx, or C(Rx₁)(Rx₂);
at least one combination of adjacent two or more of R₁, R₁₁ to R₁₃, R_{31A} to R_{32A}, Rx, Rx₁, and Rx₂ are mutually bonded to form a substituted or unsubstituted monocyclic ring, mutually bonded to form a substituted or unsubstituted fused ring, or not mutually bonded;
at least one combination of adjacent two or more of R₁, R₁₁ to R₁₃, R₄₁ to R₄₂, Rx, Rx₁, and Rx₂ are mutually bonded to form a substituted or unsubstituted monocyclic ring, mutually bonded to form a substituted or unsubstituted fused ring, or not mutually bonded;
at least one combination of adjacent two or more of R₁₄ to R₂₂ are mutually bonded to form a substituted or unsubstituted monocyclic ring, mutually bonded to form a substituted or unsubstituted fused ring, or not mutually bonded;
R₁₁ to R₂₂, R_{31A} to R_{32A}, and R₄₁ to R₄₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆); and
Rx, Rx₁, and Rx₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the formula (12):
when a combination of R_{31A} and R_{32A} are not mutually bonded, at least one selected from the group consisting of R₁₁ to R₂₂, R_{31A} to R_{32A}, and a substituent contained in R₁ is a group represented by —N(R_{1A})(R_{2A});
when a combination of R_{31A} and R_{32A} are mutually bonded to form a ring E₁, at least one selected from the group consisting of R₁₁ to R₂₂, a substituent contained in R₁, and a substituent contained in the ring E₁ is a group represented by —N(R_{1A})(R_{2A}); and
when the ring E₁ has a group represented by —N(R_{1A})(R_{2A}) as a substituent, R_{1A} and R_{2A} are each independently bonded with the ring E₁ to form a substituted or unsubstituted monocyclic ring, bonded with the ring E₁ to form a substituted or unsubstituted fused ring, or not bonded with the ring E₁.

In the formula (13):
when a combination of R₄₁ and R₄₂ are not mutually bonded, at least one selected from the group consisting of R₁₁ to R₂₂, R₄₁ to R₄₂, and a substituent contained in R₁ is a group represented by —N(R_{1A})(R_{2A});
when a combination of R₄₁ and R₄₂ are mutually bonded to form a ring F₁, at least one selected from the group consisting of R₁₁ to R₂₂, a substituent contained in R₁, and a substituent contained in the ring F₁ is a group represented by —N(R_{1A})(R_{2A});
when the ring F₁ has a group represented by —N(R_{1A})(R_{2A}) as a substituent, R_{1A} and R_{2A} are each independently bonded with the ring F₁ to form a substituted or unsubstituted monocyclic ring, bonded with the ring F₁ to form a substituted or unsubstituted fused ring, or not bonded with the ring F₁; and
the ring E₁ and the ring F₁ are each independently a substituted or unsubstituted aryl ring having 6 to 57 ring carbon atoms, a substituted or unsubstituted heterocyclic ring having 5 to 57 ring atoms, or a substituted or unsubstituted alicyclic hydrocarbon ring having 5 to 57 ring atoms.

In the compound according to the exemplary embodiment, it is preferable that the compound represented by the formula (12) is represented by a formula (121) below and the compound represented by the formula (13) is represented by a formula (131) below.

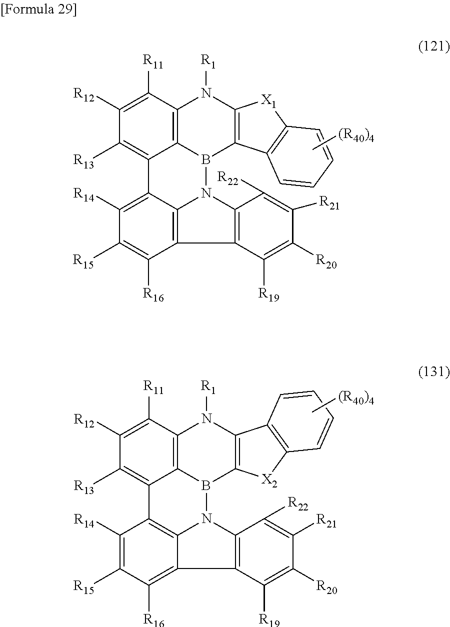

In the formulae (121) and (131):
R₁, R₁₁ to R₁₆, R₁₉ to R₂₂, X₁, and X₂ each independently represent the same as R₁, R₁₁ to R₁₆, R₁₉ to R₂₂, X₁, and X₂ in the formulae (12) and (13); at least one combination of adjacent two or more of R₁, R₁₁ to R₁₃, R₄₀, Rx, Rx₁, and Rx₂ are mutually bonded to form a substituted or unsubstituted monocyclic ring, mutually bonded to form a substituted or unsubstituted fused ring, or not mutually bonded;
a plurality of R₄₀ are mutually the same or different; and
R₄₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (12) and (13).

In the compound according to the exemplary embodiment, it is preferable that the compound represented by the formula (121) is represented by one of formulae (A121) to (A131) below and the compound represented by the formula (131) is represented by one of formulae (B131) to (B141) below.

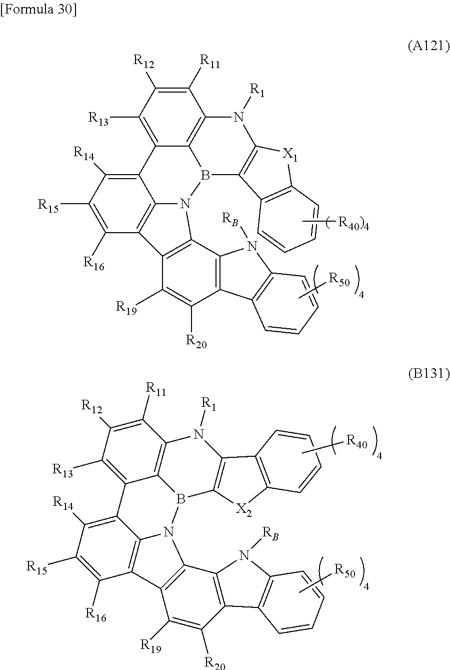

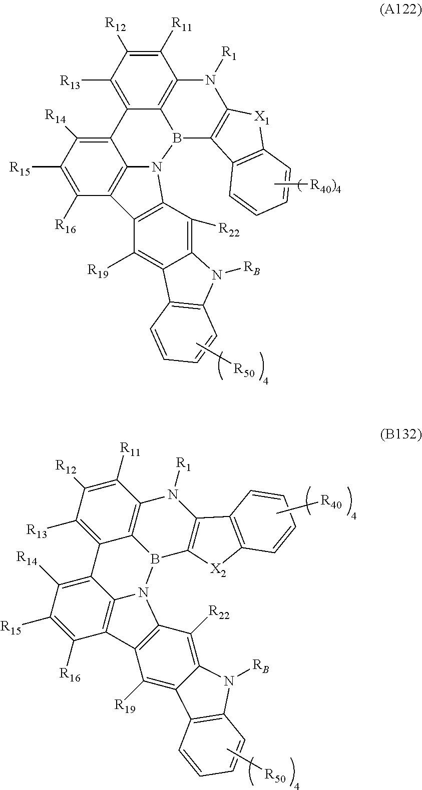

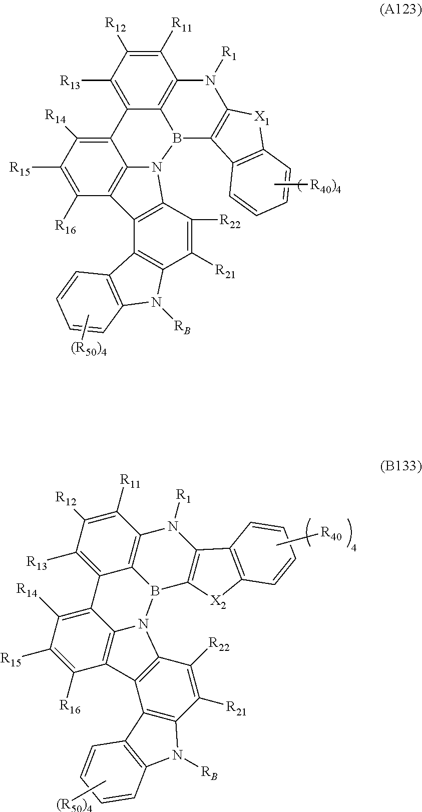

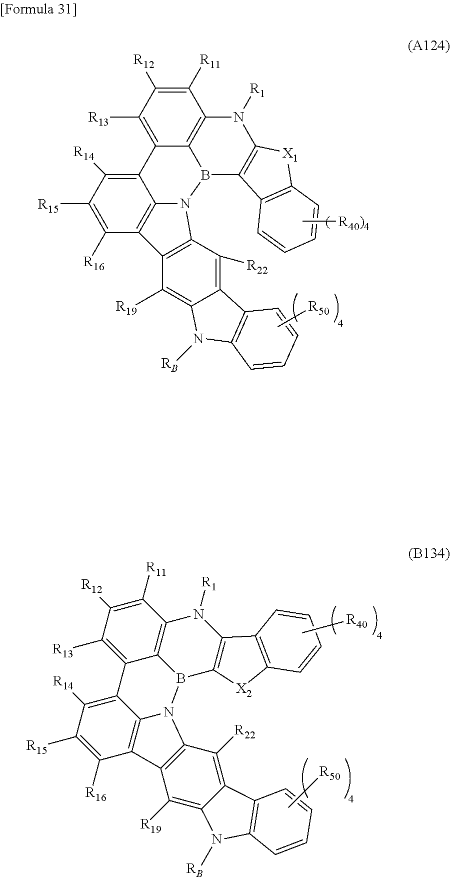

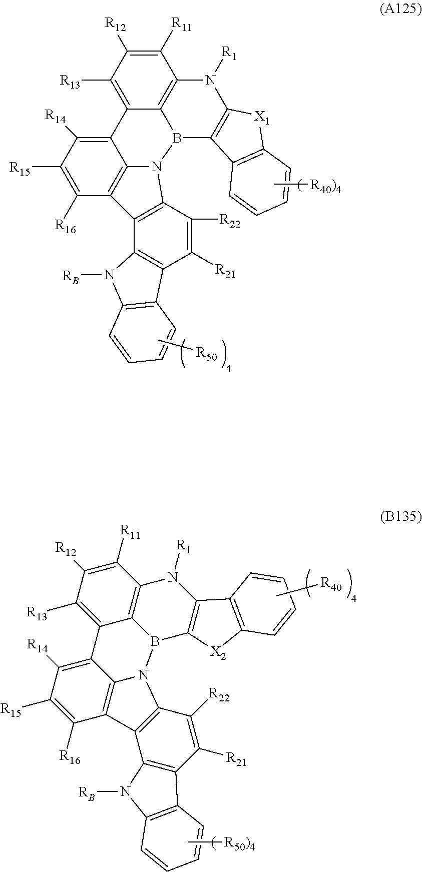

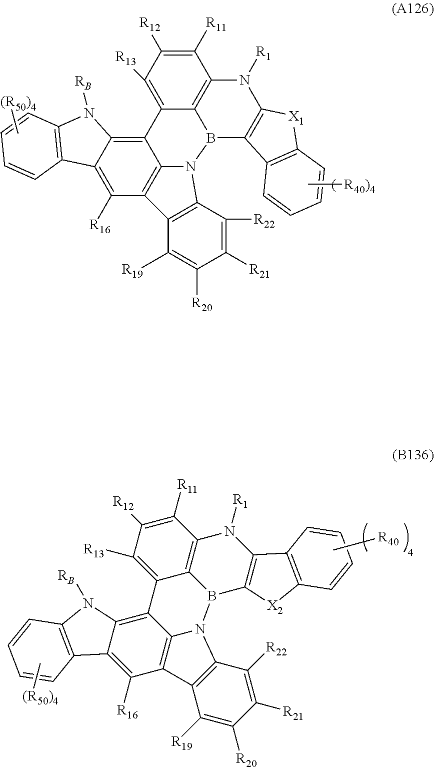

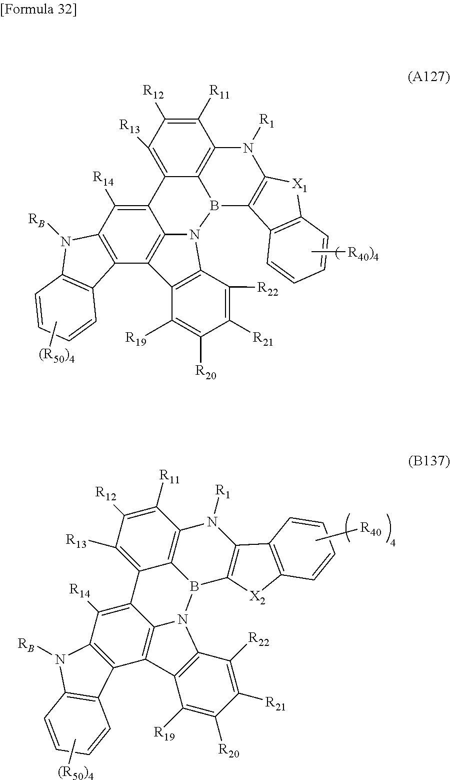

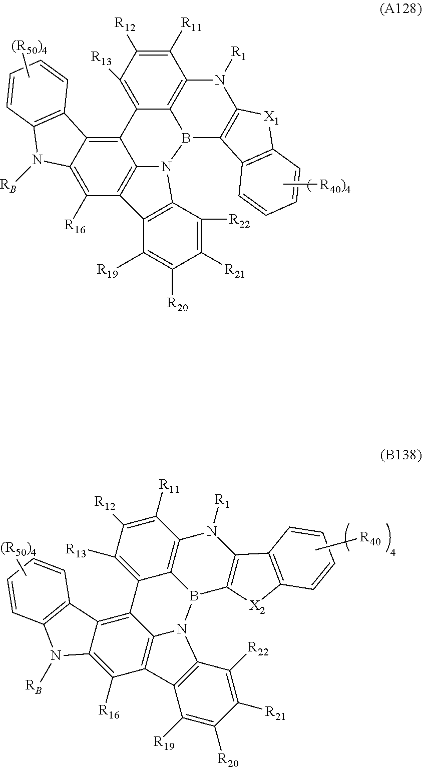

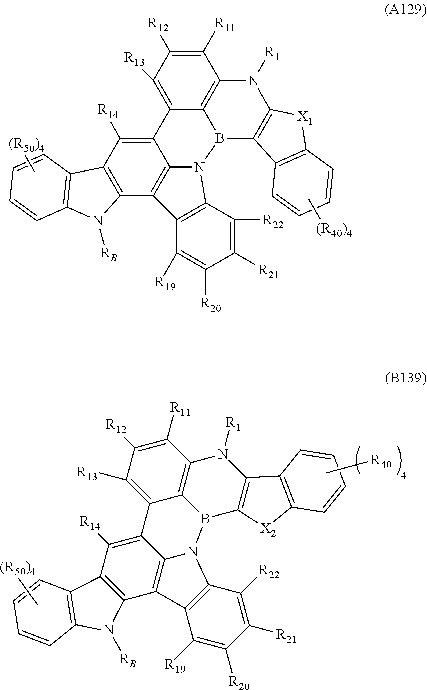

In the formulae (A121) to (A129) and (B131) to (B139):
R₁, R₁₁ to R₁₆, R₁₉ to R₂₂, X₁, X₂, and R₄₀ each independently represent the same as R₁, R₁₁ to R₁₆, R₁₉ to R₂₂, X₁, X₂, and R₄₀ in the formulae (121) and (131);
at least one combination of adjacent two or more of R₅₀ and R_{B} are mutually bonded to form a substituted or unsubstituted monocyclic ring, mutually bonded to form a substituted or unsubstituted fused ring, or not mutually bonded;
a plurality of R₅₀ are mutually the same or different;
R_{B} forming neither the substituted or unsubstituted monocyclic ring nor the substituted or unsubstituted fused ring is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₅₀ forming neither the substituted or unsubstituted monocyclic ring nor the substituted or unsubstituted fused ring each independently represent the same as R₄₀ forming neither the substituted or unsubstituted monocyclic ring nor the substituted or unsubstituted fused ring in the formulae (121) and (131).

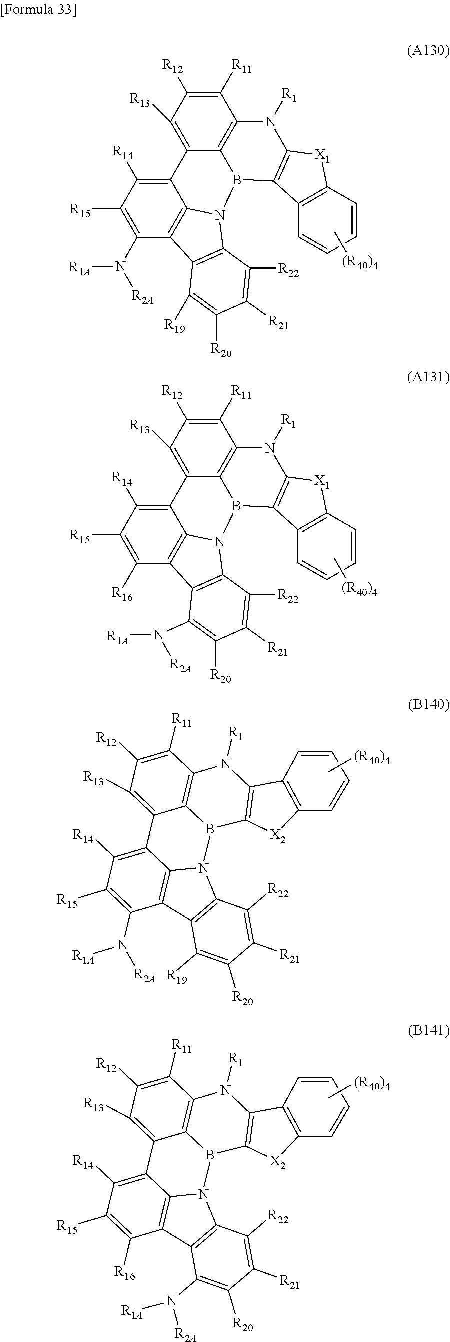

In the formulae (A130) to (A131) and (B140) to (B141):
R₁, R₁₁ to R₁₆, R₁₉ to R₂₂, X₁, X₂, and R₄₀ each independently represent the same as R₁, R₁₁ to R₁₆, R₁₉ to R₂₂, X₁, X₂, and R₄₀ in the formulae (121) and (131); R_{1A} and R_{2A} each independently represent the same as R_{1A} and R_{2A} in the formula (1).

In the compound according to the exemplary embodiment, it is also preferable that the compound represented by the formula (12) is represented by a formula (1201) below and the compound represented by the formula (13) is represented by a formula (1301) below.

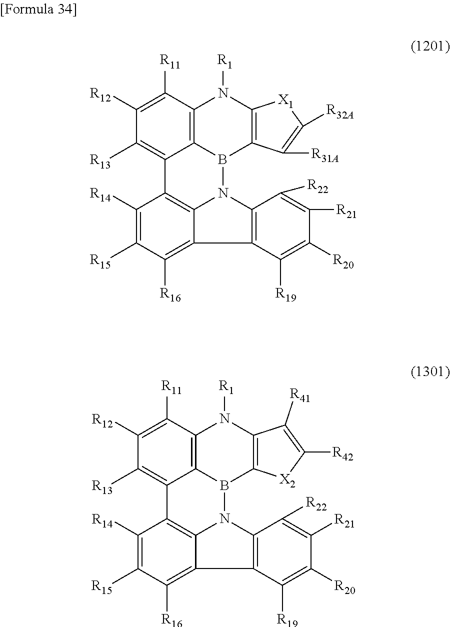

In the formulae (1201) and (1301):
R₁, R₁₁ to R₁₆, R₁₉ to R₂₂, R_{31A} to R_{32A}, R₄₁ to R₄₂, X₁, and X₂ each independently represent the same as R₁, R₁₁ to R₁₆, R₁₉ to R₂₂, R_{31A} to R_{32A}, R₄₁ to R₄₂, X₁, and X₂ in the formulae (12) and (13); and
R_{31A} to R_{32A} and R₄₁ to R₄₂ each independently represent the same as R₁₁ forming neither the substituted or unsubstituted monocyclic ring nor the substituted or unsubstituted fused ring in the formulae (12) and (13).

In the compound according to the exemplary embodiment, it is preferable that the compound represented by the formula (1201) is represented by one of formulae (A1201) to (A1209) below and the compound represented by the formula (1301) is represented by one of formulae (B1301) to (B1309) below.

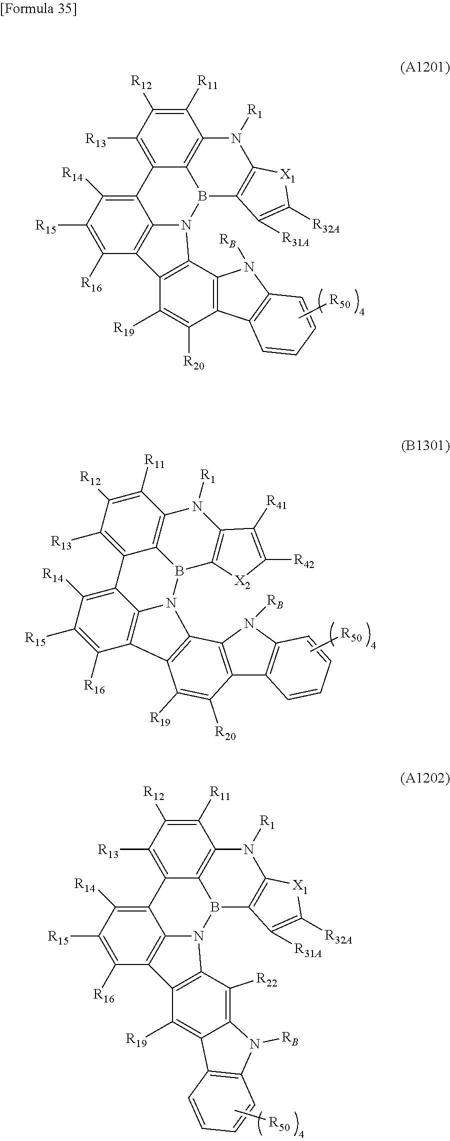

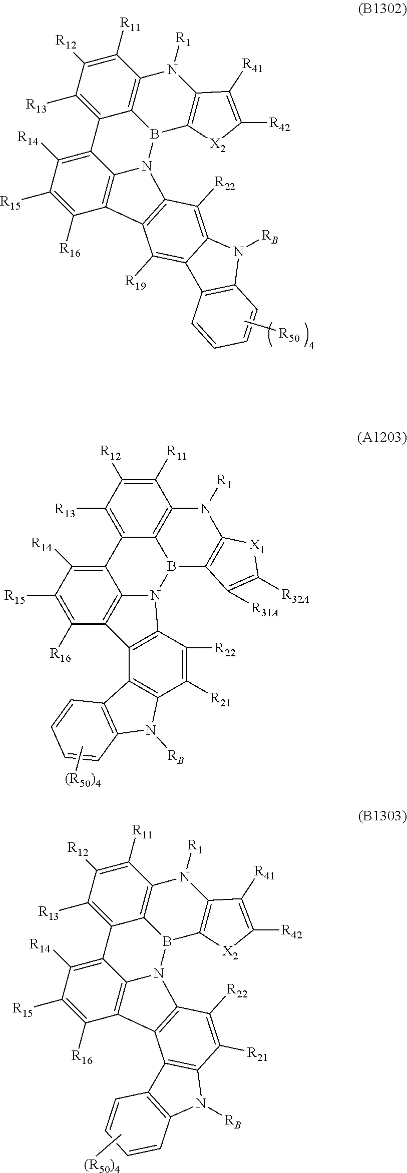

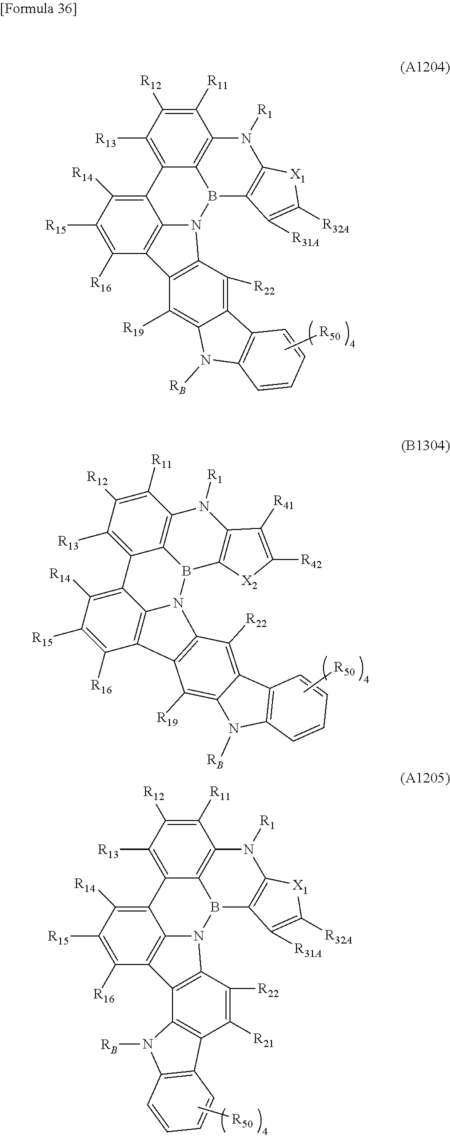

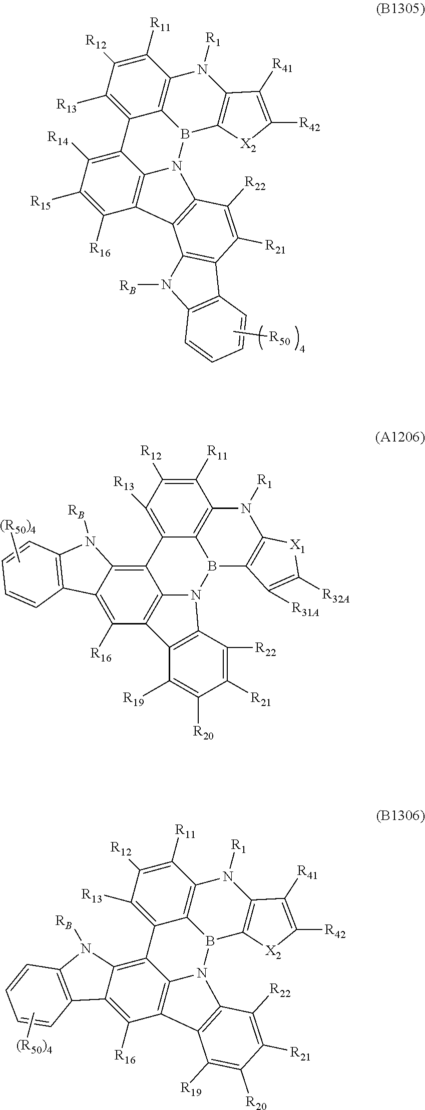

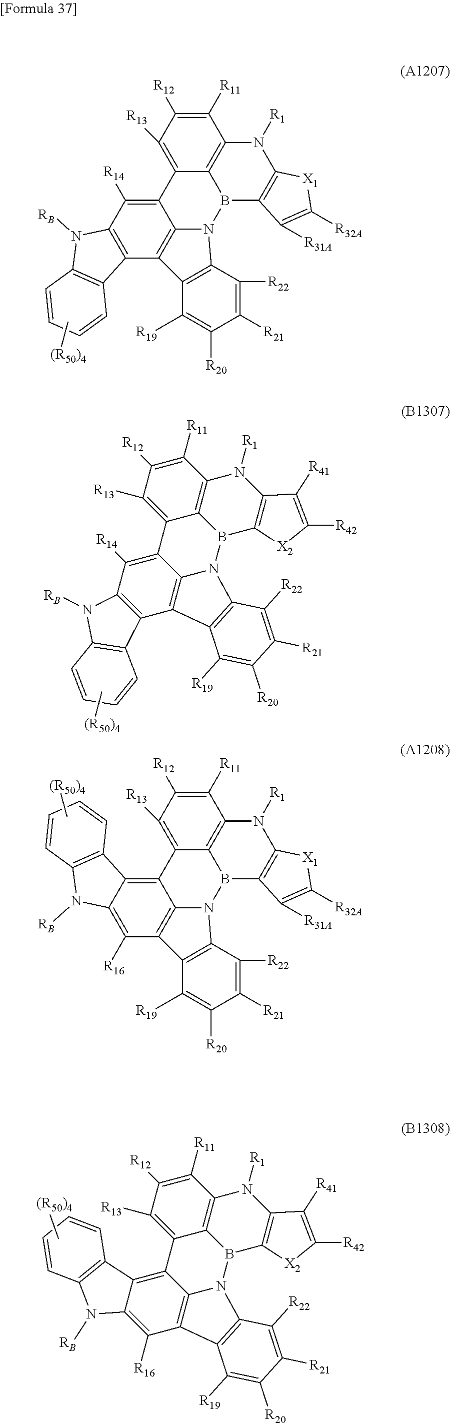

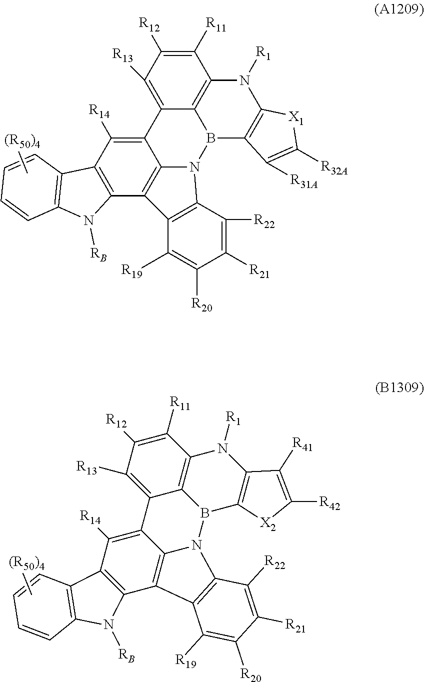

In the formulae (A1201) to (A1209) and (B1301) to (B1309):
R₁, R₁₁ to R₁₆, R₁₉ to R₂₂, R_{31A} to R_{32A}, R₄₁ to R₄₂, X₁, and X₂ each independently represent the same as R₁, R₁₁ to R₁₆, R₁₉ to R₂₂, R_{31A} to R_{32A}, R₄₁ to R₄₂, X₁, and X₂ in the formulae (1201) and (1301);
at least one combination of adjacent two or more of R₅₀ and R_{B} are mutually bonded to form a substituted or unsubstituted monocyclic ring, mutually bonded to form a substituted or unsubstituted fused ring, or not mutually bonded;
a plurality of R₅₀ are mutually the same or different;
R_{B} forming neither the substituted or unsubstituted monocyclic ring nor the substituted or unsubstituted fused ring is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₅₀ forming neither the substituted or unsubstituted monocyclic ring nor the substituted or unsubstituted fused ring each independently represent the same as R₄₀ forming neither the substituted or unsubstituted monocyclic ring nor the substituted or unsubstituted fused ring in the formulae (121) and (131).

In the compound according to the exemplary embodiment, R₁ is preferably a substituted or unsubstituted aryl group having 6 to 50 ring carbon atoms, or a substituted or unsubstituted heterocyclic group having 5 to 50 ring atoms.

In the compound according to the exemplary embodiment: R₁₁ to R₂₂, R_{31A} to R_{32A}, R₄₀, R₄₁ to R₄₂, and R₅₀ are preferably each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{1A})(R_{2A}).

In the compound according to the exemplary embodiment, it is preferable that one of R₁₄ to R₂₂ is a group represented by —N(R_{1A})(R_{2A}), and R_{1A} and R_{2A} are each independently a substituted or unsubstituted aryl group having 6 to 50 ring carbon atoms, or a substituted or unsubstituted heterocyclic group having 5 to 50 ring atoms.

In the compound according to the exemplary embodiment, it is more preferable that one of R₁₄ to R₂₂ is a group represented by —N(R_{1A})(R_{2A}), and R_{1A} and R_{2A} are each independently a substituted or unsubstituted aryl group having 6 to 50 ring carbon atoms.

In the compound according to the exemplary embodiment, it is also preferable that one of R₁₄ to R₂₂ is a group represented by —N(R_{1A})(R_{2A}), and a combination of R_{1A} and R_{2A} are mutually bonded to form a substituted or unsubstituted monocyclic ring, or mutually bonded to form a substituted or unsubstituted fused ring.

In the compound according to the exemplary embodiment, it is preferable that X₁ and X₂ are each independently an oxygen atom or C(Rx₁)(Rx₂); and Rx₁ and Rx₂ are each independently a substituted or unsubstituted alkyl group having 1 to 50 carbon atoms, or a substituted or unsubstituted aryl group having 6 to 50 ring carbon atoms.

In the compound according to the exemplary embodiment, the compound represented by the formula (1) is preferably represented by a formula (14) or (15) below.

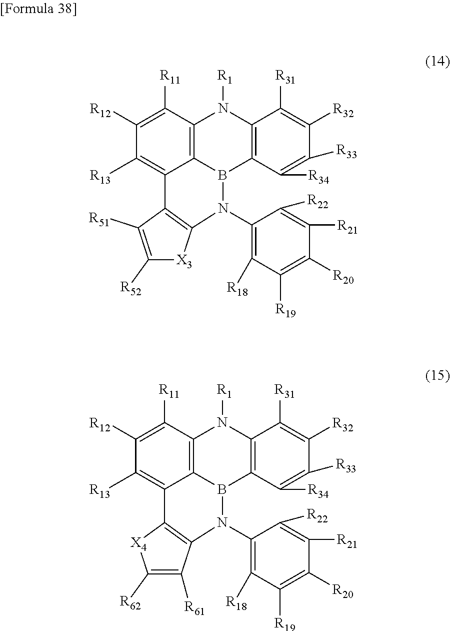

In the formulae (14) and (15):
R₁ represents the same as R₁ in the formula (1);
X₃ and X₄ are each independently an oxygen atom, a sulfur atom, NRx, or C(Rx₁)(Rx₂);
at least one combination of adjacent two or more of R₁, R₁₁ to R₁₃, and R₃₁ to R₃₄ are mutually bonded to form a substituted or unsubstituted monocyclic ring, mutually bonded to form a substituted or unsubstituted fused ring, or not mutually bonded;
at least one combination of adjacent two or more of R₁₈ to R₂₂, R₅₁ to R₅₂, Rx, Rx₁, and Rx₂ are mutually bonded to form a substituted or unsubstituted monocyclic ring, mutually bonded to form a substituted or unsubstituted fused ring, or not mutually bonded;
at least one combination of adjacent two or more of R₁₈ to R₂₂, R₆₁ to R₆₂, Rx, Rx₁, and Rx₂ are mutually bonded to form a substituted or unsubstituted monocyclic ring, mutually bonded to form a substituted or unsubstituted fused ring, or not mutually bonded;
R₁₁ to R₁₃, R₁₈ to R₂₂, R₃₁ to R₃₄, R₅₁ to R₅₂, and R₆₁ to R₆₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆); and
Rx, Rx₁, and Rx₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound according to the exemplary embodiment, the compound represented by the formula (1) is preferably represented by a formula (141) or (151) below.

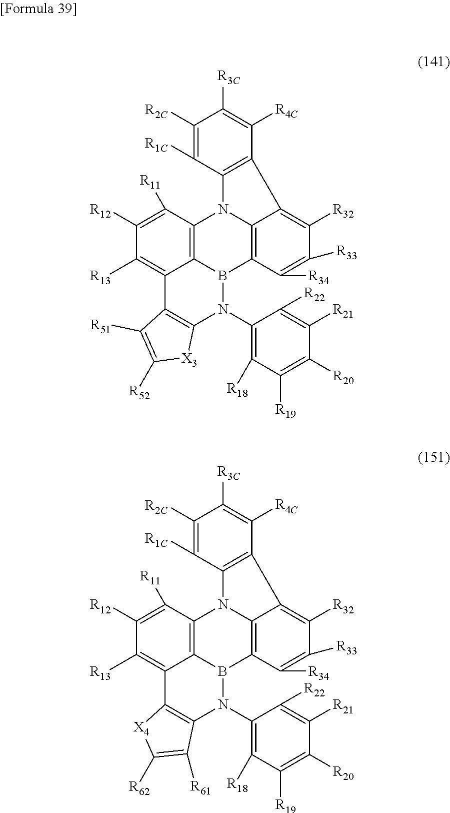

In the formulae (141) and (151):
R₁₁ to R₁₃, R₁₈ to R₂₂, R₃₂ to R₃₄, R₅₁ to R₅₂, R₆₁ to R₆₂, X₃, and X₄ each independently represent the same as R₁₁ to R₁₃, R₁₈ to R₂₂, R₃₂ to R₃₄, R₅₁ to R₅₂, R₆₁ to R₆₂, X₃, and X₄ in the formulae (14) and (15);
at least one combination of adjacent two or more of R_{1C} to R_{4C} are mutually bonded to form a substituted or unsubstituted monocyclic ring, mutually bonded to form a substituted or unsubstituted fused ring, or not mutually bonded; and
R_{1C} to R_{4C} forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (14) and (15).

In the compound according to the exemplary embodiment, it is preferable that the compound represented by the formula (141) is represented by one of formulae (C141) to (C150) below and the compound represented by the formula (151) is represented by one of formulae (D151) to (D160) below.

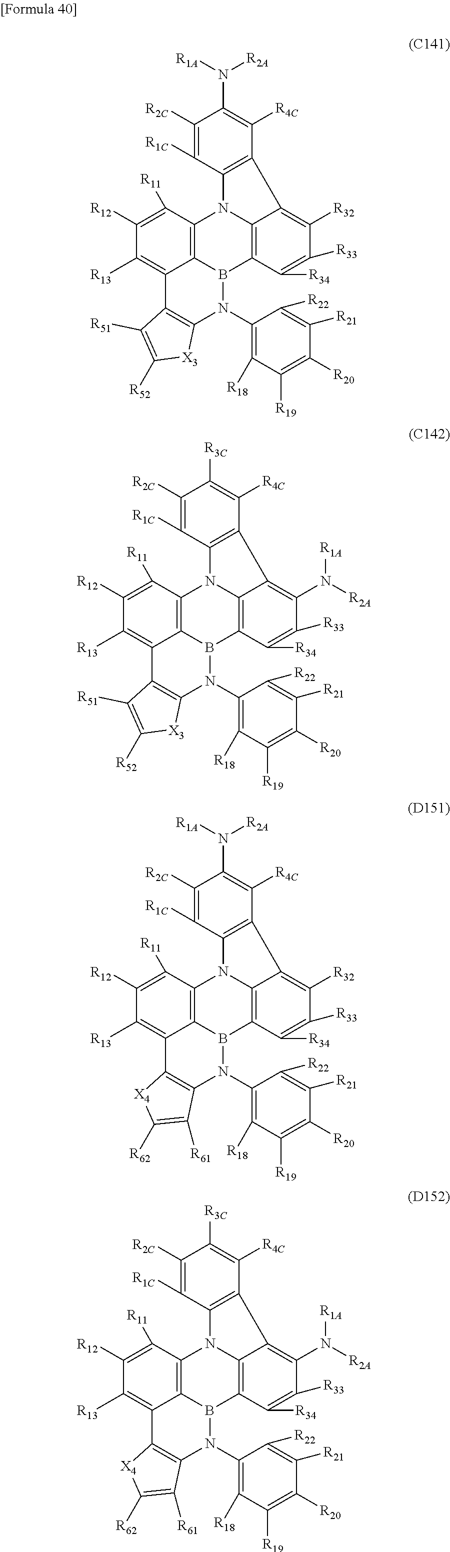

In the formulae (C141), (C142), (D151), and (D152):
X₃, X₄, R₁₁ to R₁₃, R₁₈ to R₂₂, R₃₂ to R₃₄, R₅₁ to R₅₂, R₆₁ to R₆₂, and R_{1C} to R_{4C} each independently represent the same as X₃, X₄, R₁₁ to R₁₃, R₁₈ to R₂₂, R₃₂ to R₃₄, R₅₁ to R₅₂, R₆₁ to R₆₂, and R_{1C} to R_{4C} in the formulae (141) and (151); and R_{1A} and R_{2A} each independently represent the same as R_{1A} and R_{2A} forming neither the substituted or unsubstituted monocyclic ring nor the substituted or unsubstituted fused ring in the formula (1).

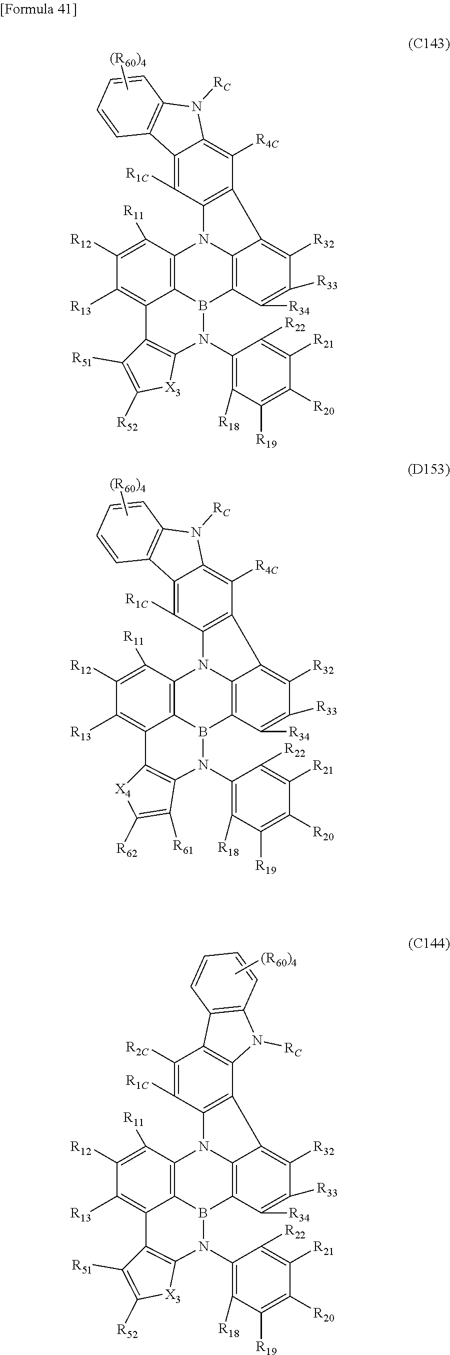

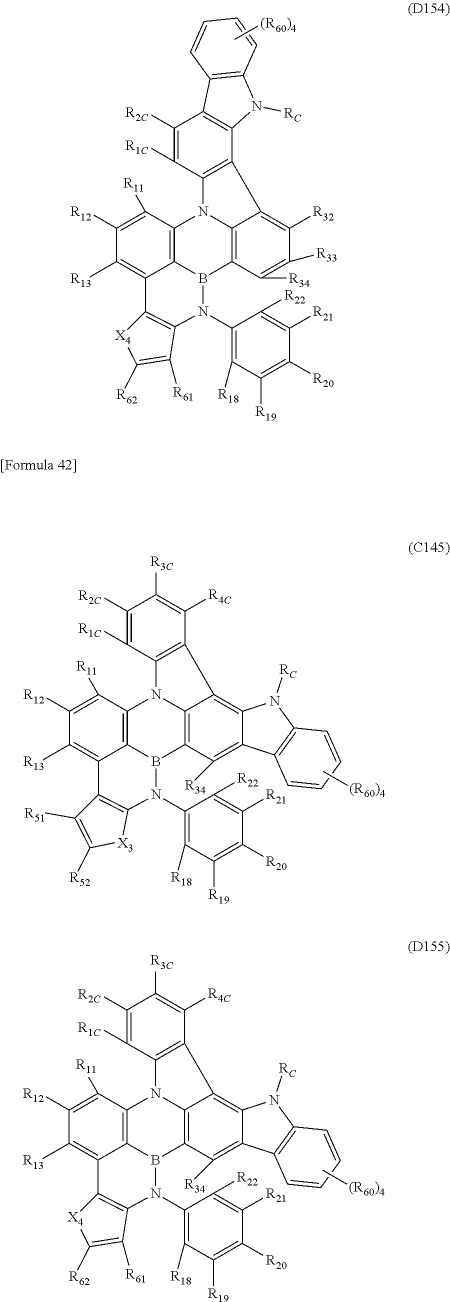

In the formulae (C143) to (C145) and (D153) to (D155):
X₃, X₄, R₁₁ to R₁₃, R₁₈ to R₂₂, R₃₂ to R₃₄, R₅₁ to R₅₂, R₆₁ to R₆₂, and R_{1C} to R_{4C} each independently represent the same as X₃, X₄, R₁₁ to R₁₃, R₁₈ to R₂₂, R₃₂ to R₃₄, R₅₁ to R₅₂, R₆₁ to R₆₂, and R_{1C} to R_{4C} in the formulae (141) and (151);
at least one combination of adjacent two or more of R₆₀ are mutually bonded to form a substituted or unsubstituted monocyclic ring, mutually bonded to form a substituted or unsubstituted fused ring, or not mutually bonded;
a plurality of R₆₀ are mutually the same or different;
R_{C} is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₆₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (141) and (151).

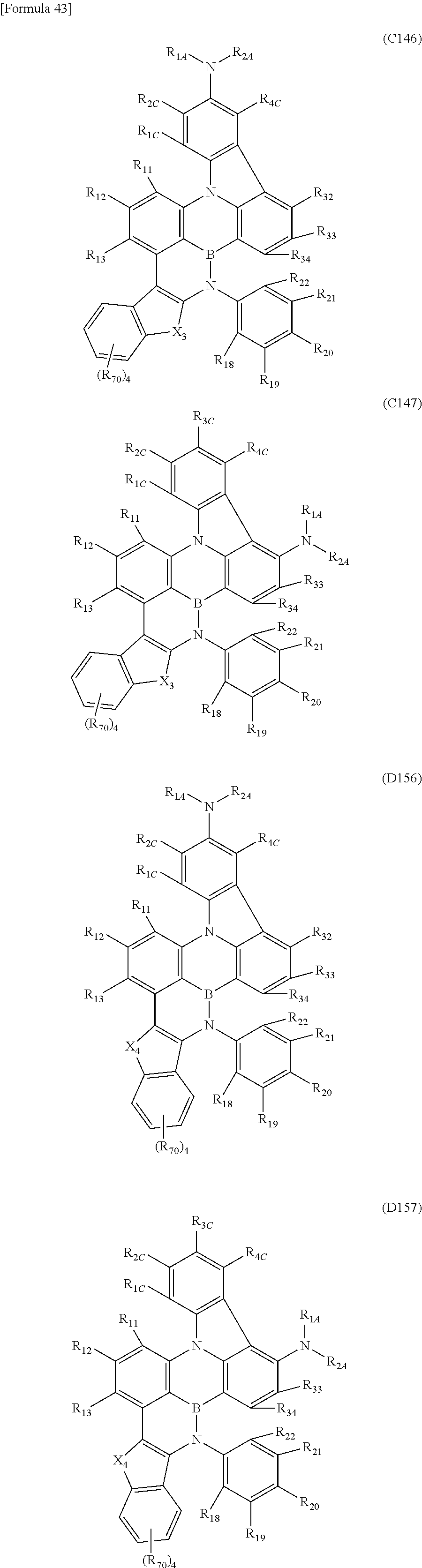

In the formulae (C146), (C147), (D156), and (D157):
X₃, X₄, R₁₁ to R₁₃, R₁₈ to R₂₂, R₃₂ to R₃₄, and R_{1C} to R_{4C} each independently represent the same as X₃, X₄, R₁₁ to R₁₃, R₁₈ to R₂₂, R₃₂ to R₃₄, and R_{1C} to R_{4C} in the formulae (141) and (151);
R_{1A} and R_{2A} each independently represent the same as R_{1A} and R_{2A} forming neither the substituted or unsubstituted monocyclic ring nor the substituted or unsubstituted fused ring in the formula (1);
at least one combination of adjacent two or more of R₇₀ are mutually bonded to form a substituted or unsubstituted monocyclic ring, mutually bonded to form a substituted or unsubstituted fused ring, or not mutually bonded;
a plurality of R₇₀ are mutually the same or different; and
R₇₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (141) and (151).

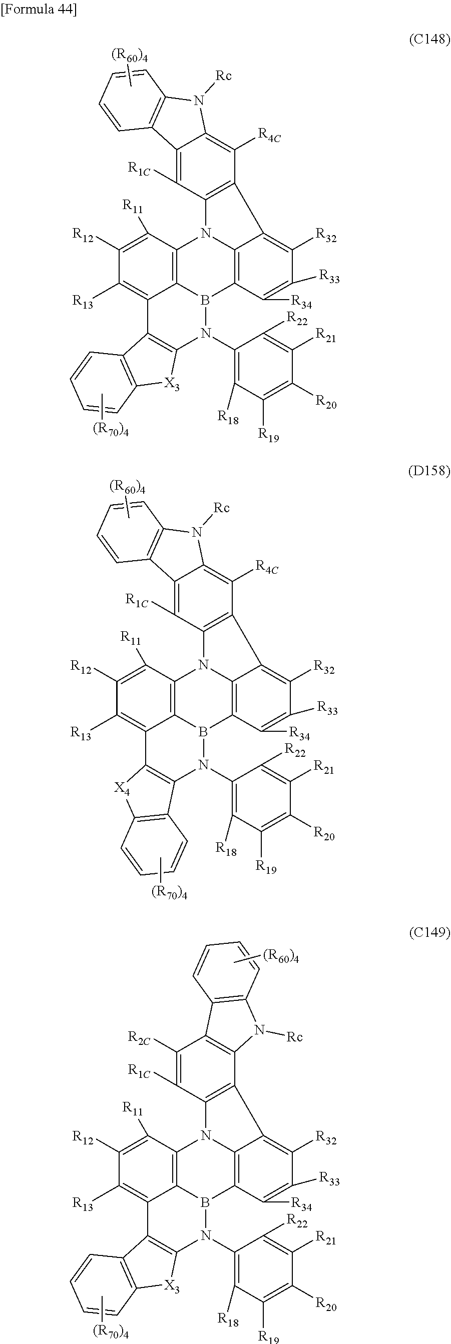

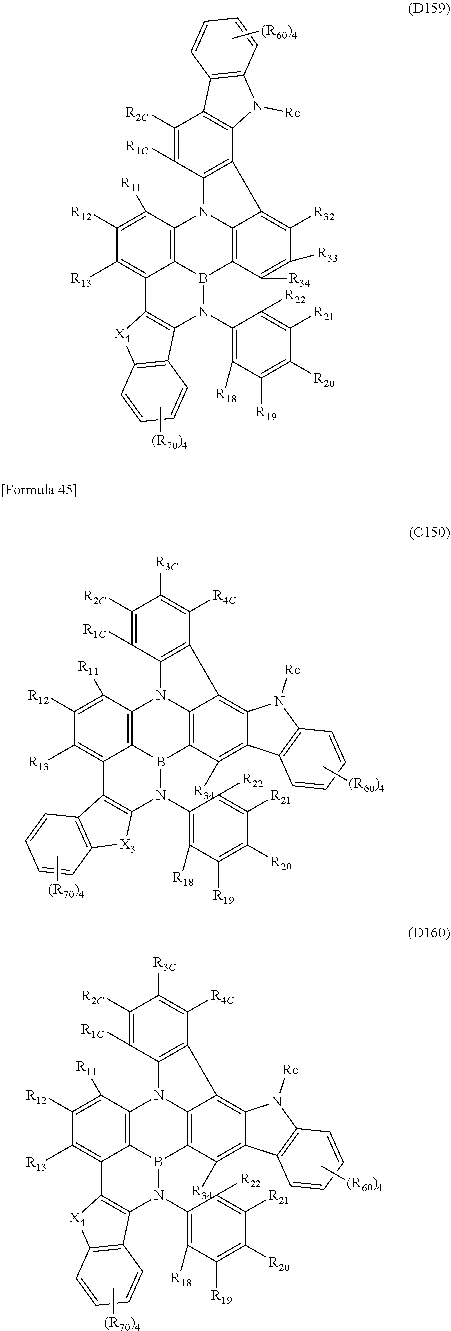

In the formulae (C148) to (C150) and (D158) to (D160):
X₃, X₄, R₁₁ to R₁₃, R₁₈ to R₂₂, R₃₂ to R₃₄, and R_{1C} to R_{4C} each independently represent the same as X₃, X₄, R₁₁ to R₁₃, R₁₈ to R₂₂, R₃₂ to R₃₄, and R_{1C} to R_{4C} in the formulae (141) and (151);
at least one combination of adjacent two or more of R₆₀ are mutually bonded to form a substituted or unsubstituted monocyclic ring, mutually bonded to form a substituted or unsubstituted fused ring, or not mutually bonded;
a plurality of R₆₀ are mutually the same or different;
at least one combination of adjacent two or more of R₇₀ are mutually bonded to form a substituted or unsubstituted monocyclic ring, mutually bonded to form a substituted or unsubstituted fused ring, or not mutually bonded;
a plurality of R₇₀ are mutually the same or different;
R_{C} is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₆₀ and R₇₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (141) and (151).

In the compound according to the exemplary embodiment: R₁₁ to R₁₃, R₁₈ to R₂₂, R₃₁ to R₃₄, R₅₁ to R₅₂, R₆₁ to R₆₂, and R_{1C} to R_{4C} are preferably each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{1A})(R_{2A}).

In the compound according to the exemplary embodiment, R₆₀ and R₇₀ are preferably each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{1A})(R_{2A}).

In the compound according to the exemplary embodiment, it is preferable that X₃ and X₄ are each independently an oxygen atom or C(Rx₁)(Rx₂); and Rx₁ and Rx₂ are each independently a substituted or unsubstituted alkyl group having 1 to 50 carbon atoms, or a substituted or unsubstituted aryl group having 6 to 50 ring carbon atoms.

In the formulae (14) and (15): R₁ is also preferably a substituted or unsubstituted aryl group having 6 to 50 ring carbon atoms, or a substituted or unsubstituted heterocyclic group having 5 to 50 ring atoms.

In the formulae (14) and (15), it is also preferable that R₁ is a substituted or unsubstituted aryl group having 6 to 18 ring carbon atoms (preferably a substituted or unsubstituted phenyl group), and the R₁ is bonded with the ring A₁ to form a substituted or unsubstituted monocyclic ring, or bonded with the ring A₁ to form a substituted or unsubstituted fused ring.

In the formulae (14) and (15), it is also preferable that R₁ is a substituted or unsubstituted aryl group having 6 to 18 ring carbon atoms (preferably a substituted or unsubstituted phenyl group), and the R₁ is bonded with the ring B₁ to form a substituted or unsubstituted monocyclic ring, or bonded with the ring B₁ to form a substituted or unsubstituted fused ring.

In the compound according to the exemplary embodiment, the substituent for “the substituted or unsubstituted” group is preferably a halogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compound according to the exemplary embodiment, the substituent for “the substituted or unsubstituted” group is preferably an unsubstituted alkyl group having 1 to 10 carbon atoms, an unsubstituted aryl group having 6 to 12 ring carbon atoms, or an unsubstituted heterocyclic group having 5 to 12 ring atoms.

In the compound according to the exemplary embodiment, all groups specified as “substituted or unsubstituted” groups are preferably “unsubstituted” groups.

### Producing Method of Compound in the Exemplary Embodiment

The compound according to the exemplary embodiment can be produced by application of known substitution reactions and materials depending on a target compound, according to a synthesis method described in Examples described later or in a similar manner as the synthesis method.

### Specific Examples of Compound in the Exemplary Embodiment

Specific examples of the compound in the exemplary embodiment include compounds below. However, the invention is by no means limited to the specific examples. Herein, a deuterium atom is denoted as D in formulae, and a protium atom is denoted as H or omitted.

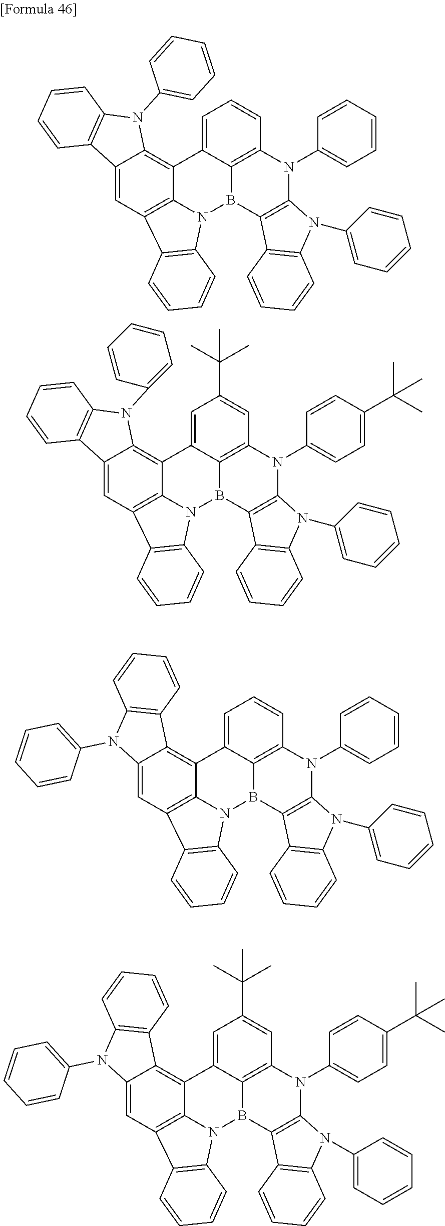

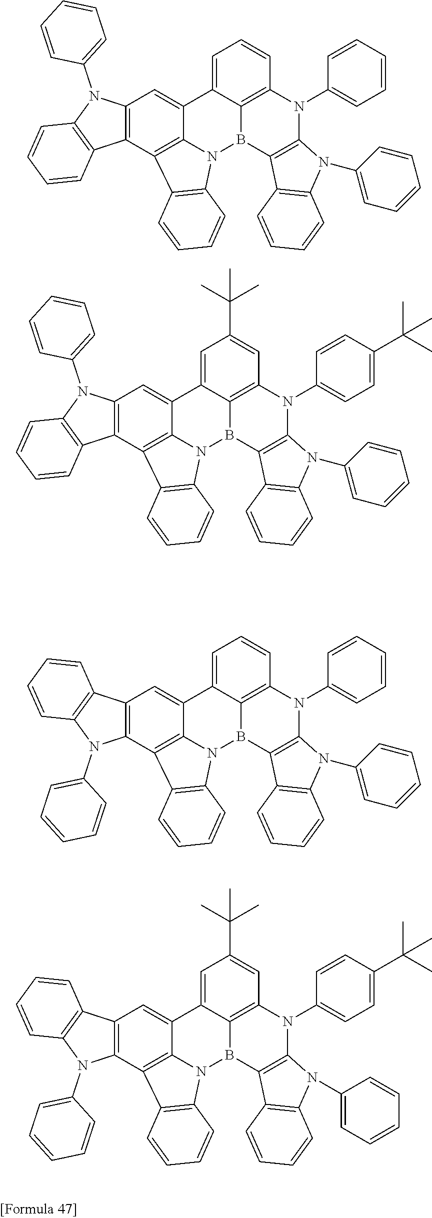

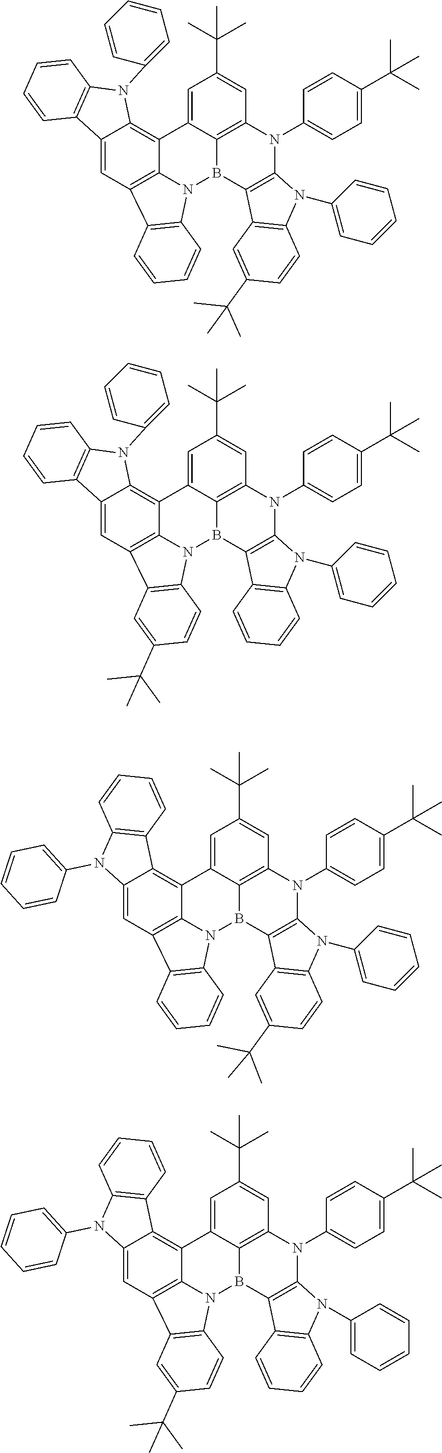

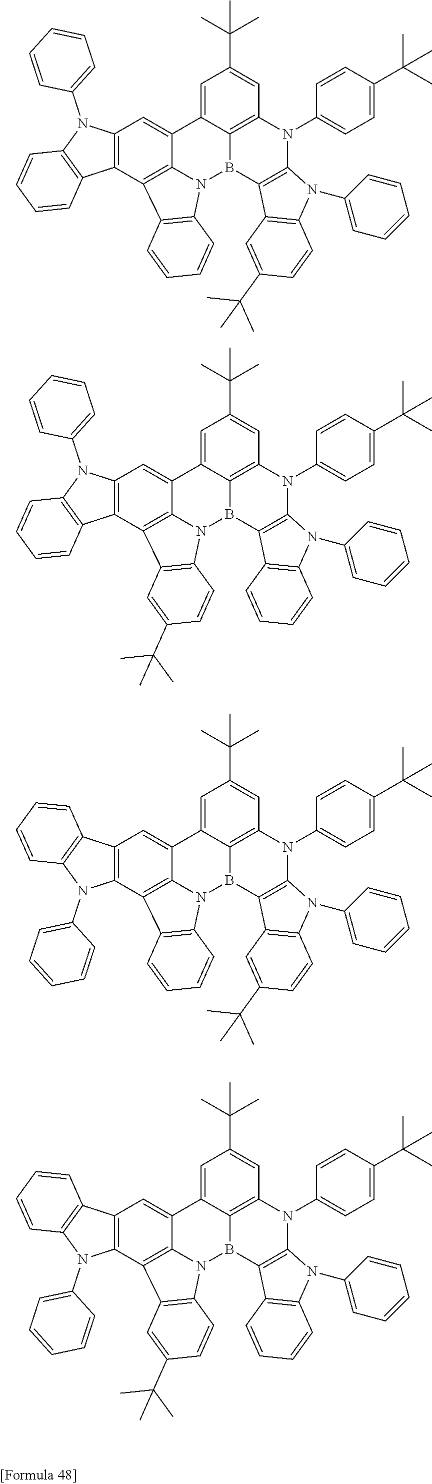

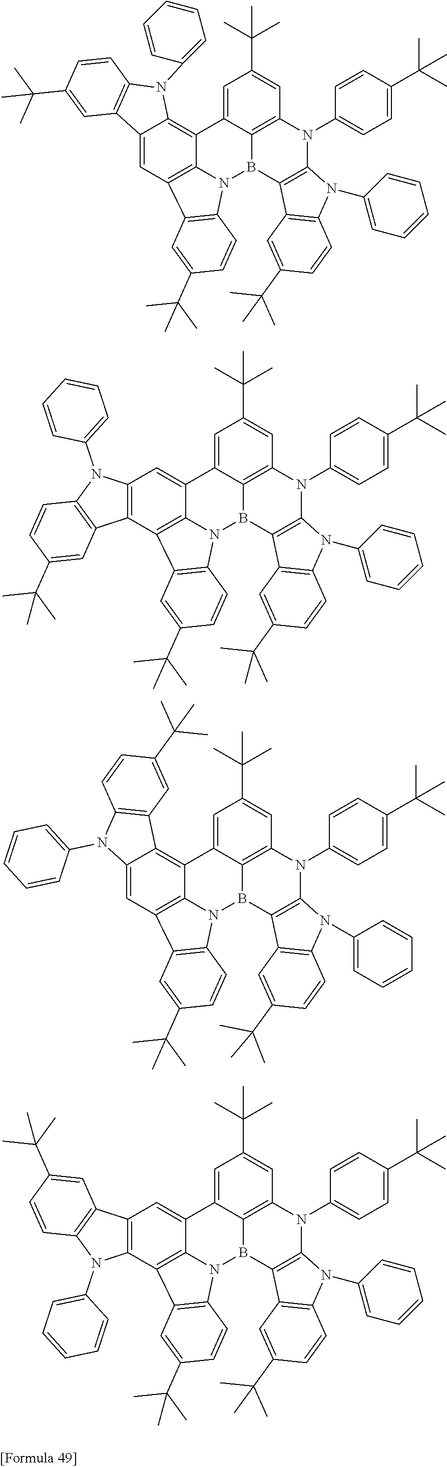

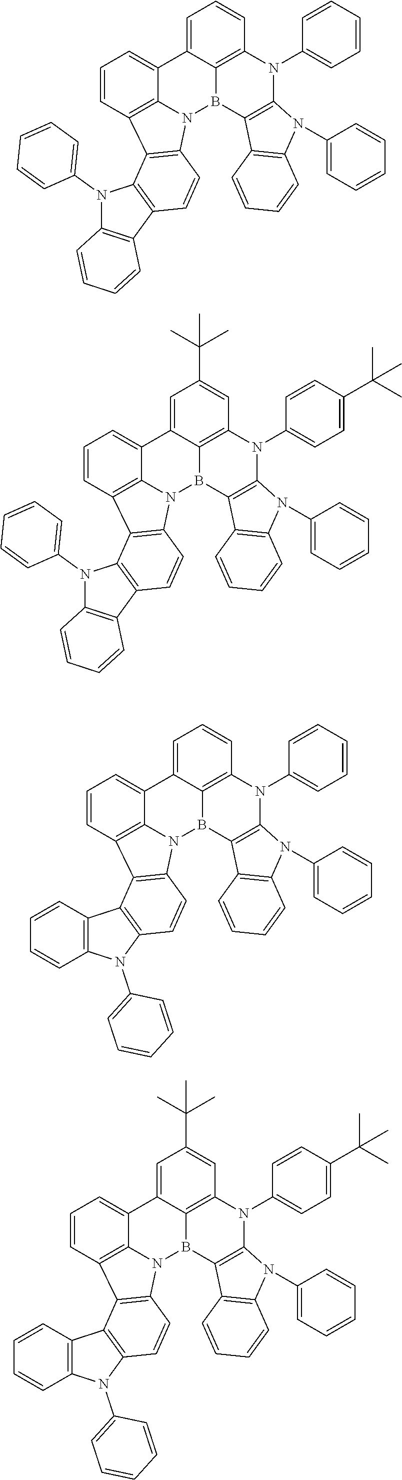

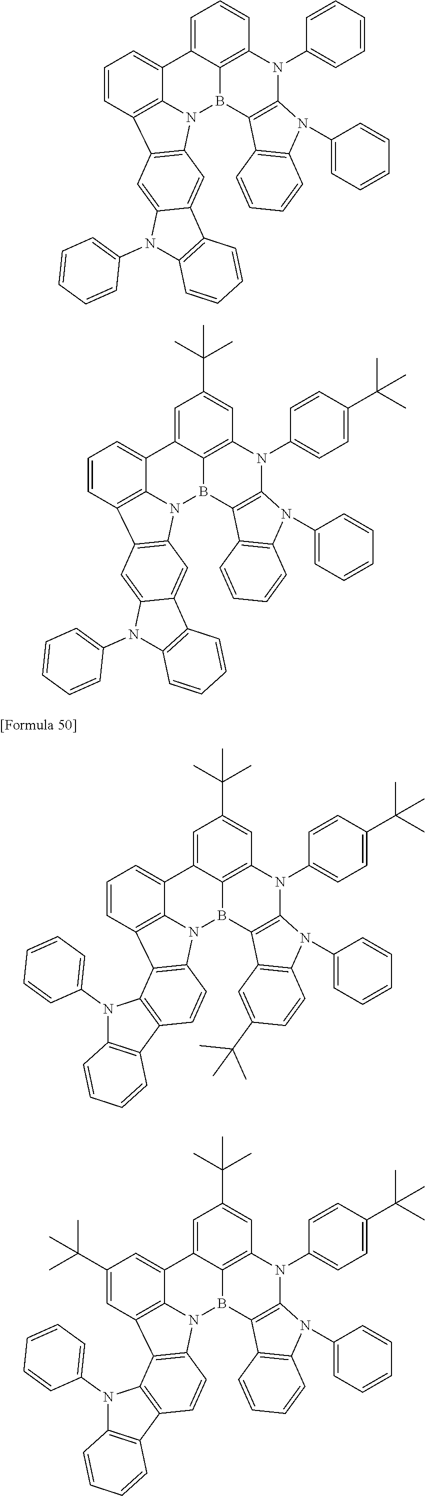

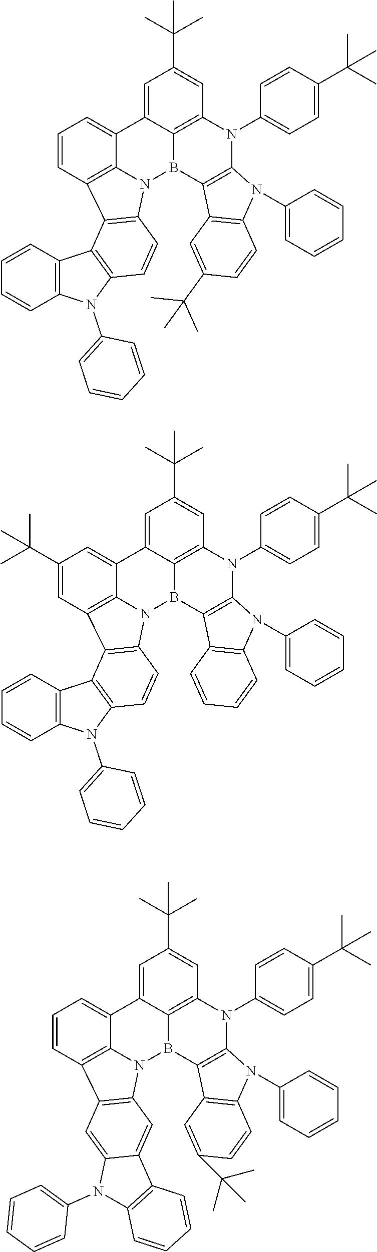

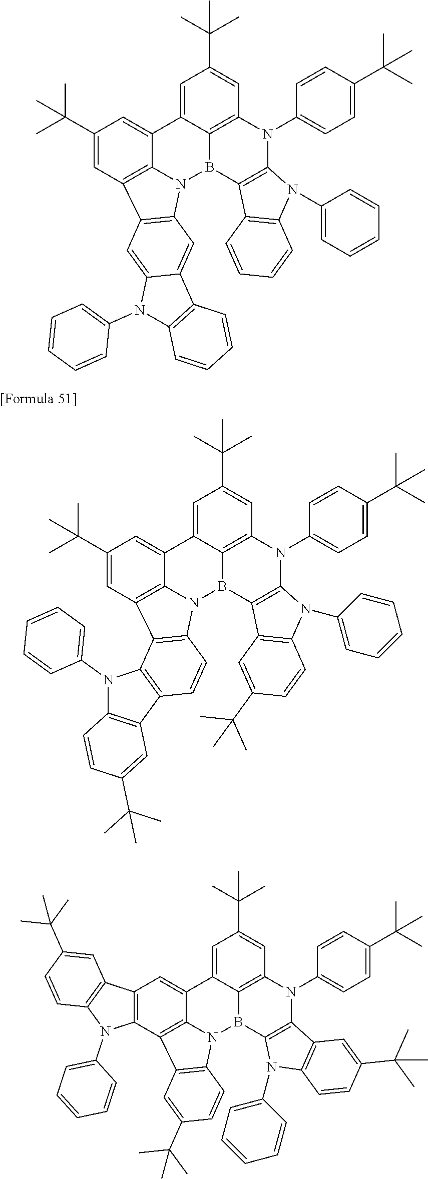

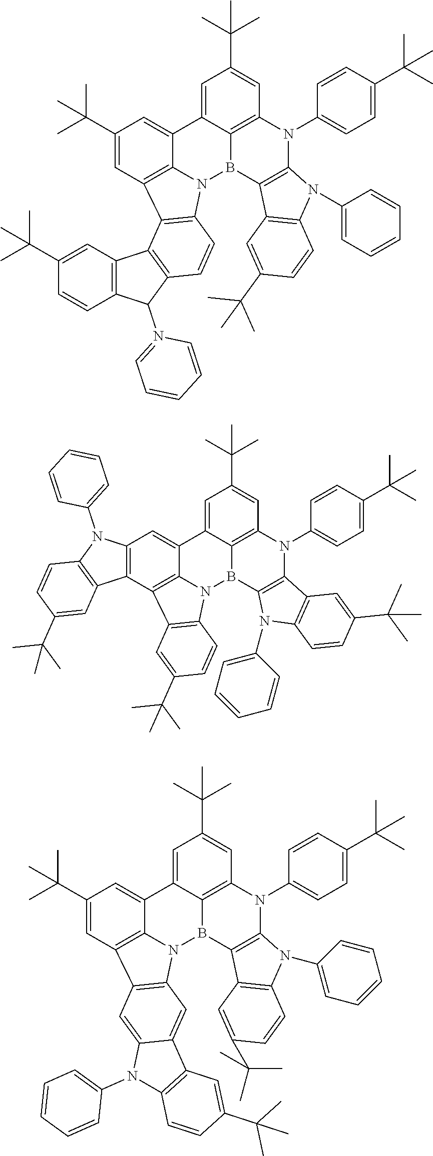

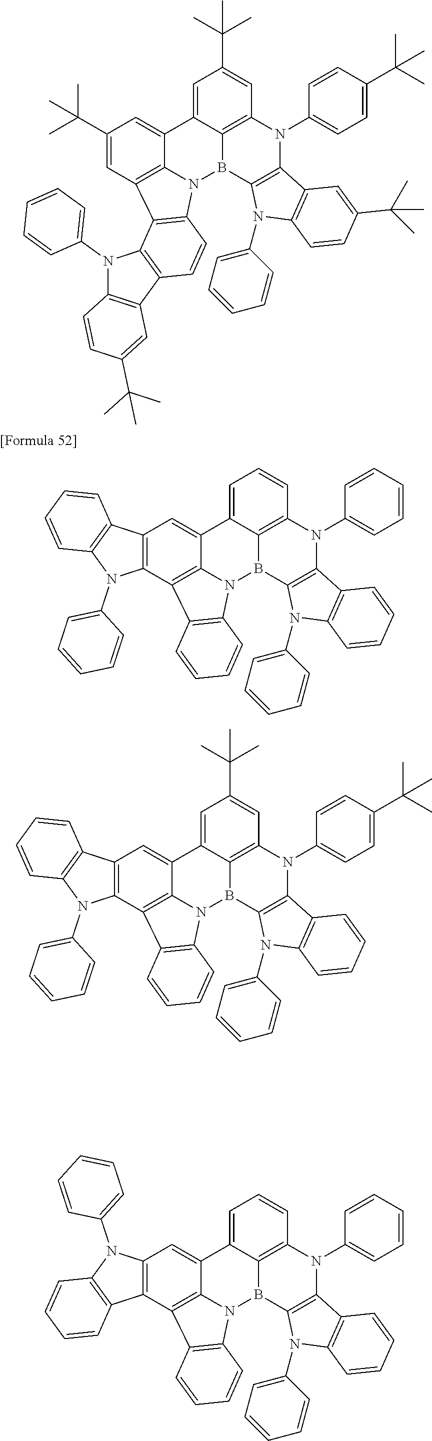

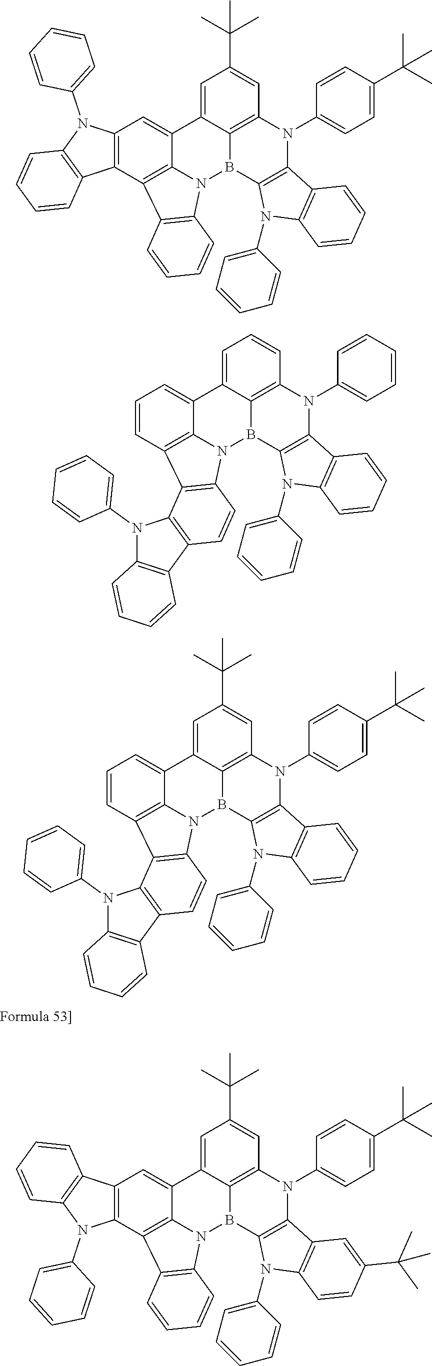

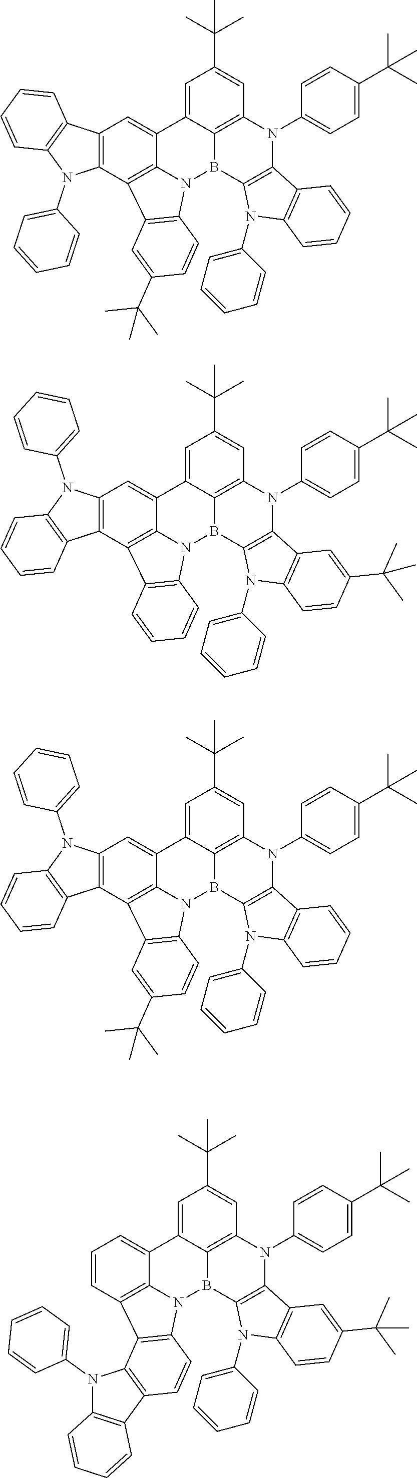

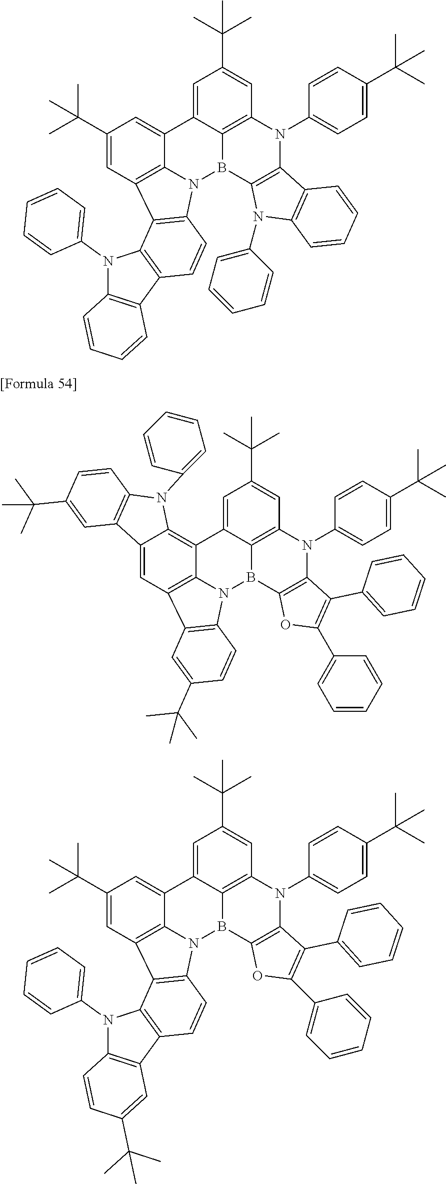

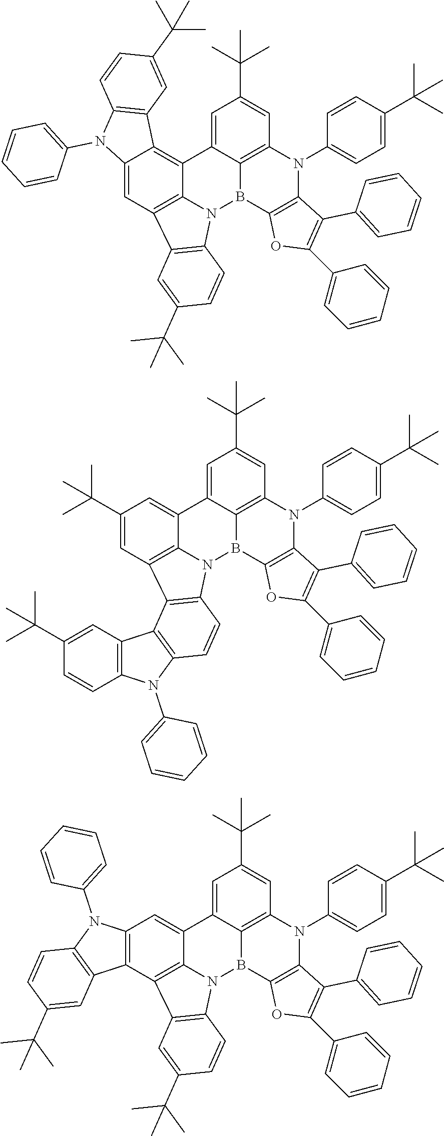

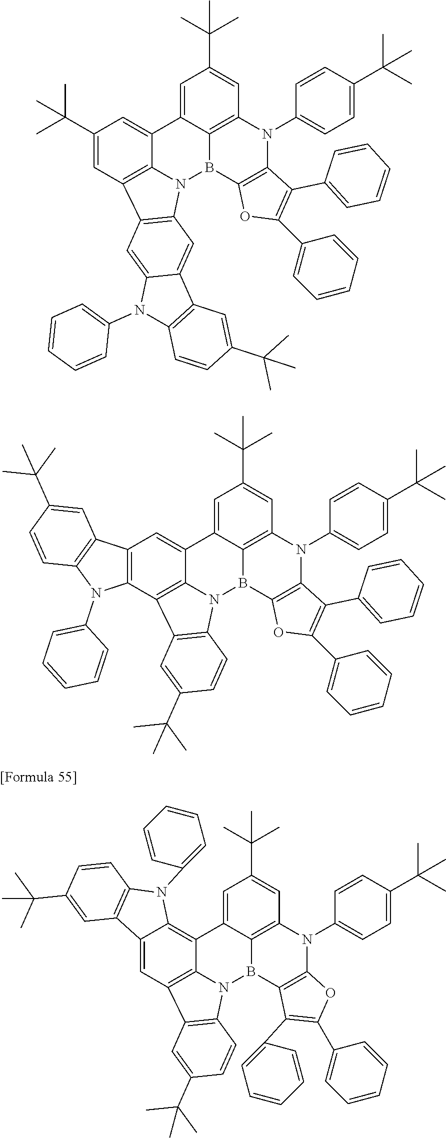

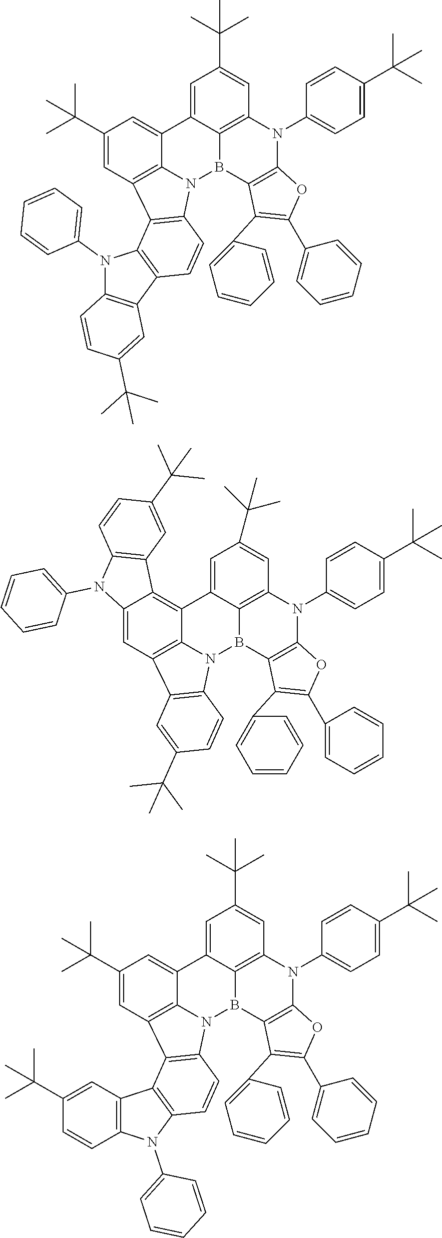

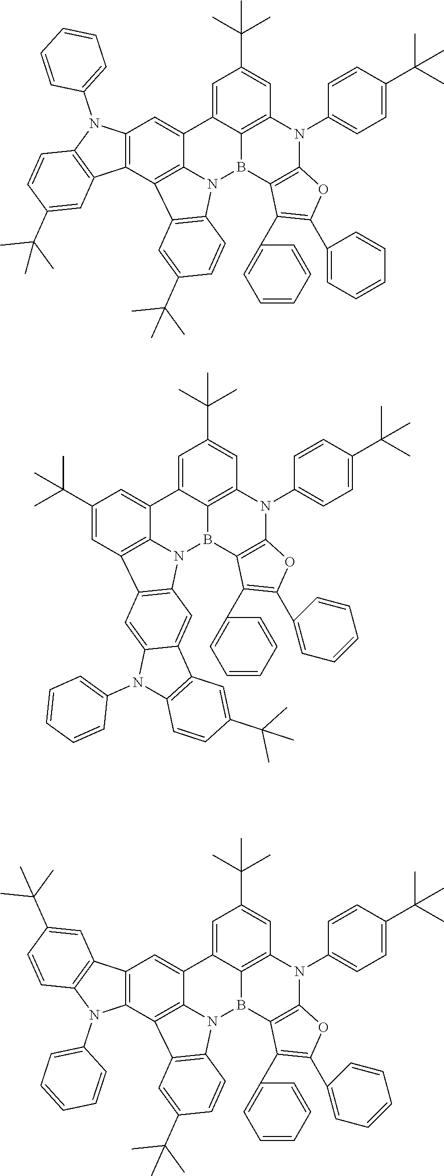

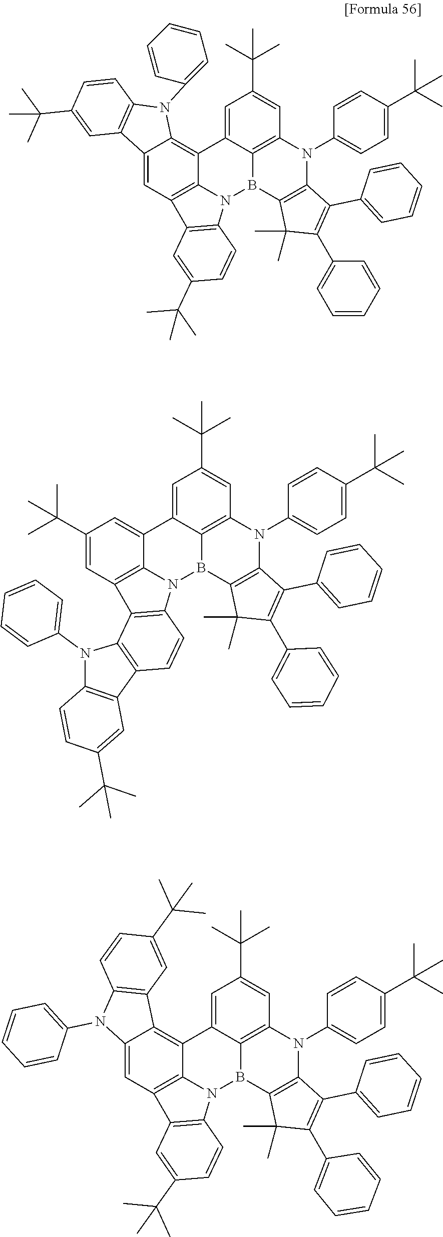 [SMILES: CC1(C)C2=C(C(c3ccccc3)=C1c1ccccc1)N(c1ccc(C(C)(C)C)cc1)c1cc(C(C)(C)C)cc3c1B2n1c2ccc(C(C)(C)C)cc2c2cc4c5cc(C(C)(C)C)ccc5n(-c5ccccc5)c4c-3c21 ; CC1(C)C2=C(C(c3ccccc3)=C1c1ccccc1)N(c1ccc(C(C)(C)C)cc1)c1cc(C(C)(C)C)cc3c1B2n1c2ccc4c5cc(C(C)(C)C)ccc5n(-c5ccccc5)c4c2c2cc(C(C)(C)C)cc-3c21 ; CC1(C)C2=C(C(c3ccccc3)=C1c1ccccc1)N(c1ccc(C(C)(C)C)cc1)c1cc(C(C)(C)C)cc3c1B2n1c2ccc(C(C)(C)C)cc2c2cc4c(c-3c21)c1cc(C(C)(C)C)ccc1n4-c1ccccc1]

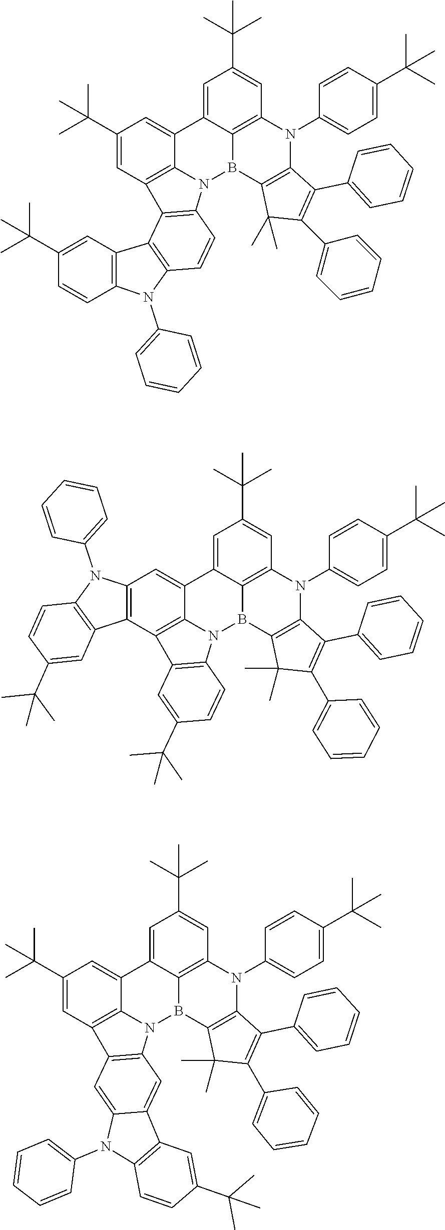

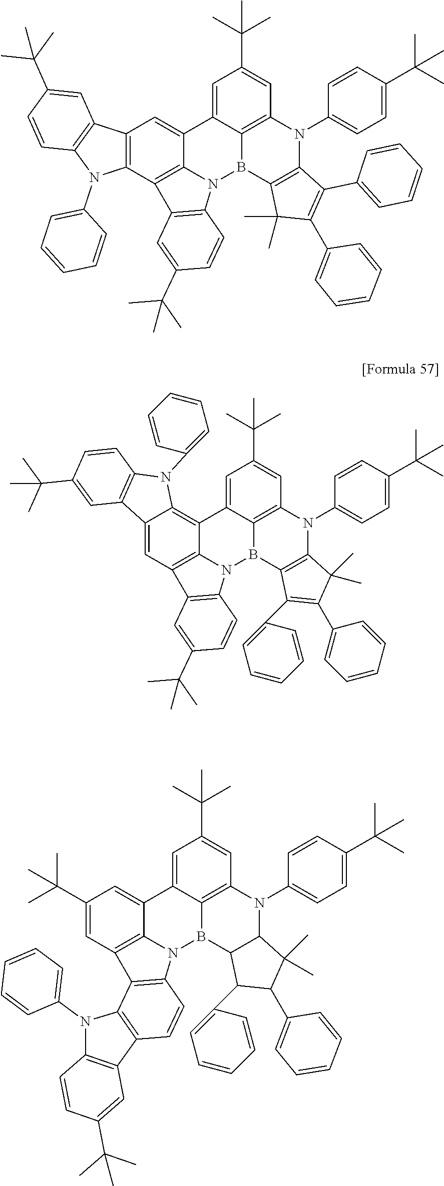

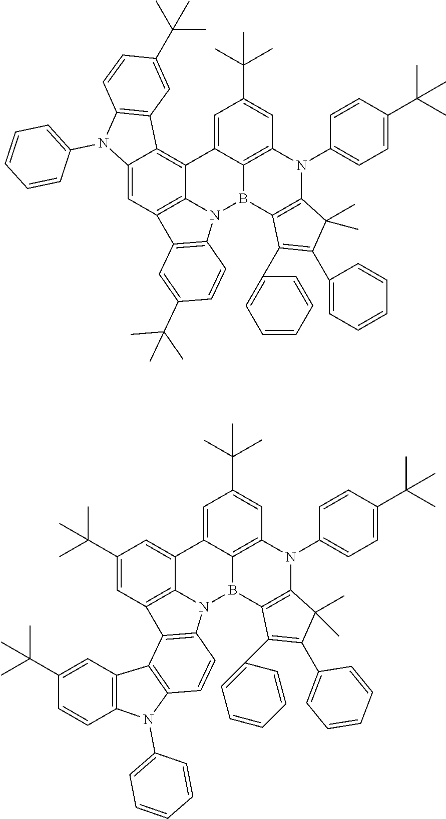

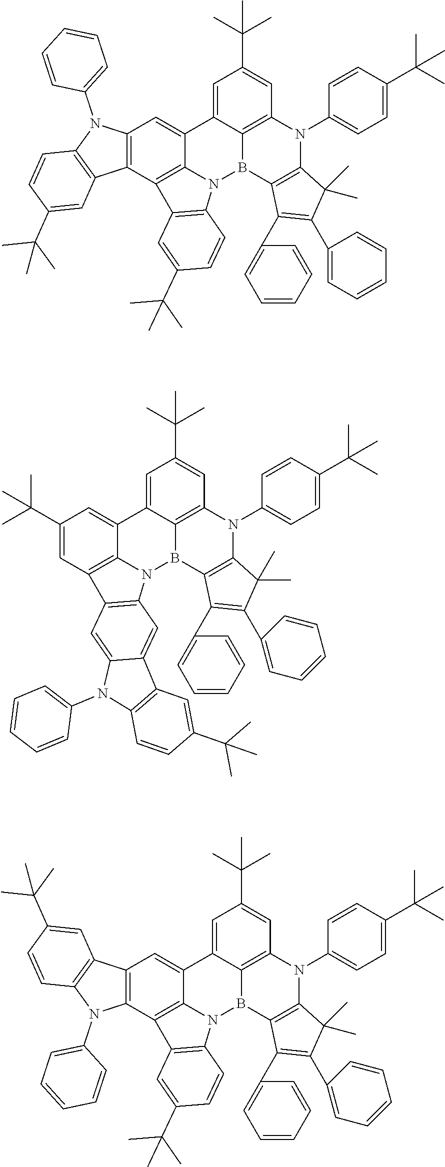

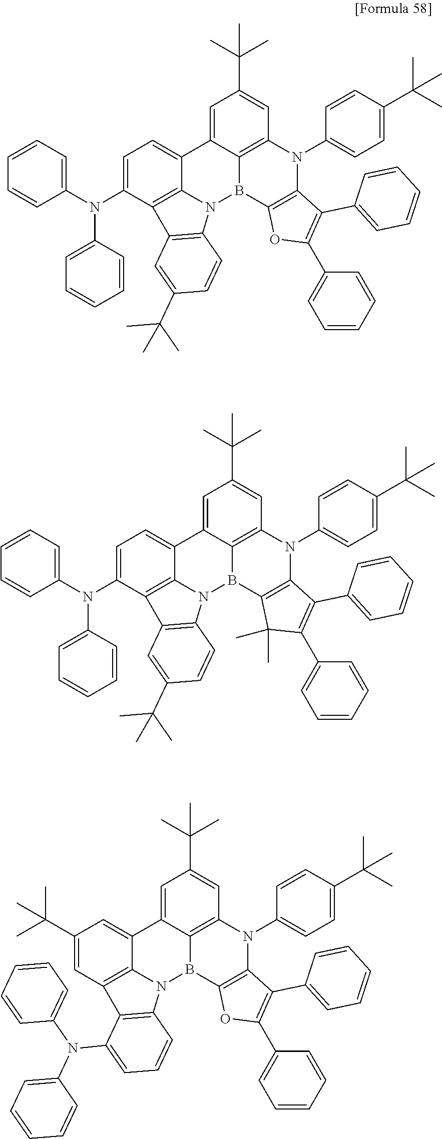 [SMILES: CC(C)(C)c1ccc(N2c3cc(C(C)(C)C)cc4c3B(c3oc(-c5ccccc5)c(-c5ccccc5)c32)n2c3ccc(C(C)(C)C)cc3c3c(N(c5ccccc5)c5ccccc5)ccc-4c32)cc1 ; CC1(C)C2=C(C(c3ccccc3)=C1c1ccccc1)N(c1ccc(C(C)(C)C)cc1)c1cc(C(C)(C)C)cc3c1B2n1c2ccc(C(C)(C)C)cc2c2c(N(c4ccccc4)c4ccccc4)ccc-3c21 ; CC(C)(C)c1ccc(N2c3cc(C(C)(C)C)cc4c3B(c3oc(-c5ccccc5)c(-c5ccccc5)c32)n2c3cccc(N(c5ccccc5)c5ccccc5)c3c3cc(C(C)(C)C)cc-4c32)cc1]

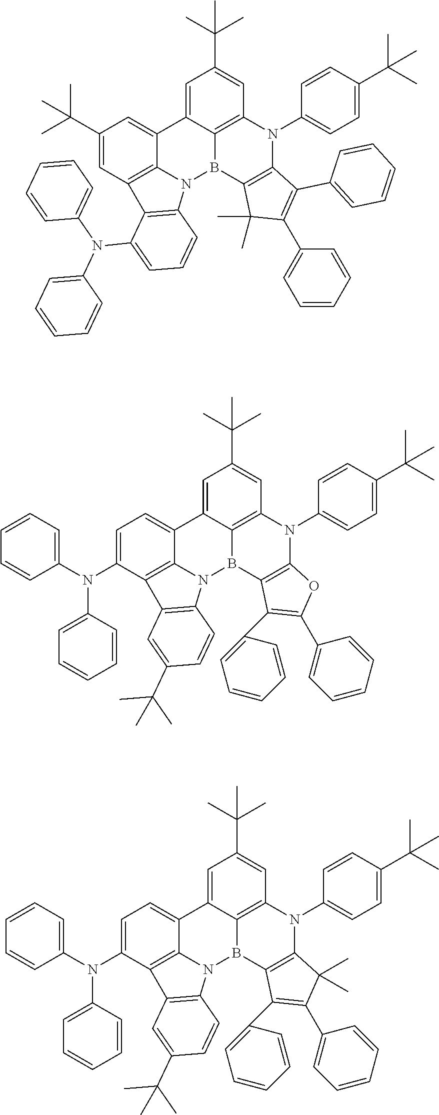 [SMILES: CC1(C)C2=C(C(c3ccccc3)=C1c1ccccc1)N(c1ccc(C(C)(C)C)cc1)c1cc(C(C)(C)C)cc3c1B2n1c2cccc(N(c4ccccc4)c4ccccc4)c2c2cc(C(C)(C)C)cc-3c21 ; CC(C)(C)c1ccc(N2c3cc(C(C)(C)C)cc4c3B(c3c2oc(-c2ccccc2)c3-c2ccccc2)n2c3ccc(C(C)(C)C)cc3c3c(N(c5ccccc5)c5ccccc5)ccc-4c32)cc1 ; CC1(C)C(c2ccccc2)=C(c2ccccc2)C2=C1N(c1ccc(C(C)(C)C)cc1)c1cc(C(C)(C)C)cc3c1B2n1c2ccc(C(C)(C)C)cc2c2c(N(c4ccccc4)c4ccccc4)ccc-3c21]

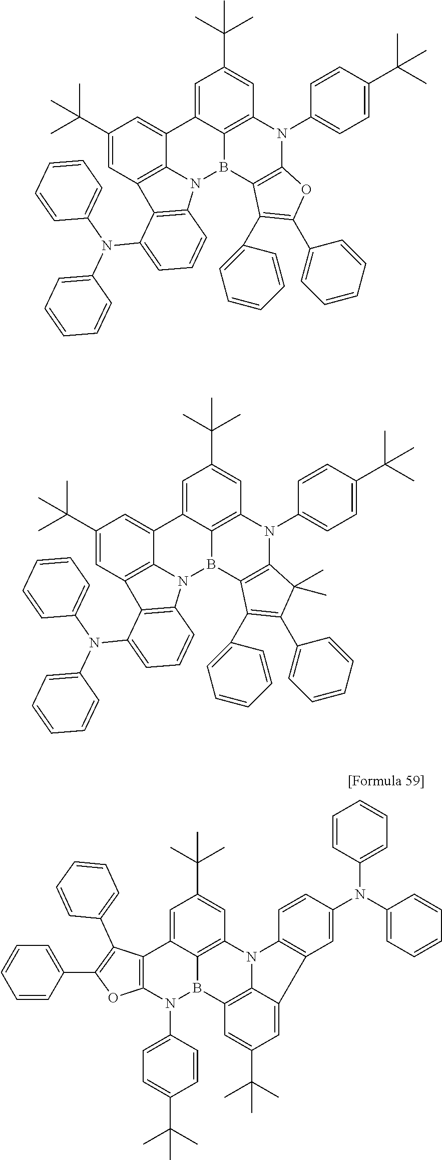 [SMILES: CC(C)(C)c1ccc(N2c3cc(C(C)(C)C)cc4c3B(c3c2oc(-c2ccccc2)c3-c2ccccc2)n2c3cccc(N(c5ccccc5)c5ccccc5)c3c3cc(C(C)(C)C)cc-4c32)cc1 ; CC1(C)C(c2ccccc2)=C(c2ccccc2)C2=C1N(c1ccc(C(C)(C)C)cc1)c1cc(C(C)(C)C)cc3c1B2n1c2cccc(N(c4ccccc4)c4ccccc4)c2c2cc(C(C)(C)C)cc-3c21 ; CC(C)(C)c1ccc(N2B3c4c(cc(C(C)(C)C)cc4-n4c5ccc(N(c6ccccc6)c6ccccc6)cc5c5cc(C(C)(C)C)cc3c54)-c3c2oc(-c2ccccc2)c3-c2ccccc2)cc1]

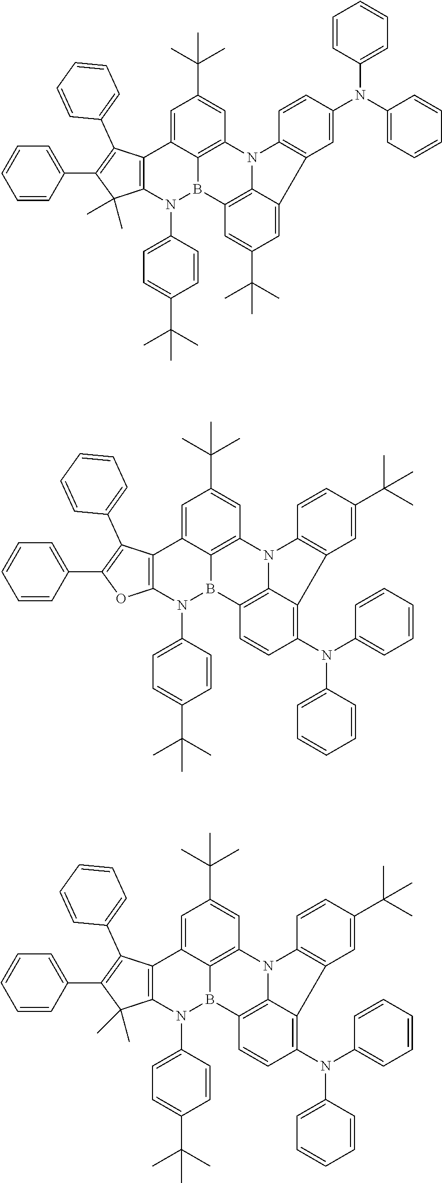 [SMILES: CC1(C)C(c2ccccc2)=C(c2ccccc2)C2=C1N(c1ccc(C(C)(C)C)cc1)B1c3c2cc(C(C)(C)C)cc3-n2c3ccc(N(c4ccccc4)c4ccccc4)cc3c3cc(C(C)(C)C)cc1c32 ; CC(C)(C)c1ccc(N2B3c4c(cc(C(C)(C)C)cc4-n4c5ccc(C(C)(C)C)cc5c5c(N(c6ccccc6)c6ccccc6)ccc3c54)-c3c2oc(-c2ccccc2)c3-c2ccccc2)cc1 ; CC1(C)C(c2ccccc2)=C(c2ccccc2)C2=C1N(c1ccc(C(C)(C)C)cc1)B1c3c2cc(C(C)(C)C)cc3-n2c3ccc(C(C)(C)C)cc3c3c(N(c4ccccc4)c4ccccc4)ccc1c32]

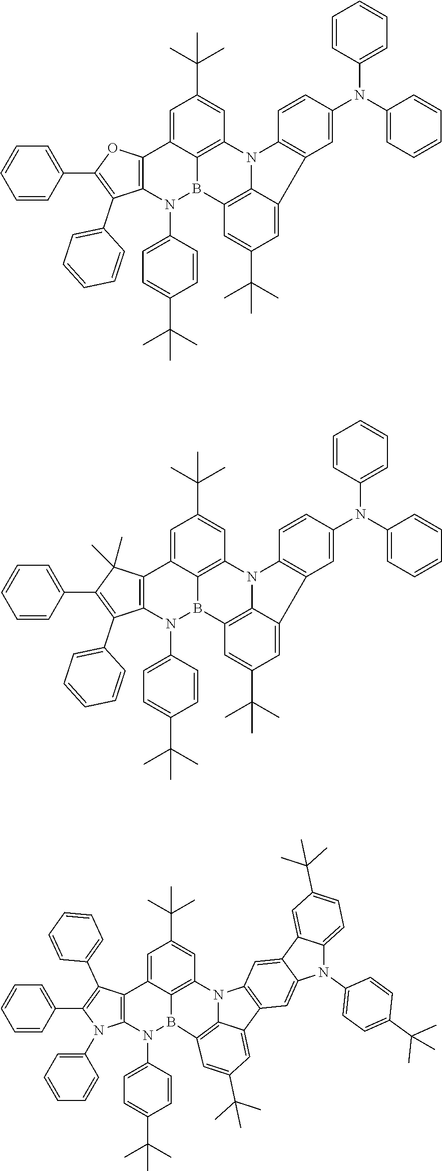 [SMILES: CC(C)(C)c1ccc(N2B3c4c(cc(C(C)(C)C)cc4-n4c5ccc(N(c6ccccc6)c6ccccc6)cc5c5cc(C(C)(C)C)cc3c54)-c3oc(-c4ccccc4)c(-c4ccccc4)c32)cc1 ; CC1(C)C(c2ccccc2)=C(c2ccccc2)C2=C1c1cc(C(C)(C)C)cc3c1B(c1cc(C(C)(C)C)cc4c5cc(N(c6ccccc6)c6ccccc6)ccc5n-3c14)N2c1ccc(C(C)(C)C)cc1 ; CC(C)(C)c1ccc(N2B3c4c(cc(C(C)(C)C)cc4-n4c5cc6c7cc(C(C)(C)C)ccc7n(-c7ccc(C(C)(C)C)cc7)c6cc5c5cc(C(C)(C)C)cc3c54)-c3c(-c4ccccc4)c(-c4ccccc4)n(-c4ccccc4)c32)cc1]

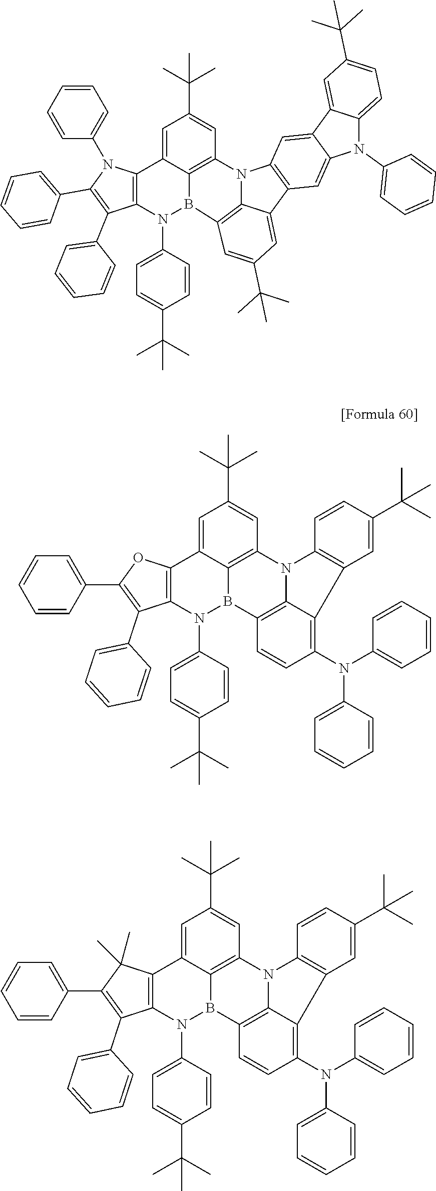 [SMILES: CC(C)(C)c1ccc(N2B3c4c(cc(C(C)(C)C)cc4-n4c5cc6c7cc(C(C)(C)C)ccc7n(-c7ccccc7)c6cc5c5cc(C(C)(C)C)cc3c54)-c3c2c(-c2ccccc2)c(-c2ccccc2)n3-c2ccccc2)cc1 ; CC(C)(C)c1ccc(N2B3c4c(cc(C(C)(C)C)cc4-n4c5ccc(C(C)(C)C)cc5c5c(N(c6ccccc6)c6ccccc6)ccc3c54)-c3oc(-c4ccccc4)c(-c4ccccc4)c32)cc1 ; CC1(C)C(c2ccccc2)=C(c2ccccc2)C2=C1c1cc(C(C)(C)C)cc3c1B(c1ccc(N(c4ccccc4)c4ccccc4)c4c5cc(C(C)(C)C)ccc5n-3c14)N2c1ccc(C(C)(C)C)cc1]

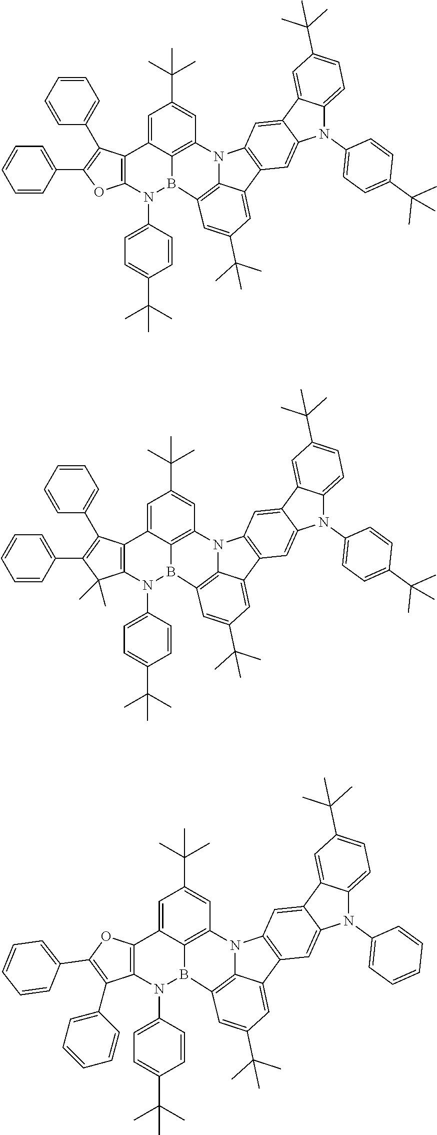 [SMILES: CC(C)(C)c1ccc(N2B3c4c(cc(C(C)(C)C)cc4-n4c5cc6c7cc(C(C)(C)C)ccc7n(-c7ccc(C(C)(C)C)cc7)c6cc5c5cc(C(C)(C)C)cc3c54)-c3c2oc(-c2ccccc2)c3-c2ccccc2)cc1 ; CC1(C)C(c2ccccc2)=C(c2ccccc2)C2=C1N(c1ccc(C(C)(C)C)cc1)B1c3c2cc(C(C)(C)C)cc3-n2c3cc4c5cc(C(C)(C)C)ccc5n(-c5ccc(C(C)(C)C)cc5)c4cc3c3cc(C(C)(C)C)cc1c32 ; CC(C)(C)c1ccc(N2B3c4c(cc(C(C)(C)C)cc4-n4c5cc6c7cc(C(C)(C)C)ccc7n(-c7ccccc7)c6cc5c5cc(C(C)(C)C)cc3c54)-c3oc(-c4ccccc4)c(-c4ccccc4)c32)cc1]

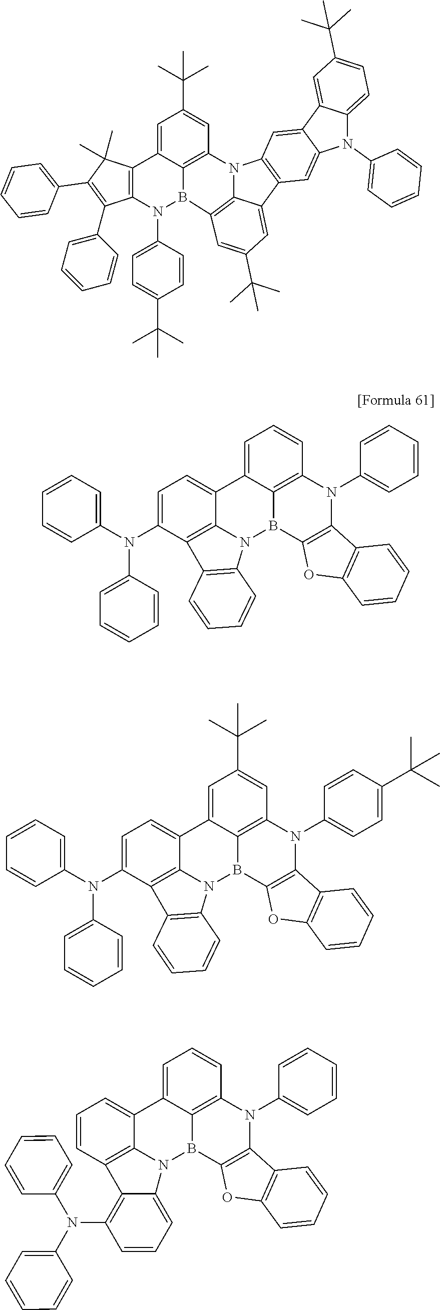 [SMILES: CC1(C)C(c2ccccc2)=C(c2ccccc2)C2=C1c1cc(C(C)(C)C)cc3c1B(c1cc(C(C)(C)C)cc4c5cc6c(cc5n-3c14)c1cc(C(C)(C)C)ccc1n6-c1ccccc1)N2c1ccc(C(C)(C)C)cc1 ; c1ccc(N2c3cccc4c3B(c3oc5ccccc5c32)n2c3ccccc3c3c(N(c5ccccc5)c5ccccc5)ccc-4c32)cc1 ; CC(C)(C)c1ccc(N2c3cc(C(C)(C)C)cc4c3B(c3oc5ccccc5c32)n2c3ccccc3c3c(N(c5ccccc5)c5ccccc5)ccc-4c32)cc1 ; c1ccc(N2c3cccc4c3B(c3oc5ccccc5c32)n2c3cccc(N(c5ccccc5)c5ccccc5)c3c3cccc-4c32)cc1]

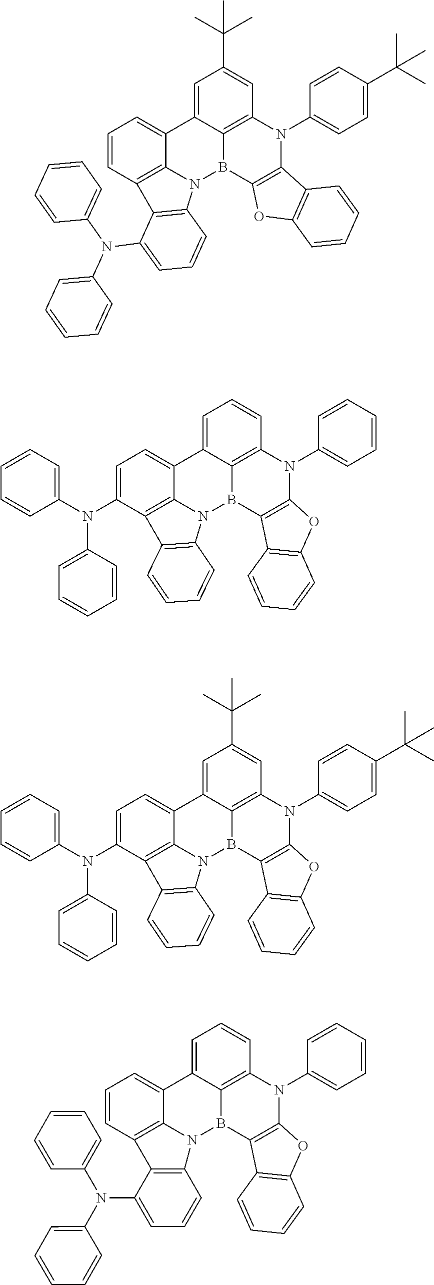 [SMILES: CC(C)(C)c1ccc(N2c3cc(C(C)(C)C)cc4c3B(c3oc5ccccc5c32)n2c3cccc(N(c5ccccc5)c5ccccc5)c3c3cccc-4c32)cc1 ; c1ccc(N2c3cccc4c3B(c3c2oc2ccccc32)n2c3ccccc3c3c(N(c5ccccc5)c5ccccc5)ccc-4c32)cc1 ; CC(C)(C)c1ccc(N2c3cc(C(C)(C)C)cc4c3B(c3c2oc2ccccc32)n2c3ccccc3c3c(N(c5ccccc5)c5ccccc5)ccc-4c32)cc1 ; c1ccc(N2c3cccc4c3B(c3c2oc2ccccc32)n2c3cccc(N(c5ccccc5)c5ccccc5)c3c3cccc-4c32)cc1]

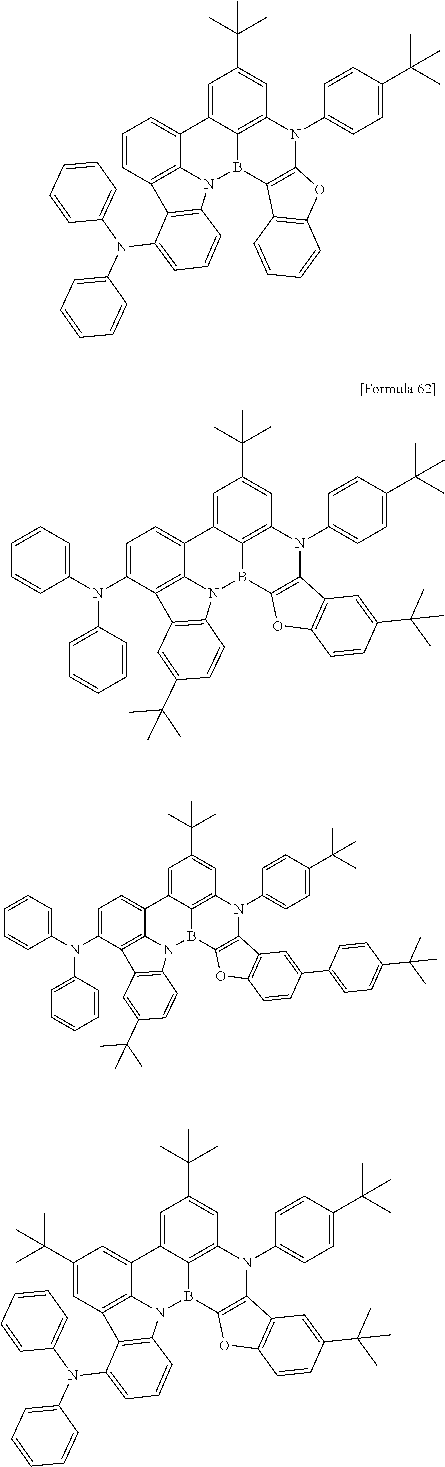 [SMILES: CC(C)(C)c1ccc(N2c3cc(C(C)(C)C)cc4c3B(c3c2oc2ccccc32)n2c3cccc(N(c5ccccc5)c5ccccc5)c3c3cccc-4c32)cc1 ; CC(C)(C)c1ccc(N2c3cc(C(C)(C)C)cc4c3B(c3oc5ccc(C(C)(C)C)cc5c32)n2c3ccc(C(C)(C)C)cc3c3c(N(c5ccccc5)c5ccccc5)ccc-4c32)cc1 ; CC(C)(C)c1ccc(-c2ccc3oc4c(c3c2)N(c2ccc(C(C)(C)C)cc2)c2cc(C(C)(C)C)cc3c2B4n2c4ccc(C(C)(C)C)cc4c4c(N(c5ccccc5)c5ccccc5)ccc-3c42)cc1 ; CC(C)(C)c1ccc(N2c3cc(C(C)(C)C)cc4c3B(c3oc5ccc(C(C)(C)C)cc5c32)n2c3cccc(N(c5ccccc5)c5ccccc5)c3c3cc(C(C)(C)C)cc-4c32)cc1]

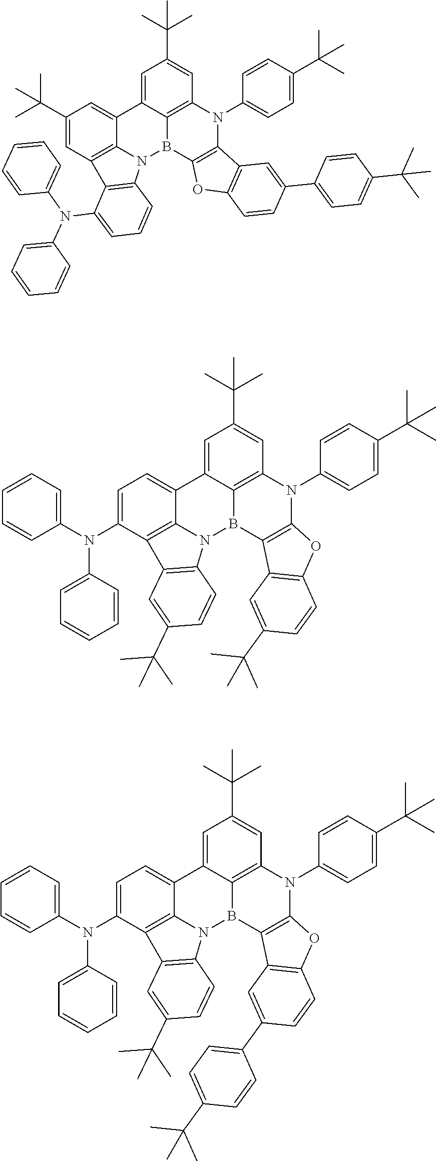 [SMILES: CC(C)(C)c1ccc(-c2ccc3oc4c(c3c2)N(c2ccc(C(C)(C)C)cc2)c2cc(C(C)(C)C)cc3c2B4n2c4cccc(N(c5ccccc5)c5ccccc5)c4c4cc(C(C)(C)C)cc-3c42)cc1 ; CC(C)(C)c1ccc(N2c3cc(C(C)(C)C)cc4c3B(c3c2oc2ccc(C(C)(C)C)cc32)n2c3ccc(C(C)(C)C)cc3c3c(N(c5ccccc5)c5ccccc5)ccc-4c32)cc1 ; CC(C)(C)c1ccc(-c2ccc3oc4c(c3c2)B2c3c(cc(C(C)(C)C)cc3N4c3ccc(C(C)(C)C)cc3)-c3ccc(N(c4ccccc4)c4ccccc4)c4c5cc(C(C)(C)C)ccc5n2c34)cc1]

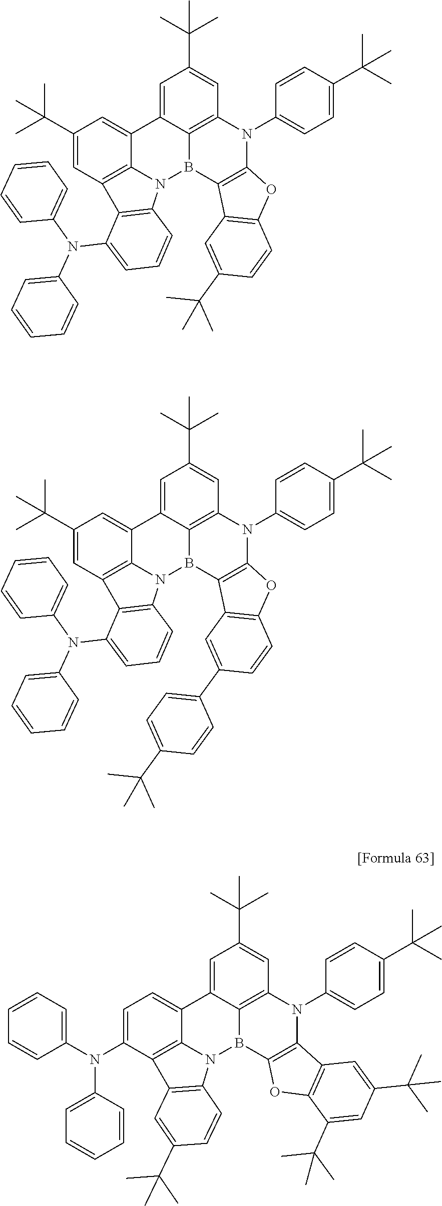 [SMILES: CC(C)(C)c1ccc(N2c3cc(C(C)(C)C)cc4c3B(c3c2oc2ccc(C(C)(C)C)cc32)n2c3cccc(N(c5ccccc5)c5ccccc5)c3c3cc(C(C)(C)C)cc-4c32)cc1 ; CC(C)(C)c1ccc(-c2ccc3oc4c(c3c2)B2c3c(cc(C(C)(C)C)cc3N4c3ccc(C(C)(C)C)cc3)-c3cc(C(C)(C)C)cc4c5c(N(c6ccccc6)c6ccccc6)cccc5n2c34)cc1 ; CC(C)(C)c1ccc(N2c3cc(C(C)(C)C)cc4c3B(c3oc5c(C(C)(C)C)cc(C(C)(C)C)cc5c32)n2c3ccc(C(C)(C)C)cc3c3c(N(c5ccccc5)c5ccccc5)ccc-4c32)cc1]

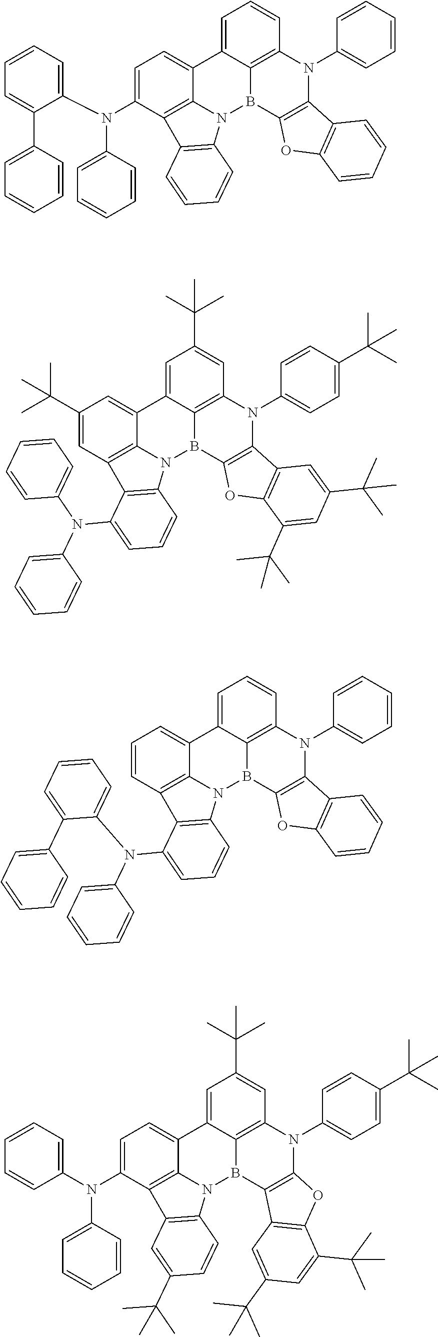 [SMILES: c1ccc(-c2ccccc2N(c2ccccc2)c2ccc3c4c2c2ccccc2n4B2c4oc5ccccc5c4N(c4ccccc4)c4cccc-3c42)cc1 ; CC(C)(C)c1ccc(N2c3cc(C(C)(C)C)cc4c3B(c3oc5c(C(C)(C)C)cc(C(C)(C)C)cc5c32)n2c3cccc(N(c5ccccc5)c5ccccc5)c3c3cc(C(C)(C)C)cc-4c32)cc1 ; c1ccc(-c2ccccc2N(c2ccccc2)c2cccc3c2c2cccc4c2n3B2c3oc5ccccc5c3N(c3ccccc3)c3cccc-4c32)cc1 ; CC(C)(C)c1ccc(N2c3cc(C(C)(C)C)cc4c3B(c3c2oc2c(C(C)(C)C)cc(C(C)(C)C)cc32)n2c3ccc(C(C)(C)C)cc3c3c(N(c5ccccc5)c5ccccc5)ccc-4c32)cc1]

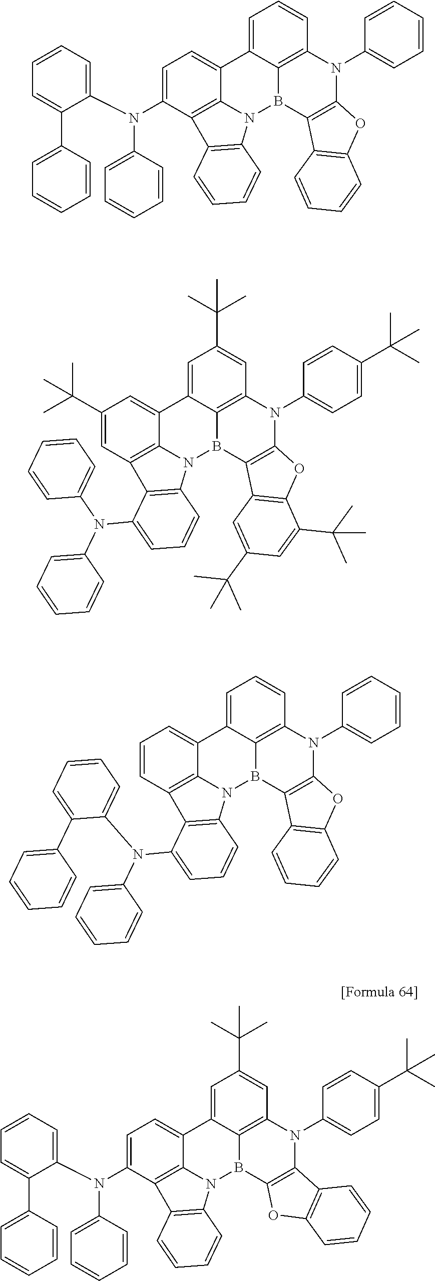 [SMILES: c1ccc(-c2ccccc2N(c2ccccc2)c2ccc3c4c2c2ccccc2n4B2c4c-3cccc4N(c3ccccc3)c3oc4ccccc4c32)cc1 ; CC(C)(C)c1ccc(N2c3cc(C(C)(C)C)cc4c3B(c3c2oc2c(C(C)(C)C)cc(C(C)(C)C)cc32)n2c3cccc(N(c5ccccc5)c5ccccc5)c3c3cc(C(C)(C)C)cc-4c32)cc1 ; c1ccc(-c2ccccc2N(c2ccccc2)c2cccc3c2c2cccc4c2n3B2c3c-4cccc3N(c3ccccc3)c3oc4ccccc4c32)cc1 ; CC(C)(C)c1ccc(N2c3cc(C(C)(C)C)cc4c3B(c3oc5ccccc5c32)n2c3ccccc3c3c(N(c5ccccc5)c5ccccc5-c5ccccc5)ccc-4c32)cc1]

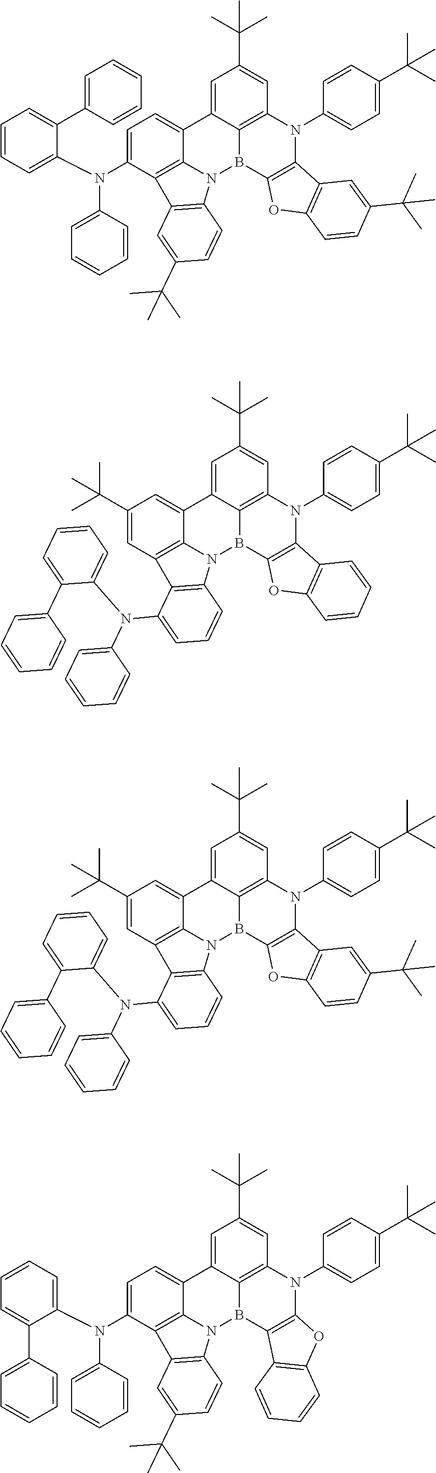 [SMILES: CC(C)(C)c1ccc(N2c3cc(C(C)(C)C)cc4c3B(c3oc5ccc(C(C)(C)C)cc5c32)n2c3ccc(C(C)(C)C)cc3c3c(N(c5ccccc5)c5ccccc5-c5ccccc5)ccc-4c32)cc1 ; CC(C)(C)c1ccc(N2c3cc(C(C)(C)C)cc4c3B(c3oc5ccccc5c32)n2c3cccc(N(c5ccccc5)c5ccccc5-c5ccccc5)c3c3cc(C(C)(C)C)cc-4c32)cc1 ; CC(C)(C)c1ccc(N2c3cc(C(C)(C)C)cc4c3B(c3oc5ccc(C(C)(C)C)cc5c32)n2c3cccc(N(c5ccccc5)c5ccccc5-c5ccccc5)c3c3cc(C(C)(C)C)cc-4c32)cc1 ; CC(C)(C)c1ccc(N2c3cc(C(C)(C)C)cc4c3B(c3c2oc2ccccc32)n2c3ccc(C(C)(C)C)cc3c3c(N(c5ccccc5)c5ccccc5-c5ccccc5)ccc-4c32)cc1]

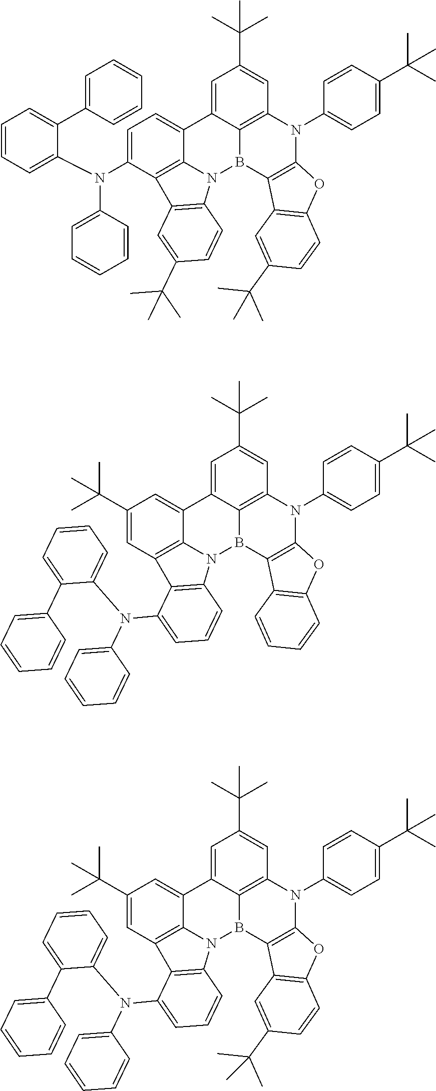 [SMILES: CC(C)(C)c1ccc(N2c3cc(C(C)(C)C)cc4c3B(c3c2oc2ccc(C(C)(C)C)cc32)n2c3ccc(C(C)(C)C)cc3c3c(N(c5ccccc5)c5ccccc5-c5ccccc5)ccc-4c32)cc1 ; CC(C)(C)c1ccc(N2c3cc(C(C)(C)C)cc4c3B(c3c2oc2ccccc32)n2c3cccc(N(c5ccccc5)c5ccccc5-c5ccccc5)c3c3cc(C(C)(C)C)cc-4c32)cc1 ; CC(C)(C)c1ccc(N2c3cc(C(C)(C)C)cc4c3B(c3c2oc2ccc(C(C)(C)C)cc32)n2c3cccc(N(c5ccccc5)c5ccccc5-c5ccccc5)c3c3cc(C(C)(C)C)cc-4c32)cc1]

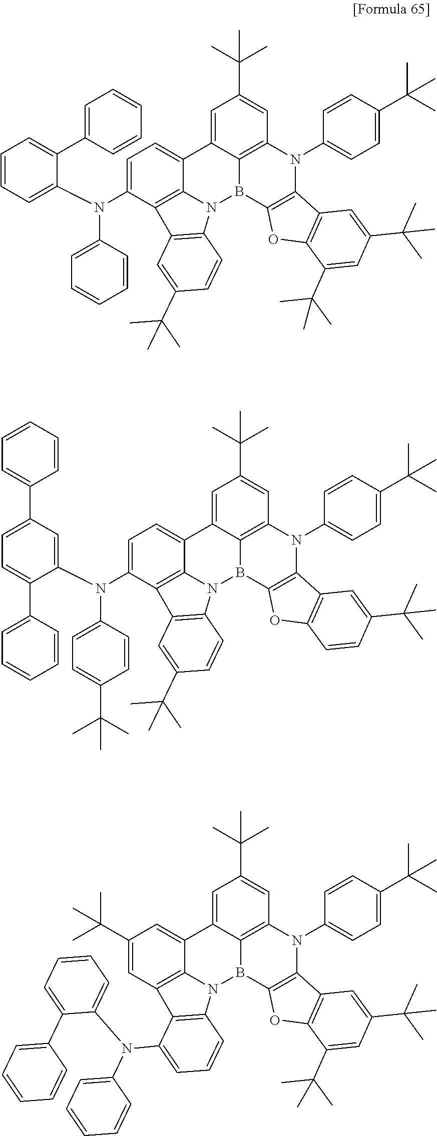 [SMILES: CC(C)(C)c1ccc(N2c3cc(C(C)(C)C)cc4c3B(c3oc5c(C(C)(C)C)cc(C(C)(C)C)cc5c32)n2c3ccc(C(C)(C)C)cc3c3c(N(c5ccccc5)c5ccccc5-c5ccccc5)ccc-4c32)cc1 ; CC(C)(C)c1ccc(N2c3cc(C(C)(C)C)cc4c3B(c3oc5ccc(C(C)(C)C)cc5c32)n2c3ccc(C(C)(C)C)cc3c3c(N(c5ccc(C(C)(C)C)cc5)c5cc(-c6ccccc6)ccc5-c5ccccc5)ccc-4c32)cc1 ; CC(C)(C)c1ccc(N2c3cc(C(C)(C)C)cc4c3B(c3oc5c(C(C)(C)C)cc(C(C)(C)C)cc5c32)n2c3cccc(N(c5ccccc5)c5ccccc5-c5ccccc5)c3c3cc(C(C)(C)C)cc-4c32)cc1]

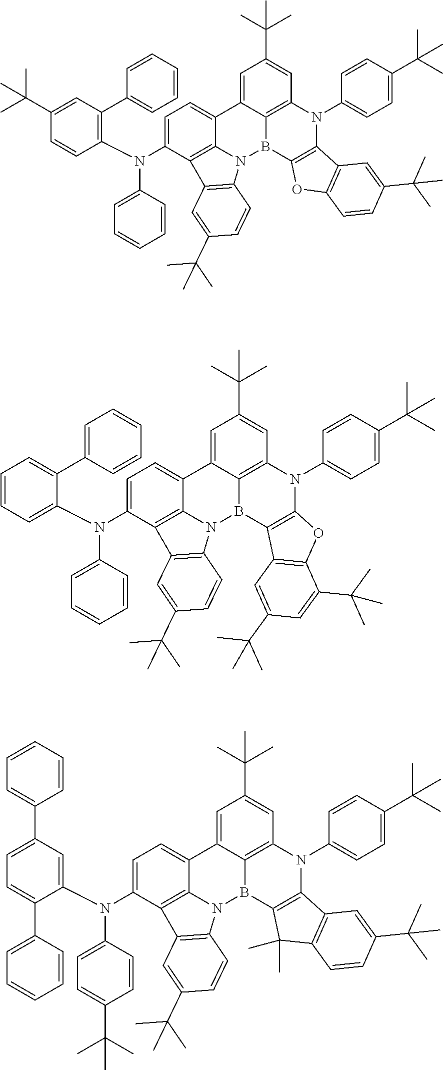 [SMILES: CC(C)(C)c1ccc(N2c3cc(C(C)(C)C)cc4c3B(c3oc5ccc(C(C)(C)C)cc5c32)n2c3ccc(C(C)(C)C)cc3c3c(N(c5ccccc5)c5ccc(C(C)(C)C)cc5-c5ccccc5)ccc-4c32)cc1 ; CC(C)(C)c1ccc(N2c3cc(C(C)(C)C)cc4c3B(c3c2oc2c(C(C)(C)C)cc(C(C)(C)C)cc32)n2c3ccc(C(C)(C)C)cc3c3c(N(c5ccccc5)c5ccccc5-c5ccccc5)ccc-4c32)cc1 ; CC(C)(C)c1ccc(N2C3=C(B4c5c(cc(C(C)(C)C)cc52)-c2ccc(N(c5ccc(C(C)(C)C)cc5)c5cc(-c6ccccc6)ccc5-c5ccccc5)c5c6cc(C(C)(C)C)ccc6n4c25)C(C)(C)c2ccc(C(C)(C)C)cc23)cc1]

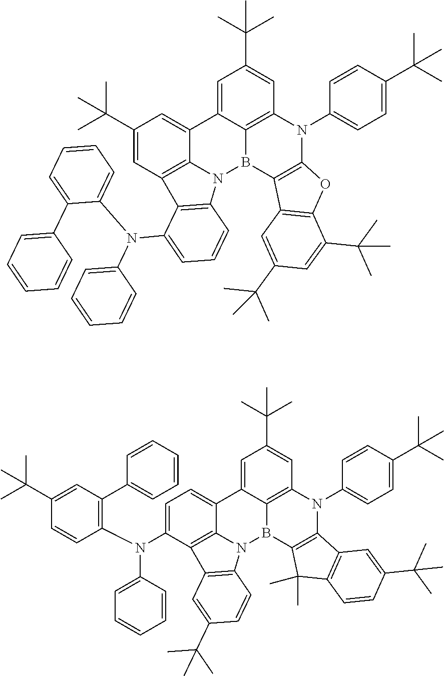

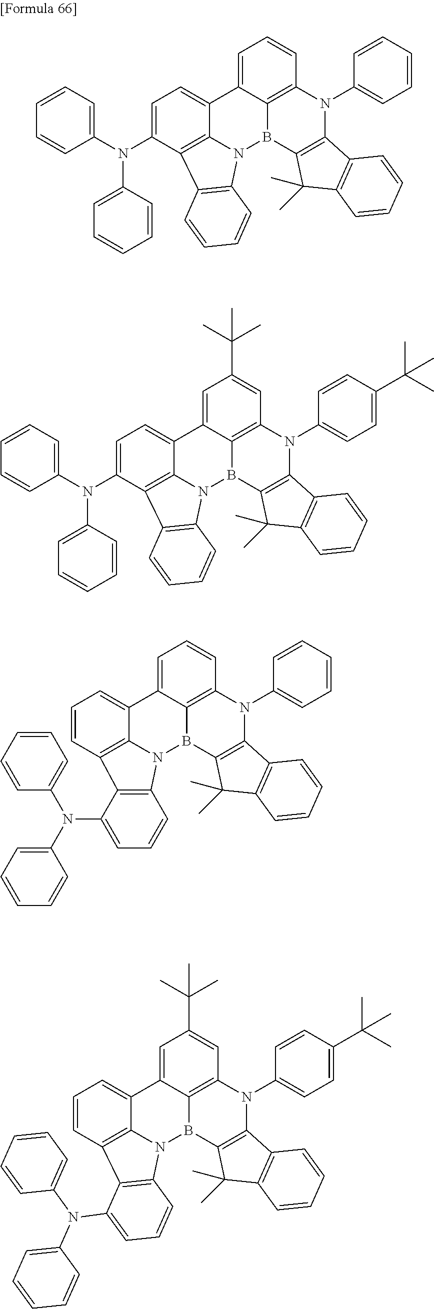 [SMILES: CC1(C)C2=C(c3ccccc31)N(c1ccccc1)c1cccc3c1B2n1c2ccccc2c2c(N(c4ccccc4)c4ccccc4)ccc-3c21 ; CC(C)(C)c1ccc(N2C3=C(B4c5c(cc(C(C)(C)C)cc52)-c2ccc(N(c5ccccc5)c5ccccc5)c5c6ccccc6n4c25)C(C)(C)c2ccccc23)cc1 ; CC1(C)C2=C(c3ccccc31)N(c1ccccc1)c1cccc3c1B2n1c2cccc(N(c4ccccc4)c4ccccc4)c2c2cccc-3c21 ; CC(C)(C)c1ccc(N2C3=C(B4c5c(cc(C(C)(C)C)cc52)-c2cccc5c6c(N(c7ccccc7)c7ccccc7)cccc6n4c25)C(C)(C)c2ccccc23)cc1]

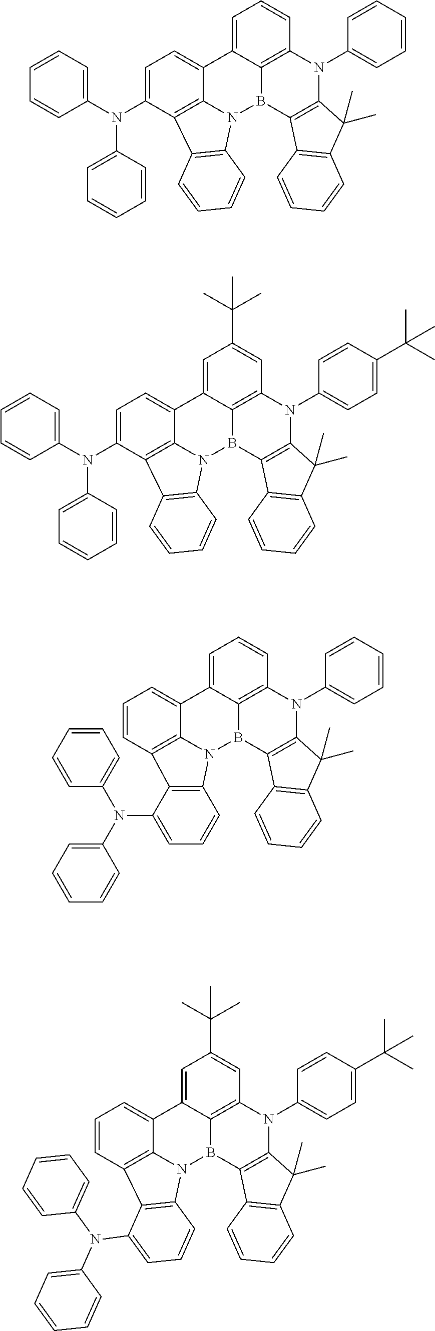 [SMILES: CC1(C)C2=C(B3c4c(cccc4N2c2ccccc2)-c2ccc(N(c4ccccc4)c4ccccc4)c4c5ccccc5n3c24)c2ccccc21 ; CC(C)(C)c1ccc(N2C3=C(B4c5c(cc(C(C)(C)C)cc52)-c2ccc(N(c5ccccc5)c5ccccc5)c5c6ccccc6n4c25)c2ccccc2C3(C)C)cc1 ; CC1(C)C2=C(B3c4c(cccc4N2c2ccccc2)-c2cccc4c5c(N(c6ccccc6)c6ccccc6)cccc5n3c24)c2ccccc21 ; CC(C)(C)c1ccc(N2C3=C(B4c5c(cc(C(C)(C)C)cc52)-c2cccc5c6c(N(c7ccccc7)c7ccccc7)cccc6n4c25)c2ccccc2C3(C)C)cc1]

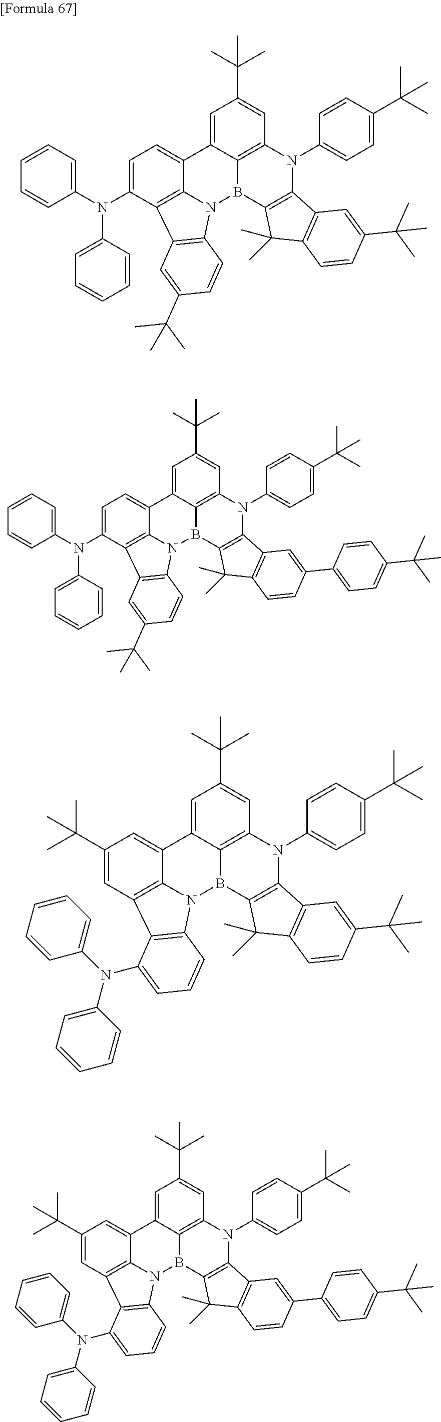

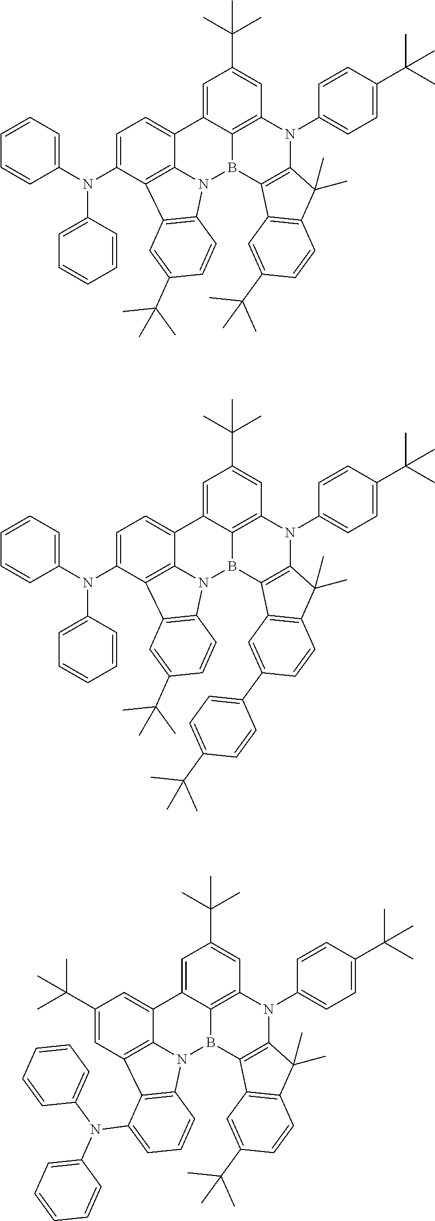 [SMILES: CC(C)(C)c1ccc(N2C3=C(B4c5c(cc(C(C)(C)C)cc52)-c2ccc(N(c5ccccc5)c5ccccc5)c5c6cc(C(C)(C)C)ccc6n4c25)c2cc(C(C)(C)C)ccc2C3(C)C)cc1 ; CC(C)(C)c1ccc(-c2ccc3c(c2)C2=C(N(c4ccc(C(C)(C)C)cc4)c4cc(C(C)(C)C)cc5c4B2n2c4ccc(C(C)(C)C)cc4c4c(N(c6ccccc6)c6ccccc6)ccc-5c42)C3(C)C)cc1 ; CC(C)(C)c1ccc(N2C3=C(B4c5c(cc(C(C)(C)C)cc52)-c2cc(C(C)(C)C)cc5c6c(N(c7ccccc7)c7ccccc7)cccc6n4c25)c2cc(C(C)(C)C)ccc2C3(C)C)cc1]

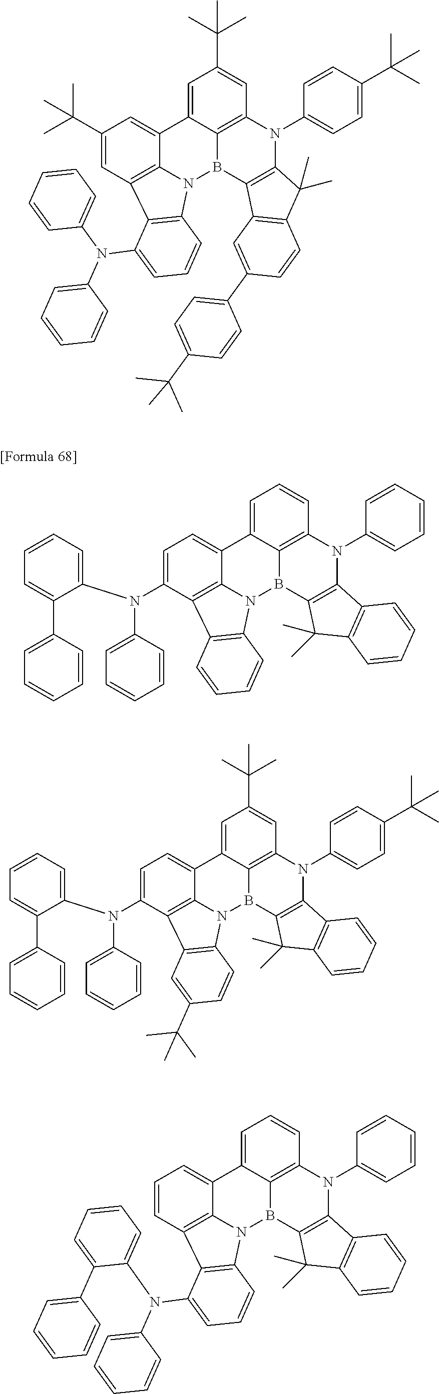 [SMILES: CC(C)(C)c1ccc(-c2ccc3c(c2)C2=C(N(c4ccc(C(C)(C)C)cc4)c4cc(C(C)(C)C)cc5c4B2n2c4cccc(N(c6ccccc6)c6ccccc6)c4c4cc(C(C)(C)C)cc-5c42)C3(C)C)cc1 ; CC1(C)C2=C(c3ccccc31)N(c1ccccc1)c1cccc3c1B2n1c2ccccc2c2c(N(c4ccccc4)c4ccccc4-c4ccccc4)ccc-3c21 ; CC(C)(C)c1ccc(N2C3=C(B4c5c(cc(C(C)(C)C)cc52)-c2ccc(N(c5ccccc5)c5ccccc5-c5ccccc5)c5c6cc(C(C)(C)C)ccc6n4c25)C(C)(C)c2ccccc23)cc1 ; CC1(C)C2=C(c3ccccc31)N(c1ccccc1)c1cccc3c1B2n1c2cccc(N(c4ccccc4)c4ccccc4-c4ccccc4)c2c2cccc-3c21]

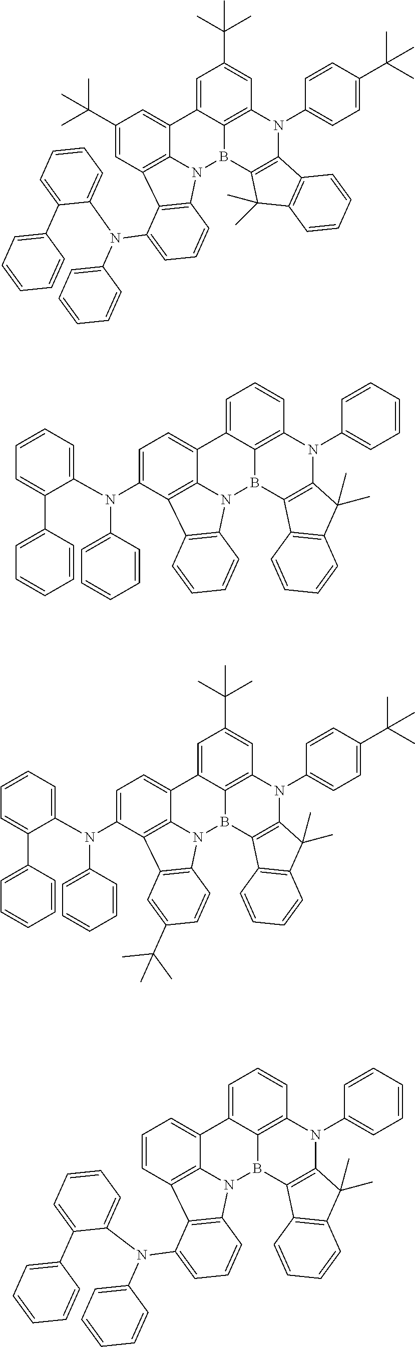 [SMILES: CC(C)(C)c1ccc(N2C3=C(B4c5c(cc(C(C)(C)C)cc52)-c2cc(C(C)(C)C)cc5c6c(N(c7ccccc7)c7ccccc7-c7ccccc7)cccc6n4c25)C(C)(C)c2ccccc23)cc1 ; CC1(C)C2=C(B3c4c(cccc4N2c2ccccc2)-c2ccc(N(c4ccccc4)c4ccccc4-c4ccccc4)c4c5ccccc5n3c24)c2ccccc21 ; CC(C)(C)c1ccc(N2C3=C(B4c5c(cc(C(C)(C)C)cc52)-c2ccc(N(c5ccccc5)c5ccccc5-c5ccccc5)c5c6cc(C(C)(C)C)ccc6n4c25)c2ccccc2C3(C)C)cc1 ; CC1(C)C2=C(B3c4c(cccc4N2c2ccccc2)-c2cccc4c5c(N(c6ccccc6)c6ccccc6-c6ccccc6)cccc5n3c24)c2ccccc21]

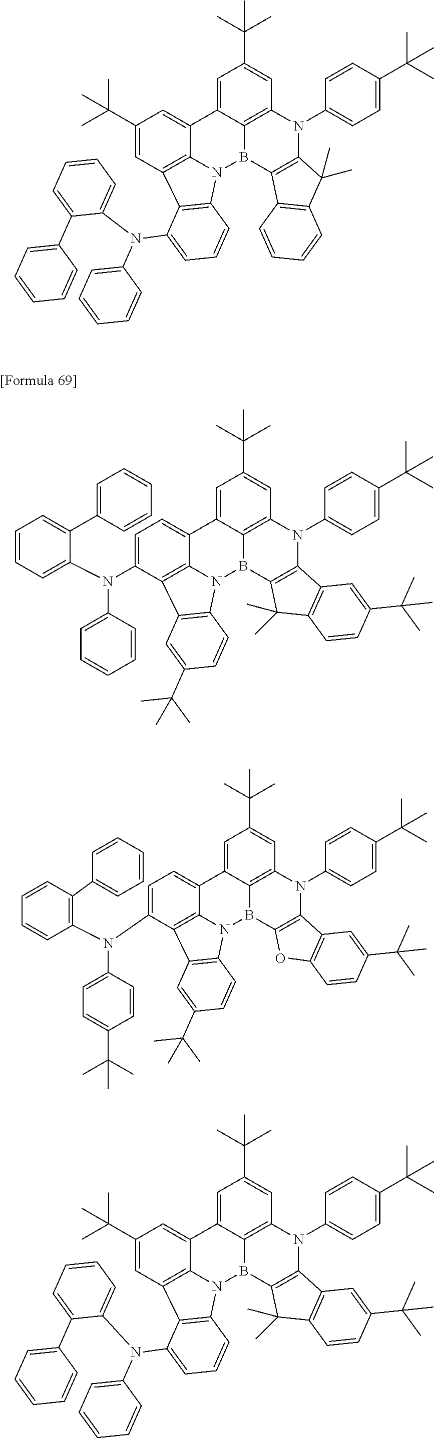

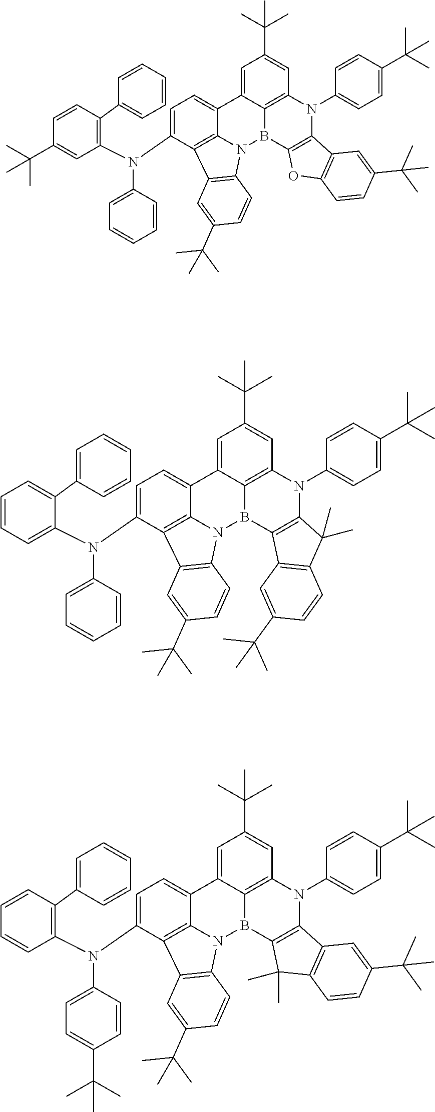 [SMILES: CC(C)(C)c1ccc(N2c3cc(C(C)(C)C)cc4c3B(c3oc5ccc(C(C)(C)C)cc5c32)n2c3ccc(C(C)(C)C)cc3c3c(N(c5ccccc5)c5cc(C(C)(C)C)ccc5-c5ccccc5)ccc-4c32)cc1 ; CC(C)(C)c1ccc(N2C3=C(B4c5c(cc(C(C)(C)C)cc52)-c2ccc(N(c5ccccc5)c5ccccc5-c5ccccc5)c5c6cc(C(C)(C)C)ccc6n4c25)c2cc(C(C)(C)C)ccc2C3(C)C)cc1 ; CC(C)(C)c1ccc(N2C3=C(B4c5c(cc(C(C)(C)C)cc52)-c2ccc(N(c5ccc(C(C)(C)C)cc5)c5ccccc5-c5ccccc5)c5c6cc(C(C)(C)C)ccc6n4c25)C(C)(C)c2ccc(C(C)(C)C)cc23)cc1]

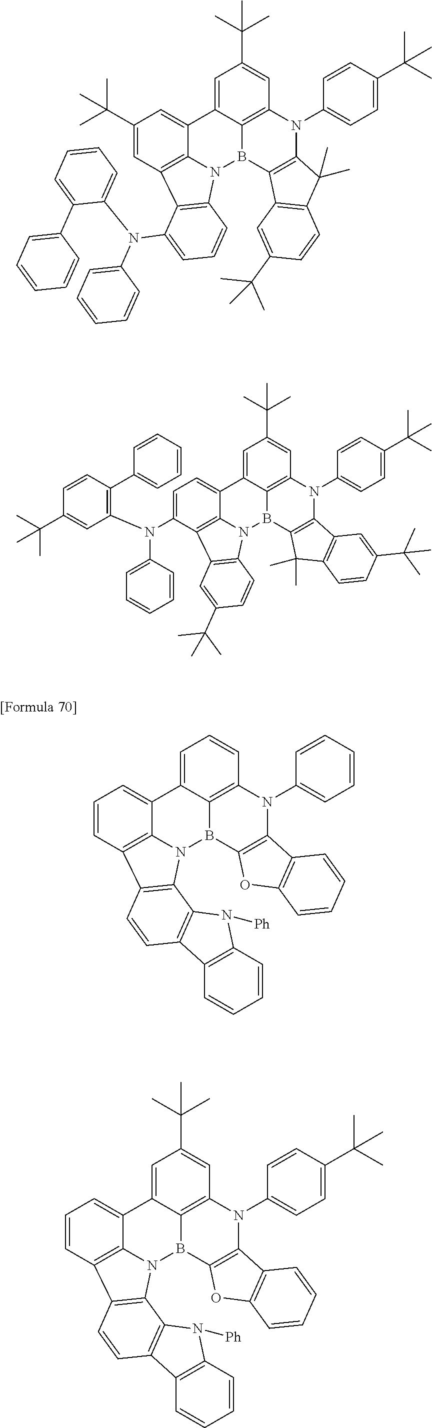

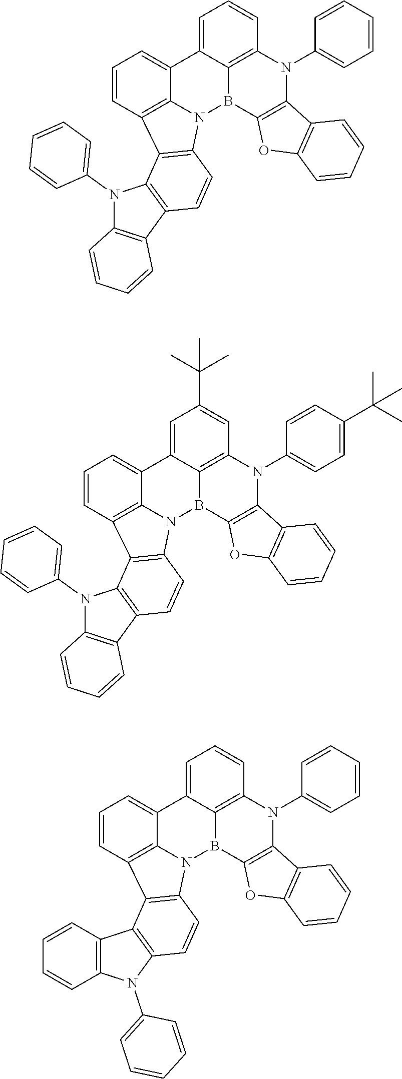

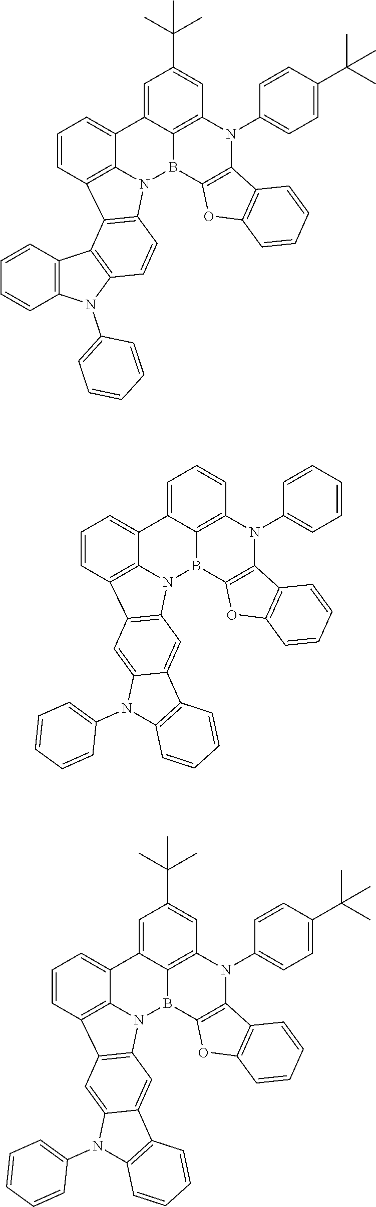 [SMILES: CC(C)(C)c1ccc(N2c3cc(C(C)(C)C)cc4c3B(c3oc5ccccc5c32)n2c3ccc5c(c6ccccc6n5-c5ccccc5)c3c3cccc-4c32)cc1 ; c1ccc(N2c3cccc4c3B(c3oc5ccccc5c32)n2c3cc5c6ccccc6n(-c6ccccc6)c5cc3c3cccc-4c32)cc1 ; CC(C)(C)c1ccc(N2c3cc(C(C)(C)C)cc4c3B(c3oc5ccccc5c32)n2c3cc5c6ccccc6n(-c6ccccc6)c5cc3c3cccc-4c32)cc1]

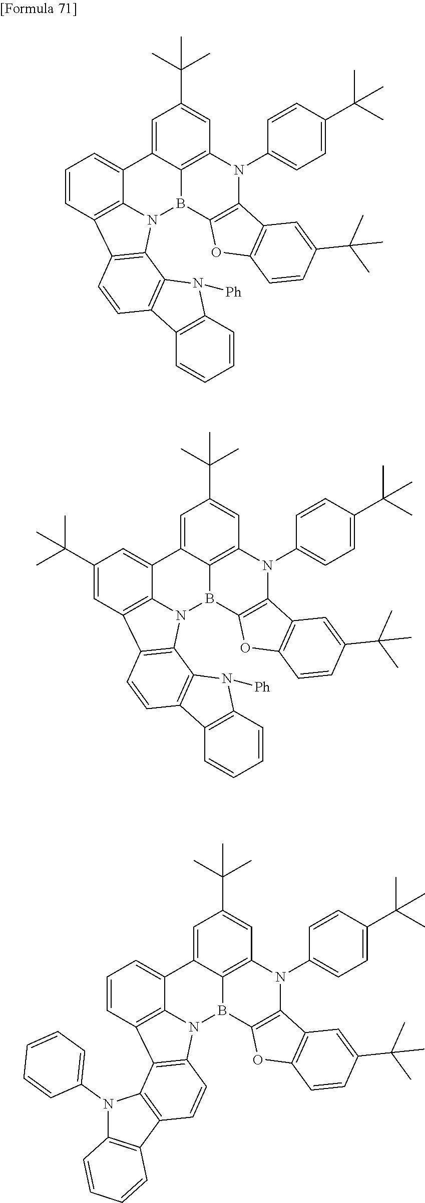

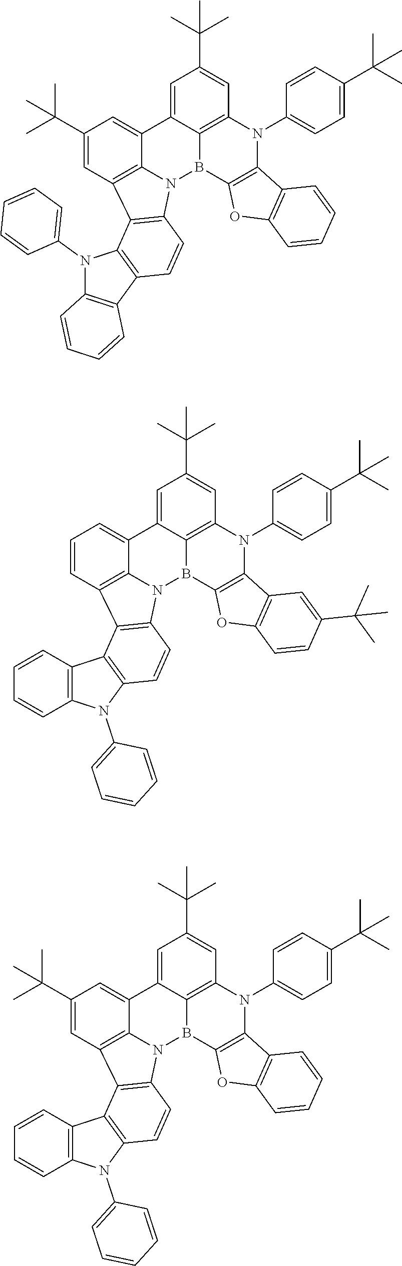

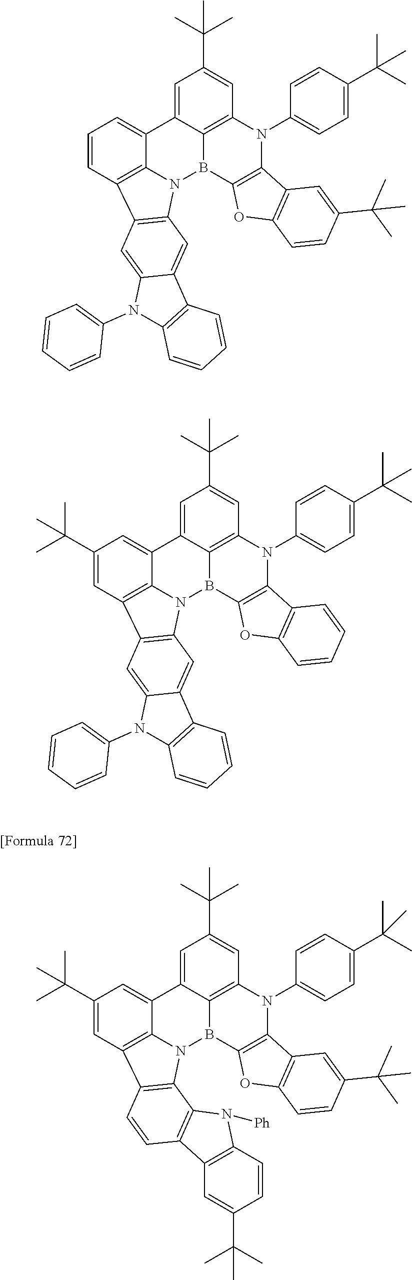

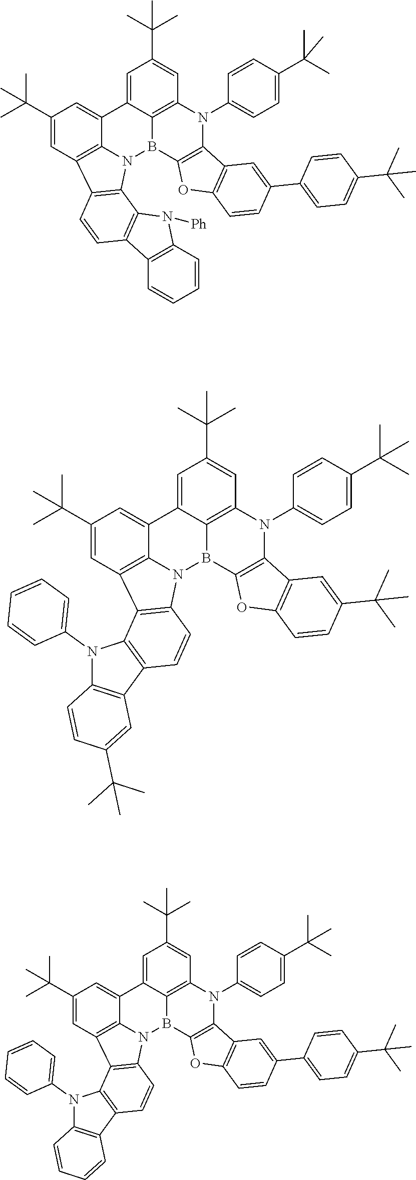 [SMILES: CC(C)(C)c1ccc(-c2ccc3oc4c(c3c2)N(c2ccc(C(C)(C)C)cc2)c2cc(C(C)(C)C)cc3c2B4n2c4c-3cc(C(C)(C)C)cc4c3ccc4c5ccccc5n(-c5ccccc5)c4c32)cc1 ; CC(C)(C)c1ccc(N2c3cc(C(C)(C)C)cc4c3B(c3oc5ccc(C(C)(C)C)cc5c32)n2c3ccc5c6cc(C(C)(C)C)ccc6n(-c6ccccc6)c5c3c3cc(C(C)(C)C)cc-4c32)cc1 ; CC(C)(C)c1ccc(-c2ccc3oc4c(c3c2)N(c2ccc(C(C)(C)C)cc2)c2cc(C(C)(C)C)cc3c2B4n2c4ccc5c6ccccc6n(-c6ccccc6)c5c4c4cc(C(C)(C)C)cc-3c42)cc1]

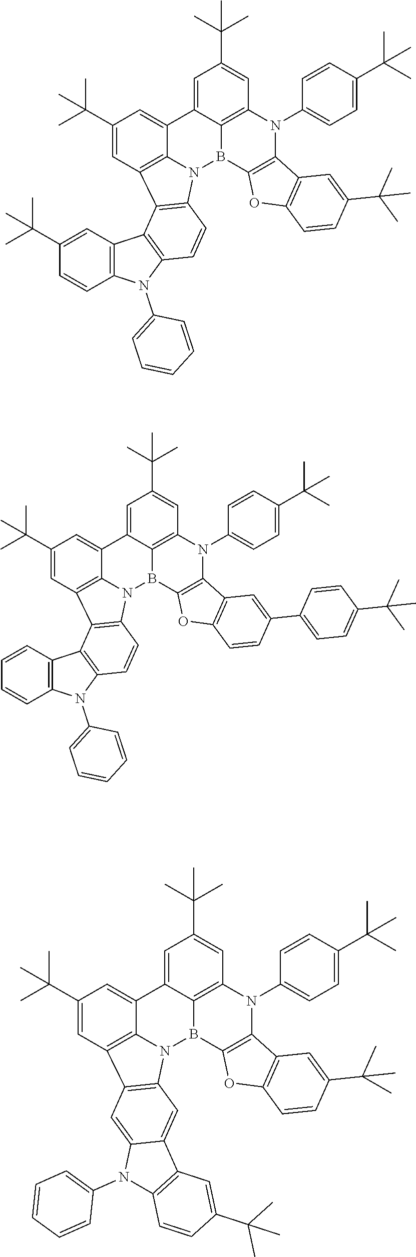

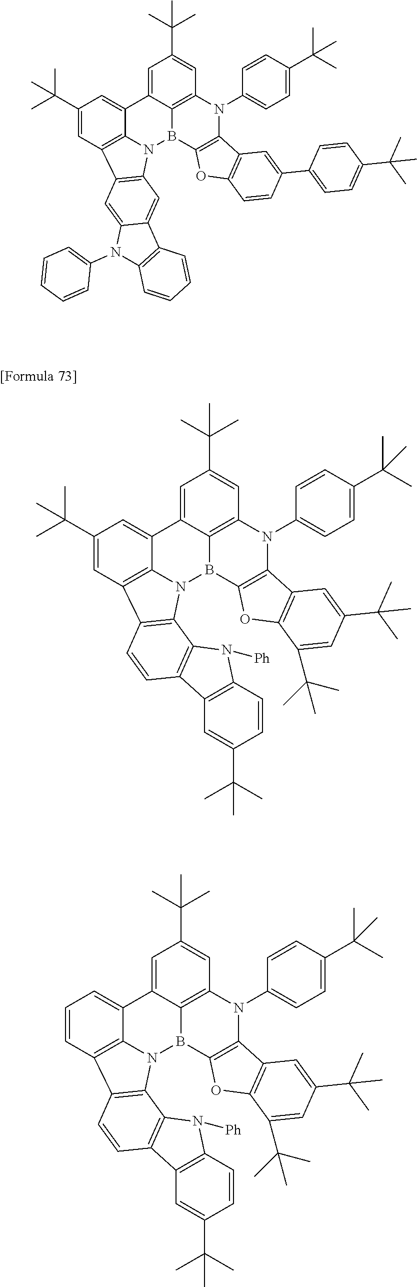

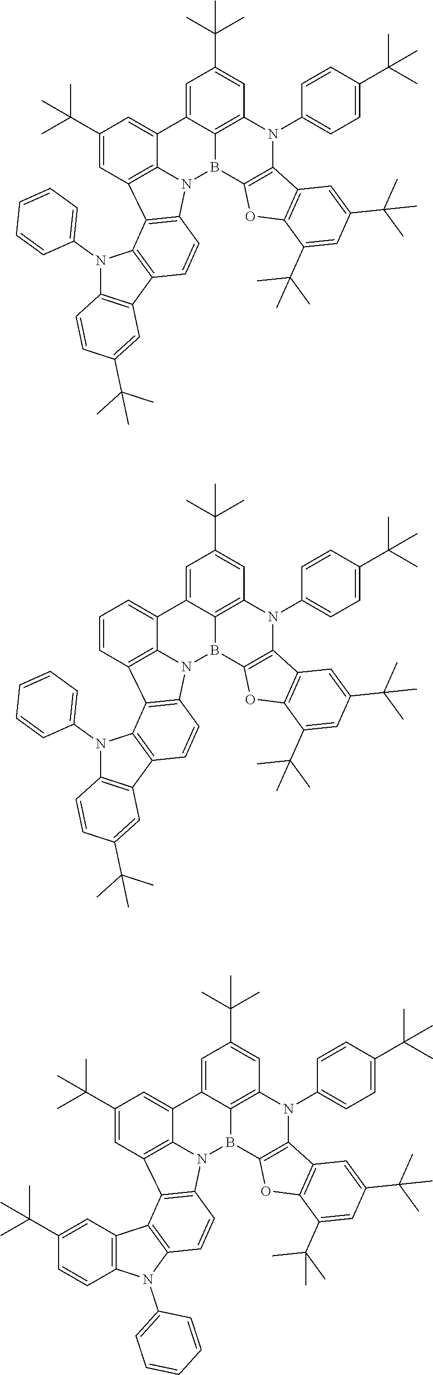

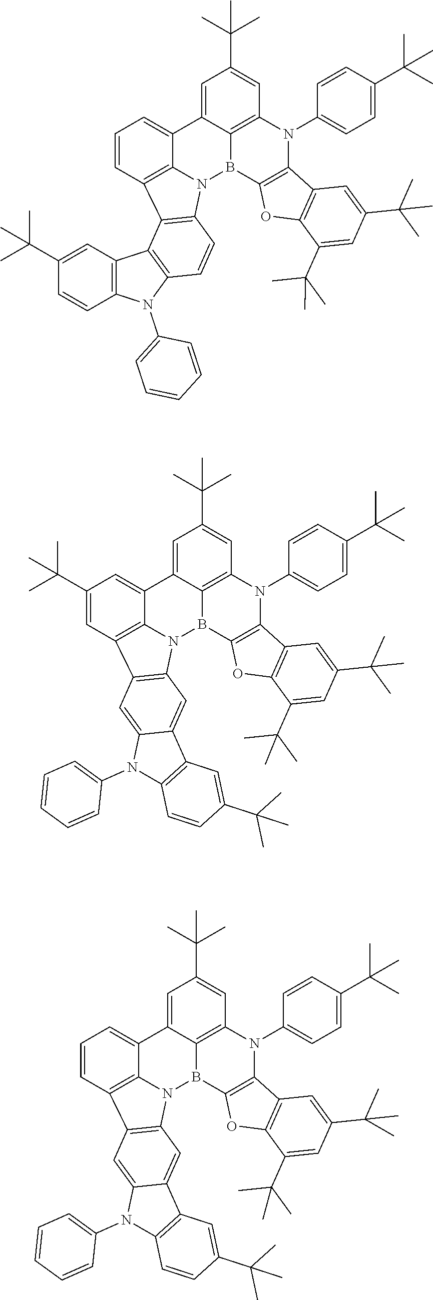

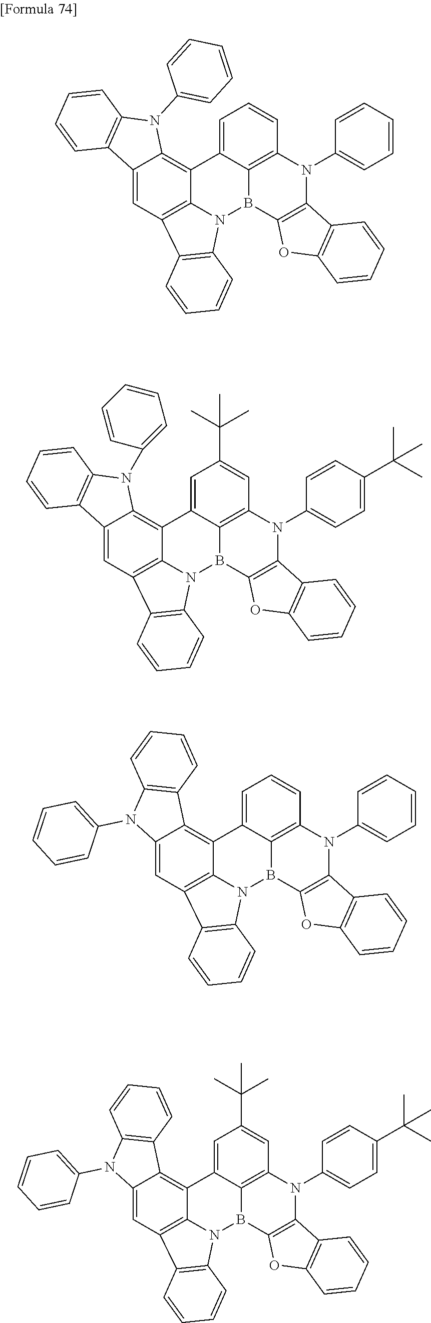 [SMILES: c1ccc(N2c3cccc4c3B(c3oc5ccccc5c32)n2c3ccccc3c3cc5c6ccccc6n(-c6ccccc6)c5c-4c32)cc1 ; CC(C)(C)c1ccc(N2c3cc(C(C)(C)C)cc4c3B(c3oc5ccccc5c32)n2c3ccccc3c3cc5c6ccccc6n(-c6ccccc6)c5c-4c32)cc1 ; c1ccc(N2c3cccc4c3B(c3oc5ccccc5c32)n2c3ccccc3c3cc5c(c-4c32)c2ccccc2n5-c2ccccc2)cc1 ; CC(C)(C)c1ccc(N2c3cc(C(C)(C)C)cc4c3B(c3oc5ccccc5c32)n2c3ccccc3c3cc5c(c-4c32)c2ccccc2n5-c2ccccc2)cc1]

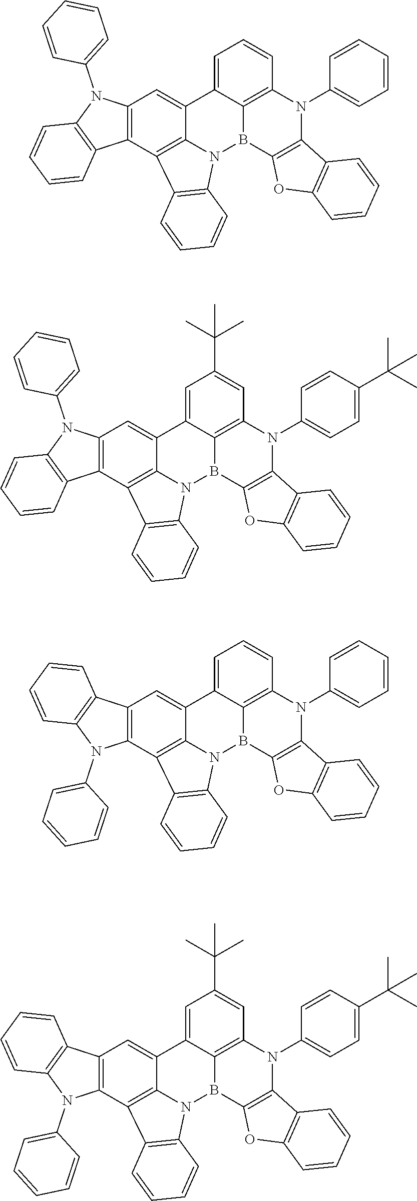 [SMILES: c1ccc(N2c3cccc4c3B(c3oc5ccccc5c32)n2c3ccccc3c3c5c6ccccc6n(-c6ccccc6)c5cc-4c32)cc1 ; CC(C)(C)c1ccc(N2c3cc(C(C)(C)C)cc4c3B(c3oc5ccccc5c32)n2c3ccccc3c3c5c6ccccc6n(-c6ccccc6)c5cc-4c32)cc1 ; c1ccc(N2c3cccc4c3B(c3oc5ccccc5c32)n2c3ccccc3c3c2c-4cc2c4ccccc4n(-c4ccccc4)c23)cc1 ; CC(C)(C)c1ccc(N2c3cc(C(C)(C)C)cc4c3B(c3oc5ccccc5c32)n2c3ccccc3c3c2c-4cc2c4ccccc4n(-c4ccccc4)c23)cc1]

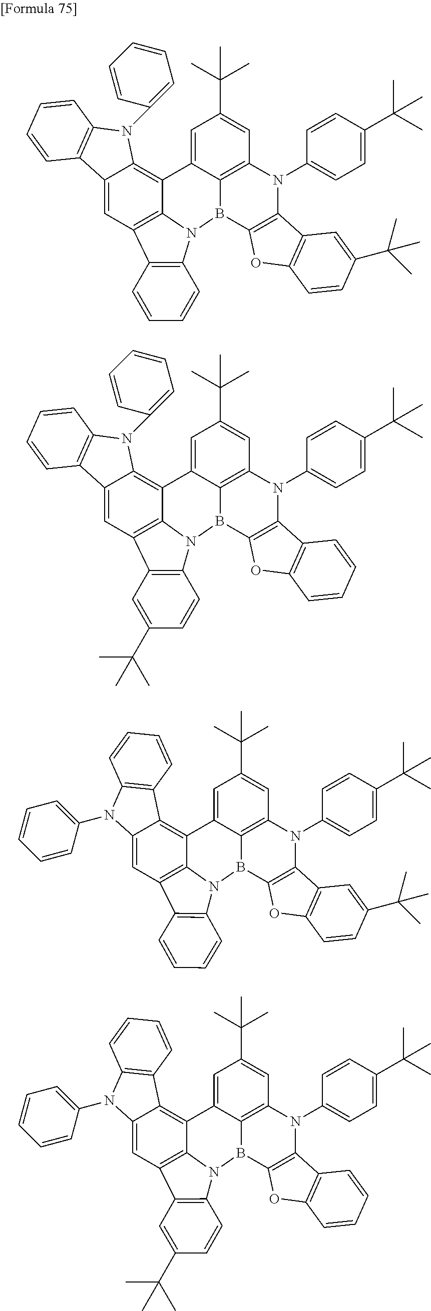

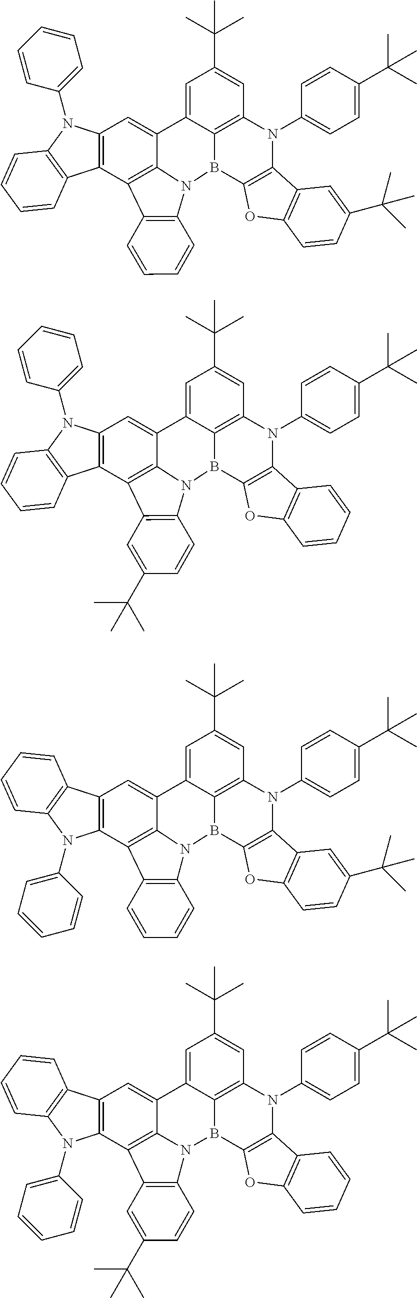

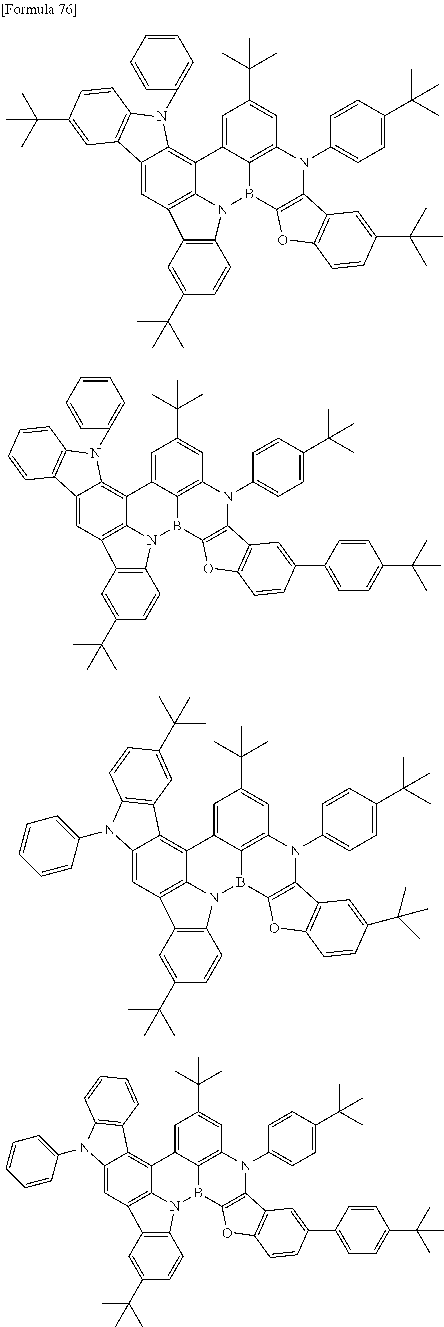

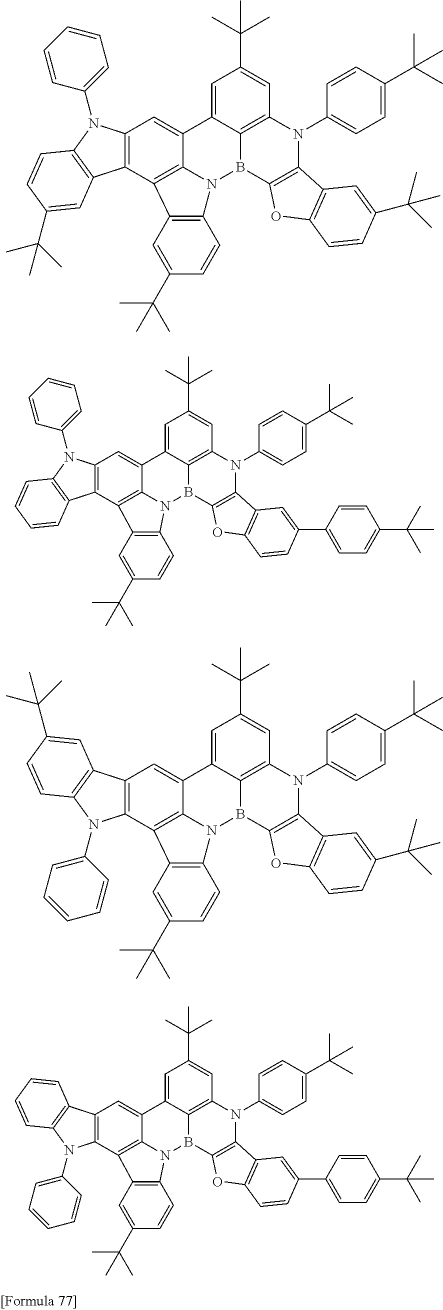

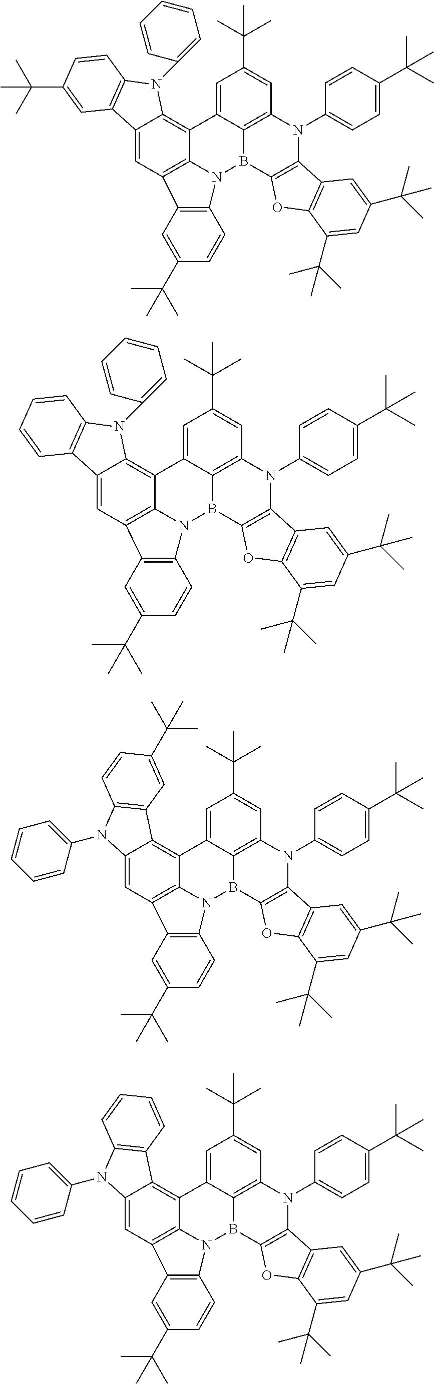

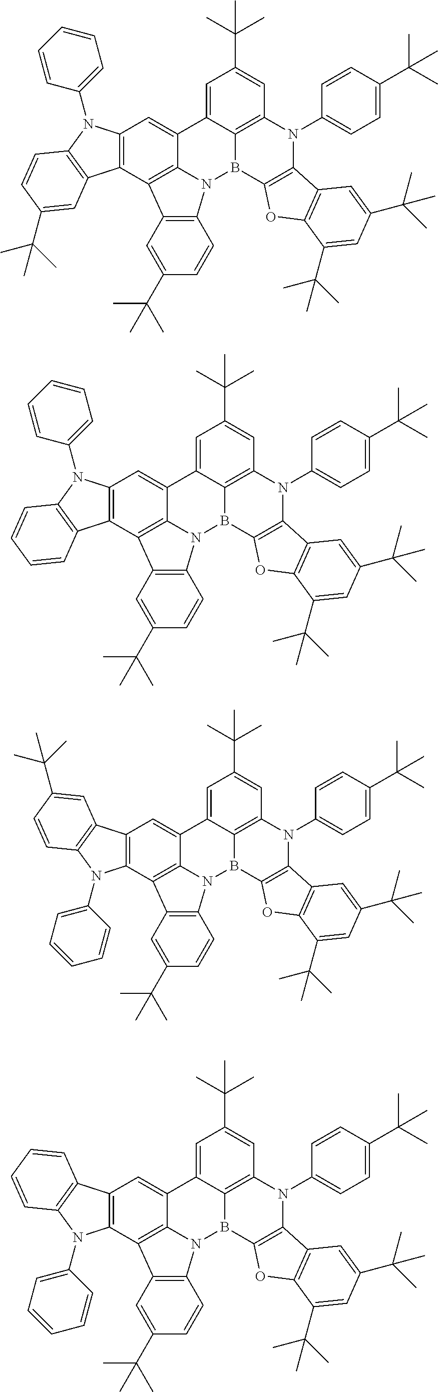

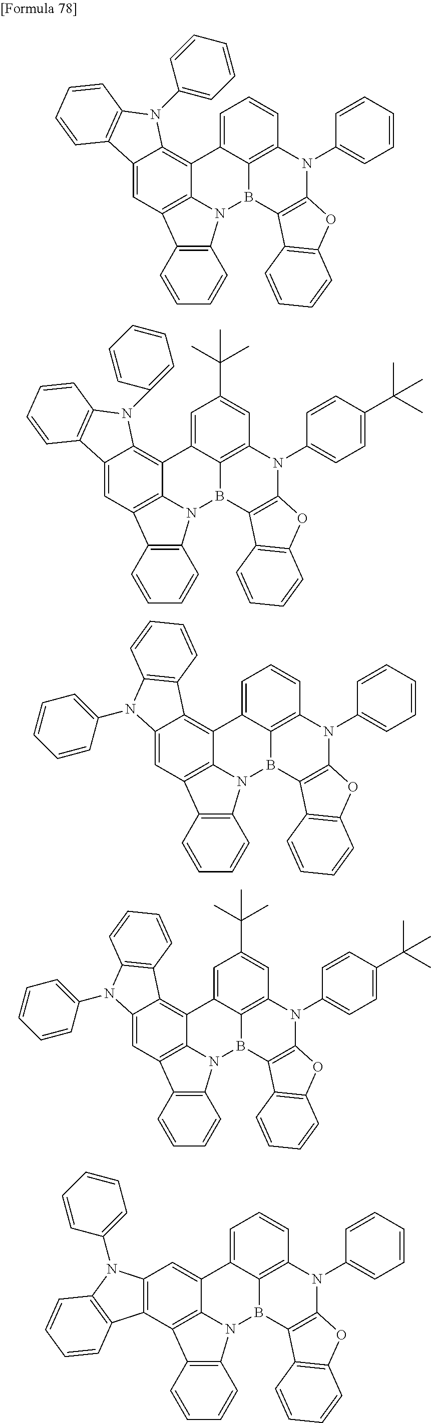

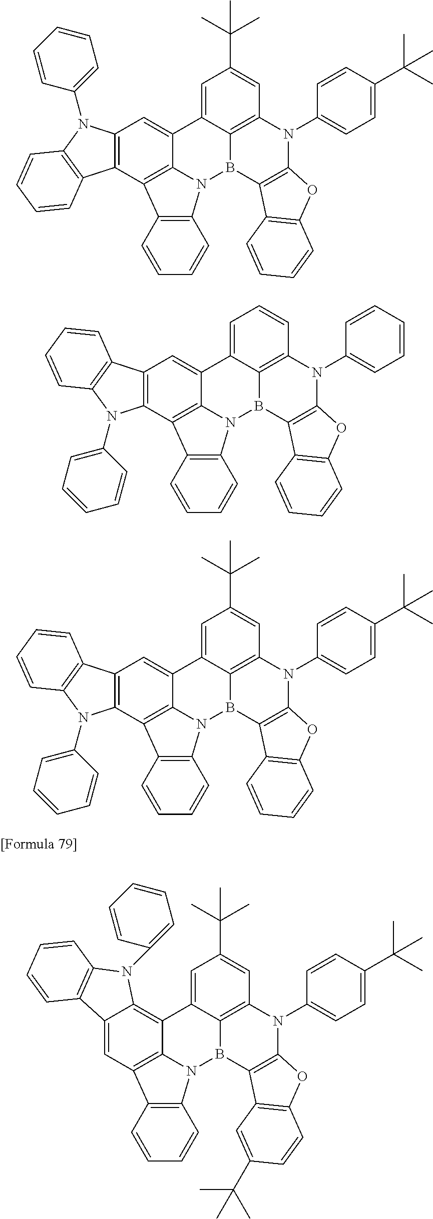

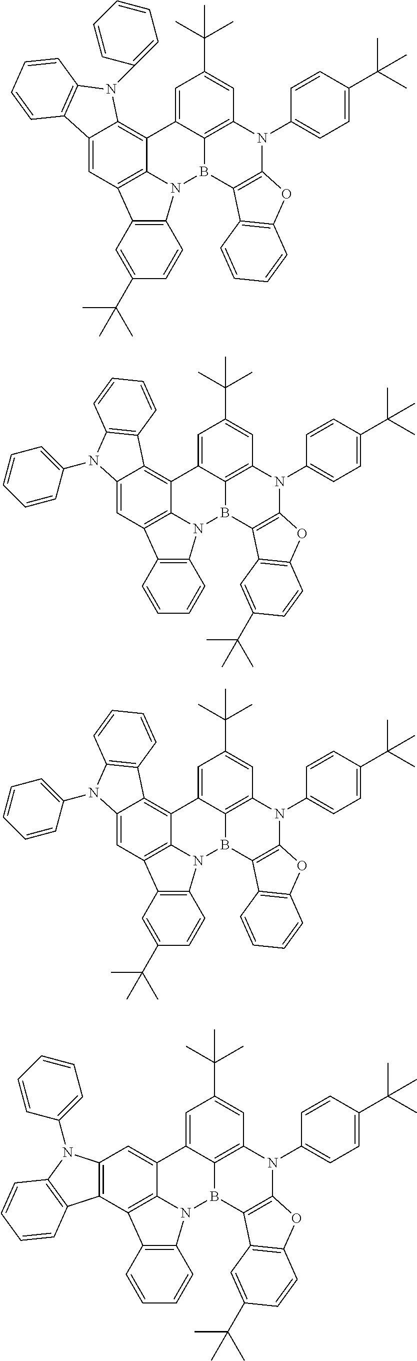

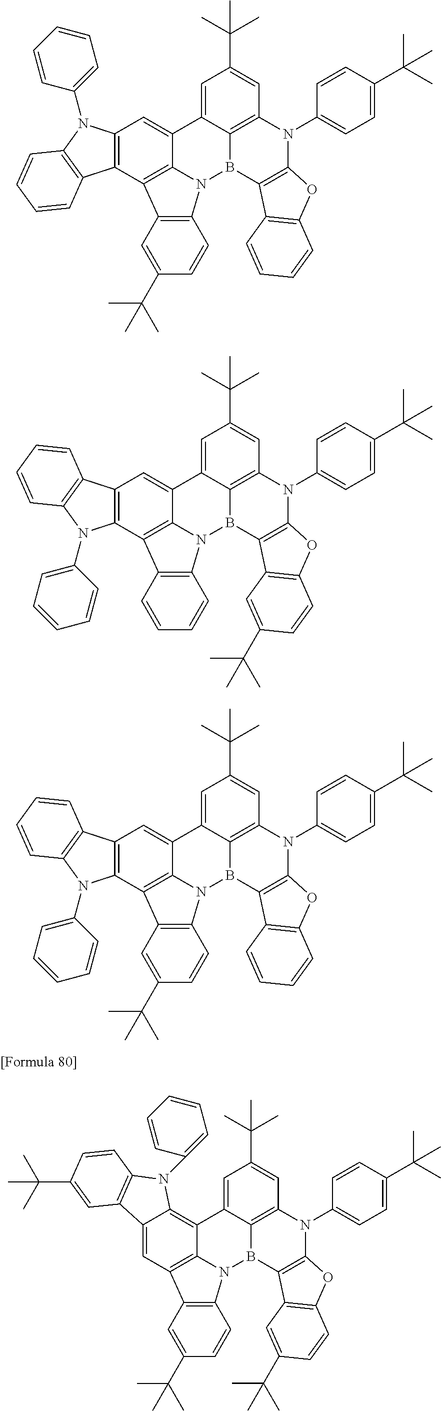

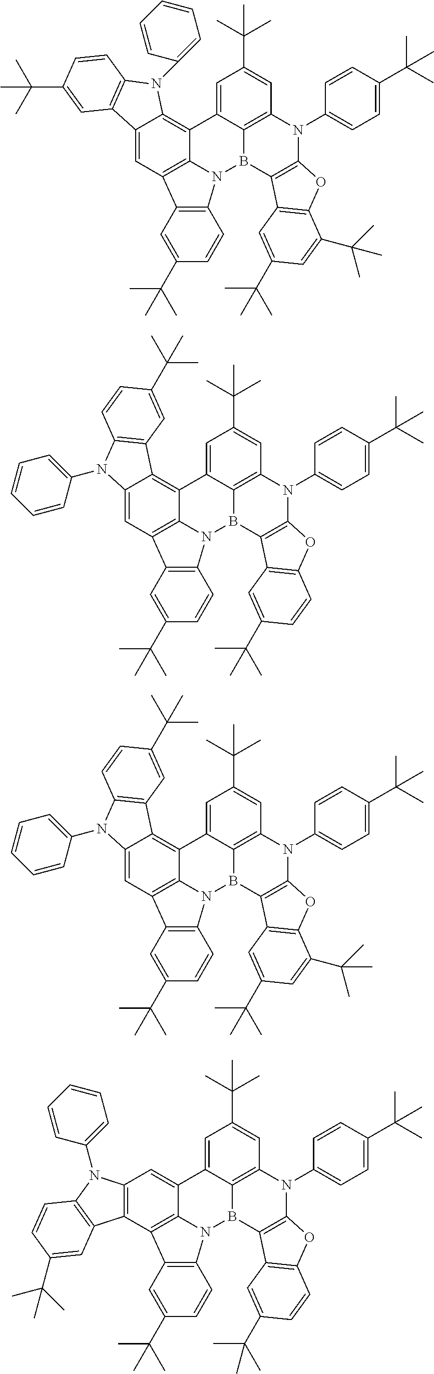

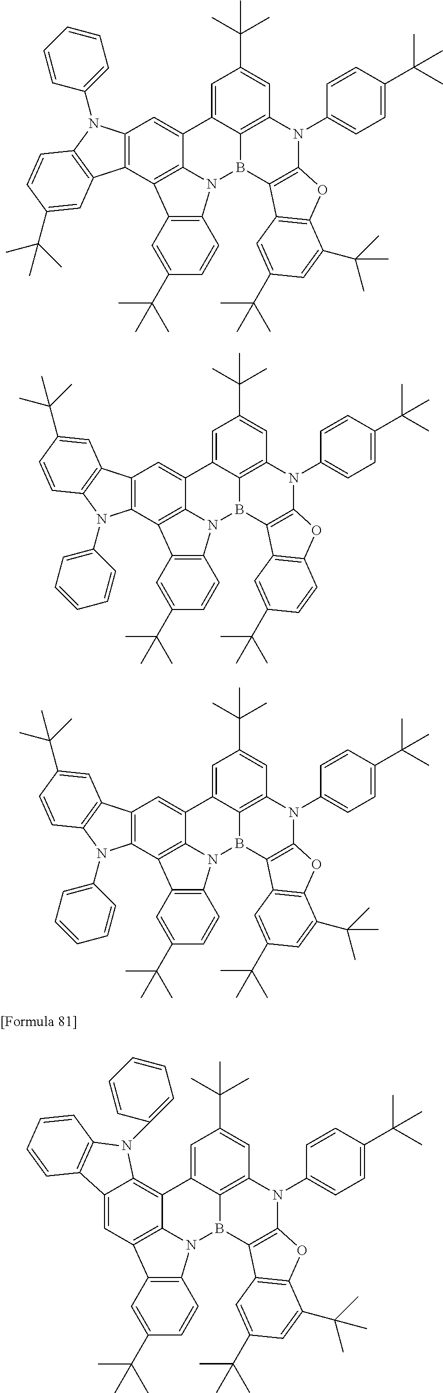

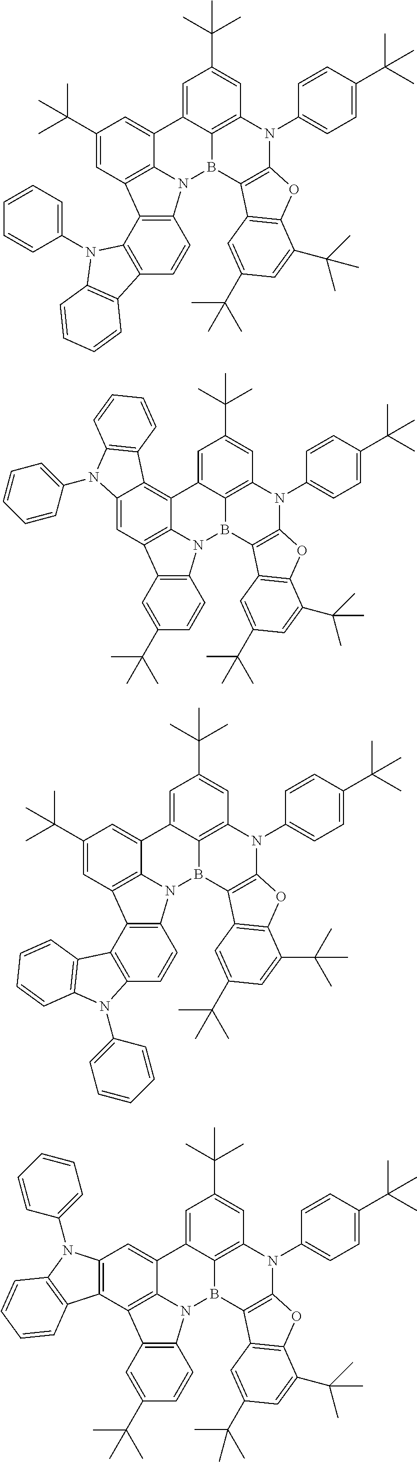

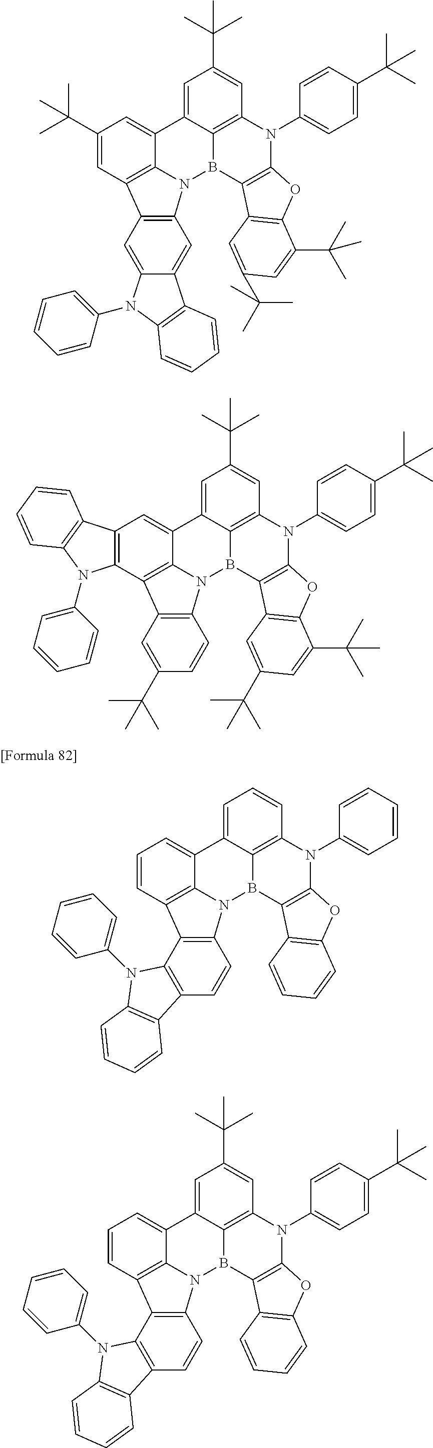

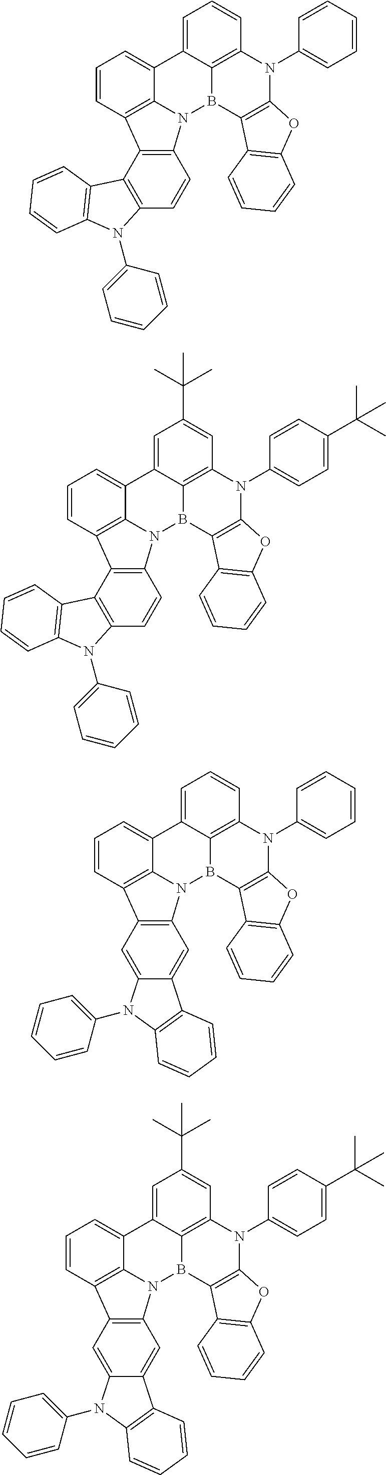

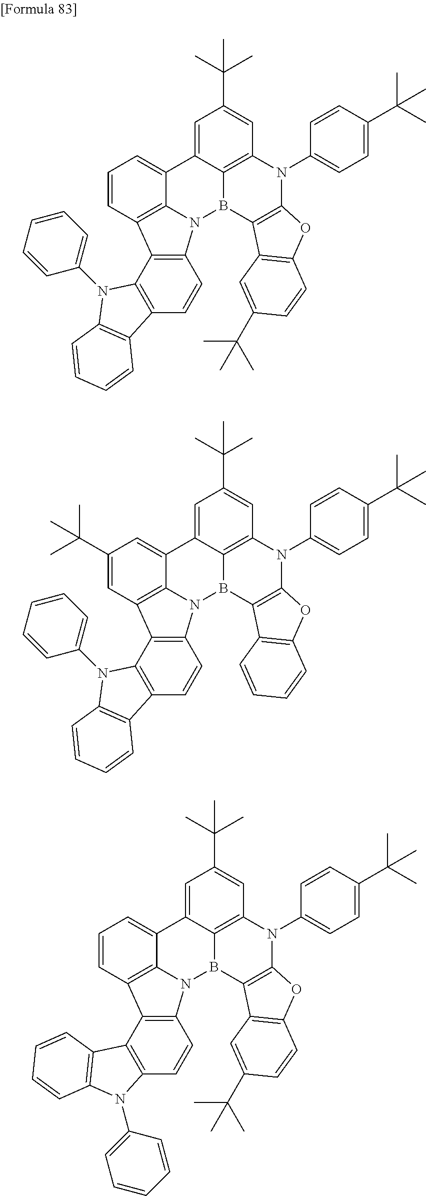 [SMILES: CC(C)(C)c1ccc(N2c3cc(C(C)(C)C)cc4c3B(c3c2oc2ccc(C(C)(C)C)cc32)n2c3ccc5c6ccccc6n(-c6ccccc6)c5c3c3cccc-4c32)cc1 ; CC(C)(C)c1ccc(N2c3cc(C(C)(C)C)cc4c3B(c3c2oc2ccccc32)n2c3ccc5c6ccccc6n(-c6ccccc6)c5c3c3cc(C(C)(C)C)cc-4c32)cc1 ; CC(C)(C)c1ccc(N2c3cc(C(C)(C)C)cc4c3B(c3c2oc2ccc(C(C)(C)C)cc32)n2c3ccc5c(c6ccccc6n5-c5ccccc5)c3c3cccc-4c32)cc1]

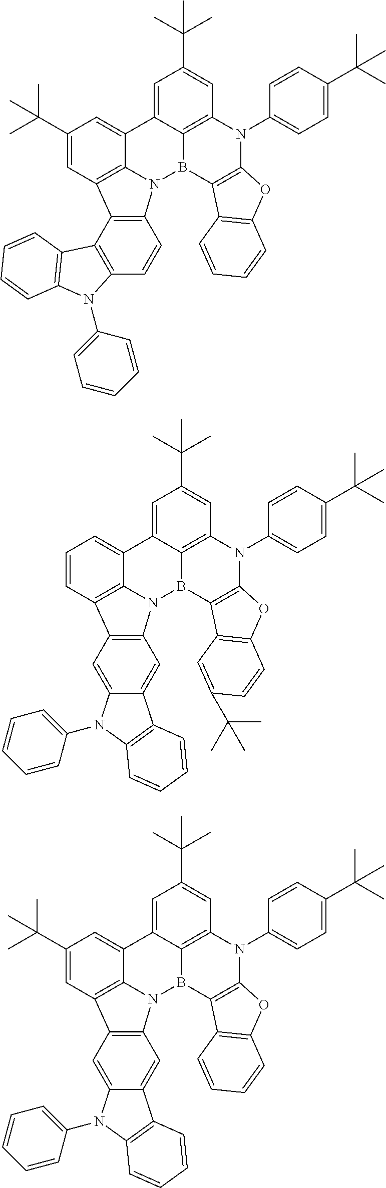

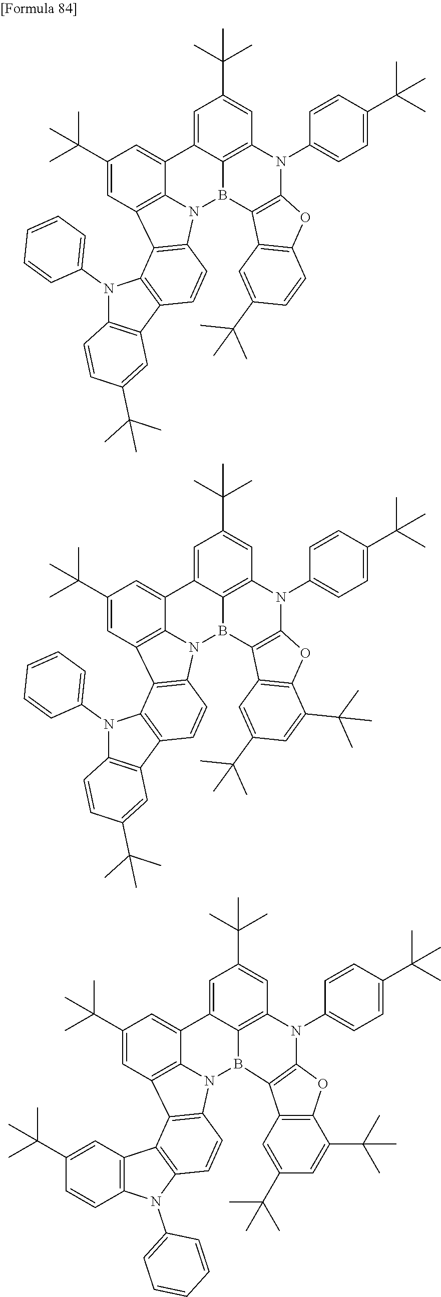

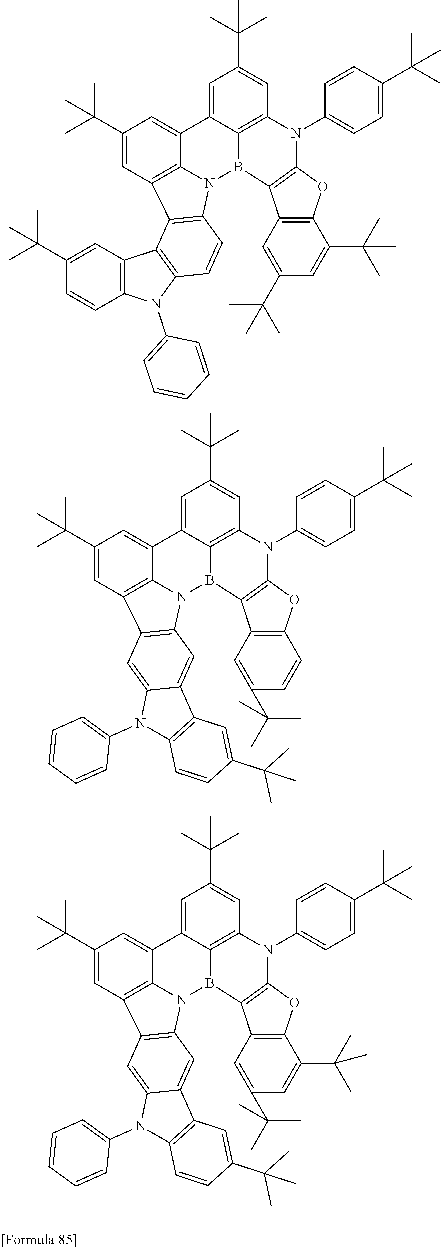

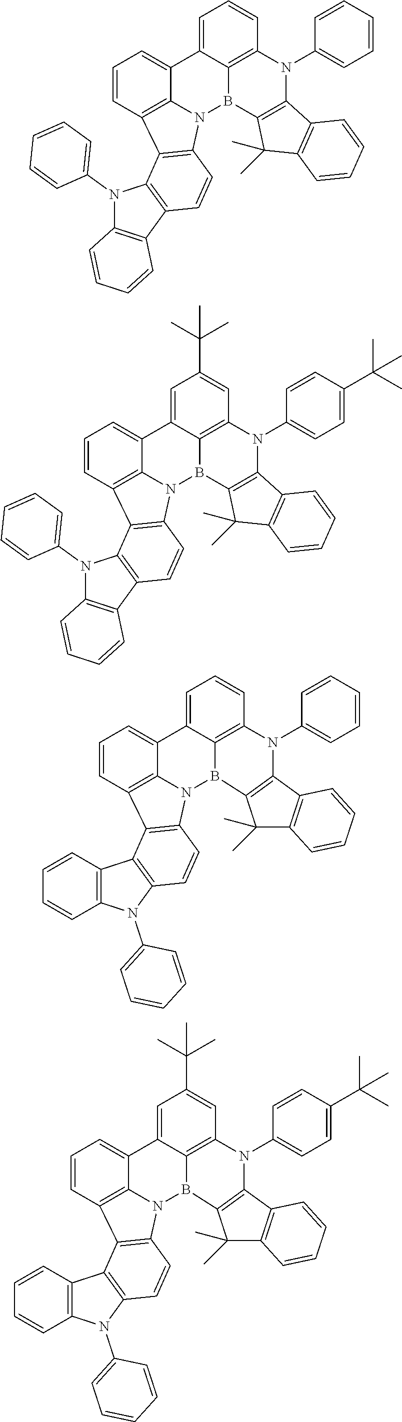

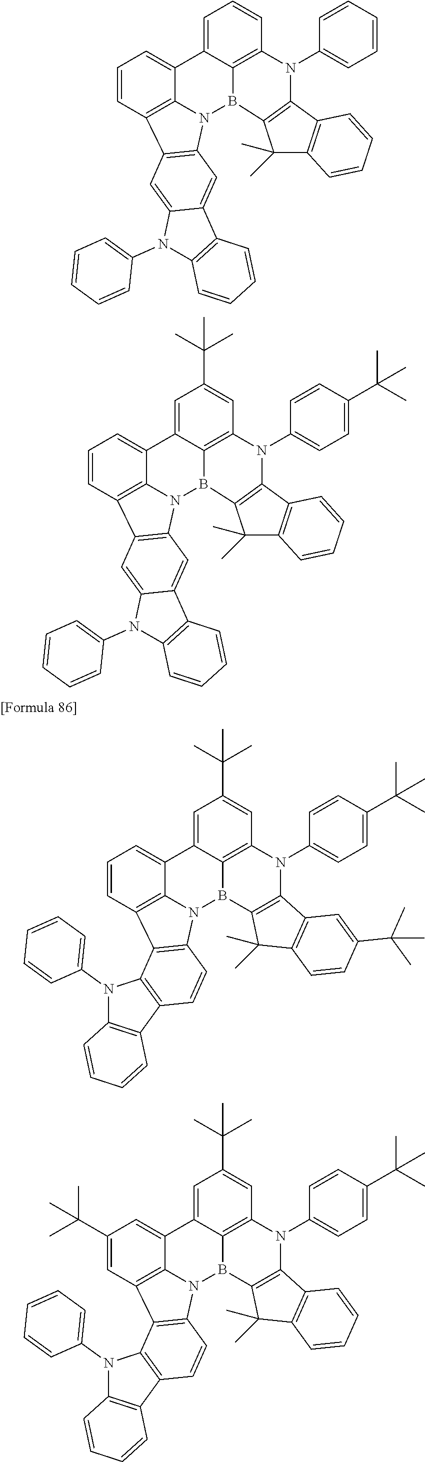

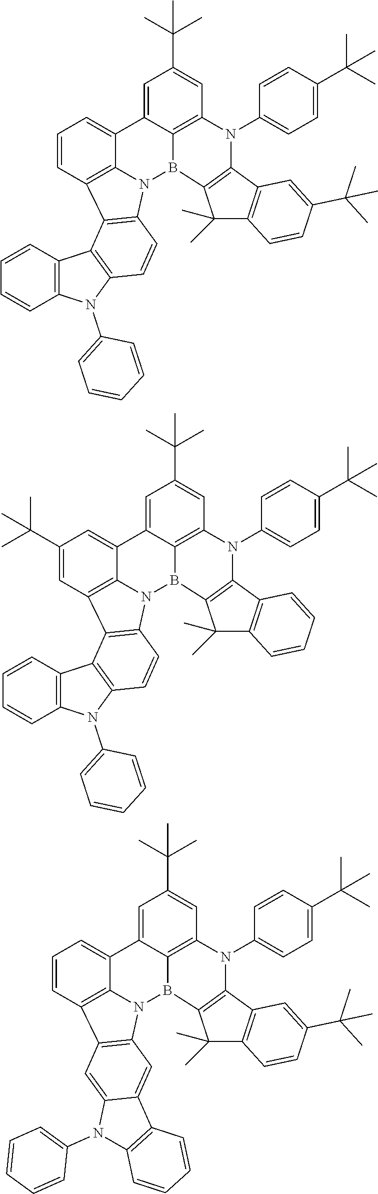

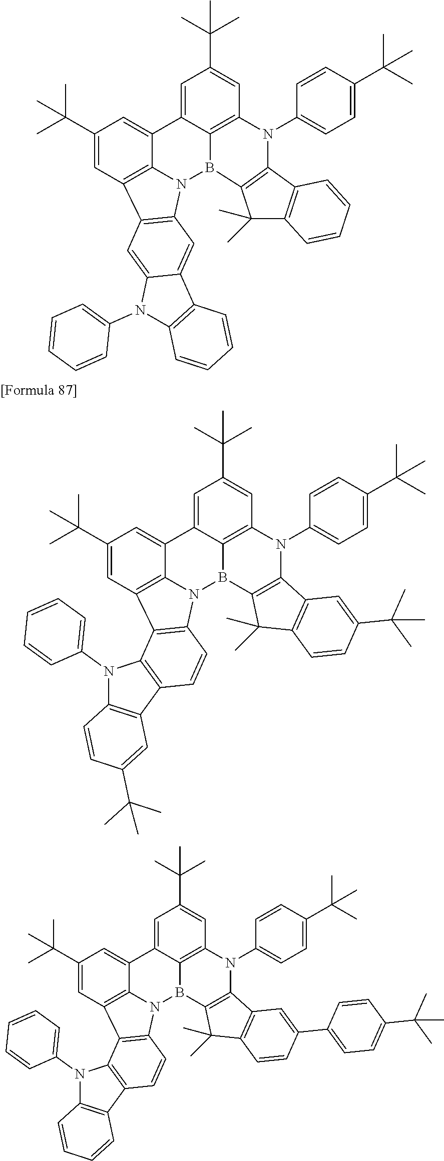

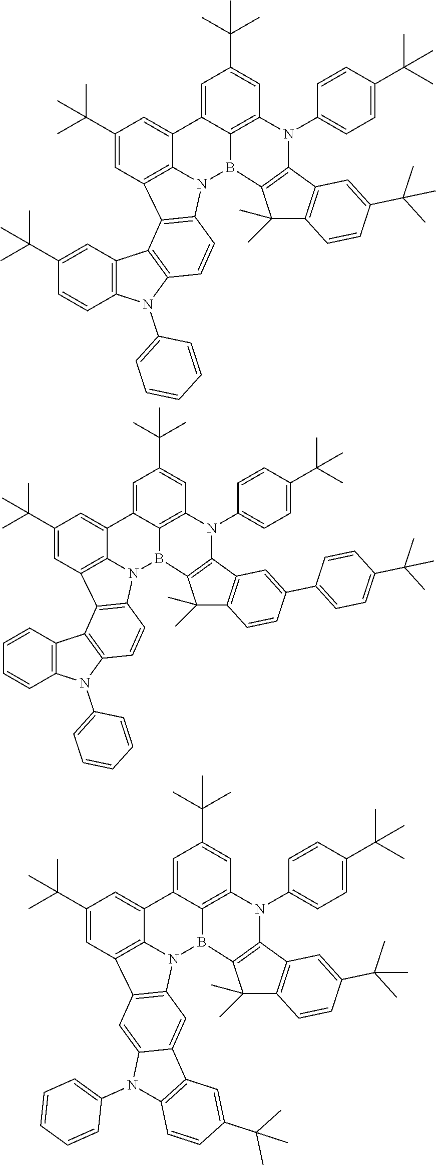

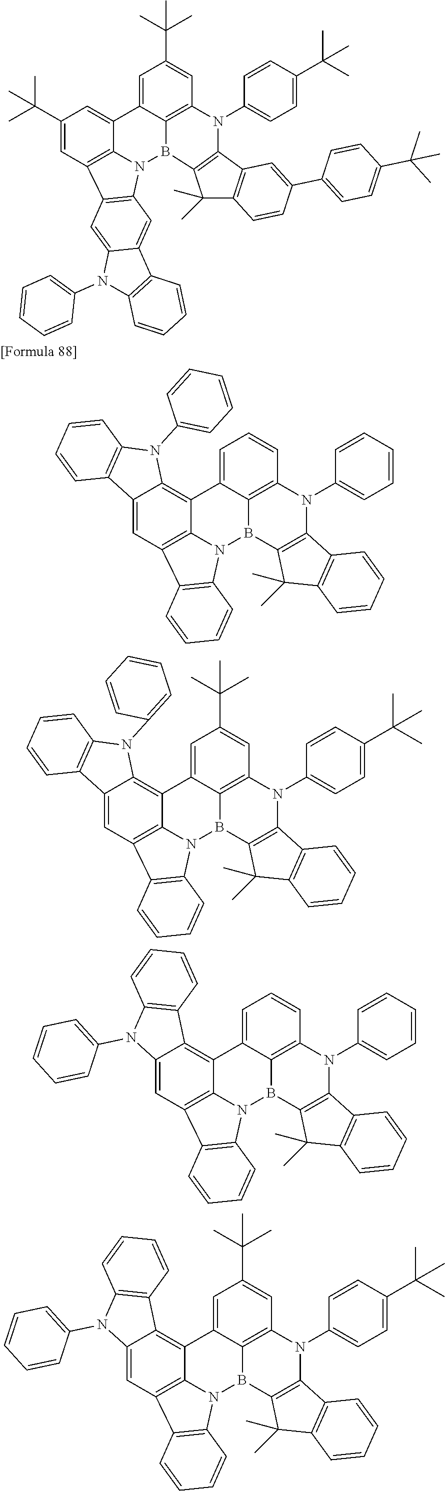

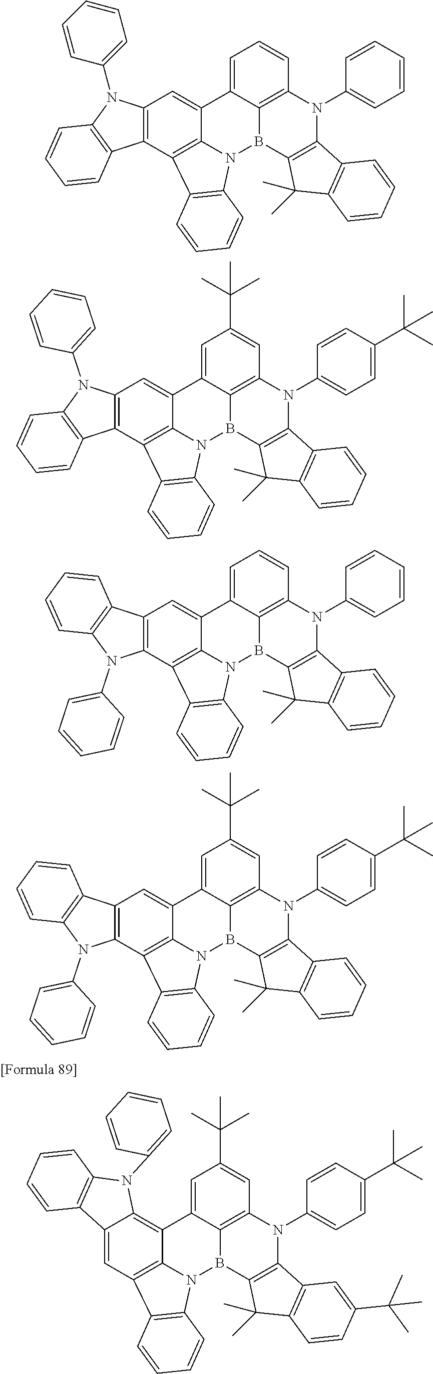

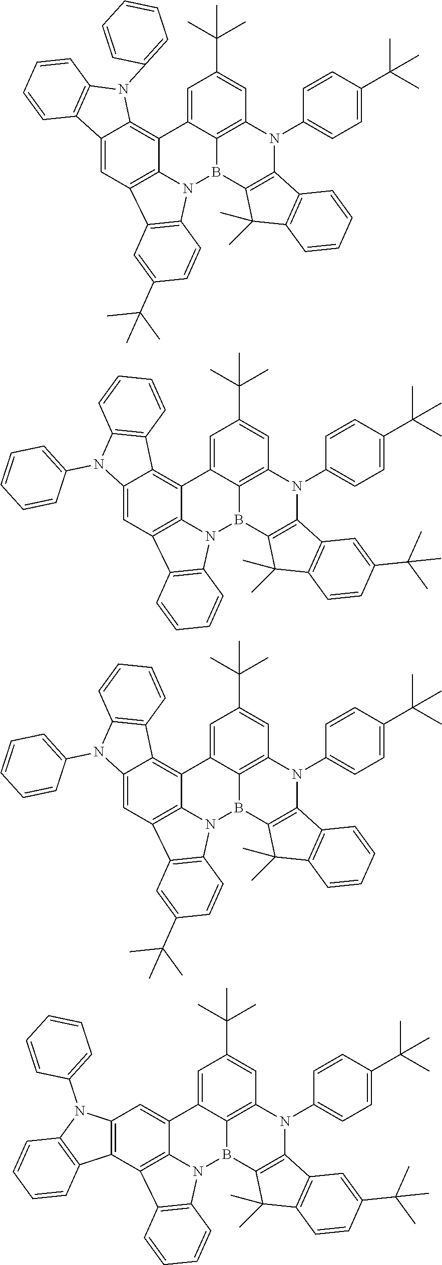

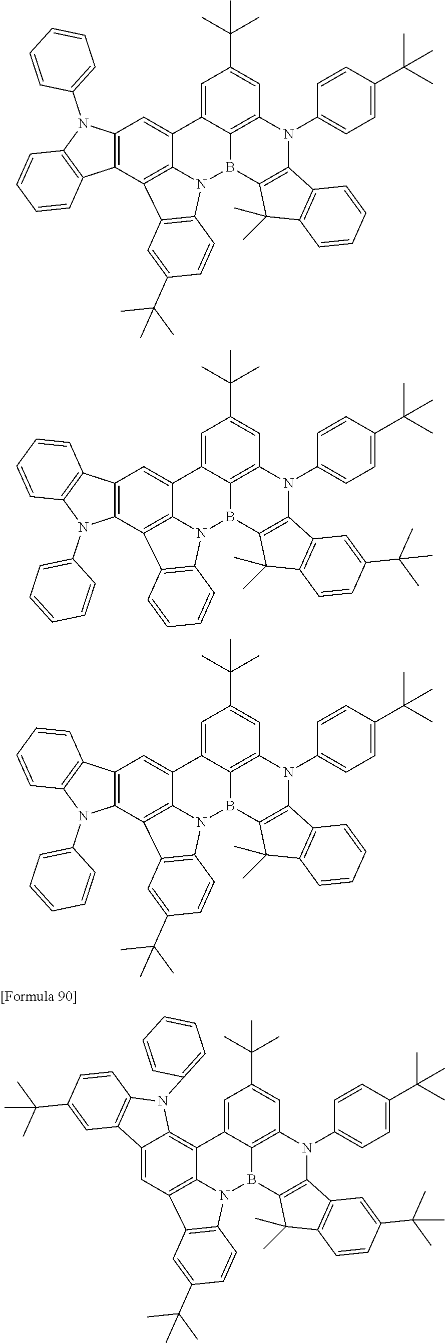

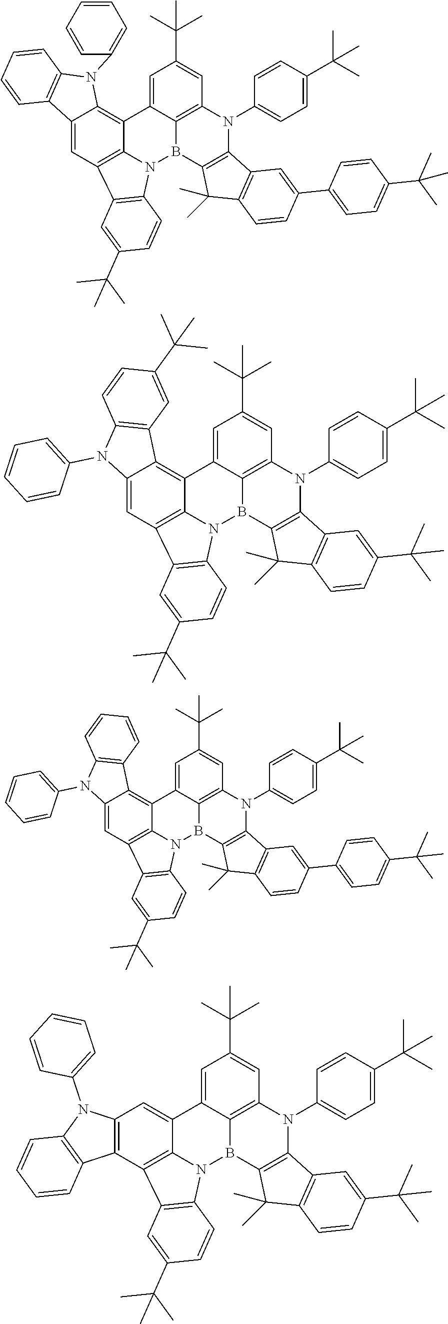

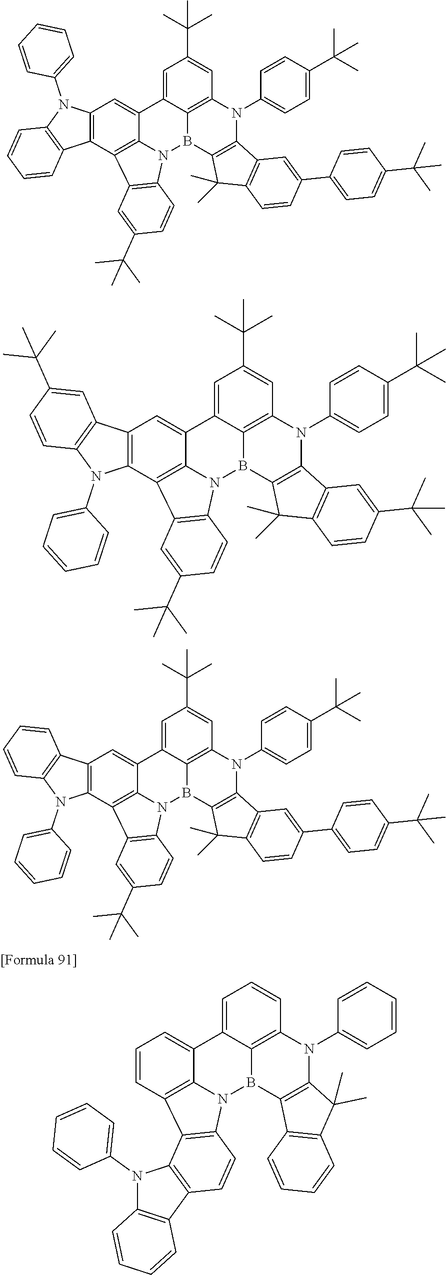

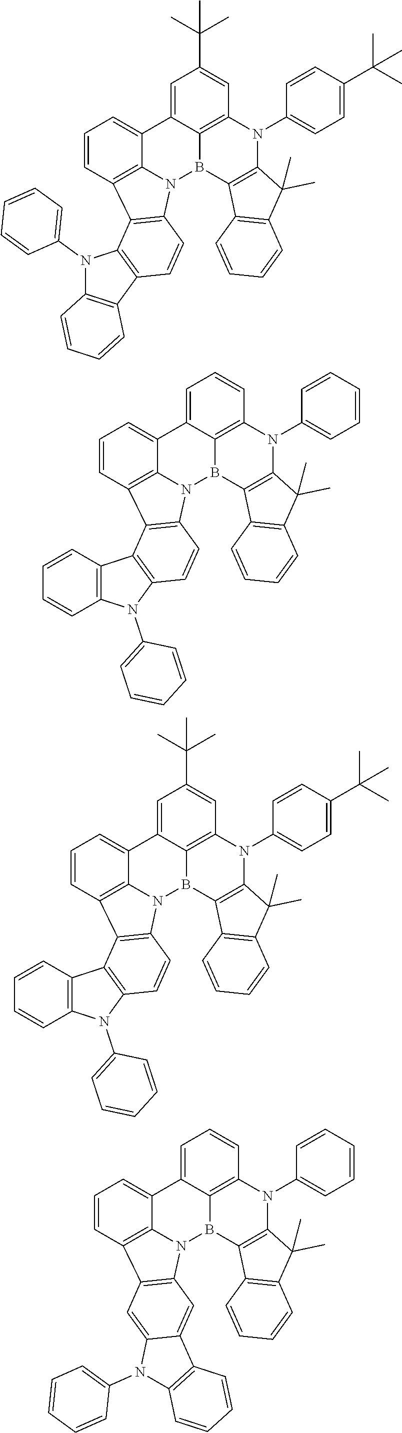

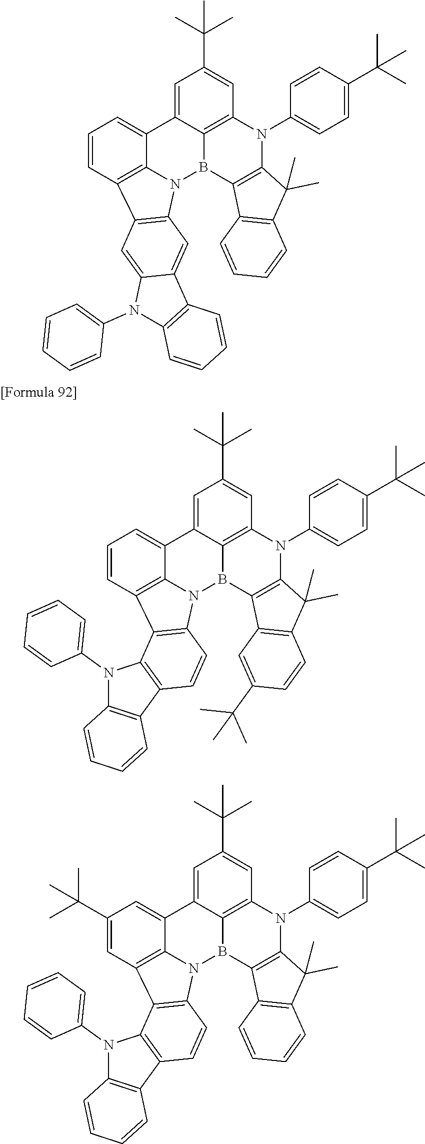

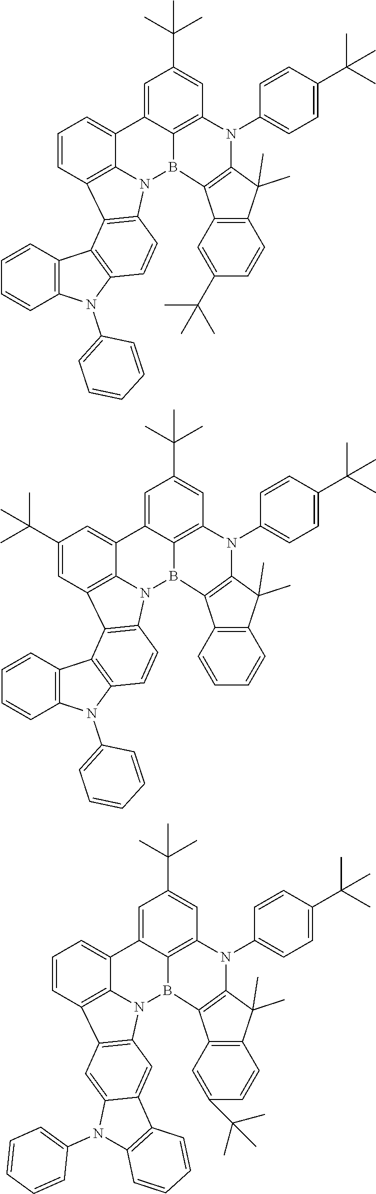

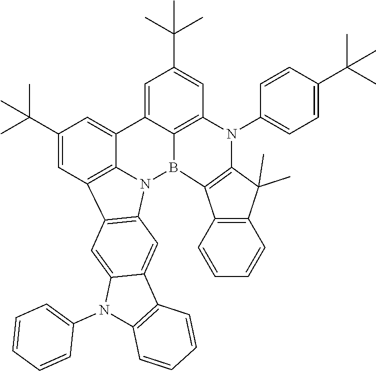 [SMILES: CC(C)(C)c1ccc(N2C3=C(B4c5c(cc(C(C)(C)C)cc52)-c2cc(C(C)(C)C)cc5c6cc7c(cc6n4c25)c2ccccc2n7-c2ccccc2)c2ccccc2C3(C)C)cc1]

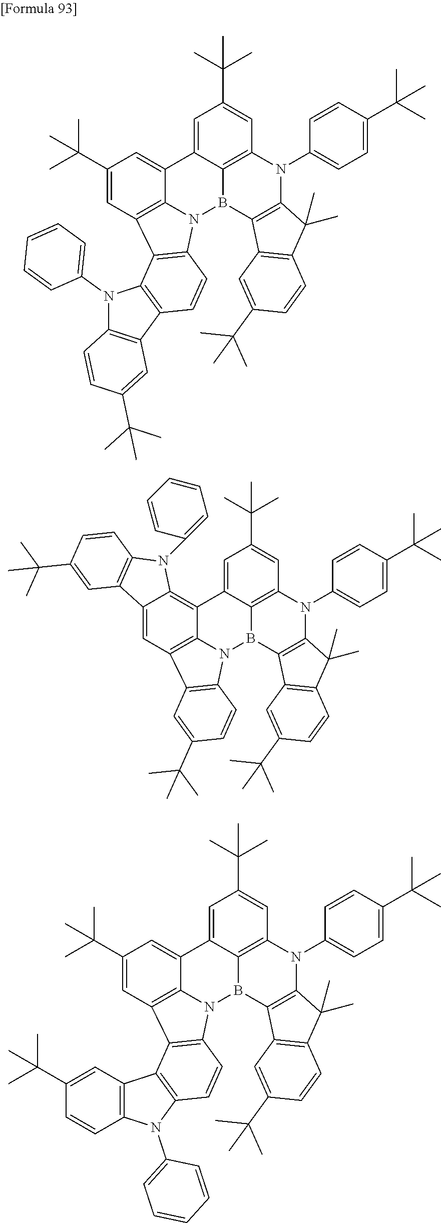

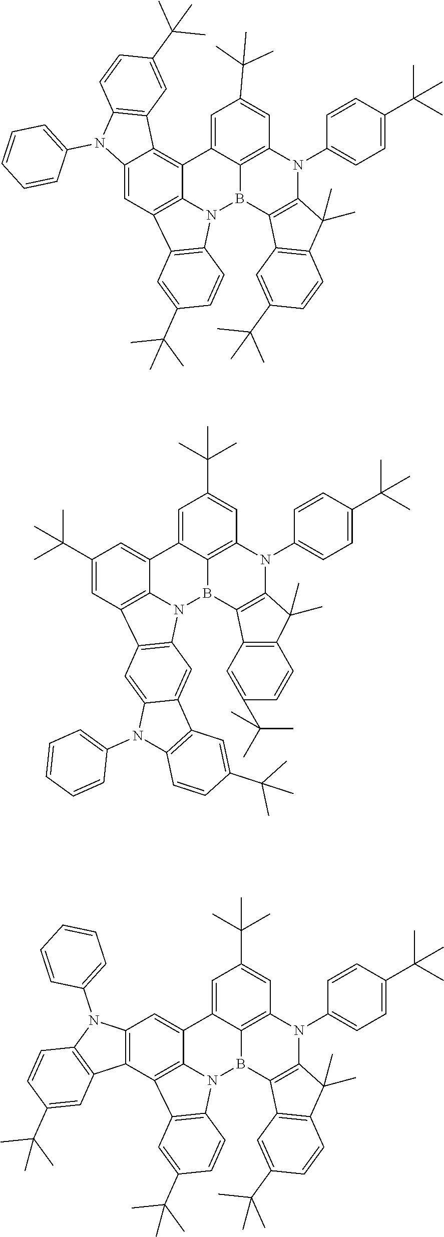

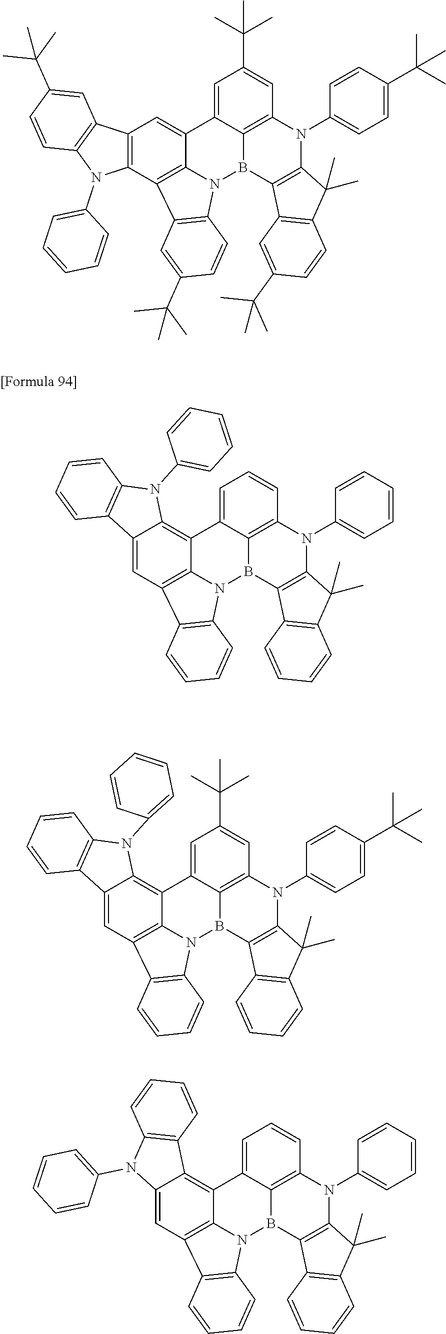

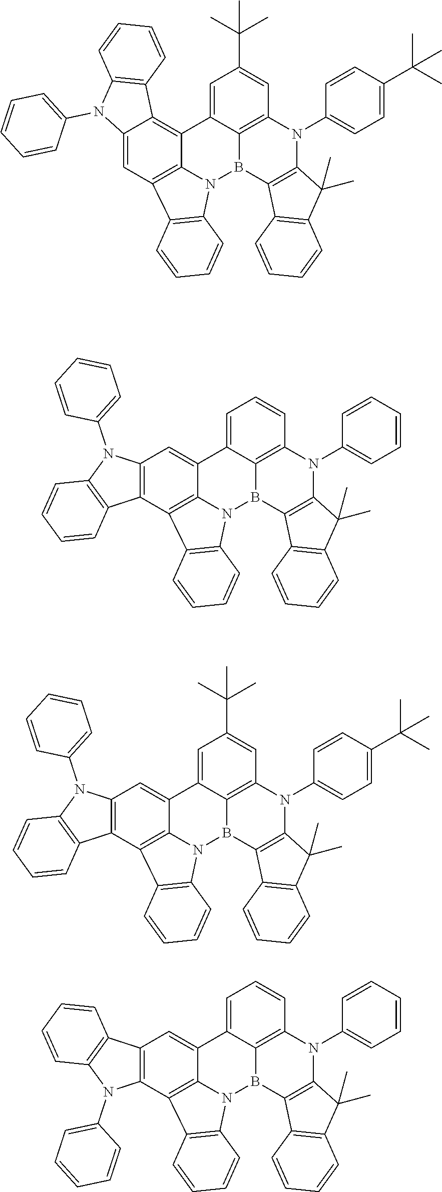

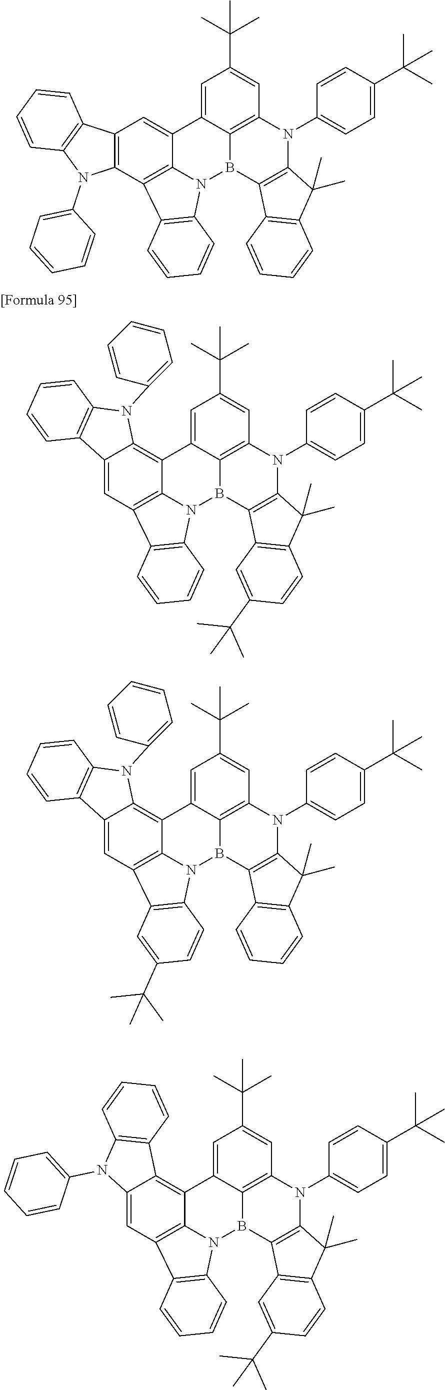

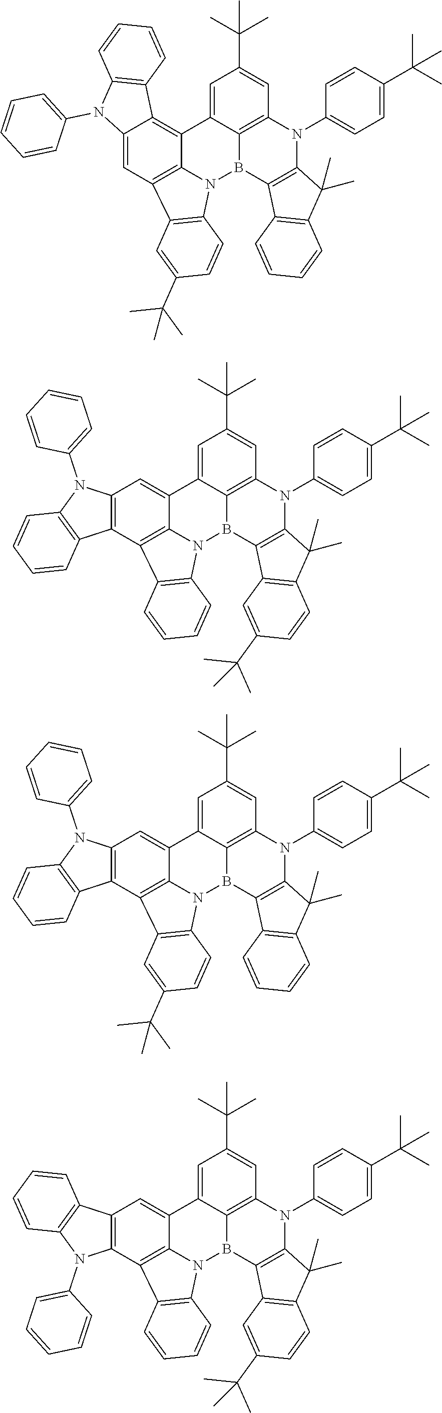

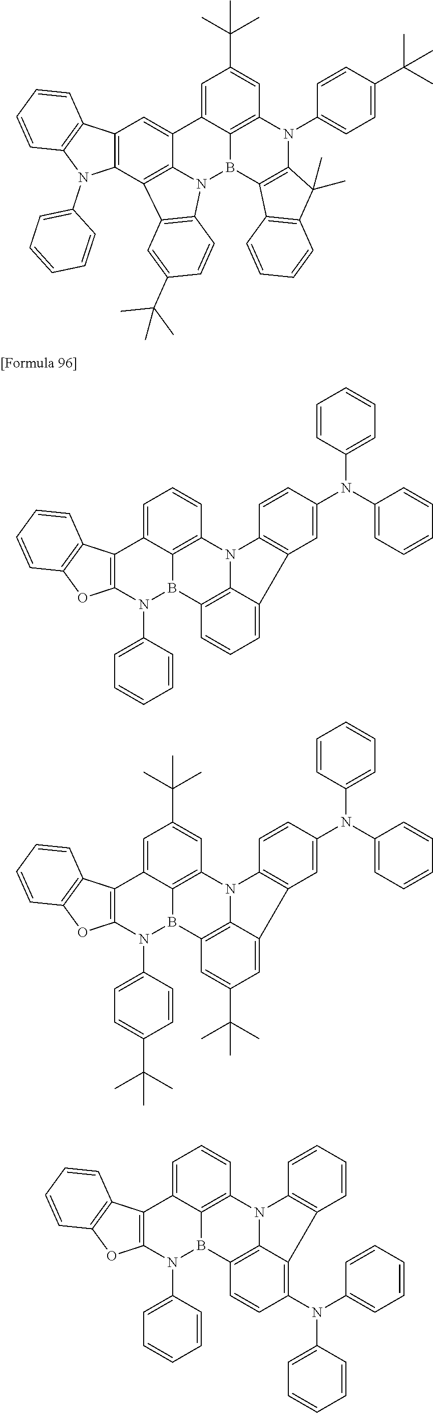 [SMILES: CC(C)(C)c1ccc(N2C3=C(B4c5c(cc(C(C)(C)C)cc52)-c2cc5c6ccccc6n(-c6ccccc6)c5c5c6cc(C(C)(C)C)ccc6n4c25)c2ccccc2C3(C)C)cc1 ; c1ccc(N2B3c4c(cccc4-n4c5ccc(N(c6ccccc6)c6ccccc6)cc5c5cccc3c54)-c3c2oc2ccccc32)cc1 ; CC(C)(C)c1ccc(N2B3c4c(cc(C(C)(C)C)cc4-n4c5ccc(N(c6ccccc6)c6ccccc6)cc5c5cc(C(C)(C)C)cc3c54)-c3c2oc2ccccc32)cc1 ; c1ccc(N2B3c4c(cccc4-n4c5ccccc5c5c(N(c6ccccc6)c6ccccc6)ccc3c54)-c3c2oc2ccccc32)cc1]

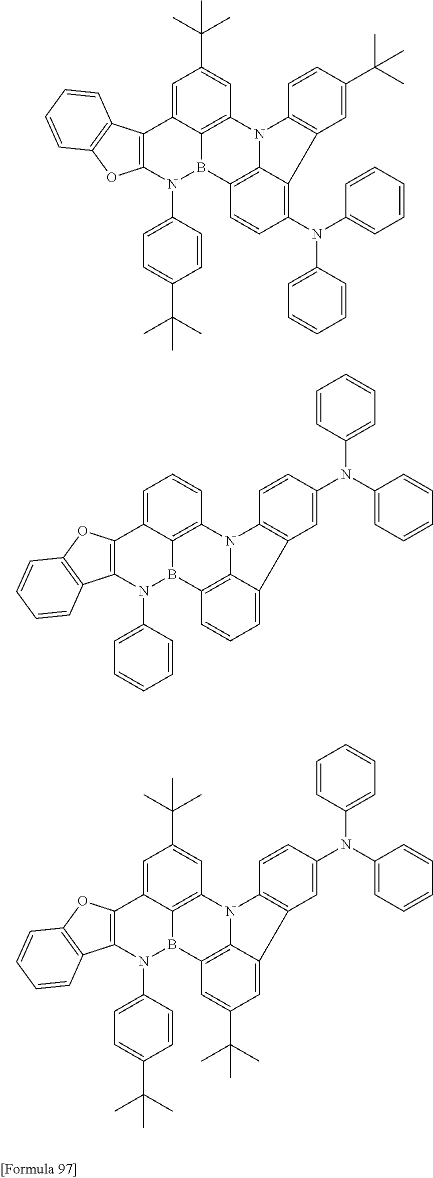 [SMILES: CC(C)(C)c1ccc(N2B3c4c(cc(C(C)(C)C)cc4-n4c5ccc(C(C)(C)C)cc5c5c(N(c6ccccc6)c6ccccc6)ccc3c54)-c3c2oc2ccccc32)cc1 ; c1ccc(N2B3c4c(cccc4-n4c5ccc(N(c6ccccc6)c6ccccc6)cc5c5cccc3c54)-c3oc4ccccc4c32)cc1 ; CC(C)(C)c1ccc(N2B3c4c(cc(C(C)(C)C)cc4-n4c5ccc(N(c6ccccc6)c6ccccc6)cc5c5cc(C(C)(C)C)cc3c54)-c3oc4ccccc4c32)cc1]

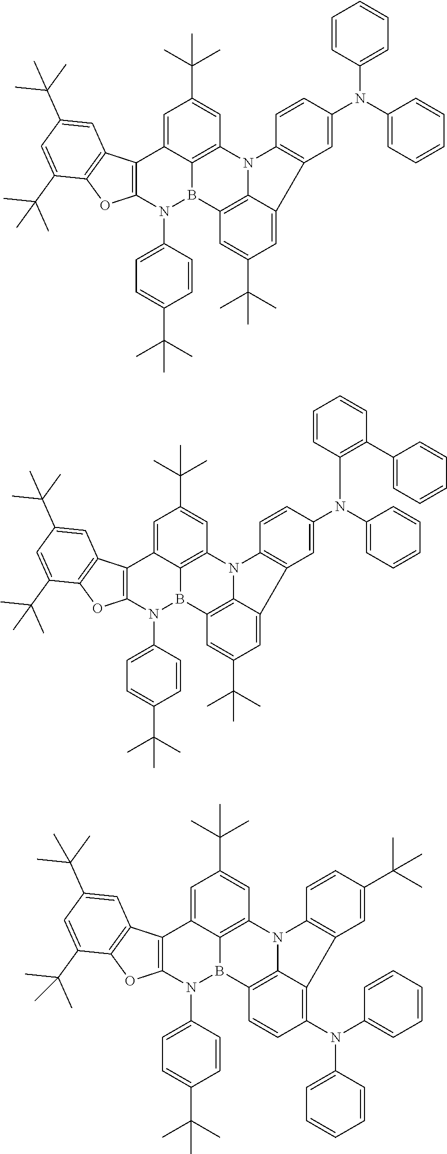 [SMILES: CC(C)(C)c1ccc(N2B3c4c(cc(C(C)(C)C)cc4-n4c5ccc(N(c6ccccc6)c6ccccc6)cc5c5cc(C(C)(C)C)cc3c54)-c3c2oc2c(C(C)(C)C)cc(C(C)(C)C)cc32)cc1 ; CC(C)(C)c1ccc(N2B3c4c(cc(C(C)(C)C)cc4-n4c5ccc(N(c6ccccc6)c6ccccc6-c6ccccc6)cc5c5cc(C(C)(C)C)cc3c54)-c3c2oc2c(C(C)(C)C)cc(C(C)(C)C)cc32)cc1 ; CC(C)(C)c1ccc(N2B3c4c(cc(C(C)(C)C)cc4-n4c5ccc(C(C)(C)C)cc5c5c(N(c6ccccc6)c6ccccc6)ccc3c54)-c3c2oc2c(C(C)(C)C)cc(C(C)(C)C)cc32)cc1]

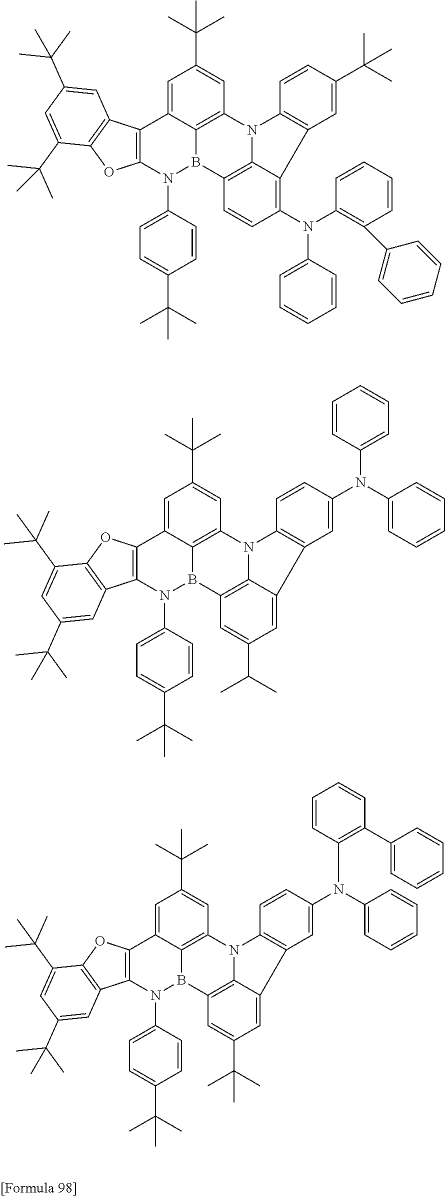 [SMILES: CC(C)(C)c1ccc(N2B3c4c(cc(C(C)(C)C)cc4-n4c5ccc(C(C)(C)C)cc5c5c(N(c6ccccc6)c6ccccc6-c6ccccc6)ccc3c54)-c3c2oc2c(C(C)(C)C)cc(C(C)(C)C)cc32)cc1 ; CC(C)c1cc2c3c(c1)c1cc(N(c4ccccc4)c4ccccc4)ccc1n3-c1cc(C(C)(C)C)cc3c1B2N(c1ccc(C(C)(C)C)cc1)c1c-3oc2c(C(C)(C)C)cc(C(C)(C)C)cc12 ; CC(C)(C)c1ccc(N2B3c4c(cc(C(C)(C)C)cc4-n4c5ccc(N(c6ccccc6)c6ccccc6-c6ccccc6)cc5c5cc(C(C)(C)C)cc3c54)-c3oc4c(C(C)(C)C)cc(C(C)(C)C)cc4c32)cc1]

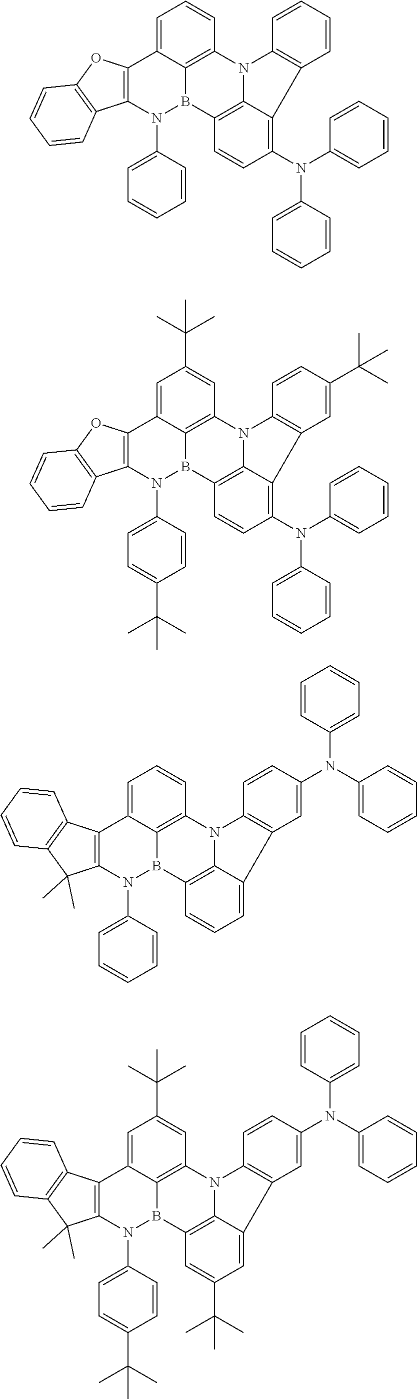

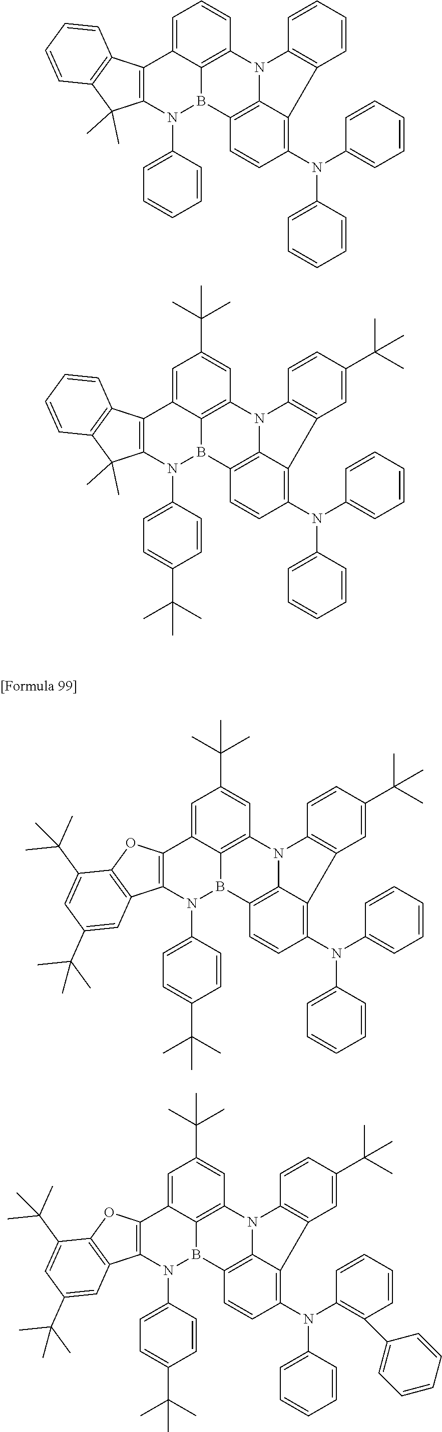

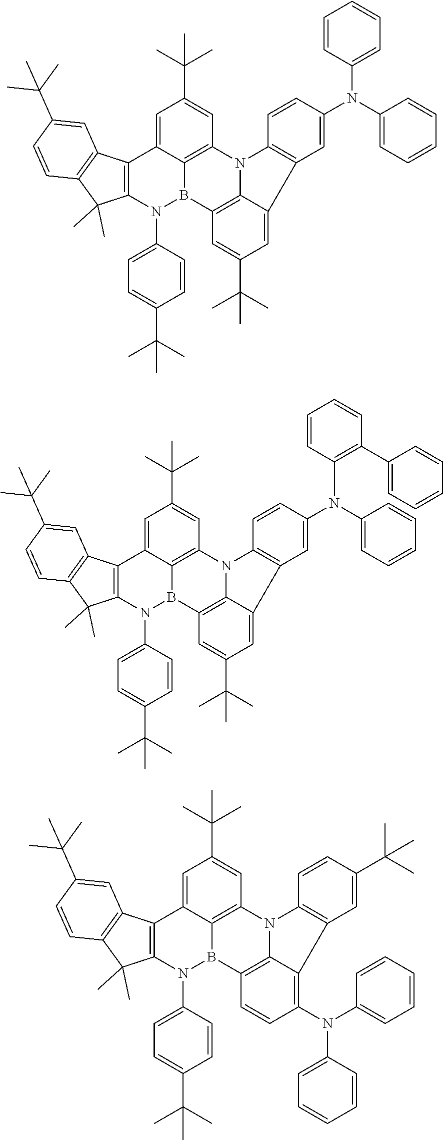 [SMILES: CC(C)(C)c1ccc(N2B3c4c(cc(C(C)(C)C)cc4-n4c5ccc(N(c6ccccc6)c6ccccc6)cc5c5cc(C(C)(C)C)cc3c54)C3=C2C(C)(C)c2ccc(C(C)(C)C)cc23)cc1 ; CC(C)(C)c1ccc(N2B3c4c(cc(C(C)(C)C)cc4-n4c5ccc(N(c6ccccc6)c6ccccc6-c6ccccc6)cc5c5cc(C(C)(C)C)cc3c54)C3=C2C(C)(C)c2ccc(C(C)(C)C)cc23)cc1 ; CC(C)(C)c1ccc(N2B3c4c(cc(C(C)(C)C)cc4-n4c5ccc(C(C)(C)C)cc5c5c(N(c6ccccc6)c6ccccc6)ccc3c54)C3=C2C(C)(C)c2ccc(C(C)(C)C)cc23)cc1]

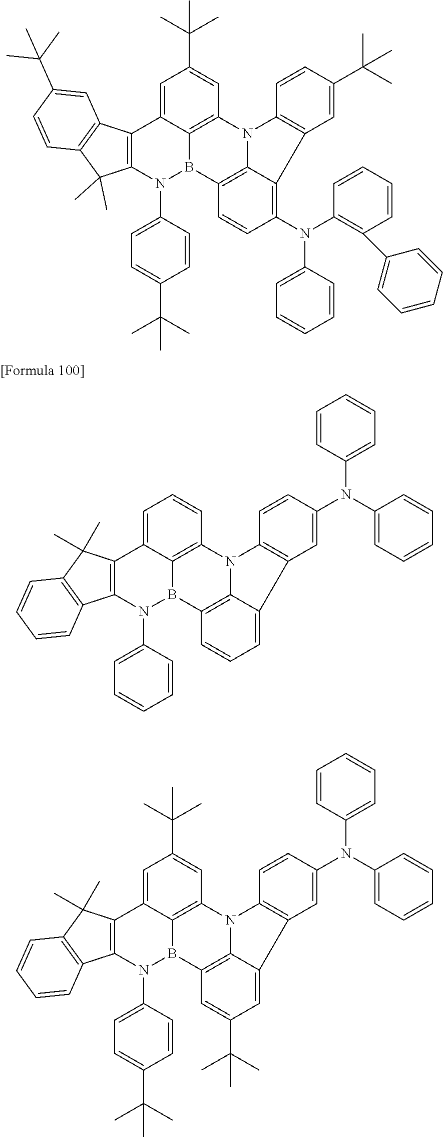 [SMILES: CC(C)(C)c1ccc(N2B3c4c(cc(C(C)(C)C)cc4-n4c5ccc(C(C)(C)C)cc5c5c(N(c6ccccc6)c6ccccc6-c6ccccc6)ccc3c54)C3=C2C(C)(C)c2ccc(C(C)(C)C)cc23)cc1 ; CC1(C)C2=C(c3ccccc31)N(c1ccccc1)B1c3c2cccc3-n2c3ccc(N(c4ccccc4)c4ccccc4)cc3c3cccc1c32 ; CC(C)(C)c1ccc(N2B3c4c(cc(C(C)(C)C)cc4-n4c5ccc(N(c6ccccc6)c6ccccc6)cc5c5cc(C(C)(C)C)cc3c54)C3=C2c2ccccc2C3(C)C)cc1]

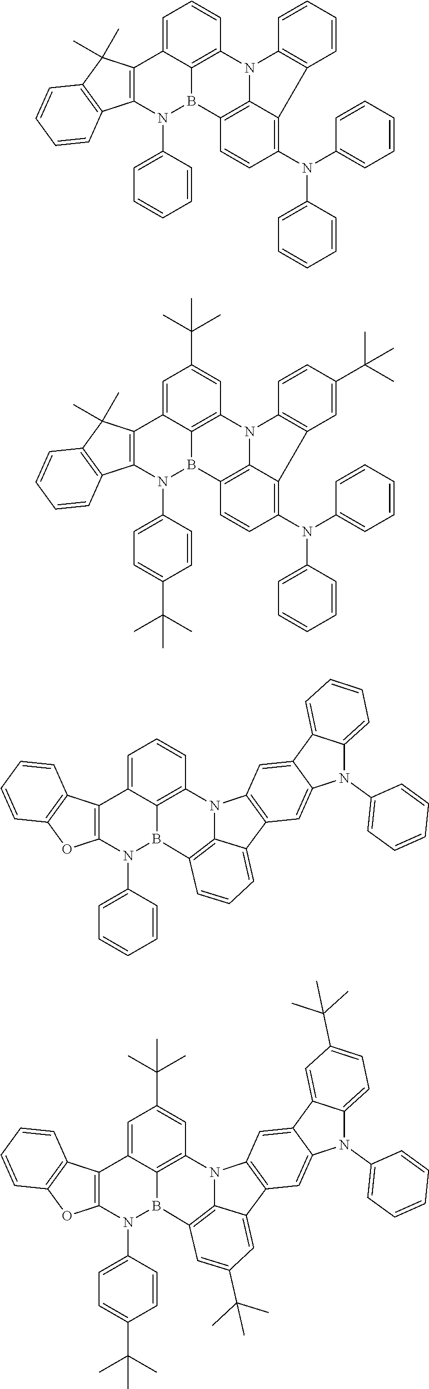 [SMILES: CC1(C)C2=C(c3ccccc31)N(c1ccccc1)B1c3c2cccc3-n2c3ccccc3c3c(N(c4ccccc4)c4ccccc4)ccc1c32 ; CC(C)(C)c1ccc(N2B3c4c(cc(C(C)(C)C)cc4-n4c5ccc(C(C)(C)C)cc5c5c(N(c6ccccc6)c6ccccc6)ccc3c54)C3=C2c2ccccc2C3(C)C)cc1 ; c1ccc(N2B3c4c(cccc4-n4c5cc6c7ccccc7n(-c7ccccc7)c6cc5c5cccc3c54)-c3c2oc2ccccc32)cc1 ; CC(C)(C)c1ccc(N2B3c4c(cc(C(C)(C)C)cc4-n4c5cc6c7cc(C(C)(C)C)ccc7n(-c7ccccc7)c6cc5c5cc(C(C)(C)C)cc3c54)-c3c2oc2ccccc32)cc1]

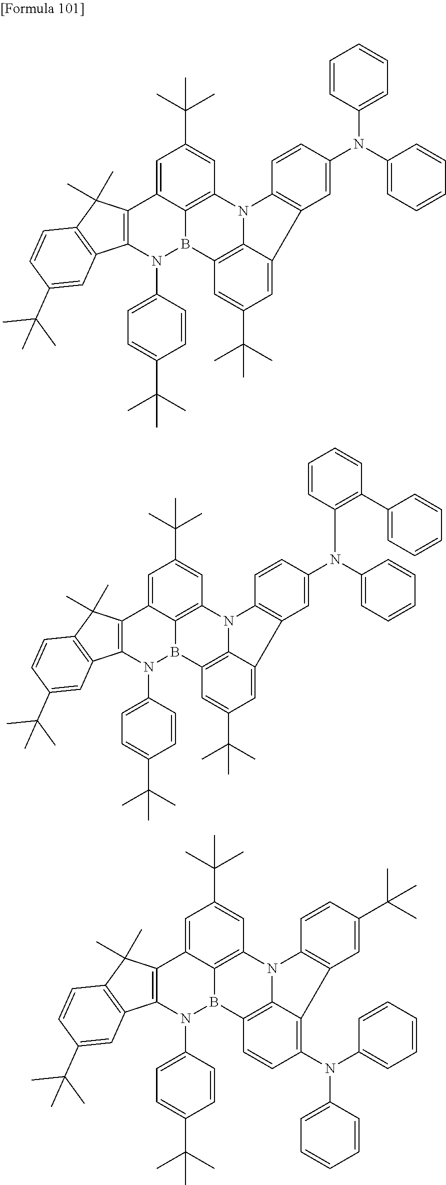 [SMILES: CC(C)(C)c1ccc(N2B3c4c(cc(C(C)(C)C)cc4-n4c5ccc(N(c6ccccc6)c6ccccc6)cc5c5cc(C(C)(C)C)cc3c54)C3=C2c2cc(C(C)(C)C)ccc2C3(C)C)cc1 ; CC(C)(C)c1ccc(N2B3c4c(cc(C(C)(C)C)cc4-n4c5ccc(N(c6ccccc6)c6ccccc6-c6ccccc6)cc5c5cc(C(C)(C)C)cc3c54)C3=C2c2cc(C(C)(C)C)ccc2C3(C)C)cc1 ; CC(C)(C)c1ccc(N2B3c4c(cc(C(C)(C)C)cc4-n4c5ccc(C(C)(C)C)cc5c5c(N(c6ccccc6)c6ccccc6)ccc3c54)C3=C2c2cc(C(C)(C)C)ccc2C3(C)C)cc1]

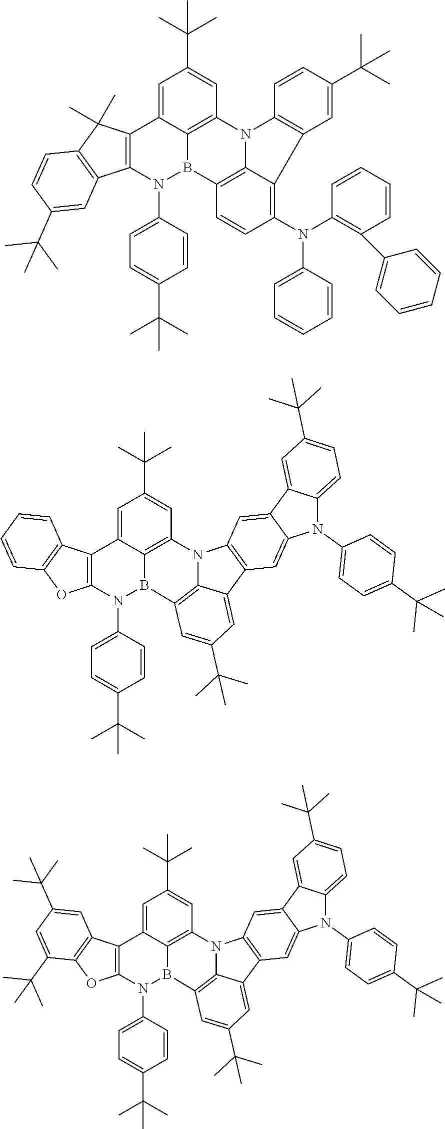

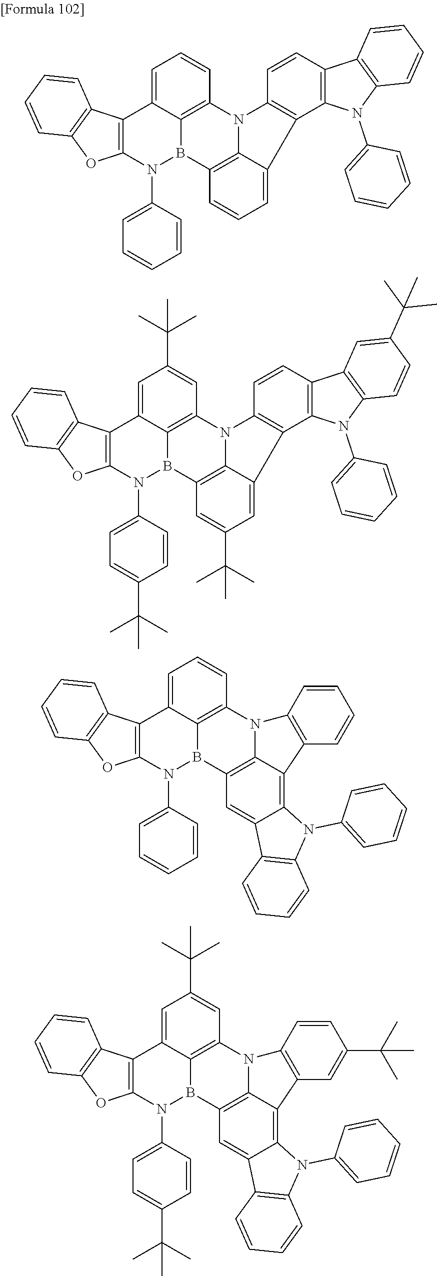

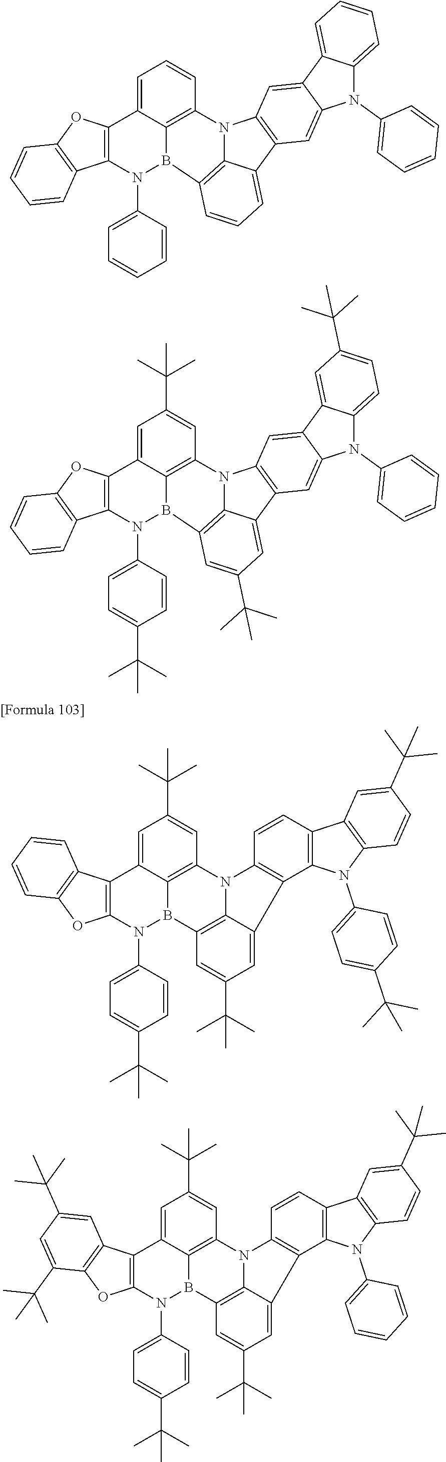

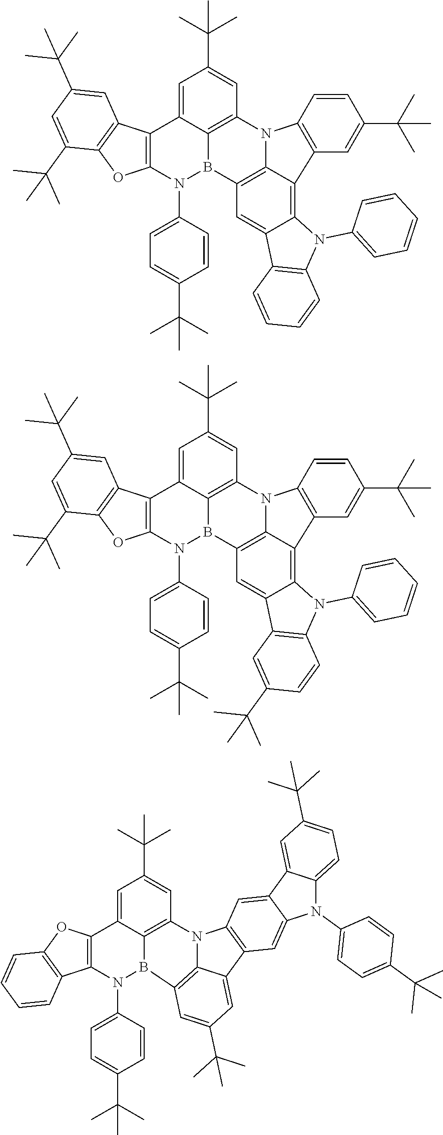

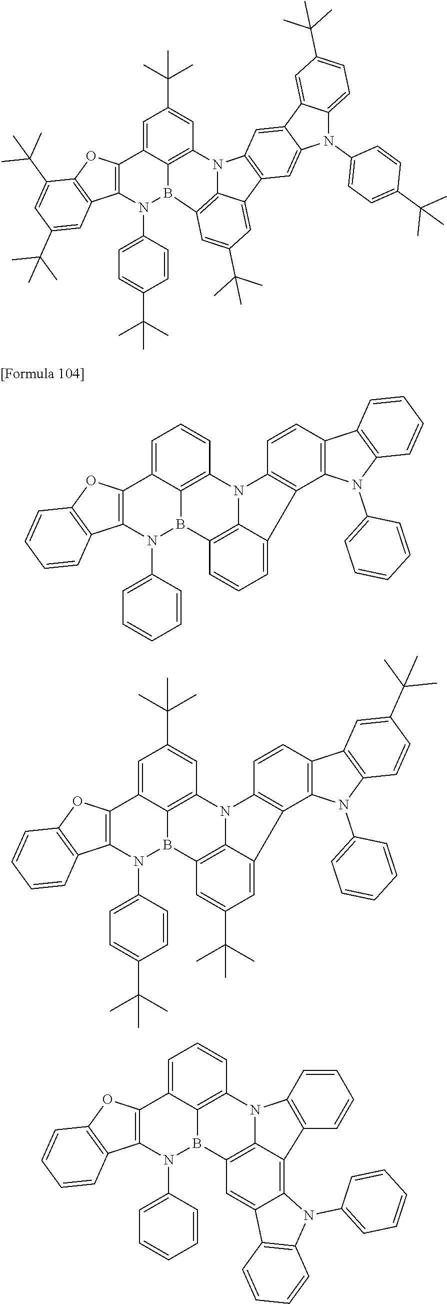

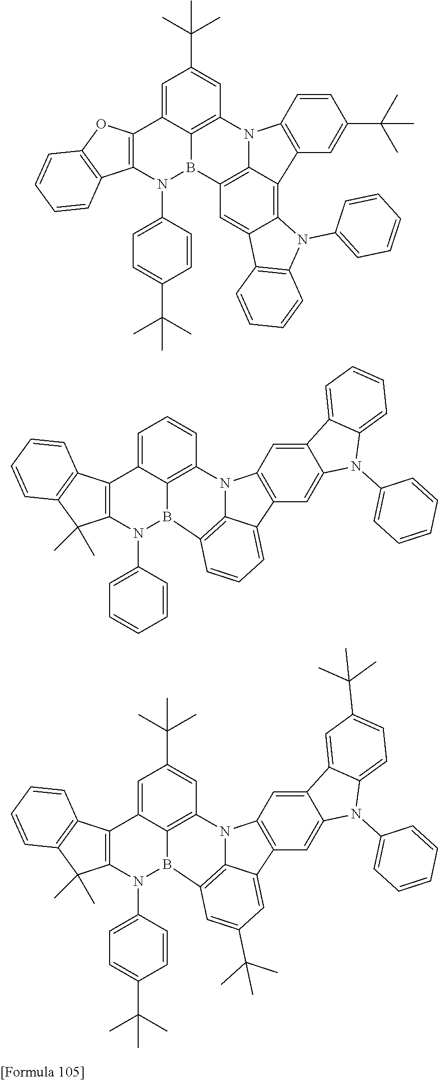 [SMILES: CC(C)(C)c1ccc(N2B3c4c(cc(C(C)(C)C)cc4-n4c5ccc(C(C)(C)C)cc5c5c4c3cc3c4ccccc4n(-c4ccccc4)c35)-c3oc4ccccc4c32)cc1 ; CC1(C)C2=C(c3ccccc31)c1cccc3c1B(c1cccc4c5cc6c(cc5n-3c14)c1ccccc1n6-c1ccccc1)N2c1ccccc1 ; CC(C)(C)c1ccc(N2B3c4c(cc(C(C)(C)C)cc4-n4c5cc6c7cc(C(C)(C)C)ccc7n(-c7ccccc7)c6cc5c5cc(C(C)(C)C)cc3c54)C3=C2C(C)(C)c2ccccc23)cc1]

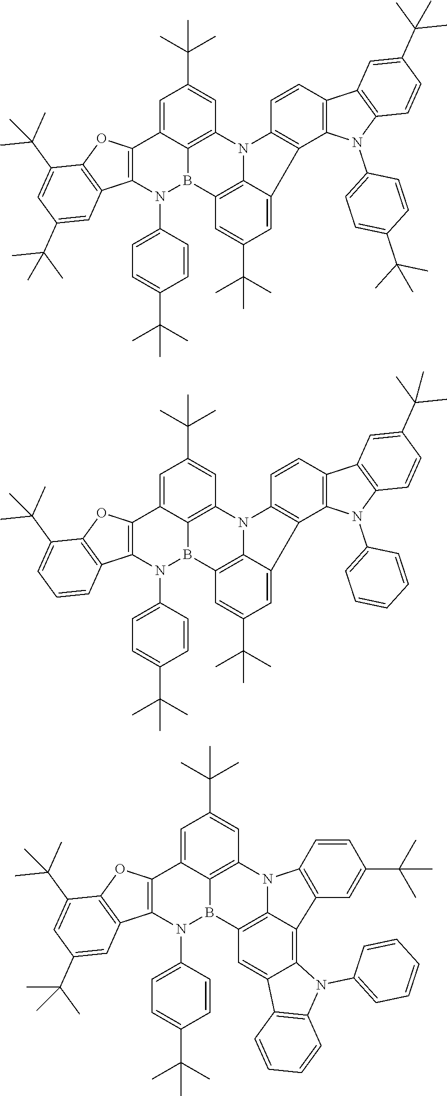

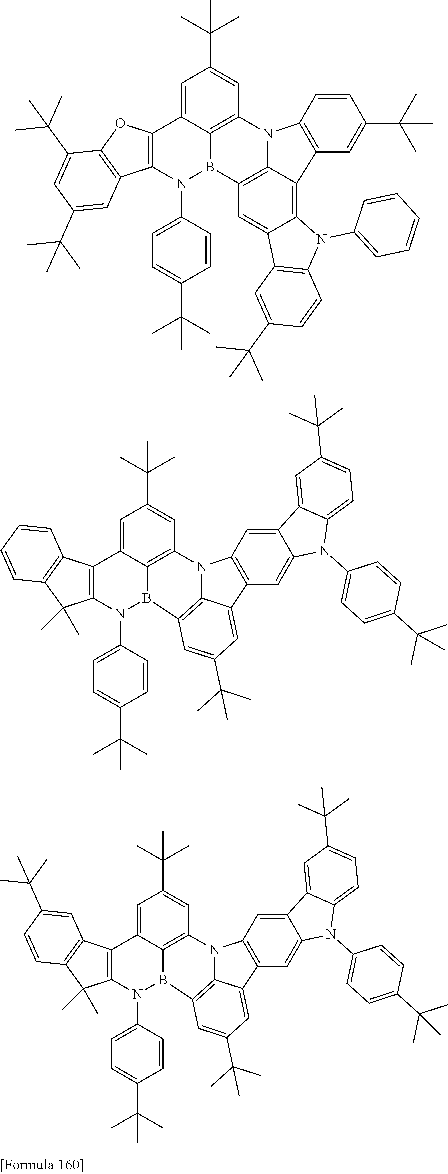

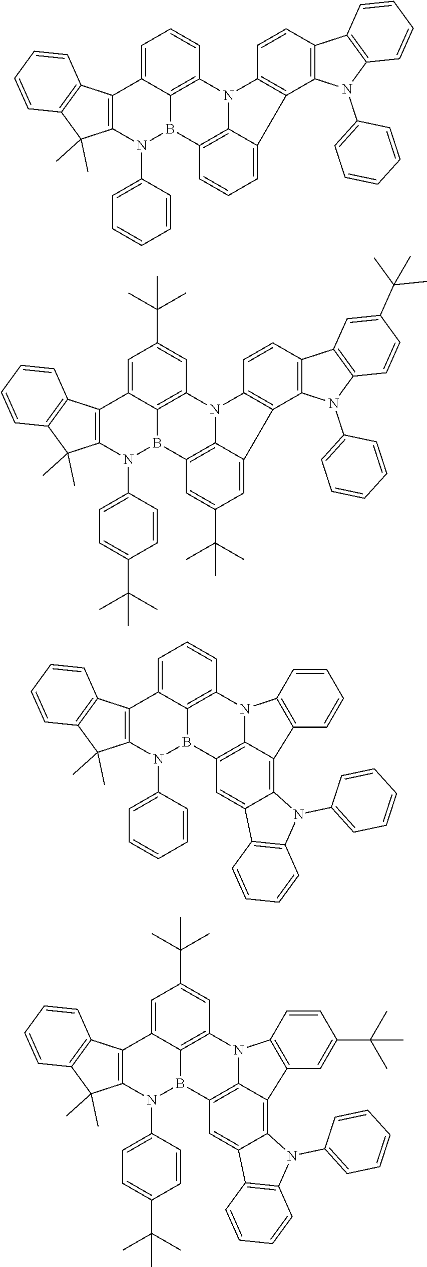

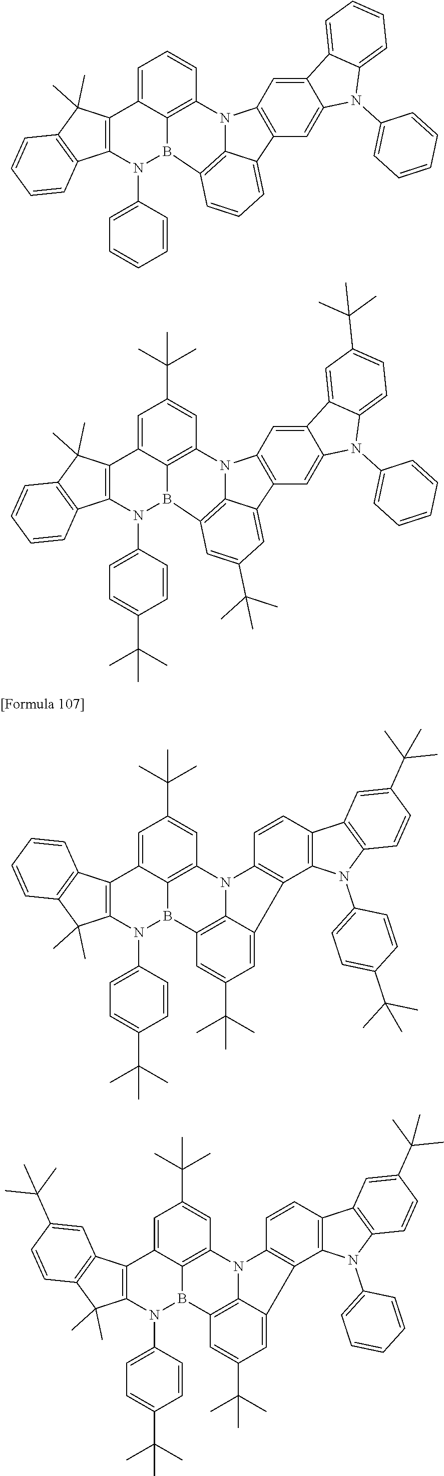

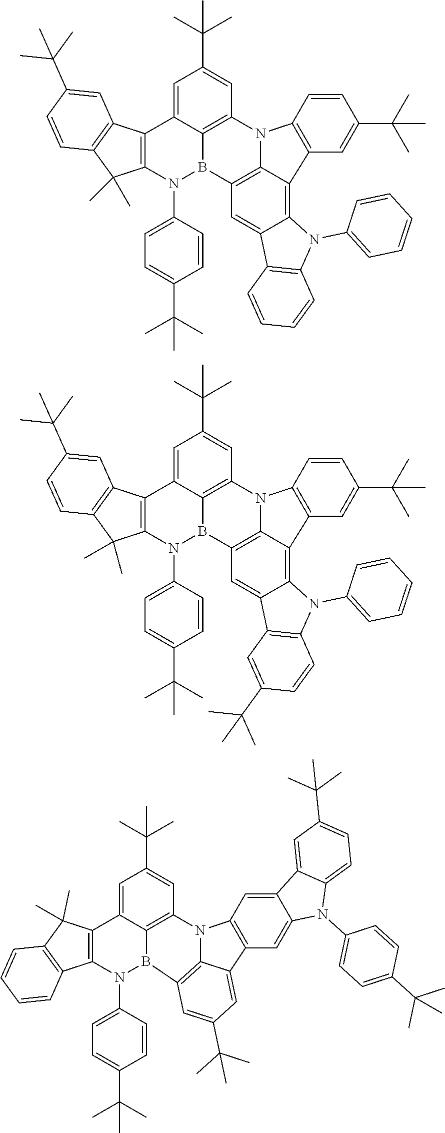

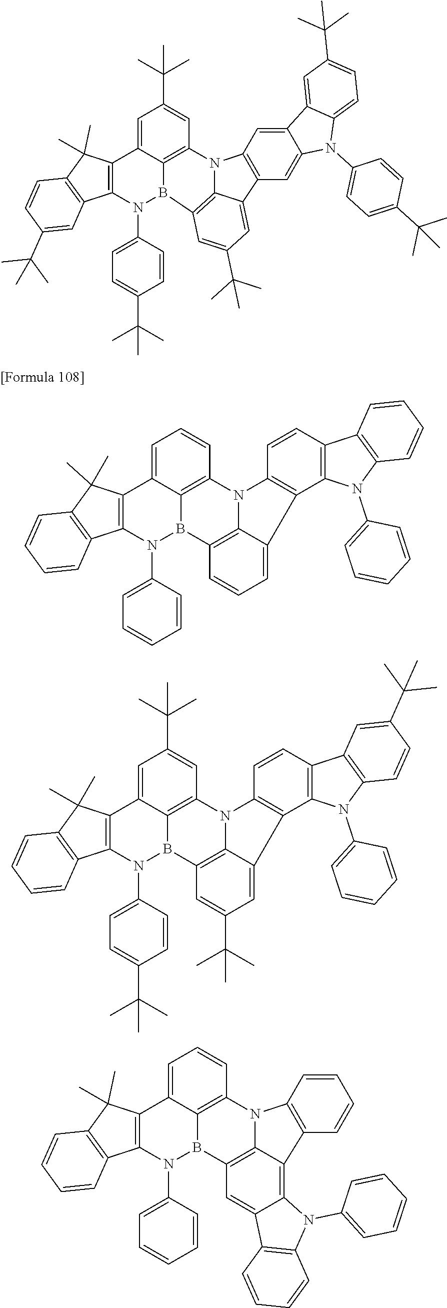

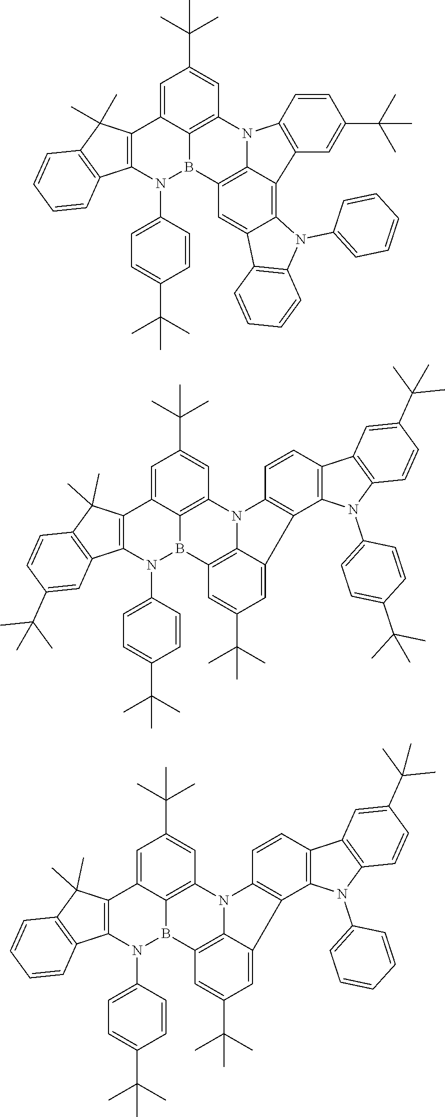

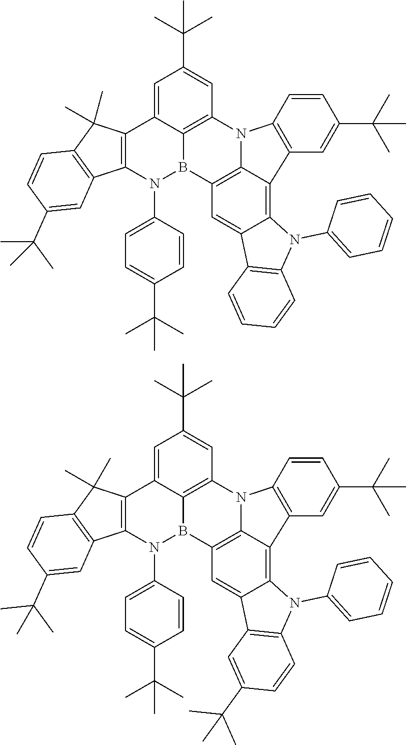

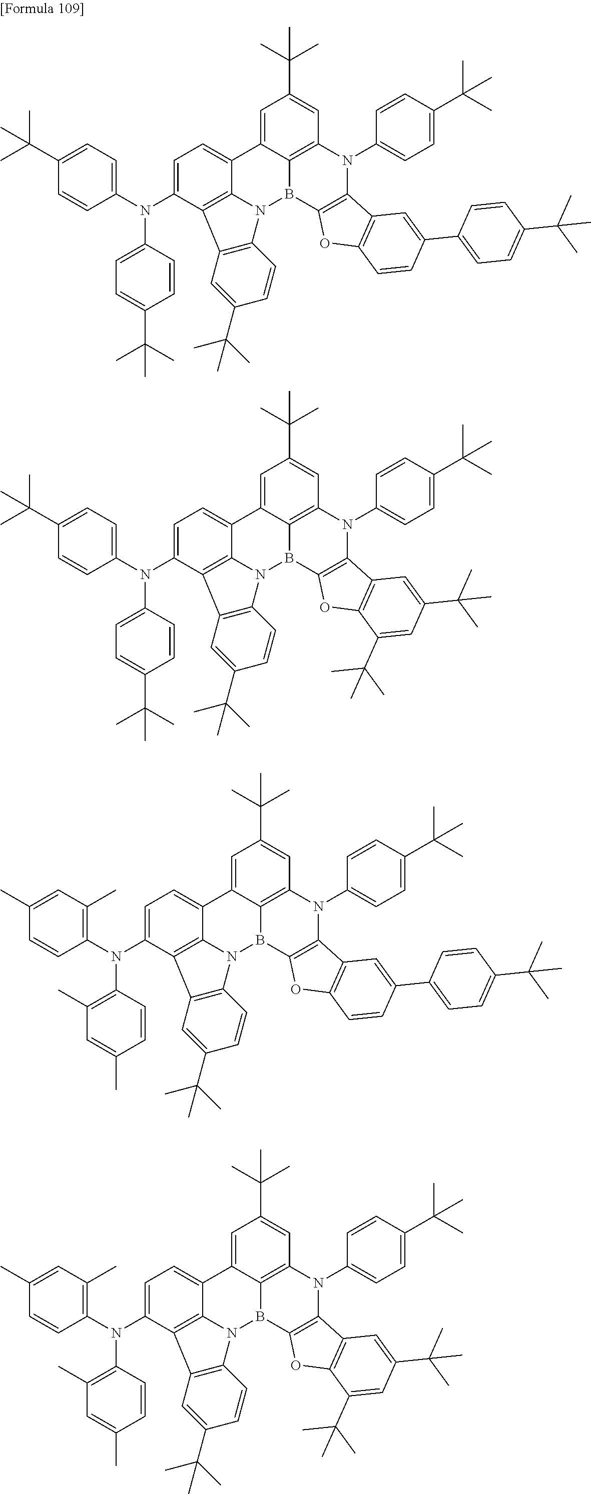

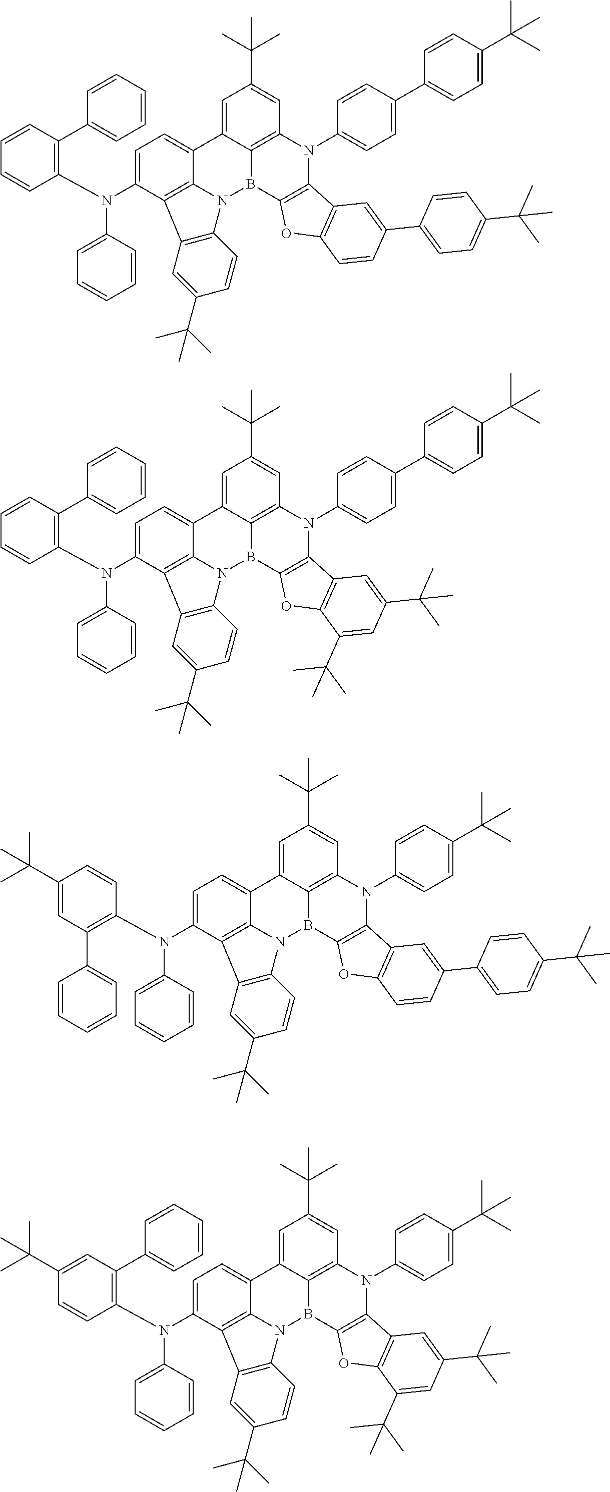

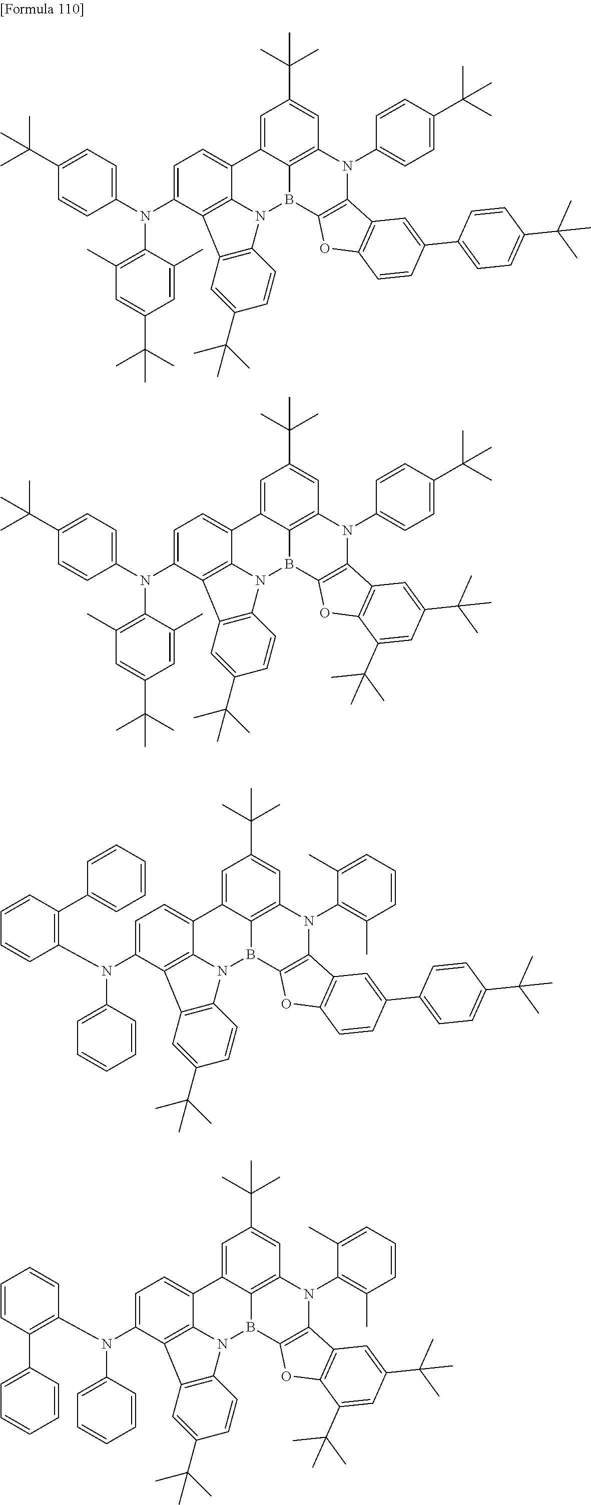

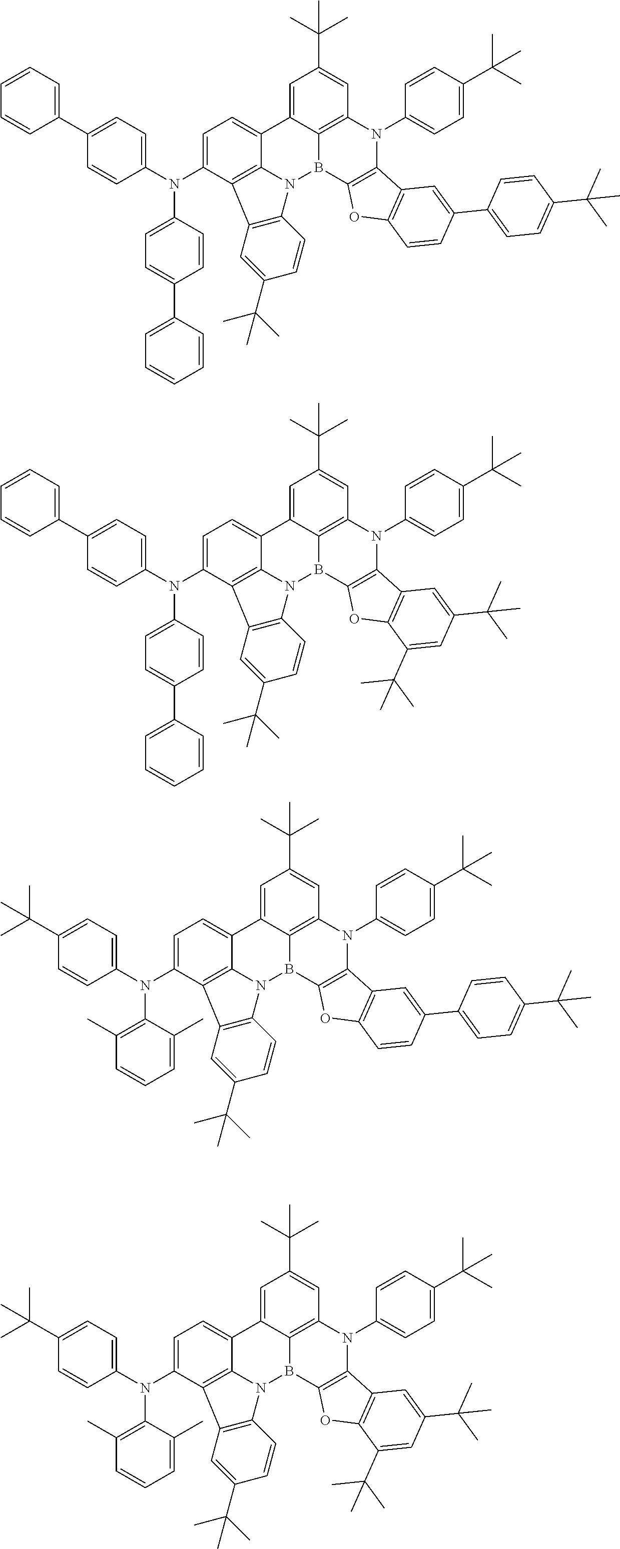

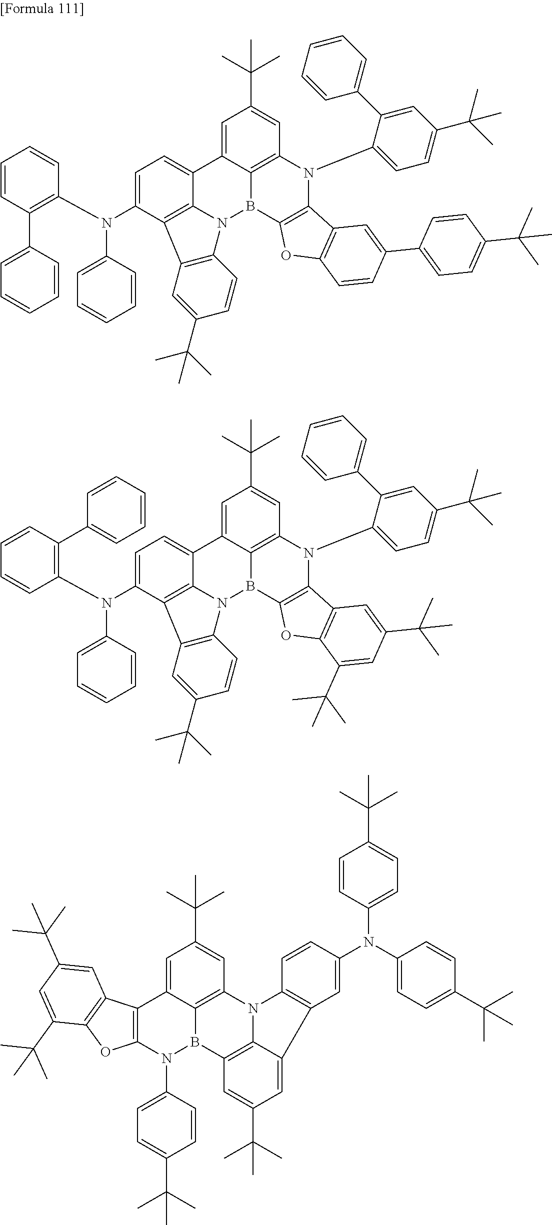

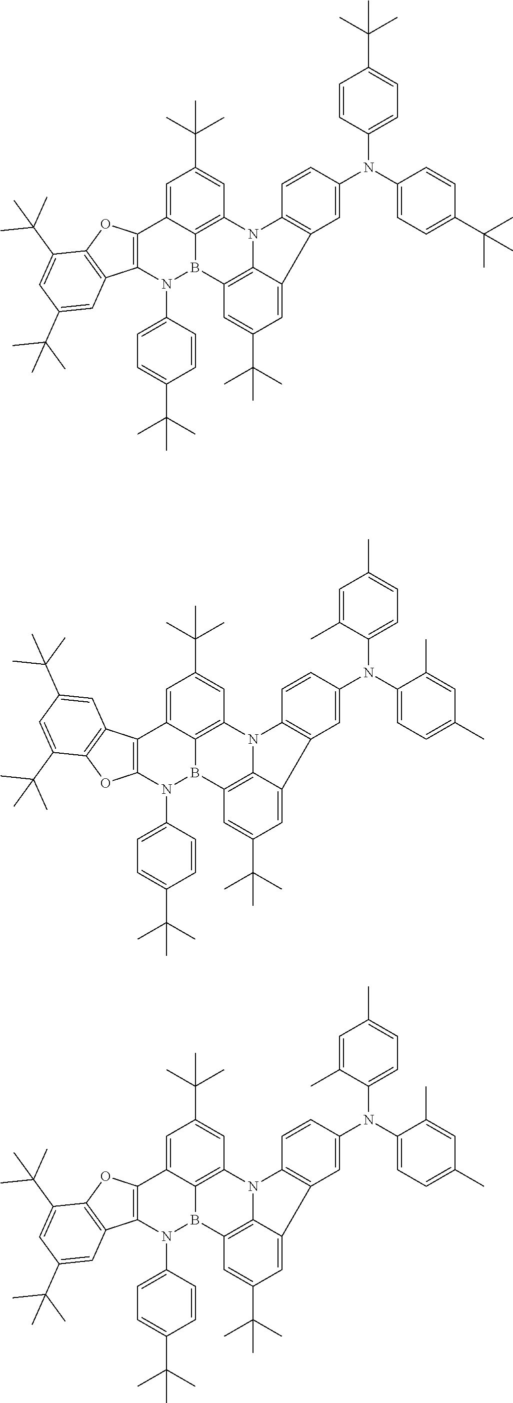

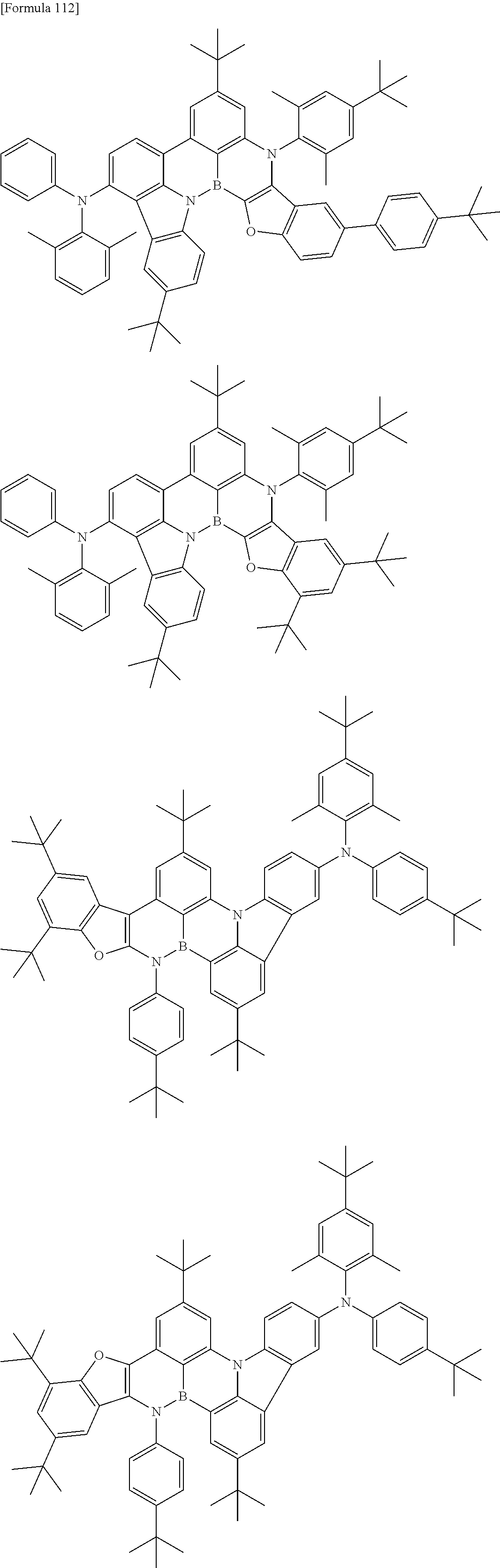

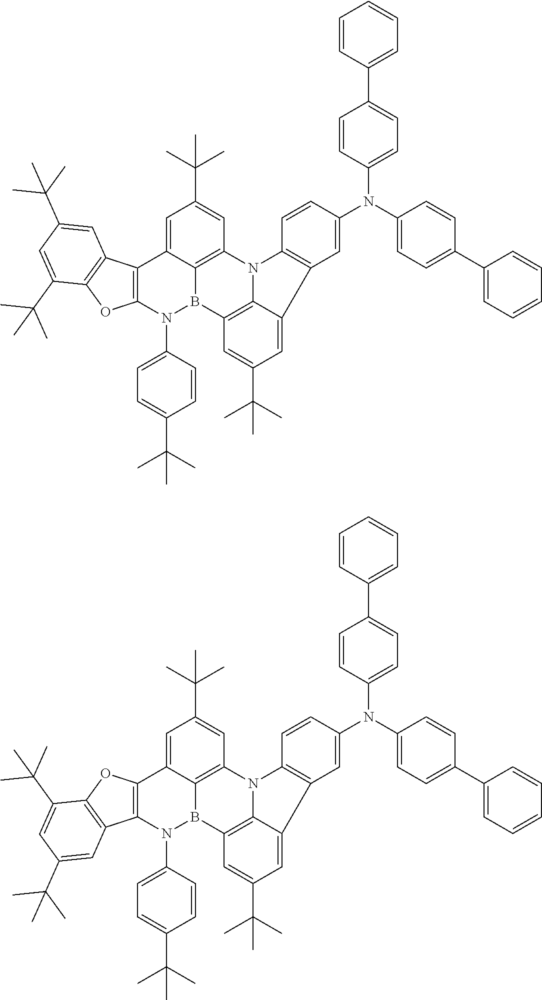 [SMILES: CC(C)(C)c1ccc(N2B3c4c(cc(C(C)(C)C)cc4-n4c5ccc(N(c6ccc(-c7ccccc7)cc6)c6ccc(-c7ccccc7)cc6)cc5c5cc(C(C)(C)C)cc3c54)-c3c2oc2c(C(C)(C)C)cc(C(C)(C)C)cc32)cc1 ; CC(C)(C)c1ccc(N2B3c4c(cc(C(C)(C)C)cc4-n4c5ccc(N(c6ccc(-c7ccccc7)cc6)c6ccc(-c7ccccc7)cc6)cc5c5cc(C(C)(C)C)cc3c54)-c3oc4c(C(C)(C)C)cc(C(C)(C)C)cc4c32)cc1]

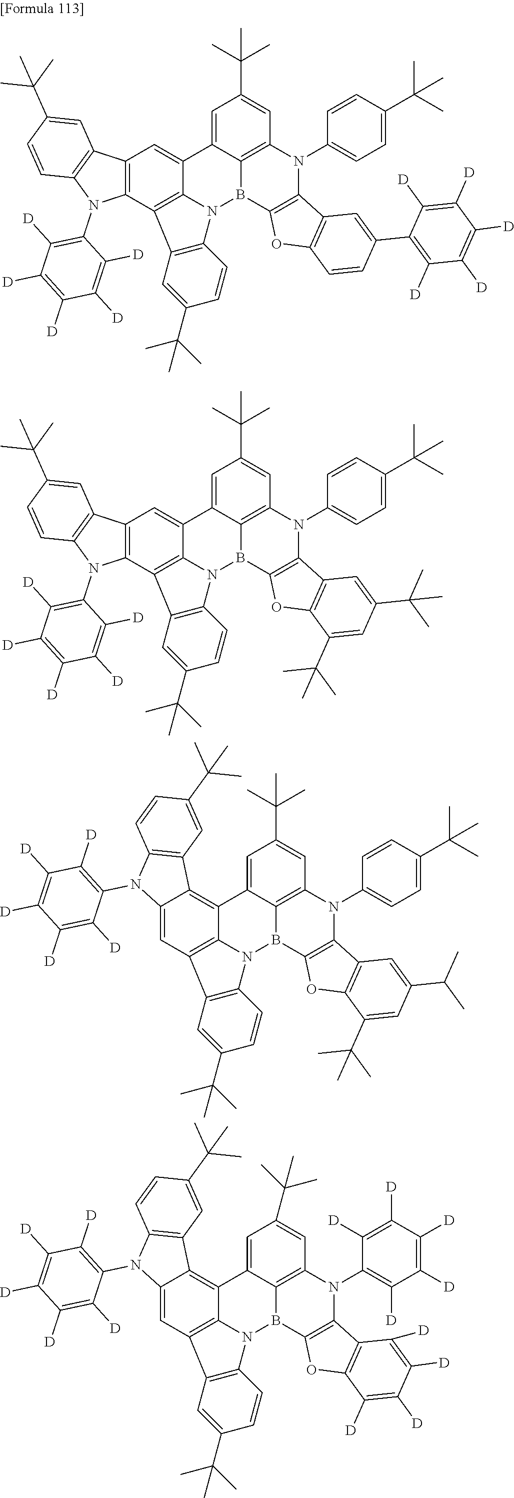

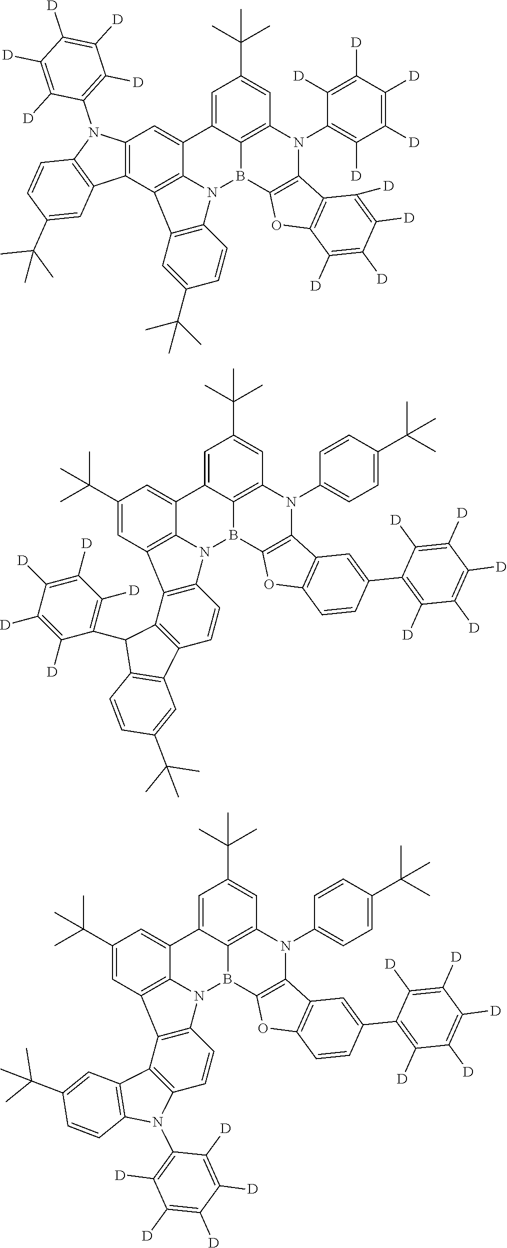

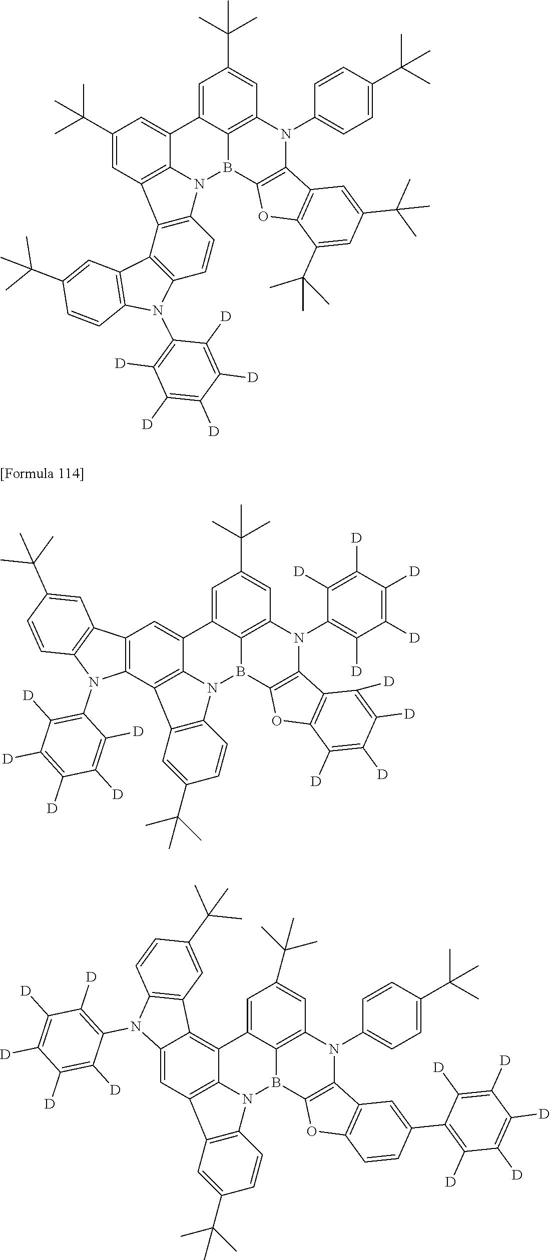

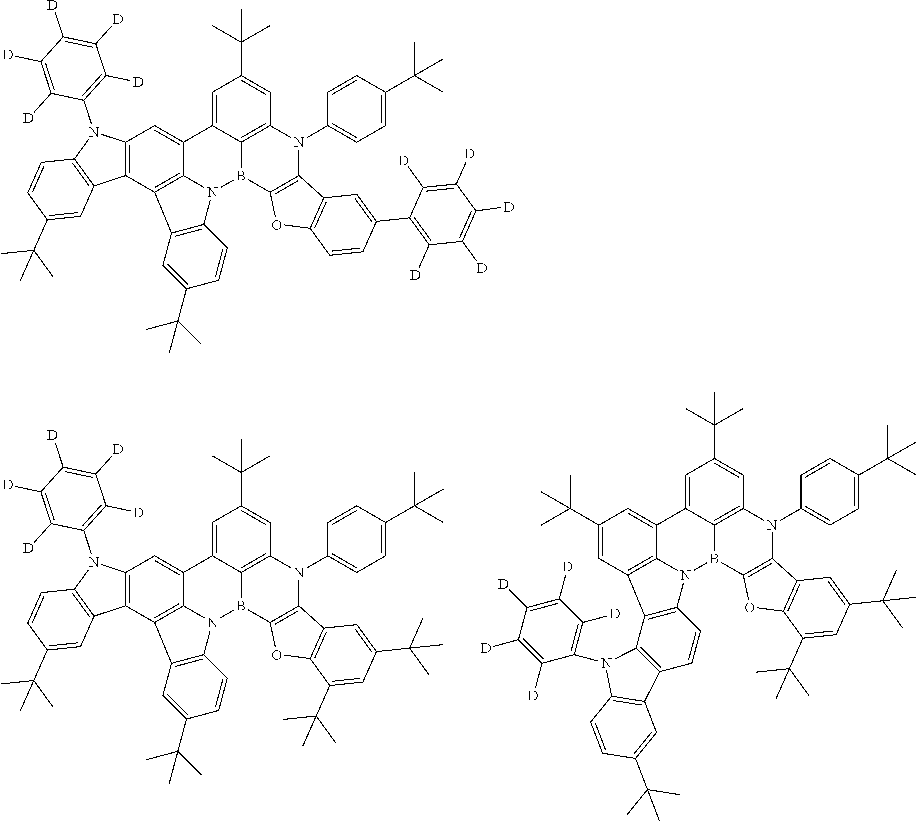

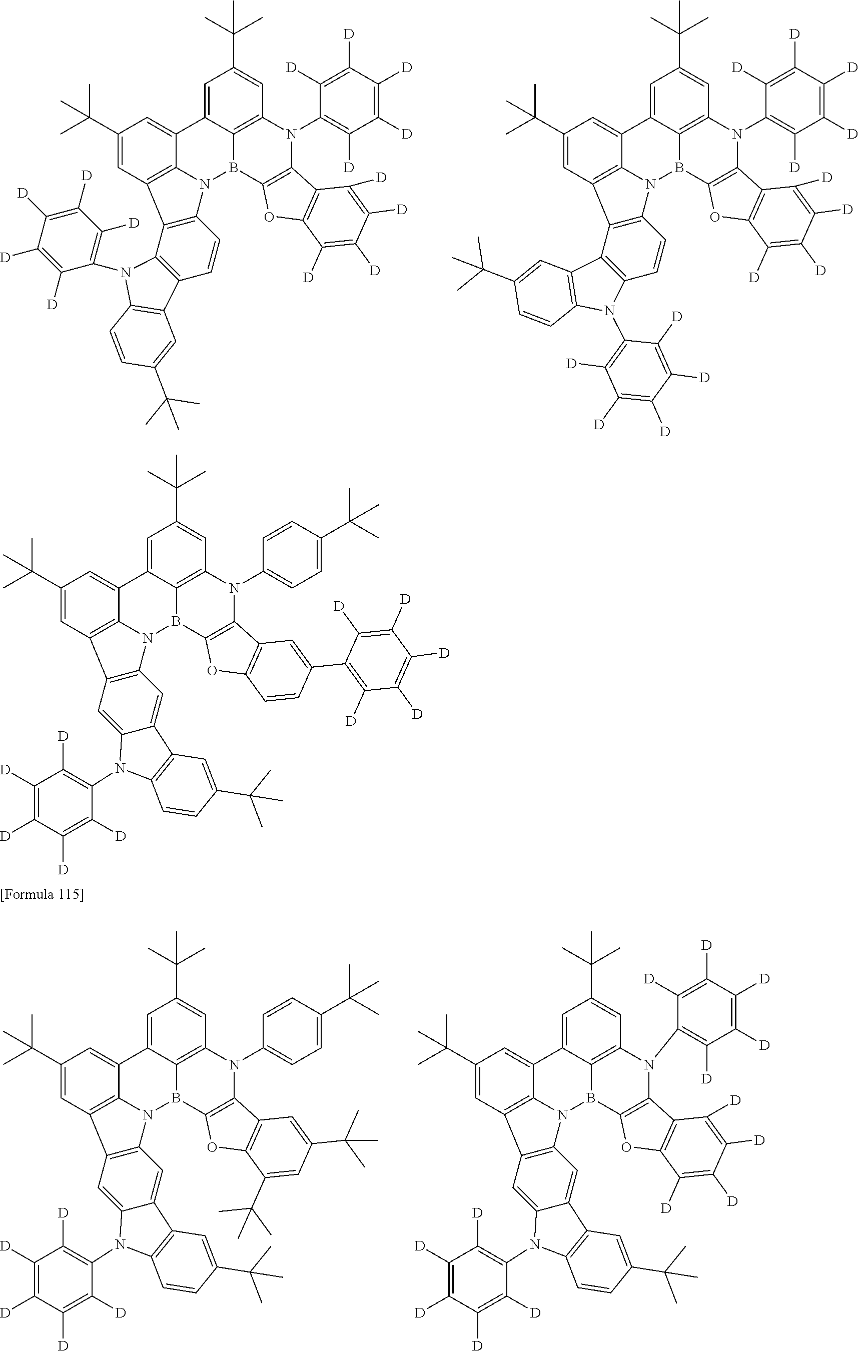

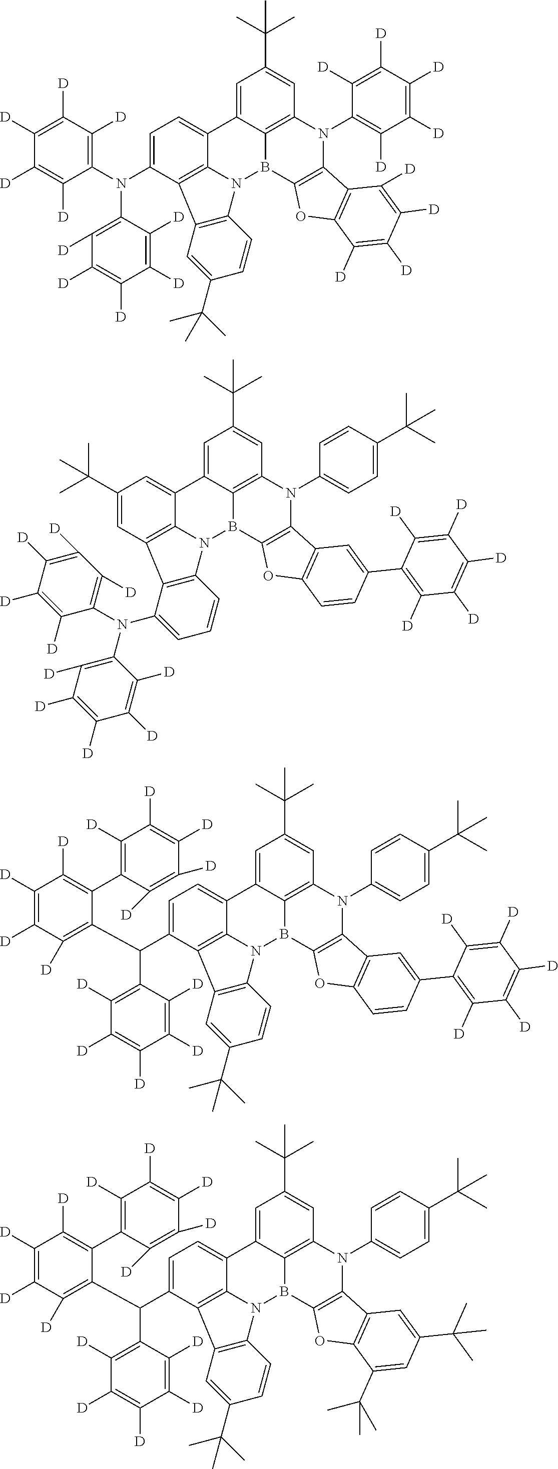

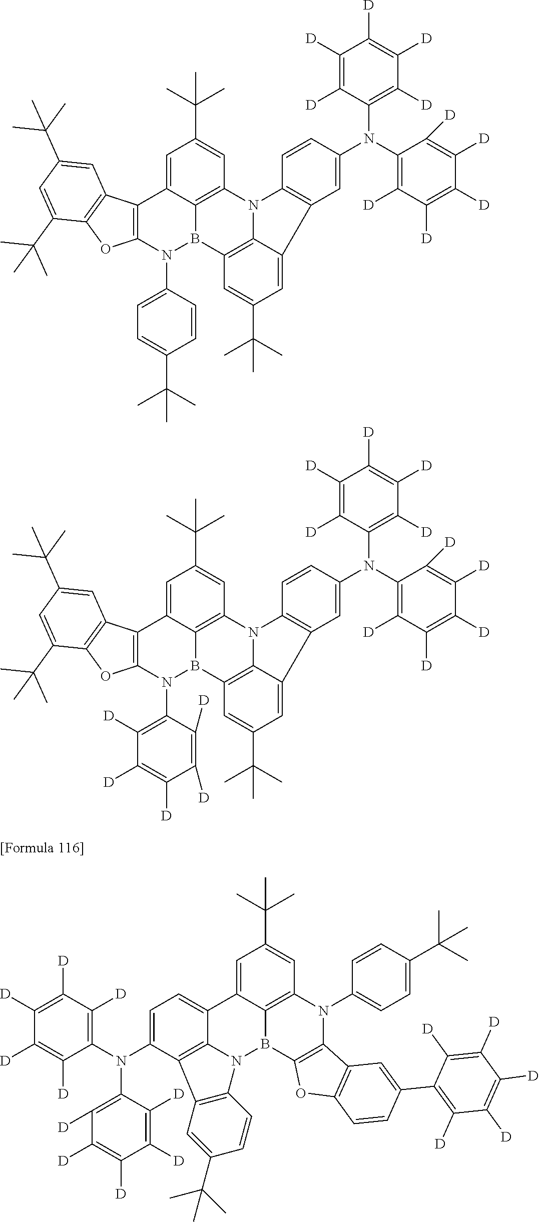

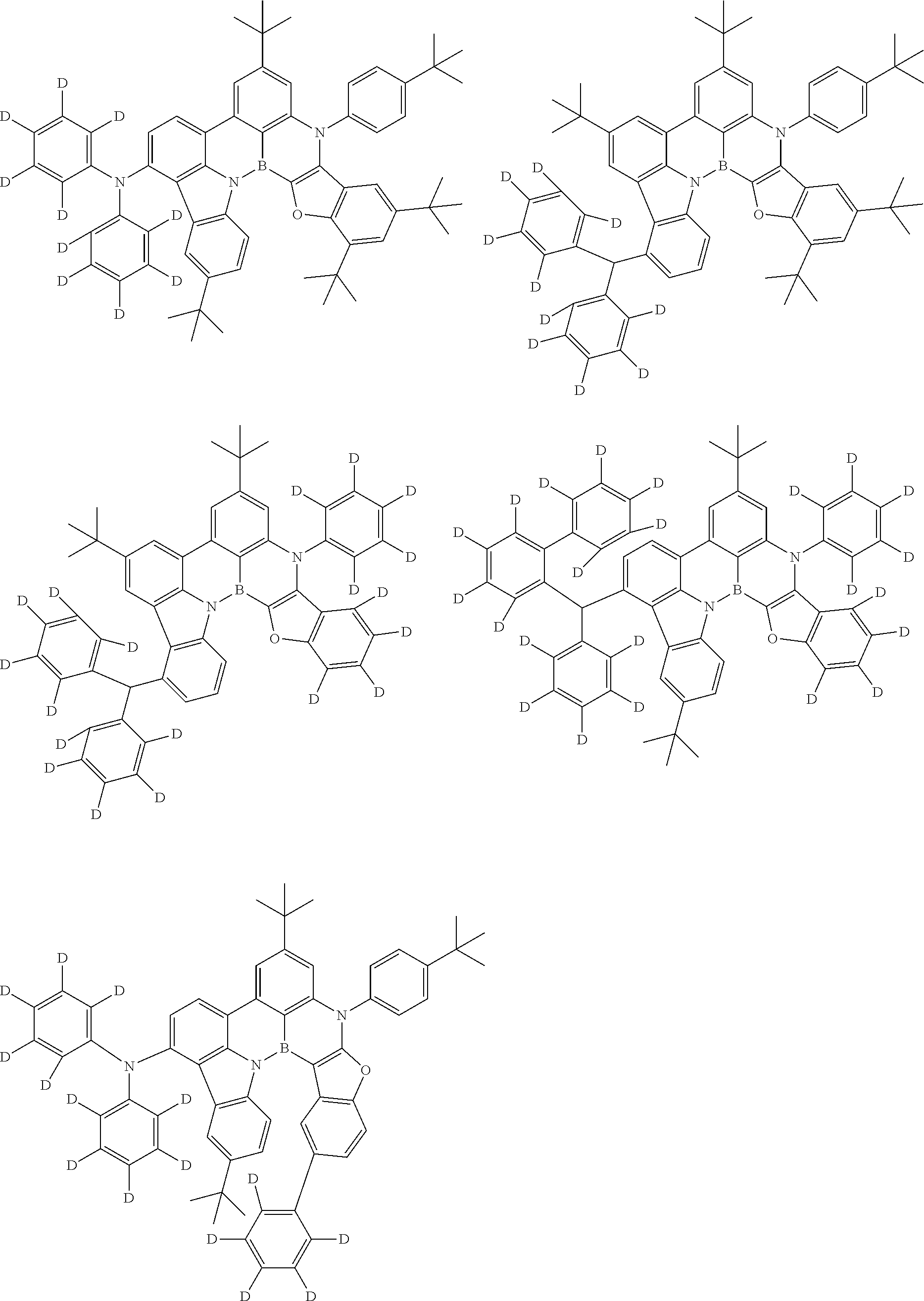

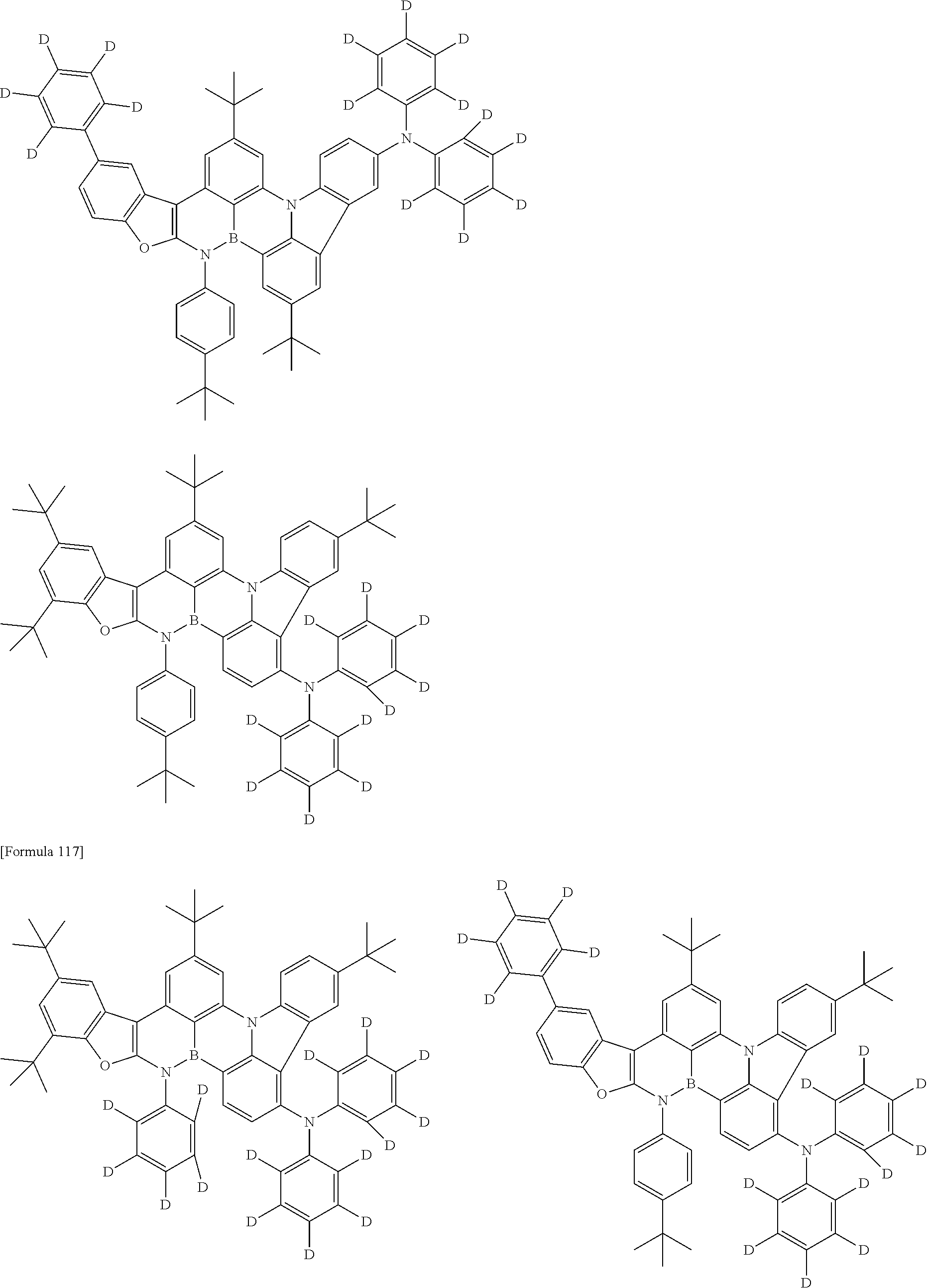

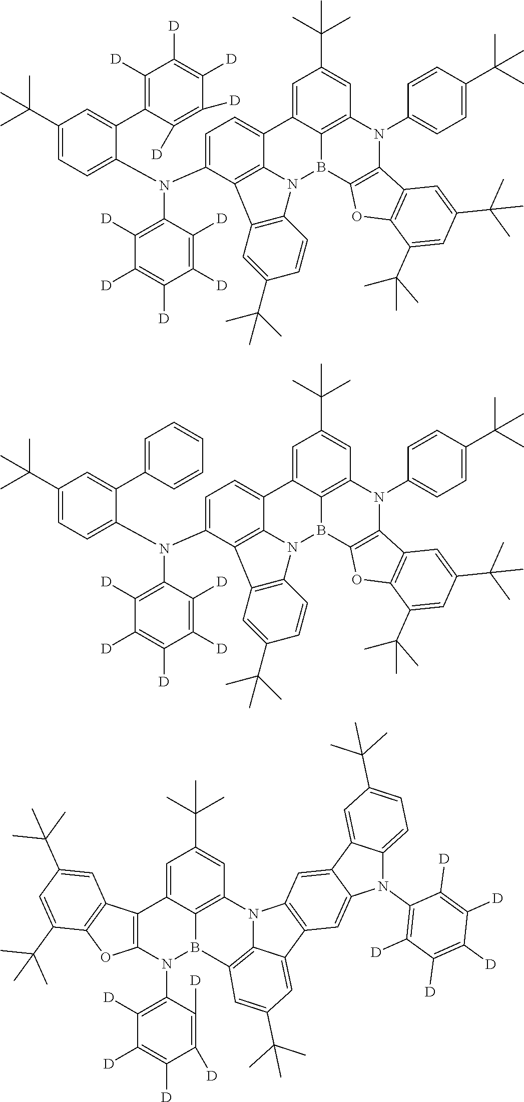

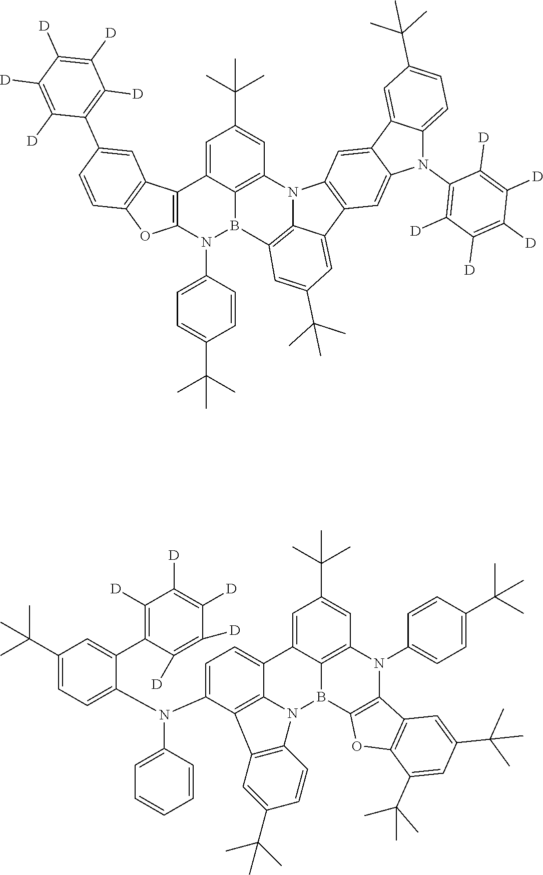 [SMILES: [2H]c1c([2H])c([2H])c(-c2ccc3oc4c(c3c2)-c2cc(C(C)(C)C)cc3c2B(c2cc(C(C)(C)C)cc5c6cc7c(cc6n-3c25)c2cc(C(C)(C)C)ccc2n7-c2c([2H])c([2H])c([2H])c([2H])c2[2H])N4c2ccc(C(C)(C)C)cc2)c([2H])c1[2H] ; [2H]c1c([2H])c([2H])c(-c2cc(C(C)(C)C)ccc2N(c2ccccc2)c2ccc3c4c2c2cc(C(C)(C)C)ccc2n4B2c4oc5c(C(C)(C)C)cc(C(C)(C)C)cc5c4N(c4ccc(C(C)(C)C)cc4)c4cc(C(C)(C)C)cc-3c42)c([2H])c1[2H]]

### Second Exemplary Embodiment

### Organic-Electroluminescence-Device Material

An organic-electroluminescence-device material according to the exemplary embodiment contains the compound according to the first exemplary embodiment. An exemplary arrangement of an organic-electroluminescence-device material is to contain only the compound according to the first exemplary embodiment. Another exemplary arrangement of the organic-electroluminescence-device material is to contain the compound according to the first exemplary embodiment and a compound different from the compound according to the first exemplary embodiment.

In the organic-electroluminescence-device material according to the exemplary embodiment, the compound according to the first exemplary embodiment is preferably a dopant material. In this arrangement, the organic-electroluminescence-device material may contain the compound according to the first exemplary embodiment as a dopant material and other compound(s) such as a host material.

The compound of the first exemplary embodiment is useful as the organic-EL-device material, useful as a material for the emitting layer of the organic EL device, particularly useful as a blue emitting material of the emitting layer.

### Third Exemplary Embodiment

### Organic Electroluminescence Device

An organic EL device according to a third exemplary embodiment will be described.

The organic EL device according to the exemplary embodiment includes an anode, a cathode, and an organic layer between the anode and the cathode. The organic layer includes at least one layer formed from an organic compound(s). Alternatively, the organic layer includes a plurality of layers formed from an organic compound(s). The organic layer may further contain an inorganic compound(s).

In the organic EL device according to the exemplary embodiment, the organic layer contains the compound according to the first exemplary embodiment. Specifically, the organic EL device according to the exemplary embodiment includes a cathode, an anode, and an organic layer provided between the cathode and the anode in which the organic layer contains the compound according to the first exemplary embodiment.

In the organic EL device according to the exemplary embodiment, the organic layer preferably includes the emitting layer and the emitting layer preferably contains the compound according to the first exemplary embodiment.

The organic EL device according to the exemplary embodiment includes a cathode, an anode, and one or more organic layers provided between the cathode and the anode, in which at least one of the one or more organic layers contains the compound according to the first exemplary embodiment.

The organic EL device according to the exemplary embodiment includes a cathode, an anode, and one or more emitting layers provided between the cathode and the anode, in which at least one of the one or more emitting layers contains the compound according to an exemplary embodiment of the invention.

The organic EL device according to the exemplary embodiment may be an organic EL device including a single-layered emitting layer as a third exemplary embodiment.

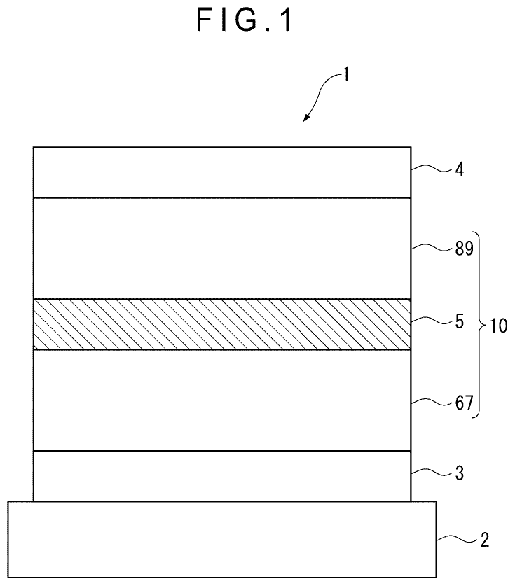

Referring to FIG. 1, a schematic arrangement of an organic EL device of an exemplary embodiment of the invention will be described below. FIG. 1 schematically depicts an exemplary arrangement of an organic EL device according to the third exemplary embodiment.

An organic EL device 1 of an exemplary embodiment of the invention includes a substrate 2, an anode 3, a cathode 4, and an organic layer 10 provided between the anode 3 and the cathode 4. The organic layer 10 includes a first organic layer 67, an emitting layer 5, and a second organic layer 89 which are layered in this order from a side close to the anode 3. Each of the first organic layer 67 and the second organic layer 89 may be provided by a single layer or a plurality of layers. The first organic layer 67 may include a hole transporting zone. The hole transporting zone may include at least one layer selected from the group consisting of a hole injecting layer, hole transporting layer, and electron blocking layer. The second organic layer 89 may include an electron transporting zone. The electron transporting zone may include at least one layer selected from the group consisting of an electron injecting layer, electron transporting layer, and hole blocking layer. The first organic layer 67 may include, for instance, the hole injecting layer and the hole transporting layer which are layered in this order from a side close to the anode 3. The second organic layer 89 may include, for instance, the electron transporting layer and the electron injecting layer which are layered in this order from the side close to the anode 3. The organic EL device 1 may include the hole injecting layer, the hole transporting layer, the emitting layer 5, the electron transporting layer, and the electron injecting layerwhich are layered in this orderfrom the side close to the anode 3. The organic EL device of the invention may have any arrangement without being limited to the arrangement of the organic EL device depicted in FIG. 1.

The compound according to the first exemplary embodiment is contained in the first organic layer 67, the emitting layer 5, or the second organic layer 89. In an exemplary embodiment, the compound according to the first exemplary embodiment is contained in the emitting layer 5. The compound according to the first exemplary embodiment can function as the dopant material in the emitting layer 5.

In the organic EL device of the third exemplary embodiment, a compound according to an exemplary embodiment of the invention and a compound represented by a formula (H10) described later are usable in combination in the emitting layer of the organic EL device.

The compound represented by the formula (H10) will be described below.

### Compound Represented by Formula (H10)

The compound represented by the formula (H10) will be described.

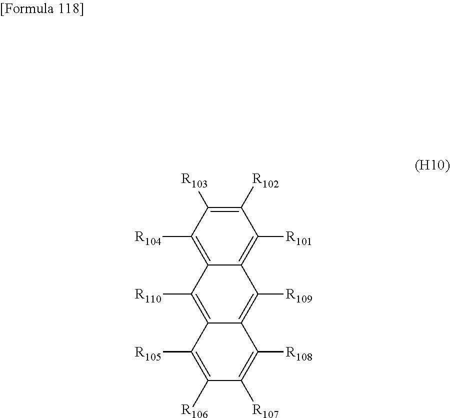

In the formula (H10):
at least one combination of adjacent two or more of R₁₀₁ to R₁₁₀ are mutually bonded to form a substituted or unsubstituted monocyclic ring, mutually bonded to form a substituted or unsubstituted fused ring, or not mutually bonded;
R₁₀₁ to R₁₁₀ forming neither the substituted or unsubstituted monocyclic ring nor the substituted or unsubstituted fused ring are each independently a hydrogen atom, a substituent R, or a group represented by a formula (H11) below;
at least one of R₁₀₁ to R₁₁₀ forming neither the substituted or unsubstituted monocyclic ring nor the substituted or unsubstituted fused ring is a group represented by the formula (H11) below; and
when two or more groups represented by the formula (H11) are present, the two or more groups represented by the formula (H11) are mutually the same or different.

-L₁₀₁-Ar₁₀₁ (H11)

In the formula (H11):
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
the substituent R is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
when two or more substituents R are present, the two or more substituents R are mutually the same or different;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

The compound represented by the formula (H10) may have a deuterium atom as a hydrogen atom.

In an exemplary embodiment, at least one Ar₁₀₁ in the formula (H10) is a substituted or unsubstituted aryl group having 6 to 50 ring carbon atoms.

In an exemplary embodiment, at least one Ar₁₀₁ in the formula (H10) is a substituted or unsubstituted monovalent heterocyclic group having 5 to 50 ring atoms.

In an exemplary embodiment, all Ar₁₀₁ in the formula (H10) are each a substituted or unsubstituted aryl group having 6 to 50 ring carbon atoms. A plurality of Ar₁₀₁ may be mutually the same or different.

In an exemplary embodiment, one of Ar₁₀₁ in the formula (H10) is a substituted or unsubstituted heterocyclic group having 5 to 50 ring atoms and the rest of Ar₁₀₁ are each a substituted or unsubstituted aryl group having 6 to 50 ring carbon atoms. A plurality of Ar₁₀₁ may be mutually the same or different.

In an exemplary embodiment, at least one L₁₀₁ in the formula (H10) is a single bond.

In an exemplary embodiment, all L₁₀₁ in the formula (H10) are each a single bond.

In an exemplary embodiment, at least one L₁₀₁ in the formula (H10) is a substituted or unsubstituted arylene group having 6 to 50 ring carbon atoms.

In an exemplary embodiment, at least one L₁₀₁ in the formula (H10) is a substituted or unsubstituted phenyl group or a substituted or unsubstituted naphthylene group.

In an exemplary embodiment, a group represented by the formula -L₁₀₁-Ar₁₀₁ in the formula (H10) is selected from the group consisting of a substituted or unsubstituted phenyl group, a substituted or unsubstituted naphthyl group, a substituted or unsubstituted biphenyl group, a substituted or unsubstituted phenanthrenyl group, a substituted or unsubstituted benzophenanthrenyl group, a substituted or unsubstituted fluorenyl group, a substituted or unsubstituted benzofluorenyl group, a substituted or unsubstituted dibenzofuranyl group, a substituted or unsubstituted naphthobenzofuranyl group, a substituted or unsubstituted dibenzothiophenyl group, and a substituted or unsubstituted carbazolyl group.

In an exemplary embodiment, the substituent R in the formula (H10) are each independently a substituted or unsubstituted alkyl group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, or a substituted or unsubstituted aryl group having 6 to 50 ring carbon atoms; and R₉₀₁ to R₉₀₇ are as defined in the formula (H10).

In an exemplary embodiment, a substituent for “the substituted or unsubstituted” group in the formula (H10) is each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₉₀₁ to R₉₀₇ are as defined in the formula (H10).

In an exemplary embodiment, a substituent for “the substituted or unsubstituted” group in the formula (H10) is each independently a substituted or unsubstituted alkyl group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, or a substituted or unsubstituted aryl group having 6 to 50 ring carbon atoms; and
R₉₀₁ to R₉₀₇ are as defined in the formula (H10).

In an exemplary embodiment, a substituent for “the substituted or unsubstituted” group in the formula (H10) is selected from the group consisting of an alkyl group having 1 to 18 carbon atoms, an aryl group having 6 to 18 ring carbon atoms, and a heterocyclic group having 5 to 18 ring atoms.

In an exemplary embodiment, the substituent for “the substituted or unsubstituted” group in the formula (H10) is an alkyl group having 1 to 5 carbon atoms.

In an exemplary embodiment, the compound represented by the formula (H10) is a compound represented by a formula (H20) below.

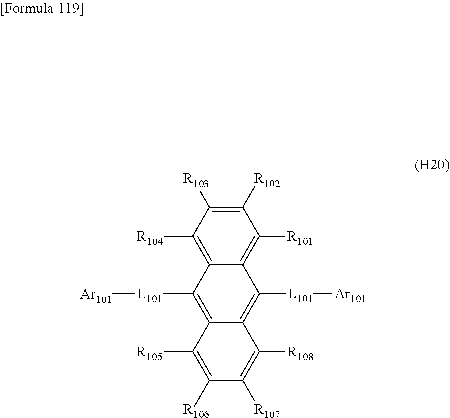

In the formula (H20), R₁₀₁ to R₁₀₈, L₁₀₁, and Ar₁₀₁ are as defined in the formula (H10).

The compound represented by the formula (H20) may have a deuterium atom as a hydrogen atom.

Specifically, in an exemplary embodiment, the compound represented by the formula (H10) or (H20) has at least two groups represented by the formula (H11).

In an exemplary embodiment, the compound represented by the formula (H10) or (H20) has two or three groups represented by the formula (H11).

In an exemplary embodiment, none of combinations of adjacent two or more of R₁₀₁ to R₁₁₀ in the formula (H10) or (H20) are bonded to each other.

In an exemplary embodiment, R₁₀₁ to R₁₁₀ in the formula (H10) or (H20) are each a hydrogen atom.

In an exemplary embodiment, the compound represented by the formula (H20) is a compound represented by a formula (H30) below.

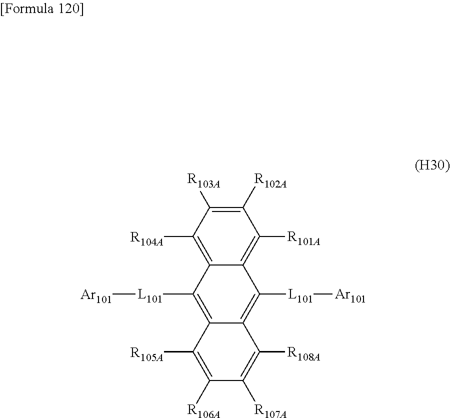

In the formula (H30):
L₁₀₁ and Ar₁₀₁ are as defined in the formula (H10);
none of a combination(s) of adjacent two or more of R_{101A} to R_{108A} are bonded to each other;
R_{101A} to R_{108A} are each independently a hydrogen atom or a substituent R; and
the substituent R is as defined in the formula (H10).

Specifically, the compound represented by the formula (H30) has two groups represented by the formula (H11).

The compound represented by the formula (H30) substantially has only a protium atom as a hydrogen atom.

To “substantially have only a protium atom” means that a ratio of a protium compound to a total of the protium compound and a deuterium compound is 90 mol % or more, 95 mol % or more, or 99 mol % or more, the protium compound meaning a compound having only a protium atom as a hydrogen atom, the deuterium compound meaning a compound having a deuterium atom as a hydrogen atom, the protium compound and the deuterium compound having the same structure.

In an exemplary embodiment, the compound represented by the formula (H30) is a compound represented by a formula (H31) below.

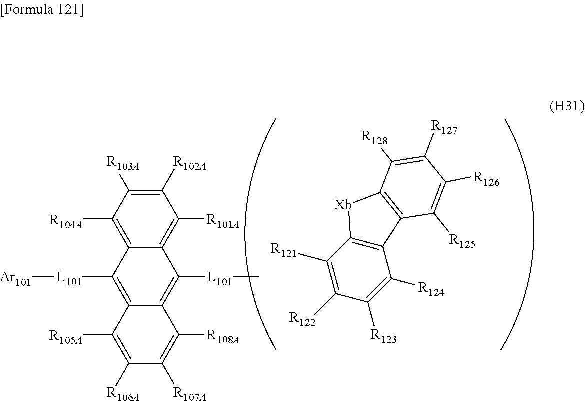

In the formula (H31):
L₁₀₁ and Ar₁₀₁ are as defined in the formula (H10);
R_{101A} to R_{108A} are as defined in the formula (H30);
X_{b} is an oxygen atom, a sulfur atom, N(R₃₃₁), or C(R₃₃₂)(R₃₃₃);
one of R₁₂₁ to R₁₂₈ and R₃₃₁ to R₃₃₃ is a single bond with L₁₀₁;
at least one combination of adjacent two or more of R₁₂₁ to R₁₂₈ not being a single bond with L₁₀₁ are mutually bonded to form a substituted or unsubstituted monocyclic ring, mutually bonded to form a substituted or unsubstituted fused ring, or not mutually bonded;
R₁₂₁ to R₁₂₈ not being a single bond with L₁₀₁ and forming neither the substituted or unsubstituted monocyclic ring nor the substituted or unsubstituted fused ring are each independently a hydrogen atom, or a substituent R; and
the substituent R is as defined in the formula (H10);
R₃₃₁ to R₃₃₃ not being the single bond with L₁₀₁ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₃₃₁ are present, the plurality of R₃₃₁ are mutually the same or different;
when a plurality of R₃₃₂ are present, the plurality of R₃₃₂ are mutually the same or different; and
when a plurality of R₃₃₃ are present, the plurality of R₃₃₃ are mutually the same or different.

In an exemplary embodiment, the compound represented by the formula (H31) is a compound represented by a formula (H32) below.

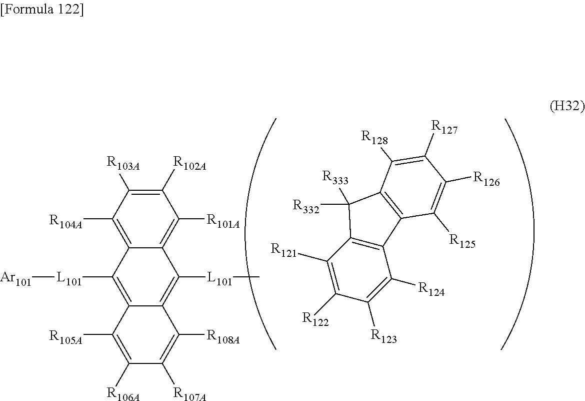

In the formula (H32), R_{101A} to R_{108A}, L₁₀₁, Ar₁₀₁, R₁₂₁ to R₁₂₈, R₃₃₂, and R₃₃₃ are as defined in the formula (H31).

In an exemplary embodiment, the compound represented by the formula (H31) is a compound represented by a formula (H33) below.

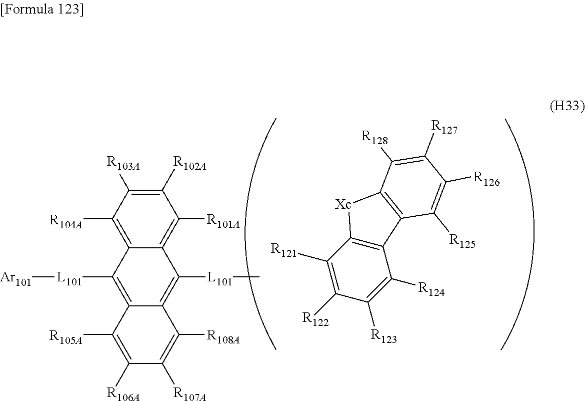

In the formula (H33): R_{101A} to R_{108A}, L₁₀₁, Ar₁₀₁, and R₁₂₁ to R₁₂₈ are as defined in the formula (H31);
X_{c} is an oxygen atom, a sulfur atom, or NR₃₃₁; and
R₃₃₁ is as defined in the formula (H31).

In an exemplary embodiment, the compound represented by the formula (H31) is a compound represented by a formula (H34) below.

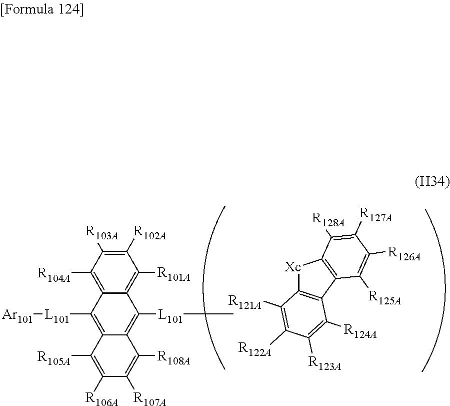

In the formula (H34):
R_{101A} to R_{108A}, L₁₀₁, and Ar₁₀₁ are as defined in the formula (H31);
X_{c} is an oxygen atom, a sulfur atom, or NR₃₃₁;
R₃₃₁ is as defined in the formula (H31);
one of R_{121A} to R_{128A} is a single bond with L₁₀₁;
none of a combination(s) of adjacent two or more of R_{121A} to R₁₂₈ not being the single bond with L₁₀₁ are bonded to each other;
R_{121A} to R_{128A} not being the single bond with L₁₀₁ are each independently a hydrogen atom, or a substituent R; and
the substituent R is as defined in the formula (H10).

In an exemplary embodiment, the compound represented by the formula (H31) is a compound represented by a formula (H35) below.

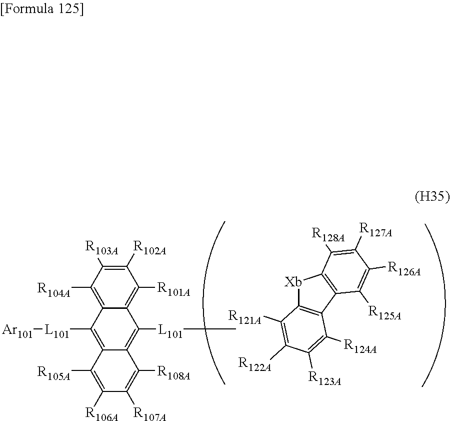

In the formula (H35):
R_{101A} to R_{108A}, L₁₀₁, Ar₁₀₁, and X_{b} are as defined in the formula (H31); none of a combination(s) of adjacent two or more of R_{121A} to R_{124A} are bonded to each other; and
one combination of a combination of R_{125A} and R_{126A}, a combination of R_{126A} and R_{127A}, and a combination of R_{127A} and R_{128A} are bonded to each other to form a ring represented by a formula (H35a) or (H35b) below.

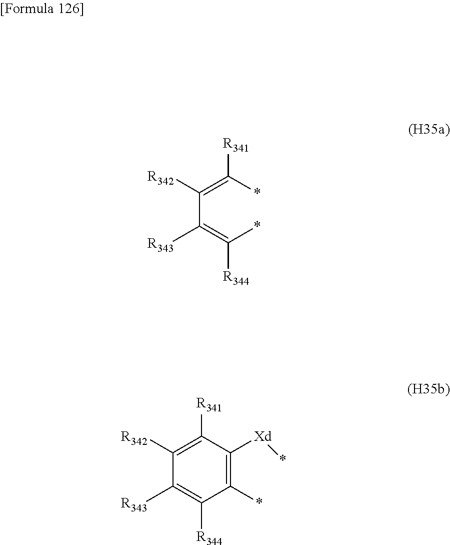

In the formulae (H35a) and (H35b):
two * are respectively bonded to one combination of a combination of R_{125A} and R_{126A}, a combination of R_{126A} and R_{127A}, and a combination of R_{127A} and R_{128A};
R₃₄₁ to R₃₄₄ are each independently a hydrogen atom, or a substituent R;
the substituent R is as defined in the formula (H10); and
X_{d} is an oxygen atom or a sulfur atom.

One of R_{121A} to R_{124A}, R_{125A} to R_{128A} not forming a ring represented by the formula (H35a) or (H35b), and R₃₄₁ to R₃₄₄ is a single bond with L₁₀₁;
R_{121A} to R_{124A} not being a single bond with L₁₀₁, and R_{125A} to R_{128A} not being a single bond with L₁₀₁ and not forming a ring represented by the formula (H35a) or (H35b) are each independently a hydrogen atom, or a substituent R; and the substituent R is as defined in the formula (H10).

In an exemplary embodiment, the compound represented by the formula (H35) is a compound represented by a formula (H36) below.

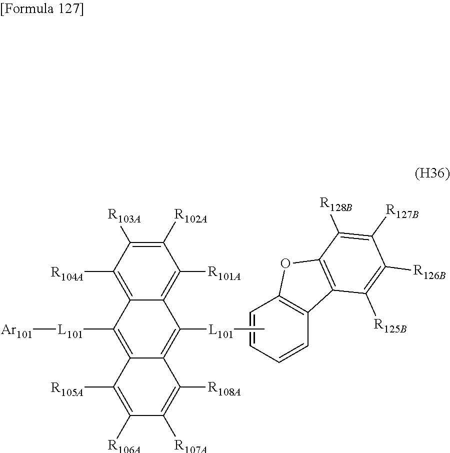

In the formula (H36): R_{101A} to R_{108A}, L₁₀₁, and Ar₁₀₁ are as defined in the formula (H35) and R_{125B} to R_{128B} each independently represent the same as R_{125A} to R_{128A} in the formula (H35).

In an exemplary embodiment, the compound represented by the formula (H34) is a compound represented by a formula (H37) below.

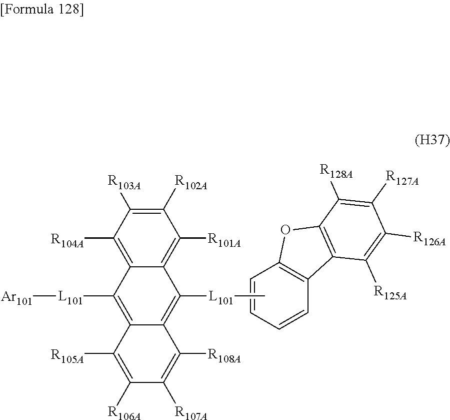

In the formula (H37): R_{101A} to R_{108A}, R_{125A} to R_{128A}, L₁₀₁, and Ar₁₀₁ are as defined in the formula (H34).

In an exemplary embodiment, R_{101A} to R_{108A} in the formulae (H30) to (H37) are each a hydrogen atom.

In an exemplary embodiment, the compound represented by the formula (H10) is a compound represented by a formula (H40) below.

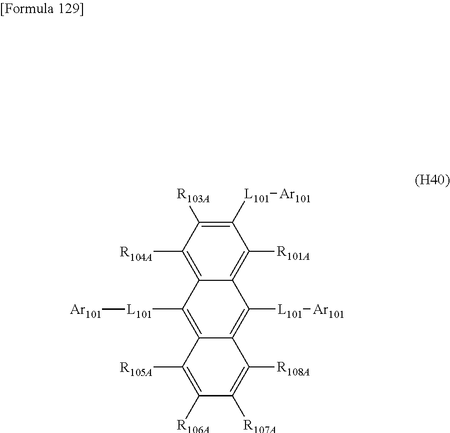

In the formula (H40):
L101 and Ar₁₀₁ are as defined in the formula (H10);
at least one combination of adjacent two or more of R_{101A} and R_{103A} to R_{108A} are mutually bonded to form a substituted or unsubstituted monocyclic ring, mutually bonded to form a substituted or unsubstituted fused ring, or not mutually bonded;
R_{101A} and R_{103A} to R_{108A} forming neither the substituted or unsubstituted monocyclic ring nor the substituted or unsubstituted fused ring are each independently a hydrogen atom or a substituent R; and
the substituent R is as defined in the formula (H10).

Specifically, the compound represented by the formula (H40) has three groups represented by the formula (H11). Moreover, the compound represented by the formula (H40) substantially has only a protium atom as a hydrogen atom.

In an exemplary embodiment, the compound represented by the formula (H40) is represented by a formula (H41) below.

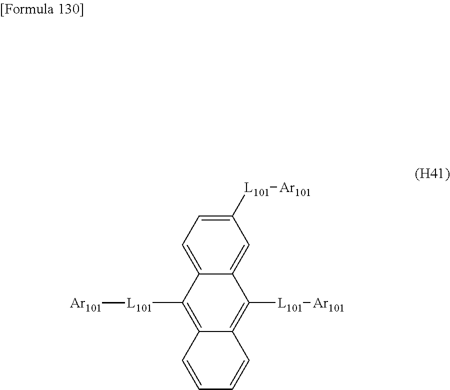

In the formula (H41), L₁₀₁ and Ar₁₀₁ are as defined in the formula (H40).

In an exemplary embodiment, the compound represented by the formula (H40) is a compound represented by one of formulae (H42-1) to (H42-3) below.

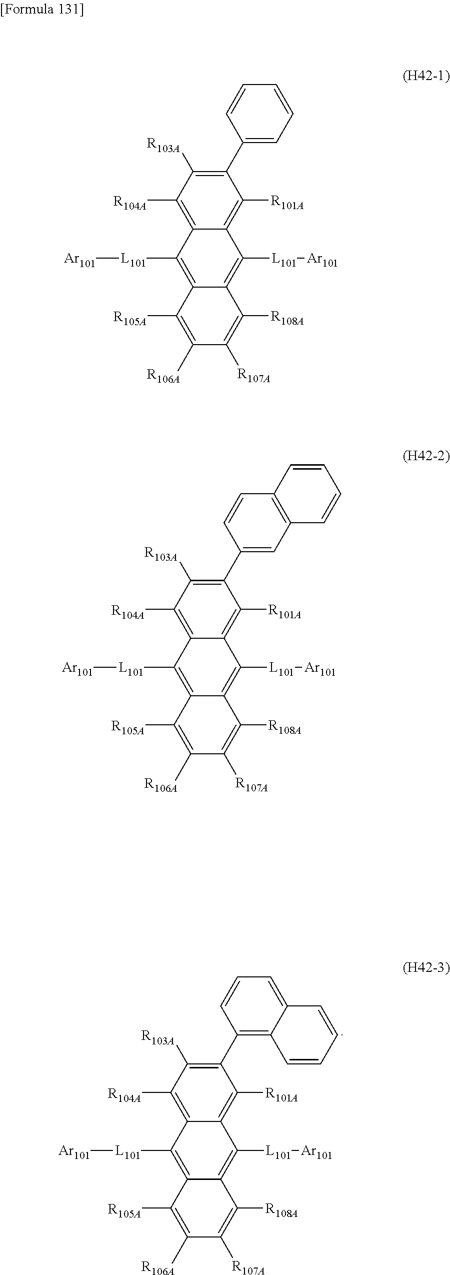

In the formulae (H42-1) to (H42-3), R_{101A} to R_{108A}, L₁₀₁, and Ar₁₀₁ are as defined in the formula (H40).

In an exemplary embodiment, the compounds represented by the formulae (H42-1) to (H42-3) are each a compound represented by one of formulae (H43-1) to (H43-3) below.

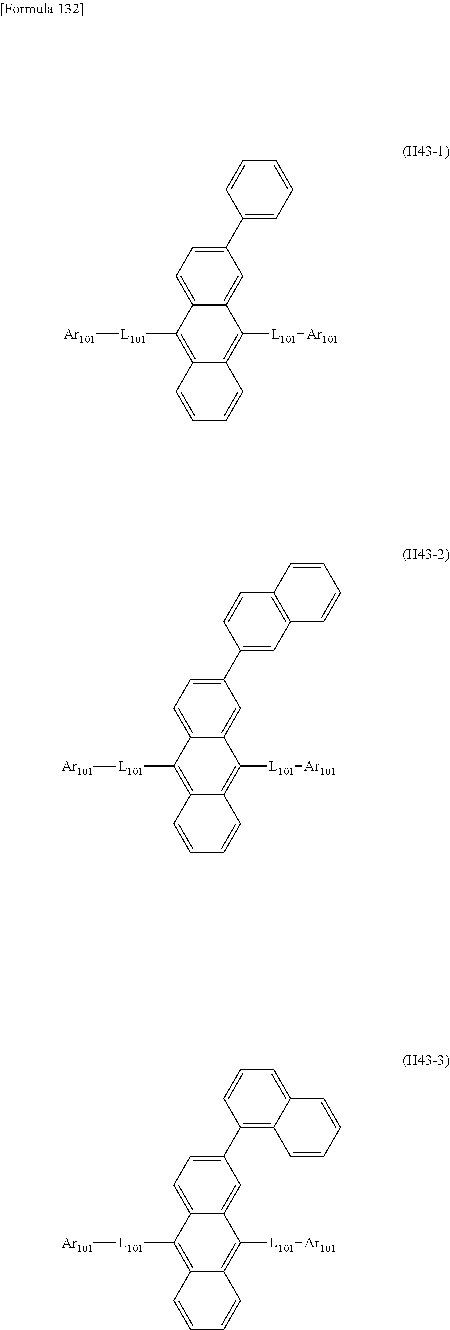

In the formulae (H43-1) to (H43-3), L₁₀₁ and Ar₁₀₁ are as defined in the formula (H40).

In an exemplary embodiment, a group represented by -L₁₀₁-Ar₁₀₁ in the formulae (H40), (H41), (H42-1) to (H42-3), and (H43-1) to (H43-3) is selected from the group consisting of a substituted or unsubstituted phenyl group, a substituted or unsubstituted naphthyl group, a substituted or unsubstituted biphenyl group, a substituted or unsubstituted phenanthrenyl group, a substituted or unsubstituted benzophenanthrenyl group, a substituted or unsubstituted fluorenyl group, a substituted or unsubstituted benzofluorenyl group, a substituted or unsubstituted dibenzofuranyl group, a substituted or unsubstituted naphthobenzofuranyl group, a substituted or unsubstituted dibenzothiophenyl group, and a substituted or unsubstituted carbazolyl group.

In an exemplary embodiment, the compound represented by the formula (H10) or (H20) is exemplified by a compound in which at least one of hydrogen atoms contained in the compound represented by the formula (H10) or (H20) is a deuterium atom.

In an exemplary embodiment, in the formula (H20), at least one of: hydrogen atoms as R₁₀₁ to R₁₀₈, hydrogen atoms contained in R₁₀₁ to R₁₀₈ being the substituent R, a hydrogen atom contained in L₁₀₁; a hydrogen atom contained in a substituent for L₁₀₁; a hydrogen atom contained in Ar₁₀₁, or a hydrogen atom contained in a substituent for Ar₁₀₁ is a deuterium atom.

The compounds represented by the formulae (H30) to (H37) are exemplified by compounds in which at least one of hydrogen atoms contained in the compounds represented by the formulae (H30) to (H37) is a deuterium atom.

In an exemplary embodiment, at least one of hydrogen atoms bonded to carbon atoms forming an anthracene skeleton in the compound represented by each of the formulae (H30) to (H37) is a deuterium atom.

In an exemplary embodiment, the compound represented by the formula (H30) is a compound represented by a formula (H30D) below.

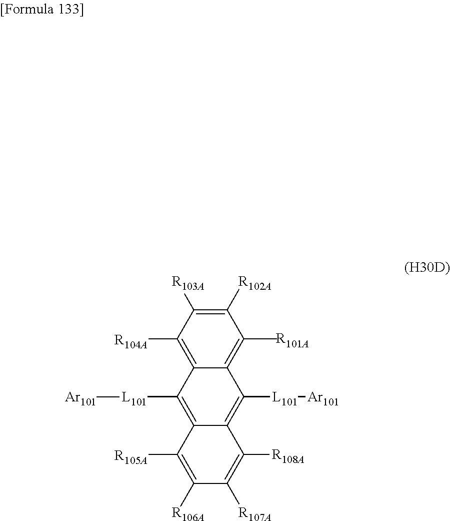

In the formula (H30D): R_{101A} to R_{108A}, L₁₀₁, and Ar₁₀₁ are as defined in the formula (H30); and at least one of: hydrogen atoms as R_{101A} to R_{108A}; hydrogen atoms contained in R_{101A} to R_{108A} being the substituent R; a hydrogen atom contained in L₁₀₁; a hydrogen atom contained in a substituent for L₁₀₁; a hydrogen atom contained in Ar₁₀₁, or a hydrogen atom contained in a substituent for Ar₁₀₁ is a deuterium atom.

The compound represented by the formula (H30D) is a compound in which at least one of hydrogen atoms contained in the compound represented by the formula (H30) is a deuterium atom.

In an exemplary embodiment, at least one of hydrogen atoms as R_{101A} to R_{108A} in the formula (H30D) is a deuterium atom.

In an exemplary embodiment, the compound represented by the formula (H30D) is a compound represented by a formula (H31 D) below.

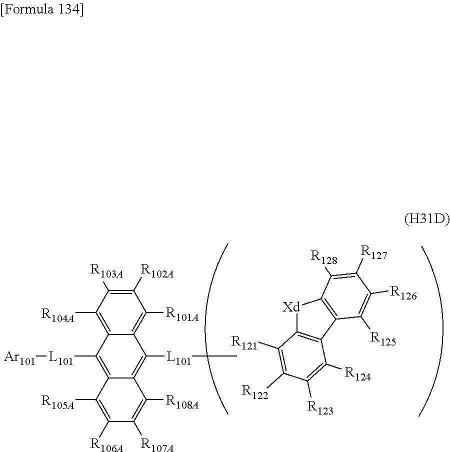

In the formula (H31 D):
R_{101A} to R_{108A}, L101, and Ar₁₀₁ are as defined in the formula (H30D);
X_{d} is an oxygen atom or a sulfur atom;
one of R₁₂₁ to R₁₂₈ is a single bond with L₁₀₁;
at least one combination of adjacent two or more of R₁₂₁ to R₁₂₈ not being a single bond with L101 are mutually bonded to form a substituted or unsubstituted monocyclic ring, mutually bonded to form a substituted or unsubstituted fused ring, or not mutually bonded;
R₁₂₁ to R₁₂₈ not being a single bond with L101 and forming neither the substituted or unsubstituted monocyclic ring nor the substituted or unsubstituted fused ring are each independently a hydrogen atom, or a substituent R; and
the substituent R is as defined in the formula (H10).

At least one of: hydrogen atoms as R_{101A} to R_{108A}; hydrogen atoms contained in R_{101A} to R_{108A} being the substituent R; a hydrogen atom contained in L₁₀₁; a hydrogen atom contained in a substituent for L₁₀₁; a hydrogen atom contained in Ar₁₀₁; a hydrogen atom contained in a substituent for Ar₁₀₁; hydrogen atoms as R₁₂₁ to R₁₂₈; or hydrogen atoms contained in R₁₂₁ to R₁₂₈ being the substituent R is a deuterium atom.

In an exemplary embodiment, the compound represented by the formula (H31 D) is a compound represented by a formula (H32D) below.

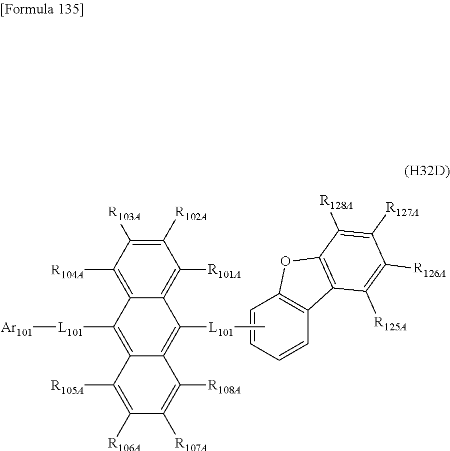

In the formula (H32D): R_{101A} to R_{110A}, L₁₀₁, and Ar₁₀₁ are as defined in the formula (H31 D) and R_{125A} to R_{128A} each independently represent the same as R₁₂₅ to R₁₂₈ in the formula (1H31 D).

At least one of: hydrogen atoms as R_{101A} to R_{110A}; hydrogen atoms contained in R_{101A} to R_{108A} being the substituent R; hydrogen atoms as R_{125A} to R_{128A}; hydrogen atoms contained in R_{125A} to R_{128A} being the substituent R; hydrogen atoms bonded to carbon atoms of a dibenzofuran skeleton in the formula (H32D); a hydrogen atom contained in L₁₀₁; a hydrogen atom contained in a substituent for L₁₀₁; a hydrogen atom contained in Ar₁₀₁, or a hydrogen atom contained in a substituent for Ar₁₀₁ is a deuterium atom.

In an exemplary embodiment, the compound represented by the formula (H32D) is a compound represented by a formula (H32D-1) or (H32D-2) below.

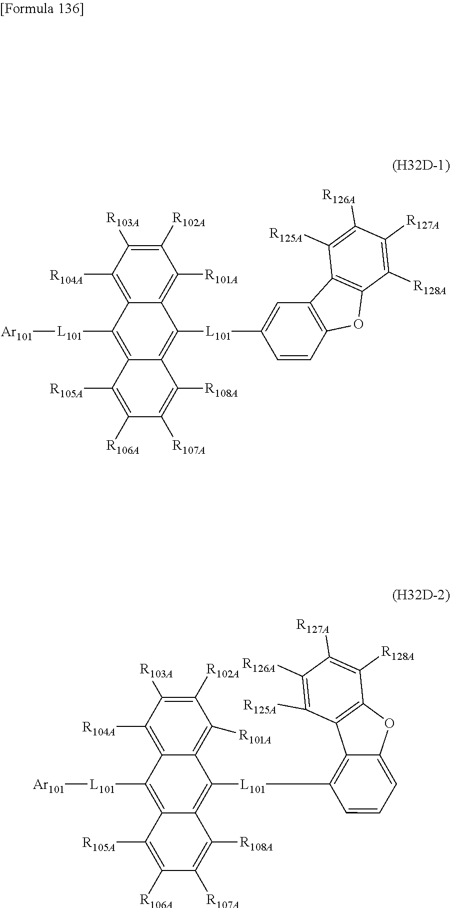

In the formulae (H32D-1) and (H32D-2), R_{101A} to R_{108A}, R_{125A} to R_{128A}, L₁₀₁, and Ar₁₀₁ are as defined in the formula (H32D).

At least one of: hydrogen atoms as R_{101A} to R_{108A}; hydrogen atoms contained in R_{101A} to R_{108A} being the substituent R; hydrogen atoms as R_{125A} to R_{128A}; hydrogen atoms contained in R_{125A} to R_{128A} being the substituent R; hydrogen atoms bonded to carbon atoms of a dibenzofuran skeleton in the formulae (H32D-1) and (H32D-2); a hydrogen atom contained in L₁₀₁; a hydrogen atom contained in a substituent for L₁₀₁; a hydrogen atom contained in Ar₁₀₁, or a hydrogen atom contained in a substituent for Ar₁₀₁ is a deuterium atom.

In an exemplary embodiment, at least one of hydrogen atoms contained in the compound represented by the formula (H40), (H41), (H42-1) to (H42-3) or (H43-1) to (H43-3) is a deuterium atom.

In an exemplary embodiment, at least one of hydrogen atoms bonded to carbon atoms forming an anthracene skeleton in the compound represented by the formula (H41) is a deuterium atom.

In an exemplary embodiment, the compound represented by the formula (H40) is a compound represented by a formula (H40D) below.

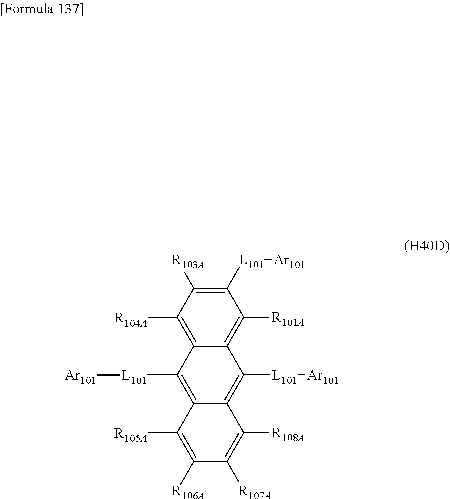

In the formula (H40D):
L₁₀₁ and Ar₁₀₁ are as defined in the formula (H10);
none of a combination(s) of adjacent two or more of R_{101A} and R_{103A} to R_{108A} are bonded to each other;
R_{101A} and R_{103A} to R_{108A} are each independently a hydrogen atom, or a substituent R; and
the substituent R is as defined in the formula (H10).

At least one of: hydrogen atoms as R_{101A} and R_{103A} to R_{108A}; hydrogen atoms contained in R_{101A} and R_{103A} to R_{108A} being the substituent R; a hydrogen atom contained in L₁₀₁; a hydrogen atom contained in a substituent for L₁₀₁; a hydrogen atom contained in Ar₁₀₁, or a hydrogen atom contained in a substituent for Ar₁₀₁ is a deuterium atom.

In an exemplary embodiment, at least one of hydrogen atoms as R_{101A} and R_{103A} to R_{108A} in the formula (H40D) is a deuterium atom.

In an exemplary embodiment, the compound represented by the formula (H40D) is a compound represented by a formula (H41 D) below.

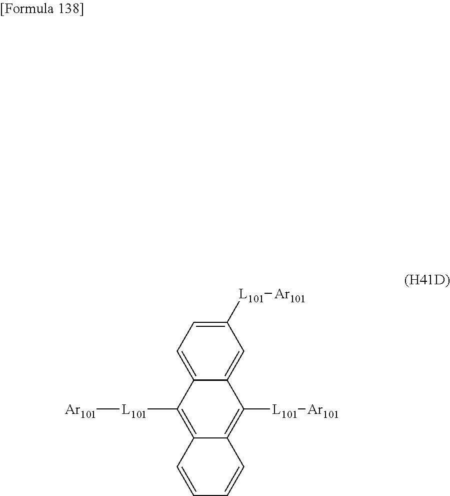

In the formula (H41 D), L₁₀₁ and Ar₁₀₁ are as defined in the formula (H40D).

In the formula (H41D), at least one of: hydrogen atoms bonded to carbon atoms forming an anthracene skeleton; a hydrogen atom contained in L11; a hydrogen atom contained in a substituent for L₁₀₁; a hydrogen atom contained in Ar₁₀₁, or a hydrogen atom contained in a substituent for Ar₁₀₁ is a deuterium atom.

In an exemplary embodiment, the compound represented by the formula (H40D) is a compound represented by one of formulae (H42D-1) to (H42D-3) below.

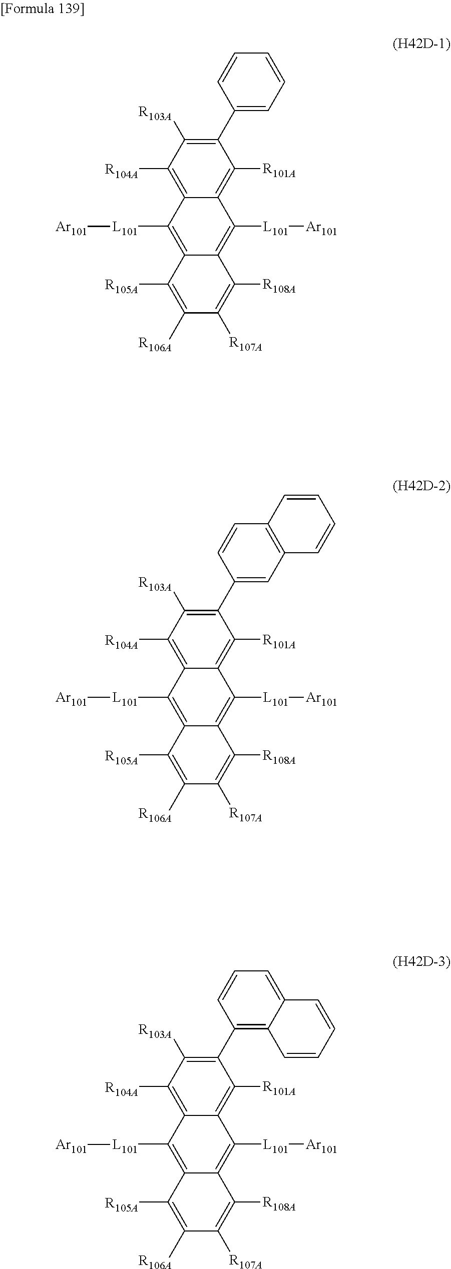

In the formulae (H42D-1) to (H42D-3), R_{101A} to R_{108A}, L₁₀₁, and Ar₁₀₁ are as defined in the formula (H40D).

In the formula (H42D-1), at least one of: hydrogen atoms as R_{101A} and R_{103A} to R_{108A}; hydrogen atoms contained in R_{101A} and R_{103A} to R_{108A} being the substituent R; a hydrogen atom contained in L₁₀₁; a hydrogen atom contained in a substituent for L101; a hydrogen atom contained in Ar₁₀₁; a hydrogen atom contained in a substituent for Ar₁₀₁; or hydrogen atoms bonded to carbon atoms forming a phenyl group in the formula (H42D-1) is a deuterium atom.

In the formula (H42D-2), at least one of: hydrogen atoms as R_{101A} and R_{103A} to R_{108A}; hydrogen atoms contained in R_{101A} and R_{103A} to R_{108A} being the substituent R; a hydrogen atom contained in L₁₀₁; a hydrogen atom contained in a substituent for L101; a hydrogen atom contained in Ar₁₀₁; a hydrogen atom contained in a substituent for Ar₁₀₁; or hydrogen atoms bonded to carbon atoms forming a naphthyl group in the formula (H42D-2) is a deuterium atom.

In the formula (H42D-3), at least one of: hydrogen atoms as R_{101A} and R_{103A} to R_{108A}; hydrogen atoms contained in R_{101A} and R_{103A} to R_{108A} being the substituent R; a hydrogen atom contained in L₁₀₁; a hydrogen atom contained in a substituent for L101; a hydrogen atom contained in Ar₁₀₁; a hydrogen atom contained in a substituent for Ar₁₀₁; or hydrogen atoms bonded to carbon atoms forming a naphthyl group in the formula (H42D-3) is a deuterium atom.

In an exemplary embodiment, the compounds represented by the formulae (H42D-1) to (H42D-3) are each a compound represented by one of formulae (H43D-1) to (H43D-3) below.

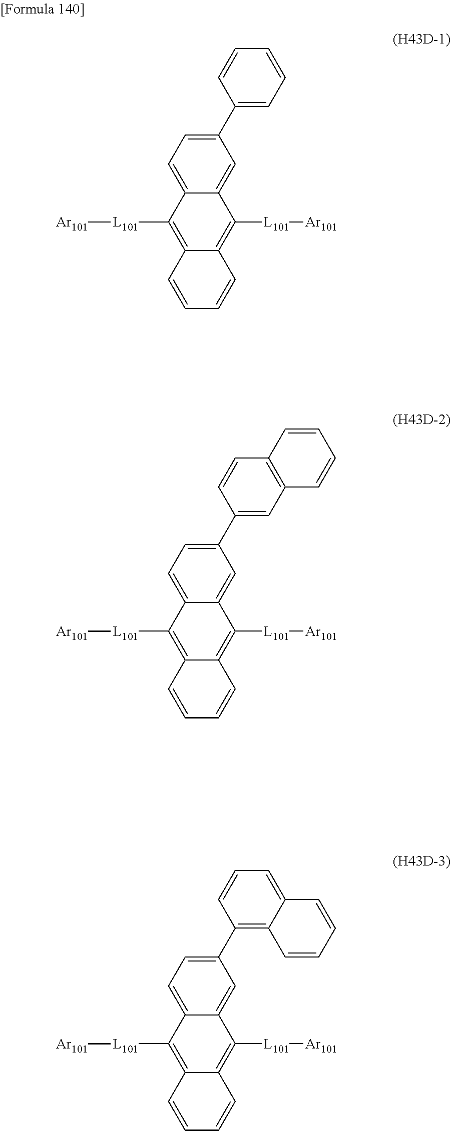

In the formulae (H43D-1) to (H43D-3), L₁₀₁ and Ar₁₀₁ are as defined in the formula (H40D).

At least one of: hydrogen atoms bonded to carbon atoms forming an anthracene skeleton in the formula (H43D-1); a hydrogen atom contained in L₁₀₁; a hydrogen atom contained in a substituent for L₁₀₁; a hydrogen atom contained in Ar₁₀₁; a hydrogen atom contained in a substituent for Ar₁₀₁; or hydrogen atoms bonded to carbon atoms forming a phenyl group in the formula (H43D-1) is a deuterium atom.

At least one of: hydrogen atoms bonded to carbon atoms forming an anthracene skeleton in the formula (H43D-2); a hydrogen atom contained in L₁₀₁; a hydrogen atom contained in a substituent for L₁₀₁; a hydrogen atom contained in Ar₁₀₁; a hydrogen atom contained in a substituent for Ar₁₀₁; or hydrogen atoms bonded to carbon atoms forming a naphthyl group in the formula (H43D-2) is a deuterium atom.

At least one of: hydrogen atoms bonded to carbon atoms forming an anthracene skeleton in the formula (H43D-3); a hydrogen atom contained in L₁₀₁; a hydrogen atom contained in a substituent for L₁₀₁; a hydrogen atom contained in Ar₁₀₁; a hydrogen atom contained in a substituent for Ar₁₀₁; or hydrogen atoms bonded to carbon atoms forming a naphthyl group in the formula (H43D-3) is a deuterium atom.

In an exemplary embodiment, at least one of Ar₁₀₁ in the compound represented by the formula (H20) is a monovalent group having a structure represented by a formula (H50) below.

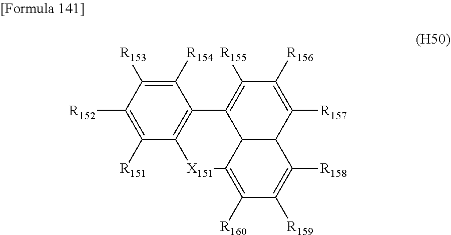

In the formula (H50):
X₁₅₁ is an oxygen atom, a sulfur atom, or C(R₁₆₁)(R₁₆₂);
one of R₁₅₁ to R₁₆₀ is a single bond with L₁₀₁;
at least one combination of combinations of adjacent two or more of R₁₅₁ to R₁₅₄ not being a single bond with L₁₀₁ or combinations of adjacent two or more of R₁₅₅ to R₁₆₀ not being a single bond with L₁₀₁ are mutually bonded to form a substituted or unsubstituted monocyclic ring, mutually bonded to form a substituted or unsubstituted fused ring, or not mutually bonded;
a combination of R₁₆₁ and R₁₆₂ are mutually bonded to form a substituted or unsubstituted monocyclic ring, mutually bonded to form a substituted or unsubstituted fused ring, or not mutually bonded;
R₁₆₁ and R₁₆₂ forming neither the substituted or unsubstituted monocyclic ring nor the substituted or unsubstituted fused ring, and R₁₅₁ to R₁₆₀ not being a single bond with L₁₀₁ and forming neither the substituted or unsubstituted saturated or unsaturated monocyclic ring nor the substituted or unsubstituted fused ring are each independently a hydrogen atom or a substituent R;
the substituent R is as defined in the formula (H10); and
Ar₁₀₁ not being a monovalent group represented by the formula (H50) is a substituted or unsubstituted aryl group having 6 to 50 ring carbon atoms, or a substituted or unsubstituted heterocyclic group having 5 to 50 ring atoms.

A position of a single bond with L₁₀₁ in the formula (H50) is not particularly limited.

In an exemplary embodiment, in the formula (H50), one of R₁₅₁ to R₁₅₄ or one of R₁₅₅ to R₁₆₀ is a single bond with L₁₀₁.

In an exemplary embodiment, Ar₁₀₁ is a monovalent group represented by a formula (H50-R₁₅₂), (H50-R₁₅₃), (H50-R₁₅₄), (H50-R₁₅₇), or (H50-R₁₅₈) below.

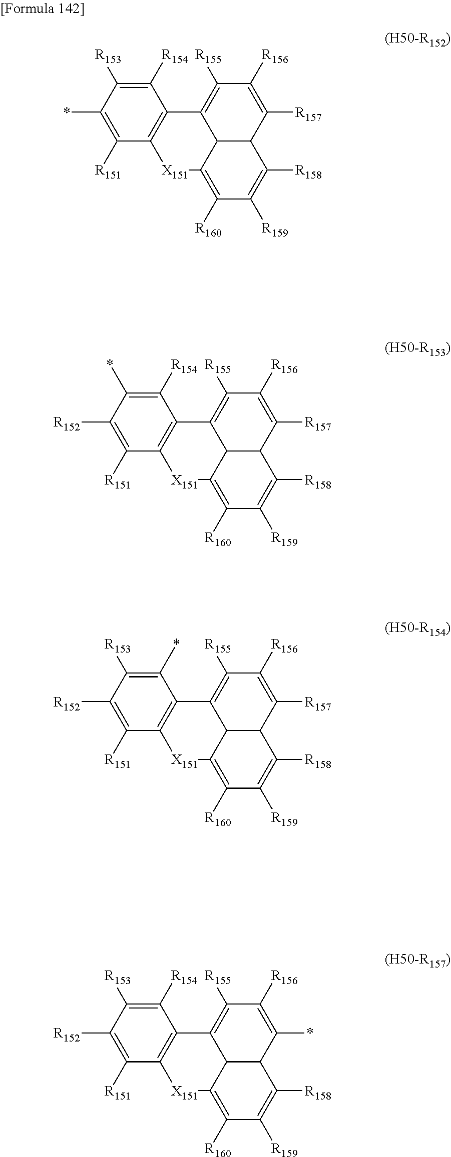

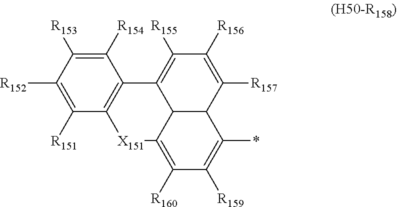

In the formulae (H50-R₁₅₂), (H50-R₁₅₃), (H50-R₁₅₄), (H50-R₁₅₇), and (H50-R₁₅₈), X₁₅₁ and R₁₅₁ to R₁₆₀ are as defined in the formula (H50), and * represents a bonding position to L₁₀₁.

### Specific Examples of Compound Represented by Formula (H10)

Specific examples of the compound represented by the formula (H10) include compounds shown below. However, the compound represented by the formula (H10) is by no means limited to the specific examples below. In the specific examples below, D represents a deuterium atom.

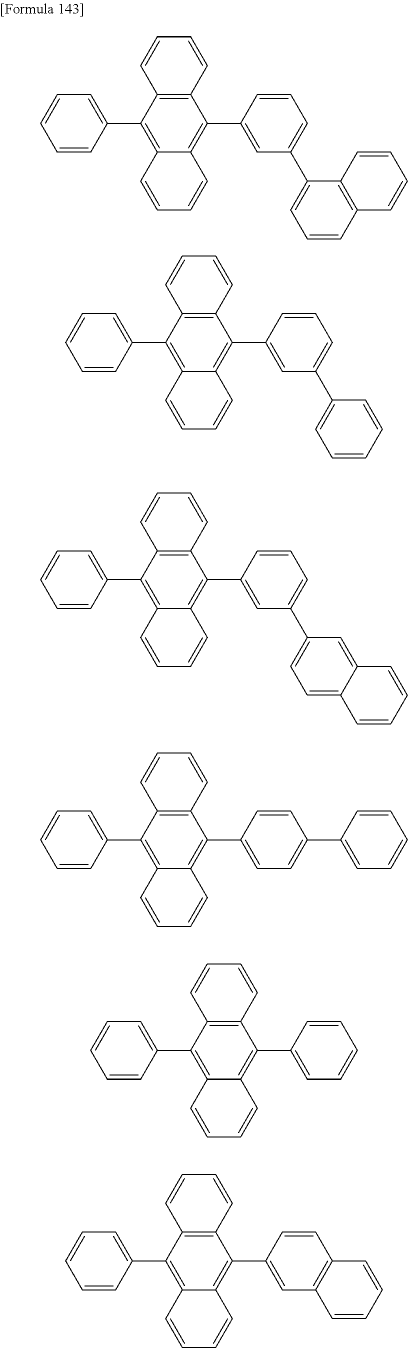

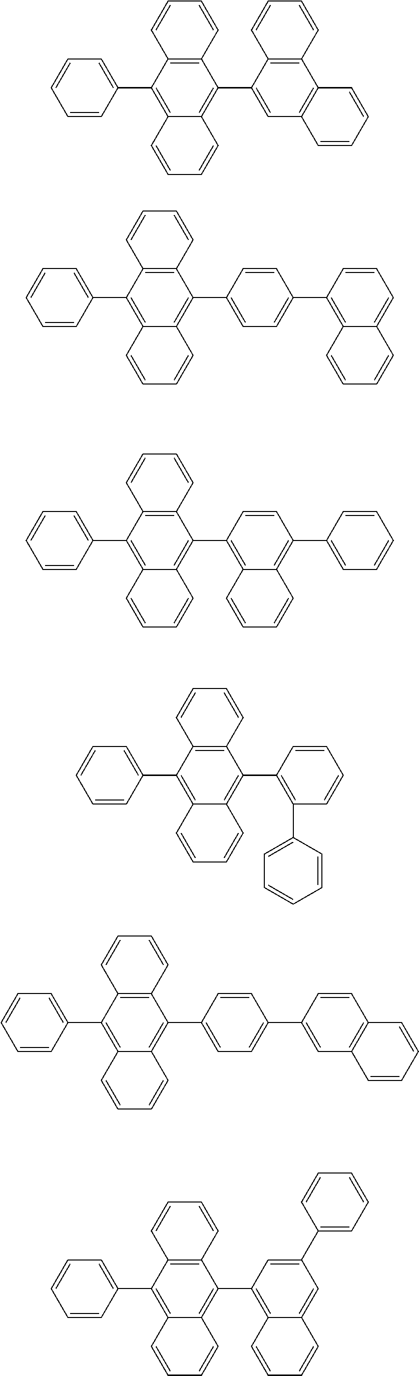

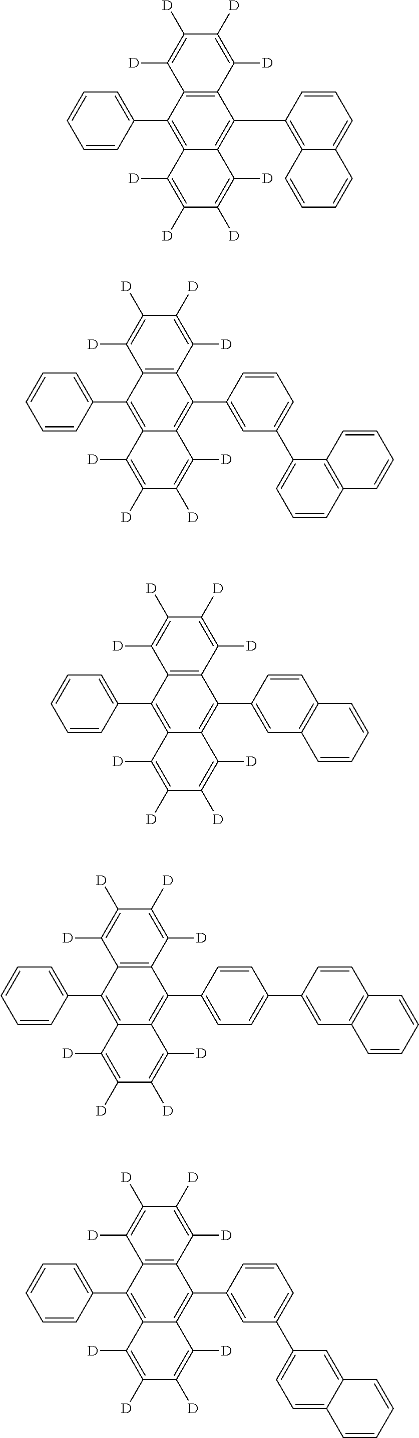

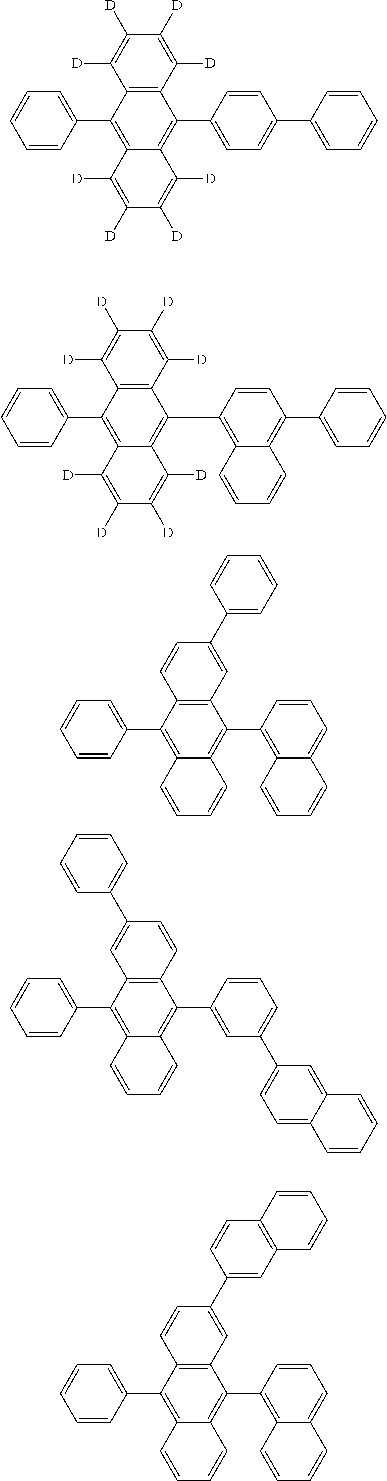

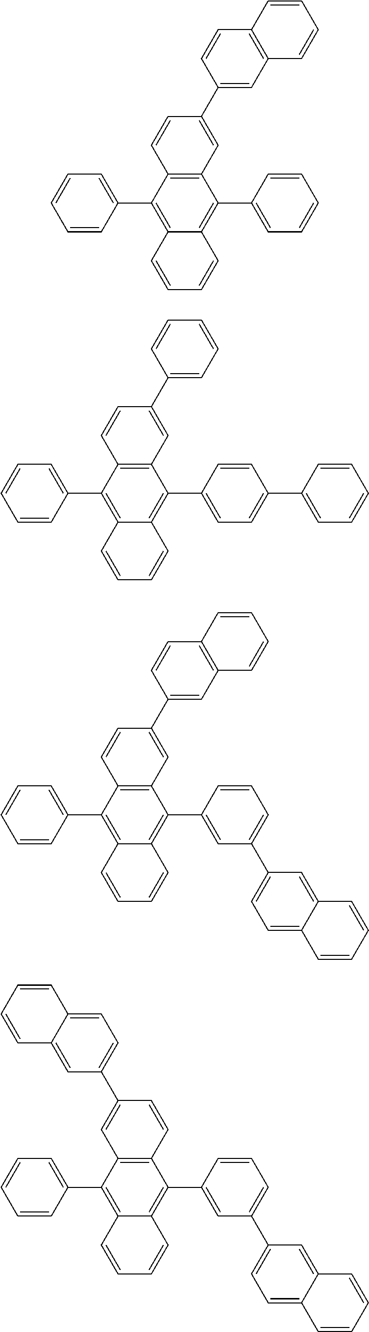

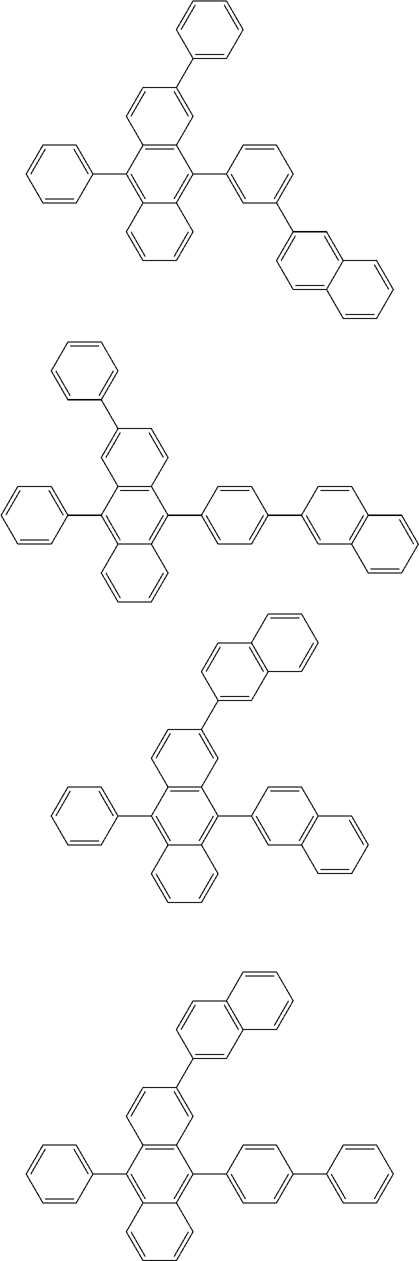

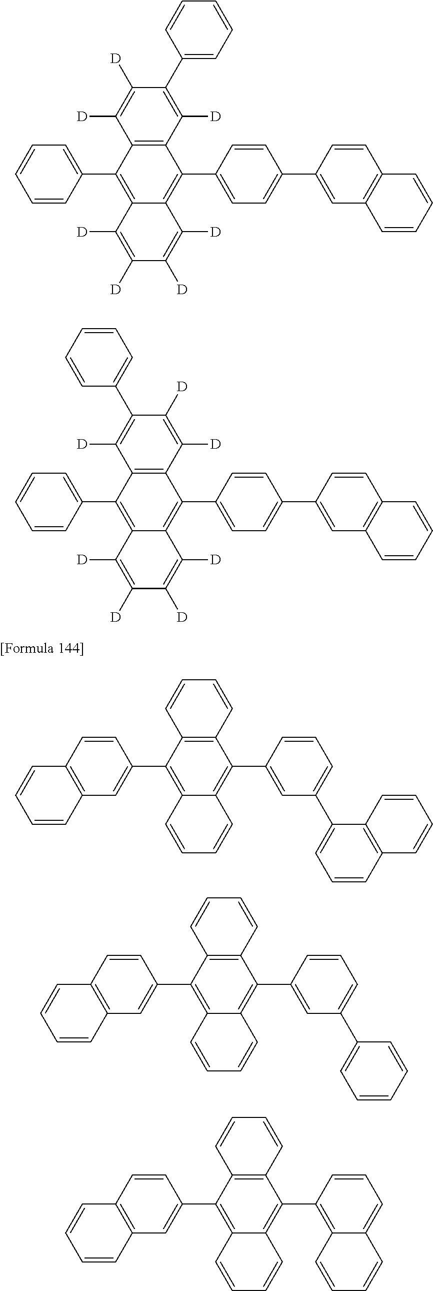

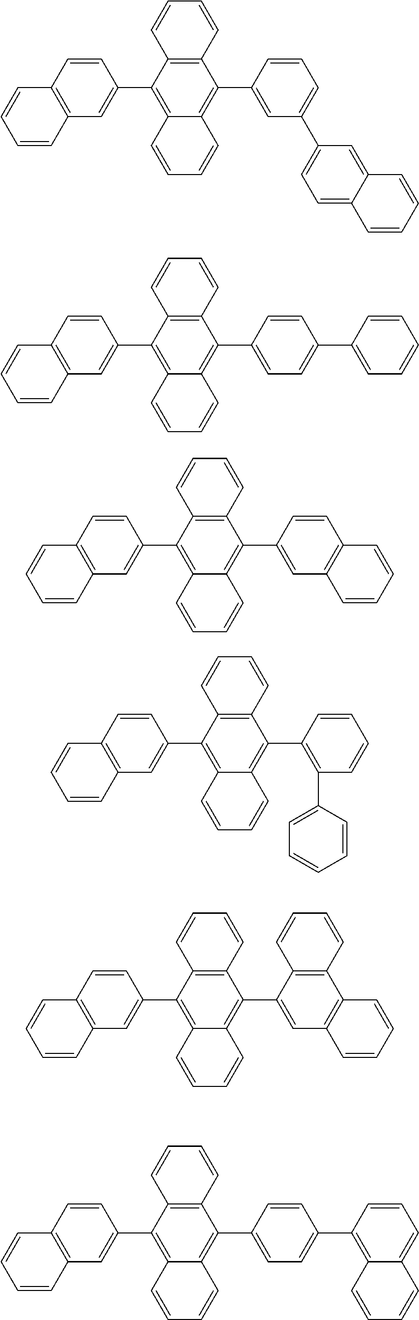

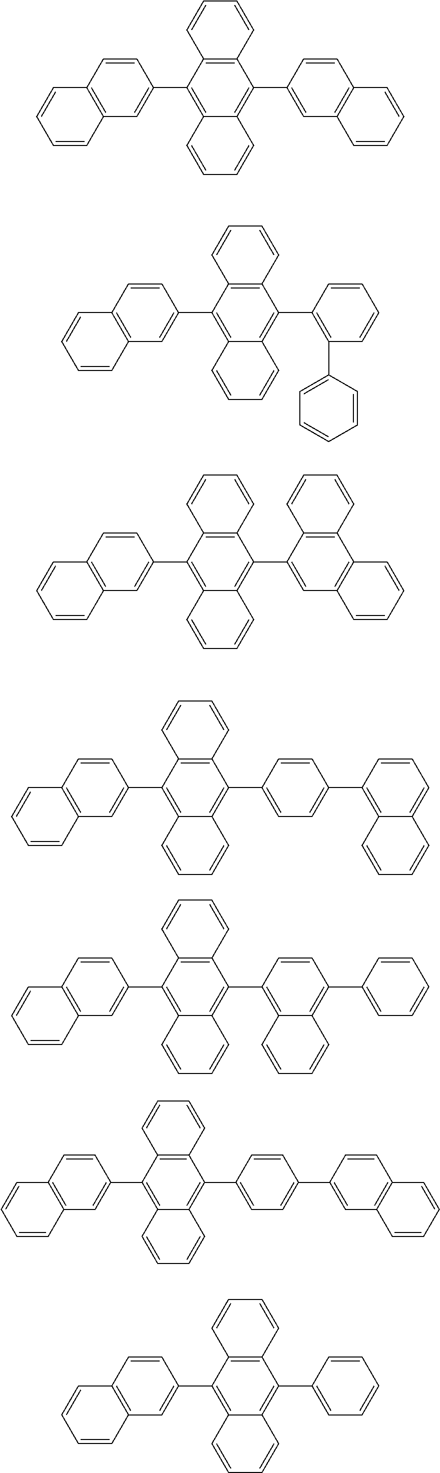

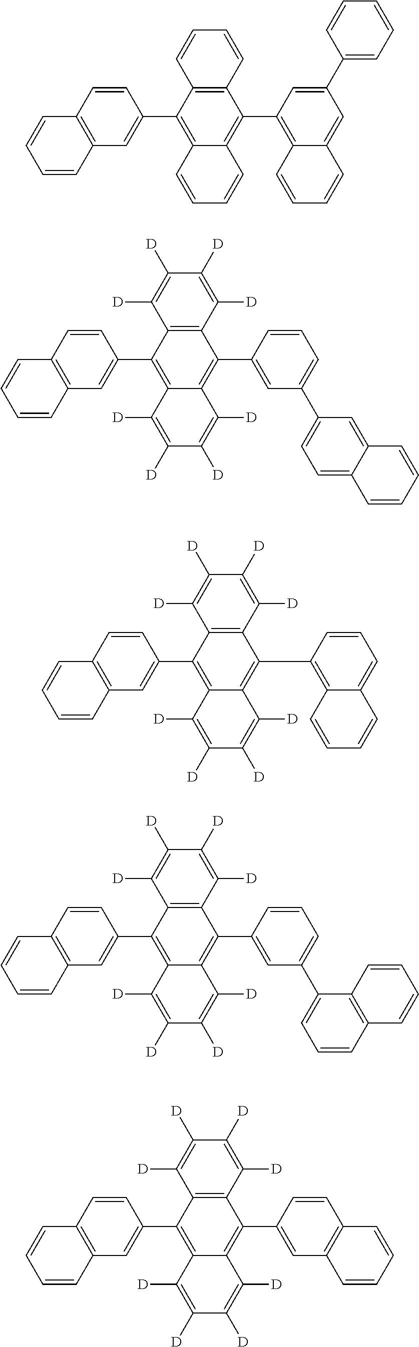

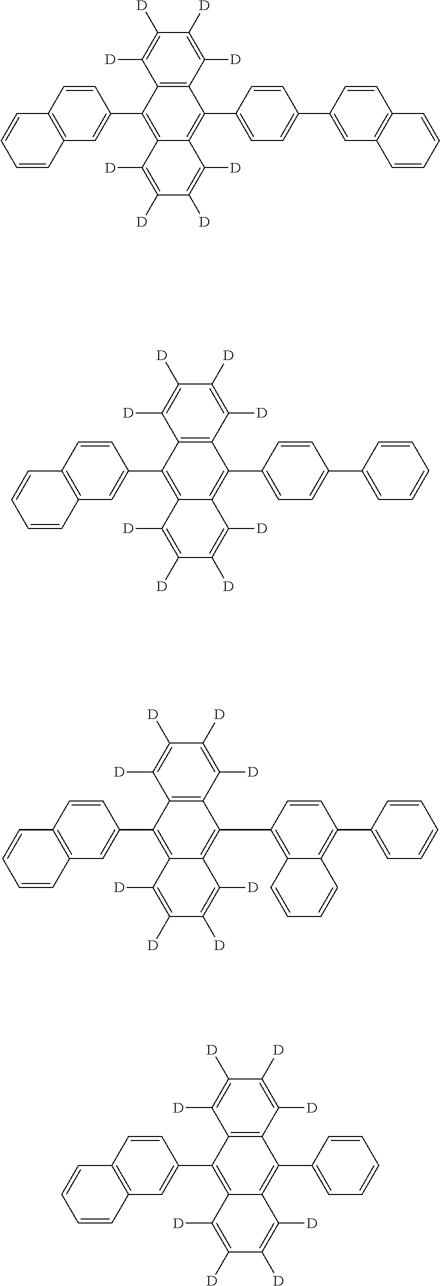 [SMILES: [2H]c1c([2H])c([2H])c2c(-c3ccc4ccccc4c3)c3c([2H])c([2H])c([2H])c([2H])c3c(-c3ccc(-c4ccc5ccccc5c4)cc3)c2c1[2H] ; [2H]c1c([2H])c([2H])c2c(-c3ccc4ccccc4c3)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccccc3)c2c1[2H]]

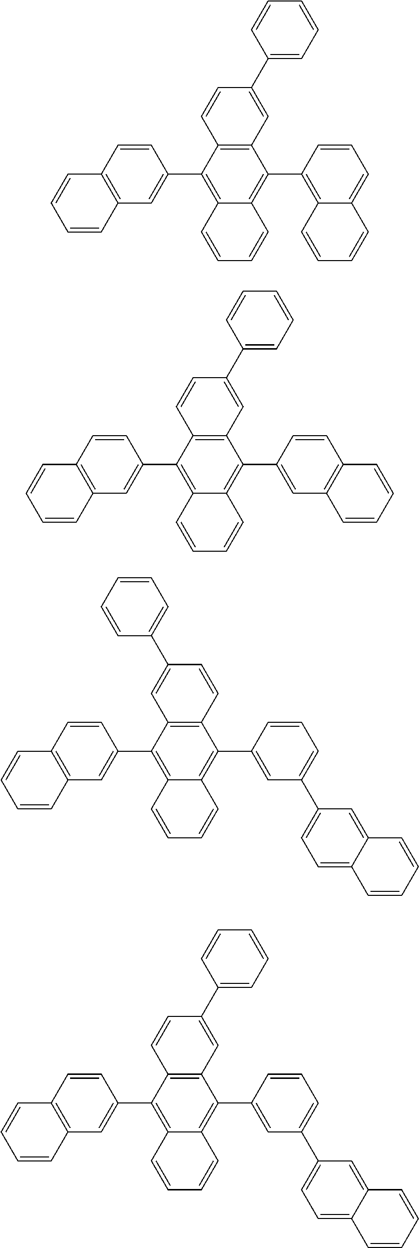

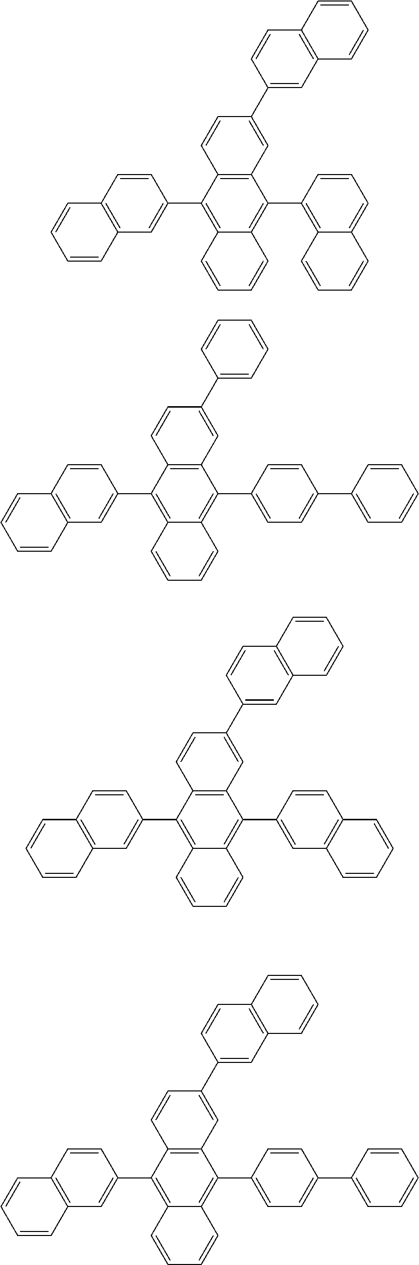

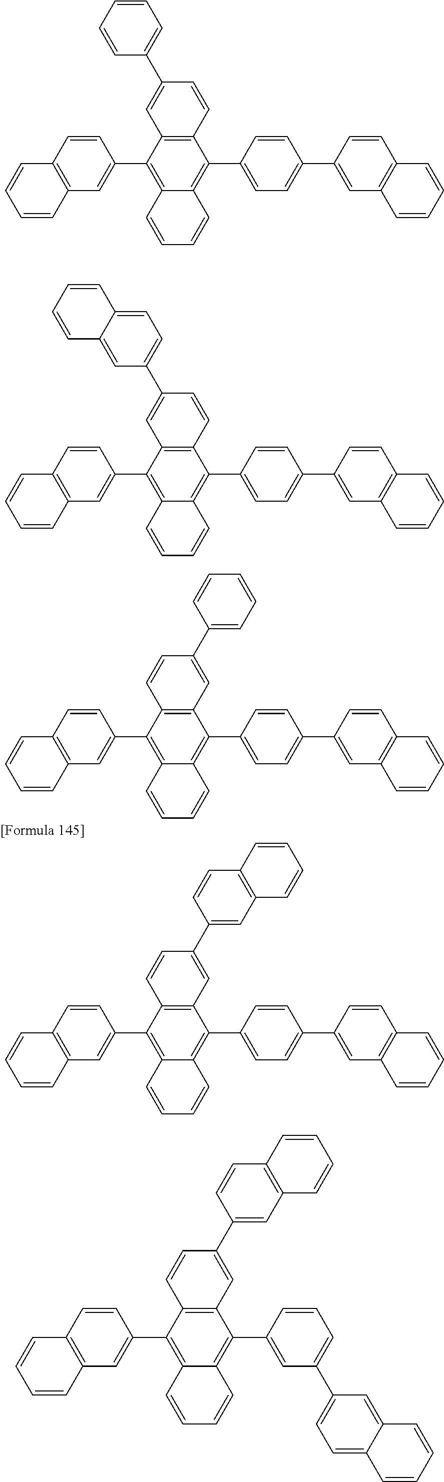

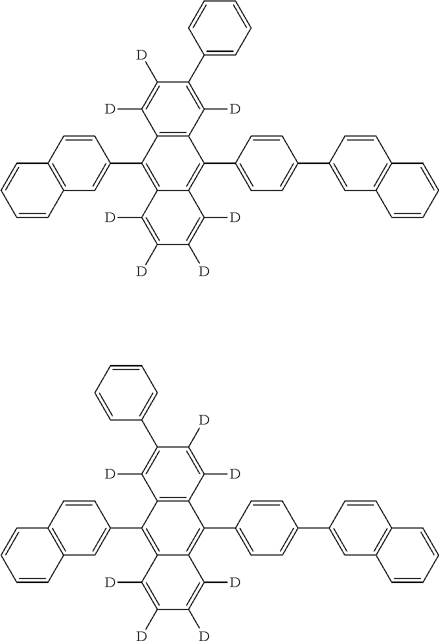 [SMILES: [2H]c1c([2H])c([2H])c2c(-c3ccc(-c4ccc5ccccc5c4)cc3)c3c([2H])c(-c4ccccc4)c([2H])c([2H])c3c(-c3ccc4ccccc4c3)c2c1[2H] ; [2H]c1c([2H])c([2H])c2c(-c3ccc4ccccc4c3)c3c([2H])c(-c4ccccc4)c([2H])c([2H])c3c(-c3ccc(-c4ccc5ccccc5c4)cc3)c2c1[2H]]

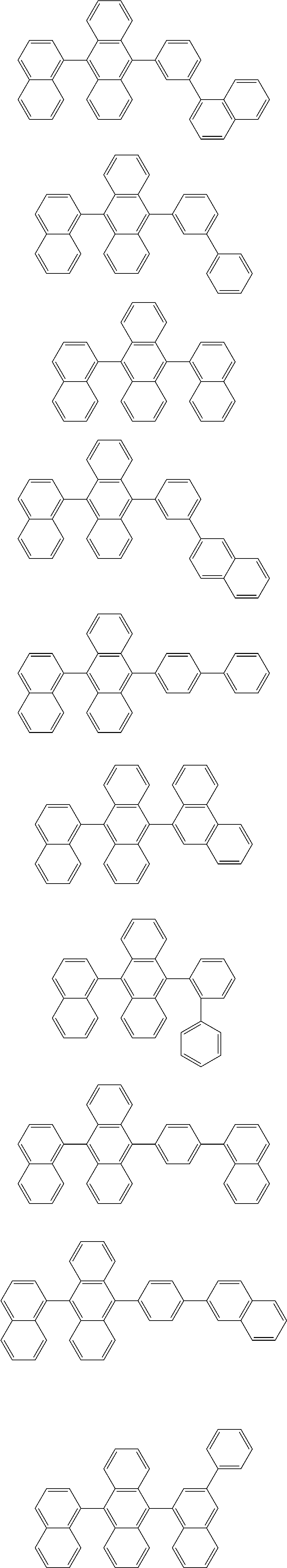

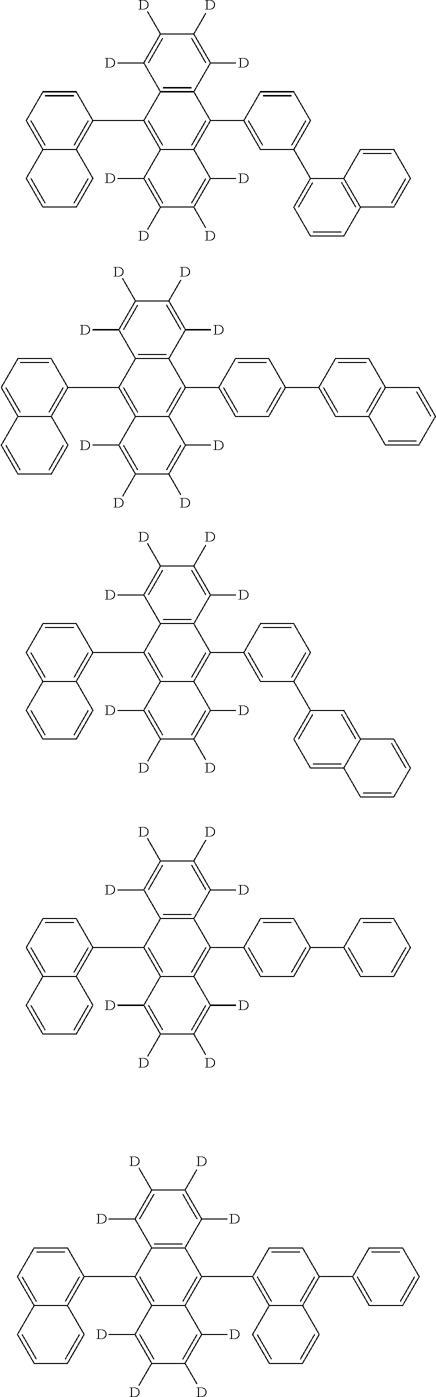

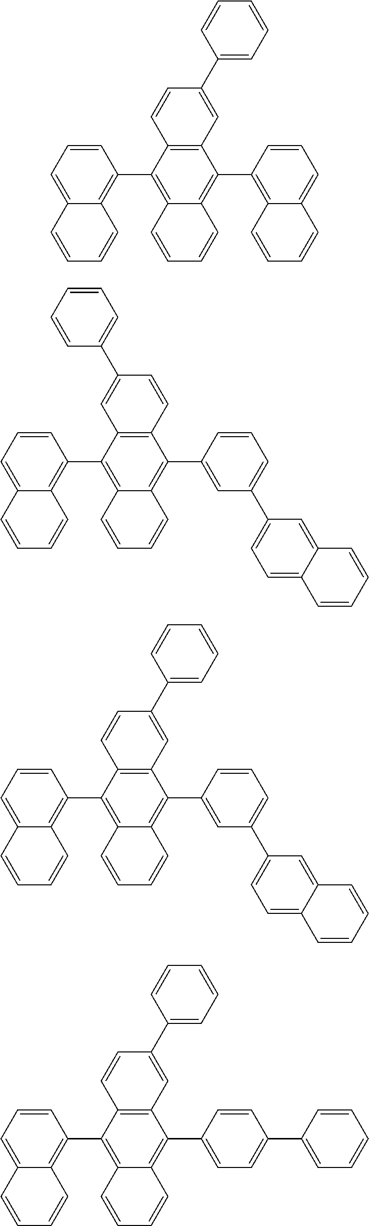

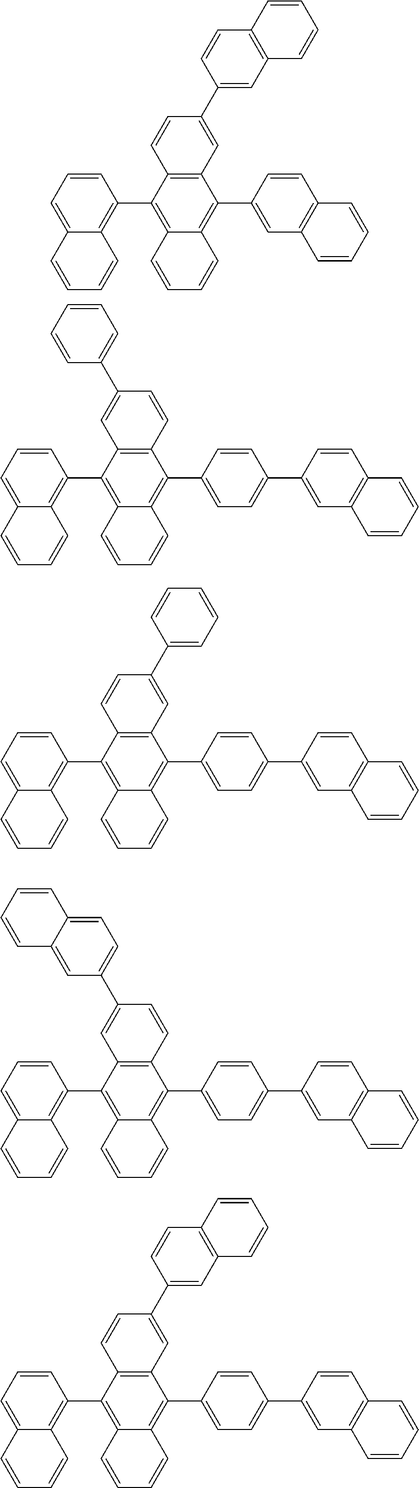

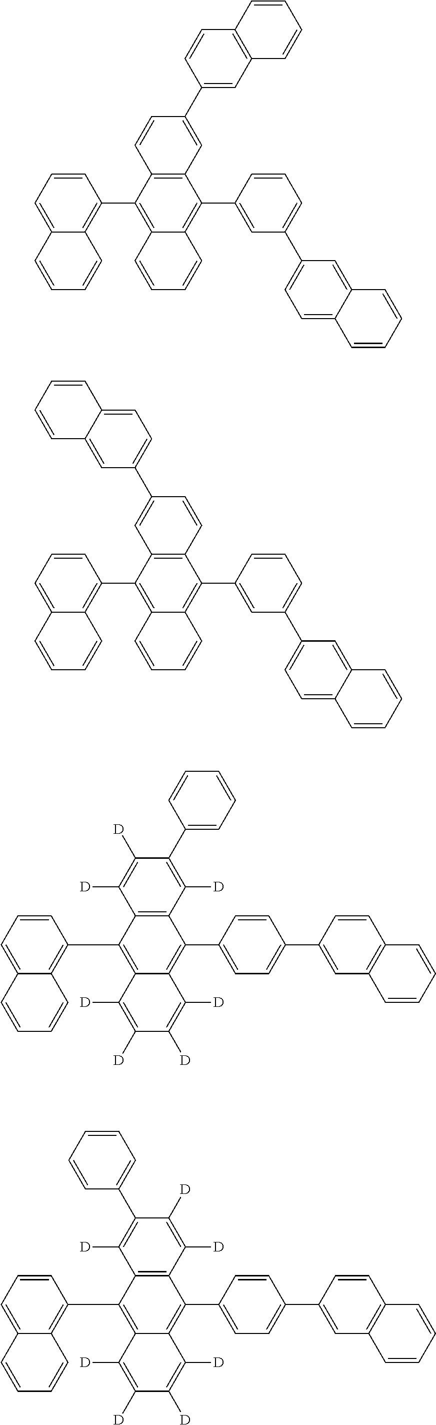

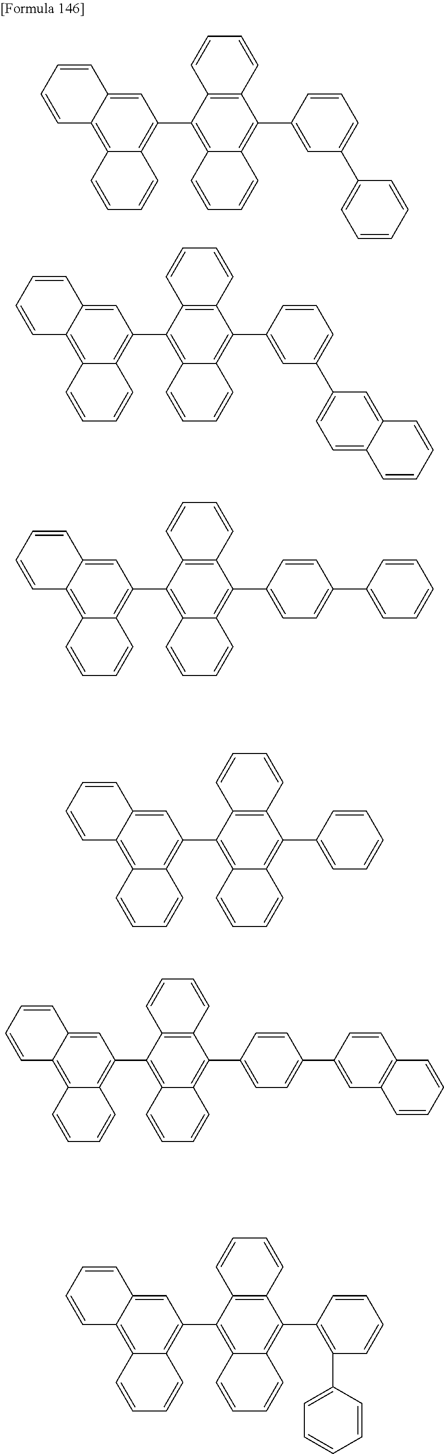

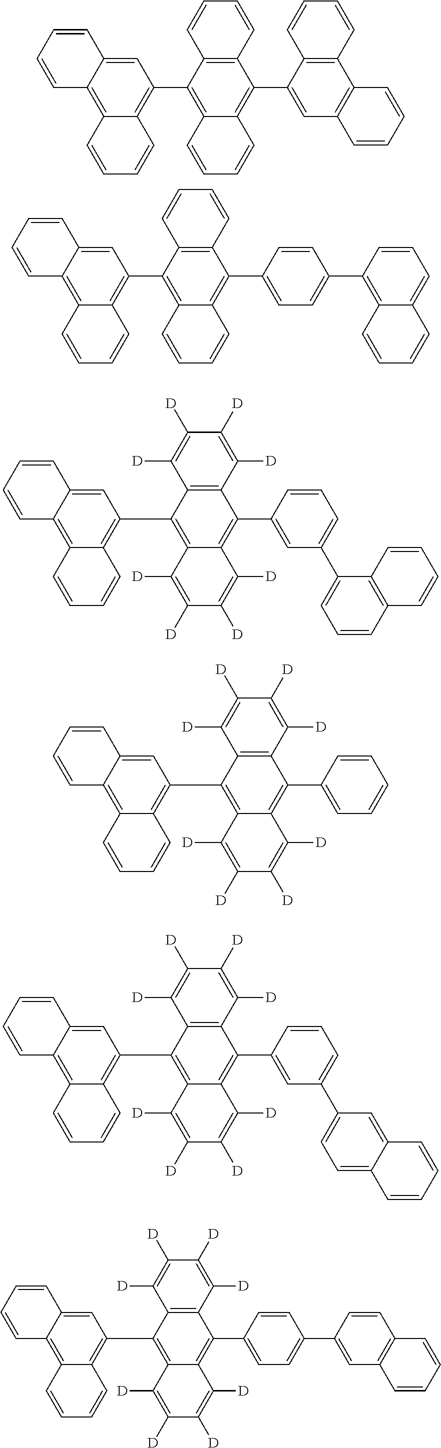

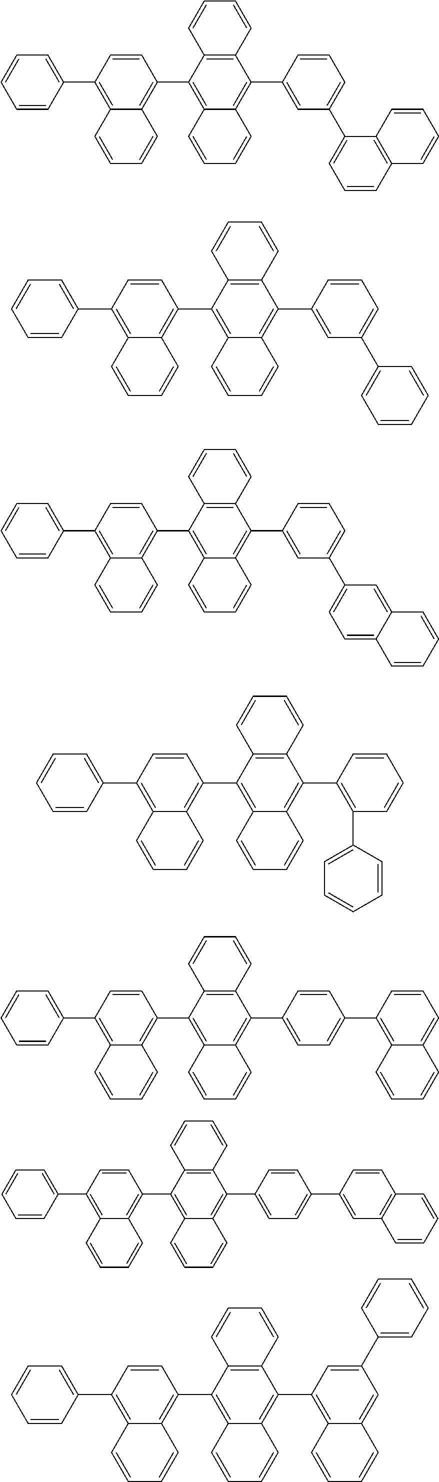

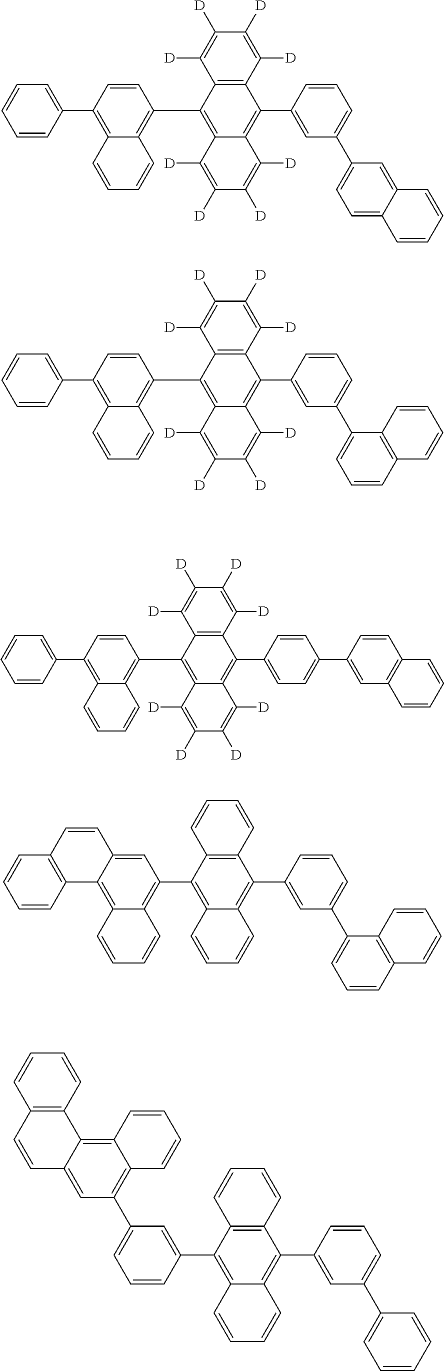

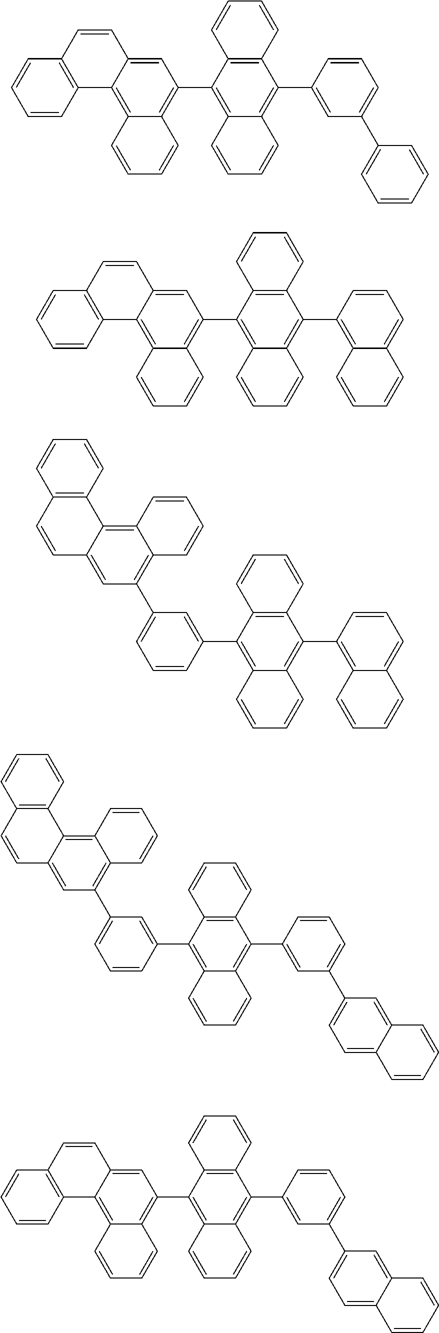

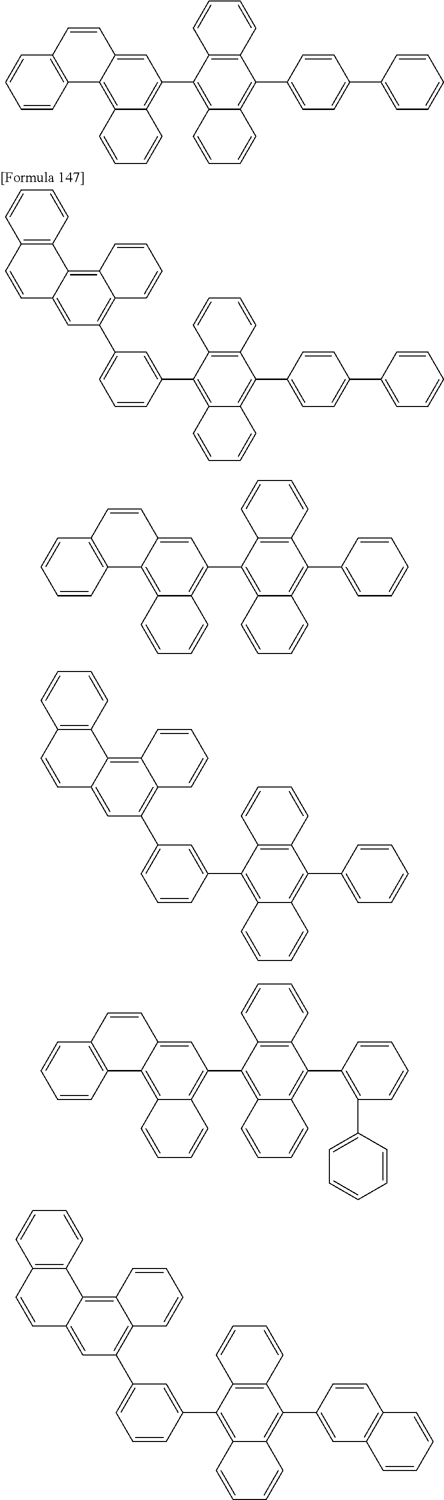

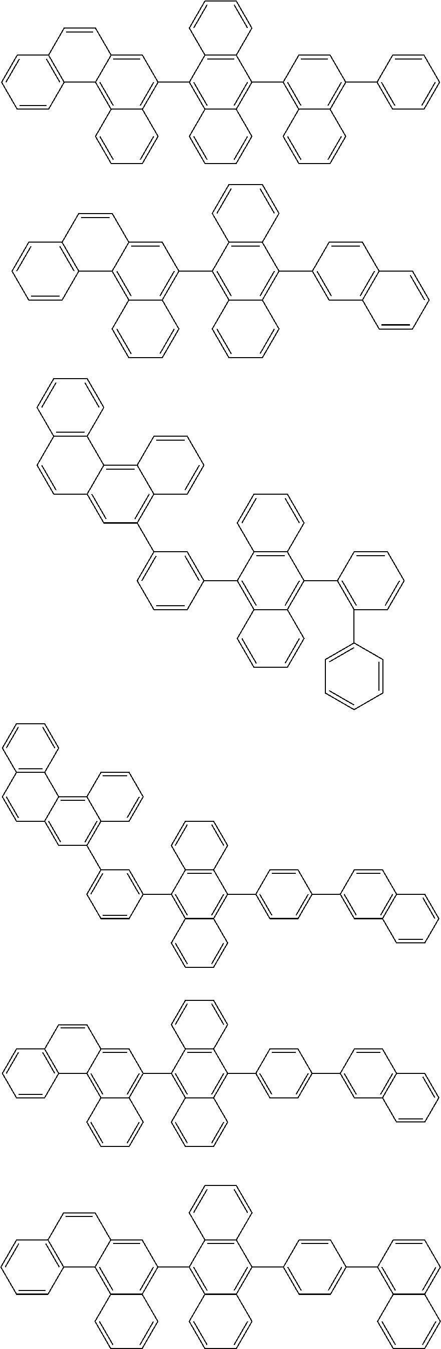

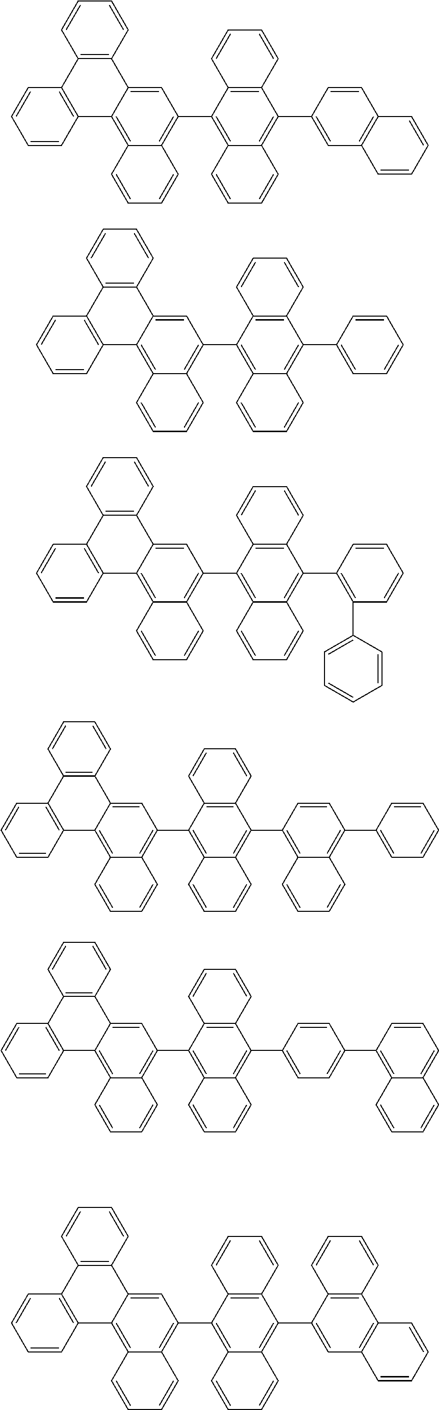

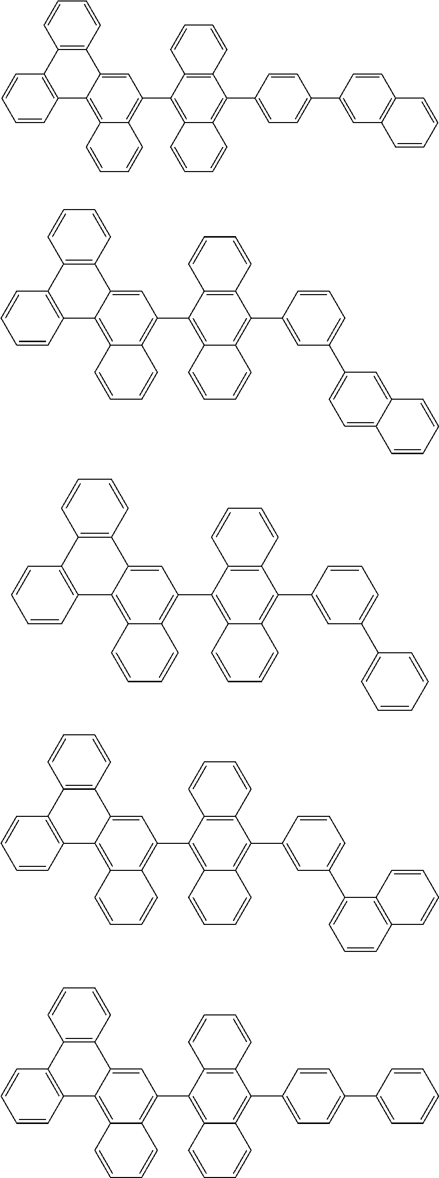

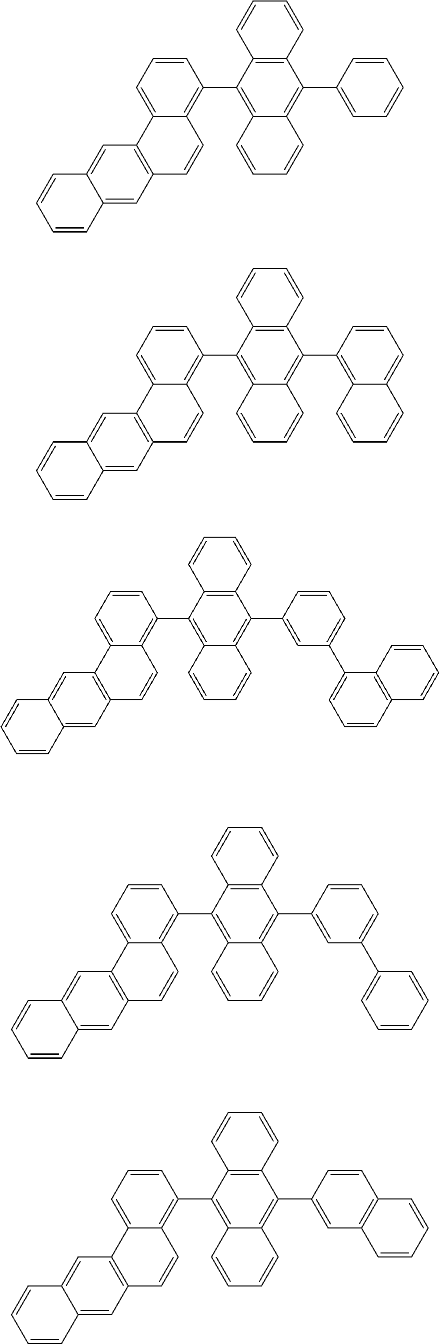

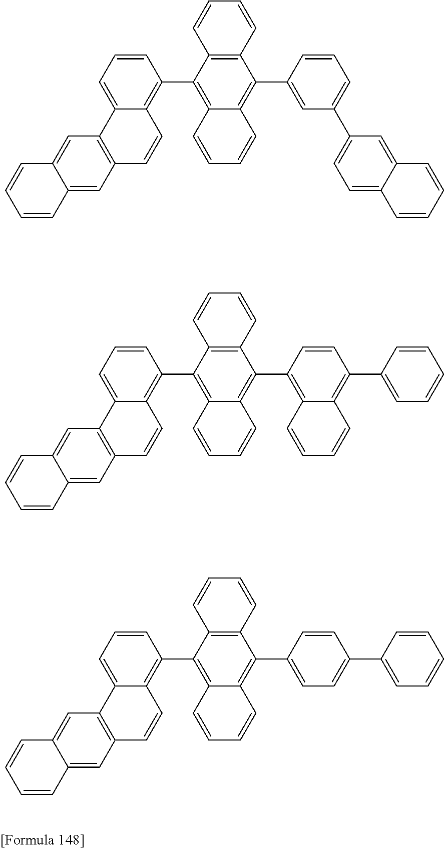

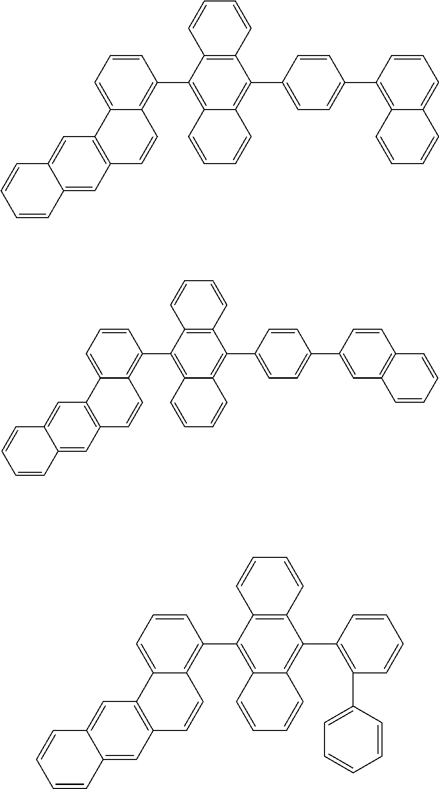

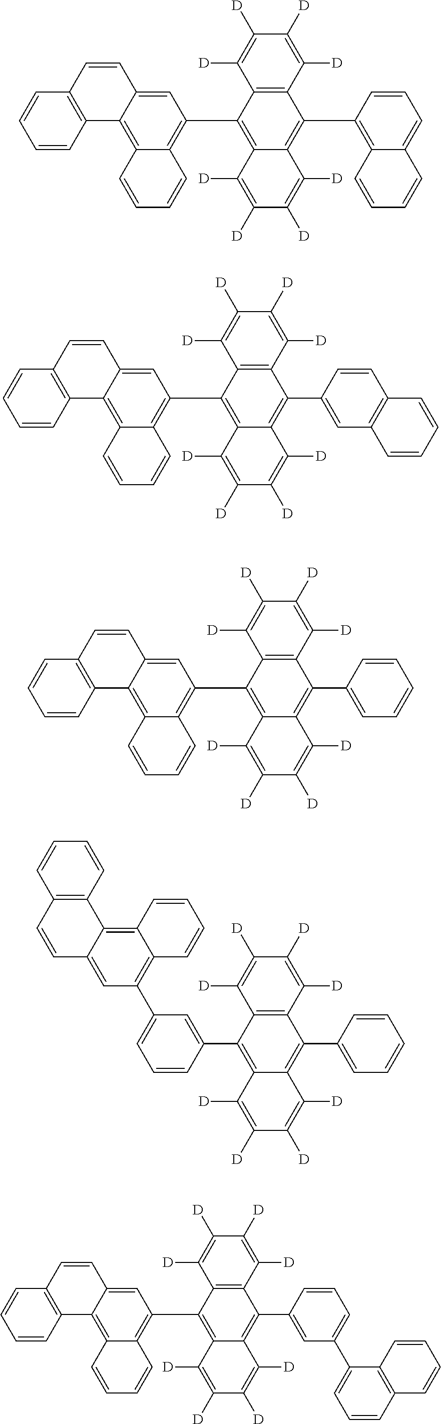

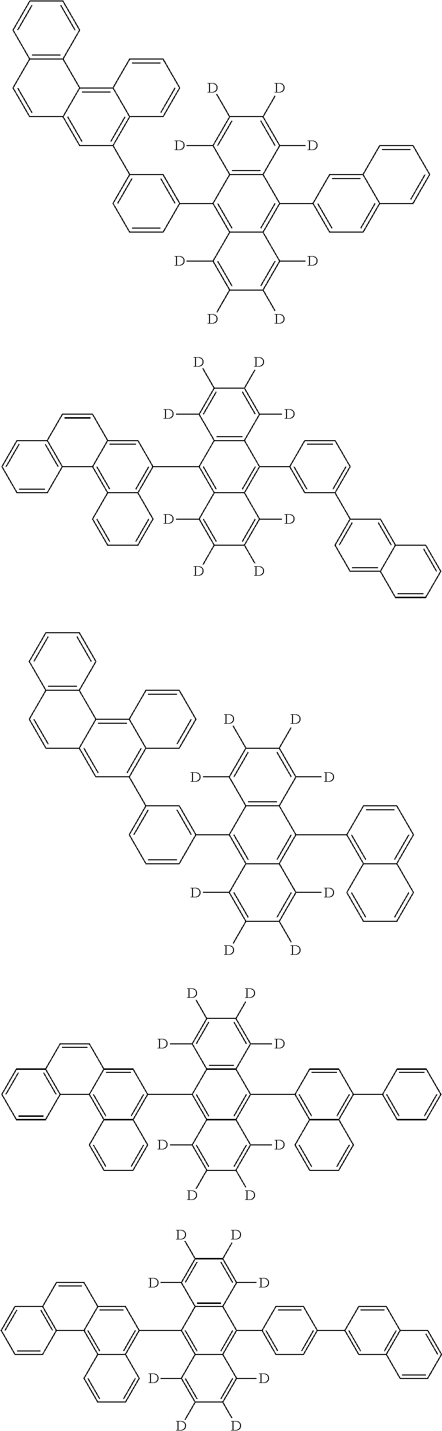

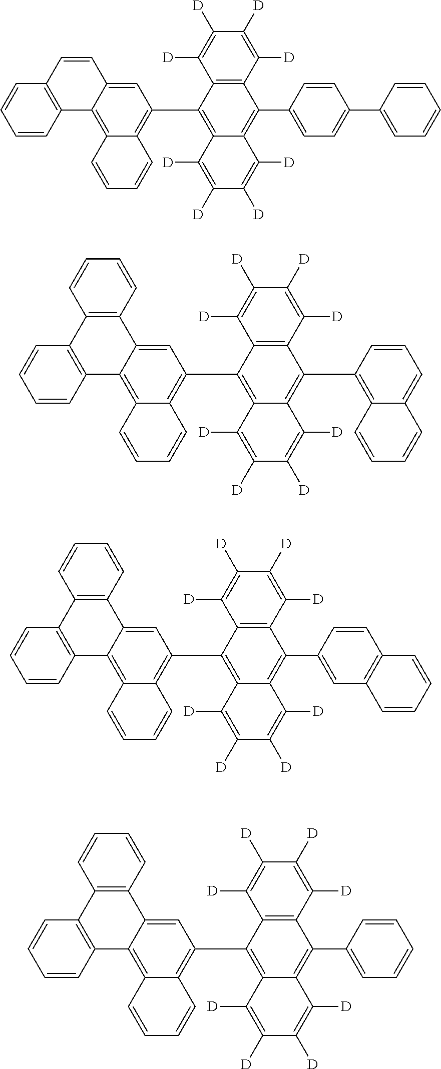 [SMILES: [2H]c1c([2H])c([2H])c2c(-c3cc4ccc5ccccc5c4c4ccccc34)c3c([2H])c([2H])c([2H])c([2H])c3c(-c3ccc(-c4ccccc4)cc3)c2c1[2H] ; [2H]c1c([2H])c([2H])c2c(-c3cc4c5ccccc5c5ccccc5c4c4ccccc34)c3c([2H])c([2H])c([2H])c([2H])c3c(-c3cccc4ccccc34)c2c1[2H] ; [2H]c1c([2H])c([2H])c2c(-c3cc4c5ccccc5c5ccccc5c4c4ccccc34)c3c([2H])c([2H])c([2H])c([2H])c3c(-c3ccc4ccccc4c3)c2c1[2H] ; [2H]c1c([2H])c([2H])c2c(-c3cc4c5ccccc5c5ccccc5c4c4ccccc34)c3c([2H])c([2H])c([2H])c([2H])c3c(-c3ccccc3)c2c1[2H]]

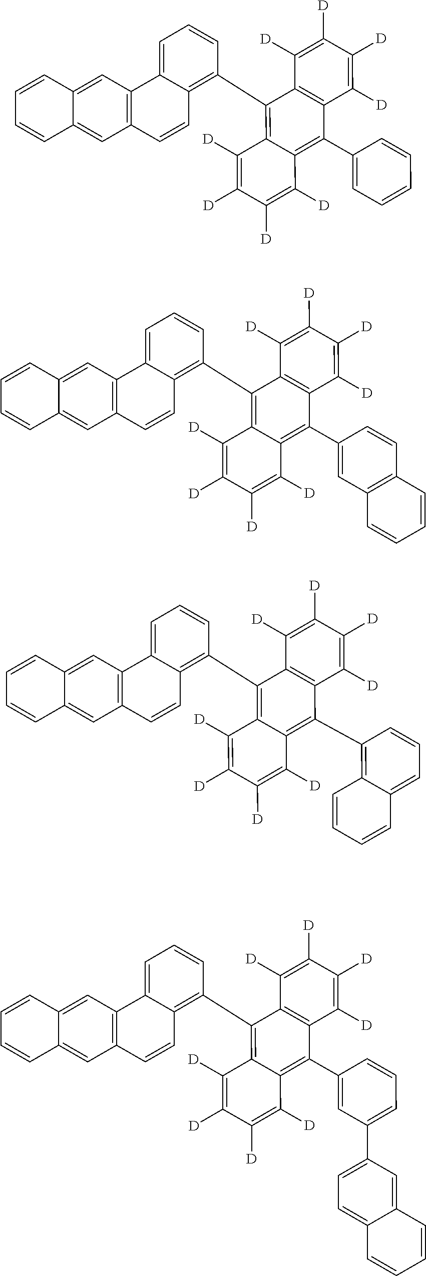 [SMILES: [2H]c1c([2H])c([2H])c2c(-c3cccc4c3ccc3cc5ccccc5cc34)c3c([2H])c([2H])c([2H])c([2H])c3c(-c3ccccc3)c2c1[2H] ; [2H]c1c([2H])c([2H])c2c(-c3cccc4c3ccc3cc5ccccc5cc34)c3c([2H])c([2H])c([2H])c([2H])c3c(-c3ccc4ccccc4c3)c2c1[2H] ; [2H]c1c([2H])c([2H])c2c(-c3cccc4c3ccc3cc5ccccc5cc34)c3c([2H])c([2H])c([2H])c([2H])c3c(-c3cccc4ccccc34)c2c1[2H] ; [2H]c1c([2H])c([2H])c2c(-c3cccc4c3ccc3cc5ccccc5cc34)c3c([2H])c([2H])c([2H])c([2H])c3c(-c3cccc(-c4ccc5ccccc5c4)c3)c2c1[2H]]

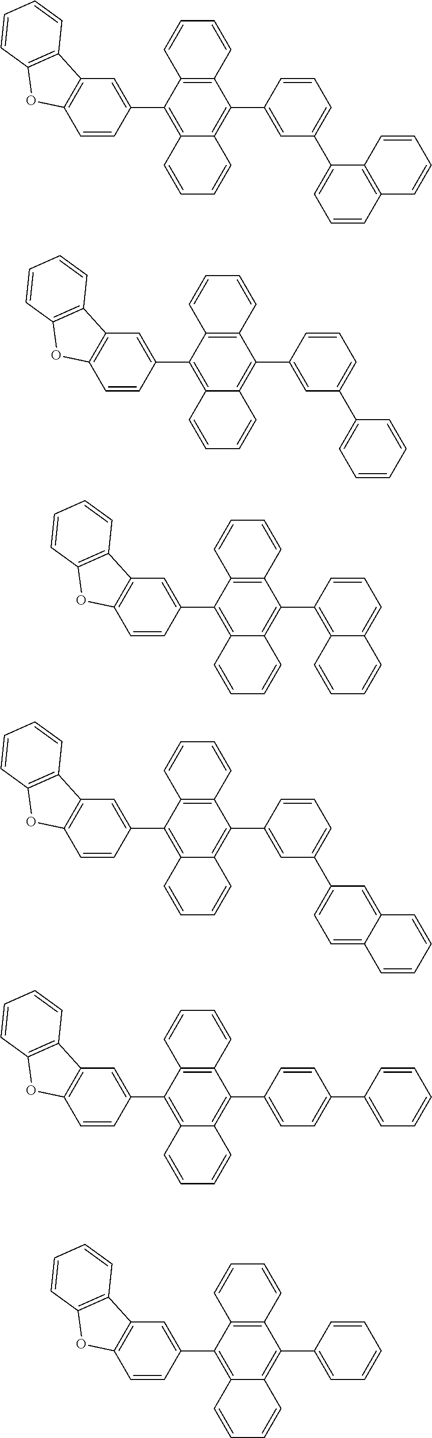 [SMILES: c1cc(-c2cccc3ccccc23)cc(-c2c3ccccc3c(-c3ccc4oc5ccccc5c4c3)c3ccccc23)c1 ; c1ccc(-c2cccc(-c3c4ccccc4c(-c4ccc5oc6ccccc6c5c4)c4ccccc34)c2)cc1 ; c1ccc2c(-c3c4ccccc4c(-c4ccc5oc6ccccc6c5c4)c4ccccc34)cccc2c1 ; c1cc(-c2ccc3ccccc3c2)cc(-c2c3ccccc3c(-c3ccc4oc5ccccc5c4c3)c3ccccc23)c1 ; c1ccc(-c2ccc(-c3c4ccccc4c(-c4ccc5oc6ccccc6c5c4)c4ccccc34)cc2)cc1 ; c1ccc(-c2c3ccccc3c(-c3ccc4oc5ccccc5c4c3)c3ccccc23)cc1]

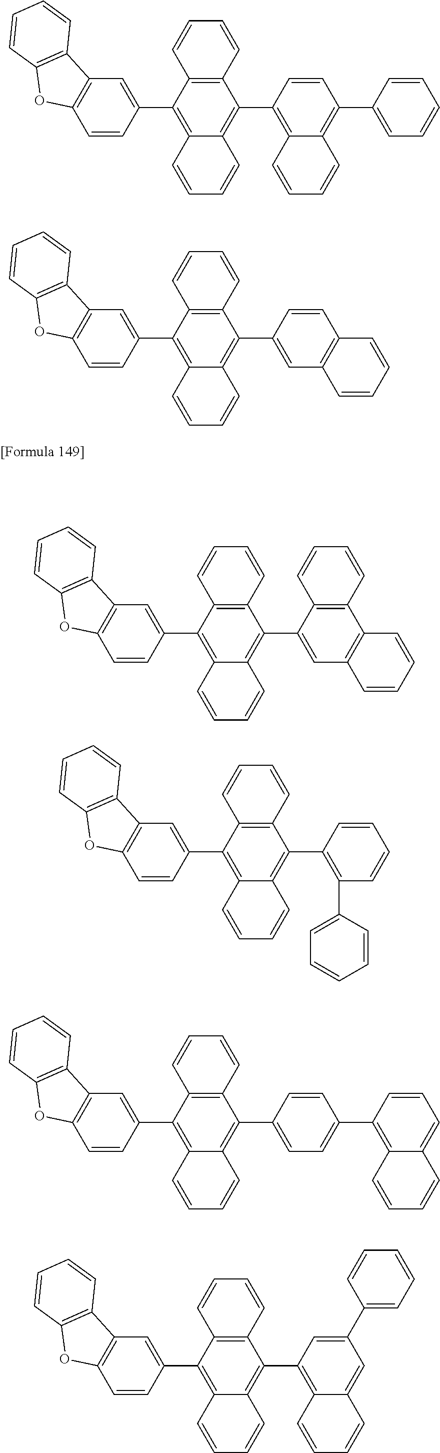

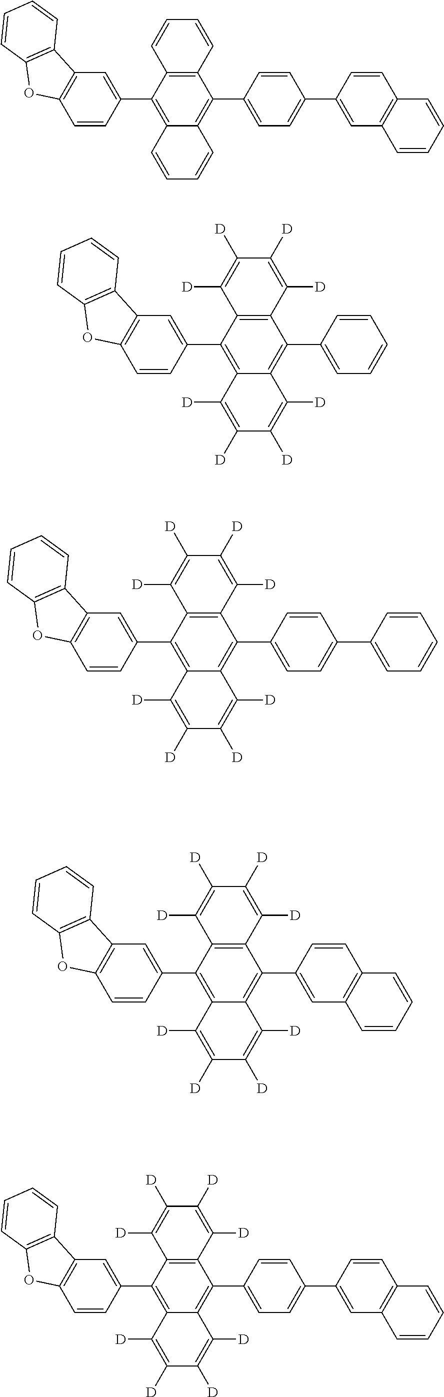

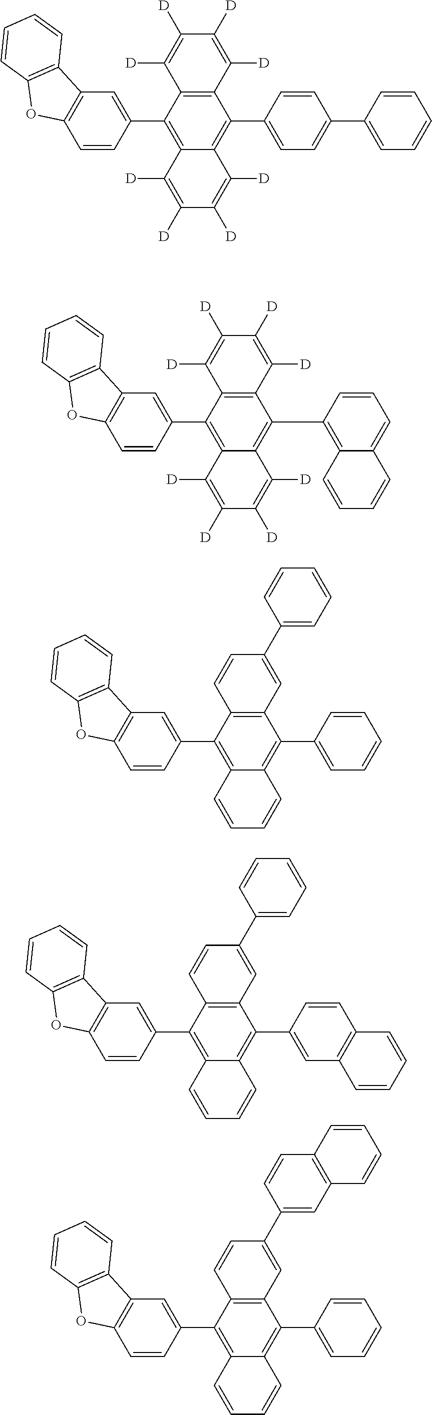

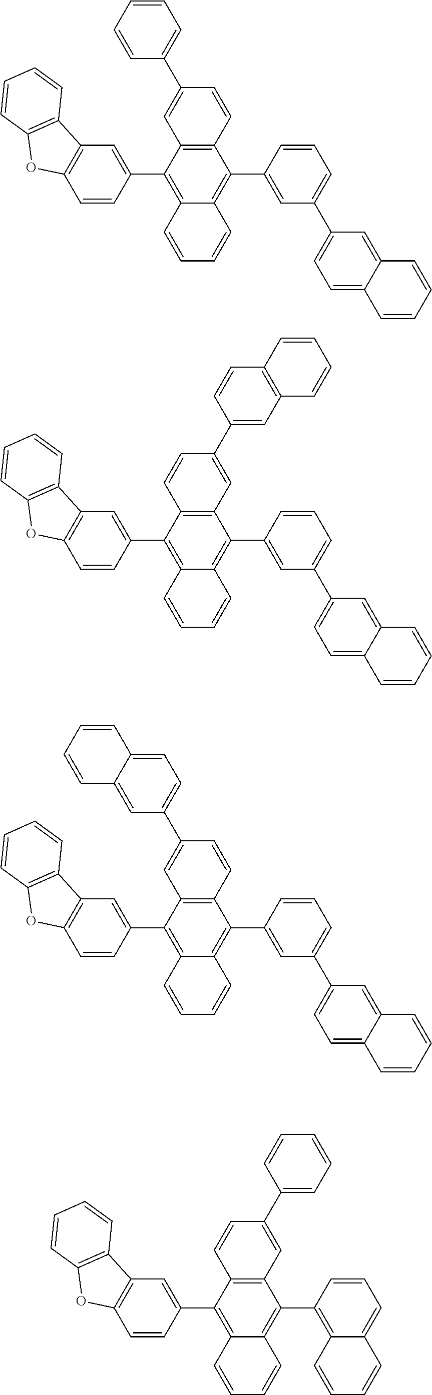 [SMILES: c1ccc(-c2ccc3c(-c4cccc(-c5ccc6ccccc6c5)c4)c4ccccc4c(-c4ccc5oc6ccccc6c5c4)c3c2)cc1 ; c1cc(-c2ccc3ccccc3c2)cc(-c2c3ccccc3c(-c3ccc4oc5ccccc5c4c3)c3ccc(-c4ccc5ccccc5c4)cc23)c1 ; c1cc(-c2ccc3ccccc3c2)cc(-c2c3ccccc3c(-c3ccc4oc5ccccc5c4c3)c3cc(-c4ccc5ccccc5c4)ccc23)c1 ; c1ccc(-c2ccc3c(-c4ccc5oc6ccccc6c5c4)c4ccccc4c(-c4cccc5ccccc45)c3c2)cc1]

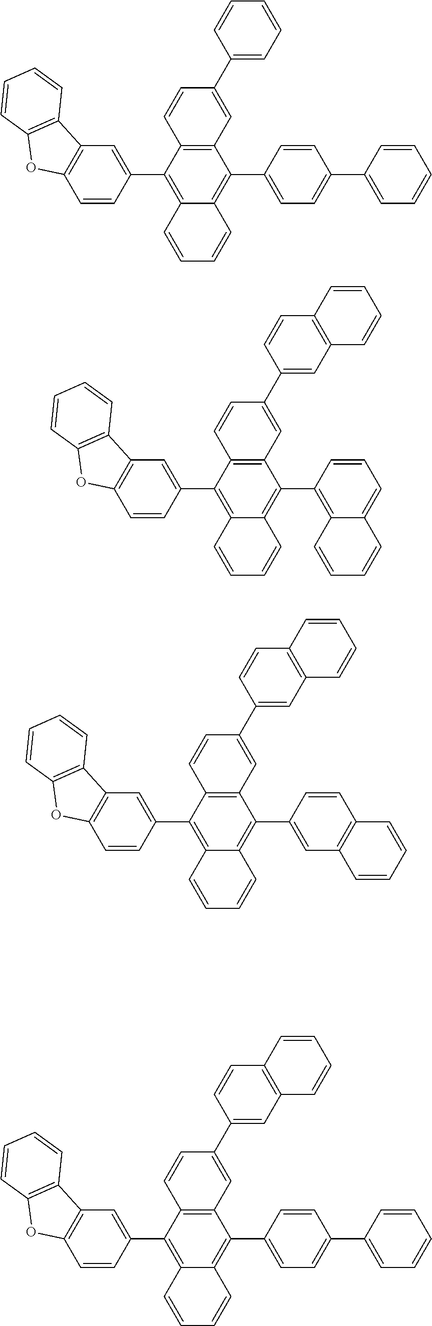

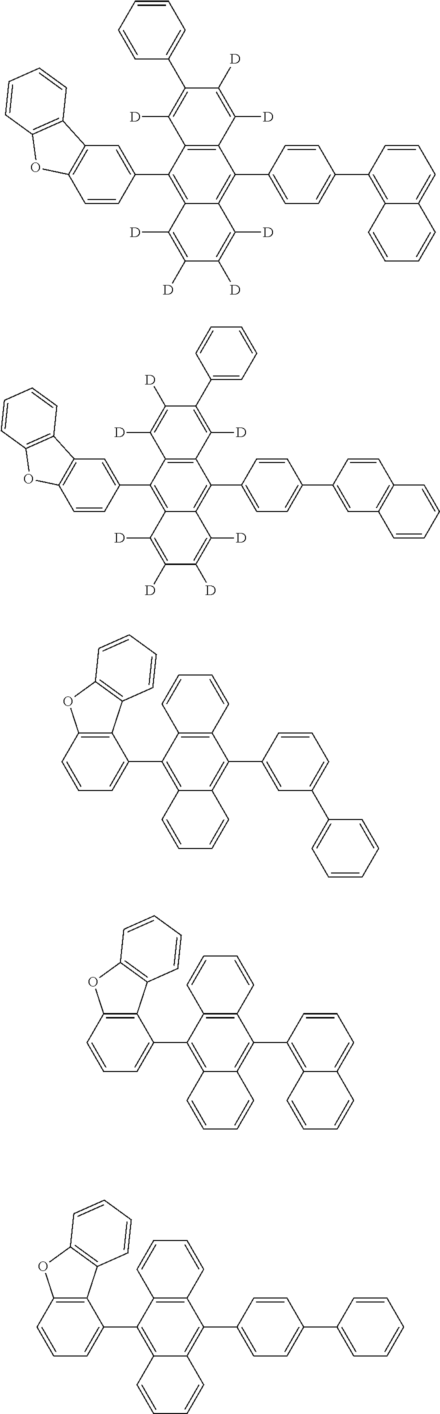

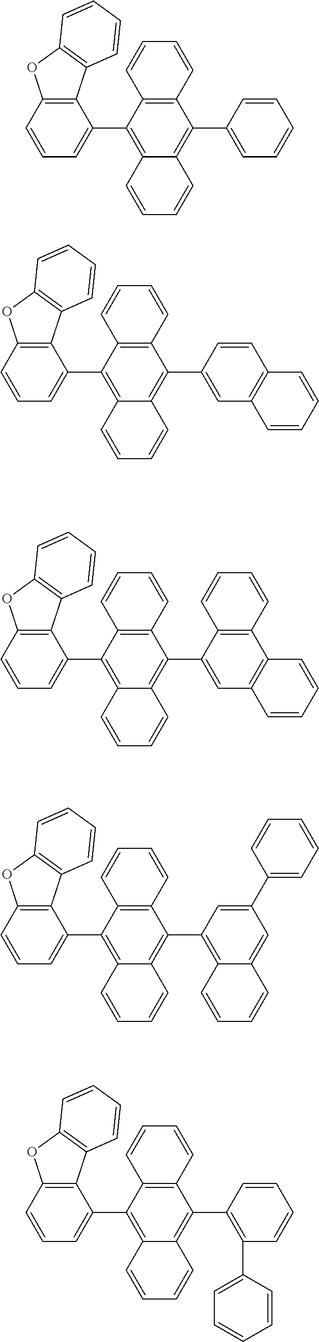 [SMILES: c1ccc(-c2c3ccccc3c(-c3cccc4oc5ccccc5c34)c3ccccc23)cc1 ; c1ccc2cc(-c3c4ccccc4c(-c4cccc5oc6ccccc6c45)c4ccccc34)ccc2c1 ; c1ccc2c(c1)cc(-c1c3ccccc3c(-c3cccc4oc5ccccc5c34)c3ccccc13)c1ccccc12 ; c1ccc(-c2cc(-c3c4ccccc4c(-c4cccc5oc6ccccc6c45)c4ccccc34)c3ccccc3c2)cc1 ; c1ccc(-c2ccccc2-c2c3ccccc3c(-c3cccc4oc5ccccc5c34)c3ccccc23)cc1]

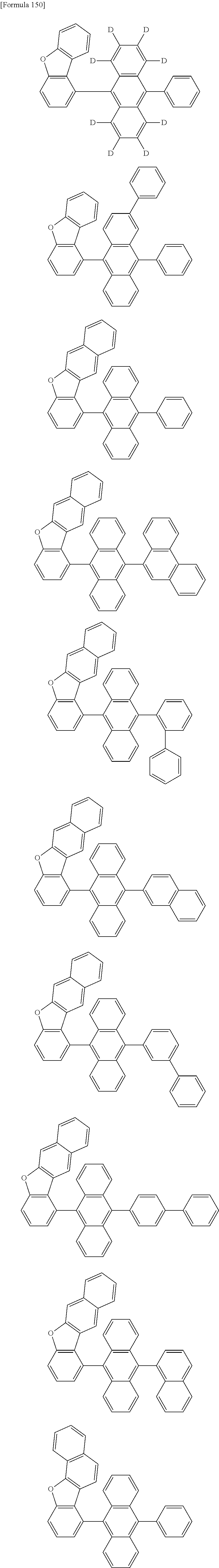

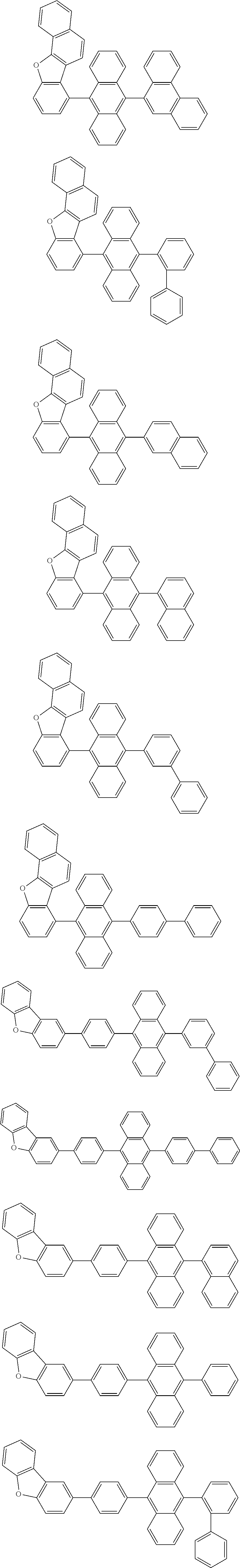

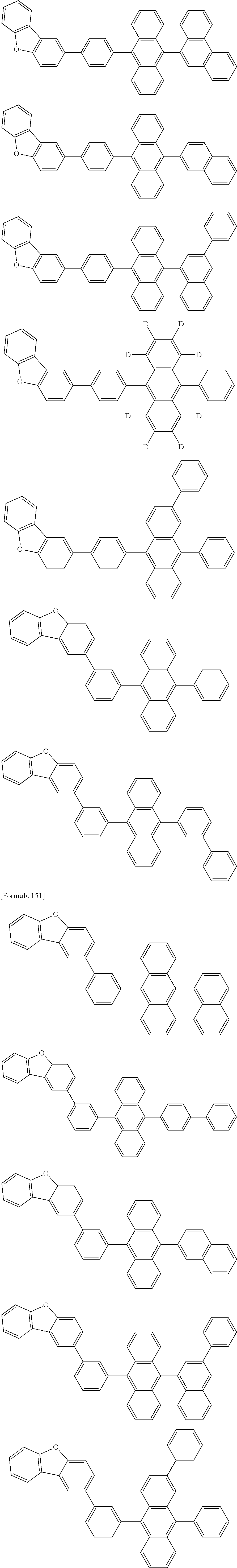

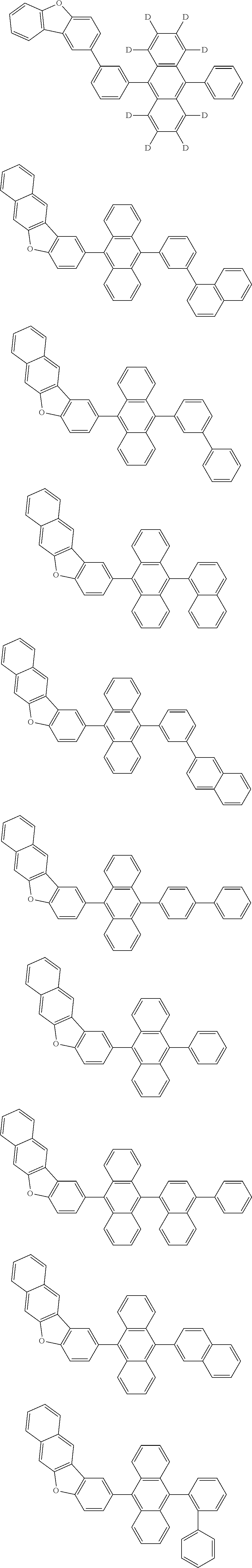

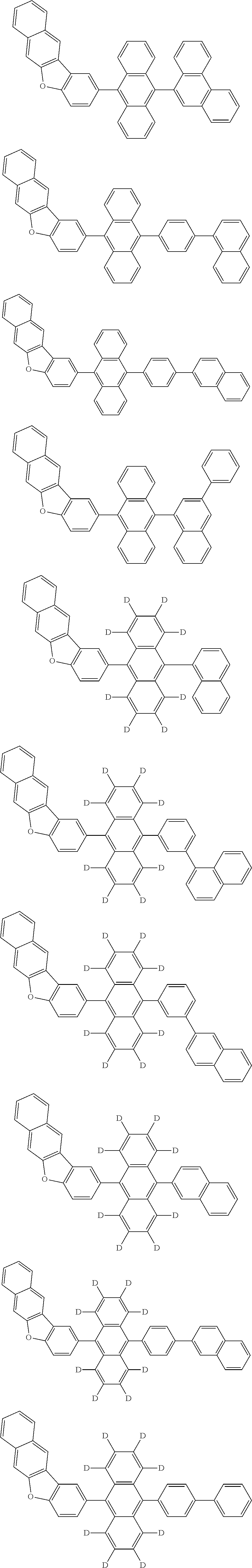

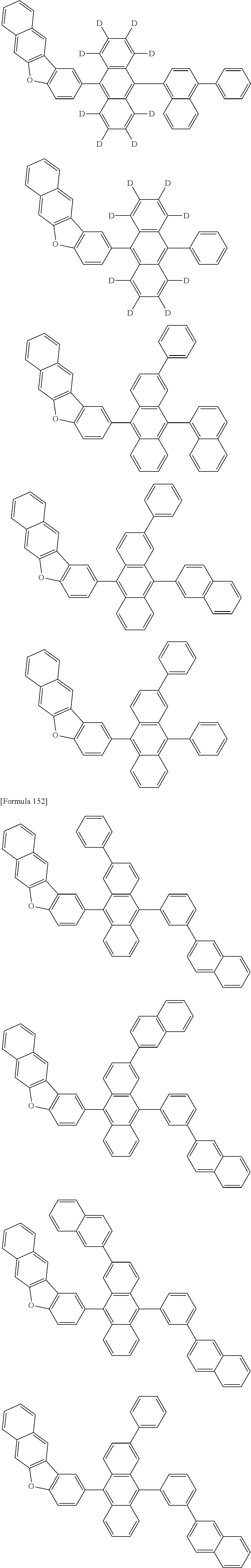

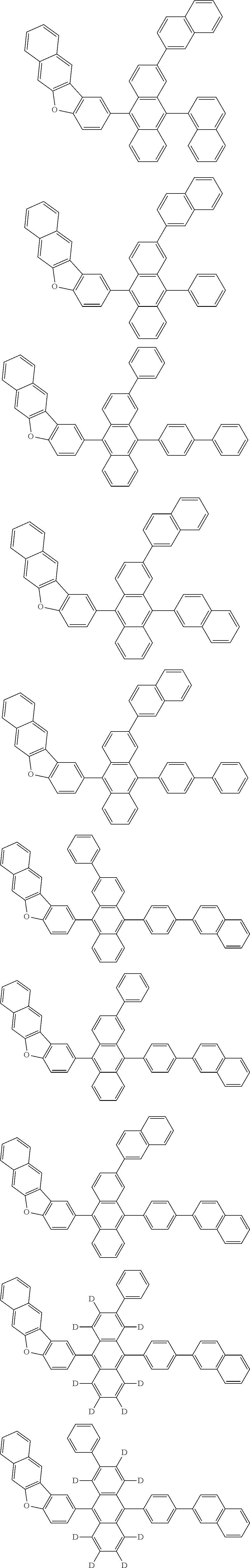

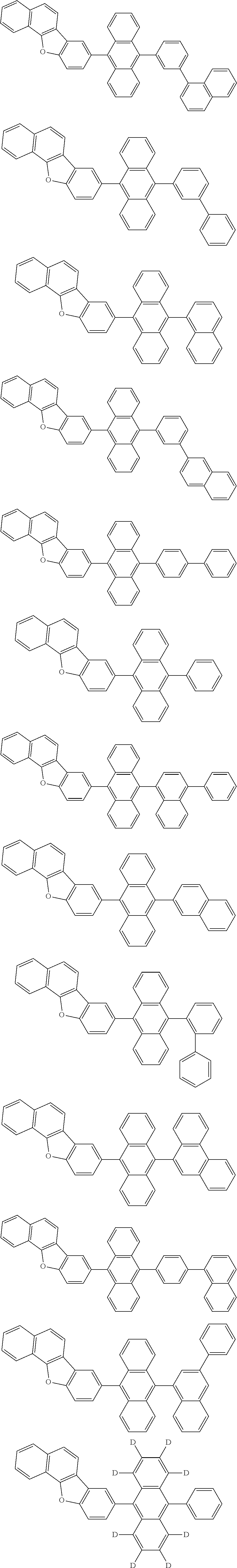

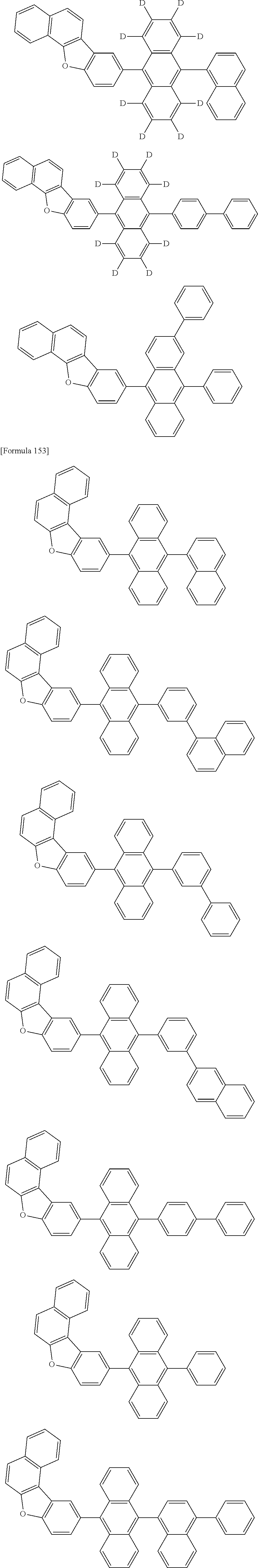

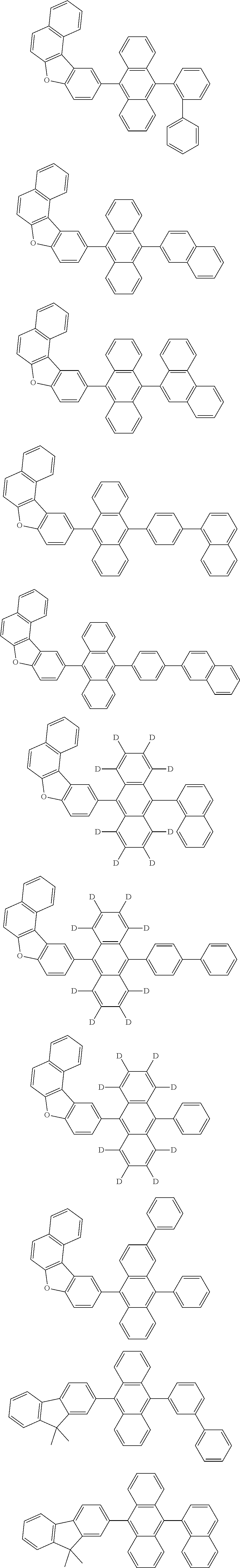

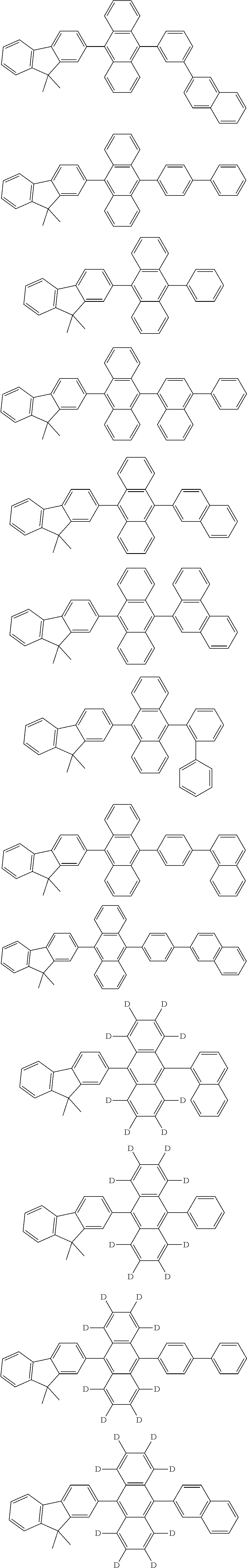

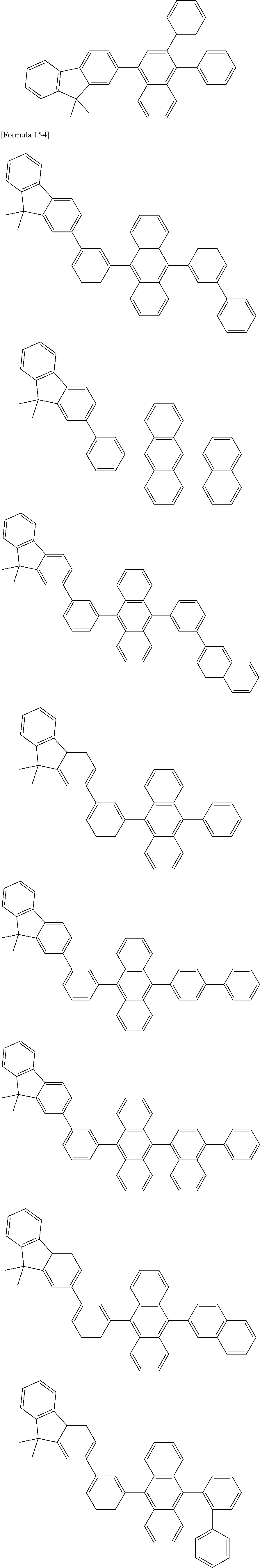

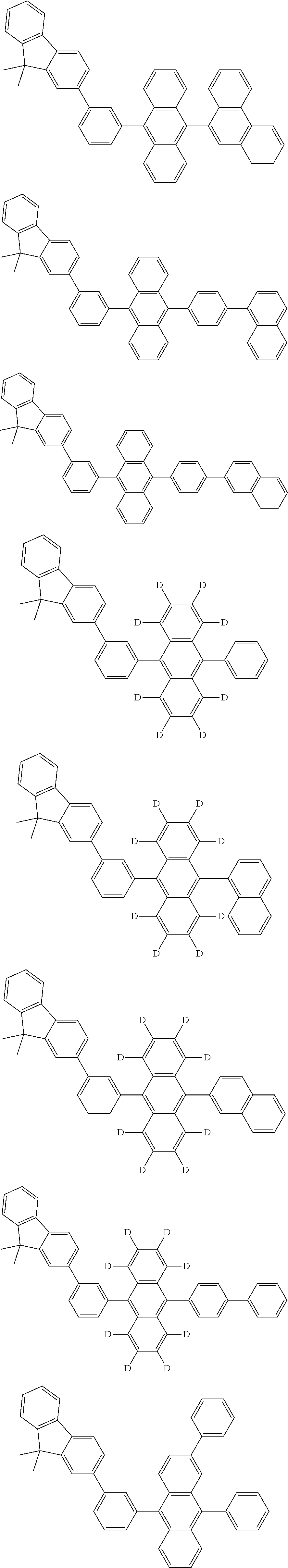

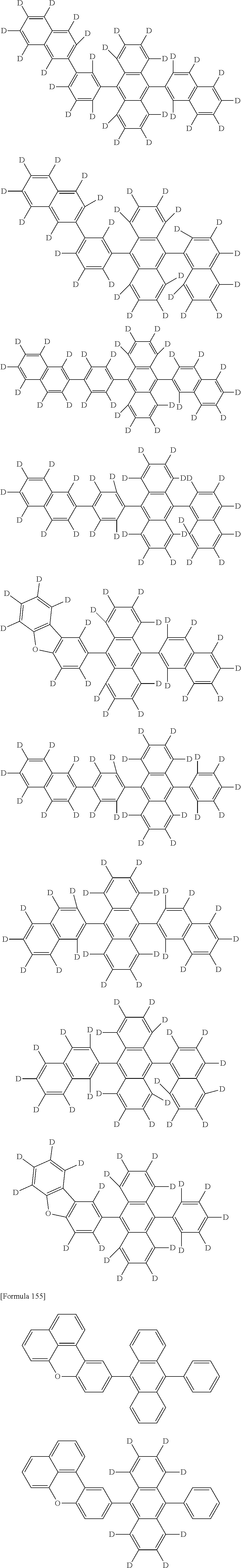

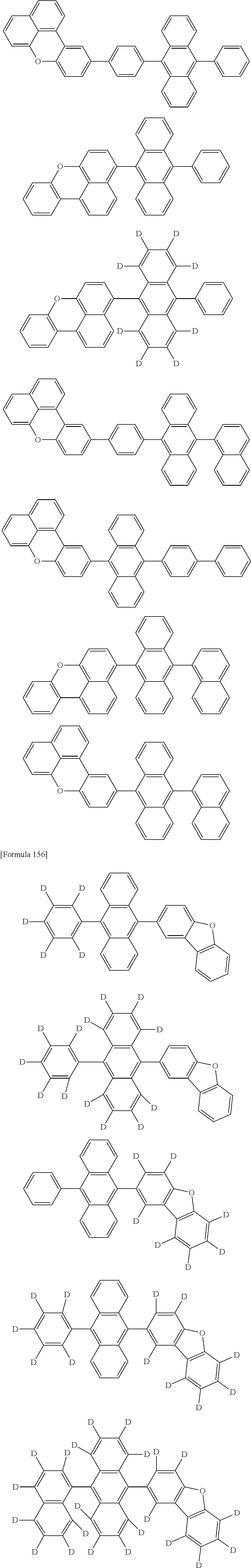

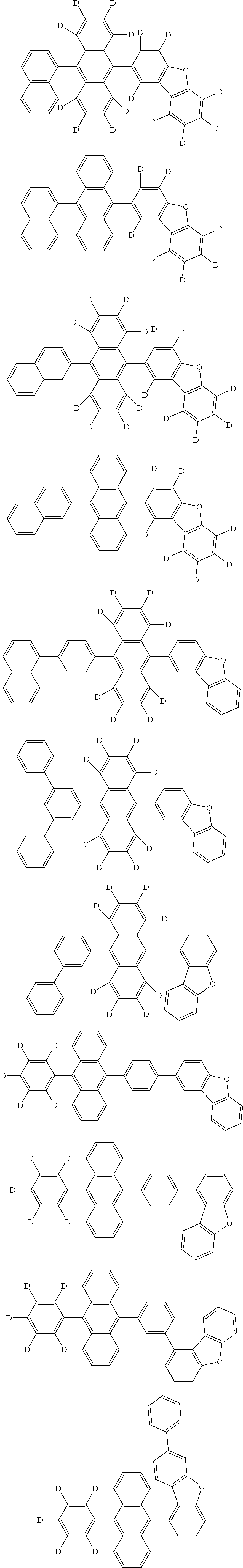

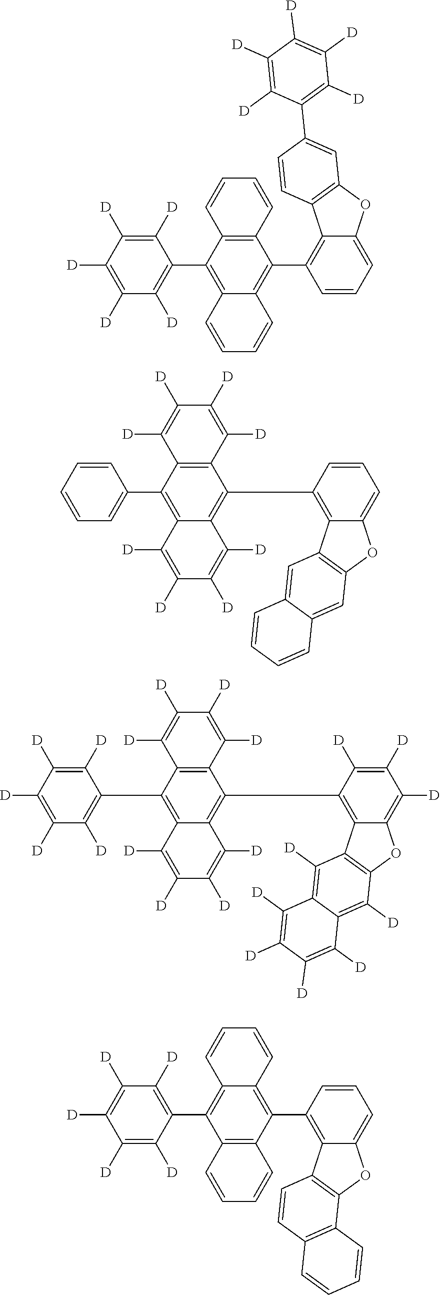

Specific examples of each of the above groups are as defined in the section of “Definitions” herein.

Any typically known materials and device arrangements are applicable to an organic EL device according to an exemplary embodiment of the invention unless the effects of the invention are not impaired, except that the organic EL device includes the cathode, the anode, and the emitting layer provided between the cathode and the anode and the emitting layer contains the compound according to the first exemplary embodiment.

A content of the compound according to the first exemplary embodiment in the emitting layer is preferably in a range from 1 mass % to 20 mass % with respect to the entirety of the emitting layer. The compound according to the first exemplary embodiment is preferably a dopant material.

In the organic EL device according to the exemplary embodiment, when the emitting layer contains a compound represented by the formula (H10), the emitting layer contains the compound represented by the formula (H10) preferably at 60 mass % or more, more preferably at 70 mass % or more, and still more preferably at 80 mass % or more with respect to the total mass of the emitting layer. The compound represented by the formula (H10) is preferably a host material.

When the emitting layer contains the compound represented by the formula (H10) as the host material and the compound according to the first exemplary embodiment as the dopant material, the upper limit of the total of the content ratios of the host material and the dopant material is 100 mass %.

### Fourth Exemplary Embodiment

The organic EL device according to the exemplary embodiment may be an organic EL device including two or more emitting layers.

The organic EL device according to the fourth exemplary embodiment is different from the organic EL device according to the third exemplary embodiment at least in that two or more emitting layers are provided. The fourth exemplary embodiment is the same as the third exemplary embodiment in other respects.

In the description of the fourth exemplary embodiment, the same components as those in the third exemplary embodiment are denoted by the same reference signs and names to simplify or omit explanation of the components. In the fourth exemplary embodiment, the same materials and compounds as described in the first and third exemplary embodiments are usable, unless otherwise specified.

The organic EL device according to the exemplary embodiment will be described.

In the organic EL device according to the exemplary embodiment, the emitting layer includes a first emitting layer and a second emitting layer. The first emitting layer includes a first host material and a first dopant material. The second emitting layer includes a second host material and a second dopant material. The first host material and the second host material are mutually different. The first dopant material and the second dopant material are mutually the same or different.

In the organic EL device according to the exemplary embodiment, the emitting layer includes at least two layers (the first emitting layer and the second emitting layer). The first emitting layer according to the exemplary embodiment has the same structure as the emitting layer of the organic EL device according to the third exemplary embodiment. Differences from the first exemplary embodiment will be mainly described below and overlapping description will be omitted or simplified.

In the organic EL device according to the exemplary embodiment, a lifetime can be prolonged and luminous efficiency can be improved by using Triplet-Triplet-Annihilation (sometimes referred to as TTA).

TTA is a mechanism in which triplet excitons collide with one another to generate singlet excitons. The TTA mechanism is sometimes also referred to as a TTF mechanism as described in International Publication No. WO2010/134350.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

³A*+³A*→(4/9)¹A+(1/9)¹A*+(13/9)³A*

In other words, 5³A*→4¹A+1A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(1/2)=37.5%) to 25% (the amount ratio of initially generated singlet excitons). At this time, the TTF ratio is 37.5/62.5=60%.

From a viewpoint of expressing the TTF mechanism, in the organic EL device of the exemplary embodiment, a triplet energy of the first host material T1(H1) and a triplet energy of the second host material T₁(H2) preferably satisfy a relationship of a numerical formula (Numerical Formula 1) below, more preferably satisfy a relationship of a numerical formula (Numerical Formula 2) below.

$$\\ \begin{matrix}{T}_{1} ( H 2 ) > {T}_{1} ( H 1 ) & ( Numerical Formula 1 )\end{matrix}$$

$$\\ \begin{matrix}{T}_{1} ( H 2 ) - {T}_{1} ( H 1 ) > 0.03 eV & ( Numerical Formula 2 )\end{matrix}$$

In the organic EL device according to the exemplary embodiment, it is considered that since the relationship of the numerical formula (Numerical Formula 1) is satisfied, triplet excitons generated by recombination of holes and electrons in the second emitting layer and present on an interface between the second emitting layer and organic layer(s) in direct contact therewith are not likely to be quenched even under the presence of excessive carriers on the interface between the second emitting layer and the organic layer(s). For instance, the presence of a recombination region locally on an interface between the second emitting layer and a hole transporting layer or an electron blocking layer is considered to cause quenching by excessive electrons. Meanwhile, the presence of a recombination region locally on an interface between the second emitting layer and an electron transporting layer or a hole blocking layer is considered to cause quenching by excessive holes.

In the organic EL device according to the exemplary embodiment, by including the first emitting layer and the second emitting layer so as to satisfy the relationship of the numerical formula (Numerical Formula 1), triplet excitons generated in the second emitting layer can transfer to the first emitting layer without being quenched by excessive carriers and be inhibited from back-transferring from the first emitting layer to the second emitting layer. Consequently, the first emitting layer exhibits the TTF mechanism to effectively generate singlet excitons, thereby improving the luminous efficiency.

Accordingly, the organic EL device includes, as different regions, the second emitting layer mainly generating triplet excitons and the first emitting layer mainly exhibiting the TTF mechanism using triplet excitons having transferred from the second emitting layer, and has a difference in triplet energy provided by using a compound having a smaller triplet energy than that of the second host material in the second emitting layer as the first host material in the first emitting layer. The luminous efficiency is thus improved.

As for the organic EL device of the exemplary embodiment, the lifetime can be prolonged and further the luminous efficiency can be improved by selecting a combination of the host materials satisfying the relationship of the numerical formula (Numerical Formula 1) and containing the compound according to the first exemplary embodiment in the first emitting layer.

### Triplet Energy T₁

A method of measuring a triplet energy T₁ is exemplified by a method below.

A measurement target compound is dissolved in EPA (diethylether:isopentane:ethanol=5:5:2 in volume ratio) so as to fall within a range from 10⁻⁵ mol/L to 10⁻⁴ mol/L, and the obtained solution is encapsulated in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F₁) below on a basis of a wavelength value λ_{edge} [nm] at an intersection of the tangent and the abscissa axis. The calculated energy amount is defined as triplet energy T₁.

$$\\ \begin{matrix}{T}_{1} [ eV ] = 1239.85 / {λ}_{edge} & Conversion Equation ( F 1 )\end{matrix}$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (manufactured by Hitachi High-Technologies Corporation) is usable. Any device for phosphorescence measurement is usable. A combination of a cooling unit, a low temperature container, an excitation light source and a light-receiving unit may be used for phosphorescence measurement.

### Emission Wavelength of Organic EL Device

The organic EL device according to the exemplary embodiment preferably emits, when being driven, light whose maximum peak wavelength is 500 nm or less, more preferably emits light whose maximum peak wavelength is in a range from 445 nm to 480 nm, and still more preferably emits light whose maximum peak wavelength is in a range from 445 nm to 465 nm. The maximum peak wavelength of the light emitted from the organic EL device when being driven is measured as described in Examples.

### First Emitting Layer

The first emitting layer includes the first host material and the first dopant material. The first host material is a compound different from the second host material contained in the second emitting layer.

The first emitting layer according to the exemplary embodiment has the same structure as the emitting layer of the organic EL device according to the third exemplary embodiment. The first dopant material is preferably the compound according to the exemplary embodiment (the compound represented by the formula (1)). The first host material is preferably a compound represented by the formula (H10).

In the organic EL device of the fourth exemplary embodiment, the compound according to the first exemplary embodiment and the compound represented by the formula (H10) are usable in combination in the first emitting layer of the organic EL device.

In the organic EL device according to the exemplary embodiment, the first emitting layer preferably emits light whose maximum peak wavelength is 500 nm or less when the device is driven.

The maximum peak wavelength of the light emitted from the emitting layer when the device is driven is measured as follows.

Maximum Peak Wavelength λp of Light Emitted from Emitting Layer When Organic EL Device Is Driven

For a maximum peak wavelength λp₁ of light emitted from the first emitting layer when the organic EL device is driven, the organic EL device is produced by using the material of the first emitting layer for the first emitting layer and the second emitting layer, and voltage is applied to the organic EL device so that a current density becomes 10 mA/cm², where spectral radiance spectrum is measured by a spectroradiometer CS-2000 (produced by Konica Minolta, Inc.). The maximum peak wavelength λp₁ (unit: nm) is calculated from the obtained spectral radiance spectrum.

For a maximum peak wavelength λp₂ of light emitted from the second emitting layer when the organic EL device is driven, the organic EL device is produced by using the material of the second emitting layer for the first emitting layer and the second emitting layer, and voltage is applied to the organic EL device so that a current density becomes 10 mA/cm², where spectral radiance spectrum is measured by a spectroradiometer CS-2000 (produced by Konica Minolta, Inc.). The maximum peak wavelength λp₂ (unit: nm) is calculated from the obtained spectral radiance spectrum.

In the organic EL device according to the exemplary embodiment, a triplet energy of the first dopant material T₁(D₁) and a triplet energy of the first host material T₁(H1) preferably satisfy a relationship of a numerical formula (Numerical Formula 4A) below.

$${T}_{1} ( D 1 ) > {T}_{1} ( H 1 ) \qquad ( Numerical Formula 4 A )$$

In the organic EL device according to the exemplary embodiment, when the first dopant material and the first host material satisfy the relationship of the numerical formula (Numerical Formula 4A), in transfer of triplet excitons generated in the second emitting layer to the first emitting layer, the triplet excitons energy-transfer not onto the first dopant material having higher triplet energy but onto molecules of the first host material. In addition, triplet excitons generated by recombination of holes and electrons on the first host material do not transfer to the first dopant material having higher triplet energy. Triplet excitons generated by recombination on molecules of the first dopant material quickly energy-transfer to molecules of the first host material.

Triplet excitons in the first host material do not transfer to the first dopant material but efficiently collide with one another on the first host material to generate singlet excitons by the TTF phenomenon.

In the organic EL device according to the exemplary embodiment, a singlet energy of the first host material S₁(H1) and a singlet energy of the first dopant material S₁(D1) preferably satisfy a relationship of a numerical formula (Numerical Formula 4) below.

$${S}_{1} ( H 1 ) > {S}_{1} ( D 1 ) \qquad ( Numerical Formula 4 )$$

In the organic EL device according to the exemplary embodiment, when the first dopant material and the first host material satisfy the relationship of the numerical formula (Numerical formula 4), due to the singlet energy of the first dopant material being smaller than the singlet energy of the first host material, singlet excitons generated by the TTF phenomenon energy-transfer from the first host material to the first dopant material, thereby contributing to emission (preferably fluorescence) of the first dopant material.

### Singlet Energy S₁

A method of measuring a singlet energy S₁ with use of a solution (occasionally referred to as a solution method) is exemplified by a method below.

A toluene solution of a measurement target compound at a concentration ranging from 10⁻⁵ mol/L to 10⁻⁴ mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} (nm) at an intersection of the tangent and the abscissa axis is assigned to a conversion equation (F2) below to calculate singlet energy.

$${S}_{1} [ eV ] = 1239.85 / {λ}_{edge} \qquad Conversion Equation ( F2 )$$

Any apparatus for measuring absorption spectrum is usable. For instance, a spectrophotometer (U3310 manufactured by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the organic EL device according to the exemplary embodiment, when the first emitting layer and the second emitting layer are layered in this order from a side on which the anode is provided, an electron mobility of the second host material μe(H2) and an electron mobility of the first host material μe(H1) preferably satisfy a formula (Numerical Formula 3) below. When the first host material and the second host material satisfy a relationship of a numerical formula (Numerical Formula 3), a recombination ability between holes and electrons in the second emitting layer is improved.

$$μ e ( H 1 ) > μ e ( H 2 ) \qquad ( Numerical Formula 3 )$$

In the organic EL device according to the exemplary embodiment, when the second emitting layer and the first emitting layer are layered in this order from a side on which the anode is provided, a hole mobility of the second host material μh(H2) and a hole mobility of the first host material μh(H1) preferably satisfy a formula (Numerical Formula 31) below.

$$μ h ( H 2 ) > μ h ( H 1 ) \qquad ( Numerical Formula 31 )$$

In the organic EL device according to the exemplary embodiment, when the second emitting layer and the first emitting layer are layered in this order from a side on which the anode is provided, a hole mobility of the second host material μh(H2), the electron mobility of the second host material μe(H2), the hole mobility of the first host material μh(H1), and the electron mobility of the first host material μe(H1) also preferably satisfy a formula (Numerical Formula 32) below.

$$( μ e ( H 1 ) / μ h ( H 1 ) ) > ( μ e ( H 2 ) / μ h ( H 2 ) ) \qquad ( Numerical Formula 32 )$$

Electron mobility can be measured by measuring impedance using a device for mobility evaluation produced according to the following steps. The device for mobility evaluation is produced, for instance, according to the following steps.

A compound Target, which is to be measured for the electron mobility, is vapor-deposited on a glass substrate provided with an aluminum electrode (anode) in a manner to cover the aluminum electrode, thereby forming a measurement target layer. A compound ET-A below is vapor-deposited on the measurement target layer to form an electron transporting layer. LiF is vapor-deposited on the formed electron transporting layer to form an electron injecting layer. Metal aluminum (Al) is vapor-deposited on the electron injecting layer to form a metal cathode.

An arrangement of the above device for mobility evaluation is roughly shown as follows.
glass/Al(50)/Target(200)/ET-A(10)/LiF(1)/Al(50)

Numerals in parentheses represent a film thickness (nm).

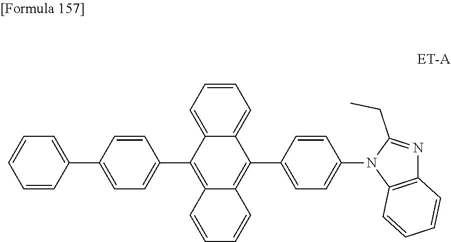 [SMILES: CCc1nc2ccccc2n1-c1ccc(-c2c3ccccc3c(-c3ccc(-c4ccccc4)cc3)c3ccccc23)cc1]

The device for evaluating electron mobility is set in an impedance measurement apparatus and an impedance measurement is performed. In the impedance measurement, a measurement frequency is swept from 1 Hz to 1 MHz. At this time, an alternating current amplitude of 0.1 V and a direct current voltage V are applied to the device. A modulus M is calculated from a measured impedance Z using a relationship of a calculation formula (C1) below.

$$M = j ω Z \qquad Calculation Formula ( C 1 )$$

In the calculation formula (C1), j is an imaginary unit whose square is −1 and ω is an angular frequency [rad/s].

In a bode plot in which an imaginary part of the modulus M is represented by an ordinate axis and the frequency [Hz] is represented by an abscissa axis, an electrical time constant T of the device for mobility evaluation is obtained from a frequency fmax showing a peak using a calculation formula (C2) below.

$$⊤ = 1 / ( 2 π f max ) \qquad Calculation Formula ( C 2 )$$

π in the calculation formula (C2) is a symbol representing a circumference ratio.

An electron mobility ρe is calculated from a relationship of a calculation formula (C3-1) below using T obtained above.

$$μ e = {d}^{2} / ( {V}_{⊤} ) \qquad Calculation Formula ( C 3 - 1 )$$

d in the calculation formula (C3-1) is a total film thickness of organic thin film(s) forming the device. In a case of the device arrangement for electron mobility evaluation, d=210 [nm] is satisfied.

Hole mobility can be measured by measuring impedance using a device for mobility evaluation produced according to the following steps. The device for mobility evaluation is produced, for instance, according to the following steps.

A compound HA-2 below is vapor-deposited on a glass substrate having an ITO transparent electrode (anode) so as to cover the transparent electrode, thereby forming a hole injecting layer. A compound HT-A was vapor-deposited on the hole injecting layer to form a hole transporting layer. Subsequently, a compound Target, which is to be measured for the hole mobility, is vapor-deposited to form a measurement target layer. Metal aluminum (Al) is vapor-deposited on the measurement target layer to form a metal cathode.

An arrangement of the above device for mobility evaluation is roughly shown as follows.
ITO(130)/HA-2(5)/HT-A(10)/Target(200)/Al(80)

Numerals in parentheses represent a film thickness (nm).

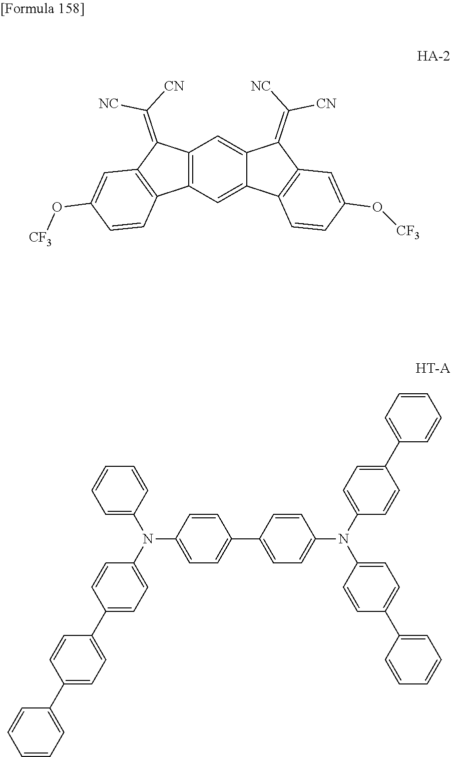 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

The device for evaluating hole mobility is set in an impedance measurement apparatus and an impedance measurement is performed. In the impedance measurement, a measurement frequency is swept from 1 Hz to 1 MHz. At this time, an alternating current amplitude of 0.1 V and a direct current voltage V are applied to the device. A modulus M is calculated from the measured impedance Z using a relationship of the above calculation formula (C1).

In a bode plot in which an imaginary part of the modulus M is represented by an ordinate axis and the frequency [Hz] was represented by an abscissa axis, an electrical time constant T of the device for mobility evaluation is obtained from a frequency fmax showing a peak using the above calculation formula (C2).

A hole mobility ph is calculated from a relationship of a calculation formula (C3-2) below using T obtained according to the calculation formula (C2).

$$μ h = {d}^{2} / ( {V}_{⊤} ) \qquad Calculation Formula ( C 3 - 2 )$$

d in the calculation formula (C3-2) is a total film thickness of organic thin film(s) forming the device. In a case of the device arrangement for hole mobility evaluation, d=215 [nm] is satisfied.

The hole mobility and electron mobility herein each are a value obtained in a case where a square root of an electric field intensity meets E^{1/2}=500 [V^{1/2}/cm^{1/2}]. The square root of the electric field intensity, E^{1/2}, can be calculated from a relationship of a calculation formula (C4) below.

$${E}^{1 / 2} = {V}^{1 / 2} / {d}^{1 / 2} \qquad Calculation Formula ( C 4 )$$

For the impedance measurement, a 1260 type by Solartron Analytical is used as the impedance measurement apparatus, and for a higher accuracy, a 1296 type dielectric constant measurement interface by Solartron Analytical can be used together therewith.

In the organic EL device according to the exemplary embodiment, the first emitting layer contains the first dopant material preferably at 0.5 mass % or more, more preferably at more than 1.1 mass %, still more preferably at 1.2 mass % or more, and still further more preferably at 1.5 mass % or more with respect to the total mass of the first emitting layer.

The first emitting layer contains the first dopant material preferably at 10 mass % or less, more preferably at 7 mass % or less, and still more preferably at 5 mass % or less with respect to the total mass of the first emitting layer.

In the organic EL device according to the exemplary embodiment, the first emitting layer contains the first host material preferably at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The first emitting layer preferably contains the first host material at 99 mass % or less with respect to the total mass of the first emitting layer.

When the first emitting layer contains the first host material and the first dopant material, the upper limit of the total of the content ratios of the first host material and the first dopant material is 100 mass %.

In the exemplary embodiment, the first emitting layer may further contain any other material than the first host material and the first dopant material.

The first emitting layer may contain a single type of the first host material alone or may contain two or more types of the first host material. The first emitting layer may contain a single type of the first dopant material alone or may contain two or more types of the first dopant material.

In the organic EL device according to the exemplary embodiment, a film thickness of the first emitting layer is preferably 5 nm or more, more preferably 15 nm or more. When a film thickness of the first emitting layer is 5 nm or more, it is easy to inhibit triplet excitons having transferred from the second emitting layer to the first emitting layer from returning to the second emitting layer. Further, when the film thickness of the first emitting layer is 5 nm or more, triplet excitons can be sufficiently separated from the recombination portion in the second emitting layer.

In the organic EL device according to the exemplary embodiment, the film thickness of the first emitting layer is preferably 20 nm or less. With the film thickness of the first emitting layer of 20 nm or less, a density of triplet excitons in the first emitting layer is improvable to further facilitate occurrence of the TTF phenomenon.

In the organic EL device of the exemplary embodiment, the film thickness of the first emitting layer is preferably in a range from 5 nm to 20 nm.

### Second Emitting Layer

The second emitting layer includes the second host material and the second dopant material. The second host material is a compound different from the first host material contained in the first emitting layer.

The second dopant material is preferably a compound that emits light having a maximum peak wavelength of 500 nm or less. The second dopant material is more preferably a compound that emits fluorescence having a maximum peak wavelength of 500 nm or less.

The method of measuring a maximum peak wavelength of a compound is as described above.

In the organic EL device according to the exemplary embodiment, the second dopant material and the first dopant material are the same compound or different compounds.

In the organic EL device according to the exemplary embodiment, the second emitting layer preferably does not contain a metal complex. In the organic EL device according to the exemplary embodiment, the first emitting layer also preferably does not contain a boron-containing complex.

In the organic EL device according to the exemplary embodiment, the second emitting layer preferably does not contain a phosphorescent material (dopant material).

Further, the second emitting layer preferably does not contain a heavy-metal complex and a phosphorescent rare earth metal complex.

In an emission spectrum of the second dopant material, where a peak exhibiting a maximum luminous intensity is defined as a maximum peak and a height of the maximum peak is defined as 1, heights of other peaks appearing in the emission spectrum are preferably less than 0.6. It should be noted that the peaks in the emission spectrum are defined as local maximum values.

Moreover, in the emission spectrum of the second luminescent compound, the number of peaks is preferably less than three.

In the organic EL device according to the exemplary embodiment, the second emitting layer preferably emits light whose maximum peak wavelength is 500 nm or less when the device is driven.

### Second Host Material

Examples of the second host material include 1) a fused aromatic compound such as an anthracene derivative, phenanthrene derivative, pyrene derivative, benzanthracene derivative, fluorene derivative, fluoranthene derivative or chrysene derivative; and

2) a heterocyclic compound such as a carbazole derivative, a dibenzofuran derivative, a dibenzothiophene derivative, or a benzoxanthene derivative.

The second host material is preferably a fused aromatic compound, more preferably a pyrene derivative (a later-described compound represented by a formula (H100)).

The second host material is also preferably a benzanthracene derivative (a later-described compound represented by a formula (H1X)) or a benzoxanthene derivative (a later-described compound represented by a formula (H14X)).

When the second host material is a pyrene derivative, the second host material is preferably a compound represented by the formula (H100) below.

### Compound Represented by Formula (H100)

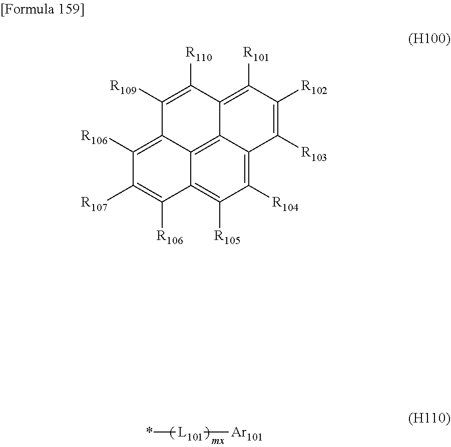

In the formula (H100):

R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (H110);
at least one of R₁₀₁ to R₁₁₀ is a group represented by the formula (H110);
when a plurality of groups represented by the formula (H110) are present, the plurality of groups represented by the formula (H110) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (H110) represents a bonding position to a pyrene ring in the formula (H100).

In the formula (H100):
R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In the organic EL device according to the exemplary embodiment, the group represented by the formula (H110) is preferably a group represented by a formula (H111) below.

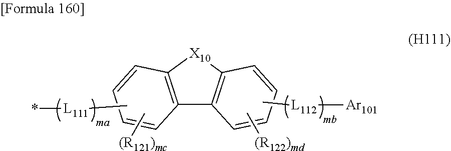

In the formula (H111):
X₁₀ is C(R₁₂₃)(R₁₂₄), an oxygen atom, a sulfur atom, or NR₁₂₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 0, 1, 2, 3, or 4;
mb is 0, 1, 2, 3, or 4;
ma+mb is 0, 1, 2, 3, or 4;
Ar₁₀₁ represents the same as Ar₁₀₁ in the formula (H110);
R₁₂₁, R₁₂₂, R₁₂₃, R₁₂₄, and R₁₂₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₂₁ are mutually the same or different;
md is 3; and
three R₁₂₂ are mutually the same or different.

Among positions *1 to *8 of carbon atoms in a cyclic structure represented by a formula (H111a) below in the group represented by the formula (H111), L₁₁₁ is bonded to one of the positions *1 to *4, R₁₂₁ is bonded to each of three positions of the rest of *1 to *4, L112 is bonded to one of the positions *5 to *8, and R₁₂₂ is bonded to each of three positions of the rest of *5 to *8.

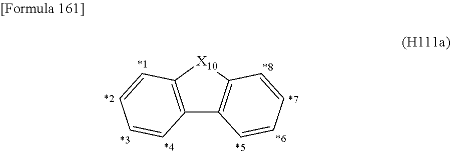

For instance, in the group represented by the formula (H111), when L₁₁₁ is bonded to a carbon atom at *2 in the cyclic structure represented by the formula (H111a) and L112 is bonded to a carbon atom at *7 in the cyclic structure represented by the formula (H111a), the group represented by the formula (H111) is represented by a formula (H111b) below.

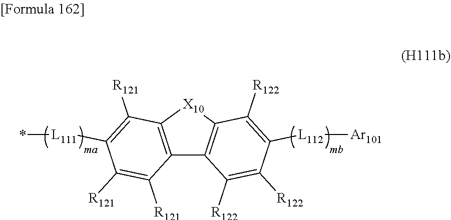

In the formula (H111b):
X₁₀, L₁₁₁, L₁₁₂, ma, mb, Ar₁₀₁, R₁₂₁, R₁₂₂, R₁₂₃, R₁₂₄ and R₁₂₅ each independently represent the same as X₁₀, L₁₁₁, L₁₁₂, ma, mb, Ar₁₀₁, R₁₂₁, R₁₂₂, R₁₂₃, R₁₂₄ and R₁₂₅ in the formula (H111);
a plurality of R₁₂₁ are mutually the same or different; and
a plurality of R₁₂₂ are mutually the same or different.

In the organic EL device according to the exemplary embodiment, the group represented by the formula (H111) is preferably a group represented by the formula (H111b).

In the organic EL device according to the exemplary embodiment, it is preferable that ma is 0, 1, or 2, and mb is 0, 1, or 2.

In the organic EL device according to the exemplary embodiment, it is preferable that ma is 0 or 1, and mb is 0 or 1.

In the organic EL device according to the exemplary embodiment, Ar₁₀₁ is preferably a substituted or unsubstituted aryl group having 6 to 50 ring carbon atoms.

In the organic EL device according to the exemplary embodiment, it is preferable that Ar₁₀₁ is a substituted or unsubstituted phenyl group, a substituted or unsubstituted naphthyl group, a substituted or unsubstituted biphenyl group, a substituted or unsubstituted terphenyl group, a substituted or unsubstituted pyrenyl group, a substituted or unsubstituted phenanthryl group, or a substituted or unsubstituted fluorenyl group.

In the organic EL device according to the exemplary embodiment, Ar₁₀₁ is also preferably a group represented by a formula (H120), a formula (H130), or a formula (H140) below.

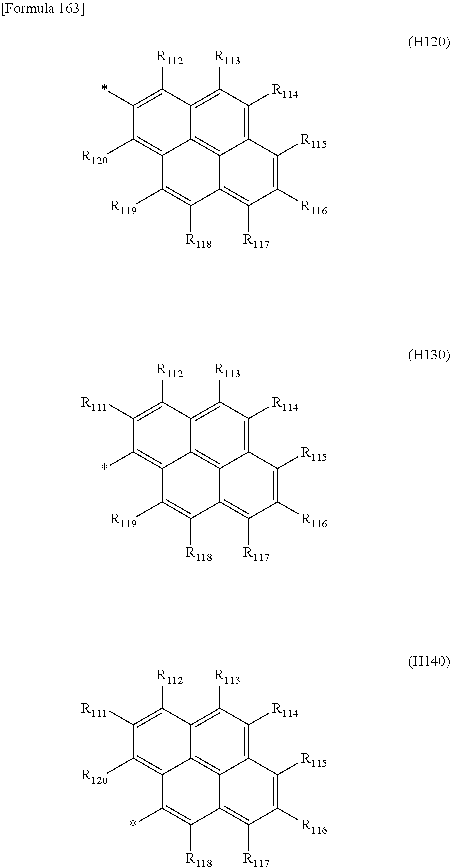

In the formulae (H120), (H130), and (H140):
R₁₁₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms, and
* in each of the formulae (H120), (H130), and (H140) represents a bonding position to L₁₀₁ in the formula (H110) or a bonding position to L112 in the formula (H111) or (H111b).

In the organic EL device according to the exemplary embodiment, the second host material is preferably represented by a formula (H101) below.

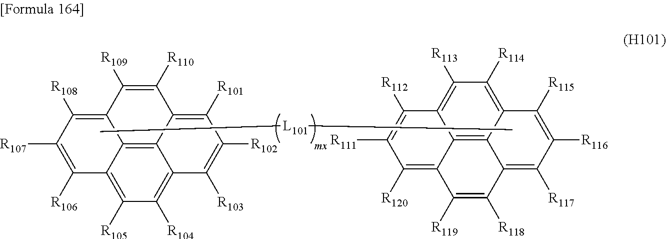

In the formula (H101):
R₁₀₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
one of R₁₀₁ to R₁₁₀ represents a bonding position to L₁₀₁, and one of R₁₁₁ to R₁₂₀ represents a bonding position to L₁₀₁;
L₁₀₁ is a single bond, a substituted or unsubstituted arylene group having 6 to 50 ring carbon atoms, or a substituted or unsubstituted divalent heterocyclic group having 5 to 50 ring atoms;
mx is 0, 1, 2, 3, 4, or 5; and
when two or more L₁₀₁ are present, the two or more L₁₀₁ are mutually the same or different.

In the organic EL device according to the exemplary embodiment, L₁₀₁ is preferably a single bond, or a substituted or unsubstituted arylene group having 6 to 50 ring carbon atoms.

In the organic EL device according to the exemplary embodiment, the second host material is preferably represented by a formula (H102) below.

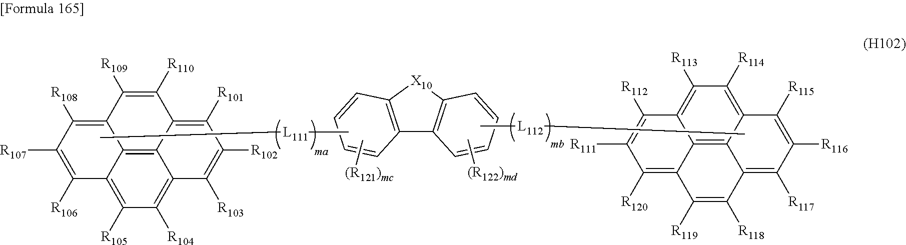

In the formula (H102):
R₁₀₁ to R₁₂₀ each independently represent the same as R₁₀₁ to R₁₂₀ in the formula (H101);
one of R₁₀₁ to R₁₁₀ represents a bonding position to L111, and one of R₁₁₁ to R₁₂₀ represents a bonding position to L112;
X₁₀ is C(R₁₂₃)(R₁₂₄), an oxygen atom, a sulfur atom, or NR₁₂₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 0, 1, 2, 3, or 4;
mb is 0, 1, 2, 3, or 4;
ma+mb is 0, 1, 2, 3, or 4;
R₁₂₁, R₁₂₂, R₁₂₃, R₁₂₄, and R₁₂₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₂₁ are mutually the same or different;
md is 3; and
three R₁₂₂ are mutually the same or different.

In the compound represented by the formula (H102), it is preferable that ma is 0, 1, or 2, and mb is 0, 1, or 2.

In the compound represented by the formula (H102), it is preferable that ma is 0 or 1, and mb is 0 or 1.

In the organic EL device according to the exemplary embodiment, two or more of R₁₀₁ to R₁₁₀ are preferably each a group represented by the formula (H110).

In the organic EL device according to the exemplary embodiment, it is preferable that two or more of R₁₀₁ to R₁₁₀ are each a group represented by the formula (H110) and Ar₁₀₁ is a substituted or unsubstituted aryl group having 6 to 50 ring carbon atoms.

In the organic EL device according to the exemplary embodiment, it is preferable that Ar₁₀₁ is not a substituted or unsubstituted pyrenyl group, L₁₀₁ is not a substituted or unsubstituted pyrenylene group, and a substituted or unsubstituted aryl group having 6 to 50 ring carbon atoms for R₁₀₁ to R₁₁₀ not being a group represented by the formula (H110) is not a substituted or unsubstituted pyrenyl group.

In the organic EL device according to the exemplary embodiment, it is preferable that R₁₀₁ to R₁₁₀ not being the group represented by the formula (H110) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the organic EL device according to the exemplary embodiment, it is preferable that R₁₀₁ to R₁₁₀ not being the group represented by the formula (H110) are each independently a hydrogen atom, a substituted or unsubstituted alkyl group having 1 to 50 carbon atoms, or a substituted or unsubstituted cycloalkyl group having 3 to 50 ring carbon atoms.

In the organic EL device according to the exemplary embodiment, R₁₀₁ to R₁₁₀ not being the group represented by the formula (H110) are preferably each a hydrogen atom.

In the compound represented by the formula (H100), the groups specified to be “substituted or unsubstituted” are preferably each an “unsubstituted” group.

A compound represented by the formula (H100) can be produced by a known method.

Specific Examples of Compound Represented by Formula (H100) Specific examples of the compound represented by the formula (H100) include compounds shown below. However, the compound represented by the formula (H100) is by no means limited to the specific examples below.

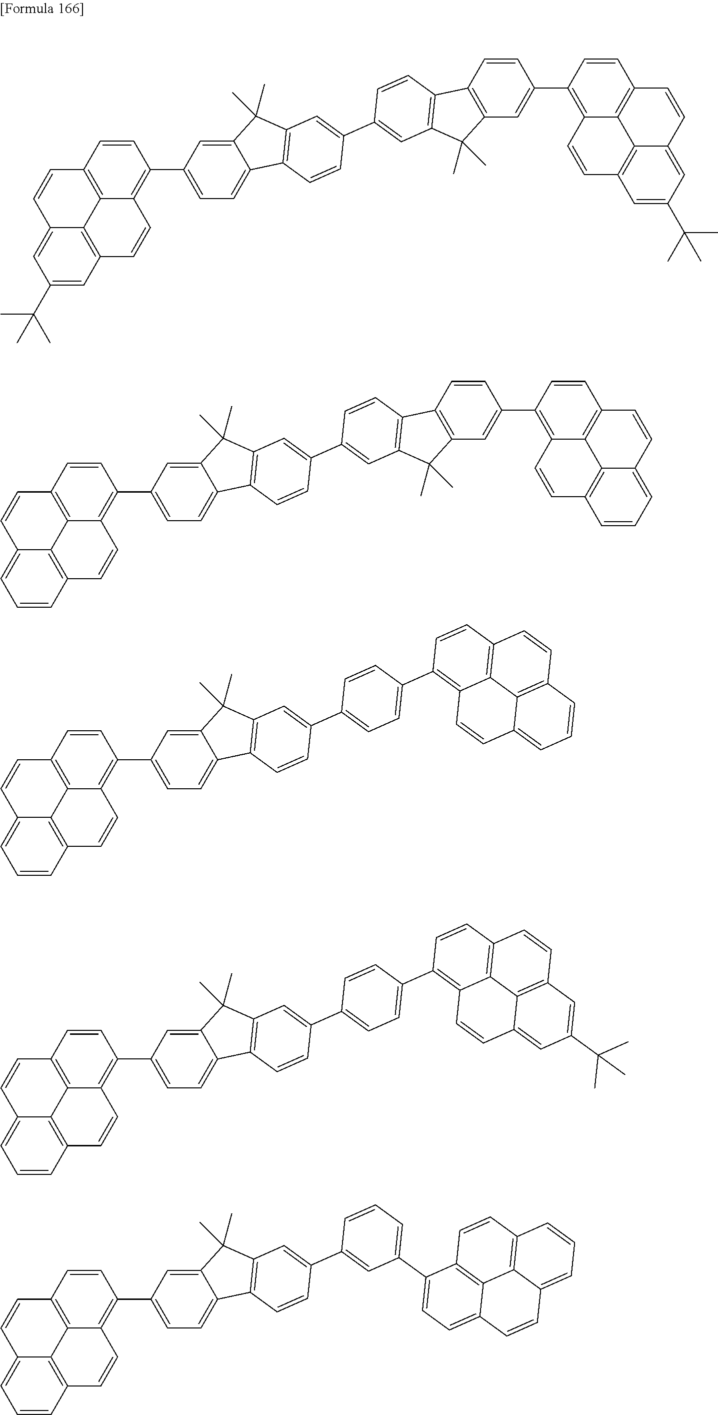

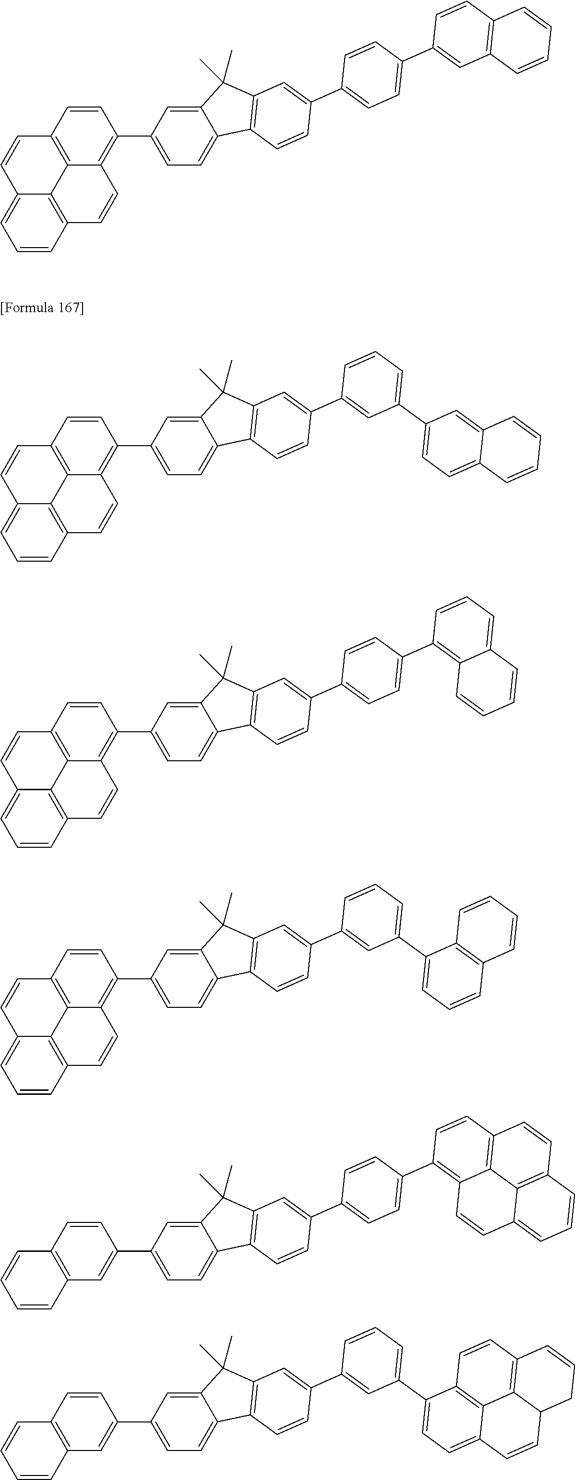

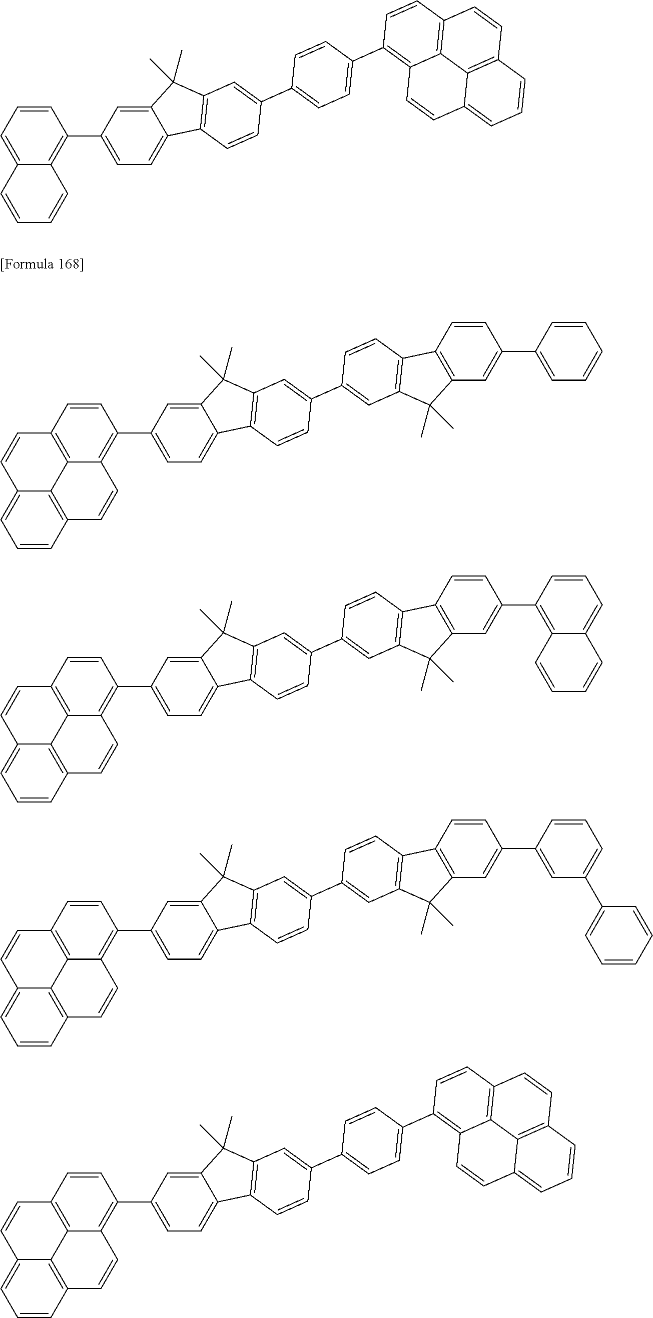

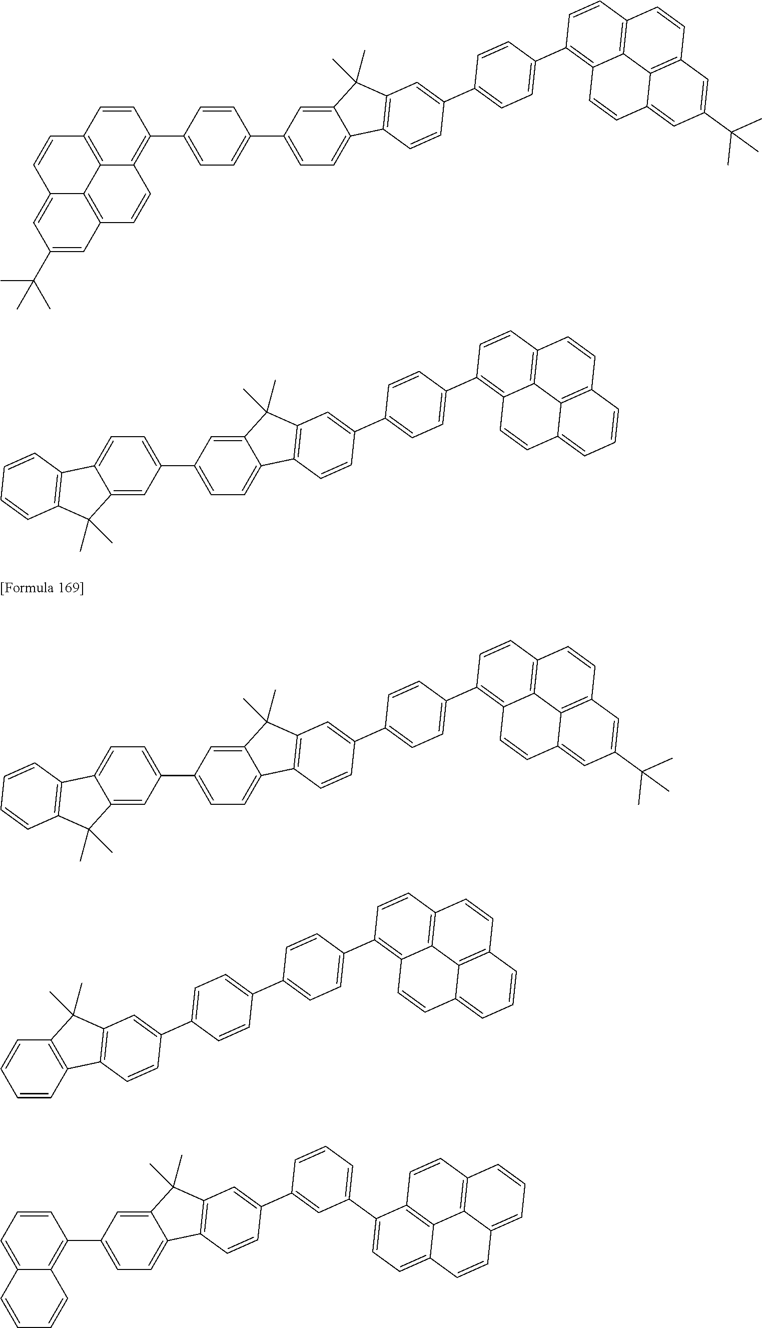

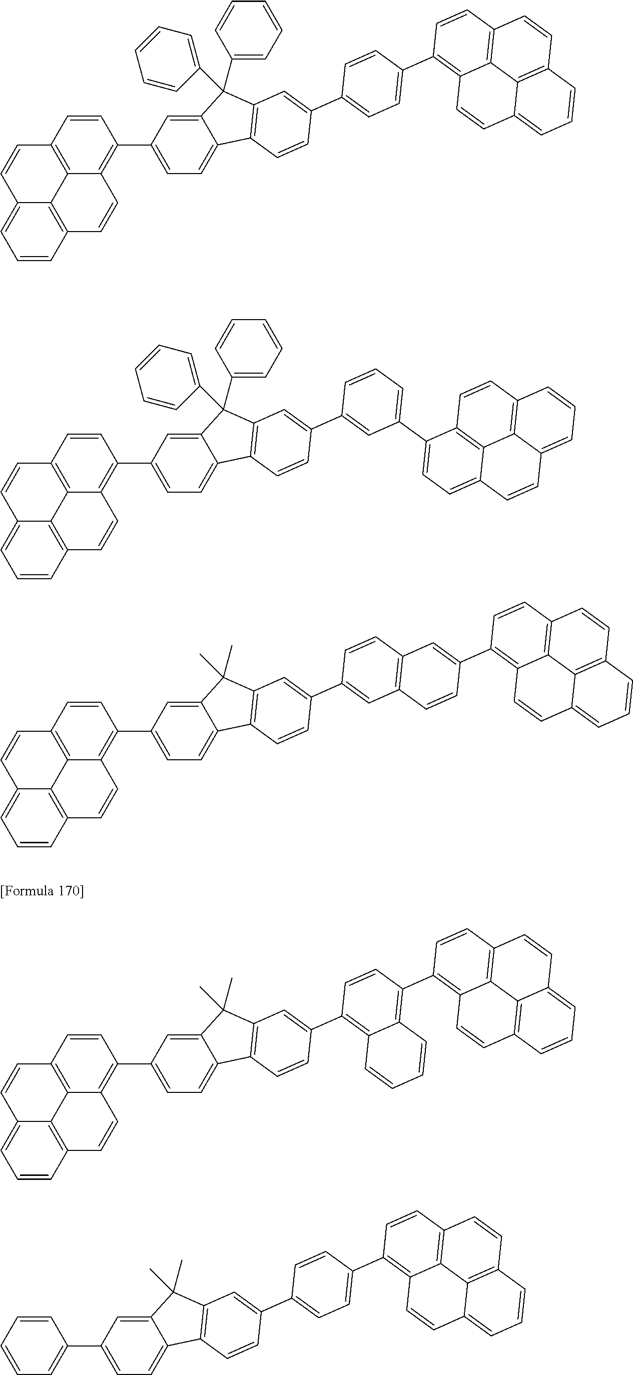

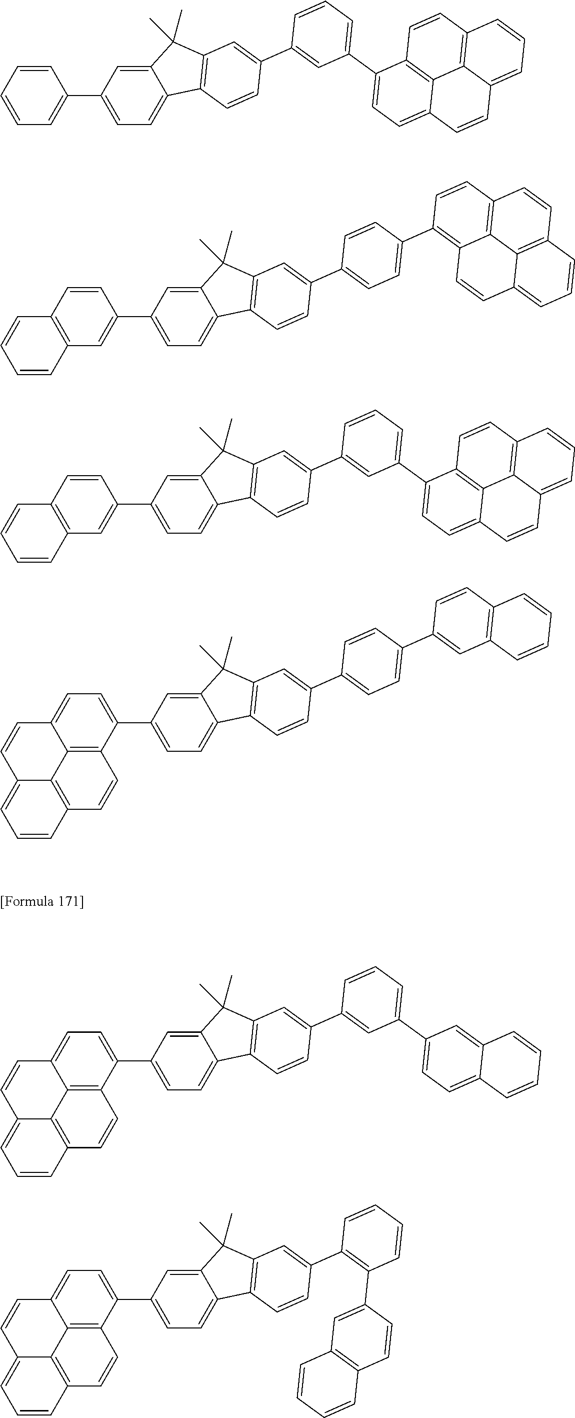

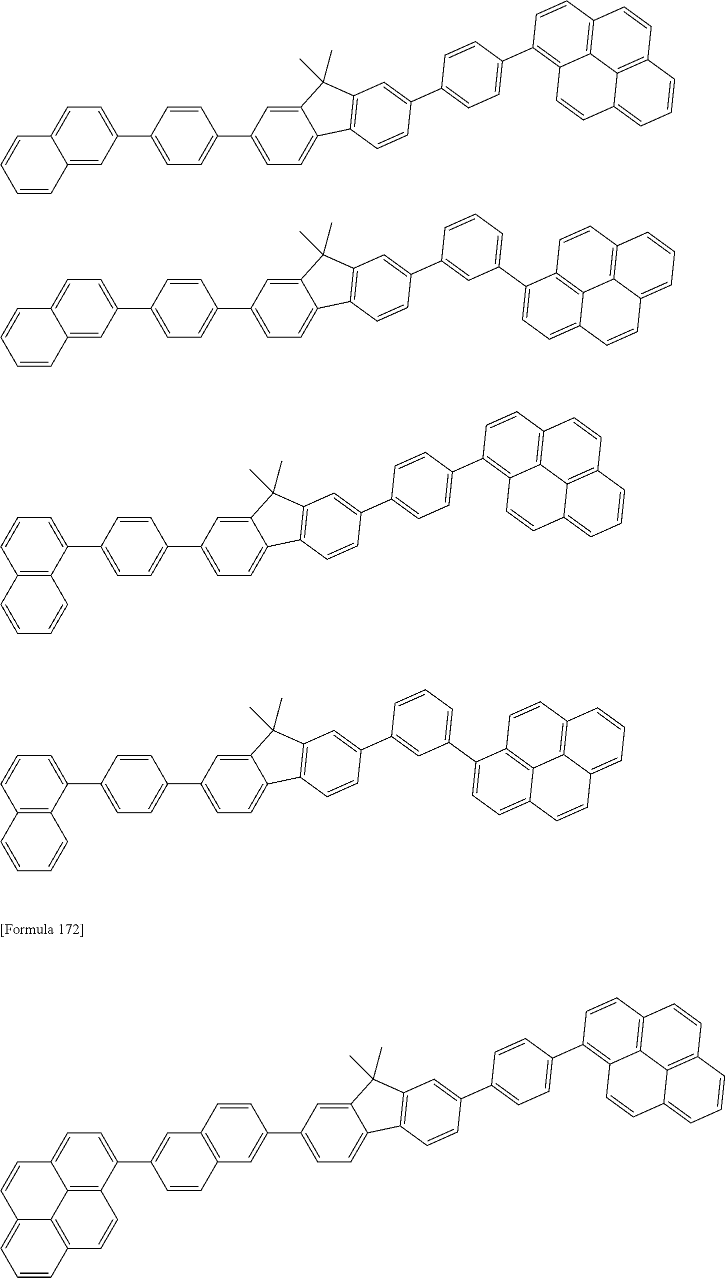

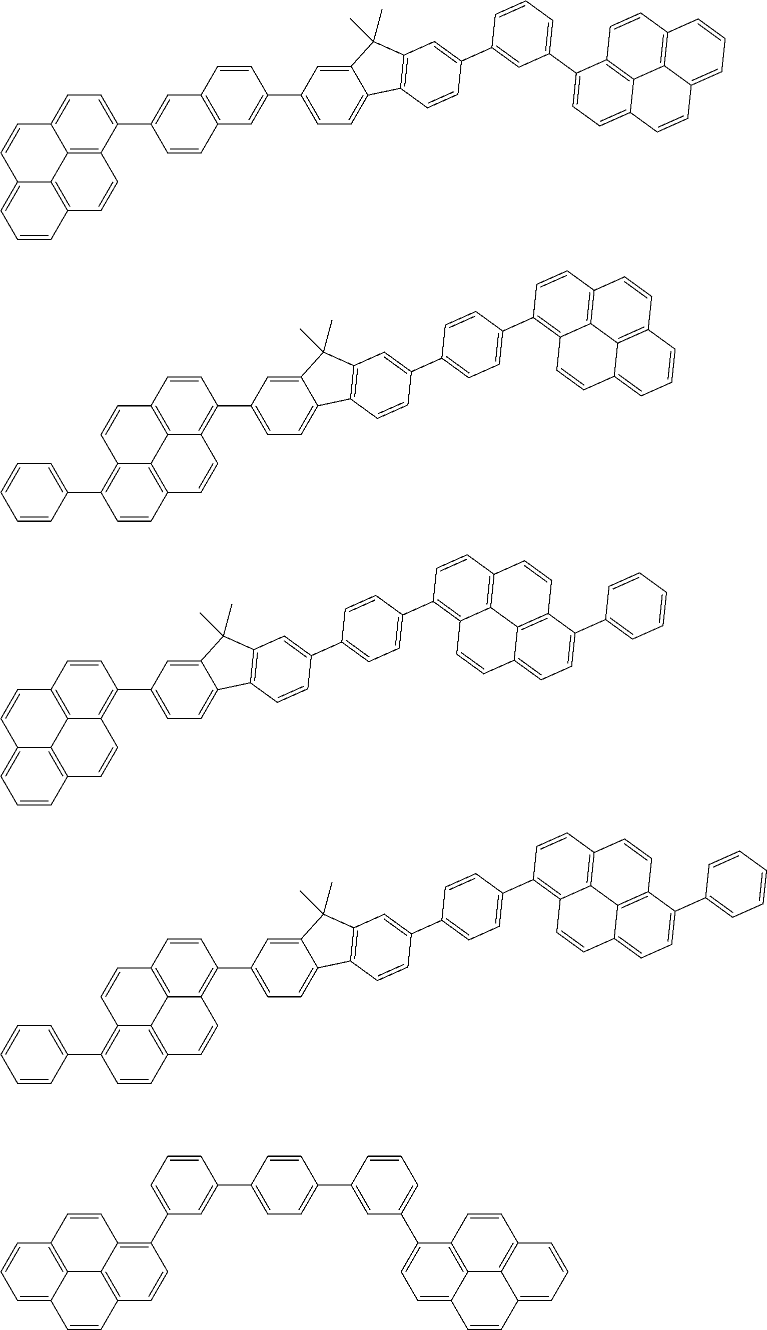

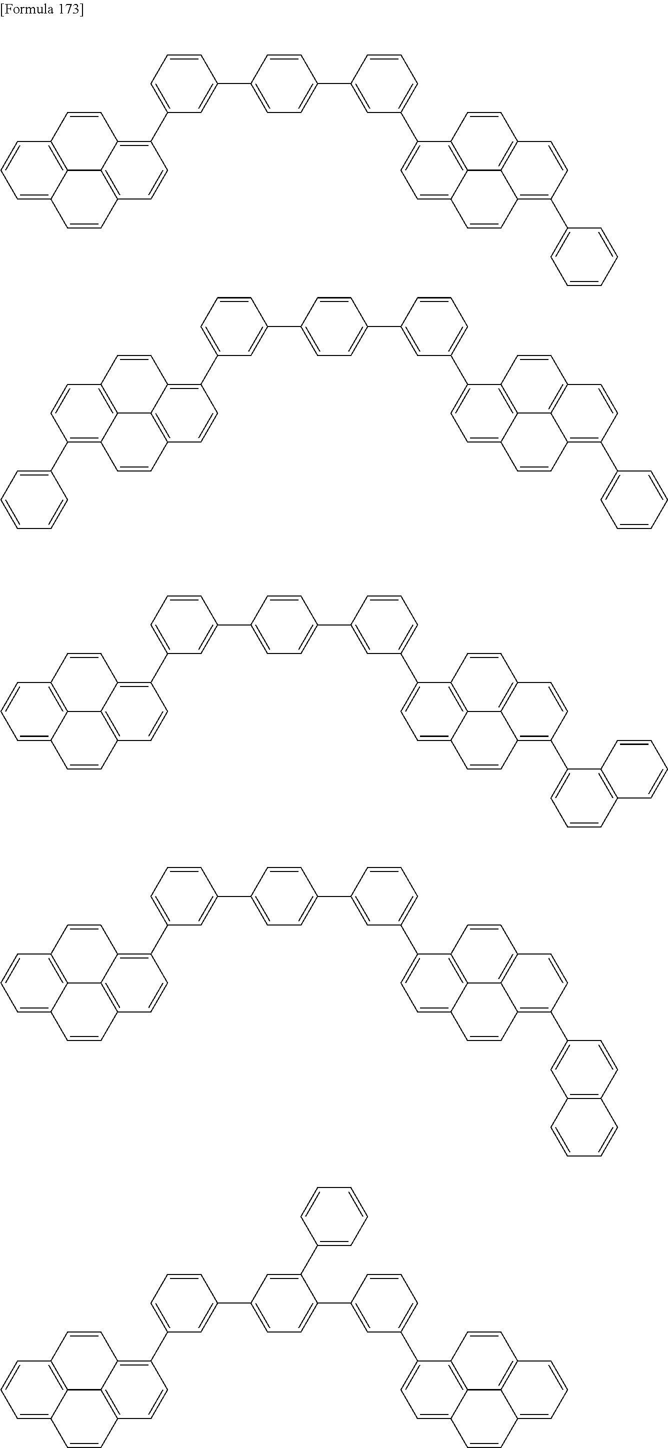

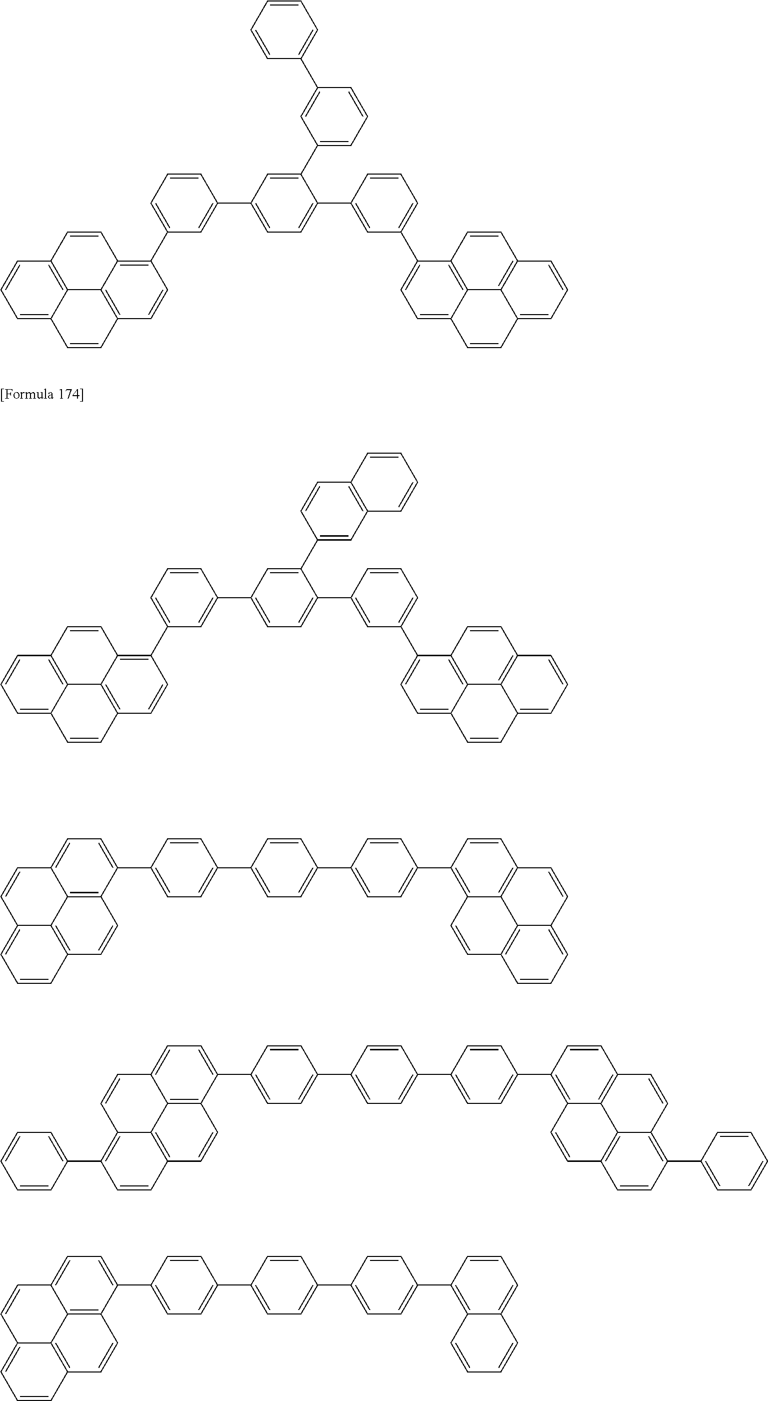

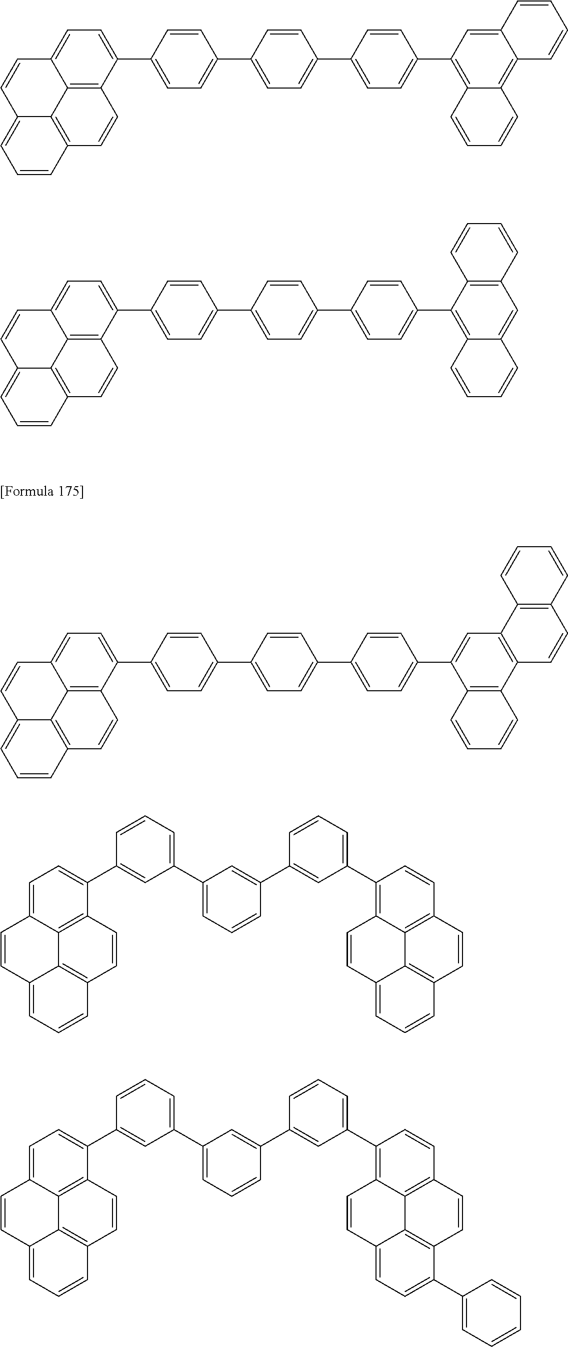

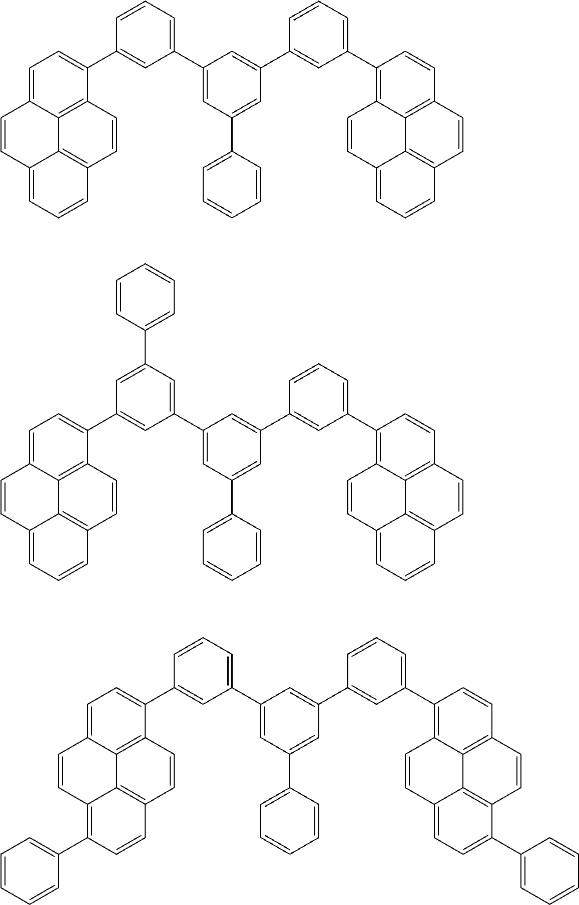

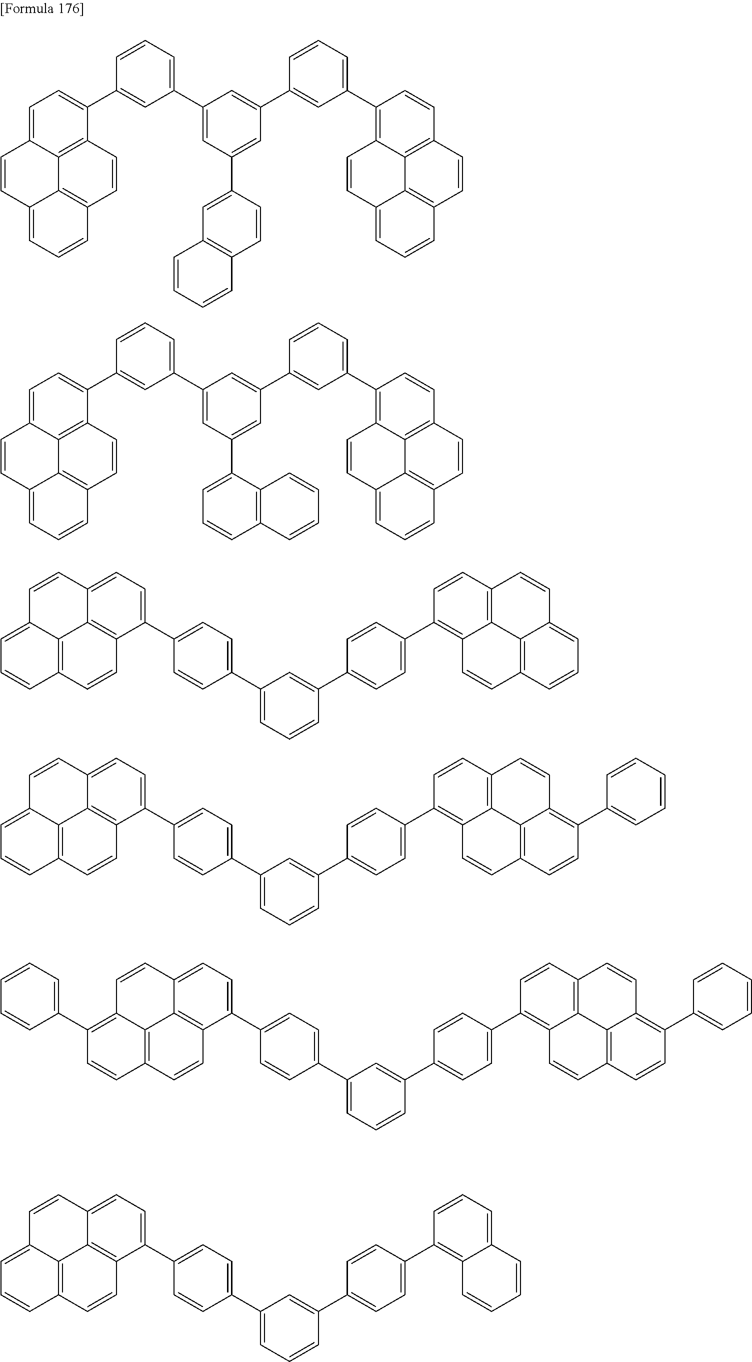

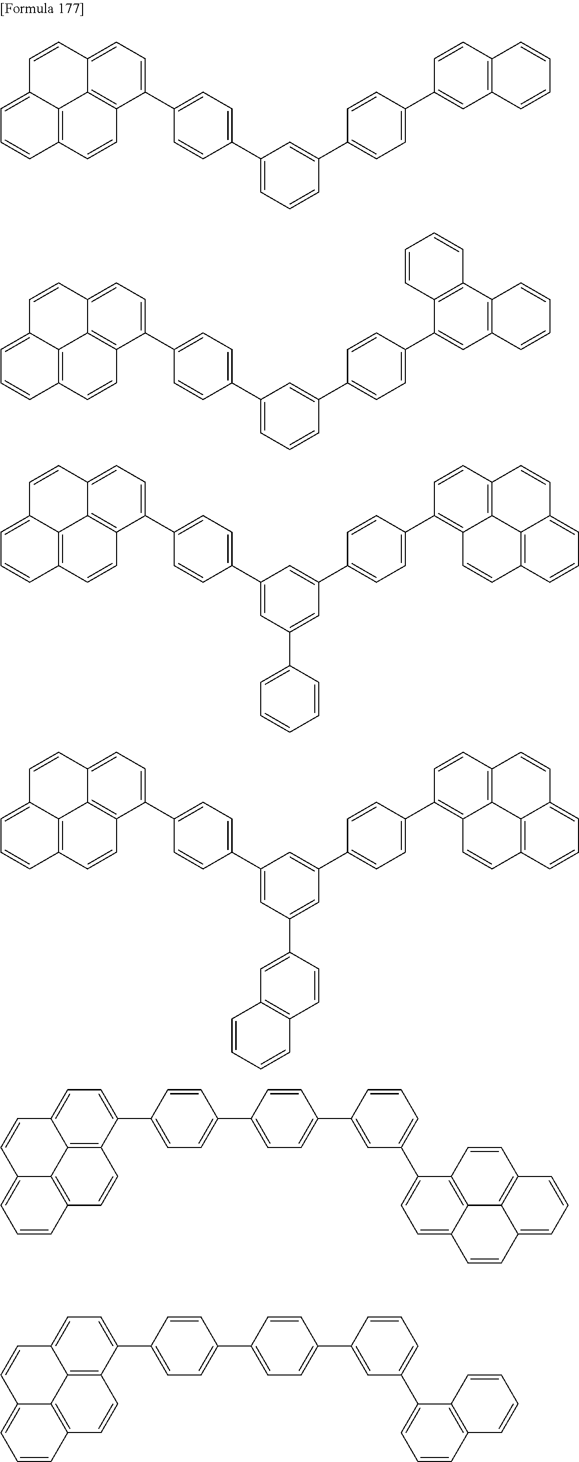

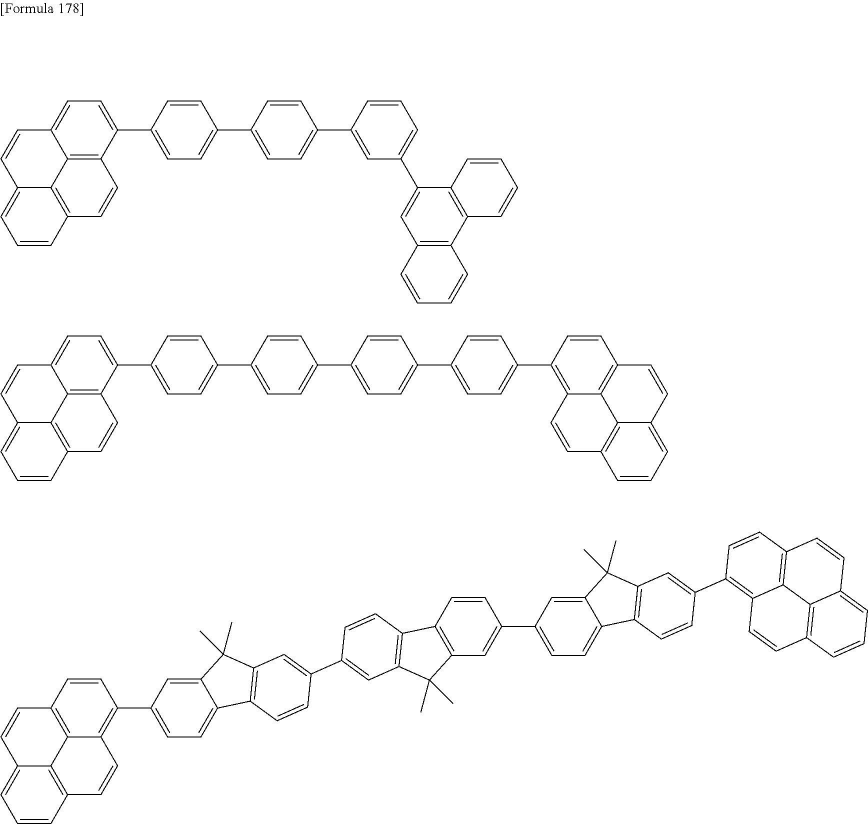

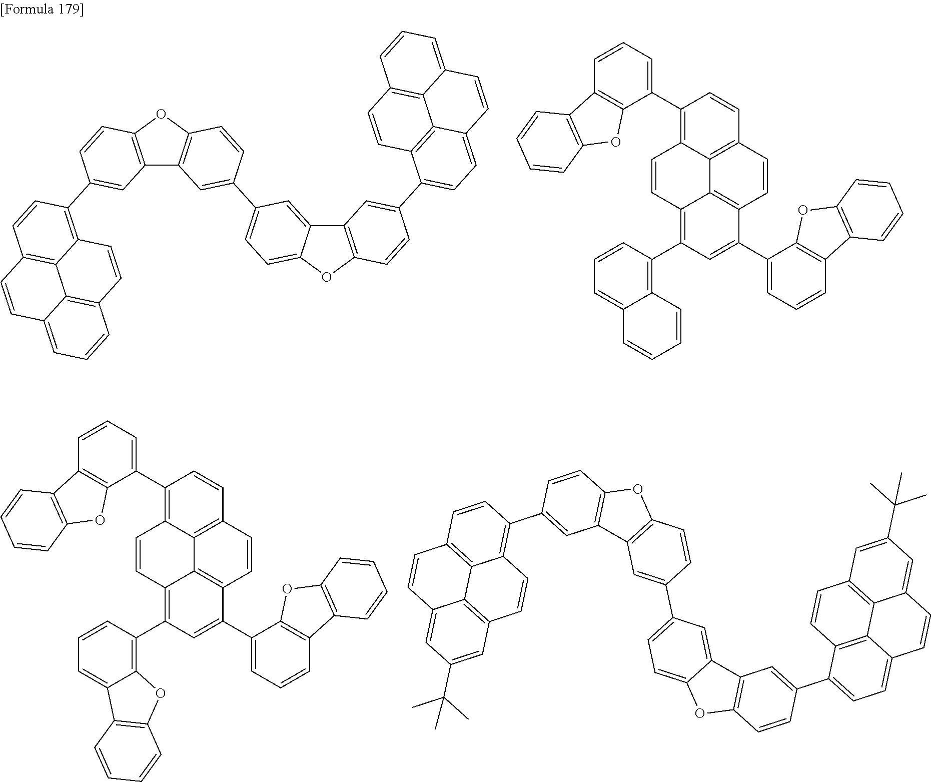

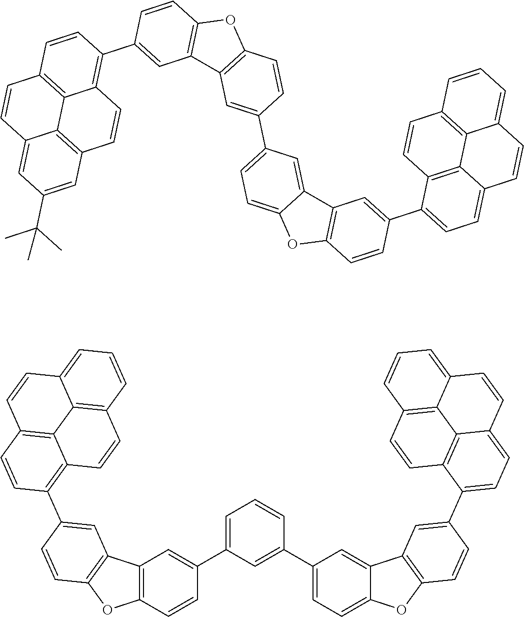 [SMILES: CC(C)(C)c1cc2ccc3ccc(-c4ccc5oc6ccc(-c7ccc8oc9ccc(-c%10ccc%11ccc%12cccc%13ccc%10c%11c%12%13)cc9c8c7)cc6c5c4)c4ccc(c1)c2c34 ; c1cc(-c2ccc3oc4ccc(-c5ccc6ccc7cccc8ccc5c6c78)cc4c3c2)cc(-c2ccc3oc4ccc(-c5ccc6ccc7cccc8ccc5c6c78)cc4c3c2)c1]

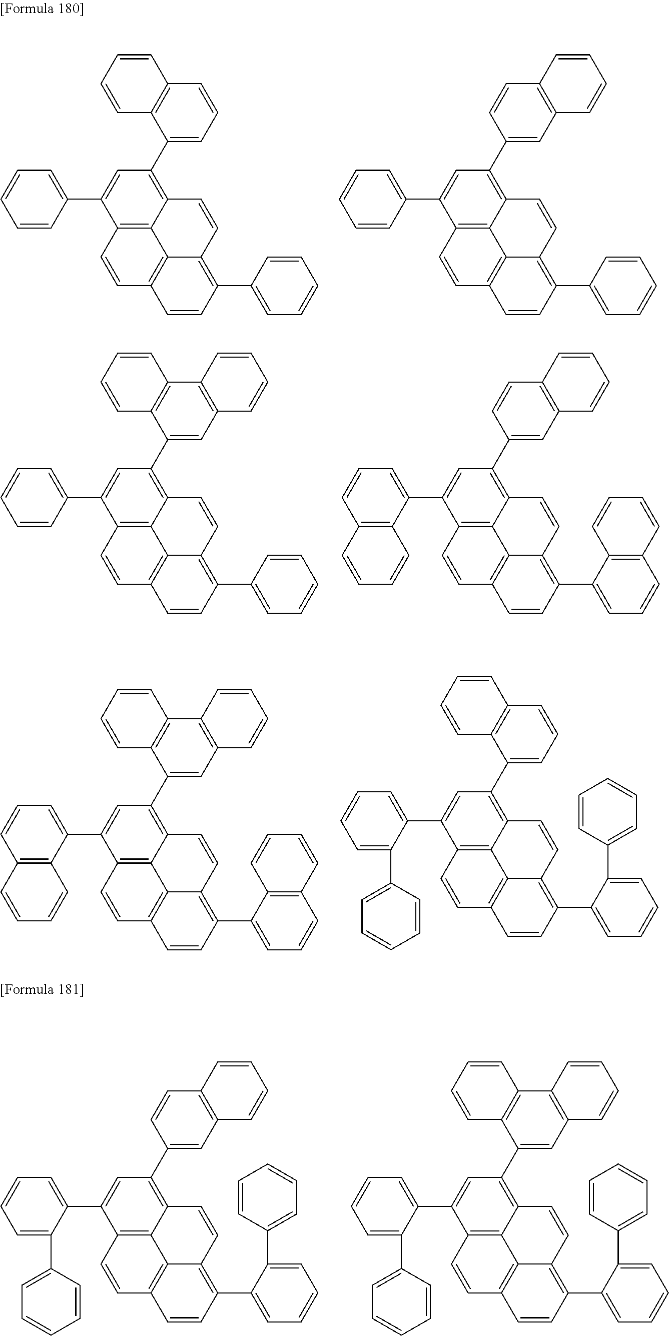

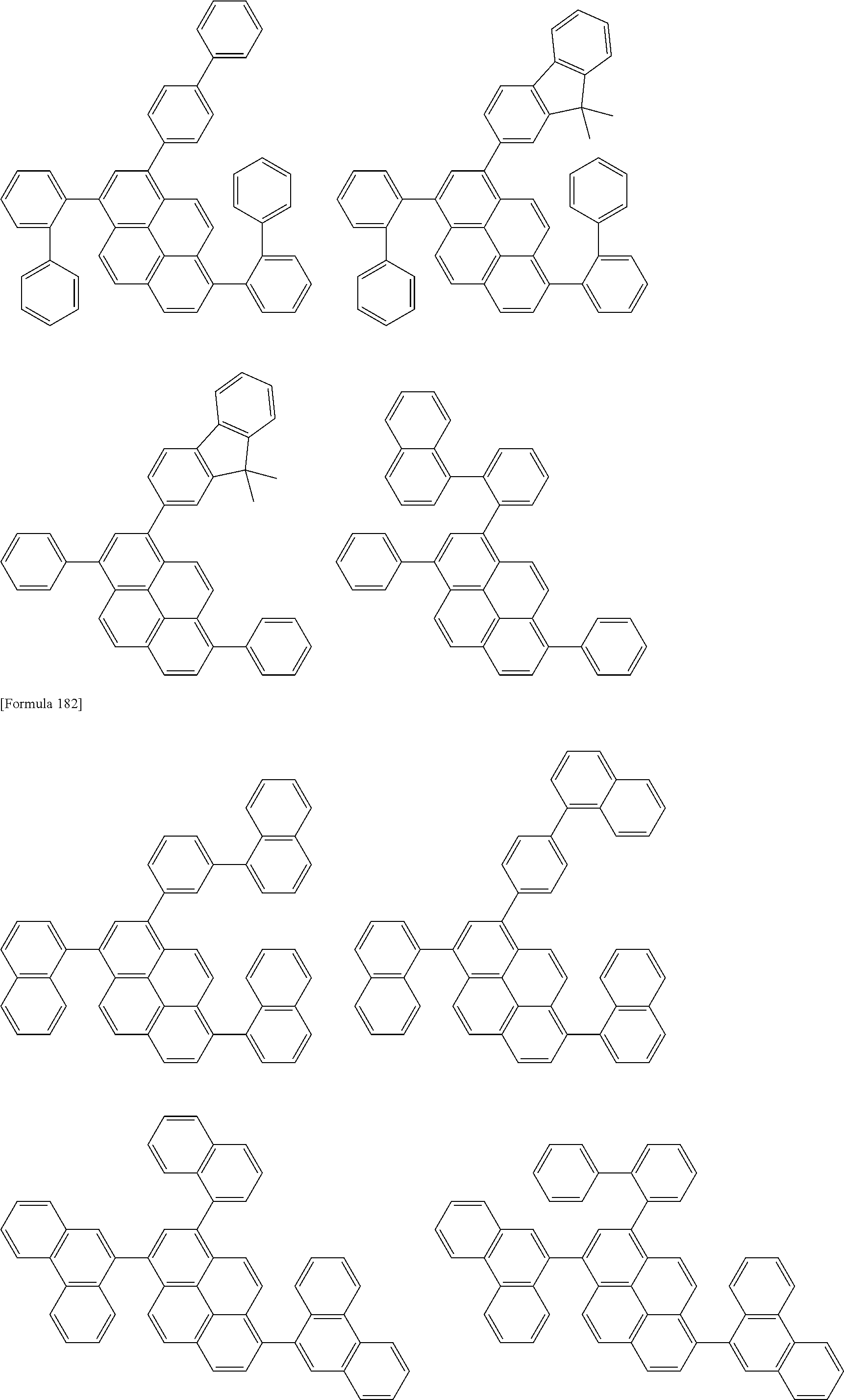

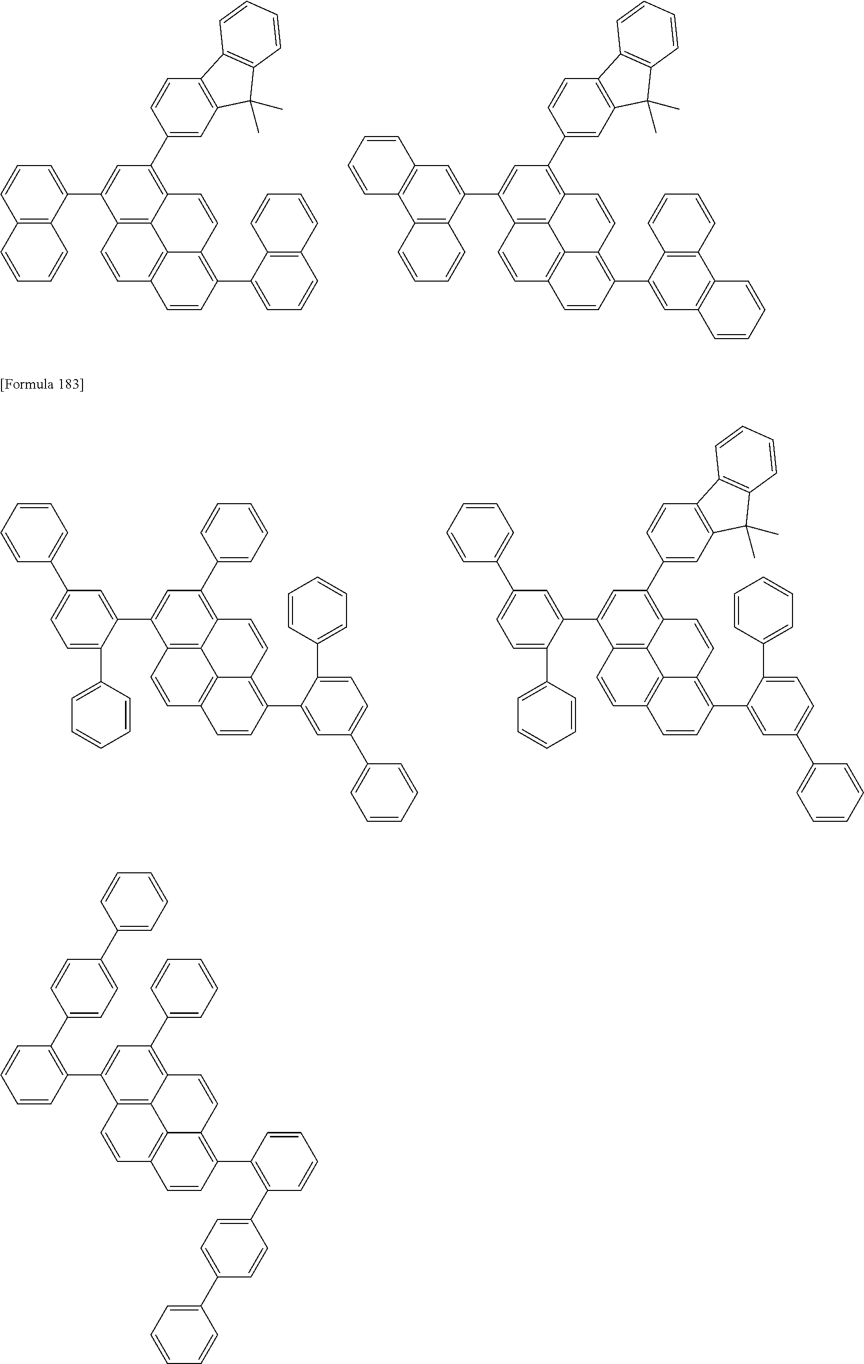

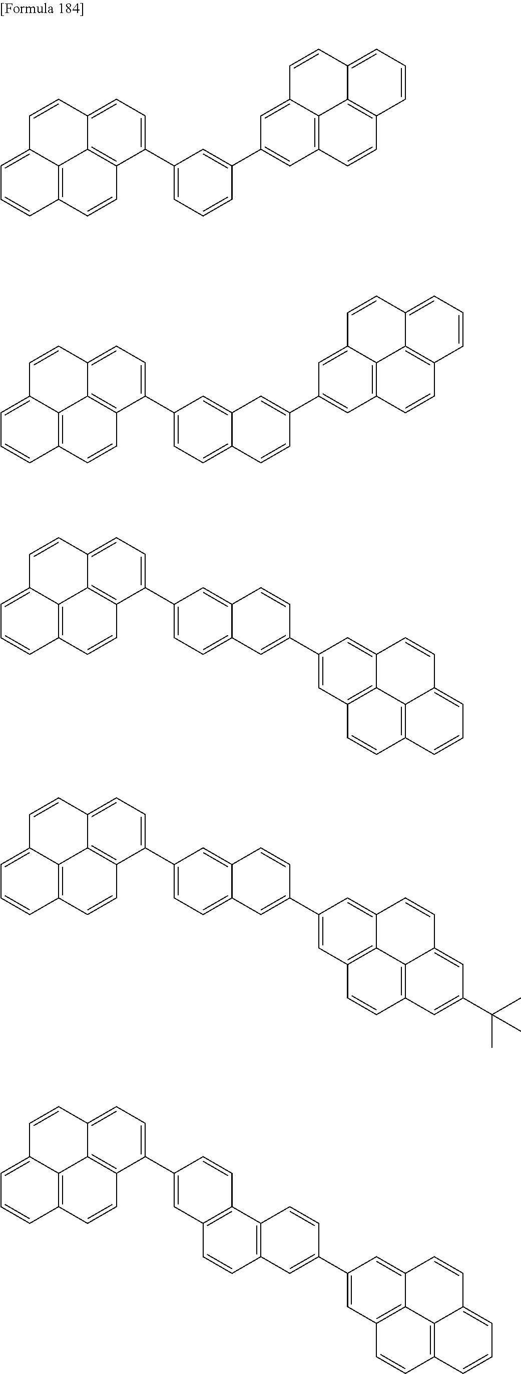

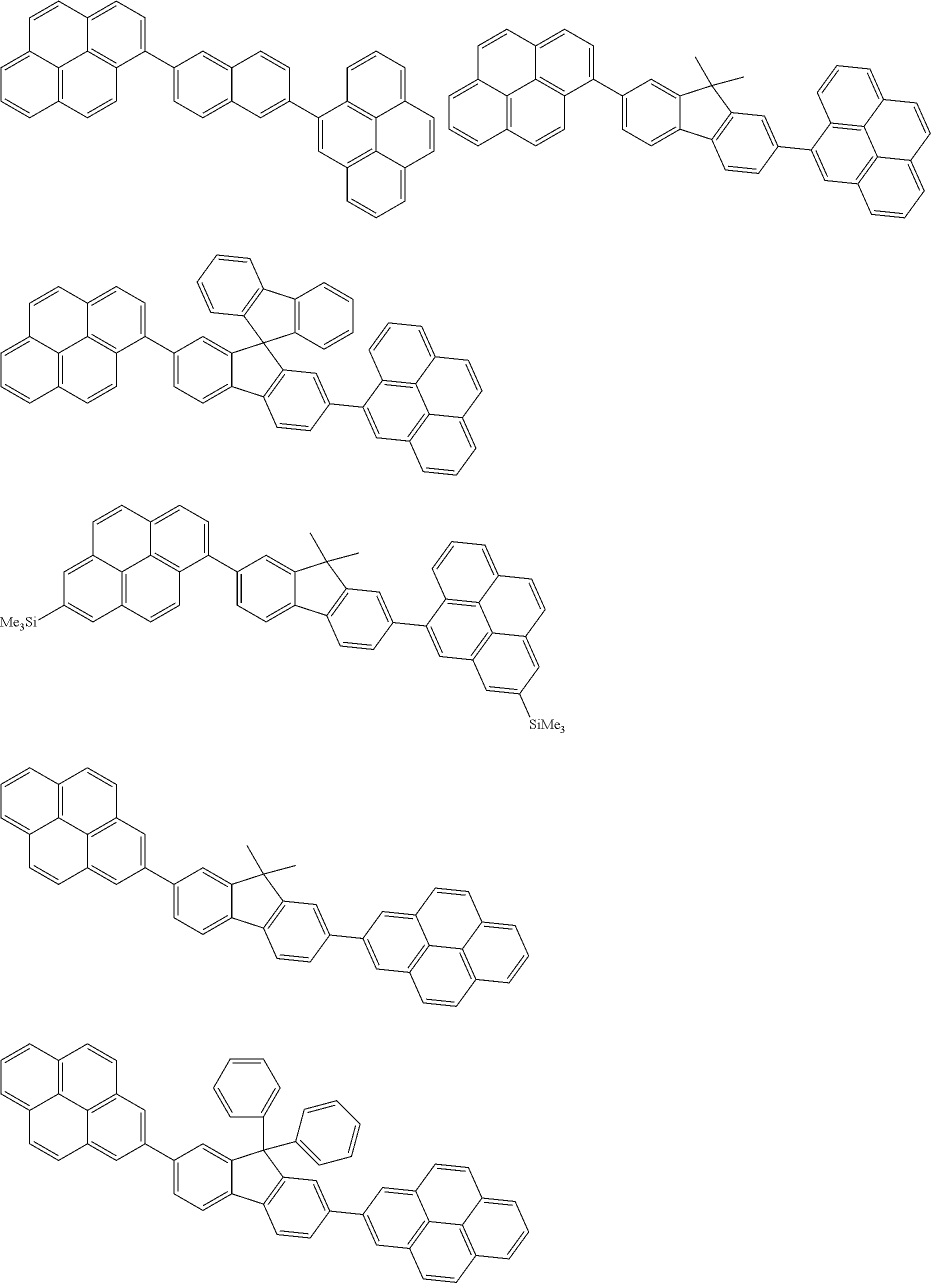

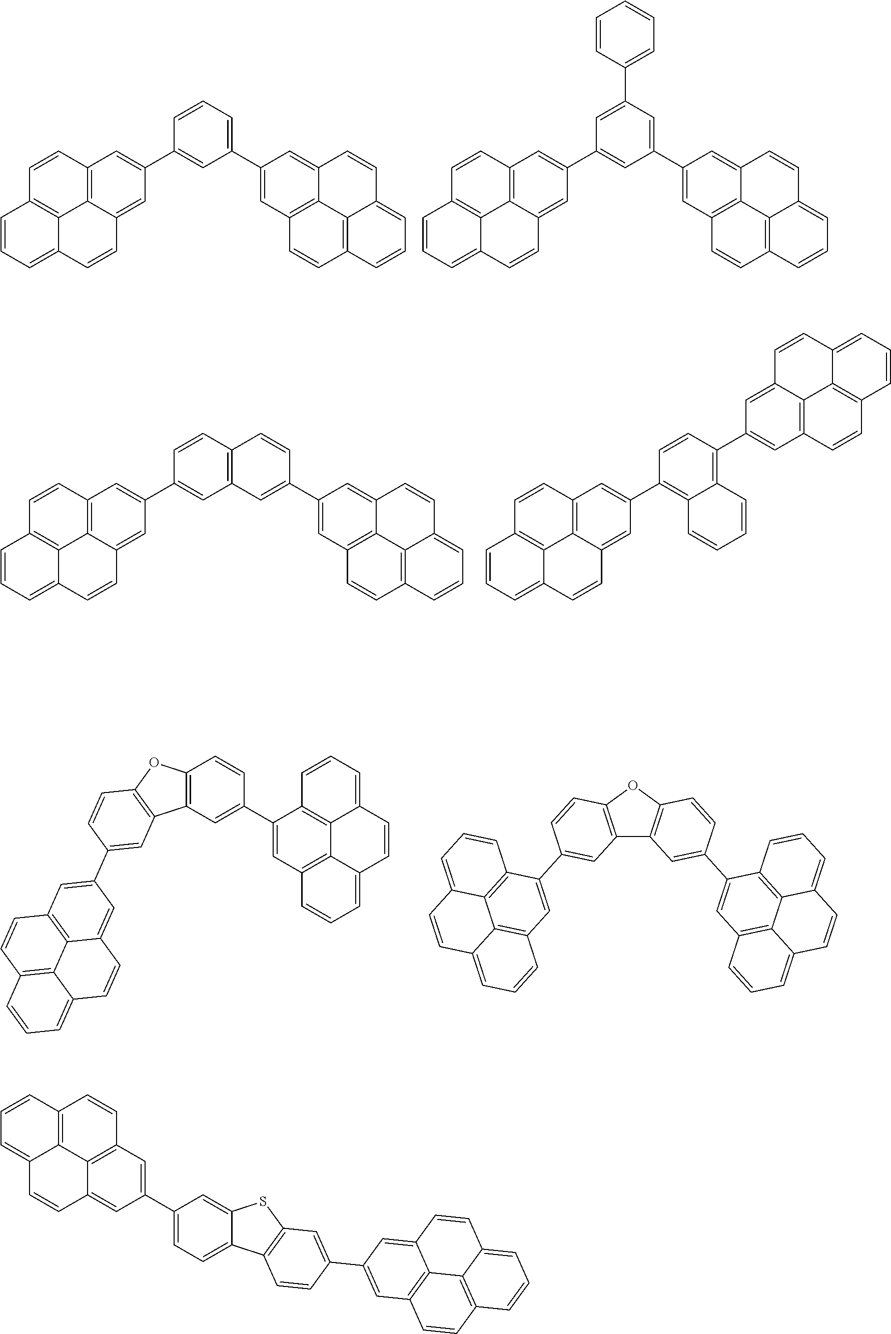

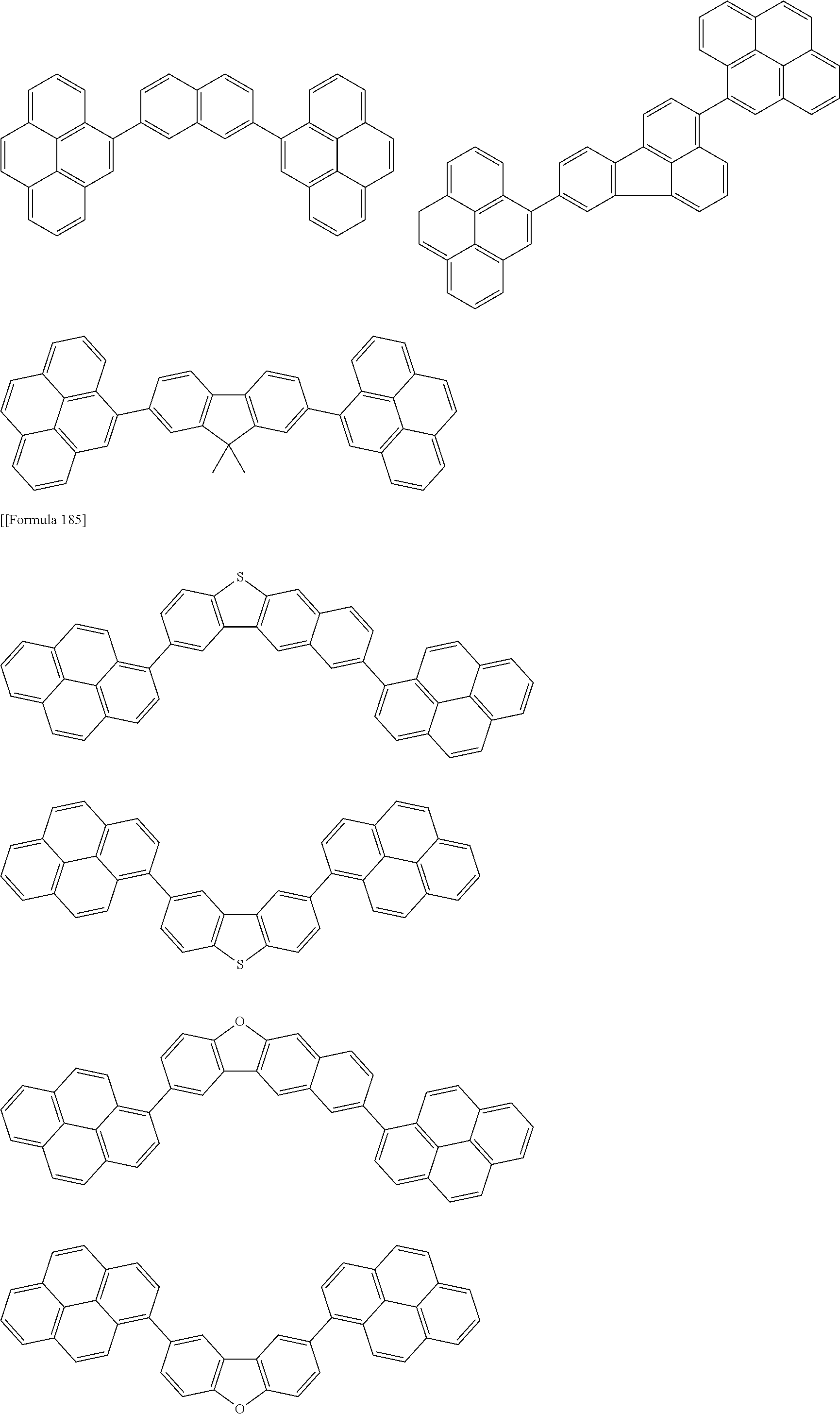

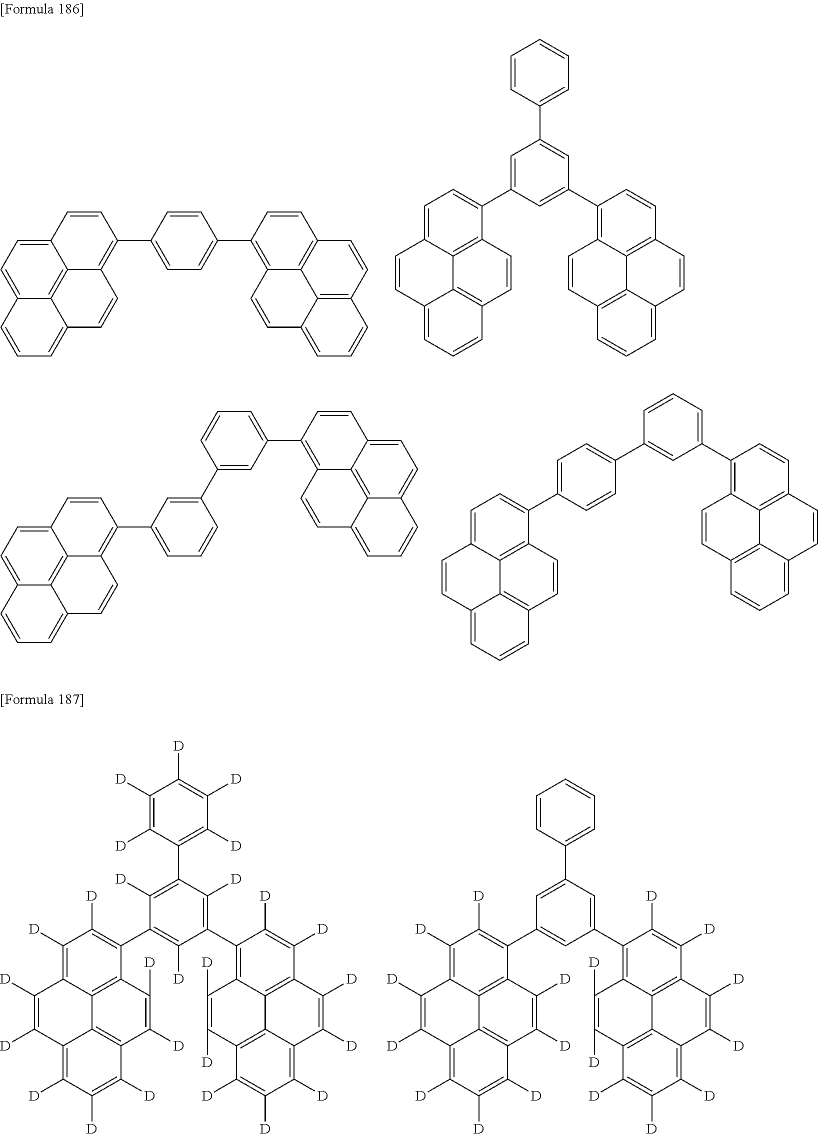

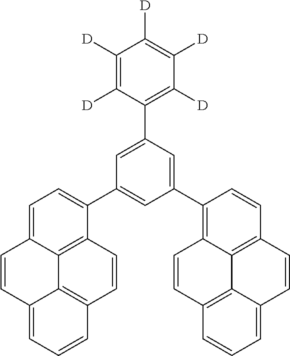 [SMILES: [2H]c1c([2H])c([2H])c(-c2cc(-c3ccc4ccc5cccc6ccc3c4c56)cc(-c3ccc4ccc5cccc6ccc3c4c56)c2)c([2H])c1[2H]]

When the second host material is a benzanthracene derivative, the second host material is preferably a compound represented by a formula (H1X) below.

### Compound Represented by Formula (H1X)

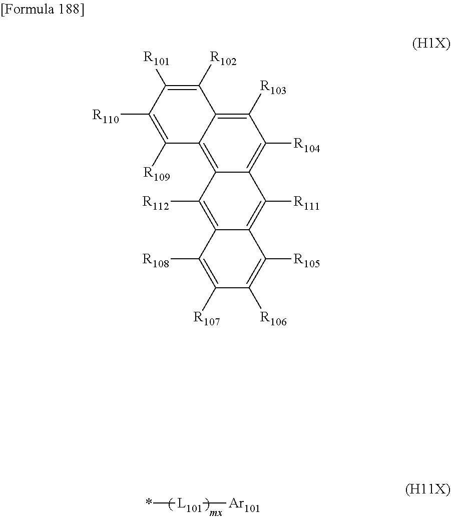

In the formula (H1X):
R₁₀₁ to R₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (H11X);
at least one of R₁₀₁ to R₁₁₂ is a group represented by the formula (H11X);
when a plurality of groups represented by the formula (H11X) are present, the plurality of groups represented by the formula (H11X) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (H11X) represents a bonding position to a benz[a]anthracene ring in the formula (H1X).

In the organic EL device according to the exemplary embodiment, the group represented by the formula (H11X) is preferably a group represented by a formula (H111X) below.

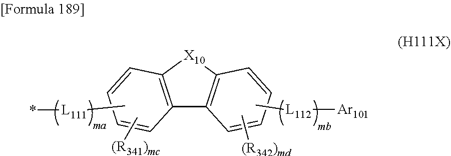

In the formula (H111X):
X₁₀ is C(R₃₄₃)(R₃₄₄), an oxygen atom, a sulfur atom, or NR₃₄₅;
L111 and L112 are each independently a single bond, a substituted or unsubstituted arylene group having 6 to 50 ring carbon atoms, or a substituted or unsubstituted divalent heterocyclic group having 5 to 50 ring atoms;
m is 1, 2, 3 or 4;
mb is 1, 2, 3 or 4;
ma+mb is 2, 3, or 4;
Ar₁₀₁ represents the same as Ar₁₀₁ in the formula (H11X);
R₃₄₁, R₃₄₂, R₃₄₃, R₃₄₄, and R₃₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₃₄₁ are mutually the same or different;
md is 3; and
three R₃₄₂ are mutually the same or different.

Among positions *1 to *8 of carbon atoms in a cyclic structure represented by a formula (H111aX) below in the group represented by the formula (H111X), L111 is bonded to one of the positions *1 to *4, R₃₄₁ is bonded to each of three positions of the rest of *1 to *4, L₁₁₂ is bonded to one of the positions *5 to *8, and R₃₄₂ is bonded to each of three positions of the rest of *5 to *8.

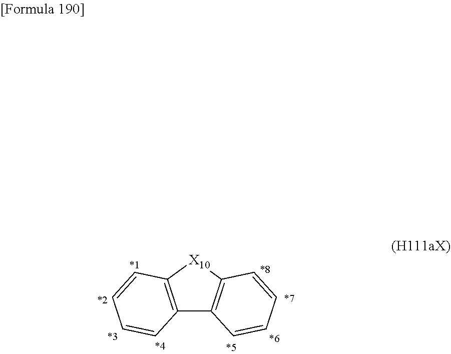

For instance, in the group represented by the formula (H111X), when L111 is bonded to a carbon atom at *2 in the cyclic structure represented by the formula (H111aX) and L112 is bonded to a carbon atom at *7 in the cyclic structure represented by the formula (H111aX), the group represented by the formula (H111X) is represented by a formula (H111bX) below.

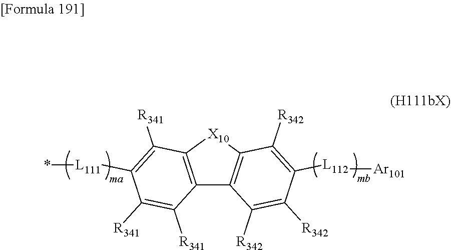

In the formula (H111 bX):
X₁₀, L₁₁₁, L₁₁₂, ma, mb, Ar₁₀₁, R₃₄₁, R₃₄₂, R₃₄₃, R₃₄₄ and R₃₄₅ each independently represent the same as X₁₀, L₁₁₁, L₁₁₂, ma, mb, Ar₁₀₁, R₃₄₁, R₃₄₂, R₃₄₃, R₃₄₄ and R₃₄₅ in the formula (H111X);
a plurality of R₃₄₁ are mutually the same or different; and
a plurality of R₃₄₂ are mutually the same or different.

In the organic EL device according to the exemplary embodiment, the group represented by the formula (H111X) is preferably a group represented by the formula (H111bX).

In the compound represented by the formula (H1X), it is preferable that ma is 1 or 2 and mb is 1 or 2.

In the compound represented by the formula (H1X), it is preferable that ma is 1 and mb is 1.

In the compound represented by the formula (H1X), Ar₁₀₁ is preferably a substituted or unsubstituted aryl group having 6 to 50 ring carbon atoms.

In the compound represented by the formula (H1X), Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted benz[a]anthryl group, a substituted or unsubstituted pyrenyl group, a substituted or unsubstituted phenanthryl group, or a substituted or unsubstituted fluorenyl group.

The compound represented by the formula (H1X) is also preferably represented by a formula (H101X) below.

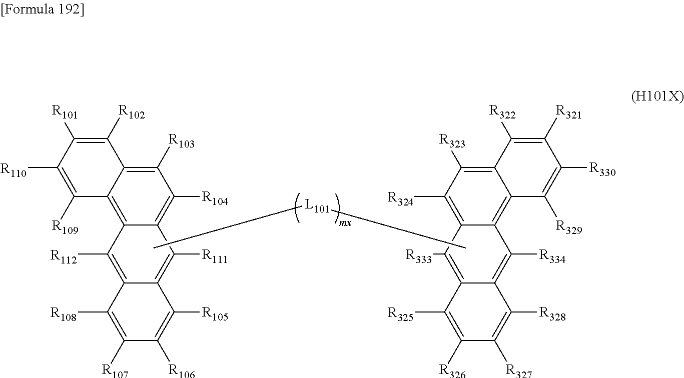

In the formula (H101X):
one of R₁₁₁ and R₁₁₂ represents a bonding position to L₁₀₁ and one of R₃₃₃ and R₃₃₄ represents a bonding position to L₁₀₁;
R₁₀₁ to R₁₁₀, R₃₂₁ to R₃₃₀, R₁₁₁ or R₁₁₂ not being the bonding position to L₁₀₁, and R₃₃₃ or R₃₃₄ not being the bonding position to L₁₀₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₀₁ is a single bond, a substituted or unsubstituted arylene group having 6 to 50 ring carbon atoms, or a substituted or unsubstituted divalent heterocyclic group having 5 to 50 ring atoms;
mx is 1, 2, 3, 4, or 5; and
when two or more L₁₀₁ are present, the two or more L₁₀₁ are mutually the same or different.

In the compound represented by the formula (H1X), L₁₀₁ is preferably a single bond or a substituted or unsubstituted arylene group having 6 to 50 ring carbon atoms.

The compound represented by the formula (H1X) is also preferably represented by a formula (H102X) below.

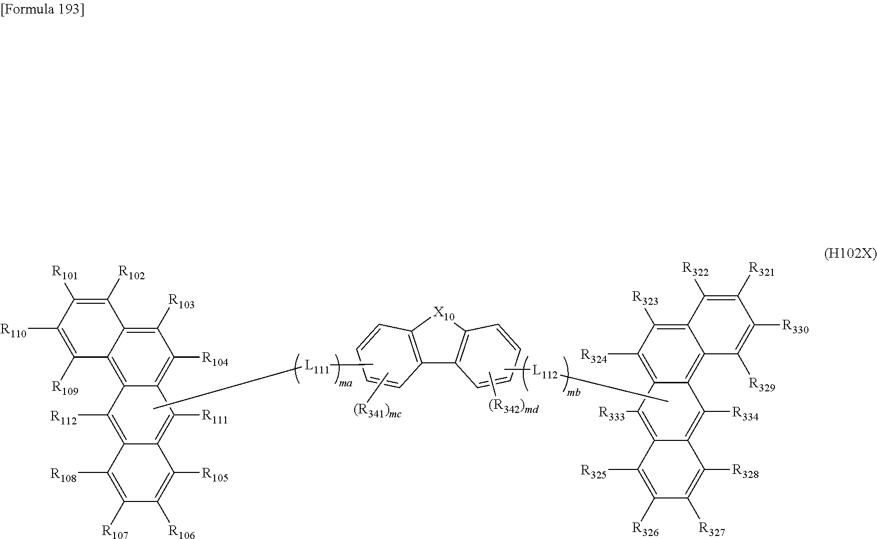

In the formula (H102X):
one of R₁₁₁ and R₁₁₂ represents a bonding position to L₁₁₁ and one of R₃₃₃ and R₃₃₄ represents a bonding position to 112;
R₁₀₁ to R₁₁₀, R₃₂₁ to R₃₃₀, R₁₁₁ or R₁₁₂ not being the bonding position to L₁₁₁, and R₃₃₃ or R₃₃₄ not being the bonding position to L112 are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
X₁₀ is C(R₃₄₃)(R₃₄₄), an oxygen atom, a sulfur atom, or NR₃₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
m is 1, 2, 3 or 4;
mb is 1, 2, 3 or 4;
ma+mb is 2, 3, 4, or 5;
R₃₄₁, R₃₄₂, R₃₄₃, R₃₄₄, and R₃₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₃₄₁ are mutually the same or different;
md is 3; and
three R₃₄₂ are mutually the same or different.

In the compound represented by the formula (H1X), it is preferable that ma is 1 or 2 and mb is 1 or 2 in the formula (H102X).

In the compound represented by the formula (H1X), it is preferable that ma is 1 and mb is 1 in the formula (H102X).

In the compound represented by the formula (H1X), the group represented by the formula (H11X) is also preferably a group represented by a formula (H11AX) or a group represented by a formula (H11 BX) below.

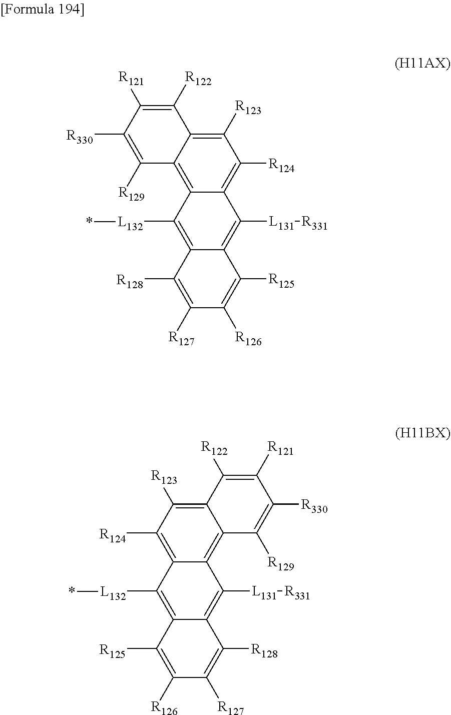

In the formulae (H11AX) and (H11 BX):
R₁₂₁ to R₁₂₉, R₃₃₀, and R₃₃₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms,
when a plurality of groups represented by the formula (H11AX) are present, the plurality of groups represented by the formula (H11AX) are mutually the same or different;
when a plurality of groups represented by the formula (H11 BX) are present, the plurality of groups represented by the formula (H11 BX) are mutually the same or different;
L131 and L132 are each independently a single bond, a substituted or unsubstituted arylene group having 6 to 50 ring carbon atoms, or a substituted or unsubstituted divalent heterocyclic group having 5 to 50 ring atoms; and
* in each of the formulae (H11AX) and (H11 BX) represents a bonding position to a benz[a]anthracene ring in the formula (H1X).

The compound represented by the formula (H1X) is also preferably represented by a formula (H103X) below.

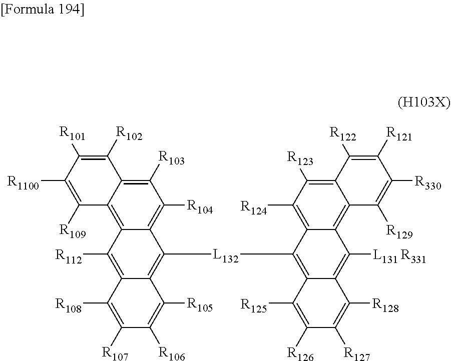

In the formula (H103X):
R₁₀₁ to R₁₁₀ and R₁₁₂ respectively represent the same as R₁₀₁ to R₁₁₀ and R₁₁₂ in the formula (H1X); and
R₁₂₁ to R₁₂₉, R₃₃₀, R₃₃₁, L₁₃₁, and L₁₃₂ each independently represent the same as R₁₂₁ to R₁₂₉, R₃₃₀, R₃₃₁, L₁₃₁, and L₁₃₂ in the formula (H11 BX).

In the compound represented by the formula (H1X), L331 is also preferably a substituted or unsubstituted arylene group having 6 to 50 ring carbon atoms.

In the compound represented by the formula (H1X), L332 is also preferably a substituted or unsubstituted arylene group having 6 to 50 ring carbon atoms.

In the compound represented by the formula (H1X), two or more of R₁₀₁ to R₁₁₂ are each also preferably a group represented by the formula (H110).

In the compound represented by the formula (H1X), it is preferable that two or more of R₁₀₁ to R₁₁₂ are each a group represented by the formula (H11 X) and Ar₁₀₁ in the formula (H11X) is a substituted or unsubstituted aryl group having 6 to 50 ring carbon atoms.

In the compound represented by the formula (H1X), it is also preferable that Ar₁₀₁ is not a substituted or unsubstituted benz[a]anthryl group, L₁₀₁ is not a substituted or unsubstituted benz[a]anthrylene group, and, the substituted or unsubstituted aryl group having 6 to 50 ring carbon atoms for R₁₀₁ to R₁₁₀ not being the group represented by the formula (H11X) is not a substituted or unsubstituted benz[a]anthryl group.

In the compound represented by the formula (H1X), R₁₀₁ to R₁₁₂ not being a group represented by the formula (H11X) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound represented by the formula (H1X), R₁₀₁ to R₁₁₂ not being a group represented by the formula (H11 X) are preferably each a hydrogen atom, a substituted or unsubstituted alkyl group having 1 to 50 carbon atoms, or a substituted or unsubstituted cycloalkyl group having 3 to 50 ring carbon atoms.

In the compound represented by the formula (H1X), R₁₀₁ to R₁₁₂ not being the group represented by the formula (H11X) are preferably each a hydrogen atom.

A compound represented by the formula (H1X) can be produced by a known method.

Specific Examples of Compound Represented by Formula (H1X) Specific examples of the compound represented by the formula (H1X) include compounds shown below. However, the compound represented by the formula (H1X) is by no means limited to the specific examples below.

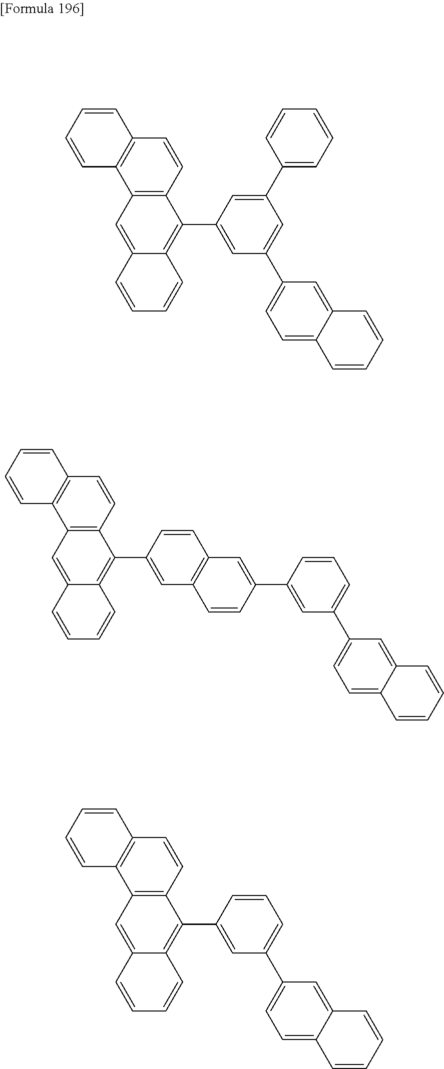

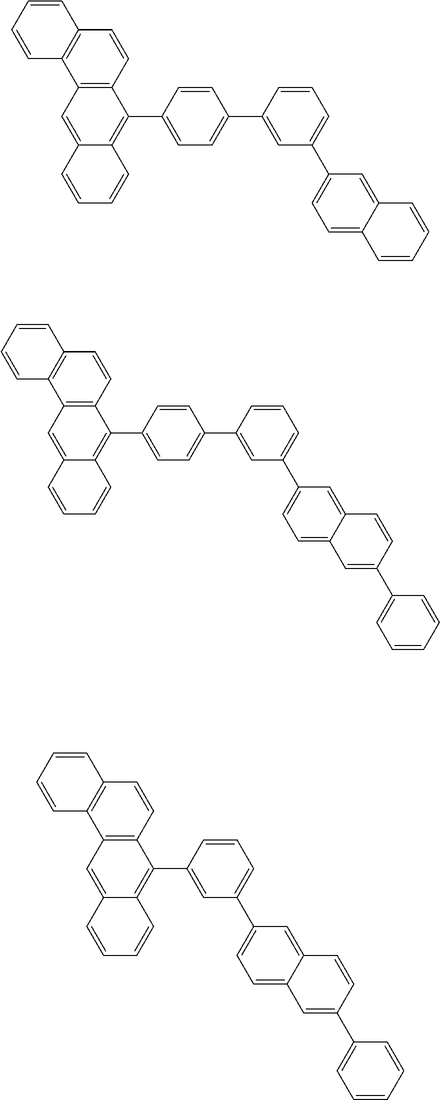

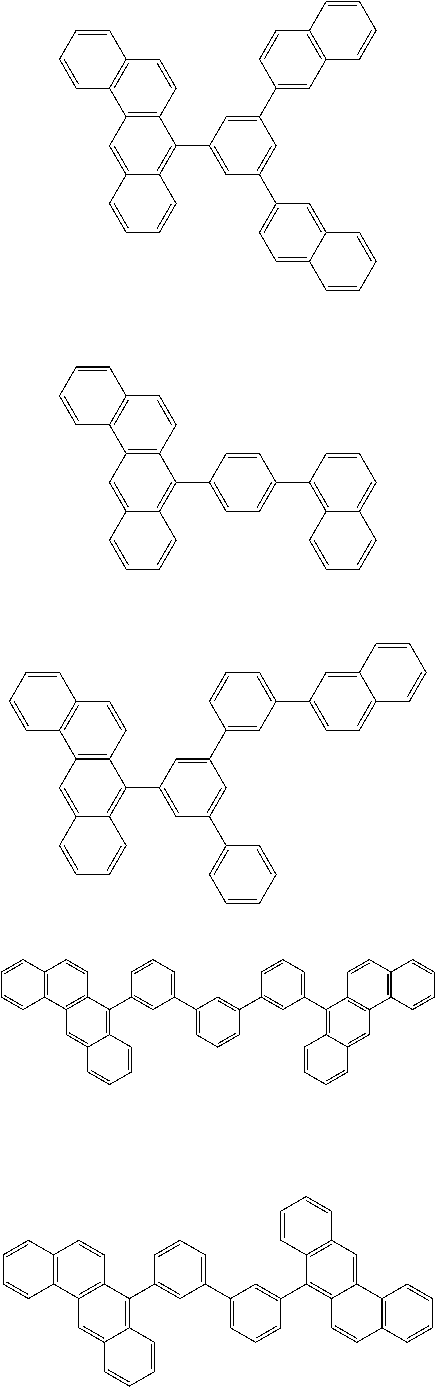

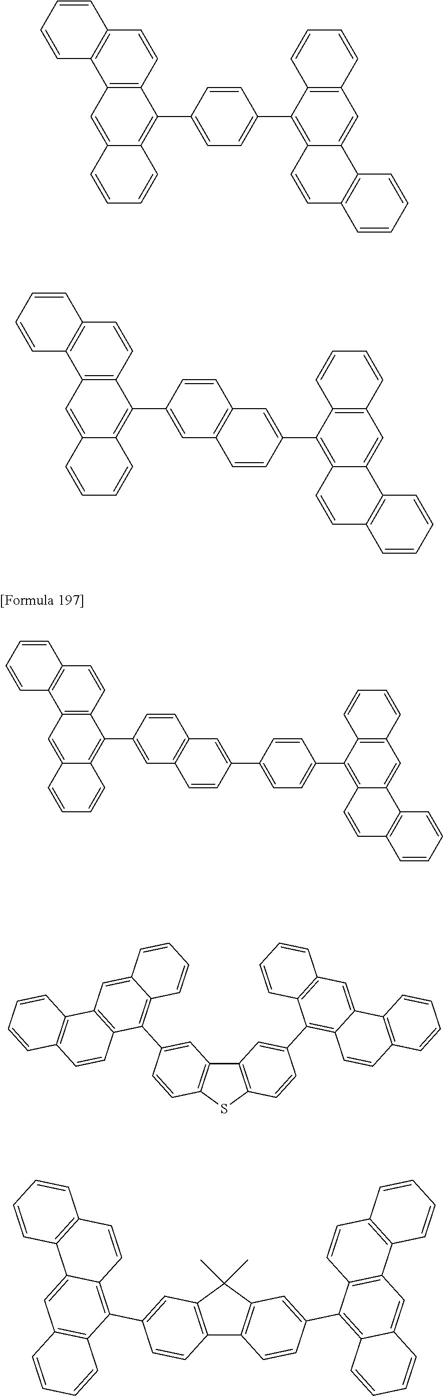

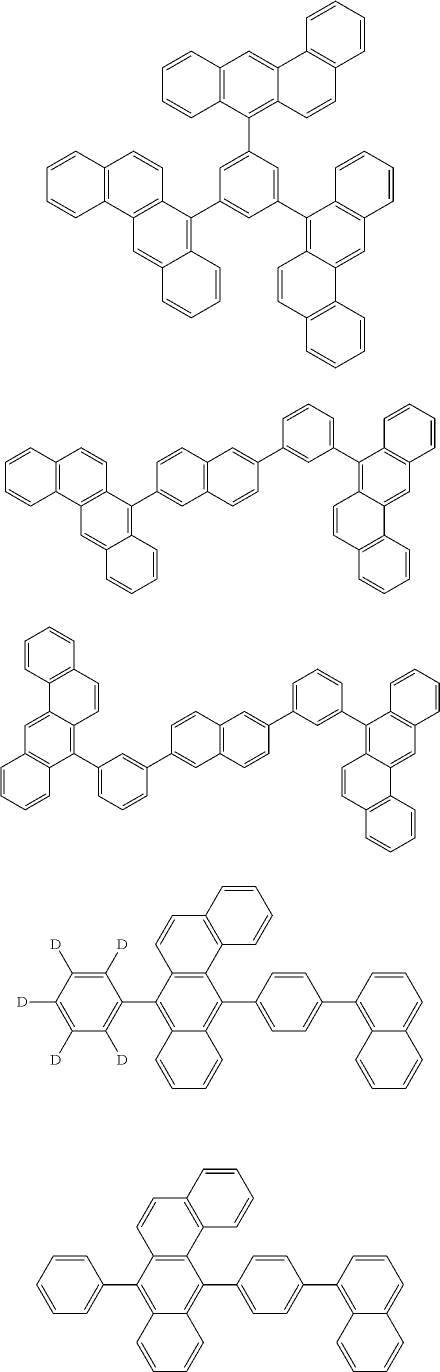

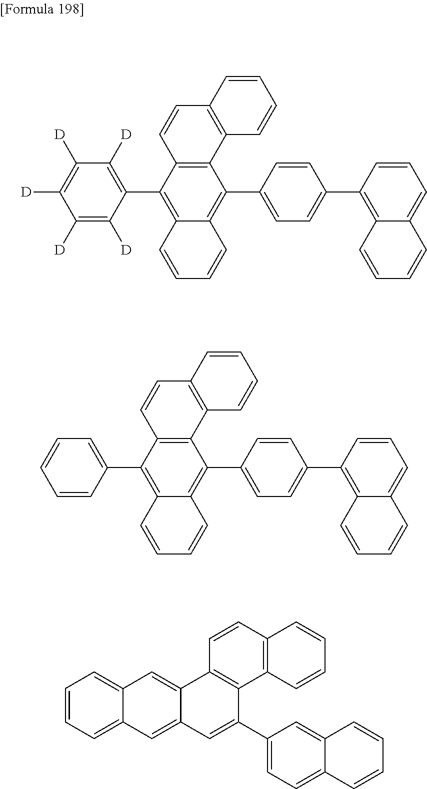

When the second host material is a benzoxanthene derivative, the second host material is preferably a compound represented by a formula (H14X) below.

### Compound Represented by Formula (H14X)

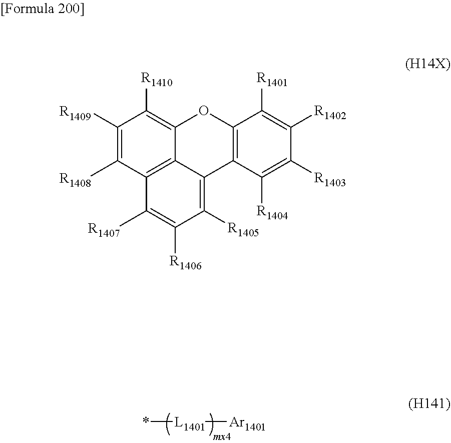

In the formula (H14X):
R₁₄₀₁ to R₁₄₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (H141);
at least one of R₁₄₀₁ to R₁₄₁₀ is a group represented by the formula (H141);
when a plurality of groups represented by the formula (H141) are present, the plurality of groups represented by the formula (H141) are mutually the same or different;
L₁₄₀₁ is a single bond, a substituted or unsubstituted arylene group having 6 to 50 ring carbon atoms, or a substituted or unsubstituted divalent heterocyclic group having 5 to 50 ring atoms;
Ar₁₄₀₁ is a substituted or unsubstituted aryl group having 6 to 50 ring carbon atoms, or a substituted or unsubstituted heterocyclic group having 5 to 50 ring atoms;
mx4 is 0, 1, 2, 3, 4, or 5;
when two or more L1401 are present, the two or more L1401 are mutually the same or different;
when two or more Ar₁₄₀₁ are present, the two or more Ar₁₄₀₁ are mutually the same or different; and
* in the formula (H141) represents a bonding position to a ring represented by the formula (H14X).

A compound represented by the formula (H14X) can be produced by a known method.

### Specific Examples of Compound Represented by Formula (H14X)

Specific examples of the compound represented by the formula (H14X) include compounds shown below. However, the compound represented by the formula (H14X) is by no means limited to the specific examples below.

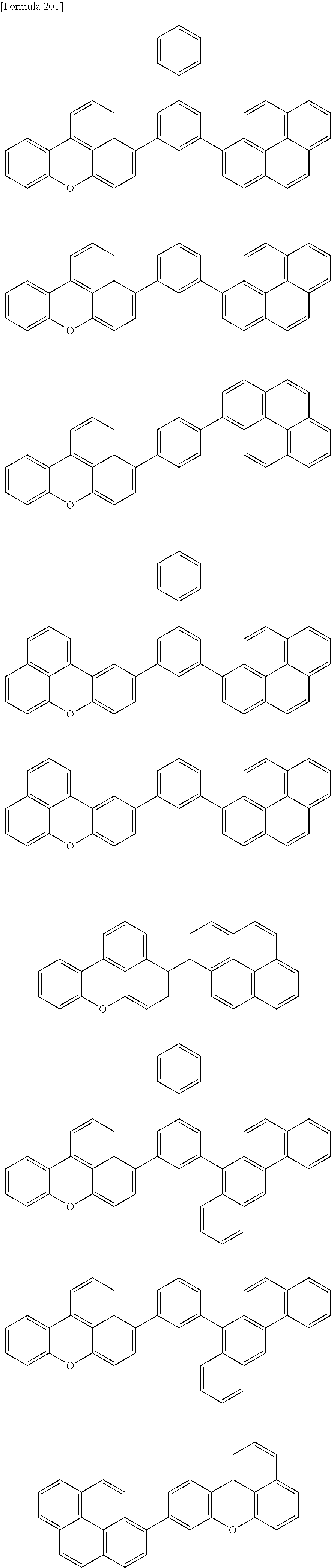

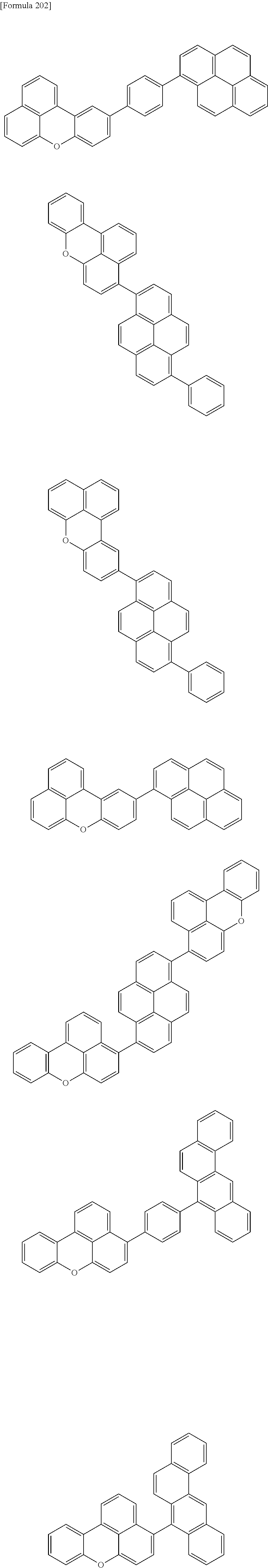

### Second Dopant Material

Examples of the second dopant material include the compound according to the first exemplary embodiment, a pyrene derivative, a styrylamine derivative, a chrysene derivative, a fluoranthene derivative, a fluorene derivative, a diamine derivative, a triarylamine derivative, an aromatic amine derivative, and a tetracene derivative.

The second dopant material is preferably the compound according to the first exemplary embodiment, a compound represented by a formula (5) below, or a compound represented by a formula (6) below.

### Compound Represented by Formula (5)

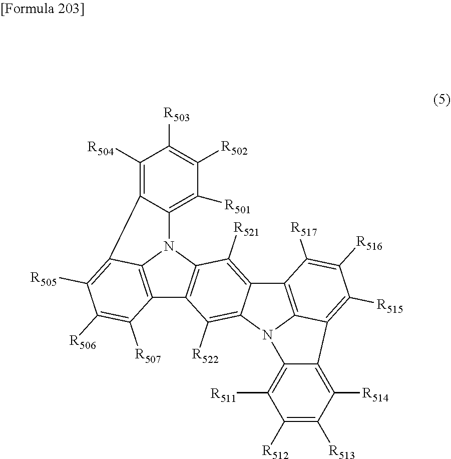

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded;
R₅₀₁ to R₅₀₇ and R₅₁₁ to R₅₁₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms, and
R₅₂₁ and R₅₂₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₅₀₆, a combination of R₅₀₆ and R₅₀₇, and a combination of R₅₀₁, R₅₀₂, and R₅₀₃.

In an exemplary embodiment, at least one, preferably two of R₅₀₁ to R₅₀₇ or R₅₁₁ to R₅₁₇ are each a group represented by —N(R₉₀₆)(R₉₀₇).

In an exemplary embodiment, R₅₀₁ to R₅₀₇ and R₅₁₁ to R₅₁₇ are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, the compound represented by the formula (5) is a compound represented by a formula (52) below.

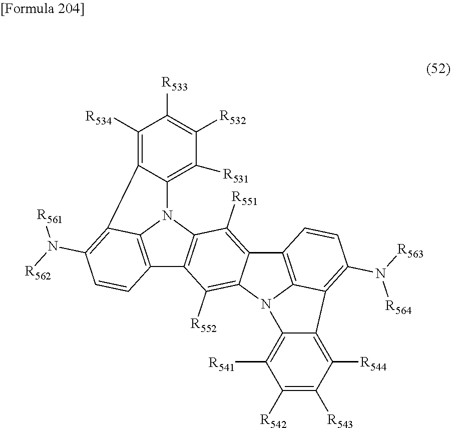

In the formula (52):
at least one combination of adjacent two or more of R₅₃₁ to R₅₃₄ and R₅₄₁ to R₅₄₄ are mutually bonded to form a substituted or unsubstituted monocyclic ring, mutually bonded to form a substituted or unsubstituted fused ring, or not mutually bonded;
R₅₃₁ to R₅₃₄, R₅₄₁ to R₅₄₄, R₅₅₁, and R₅₅₂ forming neither the substituted or unsubstituted monocyclic ring nor the substituted or unsubstituted fused ring are each independently a hydrogen atom, a substituted or unsubstituted aryl group having 6 to 50 ring carbon atoms, or a substituted or unsubstituted heterocyclic group having 5 to 50 ring atoms; and
R₅₆₁ to R₅₆₄ are each independently a substituted or unsubstituted aryl group having 6 to 50 ring carbon atoms, or a substituted or unsubstituted heterocyclic group having 5 to 50 ring atoms.

In an exemplary embodiment, the compound represented by the formula (5) is a compound represented by a formula (53) below.

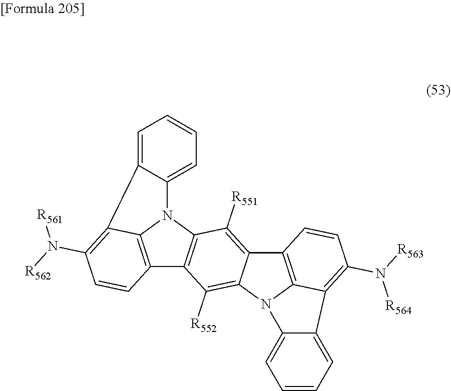

In the formula (53), R₅₅₁, R₅₅₂ and R₅₆₁ to R₅₆₄ each independently represent the same as R₅₅₁, R₅₅₂ and R₅₆₁ to R₅₆₄ in the formula (52).

In an exemplary embodiment, R₅₆₁ to R₅₆₄ in the formulae (52) and (53) are each independently a substituted or unsubstituted aryl group having 6 to 50 ring carbon atoms (preferably a phenyl group).

In an exemplary embodiment, R₅₂₁ and R₅₂₂ in the formula (5) and R₅₅₁ and R₅₅₂ in the formulae (52) and (53) are each a hydrogen atom.

In an exemplary embodiment, the substituent for the “substituted or unsubstituted” group in the formulae (5), (52) and (53) is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

A compound represented by the formula (5) can be produced by a known method.

### Specific Examples of Compound Represented by Formula (5)

Specific examples of the compound represented by the formula (5) include compounds shown below. However, the compound represented by the formula (5) is by no means limited to the specific examples below.

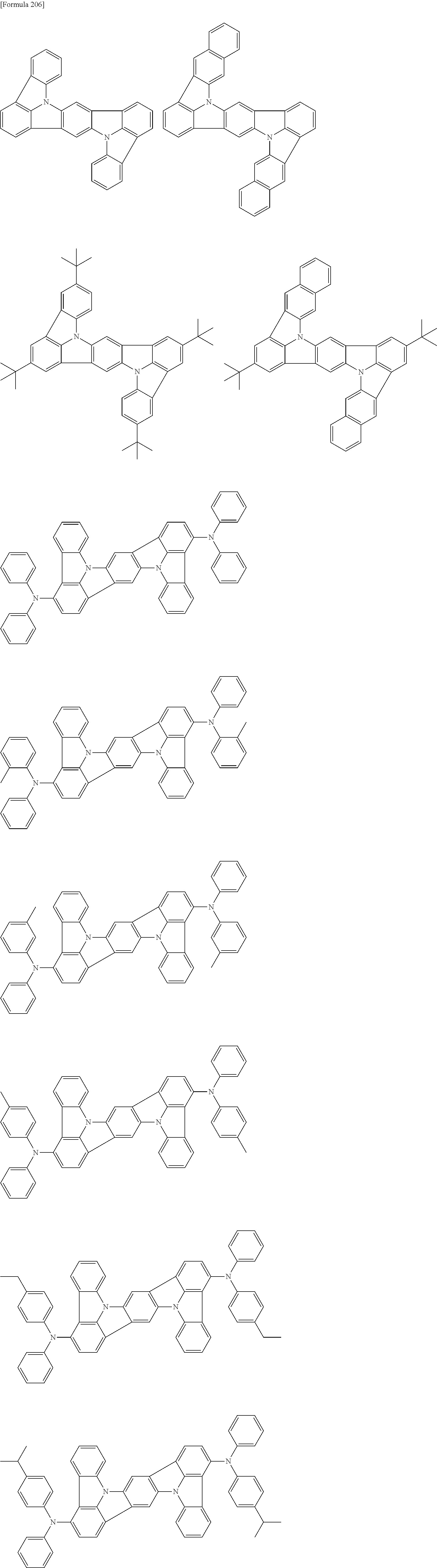

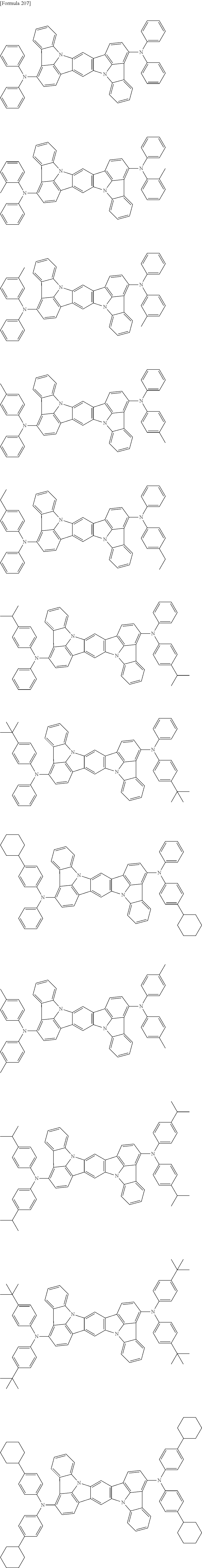

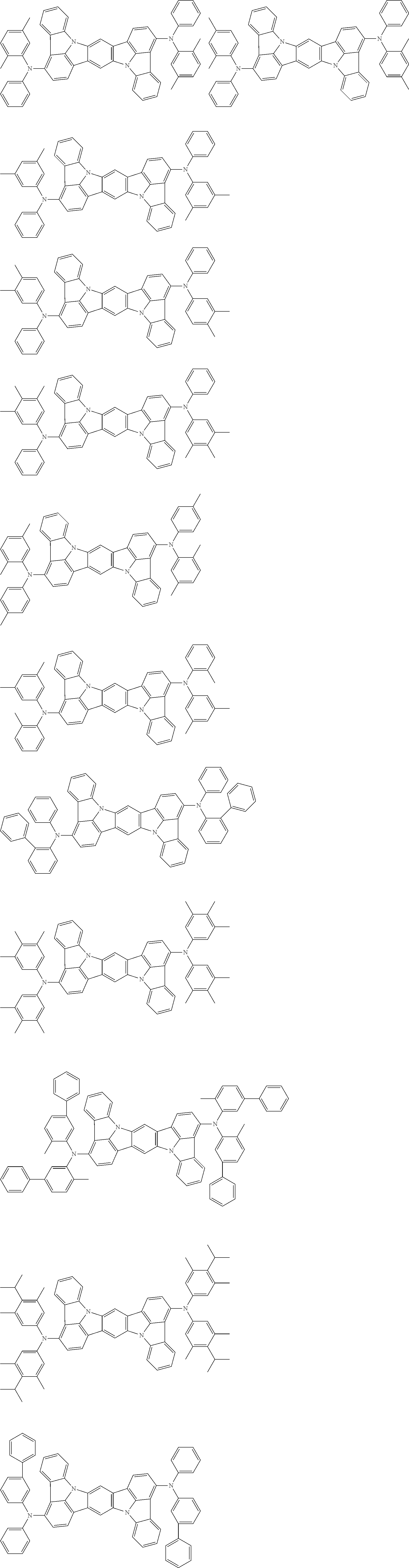

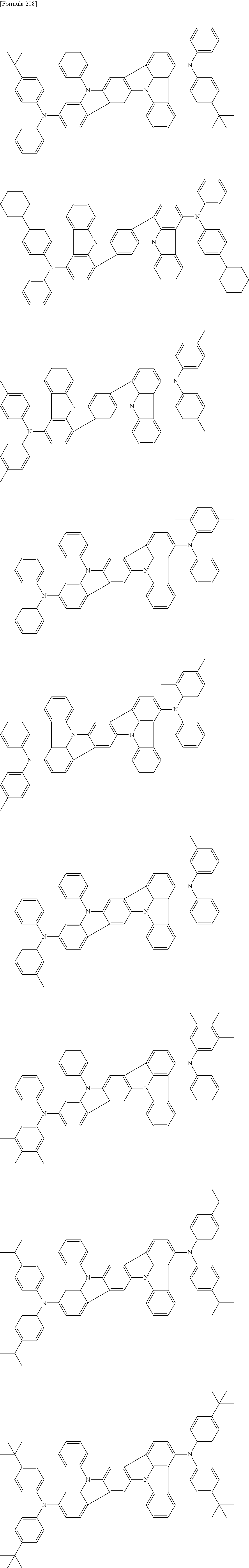

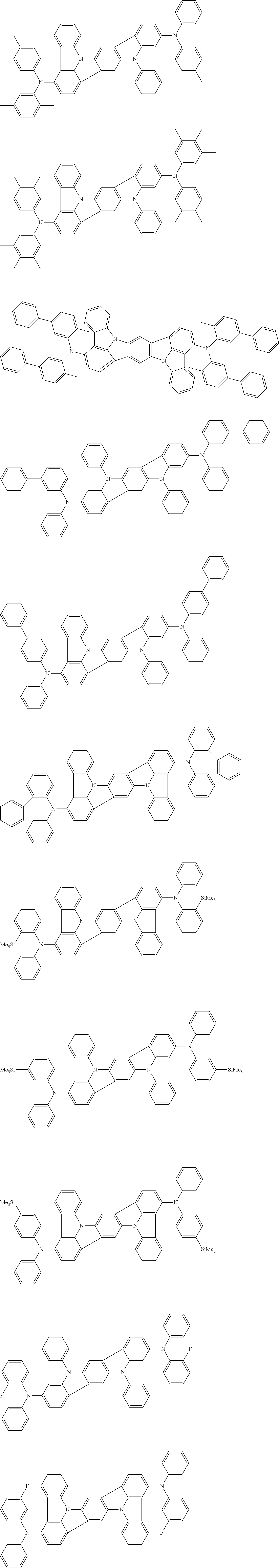

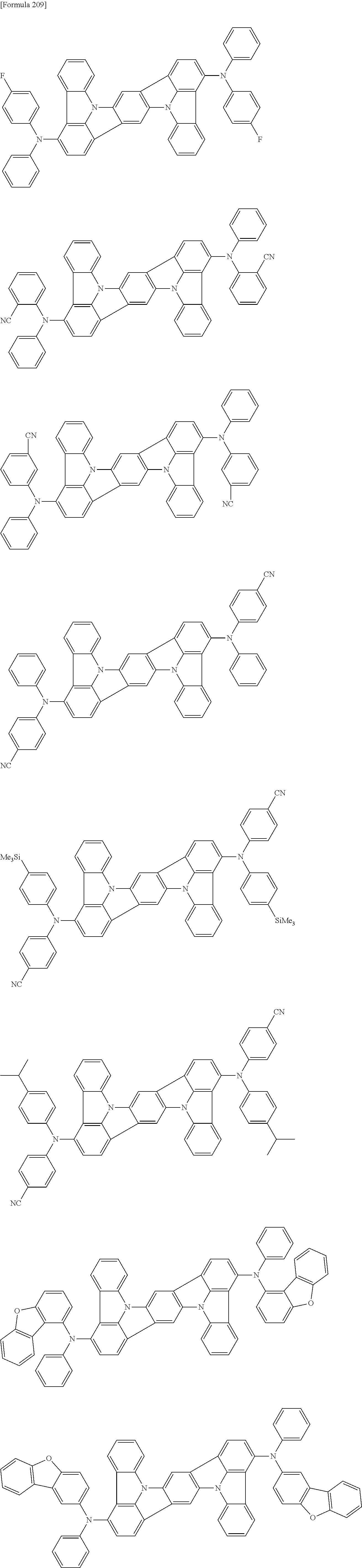

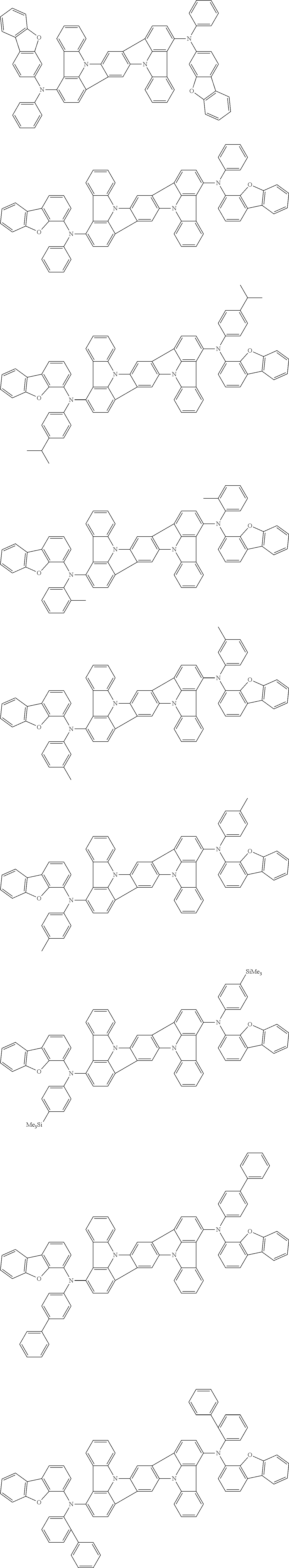

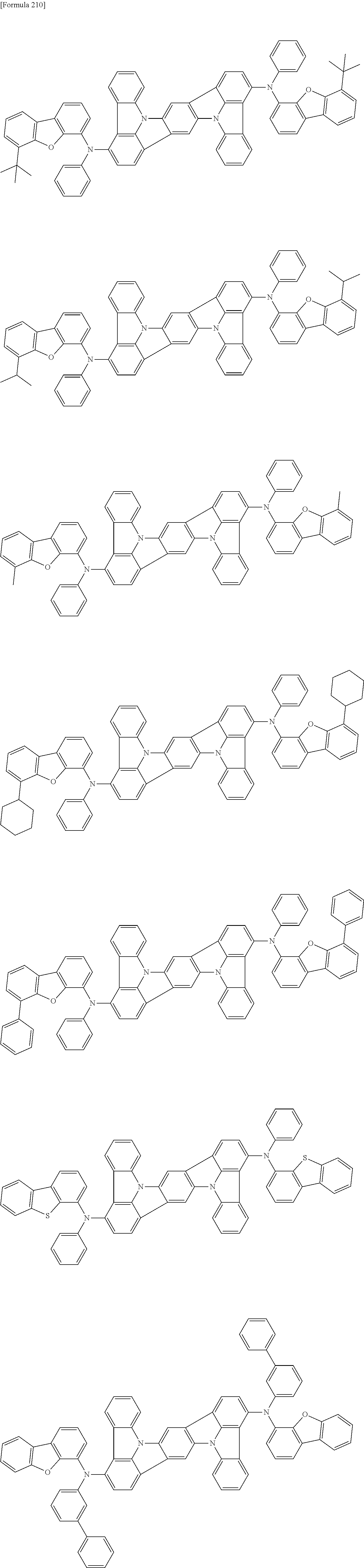

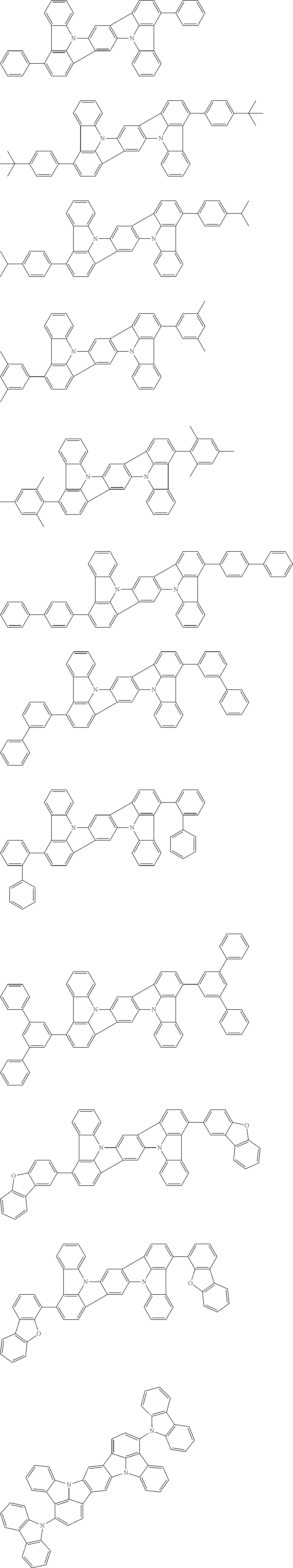

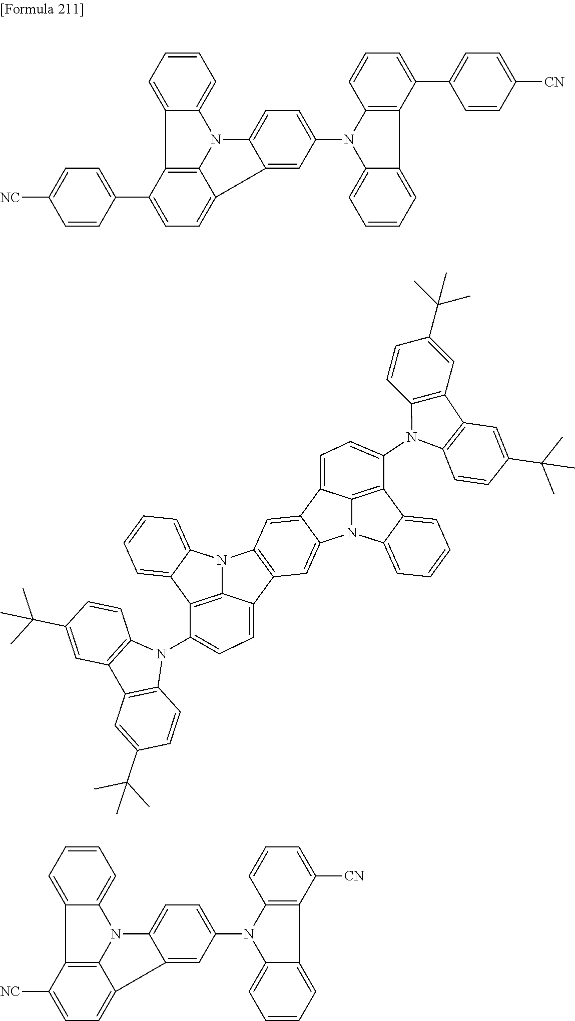

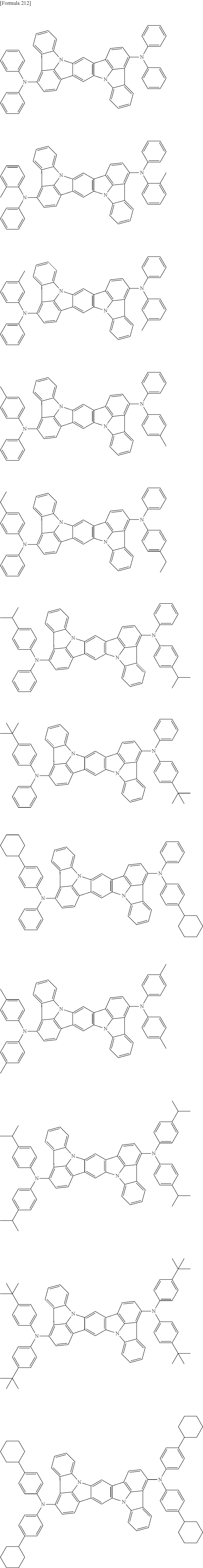

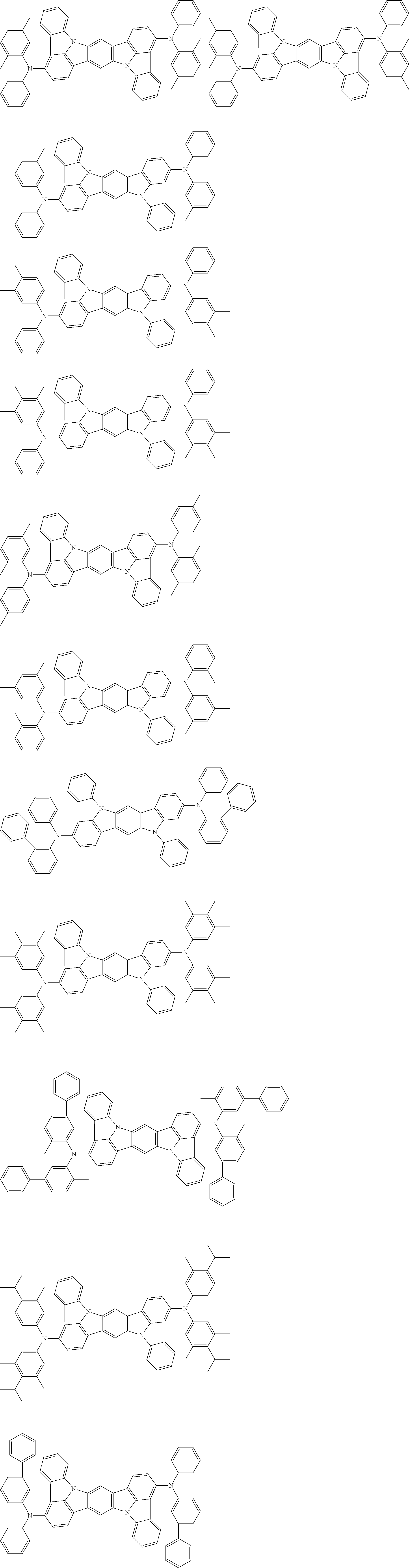

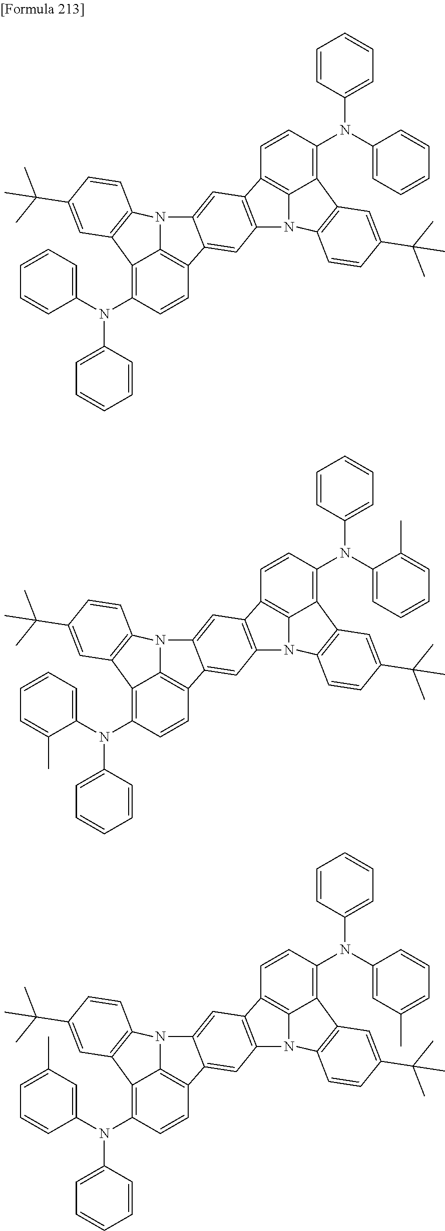

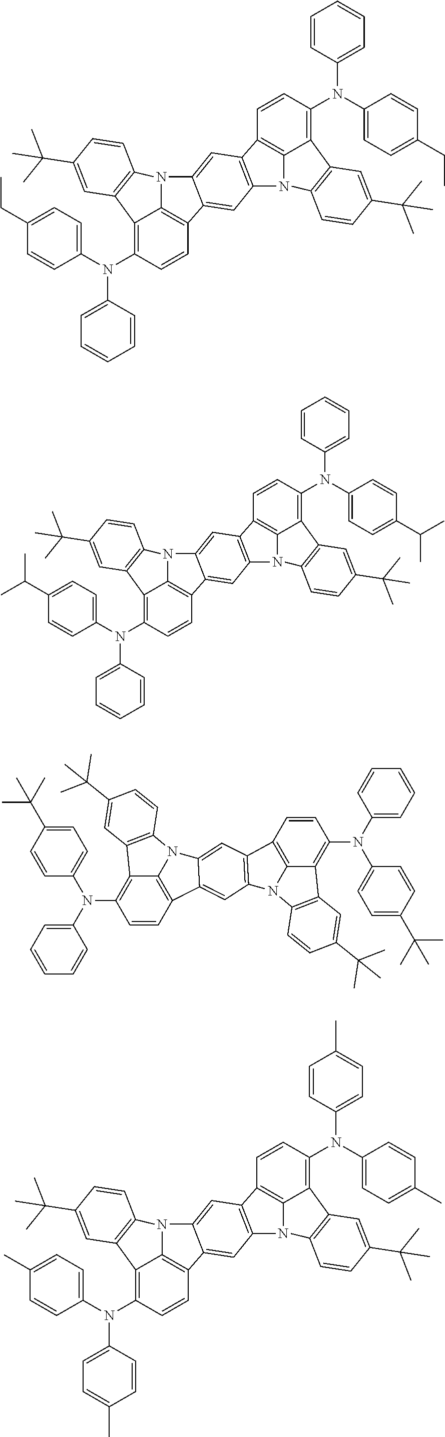

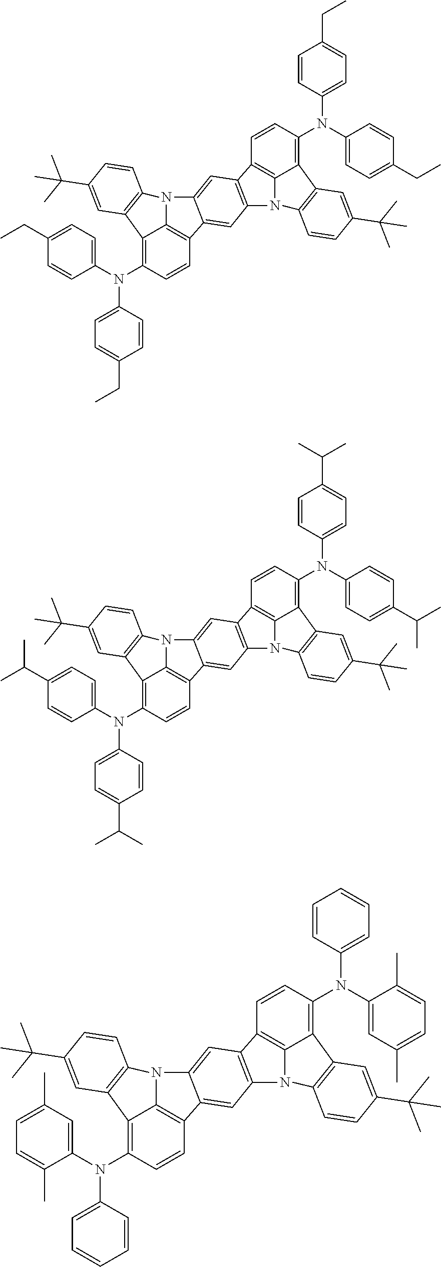

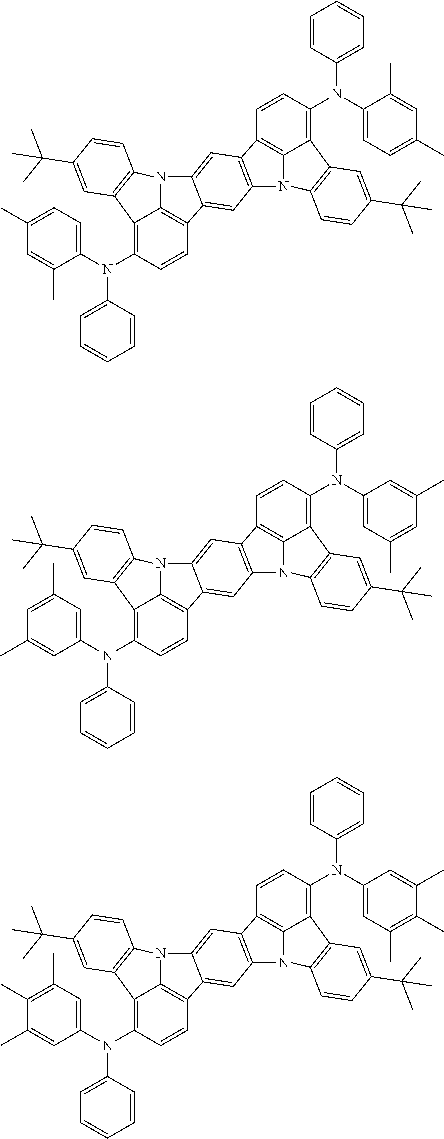

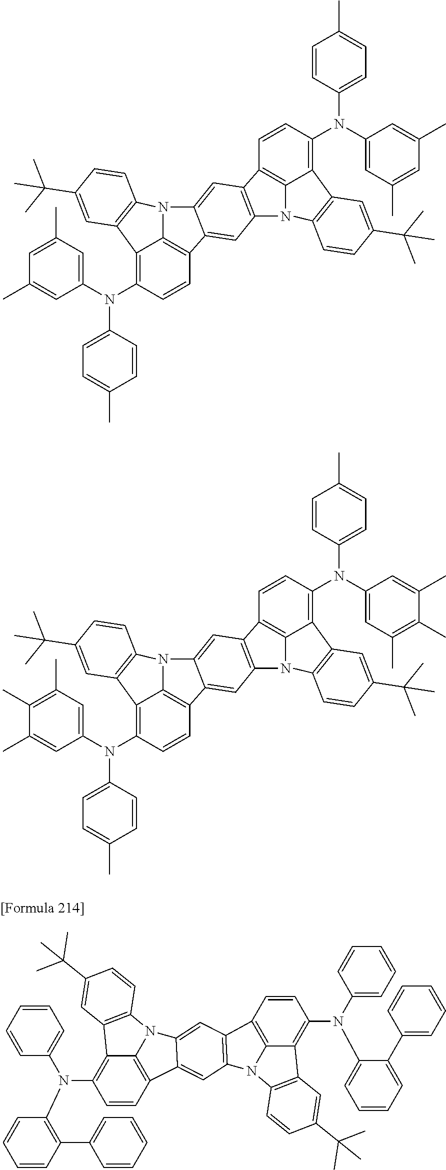

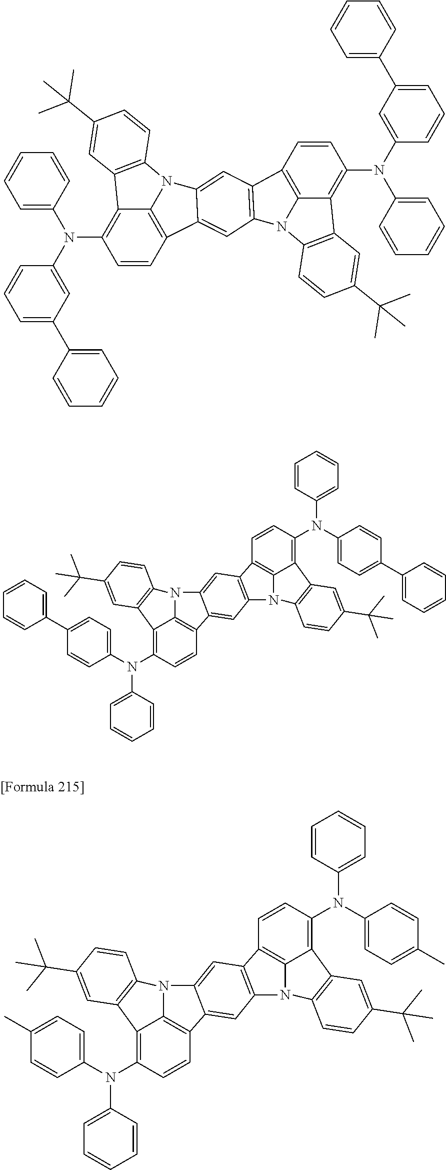

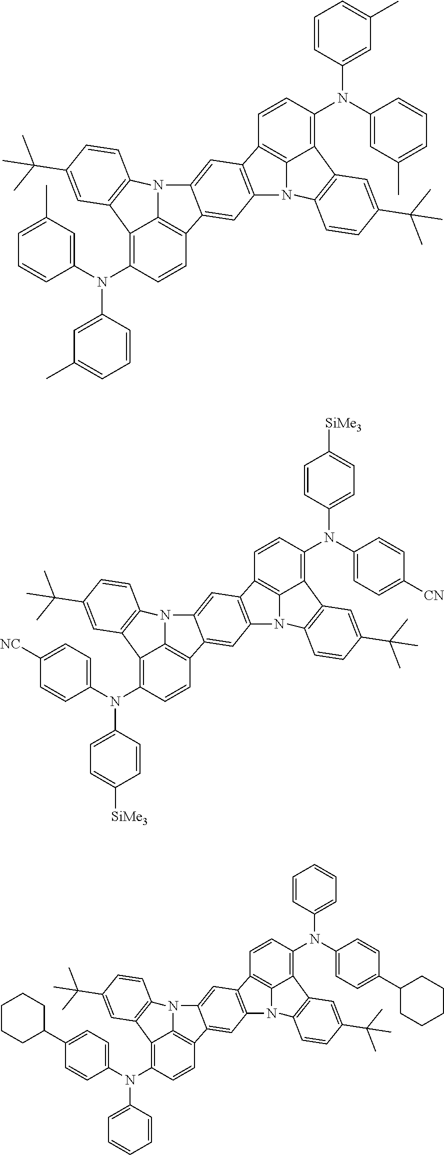 [SMILES: Cc1cccc(N(c2cccc(C)c2)c2ccc3c4cc5c(cc4n4c6ccc(C(C)(C)C)cc6c2c34)c2ccc(N(c3cccc(C)c3)c3cccc(C)c3)c3c4cc(C(C)(C)C)ccc4n5c23)c1 ; CC(C)(C)c1ccc2c(c1)c1c(N(c3ccc(C#N)cc3)c3ccc([Si](C)(C)C)cc3)ccc3c4cc5c(cc4n2c31)c1ccc(N(c2ccc(C#N)cc2)c2ccc([Si](C)(C)C)cc2)c2c3cc(C(C)(C)C)ccc3n5c12 ; CC(C)(C)c1ccc2c(c1)c1c(N(c3ccccc3)c3ccc(C4CCCCC4)cc3)ccc3c4cc5c(cc4n2c31)c1ccc(N(c2ccccc2)c2ccc(C3CCCCC3)cc2)c2c3cc(C(C)(C)C)ccc3n5c12]

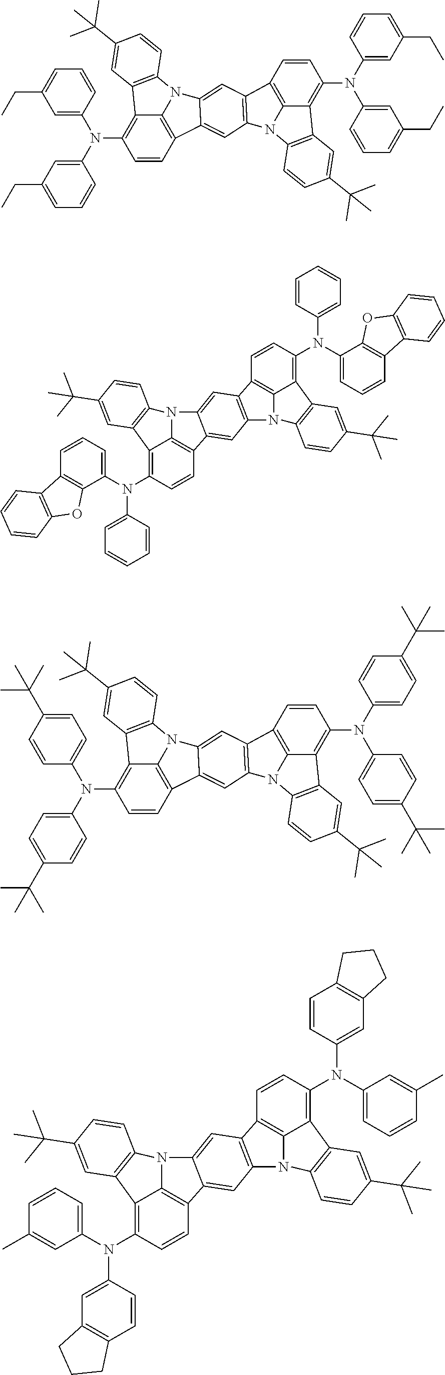

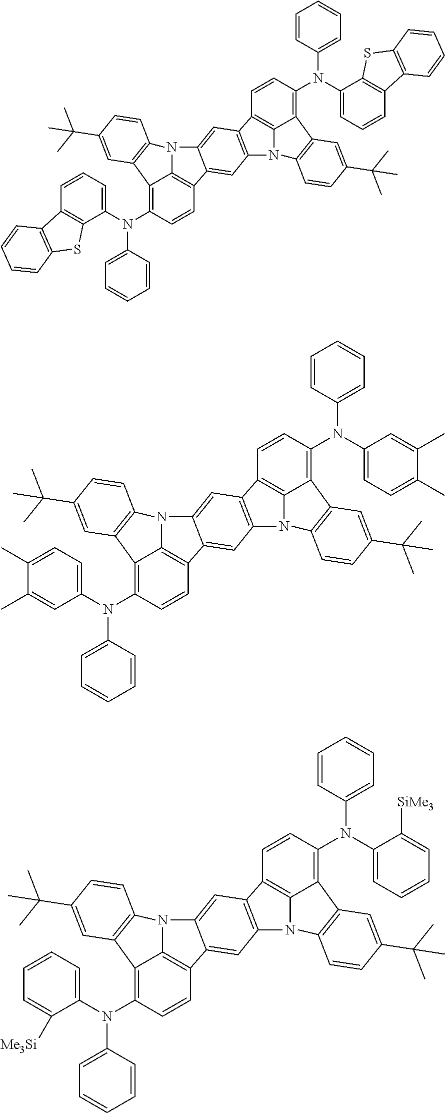

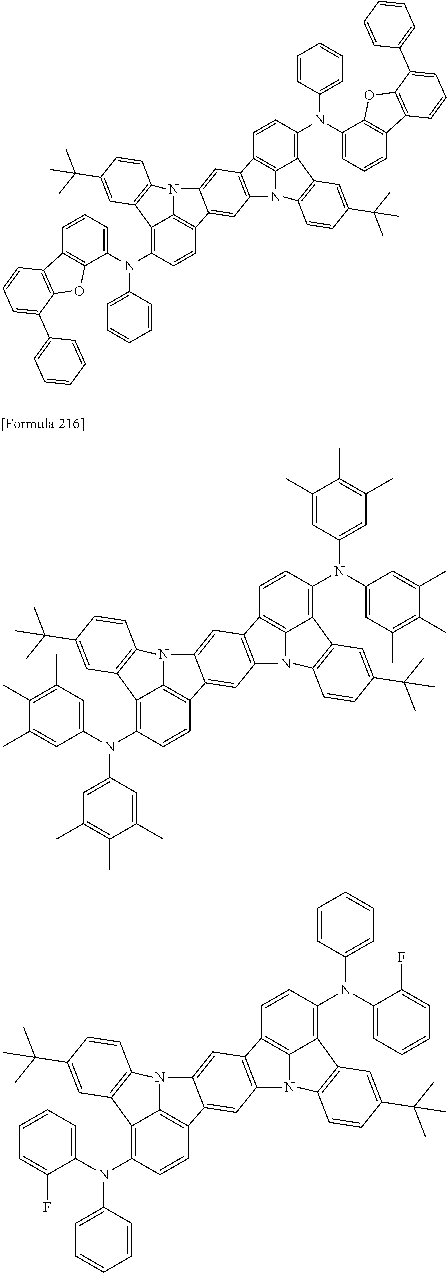

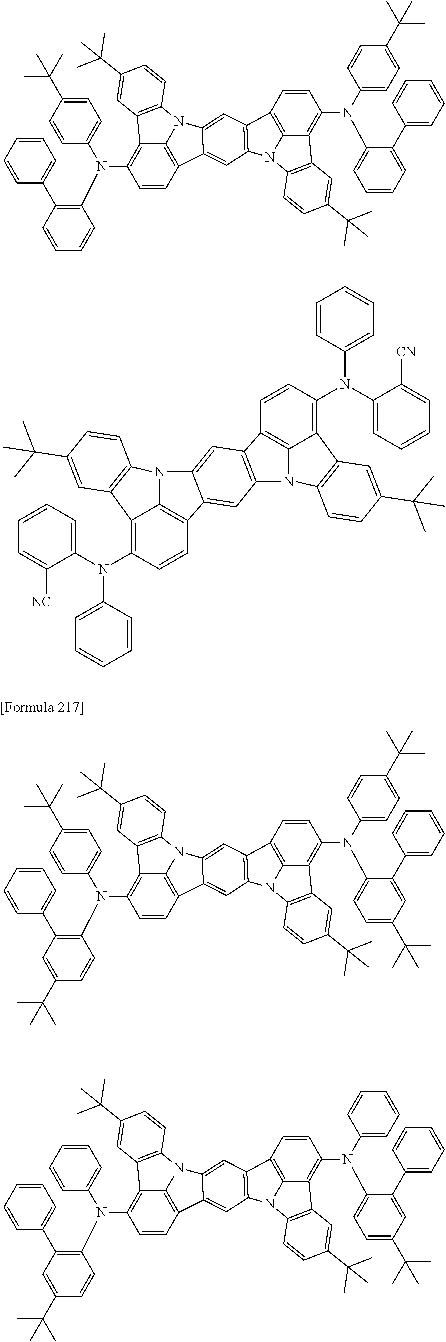

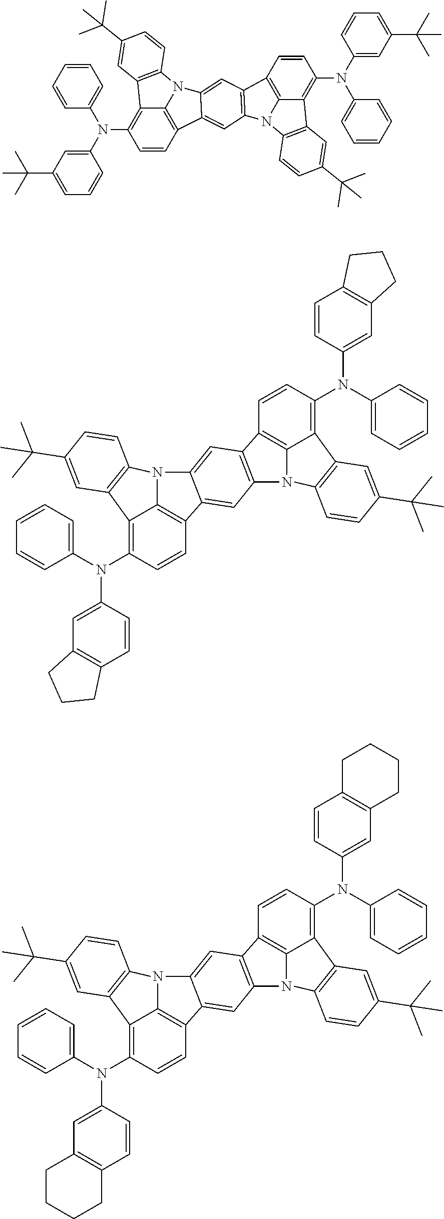

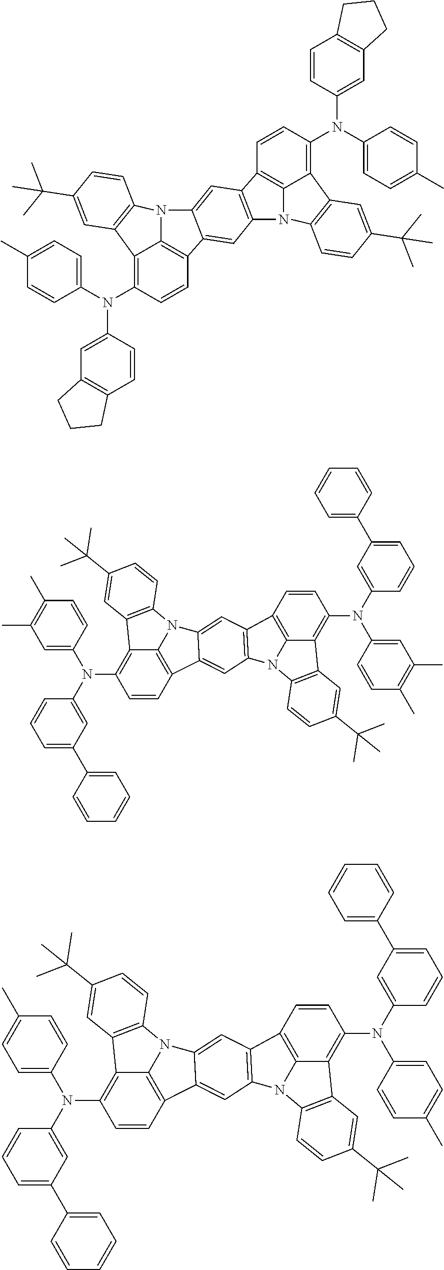

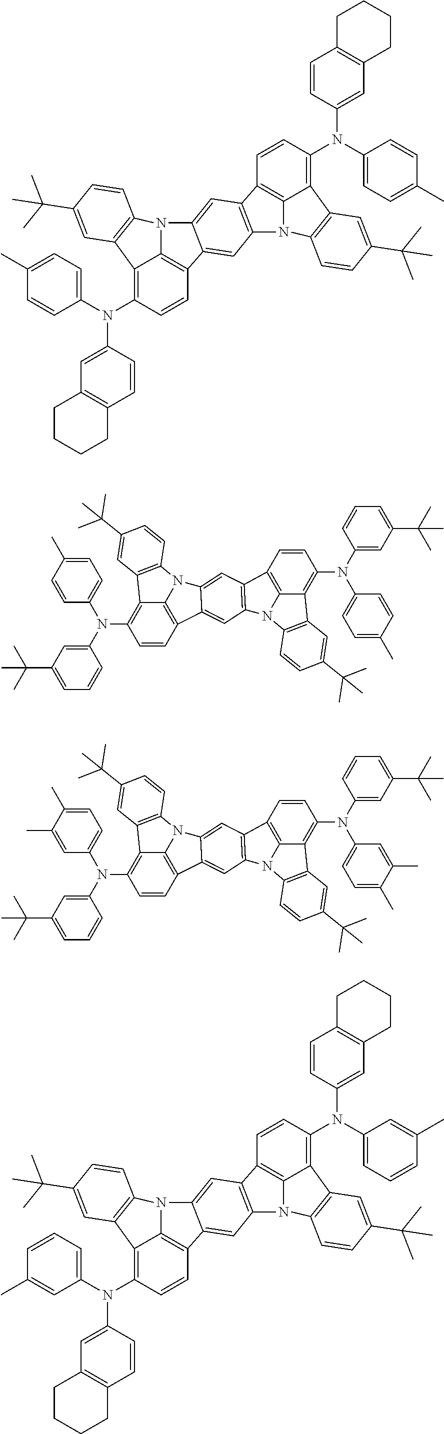

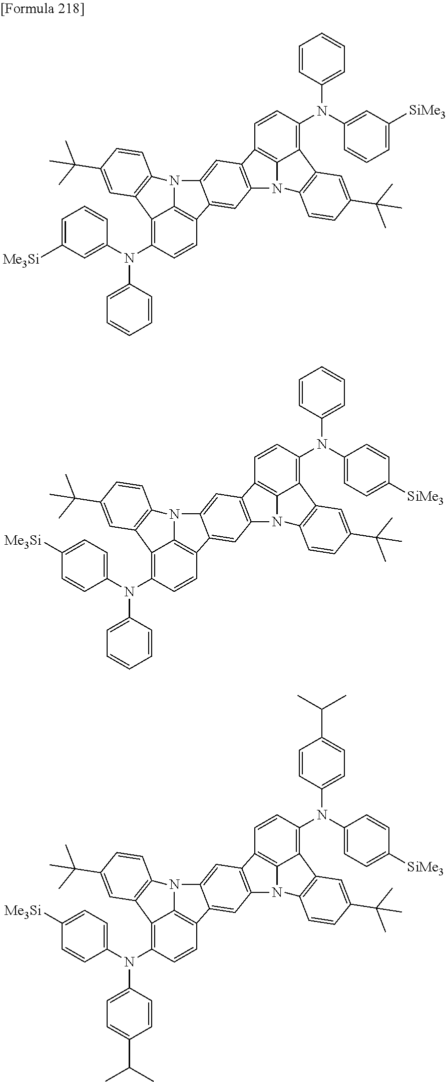 [SMILES: CC(C)(C)c1ccc2c(c1)c1c(N(c3ccccc3)c3cccc([Si](C)(C)C)c3)ccc3c4cc5c(cc4n2c31)c1ccc(N(c2ccccc2)c2cccc([Si](C)(C)C)c2)c2c3cc(C(C)(C)C)ccc3n5c12 ; CC(C)(C)c1ccc2c(c1)c1c(N(c3ccccc3)c3ccc([Si](C)(C)C)cc3)ccc3c4cc5c(cc4n2c31)c1ccc(N(c2ccccc2)c2ccc([Si](C)(C)C)cc2)c2c3cc(C(C)(C)C)ccc3n5c12 ; CC(C)c1ccc(N(c2ccc([Si](C)(C)C)cc2)c2ccc3c4cc5c(cc4n4c6ccc(C(C)(C)C)cc6c2c34)c2ccc(N(c3ccc(C(C)C)cc3)c3ccc([Si](C)(C)C)cc3)c3c4cc(C(C)(C)C)ccc4n5c23)cc1]

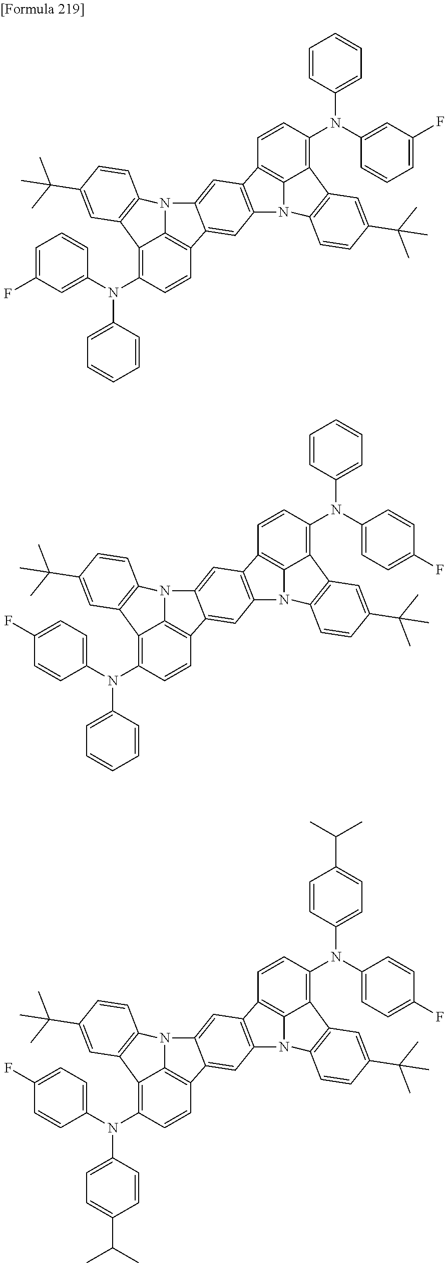 [SMILES: CC(C)(C)c1ccc2c(c1)c1c(N(c3ccccc3)c3cccc(F)c3)ccc3c4cc5c(cc4n2c31)c1ccc(N(c2ccccc2)c2cccc(F)c2)c2c3cc(C(C)(C)C)ccc3n5c12 ; CC(C)(C)c1ccc2c(c1)c1c(N(c3ccccc3)c3ccc(F)cc3)ccc3c4cc5c(cc4n2c31)c1ccc(N(c2ccccc2)c2ccc(F)cc2)c2c3cc(C(C)(C)C)ccc3n5c12 ; CC(C)c1ccc(N(c2ccc(F)cc2)c2ccc3c4cc5c(cc4n4c6ccc(C(C)(C)C)cc6c2c34)c2ccc(N(c3ccc(F)cc3)c3ccc(C(C)C)cc3)c3c4cc(C(C)(C)C)ccc4n5c23)cc1]

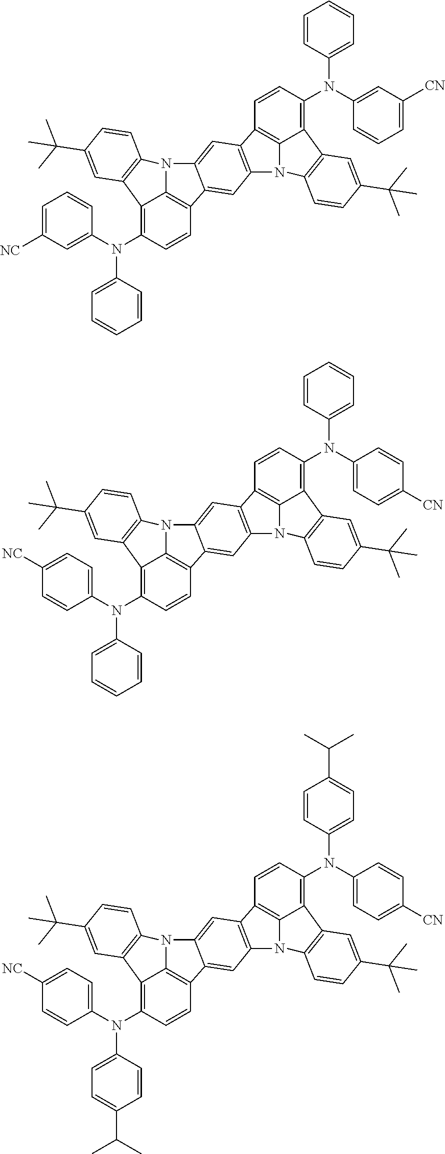 [SMILES: CC(C)(C)c1ccc2c(c1)c1c(N(c3ccccc3)c3cccc(C#N)c3)ccc3c4cc5c(cc4n2c31)c1ccc(N(c2ccccc2)c2cccc(C#N)c2)c2c3cc(C(C)(C)C)ccc3n5c12 ; CC(C)(C)c1ccc2c(c1)c1c(N(c3ccccc3)c3ccc(C#N)cc3)ccc3c4cc5c(cc4n2c31)c1ccc(N(c2ccccc2)c2ccc(C#N)cc2)c2c3cc(C(C)(C)C)ccc3n5c12 ; CC(C)c1ccc(N(c2ccc(C#N)cc2)c2ccc3c4cc5c(cc4n4c6ccc(C(C)(C)C)cc6c2c34)c2ccc(N(c3ccc(C#N)cc3)c3ccc(C(C)C)cc3)c3c4cc(C(C)(C)C)ccc4n5c23)cc1]

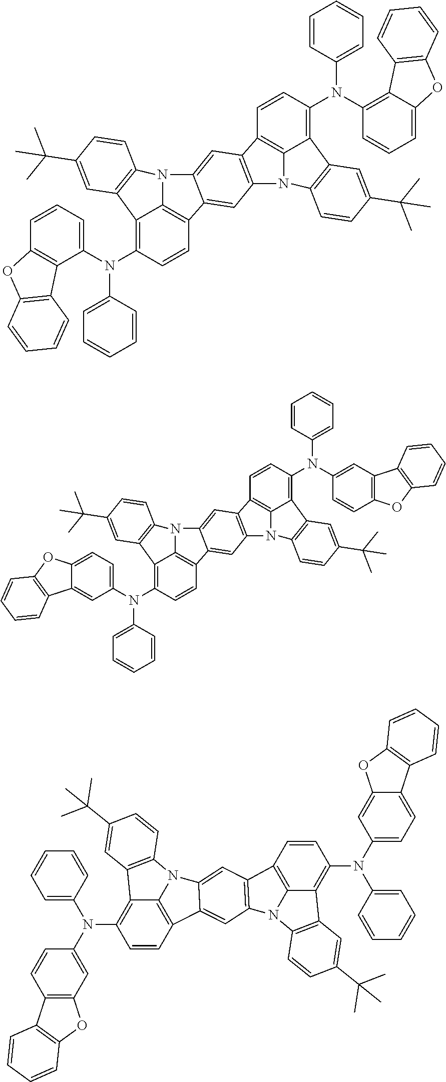 [SMILES: CC(C)(C)c1ccc2c(c1)c1c(N(c3ccccc3)c3cccc4oc5ccccc5c34)ccc3c4cc5c(cc4n2c31)c1ccc(N(c2ccccc2)c2cccc3oc4ccccc4c23)c2c3cc(C(C)(C)C)ccc3n5c12 ; CC(C)(C)c1ccc2c(c1)c1c(N(c3ccccc3)c3ccc4oc5ccccc5c4c3)ccc3c4cc5c(cc4n2c31)c1ccc(N(c2ccccc2)c2ccc3oc4ccccc4c3c2)c2c3cc(C(C)(C)C)ccc3n5c12 ; CC(C)(C)c1ccc2c(c1)c1c(N(c3ccccc3)c3ccc4c(c3)oc3ccccc34)ccc3c4cc5c(cc4n2c31)c1ccc(N(c2ccccc2)c2ccc3c(c2)oc2ccccc23)c2c3cc(C(C)(C)C)ccc3n5c12]

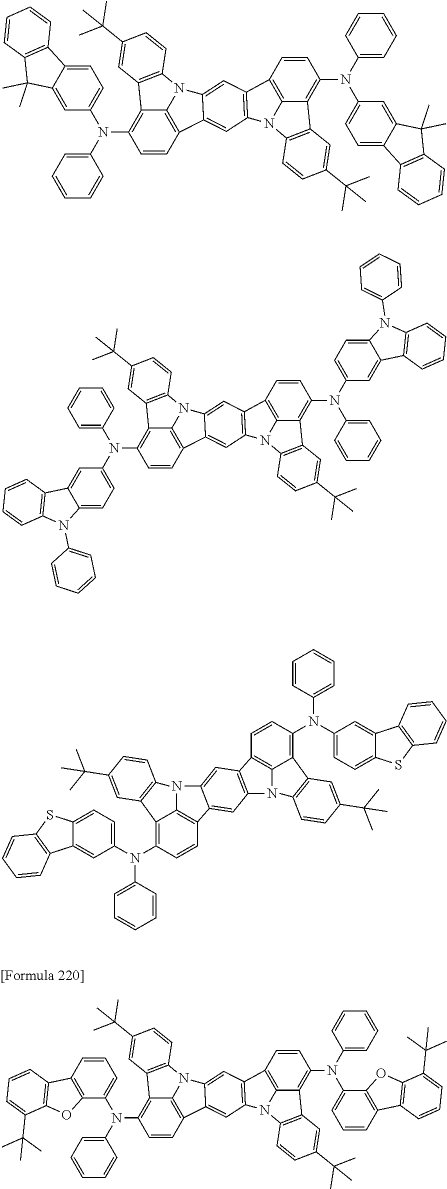

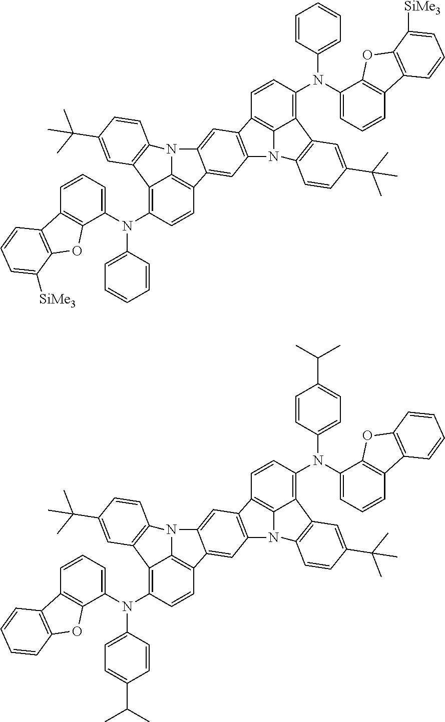 [SMILES: CC(C)(C)c1ccc2c(c1)c1c(N(c3ccccc3)c3cccc4c3oc3c([Si](C)(C)C)cccc34)ccc3c4cc5c(cc4n2c31)c1ccc(N(c2ccccc2)c2cccc3c2oc2c([Si](C)(C)C)cccc23)c2c3cc(C(C)(C)C)ccc3n5c12 ; CC(C)c1ccc(N(c2cccc3c2oc2ccccc23)c2ccc3c4cc5c(cc4n4c6ccc(C(C)(C)C)cc6c2c34)c2ccc(N(c3ccc(C(C)C)cc3)c3cccc4c3oc3ccccc34)c3c4cc(C(C)(C)C)ccc4n5c23)cc1]

### Compound Represented by Formula (6)

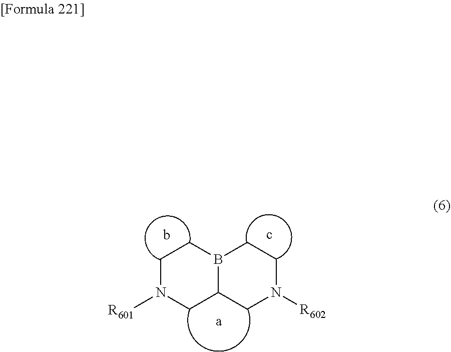

In the formula (6):
a ring a, a ring b and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀ 2 are each independently bonded to the ring a, ring b or ring c to form a substituted or unsubstituted heterocycle, or not bonded thereto to form no substituted or unsubstituted heterocycle; and
R₆₀₁ and R₆₀ 2 not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

The ring a, ring b and ring c are each a ring fused with a fused bicyclic structure formed of a boron atom and two nitrogen atoms at the center of the formula (6) (a substituted or unsubstituted aromatic hydrocarbon ring having 6 to 50 ring carbon atoms, or a substituted or unsubstituted heterocycle having 5 to 50 ring atoms).

The “aromatic hydrocarbon ring” for the rings a, b, and c has the same structure as a compound formed by introducing a hydrogen atom to the “aryl group” described above.

Ring atoms of the “aromatic hydrocarbon ring” for the ring a include three carbon atoms on the fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀ 2 may be each independently bonded with the ring a, ring b, or ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom. R₆₀₁ and R₆₀ 2 being bonded with the ring a, ring b, or ring c specifically means that atoms forming R₆₀₁ and R₆₀ 2 are bonded with atoms forming the ring a, ring b, or ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀ 2 bonded with the ring a, and R₆₀ 2 bonded with the ring c.

In an exemplary embodiment, the ring a, ring b and ring c in the formula (6) are each independently a substituted or unsubstituted aromatic hydrocarbon ring having 6 to 50 ring carbon atoms.

In an exemplary embodiment, the ring a, ring b and ring c in the formula (6) are each independently a substituted or unsubstituted benzene ring or a substituted or unsubstituted naphthalene ring.

In an exemplary embodiment, R₆₀₁ and R₆₀ 2 in the formula (6) are each independently a substituted or unsubstituted aryl group having 6 to 50 ring carbon atoms, or a substituted or unsubstituted heterocyclic group having 5 to 50 ring atoms, preferably a substituted or unsubstituted aryl group having 6 to 50 ring carbon atoms.

In an exemplary embodiment, the compound represented by the formula (6) is a compound represented by a formula (62) below.

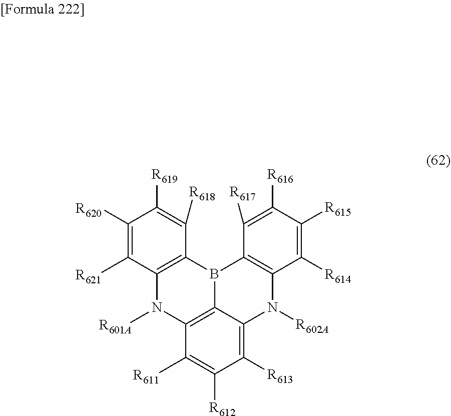

In the formula (62):
R_{601A} is bonded with at least one of R₆₁₁ or R₆₂₁ to form a substituted or unsubstituted heterocycle, or not bonded therewith to form no substituted or unsubstituted heterocycle;
R_{602A} is bonded with at least one of R₆₁₃ or R₆₁₄ to form a substituted or unsubstituted heterocycle, or not bonded therewith to form no substituted or unsubstituted heterocycle;
R_{601A} and R_{602A} not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one combination of adjacent two or more of R₆₁₁ to R₆₂₁ are mutually bonded to form a substituted or unsubstituted monocyclic ring, mutually bonded to form a substituted or unsubstituted fused ring, or not mutually bonded; and
R₆₁₁ to R₆₂₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.
R_{601A} and R_{602A} in the formula (62) are groups corresponding to R₆₀₁ and R₆₀ 2, respectively, in the formula (6).

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₁, R₆₀ 2A bonded with R₆₁₃, and R_{602A} bonded with R₆₁₄.

At least one combination of adjacent two or more of R₆₁₁ to R₆₂₁ may be mutually bonded to form a substituted or unsubstituted monocyclic ring, or mutually bonded to form a substituted or unsubstituted fused ring.

For instance, R₆₁₁ and R₆₁₂ are mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment, R₆₁₁ to R₆₂₁ not contributing to ring formation are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment, R₆₁₁ to R₆₂₁ not contributing to ring formation are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, R₆₁₁ to R₆₂₁ not contributing to ring formation are each independently a hydrogen atom, or a substituted or unsubstituted alkyl group having 1 to 50 carbon atoms.

In an exemplary embodiment, R₆₁₁ to R₆₂₁ not contributing to ring formation are each independently a hydrogen atom, or a substituted or unsubstituted alkyl group having 1 to 50 carbon atoms; and at least one of R₆₁₁ to R₆₂₁ is a substituted or unsubstituted alkyl group having 1 to 50 carbon atoms.

In an exemplary embodiment, the compound represented by the formula (62) is a compound represented by a formula (63) below.

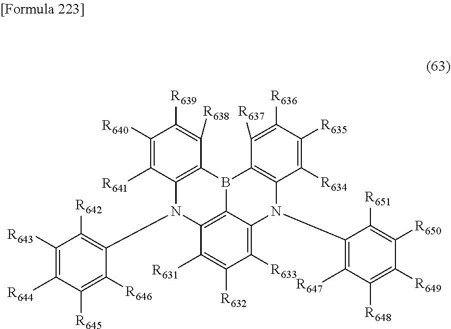

In the formula (63):

R₆₃₁ is bonded with R₆₄₆ to form a substituted or unsubstituted heterocycle, or not bonded therewith to form no substituted or unsubstituted heterocycle;
R₆₃₃ is bonded with R₆₄₇ to form a substituted or unsubstituted heterocycle, or not bonded therewith to form no substituted or unsubstituted heterocycle;
R₆₃₄ is bonded with R₆₅₁ to form a substituted or unsubstituted heterocycle, or not bonded therewith to form no substituted or unsubstituted heterocycle;
R₆₄₁ is bonded with R₆₄₂ to form a substituted or unsubstituted heterocycle, or not bonded therewith to form no substituted or unsubstituted heterocycle;
at least one combination of adjacent two or more of R₆₃₁ to R₆₅₁ are mutually bonded to form a substituted or unsubstituted monocyclic ring, mutually bonded to form a substituted or unsubstituted fused ring, or not mutually bonded; and
R₆₃₁ to R₆₅₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

R₆₃₁ is optionally bonded with R₆₄₆ to form a substituted or unsubstituted heterocycle. For instance, R₆₃₁ and R₆₄₆ are optionally bonded with each other to form a tri-or-more cyclic fused nitrogen-containing heterocycle, in which a benzene ring bonded with R₆₄₆, a ring including a nitrogen atom, and a benzene ring corresponding to the ring a are fused. Specific examples of the nitrogen-containing heterocycle include a compound corresponding to a nitrogen-containing tri(-or-more)cyclic fused heterocyclic group in the specific example group G2. The same applies to R₆₃₃ bonded with R₆₄₇, R₆₃₄ bonded with R₆₅₁, and R₆₄₁ bonded with R₆₄₂.

In an exemplary embodiment, R₆₃₁ to R₆₅₁ not contributing to ring formation are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment, R₆₃₁ to R₆₅₁ not contributing to ring formation are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, R₆₃₁ to R₆₅₁ not contributing to ring formation are each independently a hydrogen atom, or a substituted or unsubstituted alkyl group having 1 to 50 carbon atoms.

In an exemplary embodiment, R₆₃₁ to R₆₅₁ not contributing to ring formation are each independently a hydrogen atom, or a substituted or unsubstituted alkyl group having 1 to 50 carbon atoms; and at least one of R₆₃₁ to R₆₅₁ is a substituted or unsubstituted alkyl group having 1 to 50 carbon atoms.

In an exemplary embodiment, the compound represented by the formula (63) is a compound represented by a formula (63A) below.

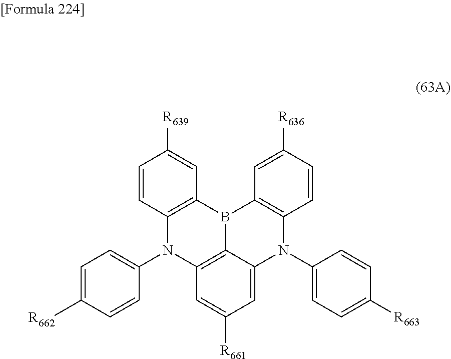

In the formula (63A):
R₆₆₁ is a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms, and
R₆₆₂ to R₆₆₅ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary embodiment, R₆₆₁ to R₆₆₅ are each independently a substituted or unsubstituted alkyl group having 1 to 50 carbon atoms, or a substituted or unsubstituted aryl group having 6 to 50 ring carbon atoms.

In an exemplary embodiment, R₆₆₁ to R₆₆₅ are each independently a substituted or unsubstituted alkyl group having 1 to 50 carbon atoms.

In an exemplary embodiment, the compound represented by the formula (63) is a compound represented by a formula (63B) below.

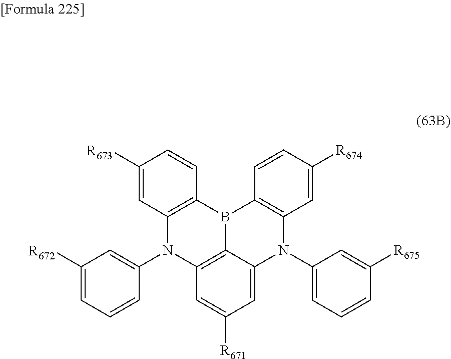

In the formula (63B):
R₆₇₁ and R₆₇₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms, and
R₆₇₃ to R₆₇₅ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms.

In an exemplary embodiment, the compound represented by the formula (63) is a compound represented by a formula (63B′) below.

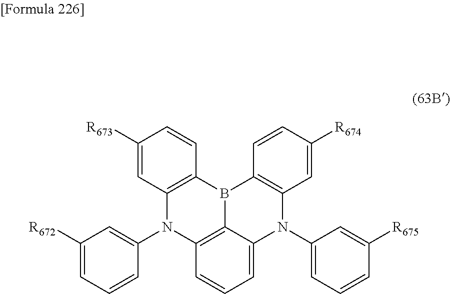

In the formula (63B′), R₆₇₂ to R₆₇₅ each independently represent the same as R₆₇₂ to R₆₇₅ in the formula (63B).

In an exemplary embodiment, at least one of R₆₇₁ to R₆₇₅ is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms.

In an exemplary embodiment: R₆₇₂ is a hydrogen atom, a substituted or unsubstituted alkyl group having 1 to 50 carbon atoms, a group represented by —N(R₉₀₆)(R₉₀₇), or a substituted or unsubstituted aryl group having 6 to 50 ring carbon atoms, and

R₆₇₁ and R₆₇₃ to R₆₇₅ are each independently a substituted or unsubstituted alkyl group having 1 to 50 carbon atoms, a group represented by —N(R₉₀₆)(R₉₀₇), or a substituted or unsubstituted aryl group having 6 to 50 ring carbon atoms.

In an exemplary embodiment, the compound represented by the formula (63) is a compound represented by a formula (63C) below.

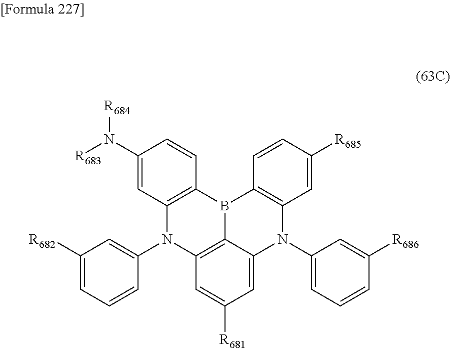

In the formula (63C):
R₆₈₁ and R₆₈₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms; and
R₆₈₃ to R₆₈₆ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary embodiment, the compound represented by the formula (63) is a compound represented by a formula (63C′) below.

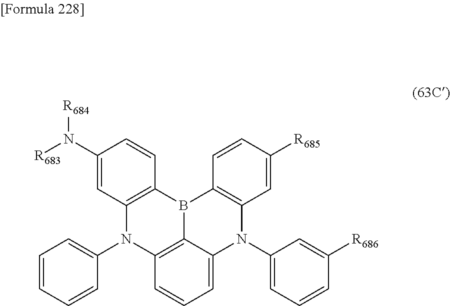

In the formula (63C′), R₆₈₃ to R₆₈₆ each independently represent the same as R₆₈₃ to R₆₈₆ in the formula (63C).

In an exemplary embodiment, R₆₈₁ to R₆₈₆ are each independently a substituted or unsubstituted alkyl group having 1 to 50 carbon atoms, or a substituted or unsubstituted aryl group having 6 to 50 ring carbon atoms.

In an exemplary embodiment, R₆₈₁ to R₆₈₆ are each independently a substituted or unsubstituted aryl group having 6 to 50 ring carbon atoms.

The compound represented by the formula (6) is producible by initially bonding the ring a, ring b and ring c with linking groups (a group including N—R₆₀₁ and a group including N—R₆₀ 2) to form an intermediate (first reaction), and bonding the ring a, ring b and ring c with a linking group (a group including a boron atom) to form a final product (second reaction). In the first reaction, an amination reaction (e.g. Buchwald-Hartwig reaction) is applicable. In the second reaction, Tandem Hetero-Friedel-Crafts Reactions or the like is applicable.

A compound represented by the formula (6) can be produced by a known method.

### Specific Examples of Compound Represented by Formula (6)

Specific examples of the compound represented by the formula (6) include compounds shown below. However, the compound represented by the formula (6) is by no means limited to the specific examples below.

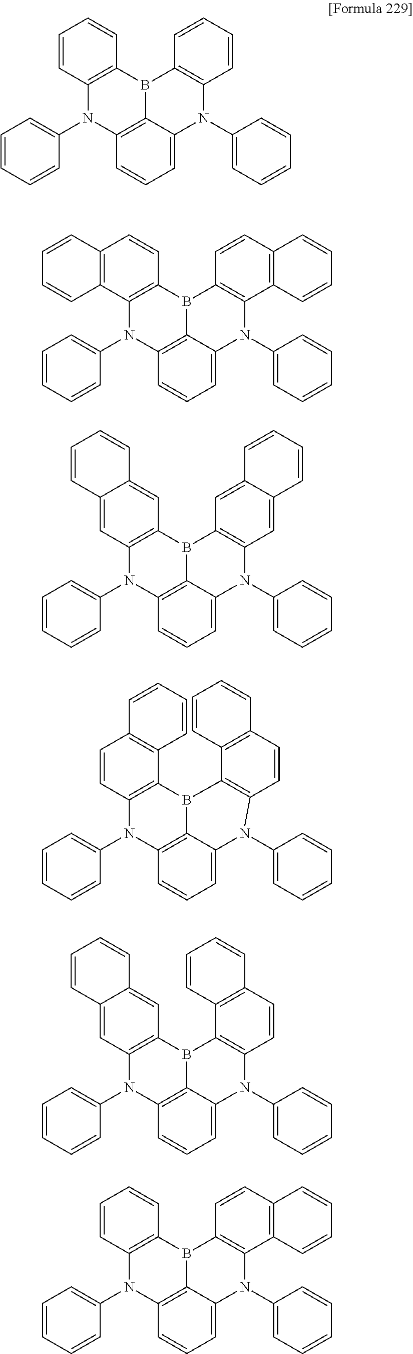

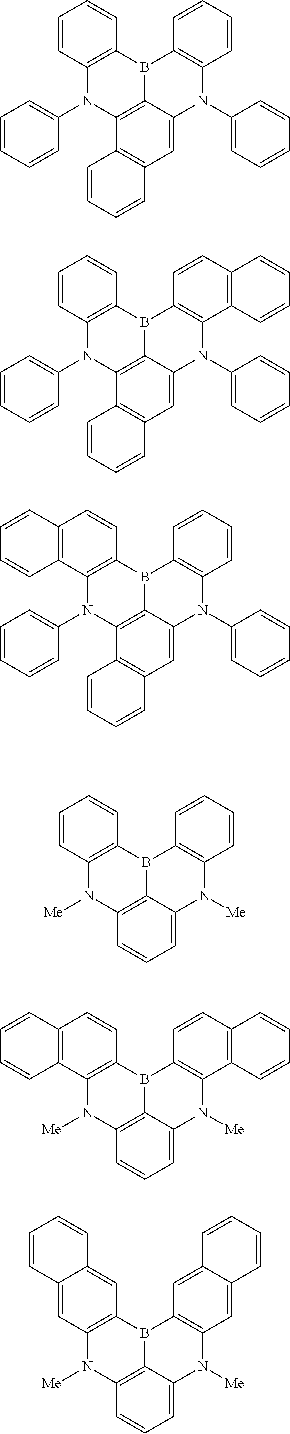 [SMILES: c1ccc(N2c3ccccc3B3c4ccccc4N(c4ccccc4)c4c3c2cc2ccccc42)cc1 ; c1ccc(N2c3cc4ccccc4c4c3B(c3ccccc3N4c3ccccc3)c3ccc4ccccc4c32)cc1 ; c1ccc(N2c3ccccc3B3c4ccc5ccccc5c4N(c4ccccc4)c4c3c2cc2ccccc42)cc1 ; CN1c2ccccc2B2c3ccccc3N(C)c3cccc1c32 ; CN1c2cccc3c2B(c2ccc4ccccc4c21)c1ccc2ccccc2c1N3C ; CN1c2cc3ccccc3cc2B2c3cc4ccccc4cc3N(C)c3cccc1c32]

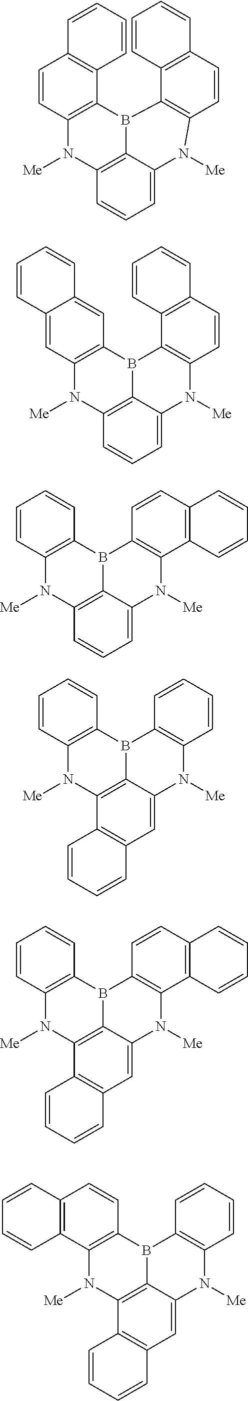

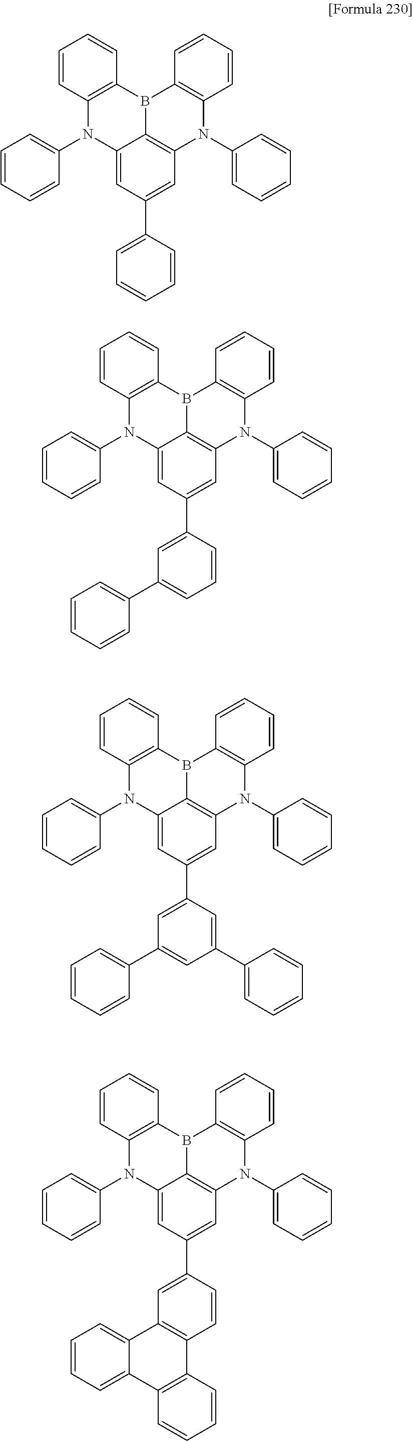

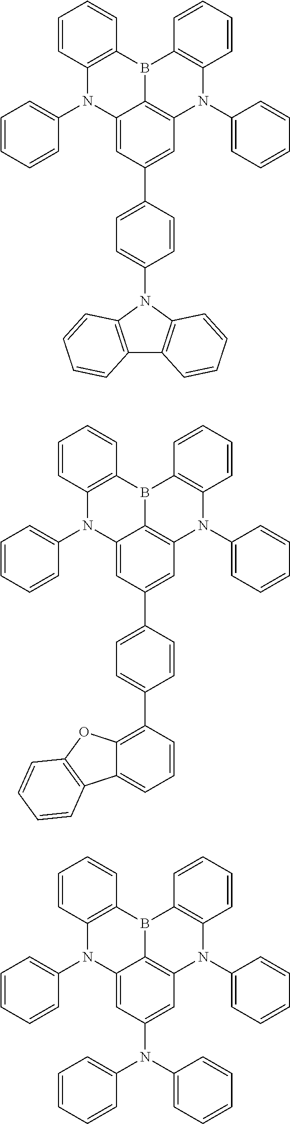

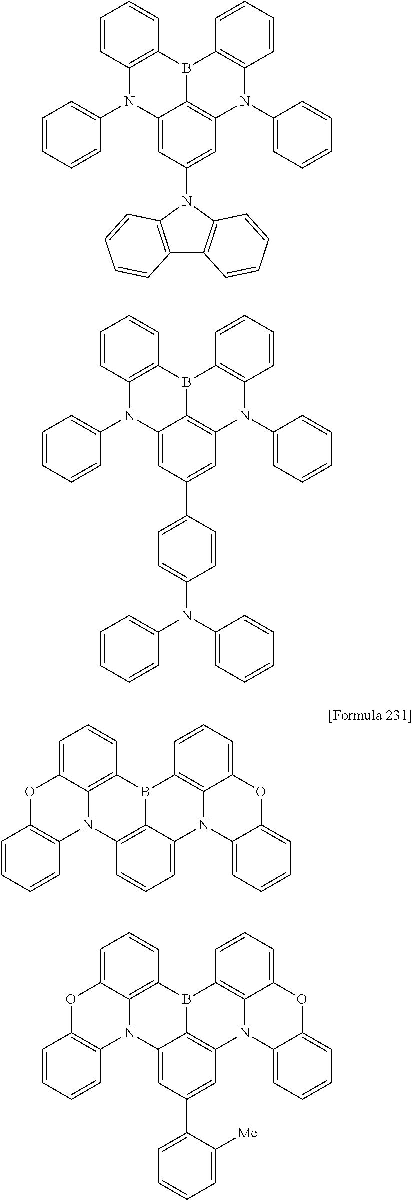

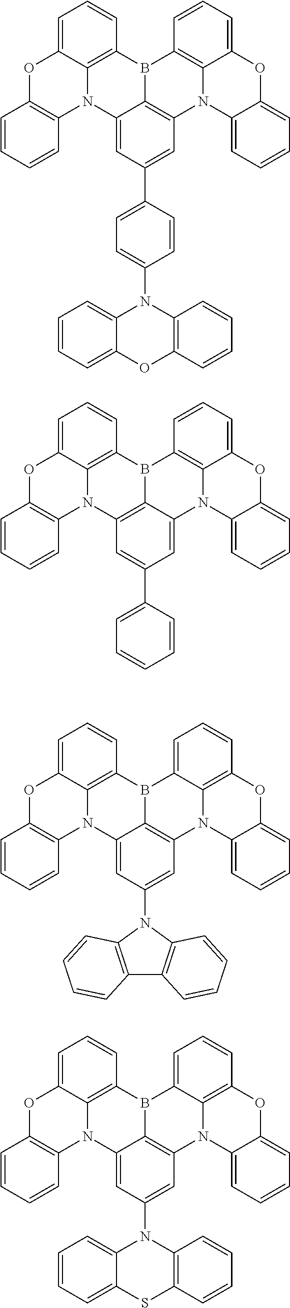

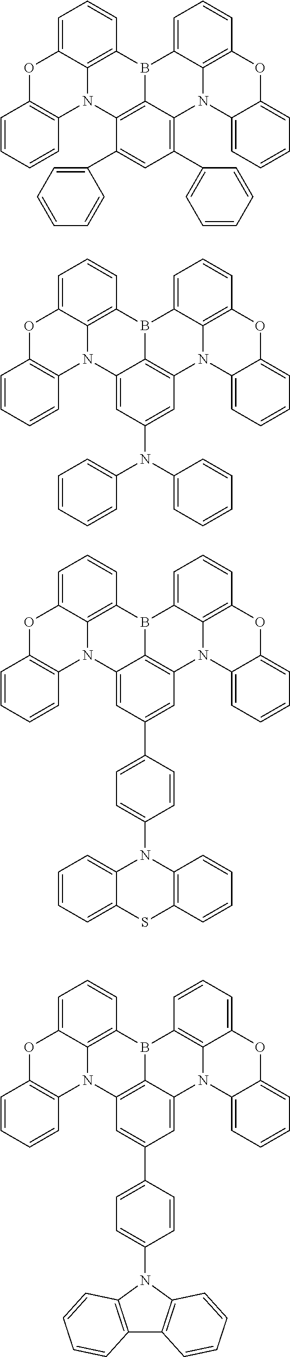

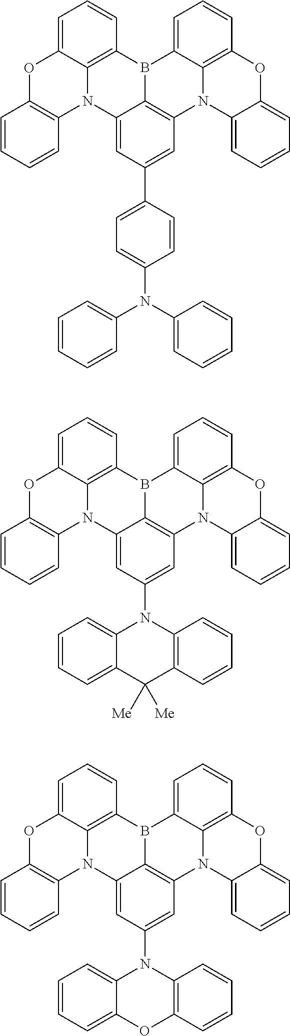 [SMILES: c1ccc(N(c2ccccc2)c2ccc(-c3cc4c5c(c3)N3c6ccccc6Oc6cccc(c63)B5c3cccc5c3N4c3ccccc3O5)cc2)cc1 ; CC1(C)c2ccccc2N(c2cc3c4c(c2)N2c5ccccc5Oc5cccc(c52)B4c2cccc4c2N3c2ccccc2O4)c2ccccc21 ; c1ccc2c(c1)Oc1ccccc1N2c1cc2c3c(c1)N1c4ccccc4Oc4cccc(c41)B3c1cccc3c1N2c1ccccc1O3]

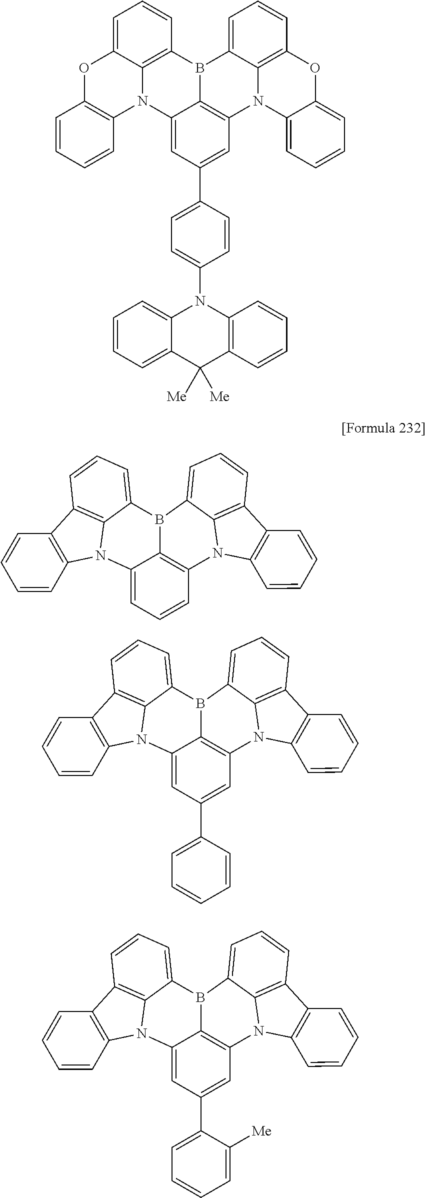

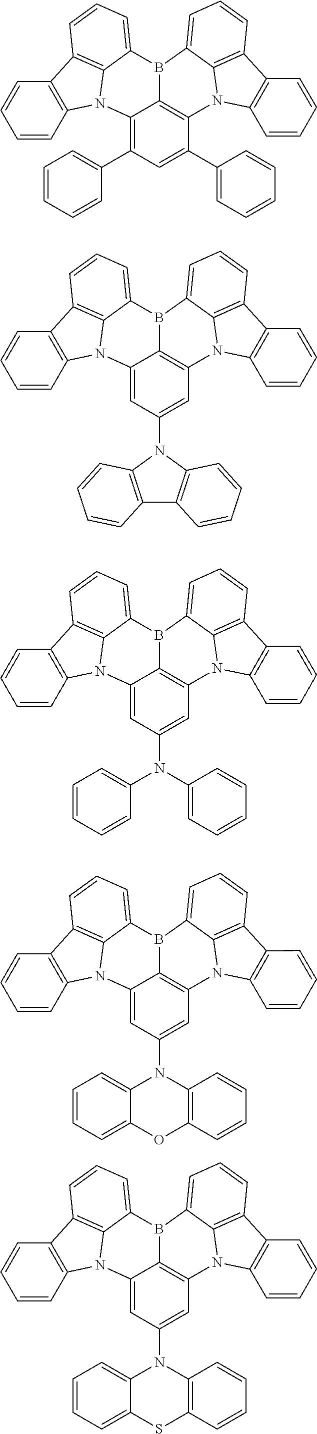

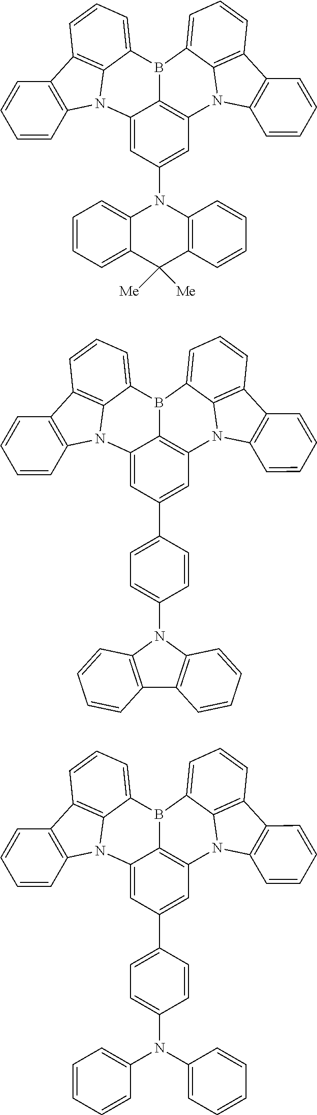

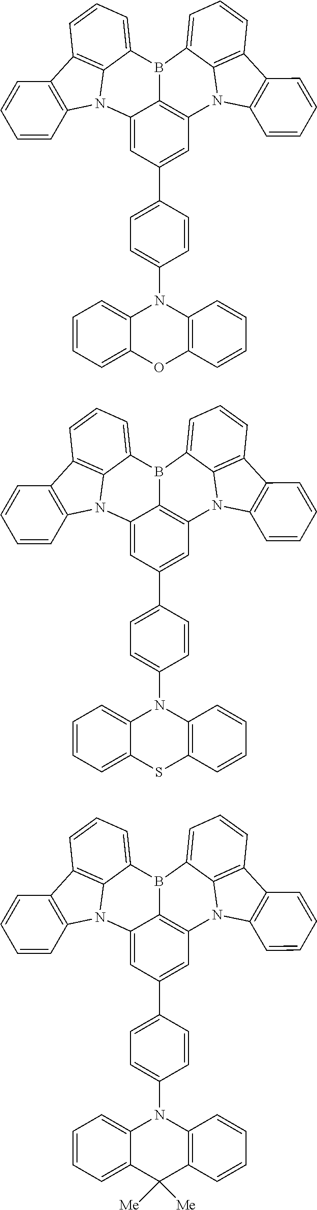

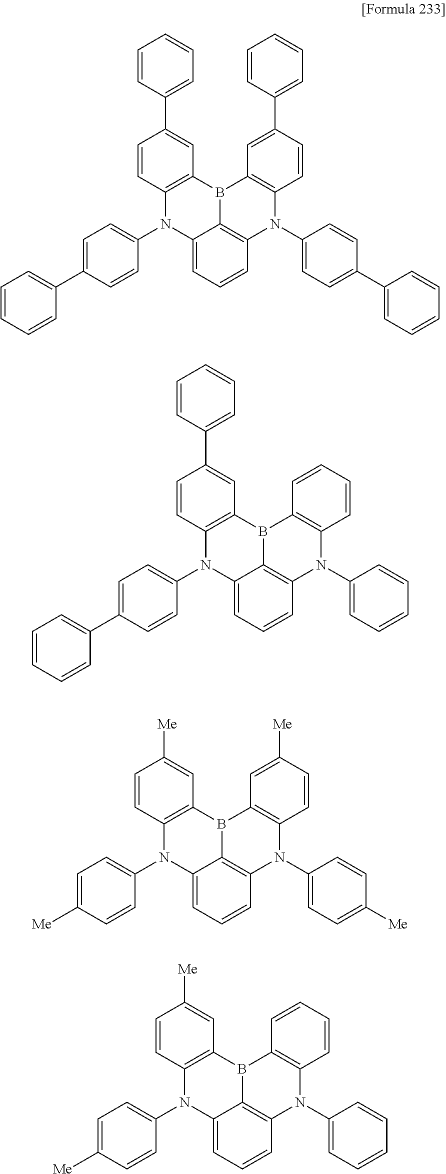 [SMILES: c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5ccccc5N(c5ccccc5)c5cccc3c54)cc2)cc1 ; Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1]

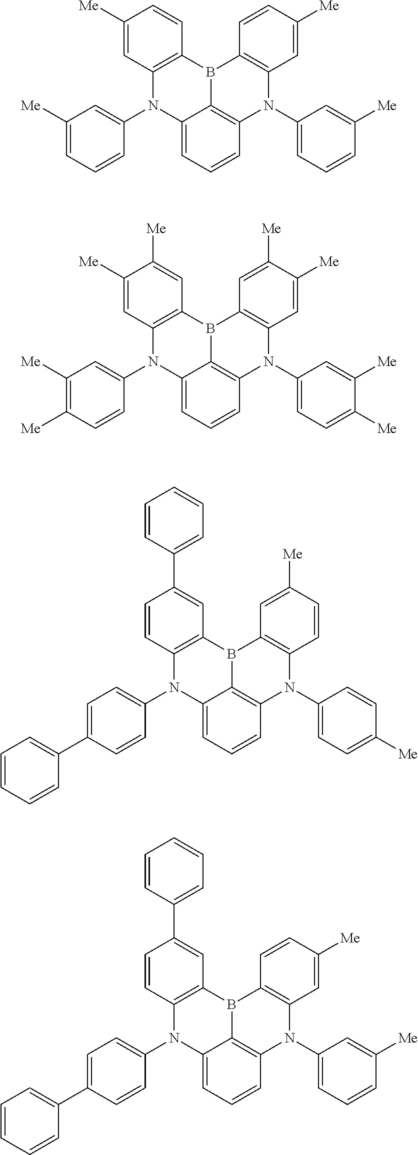 [SMILES: Cc1cccc(N2c3cc(C)ccc3B3c4ccc(C)cc4N(c4cccc(C)c4)c4cccc2c43)c1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1 ; Cc1cccc(N2c3cc(C)ccc3B3c4cc(-c5ccccc5)ccc4N(c4ccc(-c5ccccc5)cc4)c4cccc2c43)c1]

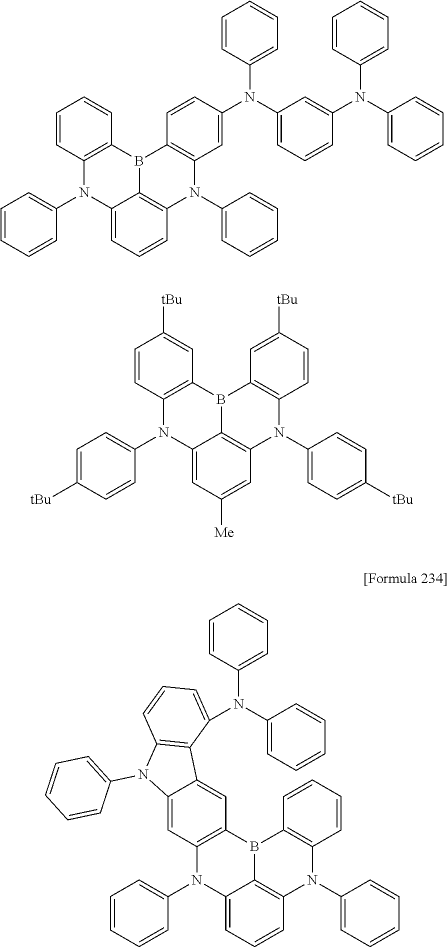 [SMILES: c1ccc(N(c2ccccc2)c2cccc(N(c3ccccc3)c3ccc4c(c3)N(c3ccccc3)c3cccc5c3B4c3ccccc3N5c3ccccc3)c2)cc1 ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(N2c3ccccc3B3c4cc5c6c(N(c7ccccc7)c7ccccc7)cccc6n(-c6ccccc6)c5cc4N(c4ccccc4)c4cccc2c43)cc1]

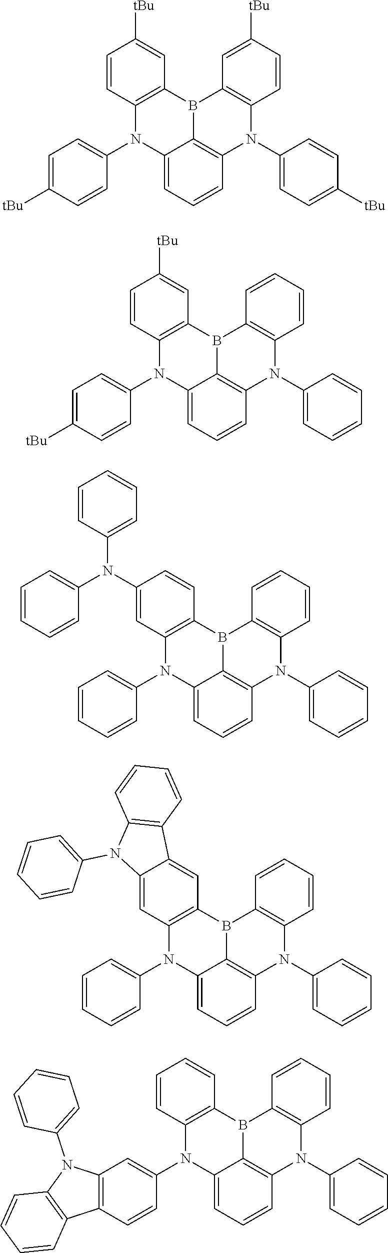

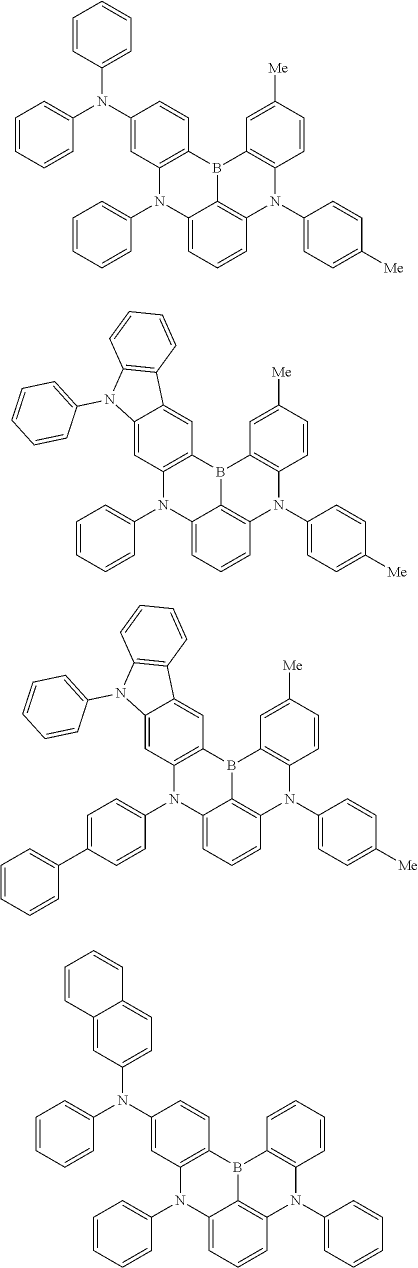 [SMILES: Cc1ccc(N2c3ccc(C)cc3B3c4ccc(N(c5ccccc5)c5ccccc5)cc4N(c4ccccc4)c4cccc2c43)cc1 ; Cc1ccc(N2c3ccc(C)cc3B3c4cc5c6ccccc6n(-c6ccccc6)c5cc4N(c4ccccc4)c4cccc2c43)cc1 ; Cc1ccc(N2c3ccc(C)cc3B3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3ccccc3c2)cc1]

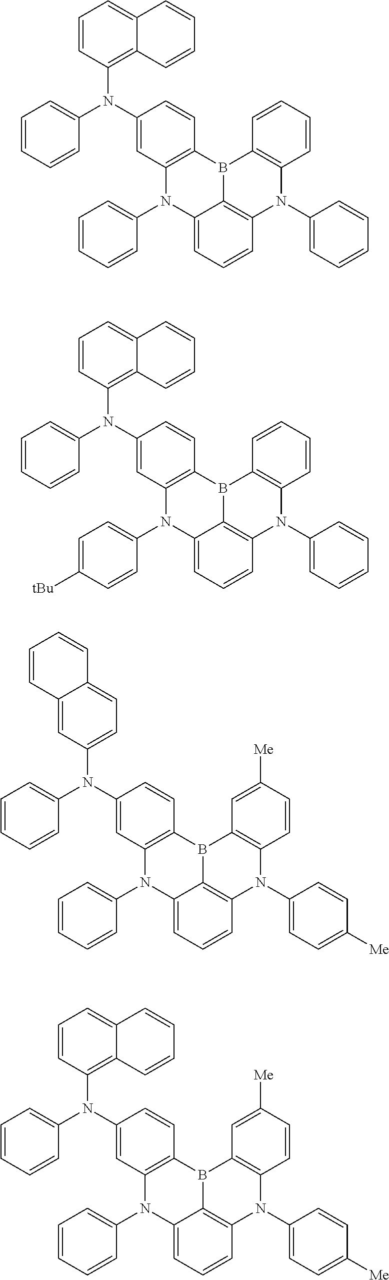

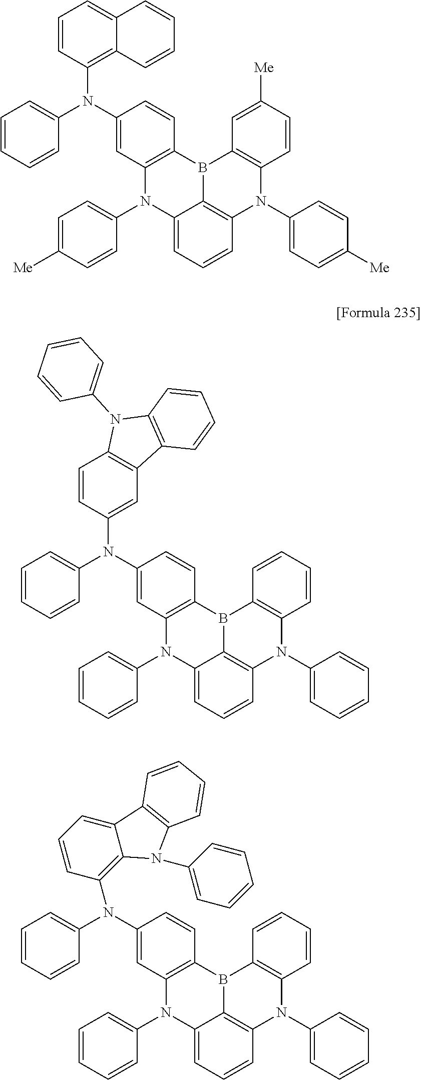 [SMILES: Cc1ccc(N2c3ccc(C)cc3B3c4ccc(N(c5ccccc5)c5cccc6ccccc56)cc4N(c4ccc(C)cc4)c4cccc2c43)cc1 ; c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1]

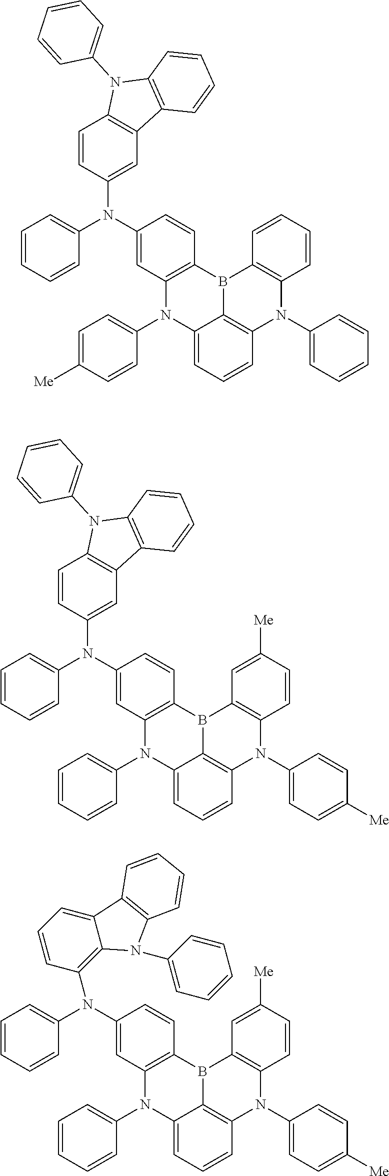 [SMILES: Cc1ccc(N2c3cc(N(c4ccccc4)c4ccc5c(c4)c4ccccc4n5-c4ccccc4)ccc3B3c4ccccc4N(c4ccccc4)c4cccc2c43)cc1 ; Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1]

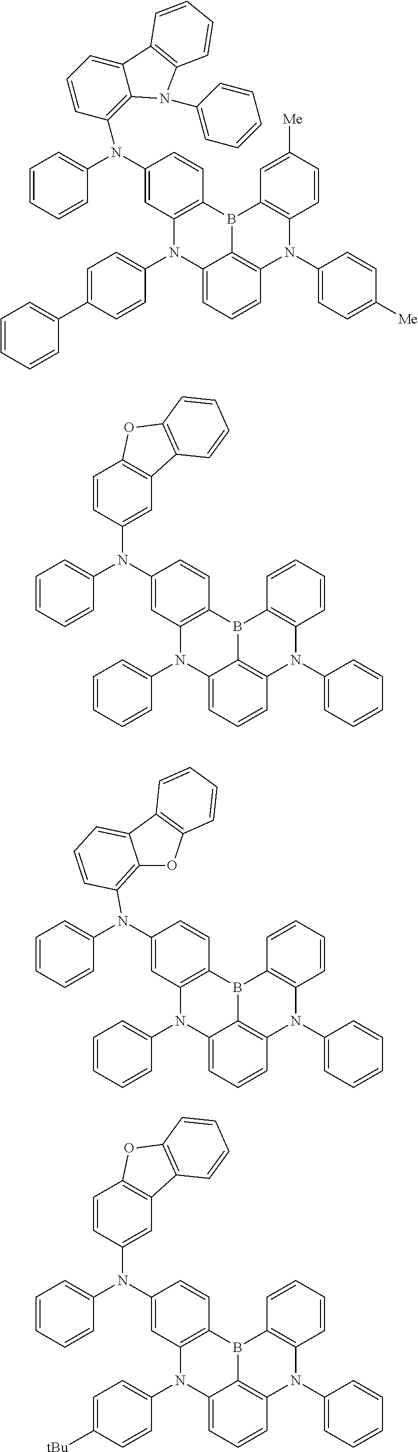

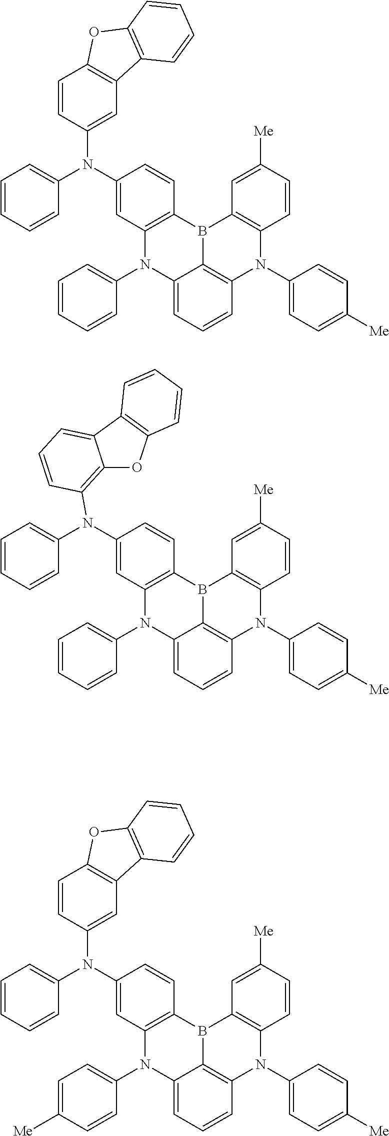 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

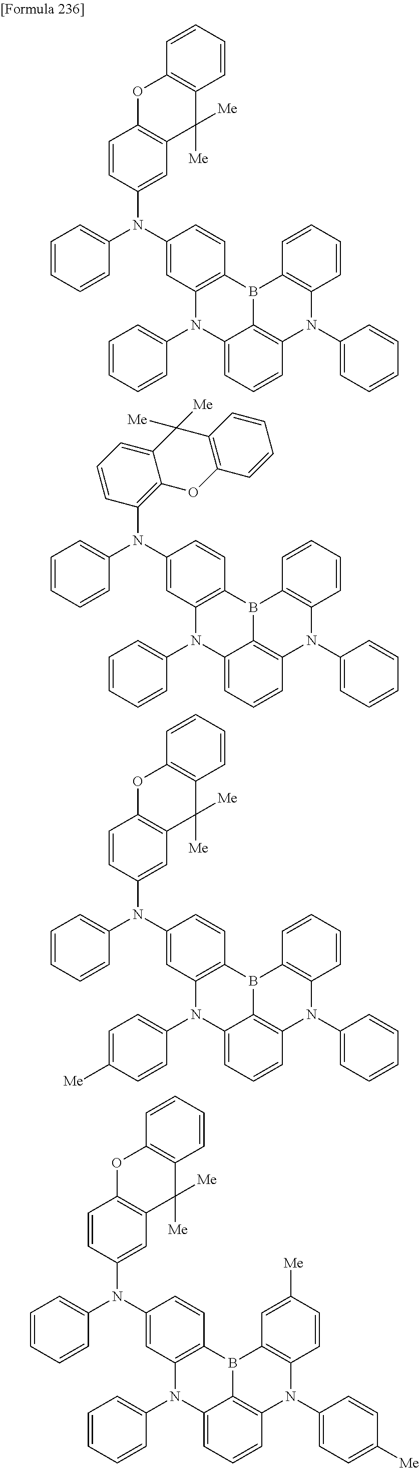

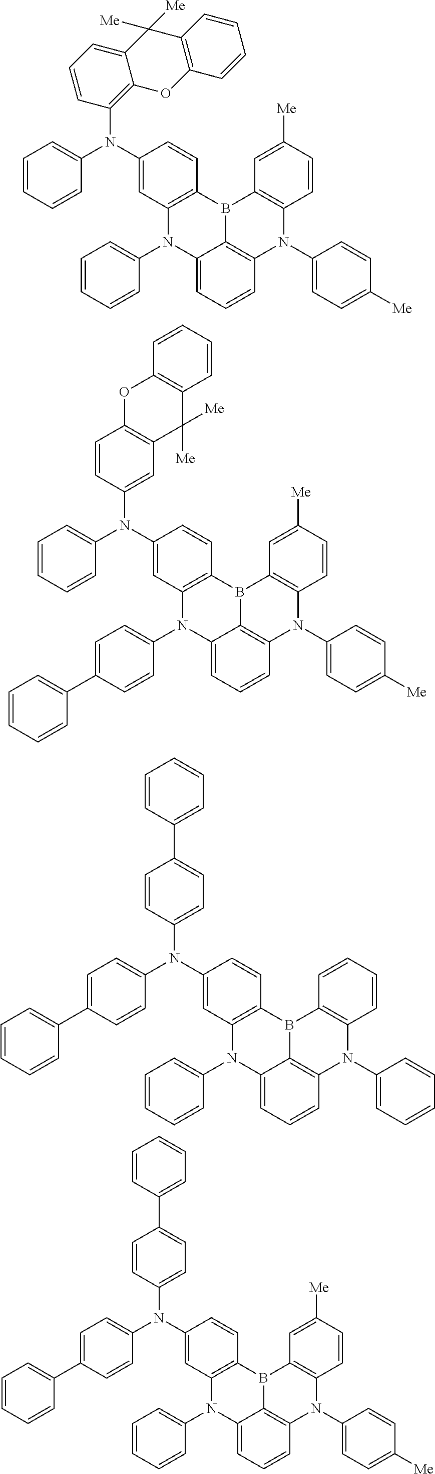

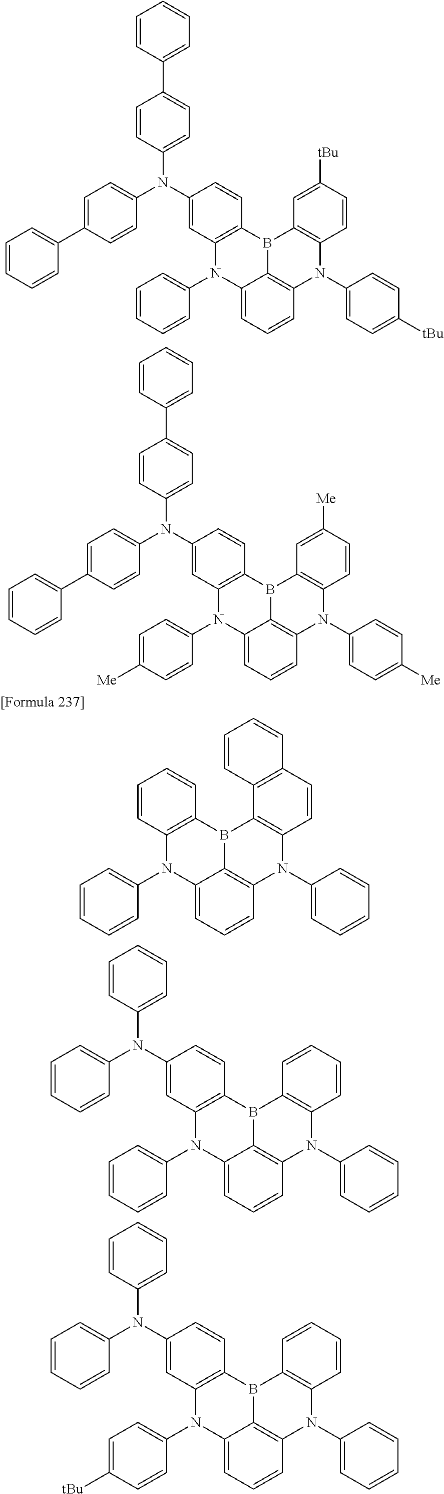

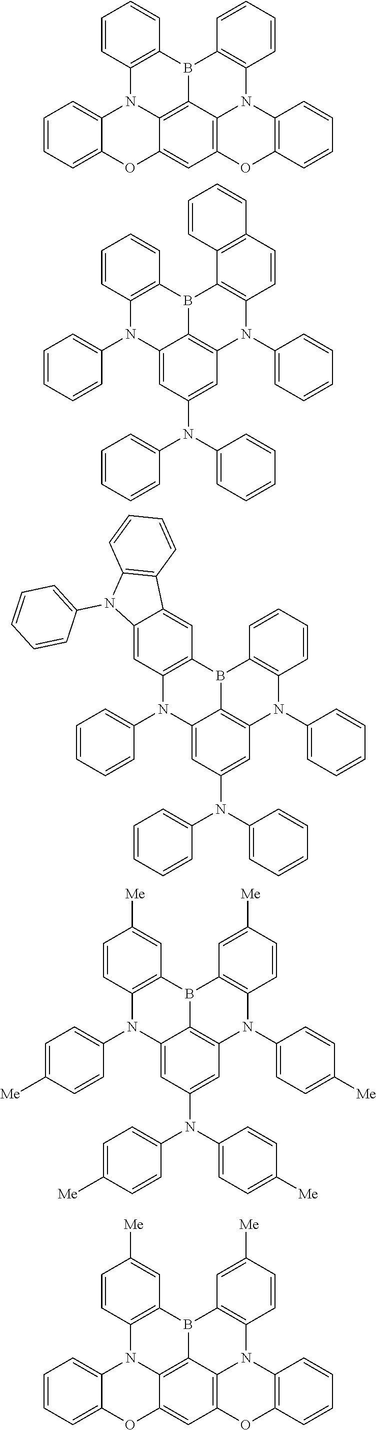

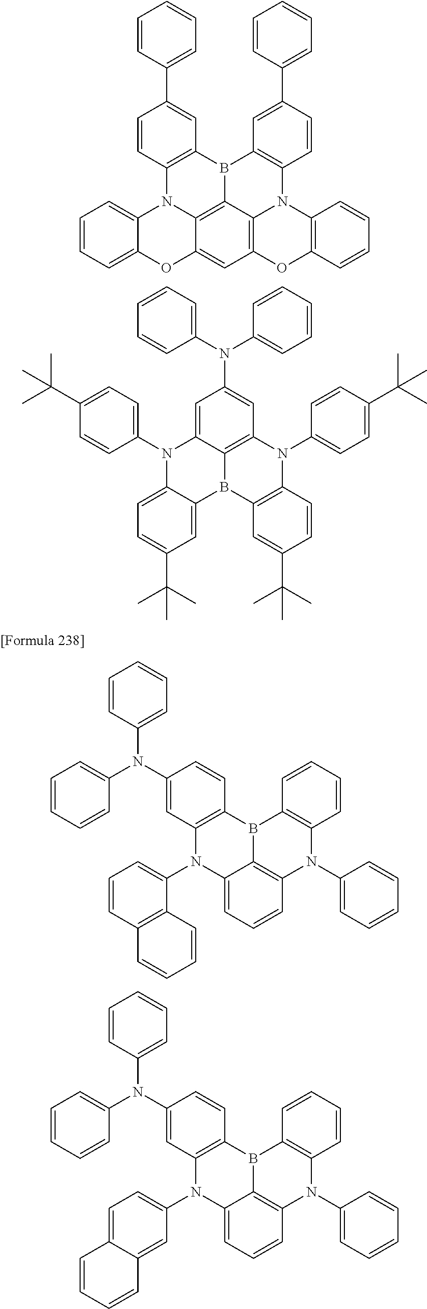

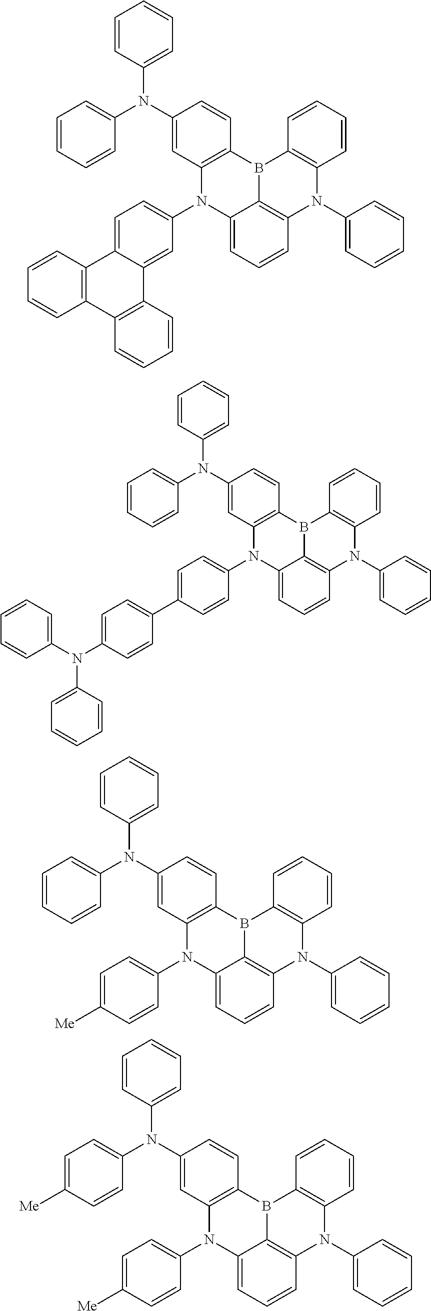

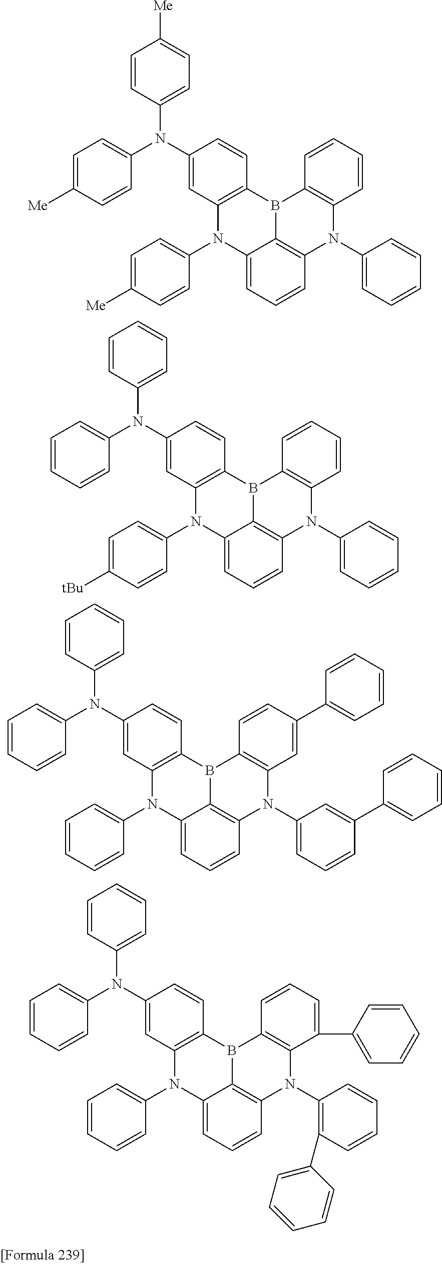

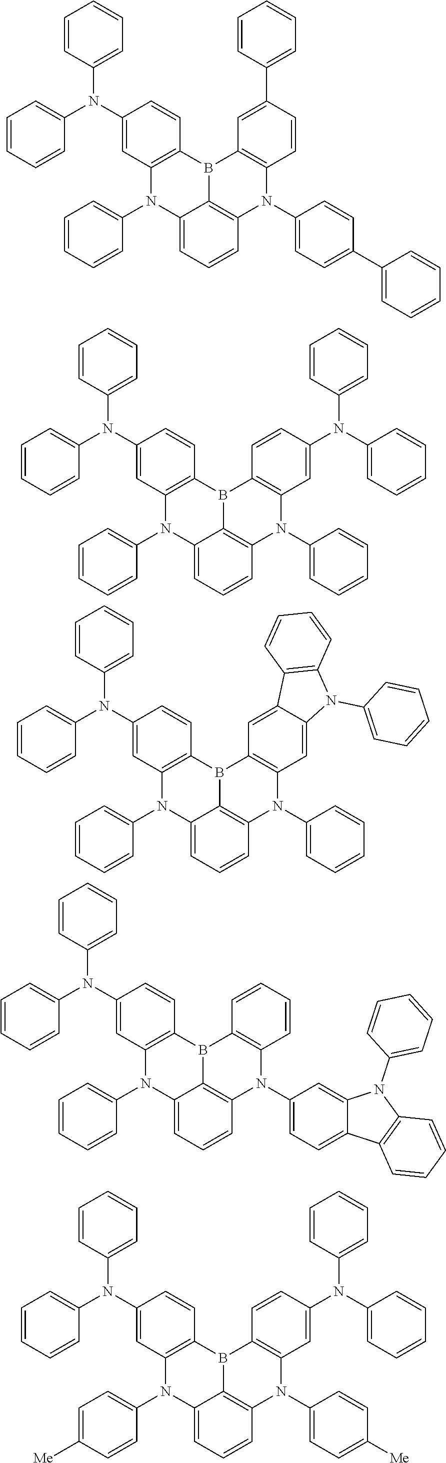

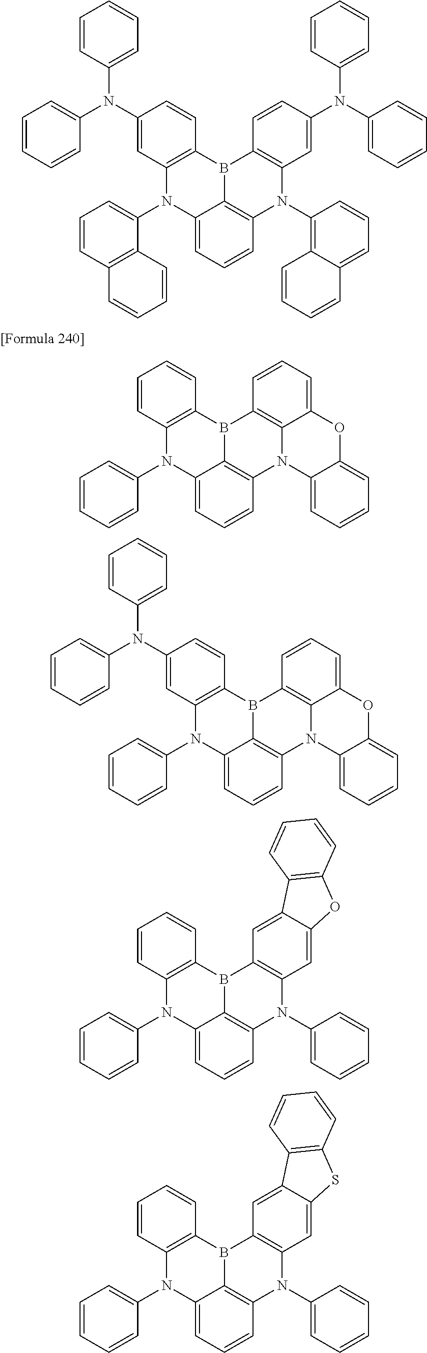

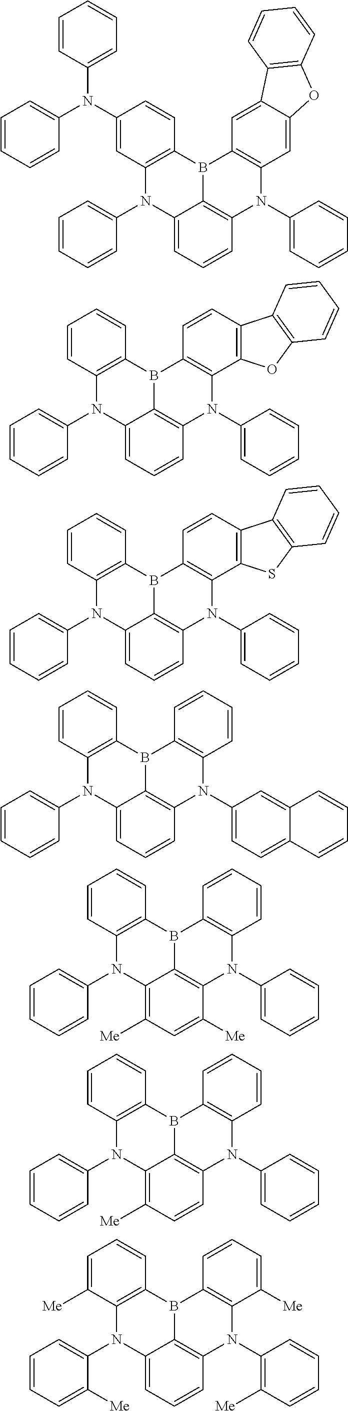

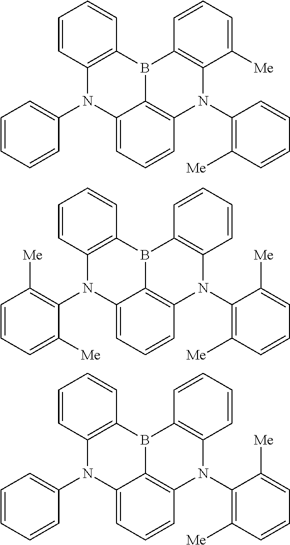

In the organic EL device according to the exemplary embodiment, a singlet energy of the second host material S₁(H2) and a singlet energy of the second dopant material S₁(D2) preferably satisfy a relationship of a numerical formula (Numerical Formula 20) below.

$${S}_{1} ( H 2 ) > {S}_{1} ( D 2 ) \qquad ( Numerical Formula 20 )$$

When the second host material and the second dopant material satisfy the relationship of the numerical formula (Numerical Formula 20), singlet excitons generated on the second host material easily energy-transfer from the second host material to the second dopant material, thereby contributing to emission (preferably fluorescence) of the second dopant material.

In the organic EL device according to the exemplary embodiment, the triplet energy of the second host material T₁(H2) and a triplet energy of the second dopant material T₁(D2) preferably satisfy a relationship of a numerical formula (Numerical Formula 20A) below.

$${T}_{1} ( D 2 ) > {T}_{1} ( H 2 ) \qquad ( Numerical Formula 20 A )$$

When the second host material and the second dopant material satisfy the relationship of the numerical formula (Numerical Formula 20A), triplet excitons generated in the second emitting layer transfer not onto the second dopant material having higher triplet energy but onto the second host material, thereby easily transferring to the first emitting layer.

In the organic EL device according to the exemplary embodiment, the second emitting layer contains the second dopant material preferably at 0.5 mass % or more, more preferably at more than 1.1 mass %, still more preferably at 1.2 mass % or more, and still further more preferably at 1.5 mass % or more with respect to the total mass of the second emitting layer.

The second emitting layer contains the second dopant material preferably at 10 mass % or less, more preferably at 7 mass % or less, and still more preferably at 5 mass % or less, with respect to the total mass of the second emitting layer.

In the organic EL device according to the exemplary embodiment, the second emitting layer contains the second host material preferably at 60 mass % or more, more preferably at 70 mass % or more, still more preferably at 80 mass % or more, still further more preferably at 90 mass % or more, and yet still further more preferably at 95 mass % or more, with respect to the total mass of the second emitting layer.

The second emitting layer preferably contains the second host material at 99 mass % or less with respect to the total mass of the second emitting layer.

When the second emitting layer contains the second host material and the second dopant material, the upper limit of the total of the content ratios of the second host material and the second dopant material is 100 mass %.

In the exemplary embodiment, the second emitting layer may further contain any other material than the second host material and the second dopant material.

The second emitting layer may contain a single type of the second host material alone or may contain two or more types of the second host material. The second emitting layer may contain a single type of the second dopant material alone or may contain two or more types of the second dopant material.

In the organic EL device according to the exemplary embodiment, a film thickness of the second emitting layer is preferably 3 nm or more, and more preferably 5 nm or more. The film thickness of the second emitting layer of 3 nm or more is sufficient for causing recombination of holes and electrons in the second emitting layer.

In the organic EL device according to the exemplary embodiment, the film thickness of the second emitting layer is preferably 15 nm or less, and more preferably 10 nm or less. The film thickness of the second emitting layer of 15 nm or less is thin enough for transfer of triplet excitons to the first emitting layer.

In the organic EL device of the exemplary embodiment, the film thickness of the second emitting layer is more preferably in a range from 3 nm to 15 nm.

### Additional Layers of Organic EL Device

The organic EL device according to the exemplary embodiment may include one or more organic layers in addition to the first emitting layer and the second emitting layer. Examples of the organic layer include at least one layer selected from the group consisting of a hole injecting layer, a hole transporting layer, an emitting layer, an electron injecting layer, an electron transporting layer, a hole blocking layer, and an electron blocking layer.

In the organic EL device according to the exemplary embodiments, for instance, the anode, the second emitting layer, the first emitting layer, and the cathode may be provided in this order. Alternatively, the order of the second emitting layer and the first emitting layer may be reversed: the anode, the first emitting layer, the second emitting layer, and the cathode may be provided in this order. Irrespective of the order of the first emitting layer and the second emitting layer, the effects obtained by layering the above emitting layers (i.e., the effect of prolonging the lifetime of the device and the effect of improving the luminous efficiency) are expected when a combination of the host materials satisfying the relationship of the numerical formula (Numerical Formula 1) is selected and the compound of the first exemplary embodiment is contained in the first emitting layer.

The organic layer of the organic EL device according to the exemplary embodiment may consist of the first emitting layer and the second emitting layer, alternatively, may further include, for instance, at least one layer selected from the group consisting of the hole injecting layer, hole transporting layer, electron injecting layer, electron transporting layer, hole blocking layer, and electron blocking layer.

In the organic EL device of the exemplary embodiment, it is preferable that the first emitting layer is provided between the anode and the cathode and the second emitting layer is provided between the first emitting layer and the anode.

In the organic EL device of the exemplary embodiment, it is also preferable that the first emitting layer is provided between the anode and the cathode and the second emitting layer is provided between the first emitting layer and the cathode.

In the organic EL device according to the exemplary embodiment, the hole transporting layer is preferably provided between the emitting layer and the anode.

In the organic EL device according to the exemplary embodiment, the electron transporting layer is preferably provided between the emitting layer and the cathode.

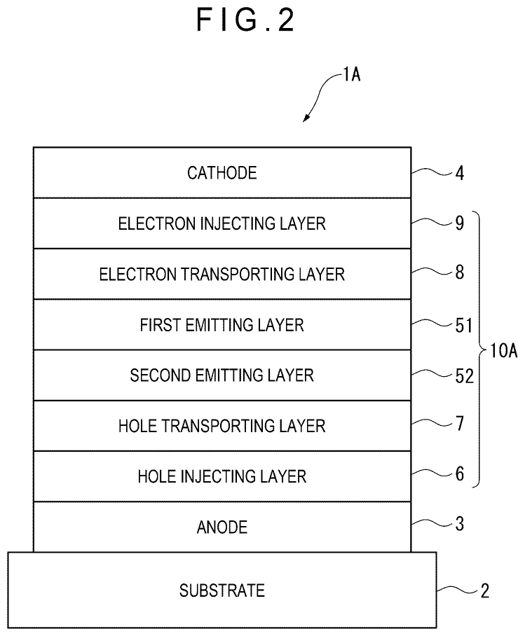

FIG. 2 schematically illustrates another exemplary arrangement of the organic EL device according to the fourth exemplary embodiment.

An organic EL device 1A includes the substrate 2, the anode 3, the cathode 4, and an organic layer 10A provided between the anode 3 and the cathode 4. The organic layer 10A includes the hole injecting layer 6, the hole transporting layer 7, the second emitting layer 52, the first emitting layer 51, the electron transporting layer 8, and the electron injecting layer 9 that are layered in this order from a side close to the anode 3.

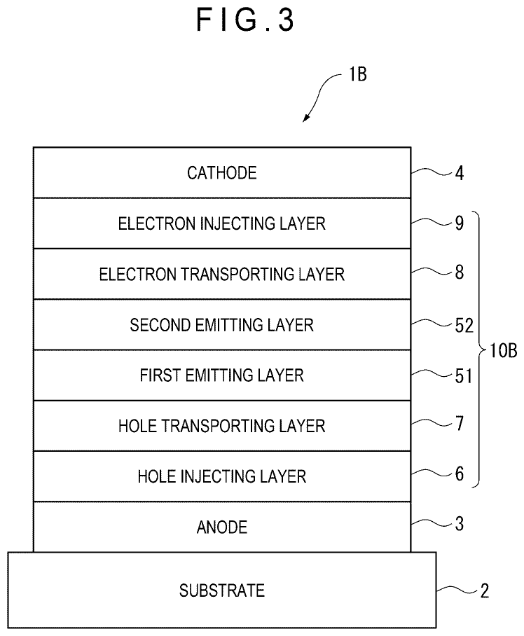

FIG. 3 schematically illustrates still another exemplary arrangement of the organic EL device according to the fourth exemplary embodiment.

An organic EL device 1B includes the substrate 2, the anode 3, the cathode 4, and an organic layer 10B provided between the anode 3 and the cathode 4. The organic layer 10B includes the hole injecting layer 6, the hole transporting layer 7, the first emitting layer 51, the second emitting layer 52, the electron transporting layer 8, and the electron injecting layer 9 that are layered in this order from a side close to the anode 3.

The invention is not limited to the exemplary arrangements of the organic EL devices illustrated in FIGS. 2 and 3.

### Third Emitting Layer

The organic EL device according to the exemplary embodiment may further include a third emitting layer.

It is preferable that: the third emitting layer contains a third host material; the first host material, the second host material, and the third host material are mutually different; the third emitting layer at least contains a third dopant material; the first dopant material, the second dopant material, and the third dopant material are mutually the same or different; and the triplet energy of the second host material T₁(H2) and a triplet energy of the third host material T₁(H3) satisfy a relationship of a numerical formula (5) below.

$${T}_{1} ( H 2 ) > {T}_{1} ( H 3 ) \qquad ( Numerical Formula 5 )$$

The third dopant material preferably emits light having the maximum peak wavelength of 500 nm or less, more preferably emits fluorescence having the maximum peak wavelength of 500 nm or less.

When the organic EL device according to the exemplary embodiment includes the third emitting layer, the triplet energy of the first host material T₁(H1) and the triplet energy of the third host material T₁(H3) preferably satisfy a relationship of a numerical formula (Numerical Formula 6) below.

$${T}_{1} ( H 1 ) > {T}_{1} ( H 3 ) \qquad ( Numerical Formula 6 )$$

The third host material, which is not particularly limited, can be exemplified by the host material listed as the first host material and the second host material in the exemplary embodiment.

The third dopant material, which is not particularly limited, can be exemplified by the dopant material listed as the first dopant material and the second dopant material in the exemplary embodiment.

In the organic EL device according to the exemplary embodiment, the first emitting layer is preferably in direct contact with the second emitting layer.

Herein, a layer arrangement in which “the first emitting layer and the second emitting layer are in direct contact with each other” may include, for instance, one of embodiments (LS1), (LS2), and (LS3) below.

(LS1) An embodiment in which a region containing both the first host material and the second host material is generated in a process of vapor-depositing the compound of the first emitting layer and vapor-depositing the compound of the second emitting layer, and is present on the interface between the first emitting layer and the second emitting layer.

(LS2) An embodiment in which in a case of containing an luminescent compound (dopant material) in the first emitting layer and the second emitting layer, a region containing the first host material, the second host material and the luminescent compound is generated in a process of vapor-depositing the compound of the first emitting layer and vapor-depositing the compound of the second emitting layer, and is present on the interface between the first emitting layer and the second emitting layer.

(LS3) An embodiment in which in a case of containing an luminescent compound in the first emitting layer and the second emitting layer, a region containing the luminescent compound, a region containing the first host material or a region containing the second host material is generated in a process of vapor-depositing the compound of the first emitting layer and vapor-depositing the compound of the second emitting layer, and is present on the interface between the first emitting layer and the second emitting layer.

When the organic EL device according to the exemplary embodiment includes the third emitting layer, preferably, the first emitting layer and the second emitting layer are in direct contact with each other and the first emitting layer and the third emitting layer are in direct contact with each other.

Herein, a layer arrangement in which “the first emitting layer and the third emitting layer are in direct contact with each other” may include, for instance, one of embodiments (LS4), (LS5), and (LS6) below.

(LS4) An embodiment in which a region containing both the first host material and the third host material is generated in a process of vapor-depositing the compound of the first emitting layer and vapor-depositing the compound of the third emitting layer, and is present on the interface between the first emitting layer and the third emitting layer.

(LS5) An embodiment in which in a case of containing a luminescent compound (dopant material) in the first emitting layer and the third emitting layer, a region containing the first host material, the third host material and the luminescent compound is generated in a process of vapor-depositing the compound of the first emitting layer and vapor-depositing the compound of the third emitting layer, and is present on the interface between the first emitting layer and the third emitting layer.

(LS6) An embodiment in which in a case of containing a luminescent compound in the first emitting layer and the third emitting layer, a region containing the luminescent compound, a region containing the first host material or a region containing the third host material is generated in a process of vapor-depositing the compound of the first emitting layer and vapor-depositing the compound of the third emitting layer, and is present on the interface between the first emitting layer and the third emitting layer.

When the organic EL device according to the exemplary embodiment includes an interposed layer, the interposed layer is preferably disposed between the first emitting layer and the second emitting layer.

The interposed layer is preferably a non-doped layer. The interposed layer is preferably a layer containing no luminescent compound (dopant material). The interposed layer preferably contains no metal atom.

The interposed layer contains an interposed layer material. The interposed layer material is preferably not a luminescent compound.

The interposed layer material, which is not particularly limited, is preferably a material other than the luminescent compound.

Examples of the interposed layer material include: 1) a heterocyclic compound such as an oxadiazole derivative, benzimidazole derivative, or phenanthroline derivative; 2) a fused aromatic compound such as a carbazole derivative, anthracene derivative, phenanthrene derivative, pyrene derivative or chrysene derivative; and 3) an aromatic amine compound such as a triarylamine derivative or a fused polycyclic aromatic amine derivative.

The interposed layer material may be one or both of the first host material contained in the first emitting layer and the second host material contained in the second emitting layer.

When the interposed layer contains a plurality of interposed layer materials, each of content ratios of the interposed layer materials is preferably 10 mass % or more with respect to the total mass of the interposed layer.

The interposed layer preferably contains 60 mass % or more of the interposed layer material, more preferably contains 70 mass % or more of the interposed layer material, still more preferably contains 80 mass % or more of the interposed layer material, still further more preferably 90 mass % or more of the interposed layer material, and yet still further more preferably 95 mass % or more of the interposed layer material, with respect to the total mass of the interposed layer.

The interposed layer may contain a single type of the interposed layer material or may contain two or more types of the interposed layer material.

When the interposed layer contains two or more types of the interposed layer material, the upper limit of the total of the content ratios of the two or more types of the interposed layer material is 100 mass %.

It should be noted that the organic EL device according to the fourth exemplary embodiment may further contain any other material than the interposed layer material.

The interposed layer may be provided in the form of a single layer or a laminate of two or more layers.

A film thickness of the interposed layer is not particularly limited, but each layer in the interposed layer is preferably in a range from 3 nm to 15 nm, and more preferably in a range from 5 nm to 10 nm.

An arrangement of an organic EL device will be further described below. This arrangement is common in the organic EL devices according to the third and fourth exemplary embodiments. It should be noted that the reference numerals are occasionally omitted below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layer formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal are also usable for the anode. It should be noted that the vacuum deposition method and the sputtering method are usable forforming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the substance exhibiting a high hole injectability include a low-molecule organic compound, examples of which include: an aromatic amine compound such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl(abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) are also usable.

### Hole Transporting Layer

The hole transporting layer is a layer containing a substance exhibiting a high hole injectability. An aromatic amine compound, carbazole derivative, anthracene derivative and the like are usable for the hole transporting layer. Specific examples of a material for the hole transporting layer include 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V-s) or more.

For the hole transporting layer, a carbazole derivative such as CBP, 9-[4-(N-carbazolyl)]phenyl-10-phenylanthracene (CzPA), and 9-phenyl-3-[4-(10-phenyl-9-anthryl)phenyl]-9H-carbazole (PCzPA) and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

### Electron Transporting Layer

In the organic EL device according to the exemplary embodiment, the electron transporting layer is preferably provided between the emitting layer and the cathode.

The electron transporting layer is a layer containing a substance exhibiting a higher electron transportability. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, for instance, a metal complex such as Alq, tris(4-methyl-8-quinolinato)aluminum (abbreviation: Almq₃), bis(10-hydroxybenzo[h]quinolinato)beryllium (abbreviation: BeBq2), BAIq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is preferably usable. The above-described substances mostly have an electron mobility of 10⁻⁶ cm²/Vs or more. It should be noted that any substance other than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)] (abbreviation: PF-BPy) are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method

A method for forming each layer of the organic EL device in each of the above exemplary embodiments is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

The film thickness of each organic layer of the organic EL device in each of the above exemplary embodiments is not limited unless otherwise specified in the above. In general, the thickness preferably ranges from several nanometers to 1 μm because an excessively small film thickness is likely to cause defects (e.g. pin holes) and an excessively large thickness leads to the necessity of applying high voltage and consequent reduction in efficiency.

### Fifth Exemplary Embodiment

### Electronic Device

An electronic device according to a fifth exemplary embodiment is installed with any one of the organic EL devices according to the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

### Modification of Embodiment(s)

The scope of the invention is not limited by the above exemplary embodiments but includes any modification and improvement as long as such modification and improvement are compatible with the invention.

For instance, the emitting layer is not limited to a single layer, but may be provided by laminating a plurality of emitting layers. In a case where the organic EL device includes a plurality of emitting layers, it is only required that at least one of the organic layers satisfies the conditions described in the above exemplary embodiments, and at least one of the emitting layers preferably contain a compound according to the first exemplary embodiment. When one of the emitting layers contains a compound according to the first exemplary embodiment, for instance, the rest of the emitting layers may be a fluorescent emitting layer(s) or a phosphorescent emitting layer(s) with use of emission caused by electron transfer from the triplet state directly to the ground state.

In a case where the organic EL device includes a plurality of emitting layers, these emitting layers may be mutually adjacently provided, or may form a so-called tandem organic EL device, in which the plurality of emitting units are layered via an intermediate layer.

For instance, a blocking layer may be provided adjacent to at least one of a side of the emitting layer close to the anode or a side of the emitting layer close to the cathode. The blocking layer is preferably provided in contact with the emitting layer to block at least any of holes, electrons, or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer is preferably interposed between the emitting layer and the electron transporting layer.

When the blocking layer is provided in contact with the side of the emitting layer close to the anode, the blocking layer permits transport of holes and blocks electrons from reaching a layer provided closer to the anode (e.g., the hole transporting layer) beyond the blocking layer. When the organic EL device includes the hole transporting layer, the blocking layer is preferably interposed between the emitting layer and the hole transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) (e.g., the electron transporting layer and the hole transporting layer) closer to the electrode(s) beyond the blocking layer.

The emitting layer is preferably bonded with the blocking layer.

Specific structure, shape and the like of the components in the invention may be designed in any manner as long as an object of the invention can be achieved.

### EXAMPLES

The invention will be described in more detail below with reference to Examples. The invention is by no means limited to these Examples.

### Compounds

Structures of compounds in Examples 1 and 3 and compounds used for producing organic EL devices in Examples 1A to 3A are shown below. Compounds BD-1, BD-2, and BD-3 each correspond to a compound represented by the formula (1).

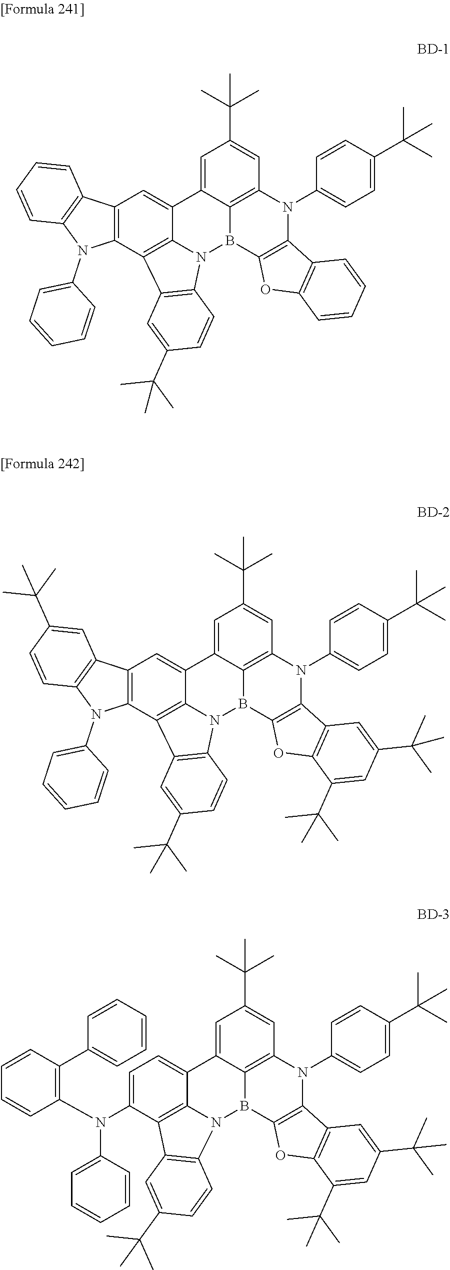

Structures of other compounds used for producing the organic EL devices in Examples 1A to 3A are shown below.

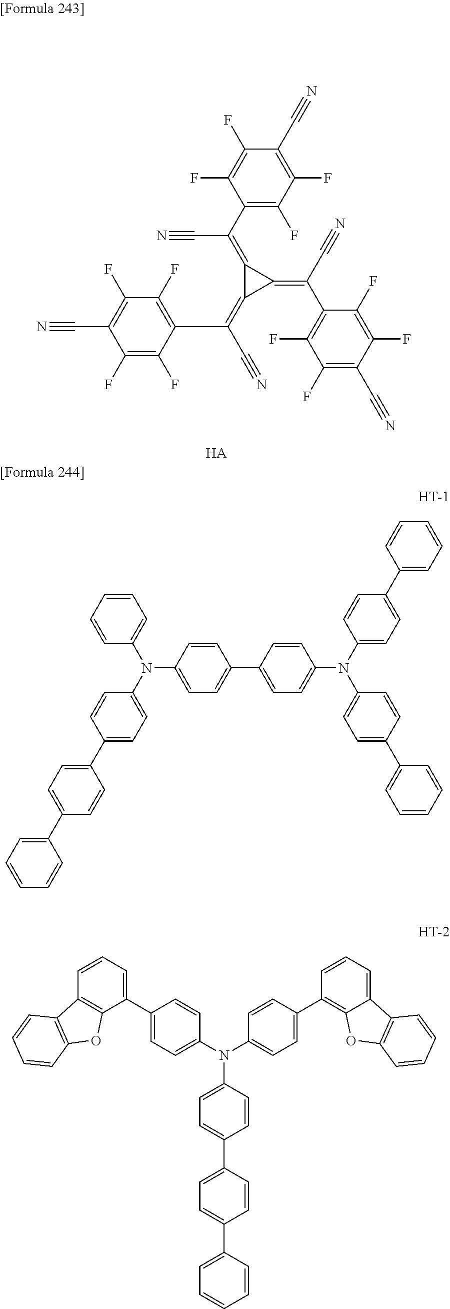 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; "HA" ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

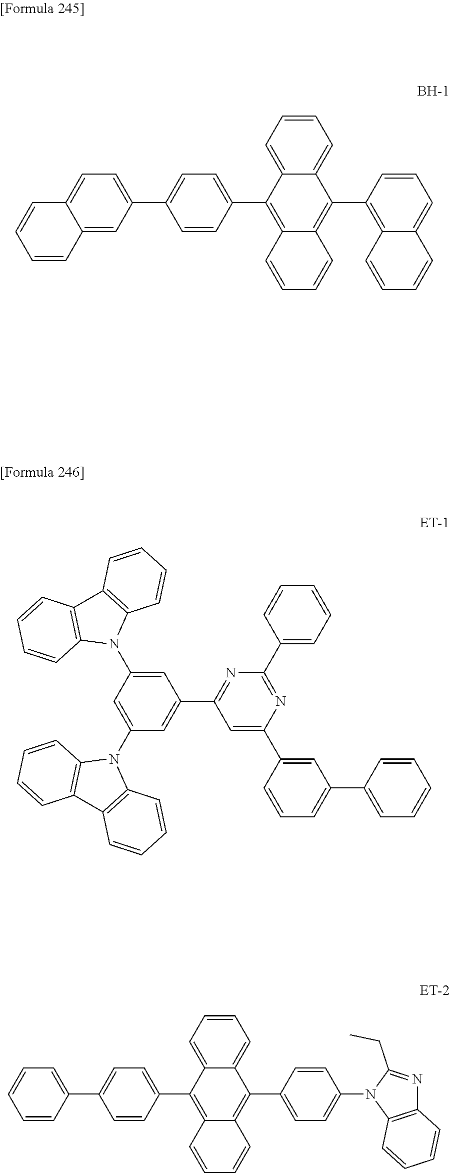

Structures of comparative compounds in Comparatives 1 and 2 are shown below.

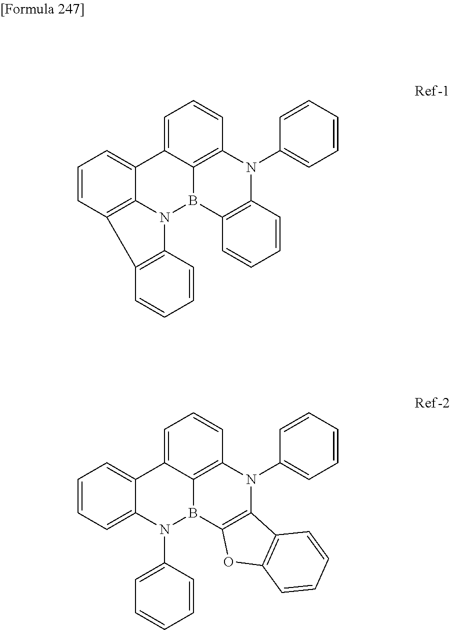 [SMILES: c1ccc(N2c3ccccc3B3c4c(cccc42)-c2cccc4c5ccccc5n3c24)cc1 ; c1ccc(N2B3c4oc5ccccc5c4N(c4ccccc4)c4cccc(c43)-c3ccccc32)cc1]

### Evaluation 1 of Compounds

### Maximum Fluorescence Peak Wavelength and Full Width at Half Maximum (FWHM) of Emission Spectrum

A measurement target compound was dissolved in toluene to prepare a solution at 5.0×10⁻⁶ mol/L. The obtained solution was put into a quartz cell (light path length: 1.0 cm). Using a fluorescence spectrometer “spectrophotofluorometer FP-8300” (produced by JASCO Corporation), the solution was excited at 400 nm, where a maximum fluorescence peak wavelength (unit: nm) and a full width at half maximum FWHM of emission spectrum (unit: nm) were measured. FWHM is an abbreviation of Full Width at Half Maximum. Table 1 shows measurement results.

### Photoluminescence Quantum Yield

A measurement target compound was dissolved in toluene to prepare a solution at 5.0×10⁻⁶ mol/L. The solution was frozen and degassed and then saturated with argon to prepare an argon saturated solution. The obtained solution was transferred to a quartz cell (light path length: 1.0 cm). Photoluminescence quantum yield (PLQY) was measured using an absolute PL quantum yield measuring device “Hamamatsu Quantaurus-QY C11347” (manufactured by Hamamatsu Photonics Co., Ltd.). Table 1 shows measurement results.

TABLE 1

| | | PLQY | FWHM | Maximum fluorescence |
|---|---|---|---|---|
| | Name | [%] | [nm] | peak wavelength [nm] |
| Example 1 | BD-1 | 85 | 14 | 446 |
| Example 2 | BD-2 | 87 | 13 | 445 |
| Example 3 | BD-3 | 84 | 18 | 446 |

The compounds BD-1, BD-2, and BD-3 in Examples 1 to 3 had emission peak wavelengths in a desired wavelength zone and exhibited a narrow full width at half maximum of emission spectrum and a high value of PLQY.

### Production of Organic EL Devices

Organic EL devices were produced and evaluated as follows.

### Example 1A

A glass substrate (size: 25 mm×75 mm×0.7 mm thick, produced by Geomatec Co., Ltd.) having an indium tin oxide (ITO) transparent electrode of a 130-nm thickness was used as an anode. This glass substrate having the ITO transparent electrode was cleaned with nitrogen plasma for 100 seconds.

The cleaned glass substrate was attached to a substrate holder and transported into a vacuum evaporator.

Subsequently, a compound HT-1 and a compound HA were co-deposited on a surface of the ITO transparent electrode at a pressure in a range from 10⁻⁶ mbar to 10⁻⁸ mbar and a deposition rate of 0.01 Å/min to 2 Å/min to form a 10-nm-thick hole injecting layer (HI). Ratios of the compound HT-1 and the compound HA in the hole injecting layer were 97 mass % and 3 mass %, respectively.

Subsequent to forming the hole injecting layer, the compound HT-1 was vapor-deposited on the hole injecting layer to form an 80-nm-thick first hole transporting layer (HT).

Subsequent to forming the first hole transporting layer, a compound HT-2 was vapor-deposited on the first hole transporting layer to form a 10-nm-thick second hole transporting layer (also referred to as an electron blocking layer) (EBL).

A compound BH-1 (first host material (BH)) and the compound BD-1 (first dopant material (BD)) were co-deposited on the second hole transporting layer such that the ratio of the compound BD-1 accounted for 2 mass %, thereby forming a 25-nm-thick emitting layer.

A compound ET-1 was vapor-deposited on the emitting layer to form a 10-nm-thick first electron transporting layer (also referred to as a hole blocking layer) (HBL).

A compound ET-2 was vapor-deposited on the first electron transporting layer (HBL) to form a 15-nm-thick second electron transporting layer (ET).

Lithium fluoride (LiF) was vapor-deposited on the second electron transporting layer to form a 1-nm-thick electron injecting layer.

Metal Al was vapor-deposited on the electron injecting layer to form an 80-nm-thick cathode.

The produced device was sealed in an inert nitrogen atmosphere containing less than 1 ppm of water and oxygen using a glass cover and a moisture absorbent.

A device arrangement of the organic EL device in Example 1A is roughly shown as follows.
ITO(130)/HT-1:HA(10.97%:3%)/HT-1(80)/HT-2(10)/BH-1:BD-1(25.98%:2%)/ET-1(10)/ET-2(15)/LiF(1)/Al(80)

Numerals in parentheses represent a film thickness (unit: nm). The numerals (97%:3%) represented by percentage in the same parentheses indicate a ratio (mass %) between the compound HT-1 and the compound HA in the hole injecting layer. The numerals (98%:2%) represented by percentage in the same parentheses indicate a ratio (mass %) between the host material (compound BH-1) and the dopant material (compound BD-1) in the emitting layer.

### Examples 2A and 3A

Organic EL devices in Examples 2A and 3A were produced in the same manner as in Example 1A except that the compound BD-1 used as the first dopant material in the emitting layer of Example 1A was replaced by compounds shown in Table 2.

### Evaluation of Organic EL Devices

The organic EL devices produced were evaluated as follows. Table 2 shows the evaluation results.

### Drive Voltage

Voltage (unit: V) when electric current was applied to between the anode and the cathode so that the current density was 10 mA/cm² was measured.

### Maximum Peak Wavelength Ap and Full Width at Half Maximum (FWHM) of Emission Spectrum

Voltage was applied to the organic EL devices such that a current density was 10 mA/cm², where spectral radiance spectrum was measured with a spectroradiometer CS-2000 (produced by Konica Minolta, Inc.). The maximum peak wavelength λp (unit: nm) and full width at half maximum (FWHM, unit: nm) of emission spectrum were calculated based on the obtained spectral-radiance spectrum.

### External Quantum Efficiency EQE

Voltage was applied to the organic EL devices such that a current density was 10 mA/cm², where spectral radiance spectrum was measured with a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation.

TABLE 2

| | Emitting layer | | Evaluation | | | |
|---|---|---|---|---|---|---|
| | | Dopant | Voltage | EQE | λp | FWHM |
| | Host material | material | [V] | [%] | [nm] | [nm] |
| Example 1A | BH-1 | BD-1 | 3.67 | 9.7 | 452 | 15 |
| Example 2A | BH-1 | BD-2 | 3.66 | 10.1 | 451 | 14 |
| Example 3A | BH-1 | BD-3 | 3.72 | 9.8 | 452 | 19 |

The organic EL devices in Examples 1A to 3A had emission peak wavelengths in a desired wavelength zone and exhibited a narrow full width at half maximum of the emission spectrum and emitted light with a high efficiency.

### Evaluation 2 of Compounds

### Lowest Singlet Energy Level

Regarding the compounds BD-1, BD-2, and BD-3 and comparative compounds Ref-1 and Ref-2, the lowest singlet energy level (S1 energy level) was calculated by TD-DFT calculation using B3LYP as hybrid functional and 6-31 g* as a basis function. All calculations were implemented using the Gaussian 16 software program available from Gaussian Inc. Table 3 shows results.

TABLE 3

| | Name | S 1 energy level [eV] |
|---|---|---|
| Example 1 | BD-1 | 2.973 |
| Example 2 | BD-2 | 2.984 |
| Example 3 | BD-3 | 2.955 |
| Comparative 1 | Ref-1 | 3.207 |
| Comparative 2 | Ref-2 | 3.375 |

As shown in Table 1, the maximum peak wavelength of each of the compound BD-1 in Example 1 and the compound BD-3 in Example 3 was 446 nm. The maximum peak wavelength of the compound BD-2 in Example 2 was 445 nm.

In contrast, the comparative compound Ref-1 in Comparative 1 and the comparative compound Ref-2 in Comparative 2, which are estimated to have higher S1 energy level than the compounds BD-1, BD-2, and BD-3, has an emission wavelength close to the short-wavelength side with respect to a blue emission wavelength (from 445 nm to 465 nm) suitable for display usage. Therefore, the comparative compound Ref-1 and the comparative compound Ref-2 are not suitable for being used as a material of an organic EL device for display usage.

### Synthesis Examples

### Synthesis of Compound BD-1

A synthesis method of the compound BD-1 is described below.

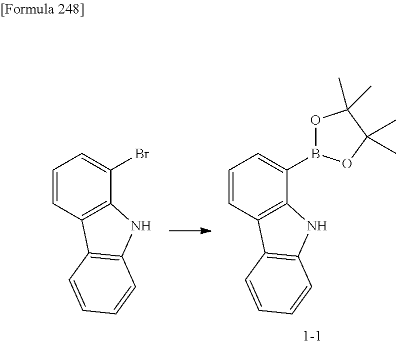 [SMILES: Brc1cccc2c1[nH]c1ccccc12 ; CC1(C)OB(c2cccc3c2[nH]c2ccccc23)OC1(C)C]

### Production of Intermediate 1-1

1-bromo-9H-carbazole (10.0 g, 40.6 mmol), bis(pinacolato)diboron (13.4 g, 52.8 mmol), and potassium acetate (16.0 g, 168.2 mmol) were suspended in 100 mL of anhydrous N,N-dimethylformamide. The reaction container was evacuated under high vacuum and purged with argon. This procedure was repeated seven times. [1,1′-bis(diphenylphosphino)ferrocene-palladium(II) (2.32 g, 7 mol %) complexed with dichloromethane was added to the reaction mixture. Subsequently, the obtained reaction mixture was degassed and purged with argon, which was repeated twice. The reaction mixture was heated at 80 degrees C. for 19 hours. After cooled to the room temperature, the reactant was diluted with 10 mL of diethyl ether and 50 mL of cyclohexane and filtered through a small pad of silica gel. The pad was washed with 300 mL of a mixture of cyclohexane and diethyl ether (cyclohexane:diethyl ether=5:1). The solvent was removed with a rotary evaporator and the residue was purified by silica gel column chromatography using cyclohexane as an eluent. Fractions containing the product were combined and the solvent was removed on a rotary evaporator until a white solid precipitated. The suspension was filtered to obtain an intermediate 1-1 (10.25 g, a yield of 86%) as a white solid.

¹H NMR (300 MHz, DMSO-d6) δ 10.33 (s, 1H), 8.31-8.23 (m, 1H), 8.14-8.09 (m, 1H), 7.75 (dt, J=8.1, 0.9 Hz, 1H), 7.71 (dd, J=7.2, 1.3 Hz, 1H), 7.44-7.36 (m, 1H), 7.23-7.13 (m, 2H), 1.41 (s, 12H).

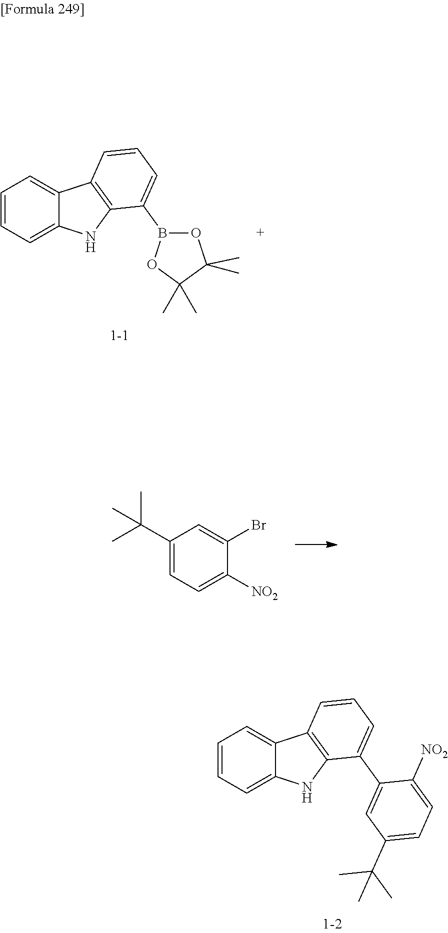

### Production of Intermediate 1-2

The intermediate 1-1 (9.57 g, 32.6 mmol), 2-bromo-4-(tert-butyl)-1-nitrobenzene (8.26 g, 32.0 mmol), and sodium hydroxide (2.56 g, 64.0 mmol) were suspended in a mixture of tetrahydrofuran/water (100/50 (mL)). The suspension was degassed under an argon atmosphere and tetrakis(triphenylphosphine)palladium(0) (555 mg, 1.5 mol %) was added to the reaction mixture. The reaction mixture was refluxed for 2.5 hours. The reactant was cooled to the room temperature and diluted with toluene/water. The layers were separated and the aqueous layer was further extracted with toluene. The organic extracts were washed with water and saturated saline solution, dried over sodium sulfate, filtered and evaporated. The residue was purified by silica gel column chromatography using heptane/toluene as an eluent to obtain an intermediate 1-2 (10.01 g, a yield of 91%) as an orange solid.

ESI-MS:343.3[M+H]⁺

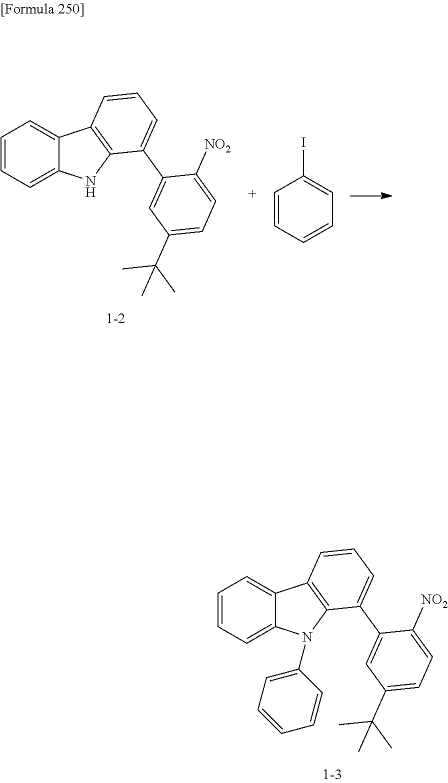

### Production of Intermediate 1-3

The intermediate 1-2 (9.30 g, 27.0 mmol), iodobenzene (18.13 mL, 162 mmol), potassium carbonate (11.19 g, 81.0 mmol), and copper (858 mg, 13.5 mmol) were suspended in 90 mL of nitrobenzene. The suspension was degassed with Ar and then heated at 200 degrees C. for six hours. The reactant was cooled to the room temperature, diluted with toluene, and then filtered through cerite. After the filtrate was concentrated and the resultant residue was dissolved in 500 mL of toluene, 60 g of silica gel was added and the suspension was stirred at the room temperature. The suspension was filtered and the filtrate was diluted with toluene/water. The layers were separated and the organic layer was further washed with water, then dried over sodium sulfate, and filtered. Subsequently, the solution was concentrated. The crude solid was recrystallized from isopropanol/diisopropyl ether (180 mL, 1:1) to obtain an intermediate 1-3 (9.65 g, 85% of yield) as a yellow solid.

ESI-MS:421.4[M+H]⁺

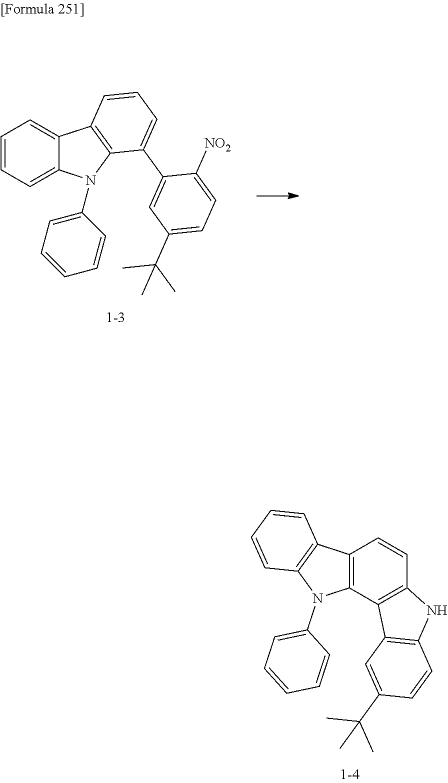 [SMILES: CC(C)(C)c1ccc([N+](=O)[O-])c(-c2cccc3c4ccccc4n(-c4ccccc4)c23)c1 ; CC(C)(C)c1ccc2[nH]c3ccc4c5ccccc5n(-c5ccccc5)c4c3c2c1]

### Production of Intermediate 1-4

The intermediate 1-3 (11.35 g, 27.0 mmol) and triphenylphosphine (85 g, 324 mmol) were combined and the solid mixture was heated at 200 degrees C. for 3.5 hours. After the mixture was cooled to the room temperature, the residue was purified by silica gel column chromatography using cyclohexane/toluene as an eluent to obtain an intermediate 1-4 (7.03 g, a yield of 67%) as a white solid.

ESI-MS:387.3[M−H]⁺

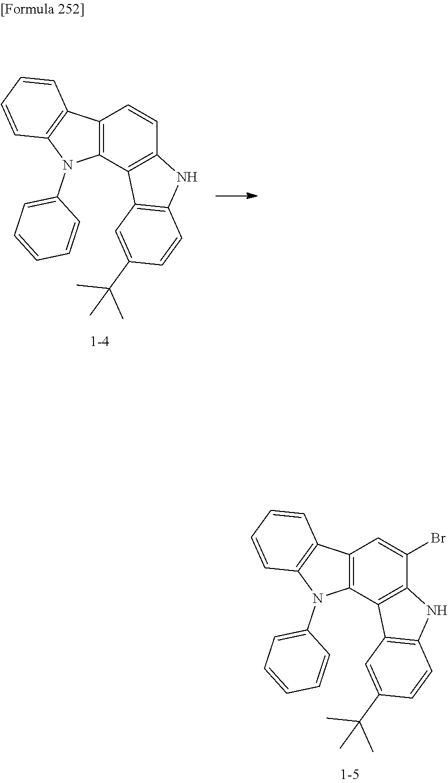 [SMILES: CC(C)(C)c1ccc2[nH]c3ccc4c5ccccc5n(-c5ccccc5)c4c3c2c1 ; CC(C)(C)c1ccc2[nH]c3c(Br)cc4c5ccccc5n(-c5ccccc5)c4c3c2c1]

### Production of Intermediate 1-5

The intermediate 1-4 (6.80 g, 17.5 mmol) was dissolved in a mixed solution of 30 mL of dimethylformamide and 60 mL of chloroform. After the solution was cooled to 0 degrees C., N-bromosuccinimide (3.11 g, 17.5 mmol) was gradually added over 30 minutes. A temperature of the reactant was raised to the room temperature, where the reaction solution was stirred for one hour. After the reaction mixture was evaporated, the residue was purified by silica gel column chromatography using heptane/toluene as an eluent to obtain an intermediate 1-5 (7.81 g, a yield of 95%) as a white solid.

ESI-MS:465.2[M−H]⁺

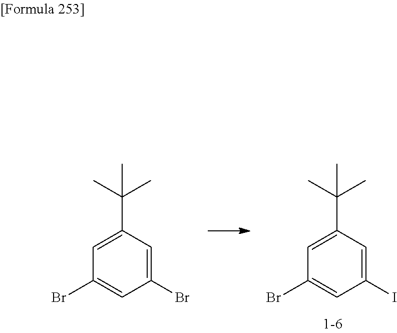

### Production of Intermediate 1-6

1,3-dibromo-5-(tert-butyl)benzene (48.0 g, 0.16 mol) was dissolved in 500 mL of tetrahydrofuran. 70.0 mL of n-butyllithium (2.5 M solution in hexane) was added dropwise at −71 degrees C. for 45 minutes. Iodine (45.9 g, 0.18 mol) was gradually added at −55 degrees C. over 15 minutes and the resultant suspension was further stirred at −78 degrees C. for 45 minutes. 400 mL of 10% aqueous sodium sulfite solution was added and the reaction mixture was further stirred until reaching the room temperature. The organic layer was separated and the aqueous phase was extracted twice with 150 mL of cyclohexane. The organic layer obtained was washed twice with 200 mL of water and then with saturated aqueous sodium chloride solution. The organic layer was dried over sodium sulfate and concentrated under vacuum to obtain an intermediate 1-6 (54.7 g, a yield of 83%) as an orange oil.

¹H NMR (300 MHz, DMSO-d6) δ 7.77 (t, 1H), 7.72 (t, 1H), 7.57 (t, 1H), 1.26 (s, 9H).

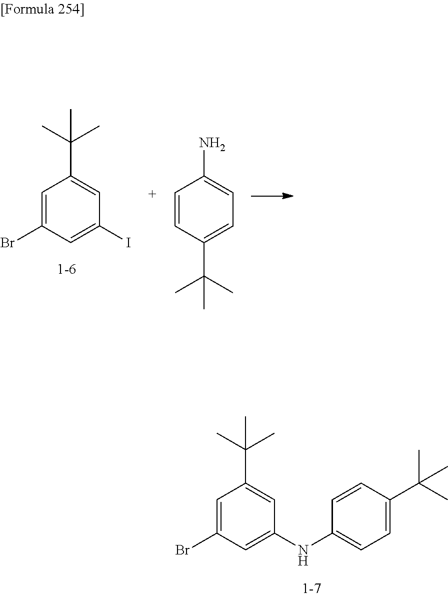

### Production of Intermediate 1-7

The intermediate 1-6 (7.46 g, 22.00 mmol), 4-(tert-butyl)aniline (3.28 g, 22.00 mmol), and sodium tert-butoxide (2.96 g, 30.08 mmol) were suspended in 100 mL of toluene. After the suspension was degassed with Ar, tris(dibenzylideneacetone)dipalladium(0) (242 mg, 1.2 mol %) and 4,5-bis(diphenylphosphino)-9,9-dimethylxanthene (611 mg, 4.8 mol %) were added to the mixture. The reaction mixture was stirred at 50 degrees C. for one hour. The reactant was cooled to the room temperature, filtered, and rinsed with toluene. The filtrate was concentrated and the residue was purified by silica gel column chromatography using heptane/toluene as an eluent to obtain an intermediate 1-7 (6.25 g, a yield of 79%) as a yellow oil.

ESI-MS:358.3[M−H]⁺

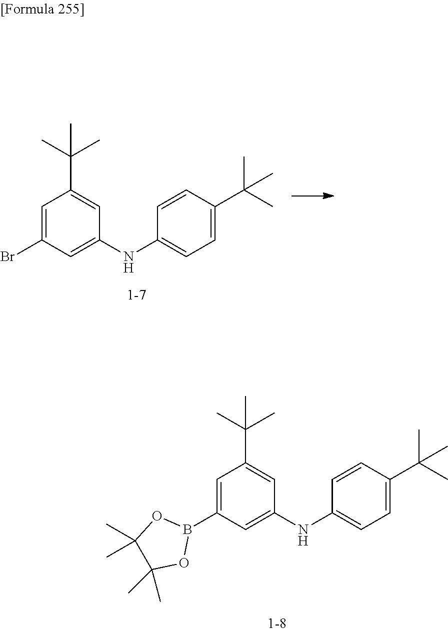 [SMILES: CC(C)(C)c1ccc(Nc2cc(Br)cc(C(C)(C)C)c2)cc1 ; CC(C)(C)c1ccc(Nc2cc(B3OC(C)(C)C(C)(C)O3)cc(C(C)(C)C)c2)cc1]

### Production of Intermediate 1-8

The intermediate 1-7 (6.09 g, 16.9 mmol), bis(pinacolato)diboron (5.58 g, 21.97 mmol), and potassium acetate (6.63 g, 67.6 mmol) were suspended in 50 mL of anhydrous N,N-dimethylformamide. The reaction container was evacuated under high vacuum and purged with argon, thereby degassing the suspension. This procedure was repeated six times. [1,1′-bis(diphenylphosphino)ferrocene-palladium(II) (414 mg, 3 mol %) complexed with dichloromethane was added to the reactant. The reaction mixture was heated to 2.5 degrees C. for 105 hours. After cooled to the room temperature, the reactant was diluted with toluene and filtered through a small pad of silica gel. The filtrate was concentrated and the residue was purified by silica gel column chromatography using heptane/toluene as an eluent to obtain an intermediate 1-8 (5.51 g, a yield of 80%) as a white solid.

ESI-MS:408.5[M+H]⁺

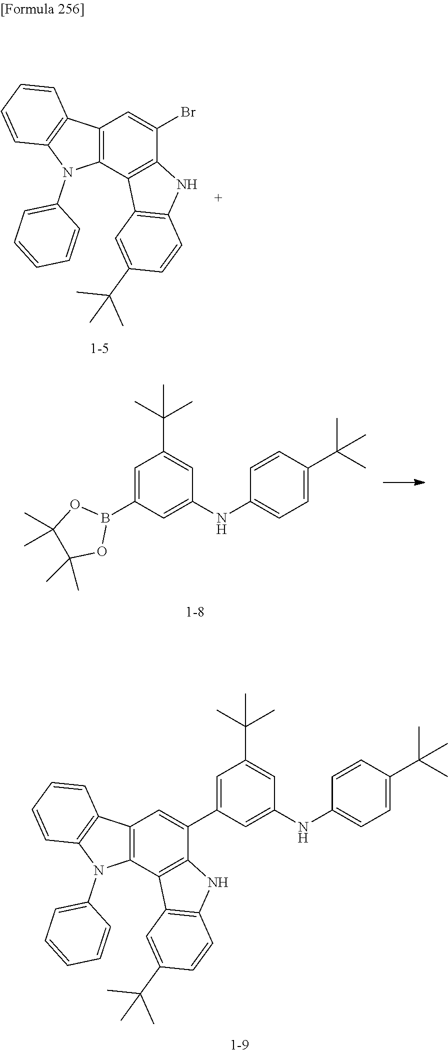

### Production of Intermediate 1-9

The intermediate 1-5 (5.84 g, 12.5 mmol), the intermediate 1-8 (5.19 g, 12.75 mmol), and sodium hydroxide (1.00 g, 25.0 mmol) were suspended in a mixture of tetrahydrofuran/water (60/30 (mL)). The suspension was degassed with Ar and tetrakis(triphenylphosphine)palladium(0) (433 mg, 3 mol %) was added to the reaction mixture. The reaction mixture was refluxed for 7 hours. The reactant was cooled to the room temperature and diluted with toluene/water. After filtration, the layers were separated and the aqueous layer was further extracted with toluene. The organic extracts were washed with water and saturated saline solution, dried over sodium sulfate, filtered and evaporated. The residue was purified by silica gel column chromatography using heptane/toluene as an eluent to obtain an intermediate 1-9 (8.00 g, a yield of 96%) as a beige solid.

ESI-MS:668.5[M+H]⁺

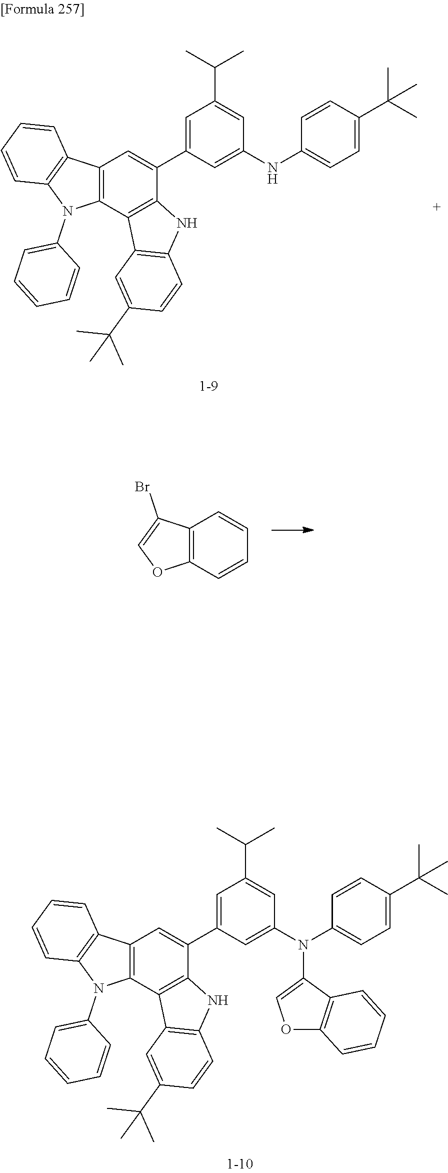 [SMILES: CC(C)c1cc(Nc2ccc(C(C)(C)C)cc2)cc(-c2cc3c4ccccc4n(-c4ccccc4)c3c3c2[nH]c2ccc(C(C)(C)C)cc23)c1 ; "+" ; Brc1coc2ccccc12 ; CC(C)c1cc(-c2cc3c4ccccc4n(-c4ccccc4)c3c3c2[nH]c2ccc(C(C)(C)C)cc23)cc(N(c2ccc(C(C)(C)C)cc2)c2coc3ccccc23)c1]

### Production of Intermediate 1-10

The intermediate 1-9 (8.02 g, 12.00 mmol), 3-bromobenzofuran (2.36 g, 12.00 mmol), and sodium tert-butoxide (2.88 g, 30.00 mmol) were suspended in 100 mL of toluene. After the suspension was degassed with Ar, tris(dibenzylideneacetone)dipalladium(0) (220 mg, 2 mol %) and tri-tert-butylphosphonium tetrafluoroborate (279 mg, 8 mol %) were added to the mixture. The reaction mixture was stirred at 6.5 degrees C. for 65 hours. The reactant was cooled to the room temperature and diluted with toluene/water. The layers were separated and the aqueous layer was further extracted with toluene. The organic extracts were washed with water and saturated saline solution, dried over sodium sulfate, filtered and evaporated. The filtrate was concentrated and the residue was purified by silica gel column chromatography using heptane/toluene as an eluent to obtain an intermediate 1-10 (6.86 g, a yield of 73%) as a beige solid.

ESI-MS:784.4[M+H]⁺

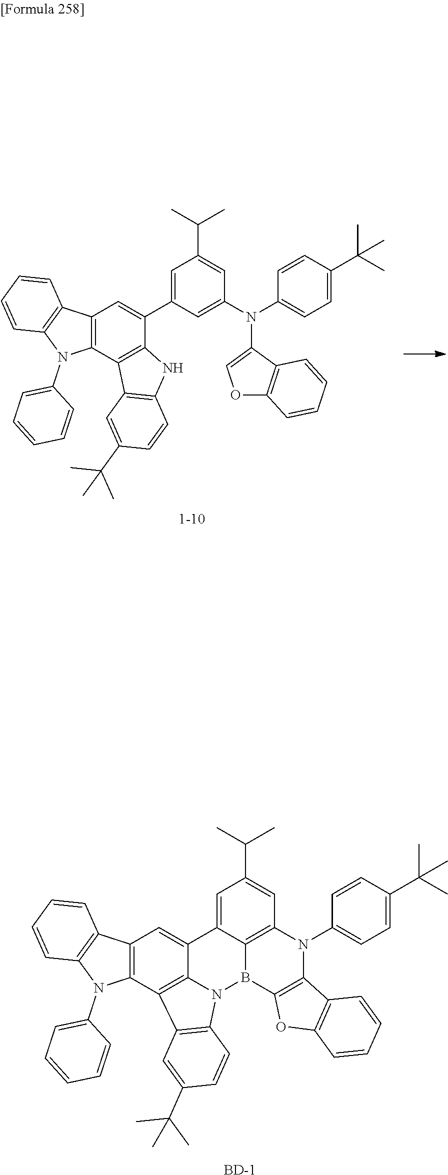

### Production of Compound BD-1

The intermediate 1-10 (2.59 g, 3.30 mmol) was dissolved in 45 mL of tert-butylbenzene, degassed with Ar, and cooled to 0 degrees C. Tert-butyllithium (4.33 mL, 6.93 mmol) (1.6 M solution in pentane) was added dropwise, then a temperature of the resultant solution was raised to the room temperature, and the solution was stirred for two hours. Next, tribromoborane (6.60 mL, 6.60 mmol) (1M solution in heptane) was added dropwise at 0 degrees C., and subsequently N-ethyl-N-isopropylpropan-2-amine (2.26 mL, 13.20 mmol) was added. The reaction mixture was stirred at 160 degrees C. for six hours. The reactant was cooled to the room temperature and diluted with methanol/water. The precipitate was filtered and washed with methanol, water, heptane, and toluene. The solid was recrystallized from xylene to obtain the compound BD-1 (891 mg, a yield of 34%) as a yellow solid. ESI-MS:792.6[M+H]⁺

### Synthesis of Compound BD-2

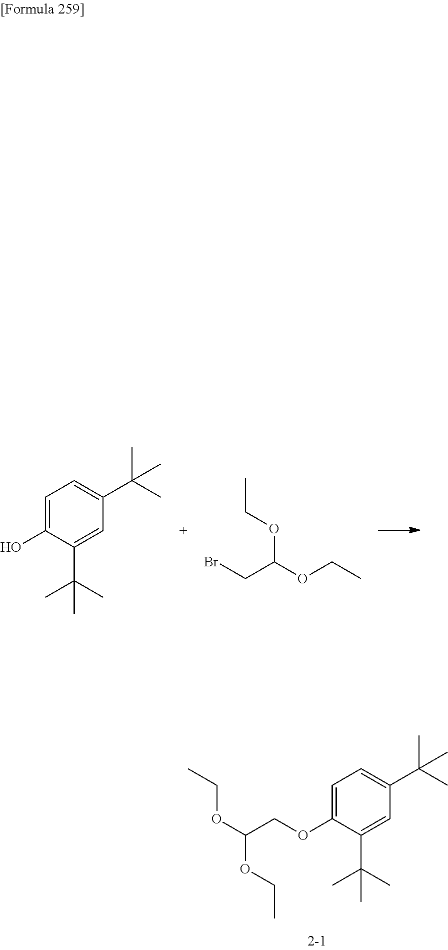

### Production of Intermediate 2-1

A mixture of 2,4-di-tert-butylphenol (10.5 g, 50.88 mmol), bromoacetaldehyde diethyl acetal (17.2 g, 101.7 mmol) and potassium carbonate (21.2 g, 152.6 mmol) was heated in 500 mL of dimethylformamide (DMF) at 150 degrees C. for 30 hours. The reactant was cooled to the room temperature and diluted with diethyl ether/water/saturated saline solution. The layers were separated and the aqueous layer was further extracted with diethyl ether. The organic extracts were washed with water and saturated saline solution, dried over sodium sulfate, filtered and evaporated. The filtrate was concentrated and the residue was purified by silica gel column chromatography using hexane/ethyl acetate as an eluent to obtain an intermediate 2-1 (13.16 g, a yield of 75%) as a highly viscous purified product.

¹H NMR (400 MHz, CDCl₃) δ 7.32 (s, 1H), 7.16-7.15 (m, 1H), 6.77-6.75 (m, 1H), 4.94-4.92 (m, 1H), 4.01-3.99 (m, 2H), 3.79-3.74 (m, 2H), 3.67-3.62 (m, 2H), 1.42 (s, 9H), 1.30 (s, 9H), 1.26-1.23 (s, 6H) ppm.

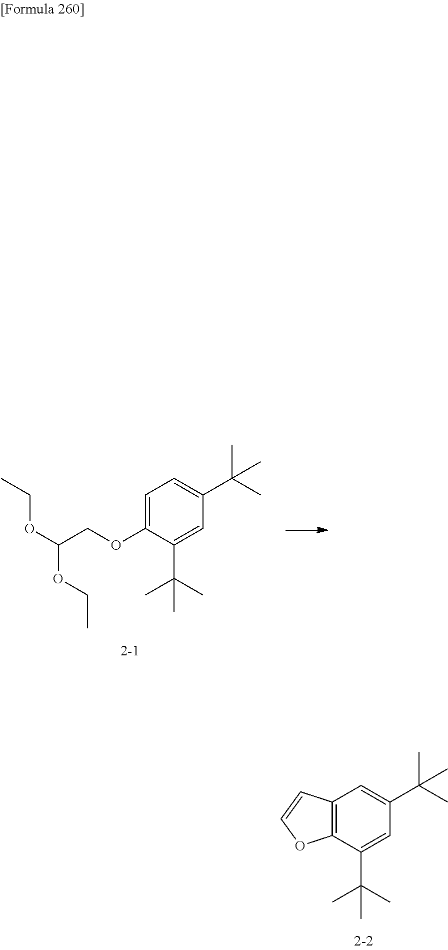 [SMILES: CCOC(COc1ccc(C(C)(C)C)cc1C(C)(C)C)OCC ; CC(C)(C)c1cc(C(C)(C)C)c2occc2c1]

### Production of Intermediate 2-2

14.4 g of polyphosphoric acid was added to a solution of the intermediate 2-1 (25.12 g, 74.0 mmol) in 260 mL of toluene, and the reaction mixture was stirred at 110 degrees C. for 18 hours. The toluene layer was separated and the resultant residue was added to 150 mL of toluene and separated again. The obtained organic layer was evaporated and the residue was purified by silica gel column chromatography using hexane as an eluent to obtain an intermediate 2-2 (16.98 g, a yield of 99%) as a colorless oily product.

¹H NMR (400 MHz, CDCl₃) δ 7.60-7.59 (m, 1H), 7.45-7.44 (m, 1H), 7.26-7.24 (m, 1H), 6.71 (s, 1H), 1.50 (s, 9H), 1.34 (s, 9H) ppm.

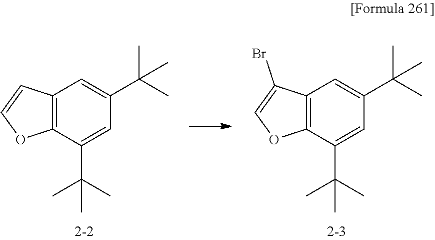 [SMILES: CC(C)(C)c1cc(C(C)(C)C)c2occc2c1 ; CC(C)(C)c1cc(C(C)(C)C)c2occ(Br)c2c1]

### Production of Intermediate 2-3

A solution of the intermediate 2-2 (6.91 g, 30.0 mmol) in 50 mL of dichloromethane was cooled to −10 degrees C., then to which a solution of bromine (1.54 mL, 30.0 mmol) in 25 mL of dichloromethane was added dropwise over 10 minutes. The reactant was stirred at −10 degrees C. for one hour. The reaction was quenched by adding 6 mL of 1 N sodium hydroxide, followed by 120 mL of 5% sodium sulfate, and 50 mL of dichloromethane. The layers were separated and the aqueous layer was extracted with 40 mL of dichloromethane. The organic extracts obtained were washed with water and saturated saline solution, dried over sodium sulfate, filtered and evaporated to obtain 13.6 g of a brown oily product. This oil was dissolved in 10 mL of dichloromethane and 100 mL of ethanol and added dropwise at 15 degrees C. to a cooled solution of potassium hydroxide (2.28 g, 35 mmol) in 70 mL of ethanol. A temperature of the suspension was raised to the room temperature, where the suspension was stirred for 2.5 hours. The reaction was quenched by adding 150 mL of saturated saline solution and 100 mL of tert-butyl methyl ether. The layers were separated and the aqueous layer was further extracted with tertbutyl methyl ether. The organic layer obtained was washed with water and saturated saline solution, dried over sodium sulfate, filtered and evaporated. The residue was purified by silica gel column chromatography using heptane as an eluent to obtain an intermediate 2-3 (6.19 g, a yield of 57%) as a colorless oily product.

¹H NMR (300 MHz, CDCl₃) δ 7.67 (s, 1H), 7.42-7.41 (m, 1H), 7.38-7.36 (m, 1H), 1.54 (s, 9H), 1.44 (s, 9H) ppm.

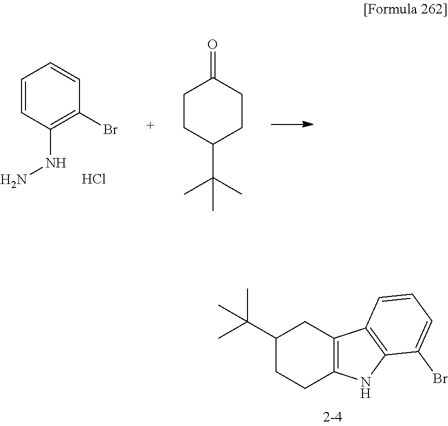 [SMILES: NNc1ccccc1Br ; Cl ; CC(C)(C)C1CCC(=O)CC1 ; CC(C)(C)C1CCc2[nH]c3c(Br)cccc3c2C1]

### Production of Intermediate 2-4

(2-bromophenyl)hydrazine hydrochloride (55.9 g, 250.0 mmol) was slowly added to a solution of 4-(tert-butyl)cyclohexan-1-on (38.6 g, 250.0 mmol) in 500 mL of acetic acid. The suspension was heated at 100 degrees C. for 2.5 hours. The resultant was cooled to the room temperature and the solvent was evaporated. The residue was dissolved in 250 mL of toluene and washed with 250 mL of water. The aqueous layer was extracted with toluene and the organic layer obtained was washed with water and saturated saline solution, dried over sodium sulfate, filtered and evaporated to obtain an intermediate 2-4 (74.67 g, a yield of 98%) of a brown highly viscous purified product. ESI-MS:306.3[M+H]⁺

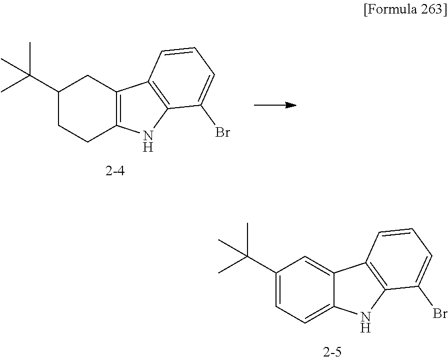 [SMILES: CC(C)(C)C1CCc2[nH]c3c(Br)cccc3c2C1 ; CC(C)(C)c1ccc2[nH]c3c(Br)cccc3c2c1]

### Production of Intermediate 2-5

4,5-dichloro-3,6-dioxocyclohexa-1,4-diene-1,2-dicarbonitrile (98 g, 430.0 mmol) was gradually added to the intermediate 2-4 in 400 mL of toluene in a cooling water bath (65.8 g, 215.0 mmol) over 15 minutes. The reactant was stirred at the room temperature for 3.5 hours. The reactant was filtered and the obtained solid was rinsed with a large amount of toluene. The filtrate was washed with water and saturated saline solution, dried over sodium sulfate, filtered and evaporated. The residue was purified by silica gel column chromatography using heptane/toluene as an eluent to obtain an intermediate 2-5 (46.82 g, a yield of 78%) as a beige solid. ESI-MS:300.2[M−H]⁺

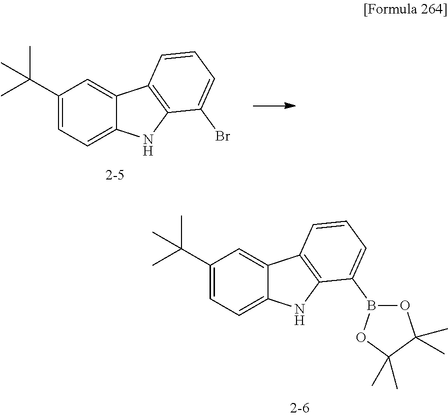 [SMILES: CC(C)(C)c1ccc2[nH]c3c(Br)cccc3c2c1 ; CC(C)(C)c1ccc2[nH]c3c(B4OC(C)(C)C(C)(C)O4)cccc3c2c1]

### Production of Intermediate 2-6

The intermediate 2-5 (36.9 g, 122.0 mmol), bis(pinacolato)diboron (37.2 g, 146.0 mmol), and potassium acetate (29.9 g, 305.0 mmol) were suspended in 400 mL of anhydrous N,N-dimethylformamide. The reaction container was evacuated under high vacuum and purged with argon, thereby degassing the suspension. A complex of [1,1′-bis(diphenylphosphino)ferrocene-palladium(II) (4.98 g, 5 mol %) with dichloromethane was added to the reaction mixture. Subsequently, the obtained reaction mixture was degassed and purged with argon, which was repeated twice. The reaction mixture was heated to 90 degrees C. for 5.5 hours. After being cooled to the room temperature, the reactant was evaporated and the residue was dissolved in toluene and washed with water. The aqueous layer was further extracted with toluene. The organic layer obtained was washed with water and saturated saline solution, dried over sodium sulfate, filtered and evaporated. The residue was recrystallized from 250 mL of acetonitrile to obtain an intermediate 2-6 (37.77 g, a yield of 89%) as a beige solid.

¹H NMR (300 MHz, DMSO-d₆) δ 10.19 (broad, 1H), 8.30-8.27 (m, 1H), 8.11 (s, 1H), 7.70-7.65 (m, 2H), 7.50-7.47 (m, 1H), 7.18-7.13 (m, 1H), 1.41-1.42 (m, 21H) ppm.

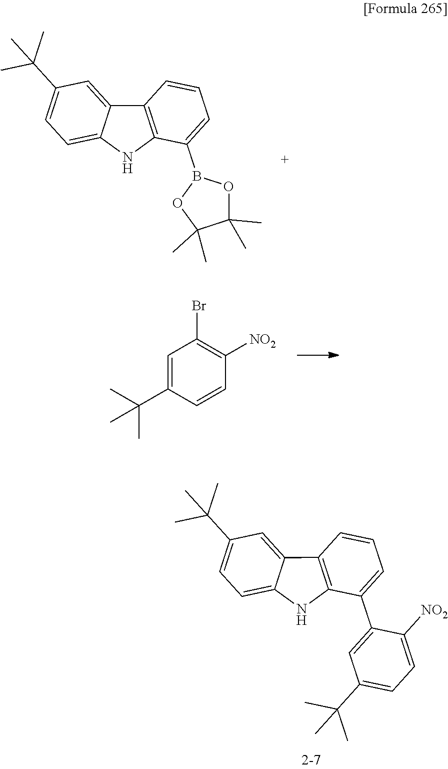

### Production of Intermediate 2-7

The intermediate 2-6 (29.7 g, 85.0 mmol), 2-bromo-4-(tert-butyl)-1-nitrobenzene (21.94 g, 85.0 mmol), and sodium hydroxide (6.80 g, 170.0 mmol) were suspended in tetrahydrofuran/water (250/125 (mL)). The suspension was degassed with Ar and tetrakis(triphenylphosphine)palladium(0) (1.47 g, 1.5 mol %) was added to the reaction mixture. The reaction mixture was refluxed for two hours. The reactant was cooled to the room temperature and diluted with toluene/water. The layers were separated and the aqueous layer was further extracted with toluene. The organic extracts were washed with water and saturated saline solution, dried over sodium sulfate, filtered and evaporated. The residue was purified by silica gel column chromatography using heptane/toluene as an eluent to obtain an intermediate 2-7 (33.52 g, a yield of 98%) as an orange solid.

ESI-MS:399.4[M−H]⁺

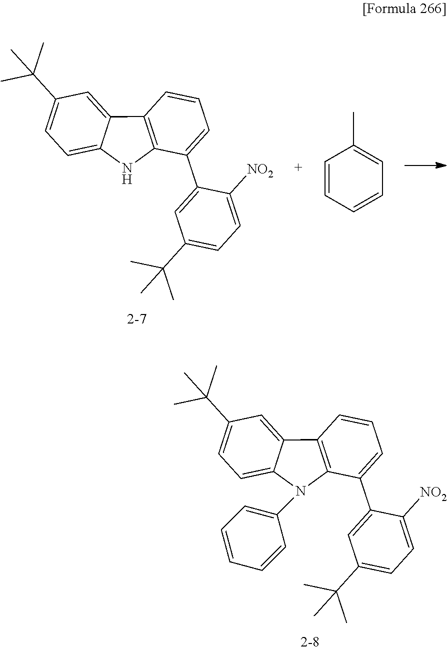

### Production of Intermediate 2-8

The intermediate 2-7 (33.6 g, 84.0 mmol), 56.54 mL (504.0 mmol) of iodobenzene, potassium carbonate (34.8 g, 252.0 mmol), and copper (2.67 g, 42 mmol) were suspended in 250 mL of nitrobenzene. The suspension was degassed with Ar and then heated at 200 degrees C. for six hours. The reactant was cooled to the room temperature, diluted with toluene, filtered through cerite and silica, and rinsed with toluene. The crude solid was recrystallized from isopropanol/diisopropyl ether (250 mL, 4:1) to obtain an intermediate 2-8 (36.9 g, 92% of yield) as a yellow solid.

ESI-MS:477.4[M+H]⁺

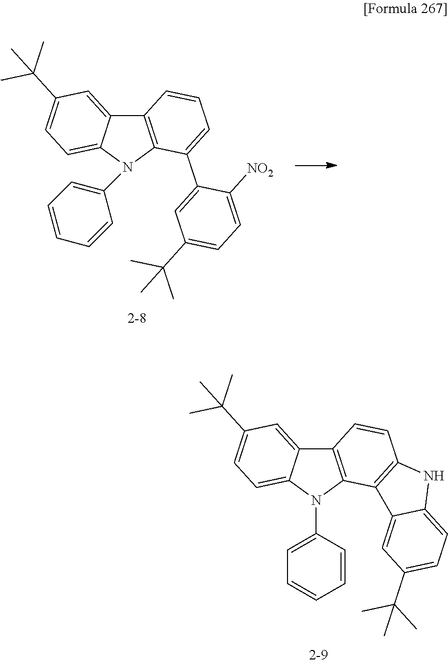 [SMILES: CC(C)(C)c1ccc([N+](=O)[O-])c(-c2cccc3c4cc(C(C)(C)C)ccc4n(-c4ccccc4)c23)c1 ; CC(C)(C)c1ccc2[nH]c3ccc4c5cc(C(C)(C)C)ccc5n(-c5ccccc5)c4c3c2c1]

### Production of Intermediate 2-9

The intermediate 2-8 (35.7 g, 75.0 mmol) and triphenylphosphine (197 g, 750.0 mmol) were combined and the solid mixture was heated at 200 degrees C. for two hours. After the mixture was cooled to the room temperature, the residue was purified by silica gel column chromatography using heptane/toluene as an eluent to obtain an intermediate 2-9 (25.15 g, a yield of 75%) as a white solid.

ESI-MS:443.5[M−H]⁺

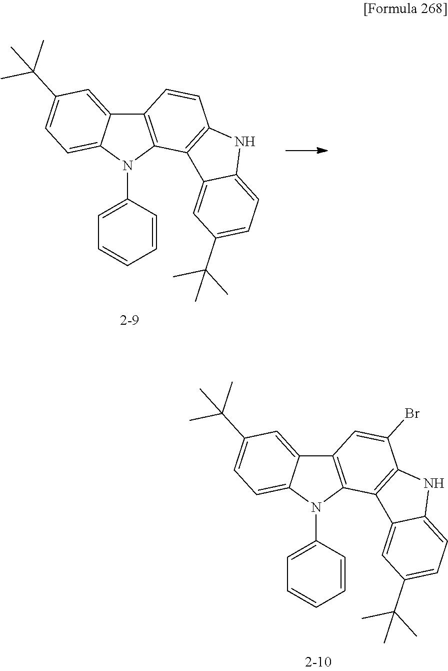 [SMILES: CC(C)(C)c1ccc2[nH]c3ccc4c5cc(C(C)(C)C)ccc5n(-c5ccccc5)c4c3c2c1 ; CC(C)(C)c1ccc2[nH]c3c(Br)cc4c5cc(C(C)(C)C)ccc5n(-c5ccccc5)c4c3c2c1]

### Production of Intermediate 2-10

The intermediate 2-9 (13.34 g, 30.0 mmol) was dissolved in 50 mL of dimethylformamide and 100 mL of chloroform. The clear yellow solution was cooled to 0 degrees C., to which N-bromosuccinimide (5.34 g, 30.0 mmol) was gradually added over 20 minutes. A temperature of the reactant was raised to the room temperature, where the reactant was stirred for 30 minutes. After the reaction mixture was evaporated, the residue was purified by silica gel column chromatography using heptane/toluene as an eluent to obtain an intermediate 2-10 (14.66 g, a yield of 93%) as a white solid.

ESI-MS:523.4[M−H]⁺

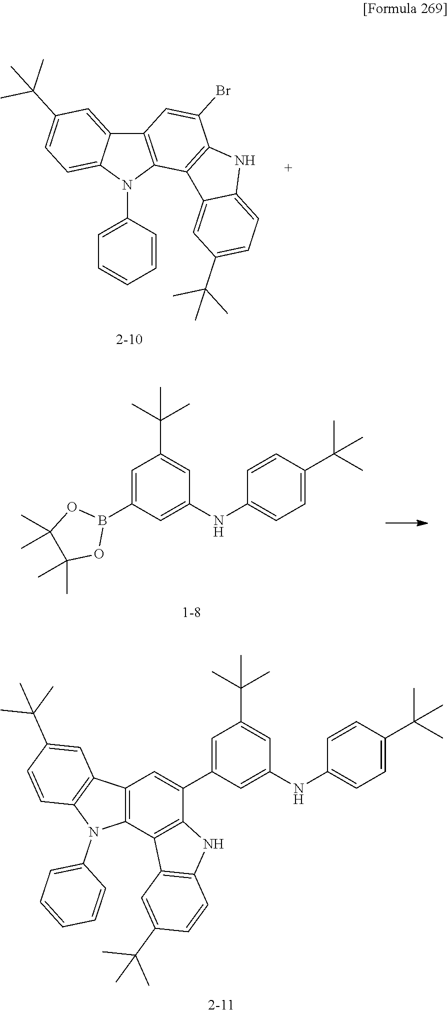

### Production of Intermediate 2-11

The intermediate 2-10 (6.81 g, 13.0 mmol), the intermediate 1-8 (5.40 g, 13.26 mmol), and sodium hydroxide (1.04 g, 26.0 mmol) were suspended in a mixture of tetrahydrofuran/water (70/35 (mL)). The suspension was degassed with Ar and tetrakis(triphenylphosphine)palladium(0) (451 mg, 3 mol %) was added to the reaction mixture. The reaction mixture was refluxed for 8 hours. The reactant was cooled to the room temperature and diluted with toluene/water. After filtration, the layers were separated, and the aqueous layer was further extracted with toluene. The organic extracts were washed with water and saturated saline solution, dried over sodium sulfate, filtered and evaporated. The residue was purified by silica gel column chromatography using heptane/toluene as an eluent to obtain an intermediate 2-11 (8.8 g, a yield of 93%) as a white solid.

ESI-MS:724.6[M+H]⁺

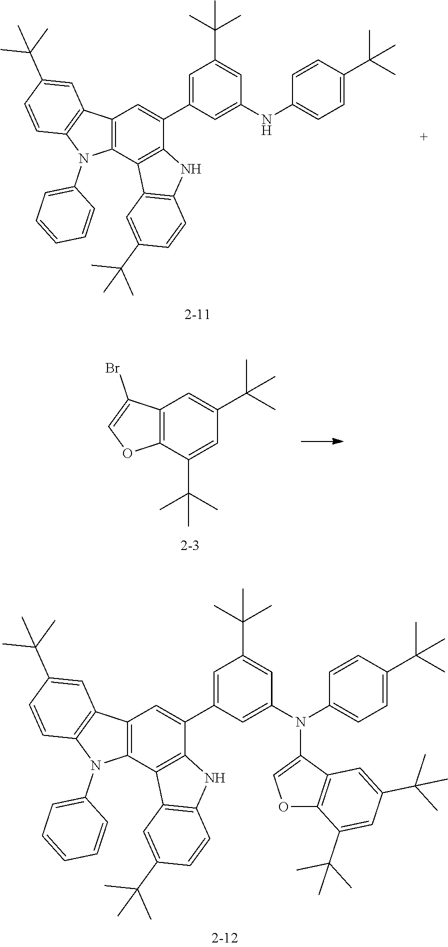

### Production of Intermediate 2-12

The intermediate 2-11 (4.34 g, 6.00 mmol), the intermediate 2-3 (2.13 g, 6.90 mmol), and sodium tert-butoxide (1.44 g, 15.0 mmol) were suspended in 45 mL of toluene. After the suspension was degassed with Ar, tris(dibenzylideneacetone)dipalladium(0) (165 mg, 3 mol %) and tri-tert-butylphosphonium tetrafluoroborate (209 mg, 12 mol %) were added to the mixture. The reaction mixture was stirred at 75 degrees C. for two hours. The reactant was cooled to the room temperature and diluted with toluene/water. The layers were separated and the aqueous layer was further extracted with toluene. The organic extracts were washed with water and saturated saline solution, dried over sodium sulfate, filtered and evaporated. The filtrate was concentrated and the residue was purified by silica gel column chromatography using heptane/toluene as an eluent to obtain an intermediate 2-12 (4.67 g, a yield of 81%) as a white solid.

ESI-MS:952.7[M+H]⁺

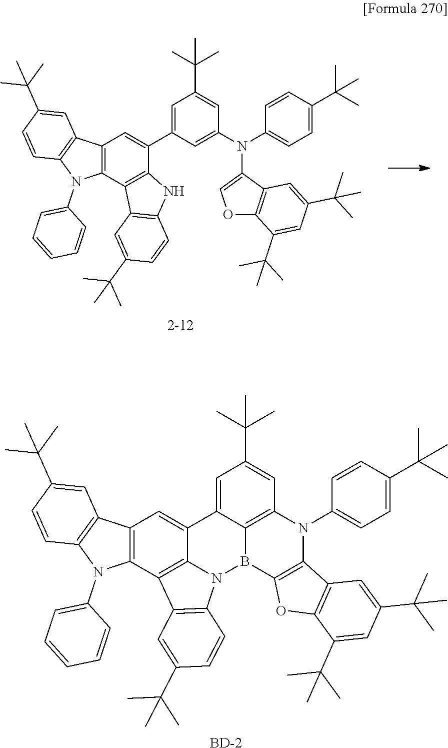

### Production of Compound BD-2

The intermediate 2-12 (4.57 g, 4.80 mmol) was dissolved in 45 mL of tert-butylbenzene, which was degassed with Ar. N-butyllithium (4.03 mL, 10.08 mmol) (2.5 M solution in hexane) was added dropwise and then the reaction mixture was stirred for 1.5 hours. Next, tribromoborane (0.91 mL, 9.60 mmol) was added dropwise at 0 degrees C. The reaction mixture was stirred at 160 degrees C. for five hours. The reactant was cooled to the room temperature and diluted with isopropanol/water. The precipitate was filtered and rinsed with isopropanol/water to obtain the compound BD-2 (2.08 g, a yield of 45%) as a yellow solid.

ESI-MS:960.7[M+H]⁺

### Synthesis of Compound BD-3

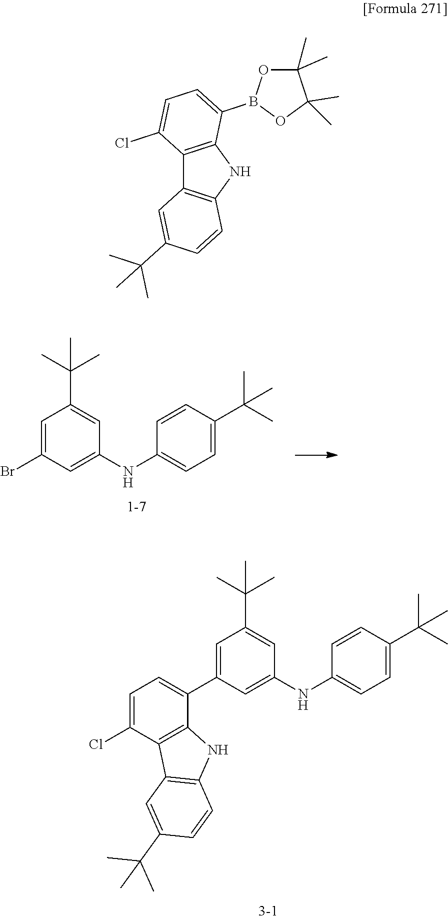 [SMILES: CC(C)(C)c1ccc2[nH]c3c(B4OC(C)(C)C(C)(C)O4)ccc(Cl)c3c2c1 ; CC(C)(C)c1ccc(Nc2cc(Br)cc(C(C)(C)C)c2)cc1 ; CC(C)(C)c1ccc(Nc2cc(-c3ccc(Cl)c4c3[nH]c3ccc(C(C)(C)C)cc34)cc(C(C)(C)C)c2)cc1]

### Production of Intermediate 3-1

6-(tert-butyl)-4-chloro-1-(4,4,5,5-tetramethyl-1,3,2-dioxaborolan-2-yl)-9H-carbazole (CAS:2567994-26-5) (4.76 g, 12.4 mmol), the intermediate 1-7 (4.47 g, 12.4 mmol) and sodium hydroxide (0.992 g, 24.8 mmol) were suspended in a mixture of tetrahydrofuran/water (100/50 (mL)). The suspension was degassed with Ar and tetrakis(triphenylphosphine)palladium(0) (358 mg, 2.5 mol %) was added to the reaction mixture. The reaction mixture was refluxed for four hours. The reactant was cooled to the room temperature and diluted with ethyl acetate/water. The layers were separated and the aqueous layer was further extracted with ethyl acetate. The organic extracts were washed with water and saturated saline solution, dried over sodium sulfate, filtered and evaporated. The residue was dissolved in ethanol and concentrated until a precipitate was formed. The suspension was stirred for 10 minutes and filtered to obtain an intermediate 3-1 (4.95 g, a yield of 74%) as a white solid.

ESI-MS:537.3[M+H]⁺

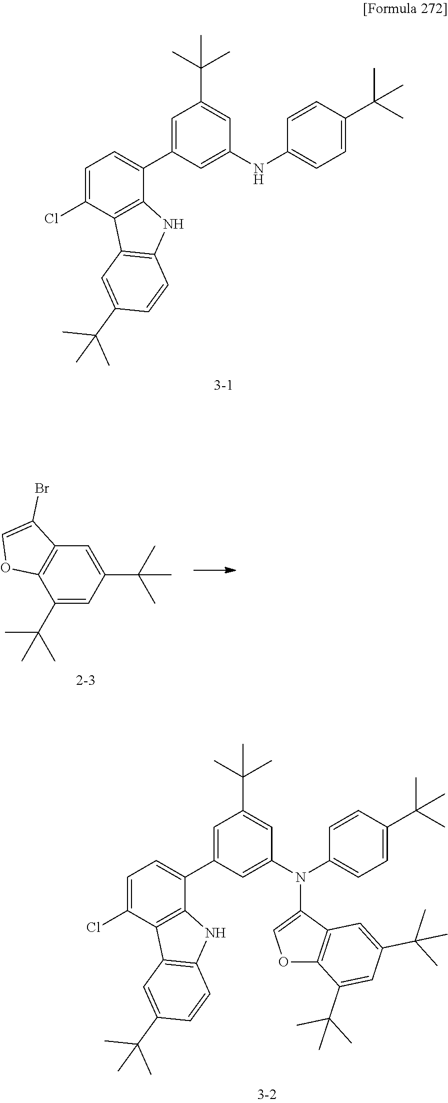 [SMILES: CC(C)(C)c1ccc(Nc2cc(-c3ccc(Cl)c4c3[nH]c3ccc(C(C)(C)C)cc34)cc(C(C)(C)C)c2)cc1 ; CC(C)(C)c1cc(C(C)(C)C)c2occ(Br)c2c1 ; CC(C)(C)c1ccc(N(c2cc(-c3ccc(Cl)c4c3[nH]c3ccc(C(C)(C)C)cc34)cc(C(C)(C)C)c2)c2coc3c(C(C)(C)C)cc(C(C)(C)C)cc23)cc1]

### Production of Intermediate 3-2

The intermediate 3-1 (3.60 g, 6.70 mmol), the intermediate 2-3 (2.38 g, 7.71 mmol), and 1.61 g (16.8 mmol) of sodium tert-butoxide were suspended in 50 mL of toluene. After the suspension was degassed with Ar, tris(dibenzylideneacetone)dipalladium(0) (184 mg, 3 mol %) and tri-tert-butylphosphonium tetrafluoroborate (233 mg, 12 mol %) were added to the mixture. The reaction mixture was stirred at 65 degrees C. for two hours. The reactant was cooled to the room temperature and diluted with toluene/water. The layers were separated and the aqueous layer was further extracted with toluene. The organic extracts were washed with water and saturated saline solution, dried over sodium sulfate, filtered and evaporated. The filtrate was concentrated and the residue was purified by silica gel column chromatography using heptane/dichloromethane as an eluent to obtain an intermediate 3-2 (3.94 g, a yield of 75%) as a white solid. ESI-MS:764.6[M+H]⁺

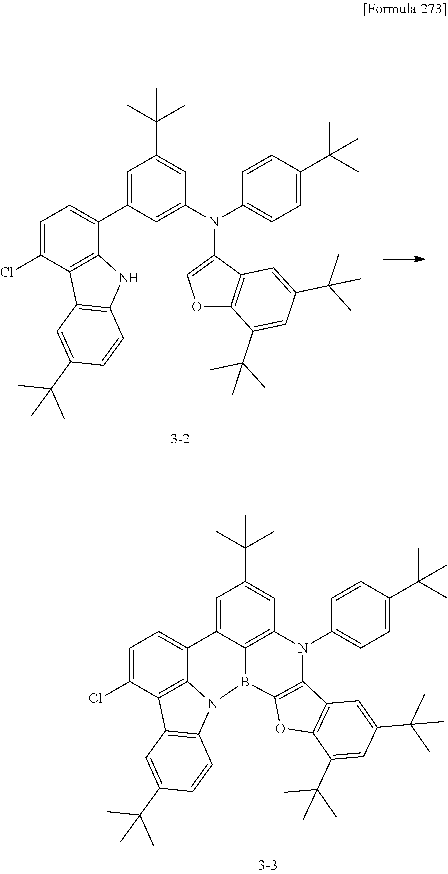 [SMILES: CC(C)(C)c1ccc(N(c2cc(-c3ccc(Cl)c4c3[nH]c3ccc(C(C)(C)C)cc34)cc(C(C)(C)C)c2)c2coc3c(C(C)(C)C)cc(C(C)(C)C)cc23)cc1 ; CC(C)(C)c1ccc(N2c3cc(C(C)(C)C)cc4c3B(c3oc5c(C(C)(C)C)cc(C(C)(C)C)cc5c32)n2c3ccc(C(C)(C)C)cc3c3c(Cl)ccc-4c32)cc1]

### Production of Intermediate 3-3

The intermediate 3-2 (3.42 g, 4.47 mmol) was dissolved in 200 mL of tert-butylbenzene, degassed with Ar, and cooled to 0 degrees C. Butyllithium (3.95 mL, 9.88 mmol) (2.5 M solution in pentane) was added dropwise, then a temperature of the reactant was raised to the room temperature, and the reactant was stirred for two hours. Next, tribromoborane (0.93 mL, 9.87 mmol) was added dropwise at −20 degrees C. The reactant was heated at 150 degrees C. for two hours. The reactant was cooled to the room temperature. The reaction was quenched with saturated sodium bicarbonate solution. The layers were separated and the aqueous layer was further extracted with ethyl acetate. The organic extracts were washed with water and saturated saline solution, dried over sodium sulfate, and filtered. The filtrate was concentrated and the residue was purified by silica gel column chromatography using heptane/dichloromethane as an eluent to obtain an intermediate 3-3 (1.13 g, a yield of 32%) as a yellow solid.

ESI-MS:773.6[M+H]⁺

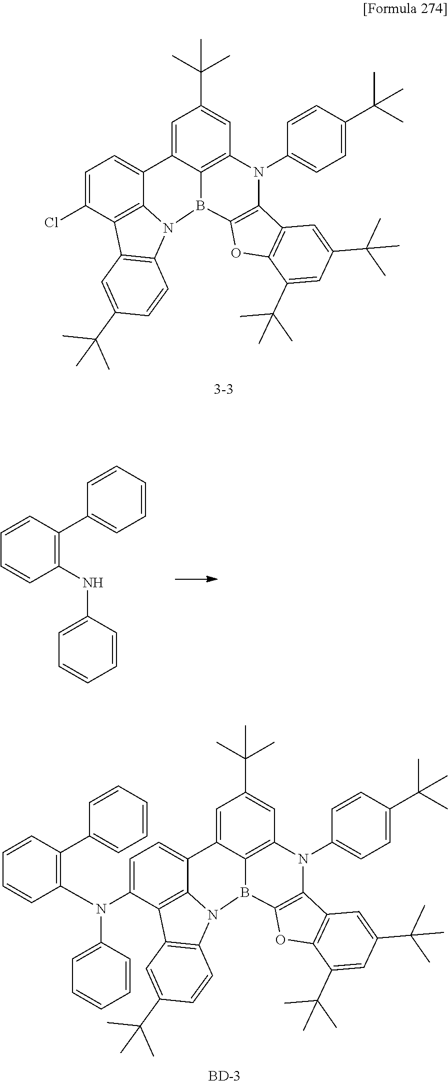 [SMILES: CC(C)(C)c1ccc(N2c3cc(C(C)(C)C)cc4c3B(c3oc5c(C(C)(C)C)cc(C(C)(C)C)cc5c32)n2c3ccc(C(C)(C)C)cc3c3c(Cl)ccc-4c32)cc1 ; c1ccc(Nc2ccccc2-c2ccccc2)cc1 ; CC(C)(C)c1ccc(N2c3cc(C(C)(C)C)cc4c3B(c3oc5c(C(C)(C)C)cc(C(C)(C)C)cc5c32)n2c3ccc(C(C)(C)C)cc3c3c(N(c5ccccc5)c5ccccc5-c5ccccc5)ccc-4c32)cc1 ; "BD-3"]

### Production of Compound BD-3

The intermediate 3-3 (0.625 g, 0.808 mmol) and N-phenyl-[1,1′-biphenyl]-2-amine (0.297 g, 1.21 mmol) were suspended in 25 mL of toluene. After the suspension was degassed with Ar, tris(dibenzylideneacetone)dipalladium(0) (15 mg, 2 mol %) and 2-dicyclohexylphosphino-2′,4′,6′-triisopropylbiphenyl (31 mg, 8 mol %) were added to the mixture. The reaction mixture was stirred at 45 degrees C. and lithium bis(trimethylsilyl)amide (1.21 mL, 1.21 mmol) (1M solution in toluene) was added. The reactant was stirred at 50 degrees C. for two hours. The reactant was cooled to the room temperature. The reaction was quenched with saturated ammonium chloride solution. The layers were separated and the aqueous layer was further extracted with ethyl acetate. The organic extracts were washed with water and saturated saline solution, dried over sodium sulfate, and filtered. The filtrate was concentrated and the residue was purified by silica gel column chromatography using heptane/dichloromethane as an eluent. The product was further purified by precipitation in acetone to obtain the compound BD-3 (0.45 g, a yield of 56%) as a yellow solid.

ESI-MS:1026.8[M+H]⁺

### EXPLANATION OF CODES

1, 1A, 1B . . . organic EL device, 2 . . . substrate, 3 . . . anode, 4 . . . cathode, 5 . . . emitting layer, 6 . . . hole injecting layer, 7 . . . hole transporting layer, 8 . . . electron transporting layer, 9 . . . electron injecting layer, 67 . . . first organic layer, 89 . . . second organic layer

1. A compound represented by a formula (1) below, 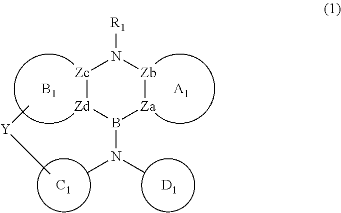
where, in the formula (1):
a ring A₁, a ring B₁, a ring C₁, and a ring D₁ are each independently a substituted or unsubstituted ring having 5 to 60 ring atoms;
Za and Zb are each an atom forming the ring A₁;
Zc and Zd are each an atom forming the ring B₁;
Za, Zb, Zc, and Zd are each independently a nitrogen atom or a carbon atom;
the ring C₁ and the ring D₁ are mutually bonded to form a substituted or unsubstituted monocyclic ring, mutually bonded to form a substituted or unsubstituted fused ring, or not mutually bonded;
R₁ is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆);
when R₁ is a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms, R₁ is bonded with the ring A₁ to form a substituted or unsubstituted monocyclic ring, bonded with the ring A₁ to form a substituted or unsubstituted fused ring, or not bonded with the ring A₁, or bonded with the ring B₁ to form a substituted or unsubstituted monocyclic ring, bonded with the ring B₁ to form a substituted or unsubstituted fused ring, or not bonded with the ring B₁;
at least one of R₁, the ring A₁, the ring B₁, the ring C₁, or the ring D₁ has a group represented by —N(R_{1A})(R_{2A}) as a substituent;
a combination of R_{1A} and R_{2A} are mutually bonded to form a substituted or unsubstituted monocyclic ring, mutually bonded to form a substituted or unsubstituted fused ring, or not mutually bonded;
when R₁ has a group represented by —N(R_{1A})(R_{2A}) as a substituent, R_{1A} and R_{2A} are each independently bonded with R₁ to form a substituted or unsubstituted monocyclic ring, bonded with R₁ to form a substituted or unsubstituted fused ring, or not bonded with R₁;
when the ring A₁ has a group represented by —N(R_{1A})(R_{2A}) as a substituent, R_{1A} and R_{2A} are each independently bonded with the ring A₁ to form a substituted or unsubstituted monocyclic ring, bonded with the ring A₁ to form a substituted or unsubstituted fused ring, or not bonded with the ring A₁;
when the ring B₁ has a group represented by —N(R_{1A})(R_{2A}) as a substituent, R_{1A} and R_{2A} are each independently bonded with the ring B₁ to form a substituted or unsubstituted monocyclic ring, bonded with the ring B₁ to form a substituted or unsubstituted fused ring, or not bonded with the ring B₁;
when the ring C₁ has a group represented by —N(R_{1A})(R_{2A}) as a substituent, R_{1A} and R_{2A} are each independently bonded with the ring C₁ to form a substituted or unsubstituted monocyclic ring, bonded with the ring C₁ to form a substituted or unsubstituted fused ring, or not bonded with the ring C₁;
when the ring D₁ has a group represented by —N(R_{1A})(R_{2A}) as a substituent, R_{1A} and R_{2A} are each independently bonded with the ring D₁ to form a substituted or unsubstituted monocyclic ring, bonded with the ring D₁ to form a substituted or unsubstituted fused ring, or not bonded with the ring D₁;
R_{1A} and R_{2A} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one of a monocyclic ring having a bond between Za and Zb in the ring A₁, or a monocyclic ring closest to a bond between a boron atom and a nitrogen atom in the ring C₁ is a substituted or unsubstituted monocyclic ring having 5 ring atoms;
Y is a single bond bonding an atom forming the ring B₁ and an atom forming the ring C₁, an oxygen atom, a sulfur atom, NR_{21A}, CR_{22A}R_{23A}, or SiR_{24A}R_{25A};
a combination of R_{22A} and R_{23A} are mutually bonded to form a substituted or unsubstituted monocyclic ring, mutually bonded to form a substituted or unsubstituted fused ring, or not mutually bonded;
a combination of R_{24A} and R_{25A} are mutually bonded to form a substituted or unsubstituted monocyclic ring, mutually bonded to form a substituted or unsubstituted fused ring, or not mutually bonded;
R_{21A}, and R_{22A}, R_{23A}, R_{24A} and R_{25A} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when R₁, the ring A₁, the ring B₁, the ring C₁, and the ring D₁ have substituents, the substituents are each independently a group represented by —N(R_{1A})(R_{2A}), a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₁₃₃)(R₁₃₄)(R₁₃₅), a group represented by —O—(R₁₃₆), a group represented by —S—(R₁₃₇), a substituted or unsubstituted aralkyl group having 7 to 50 carbon atoms, a group represented by —C(═O)R₁₃₈, a group represented by —COOR₁₃₉, a halogen atom, a cyano group, a nitro group, a group represented by —P(═O)(R₁₄₀)(R₁₄₁), a group represented by —Ge(R₁₄₂)(R₁₄₃)(R₁₄₄), a group represented by —B(R₁₄₅)(R₁₄₆), a substituted or unsubstituted aryl group having 6 to 50 ring carbon atoms, or a substituted or unsubstituted heterocyclic group having 5 to 50 ring atoms;
R₁₃₃ to R₁₄₆ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{1A} are present, the plurality of R_{1A} are mutually the same or different;
when a plurality of R_{2A} are present, the plurality of R_{2A} are mutually the same or different;
when a plurality of R₁₃₃ are present, the plurality of R₁₃₃ are mutually the same or different;
when a plurality of R₁₃₄ are present, the plurality of R₁₃₄ are mutually the same or different;
when a plurality of R₁₃₅ are present, the plurality of R₁₃₅ are mutually the same or different;
when a plurality of R₁₃₆ are present, the plurality of R₁₃₆ are mutually the same or different;
when a plurality of R₁₃₇ are present, the plurality of R₁₃₇ are mutually the same or different;
when a plurality of R₁₃₈ are present, the plurality of R₁₃₈ are mutually the same or different;
when a plurality of R₁₃₉ are present, the plurality of R₁₃₉ are mutually the same or different;
when a plurality of R₁₄₀ are present, the plurality of R₁₄₀ are mutually the same or different;
when a plurality of R₁₄₁ are present, the plurality of R₁₄₁ are mutually the same or different;
when a plurality of R₁₄₂ are present, the plurality of R₁₄₂ are mutually the same or different;
when a plurality of R₁₄₃ are present, the plurality of R₁₄₃ are mutually the same or different;
when a plurality of R₁₄₄ are present, the plurality of R₁₄₄ are mutually the same or different;
when a plurality of R₁₄₅ are present, the plurality of R₁₄₅ are mutually the same or different; and
when a plurality of R₁₄₆ are present, the plurality of R₁₄₆ are mutually the same or different.

2. The compound according to claim 1, wherein
the compound represented by the formula (1) is represented by a formula (11) below, 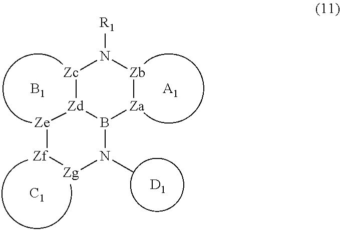
where, in the formula (11):
R₁, a ring A₁, a ring B₁, a ring C₁, a ring D₁, Za, Zb, Zc, and Zd each independently represent the same as R₁, the ring A₁, the ring B₁, the ring C₁, the ring D₁, Za, Zb, Zc, and Zd in the formula (1);
Zc, Zd, and Ze are each an atom forming the ring B₁;
Zf and Zg are each an atom forming the ring C₁; and
Ze, Zf, and Zg are each independently a nitrogen atom or a carbon atom.

3. The compound according to claim 2, wherein Ze, Zf, and Zg are each a carbon atom.

4. The compound according to claim 1, wherein Za, Zb, Zc, Zd, Ze, Zf, and Zg are each a carbon atom.

5. The compound according to claim 1, wherein the ring A₁, the ring B₁, the ring C₁, and the ring D₁ in a form of a substituted or unsubstituted ring having 5 to 60 ring atoms are each independently a substituted or unsubstituted aryl ring having 6 to 60 ring carbon atoms, a substituted or unsubstituted heterocycle having 5 to 60 ring atoms, or a substituted or unsubstituted alicyclic hydrocarbon ring having 5 to 60 ring atoms.

6. The compound according to claim 1, wherein when R₁, the ring A₁, the ring B₁, the ring C₁, and the ring D₁ have substituents, the substituents are each independently a group represented by —N(R_{1A})(R_{2A}), a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, —CN, or a group represented by —O—(R₁₃₆).

7. The compound according to claim 1, wherein
the compound represented by the formula (1) is represented by a formula (12) or (13) below, 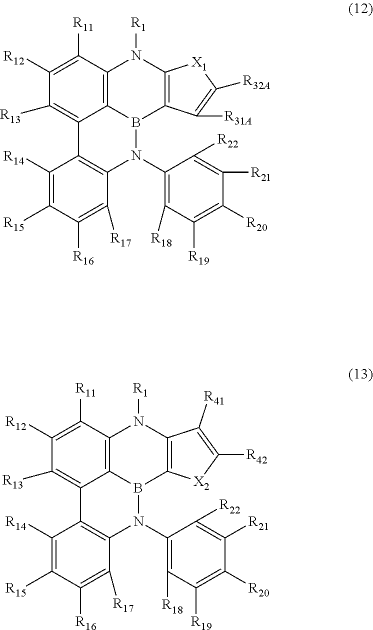
where, in the formulae (12) and (13):
R₁ represents the same as R₁ in the formula (1);
X₁ and X₂ are each independently an oxygen atom, a sulfur atom, NRx, or C(Rx₁)(Rx₂);
at least one combination of adjacent two or more of R₁, R₁₁ to R₁₃, R_{31A} to R_{32A}, Rx, Rx₁, and Rx₂ are mutually bonded to form a substituted or unsubstituted monocyclic ring, mutually bonded to form a substituted or unsubstituted fused ring, or not mutually bonded;
at least one combination of adjacent two or more of R₁, R₁₁ to R₁₃, R₄₁ to R₄₂, Rx, Rx₁, and Rx₂ are mutually bonded to form a substituted or unsubstituted monocyclic ring, mutually bonded to form a substituted or unsubstituted fused ring, or not mutually bonded;
at least one combination of adjacent two or more of R₁₄ to R₂₂ are mutually bonded to form a substituted or unsubstituted monocyclic ring, mutually bonded to form a substituted or unsubstituted fused ring, or not mutually bonded;
R₁₁ to R₂₂, R_{31A} to R_{32A}, and R₄₁ to R₄₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆); and
Rx, Rx₁, and Rx₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

8. The compound according to claim 7, wherein
the compound represented by the formula (12) is represented by a formula (121) below and the compound represented by the formula (13) is represented by a formula (131) below, 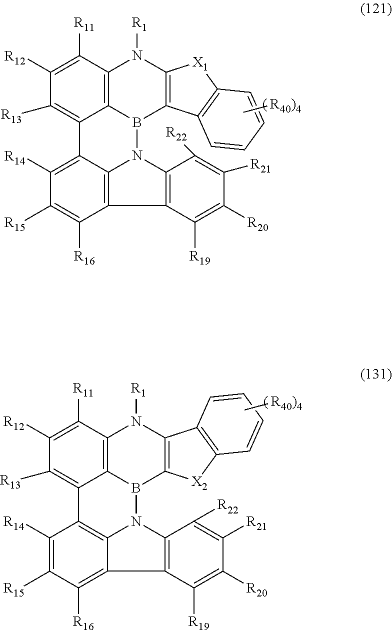
where, in the formulae (121) and (131):
R₁, R₁ to R₁₆, R₁₉ to R₂₂, X₁, and X₂ each independently represent the same as R₁, R₁₁ to R₁₆, R₁₉ to R₂₂, X₁, and X₂ in the formulae (12) and (13);
at least one combination of adjacent two or more of R₁, R₁ to R₁₃, R₄₀, Rx, Rx₁, and Rx₂ are mutually bonded to form a substituted or unsubstituted monocyclic ring, mutually bonded to form a substituted or unsubstituted fused ring, or not mutually bonded;
a plurality of R₄₀ are mutually the same or different; and
R₄₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (12) and (13).

9. The compound according to claim 7, wherein
R₁ is a substituted or unsubstituted aryl group having 6 to 50 ring carbon atoms, or a substituted or unsubstituted heterocyclic group having 5 to 50 ring atoms, and
R₁₁ to R₂₂, R_{31A} to R_{32A}, R₄₀, and R_{41 to} R₄₂ are each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{1A})(R_{2A}).

10. The compound according tom claim 7, wherein
one of R₁₄ to R₂₂ is a group represented by —N(R_{1A})(R_{2A}), and
R_{1A} and R_{2A} are each independently a substituted or unsubstituted aryl group having 6 to 50 ring carbon atoms, or a substituted or unsubstituted heterocyclic group having 5 to 50 ring atoms.

11. The compound according to claim 7, wherein
one of R₁₄ to R₂₂ is a group represented by —N(R_{1A})(R_{2A}), and
a combination of R_{1A} and R_{2A} are mutually bonded to form a substituted or unsubstituted monocyclic ring, or mutually bonded to form a substituted or unsubstituted fused ring.

12. The compound according to claim 8, wherein
the compound represented by the formula (121) is represented by one of formulae (A121) to (A131) below and the compound represented by the formula (131) is represented by one of formulae (B131) to (B141) below, 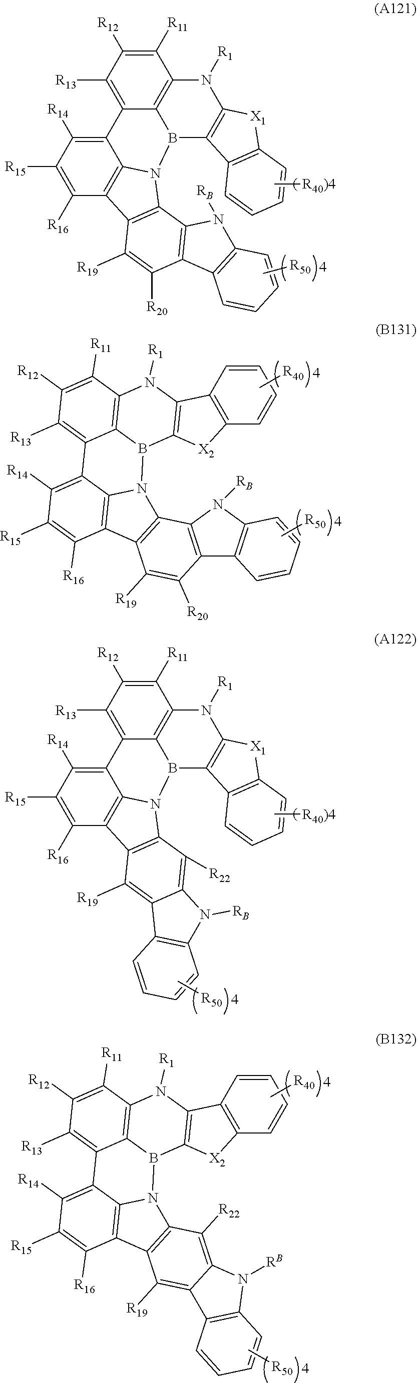 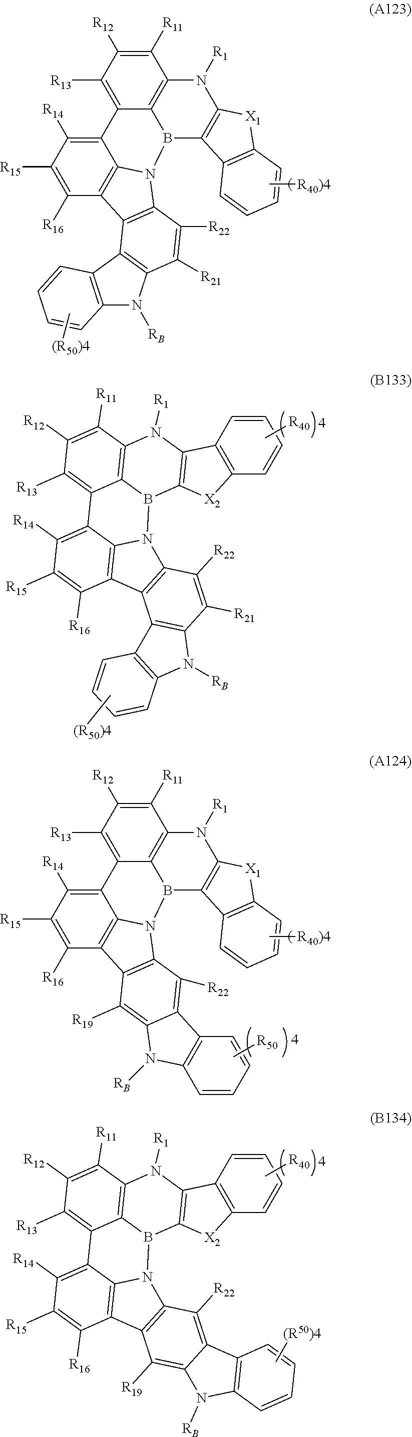 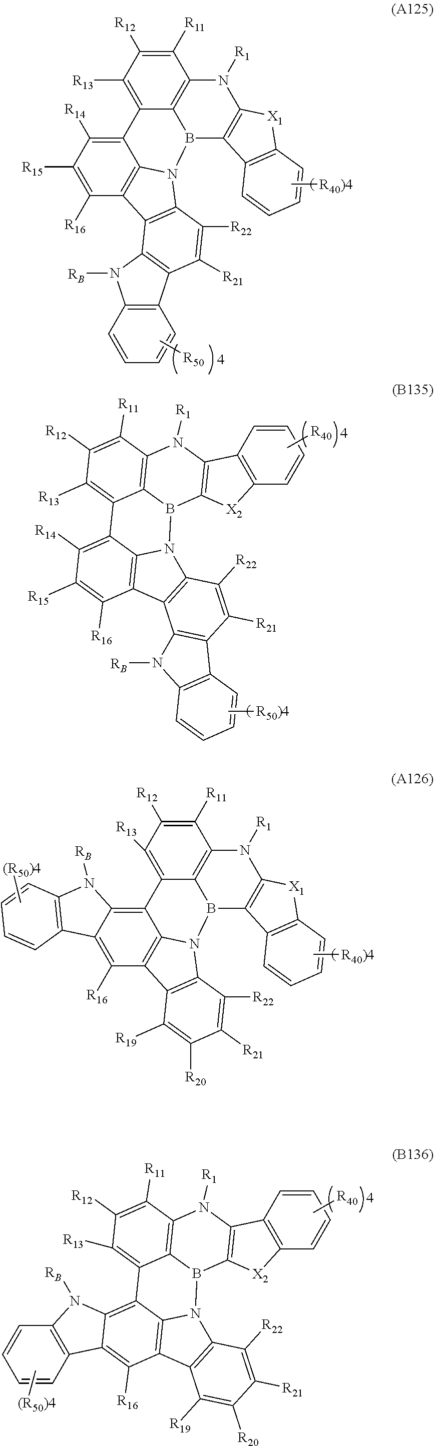 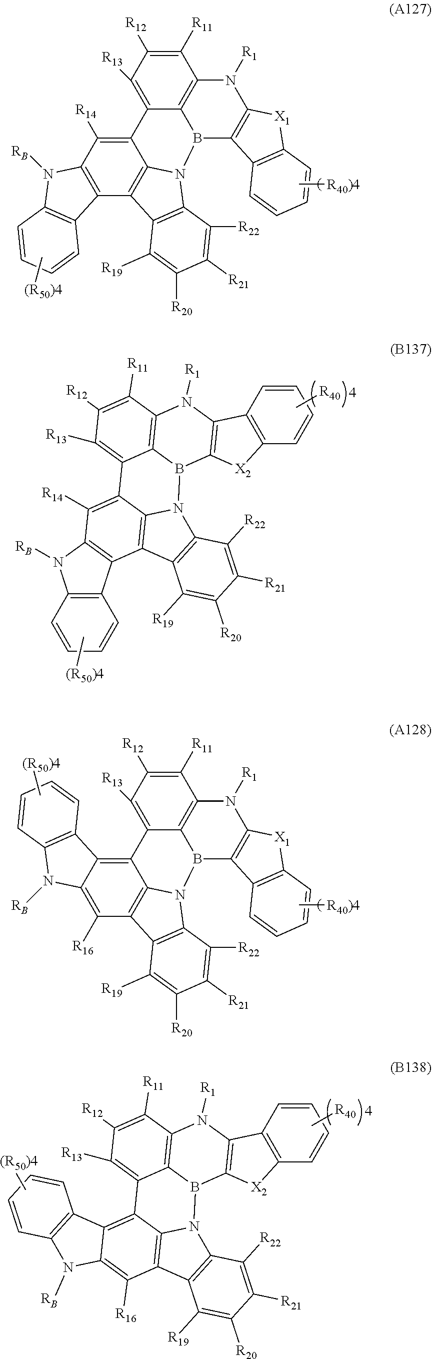 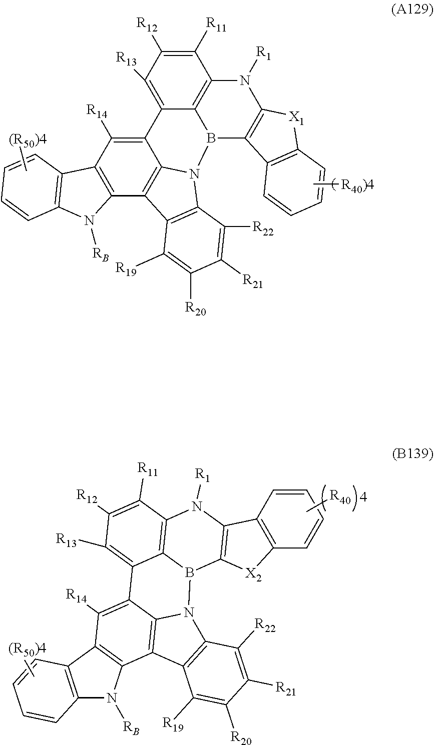
where, in the formulae (A121) to (A129) and (B131) to (B139):
R₁, R₁₁ to R₁₆, R₁₉ to R₂₂, X₁, X₂, and R₄₀ each independently represent the same as R₁, R₁₁ to R₁₆, R₁₉ to R₂₂, X₁, X₂, and R₄₀ in the formulae (121) and (131);
at least one combination of adjacent two or more of R₅₀ and R_{B} are mutually bonded to form a substituted or unsubstituted monocyclic ring, mutually bonded to form a substituted or unsubstituted fused ring, or not mutually bonded;
a plurality of R₅₀ are mutually the same or different;
R_{B} forming neither the substituted or unsubstituted monocyclic ring nor the substituted or unsubstituted fused ring is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₅₀ forming neither the substituted or unsubstituted monocyclic ring nor the substituted or unsubstituted fused ring each independently represent the same as R₄₀ forming neither the substituted or unsubstituted monocyclic ring nor the substituted or unsubstituted fused ring in the formulae (121) and (131), 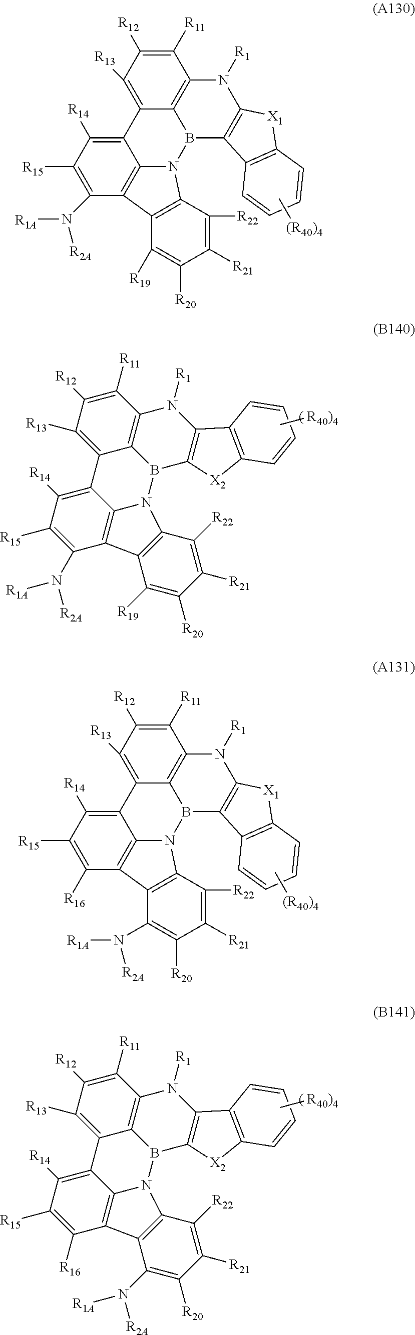
where, in the formulae (A130) to (A131) and (B140) to (B141):
R₁, R₁₁ to R₁₆, R₁₉ to R₂₂, X₁, X₂, and R₄₀ each independently represent the same as R₁, R₁₁₁ to R₁₆, R₁₉ to R₂₂, X₁, X₂, and R₄₀ in the formulae (121) and (131); and
R_{1A} and R_{2A} each independently represent the same as R_{1A} and R_{2A} in the formula (1).

13. The compound according to claim 12, wherein
R₁ is a substituted or unsubstituted aryl group having 6 to 50 ring carbon atoms, or a substituted or unsubstituted heterocyclic group having 5 to 50 ring atoms, and
R₁₁ to R₂₂, R₄₀, and R₅₀ are each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{1A})(R_{2A}).

14. The compound according to claim 7, wherein
X₁ and X₂ are each independently an oxygen atom or C(Rx₁)(Rx₂), and
Rx₁ and Rx₂ are each independently a substituted or unsubstituted alkyl group having 1 to 50 carbon atoms, or a substituted or unsubstituted aryl group having 6 to 50 ring carbon atoms.

15. The compound according to claim 1, wherein
the compound represented by the formula (1) is represented by a formula (14) or (15) below, 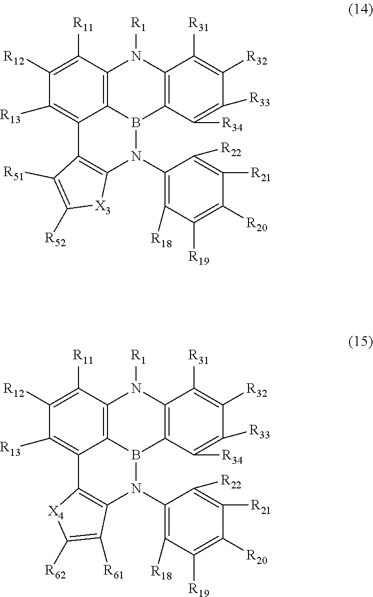
where, in the formulae (14) and (15):
R₁ represents the same as R₁ in the formula (1);
X₃ and X₄ are each independently an oxygen atom, a sulfur atom, NRx, or C(Rx₁)(Rx₂);
at least one combination of adjacent two or more of R₁, R₁₁ to R₁₃, and R₃₁ to R₃₄ are mutually bonded to form a substituted or unsubstituted monocyclic ring, mutually bonded to form a substituted or unsubstituted fused ring, or not mutually bonded;
at least one combination of adjacent two or more of R₁₈ to R₂₂, R₅₁ to R₅₂, Rx, Rx₁, and Rx₂ are mutually bonded to form a substituted or unsubstituted monocyclic ring, mutually bonded to form a substituted or unsubstituted fused ring, or not mutually bonded;
at least one combination of adjacent two or more of R₁₈ to R₂₂, R₆₁ to R₆₂, Rx, Rx₁, and Rx₂ are mutually bonded to form a substituted or unsubstituted monocyclic ring, mutually bonded to form a substituted or unsubstituted fused ring, or not mutually bonded;
R₁₁ to R₁₃, R₁₈ to R₂₂, R₃₁ to R₃₄, R₅₁ to R₅₂, and R₆₁ to R₆₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —N(R_{1A})(R_{2A}), —CN, or a group represented by —O—(R₁₃₆); and
Rx, Rx₁, and Rx₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

16. The compound according to claim 15, wherein
the compound represented by the formula (1) is represented by a formula (141) or 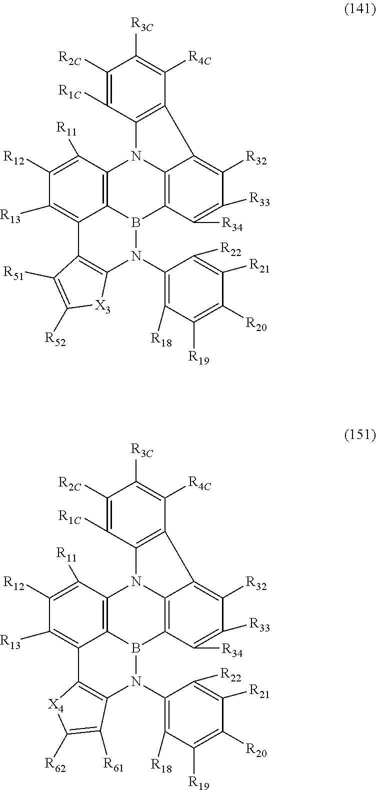
where, in the formulae (141) and (151):
R₁₁ to R₁₃, R₁₈ to R₂₂, R₃₂ to R₃₄, R₅₁ to R₅₂, R₆₁ to R₆₂, X₃, and X₄ each independently represent the same as R₁ to R₁₃, R₁₈ to R₂₂, R₃₂ to R₃₄, R₅₁ to R₅₂, R₆₁ to R₆₂, X₃, and X₄ in the formulae (14) and (15);
at least one combination of adjacent two or more of R_{1C} to R_{4C} are mutually bonded to form a substituted or unsubstituted monocyclic ring, mutually bonded to form a substituted or unsubstituted fused ring, or not mutually bonded; and
R_{1C} to R_{4C} forming neither the substituted or unsubstituted monocyclic ring nor the substituted or unsubstituted fused ring each independently represent the same as R₁ forming neither the substituted or unsubstituted monocyclic ring nor the substituted or unsubstituted fused ring in the formulae (14) and (15).

17. The compound according to claim 15, wherein R₁₁ to R₁₃, R₁₈ to R₂₂, R₃₁ to R₃₄, R₅₁ to R₅₂, R₆₁ to R₆₂, and R_{1C} to R_{4C} are each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{1A})(R_{2A}).

18. The compound according to claim 15, wherein
X₃ and X₄ are each independently an oxygen atom or C(Rx₁)(Rx₂), and
Rx₁ and Rx₂ are each independently a substituted or unsubstituted alkyl group having 1 to 50 carbon atoms, or a substituted or unsubstituted aryl group having 6 to 50 ring carbon atoms.

19. The compound according to claim 15, wherein R₁ is a substituted or unsubstituted aryl group having 6 to 50 ring carbon atoms, or a substituted or unsubstituted heterocyclic group having 5 to 50 ring atoms.

20. The compound according to claim 16, wherein
the compound represented by the formula (141) is represented by one of formulae (C141) to (C150) below and the compound represented by the formula (151) is represented by one of formulae (D151) to (D160) below, 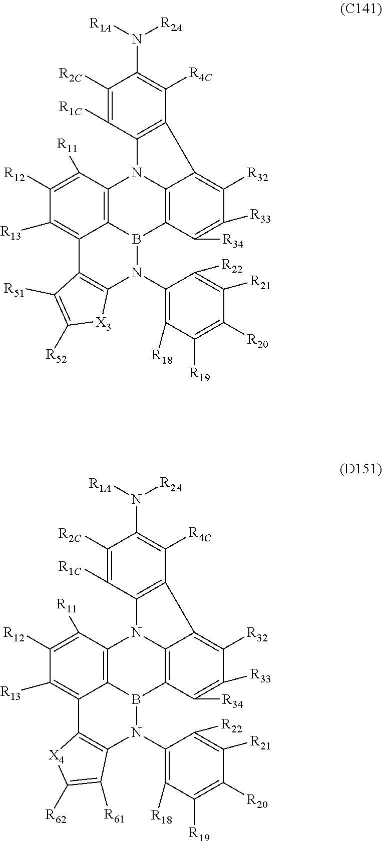 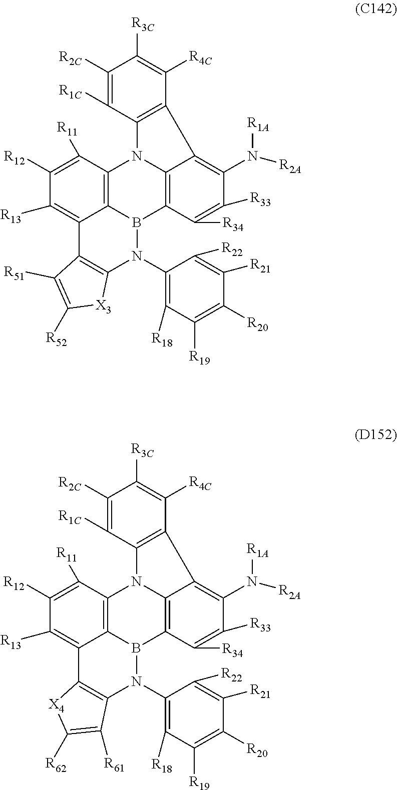
where, in the formulae (C141), (C142), (D151), and (D152):
X₃, X₄, R₁₁ to R₁₃, R₁₈ to R₂₂, R₃₂ to R₃₄, R₅₁ to R₅₂, R₆₁ to R₆₂, and R_{1C} to R_{4C} each independently represent the same as X₃, X₄, R₁₁ to R₁₃, R₁₈ to R₂₂, R₃₂ to R₃₄, R₅₁ to R₅₂, R₆₁ to R₆₂, and R_{1C} to R_{4C} in the formulae (141) and (151); and
R_{1A} and R_{2A} each independently represent the same as R_{1A} and R_{2A} forming neither the substituted or unsubstituted monocyclic ring nor the substituted or unsubstituted fused ring in the formula (1), 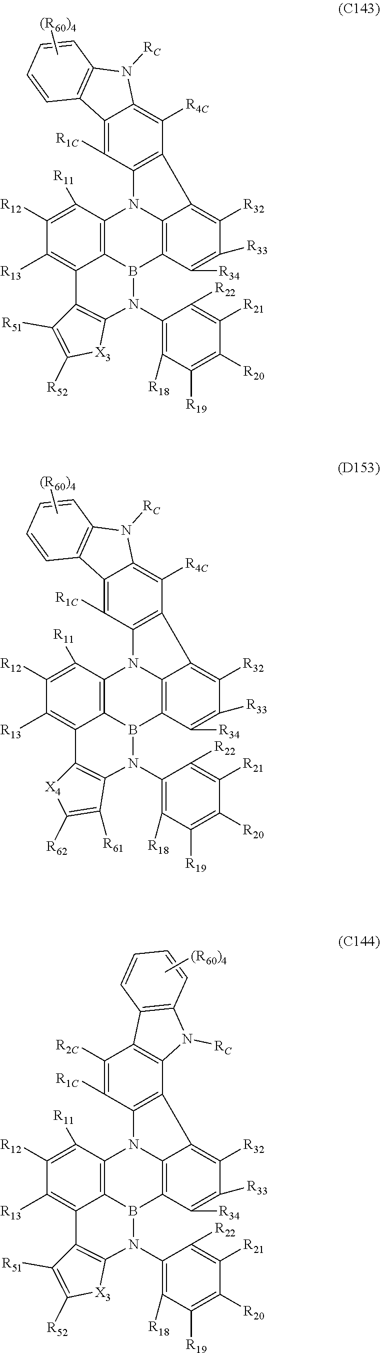 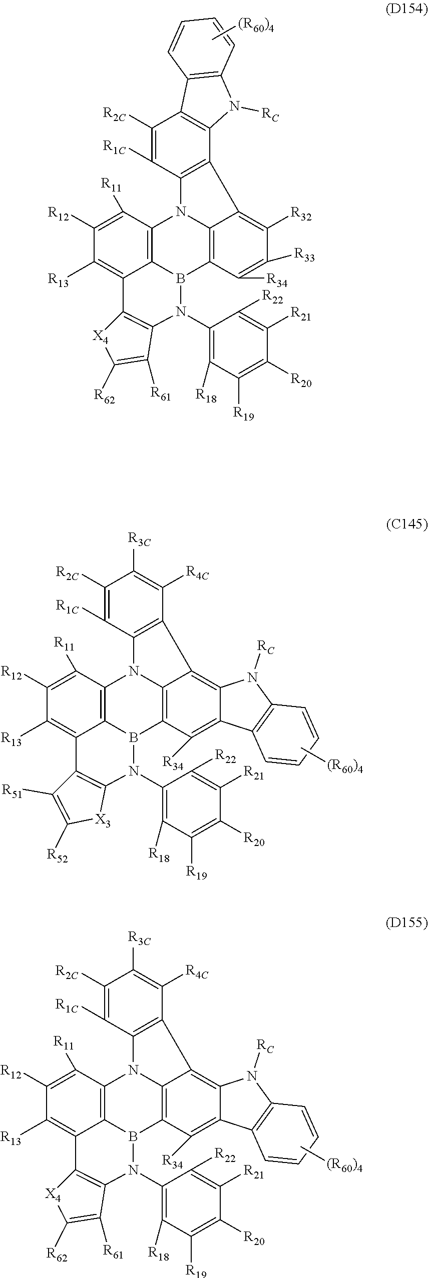
where, in the formulae (C143) to (C145) and (D153) to (D155):
X₃, X₄, R₁₁ to R₁₃, R₁₈ to R₂₂, R₃₂ to R₃₄, R₅₁ to R₅₂, R₆₁ to R₆₂, and R_{1C} to R_{4C} each independently represent the same as X₃, X₄, R₁₁ to R₁₃, R₁₈ to R₂₂, R₃₂ to R₃₄, R₅₁ to R₅₂, R₆₁ to R₆₂, and R_{1C} to R_{4C} in the formulae (141) and (151);
at least one combination of adjacent two or more of R₆₀ are mutually bonded to form a substituted or unsubstituted monocyclic ring, mutually bonded to form a substituted or unsubstituted fused ring, or not mutually bonded;
a plurality of R₆₀ are mutually the same or different;
R_{C} is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₆₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (141) and (151), 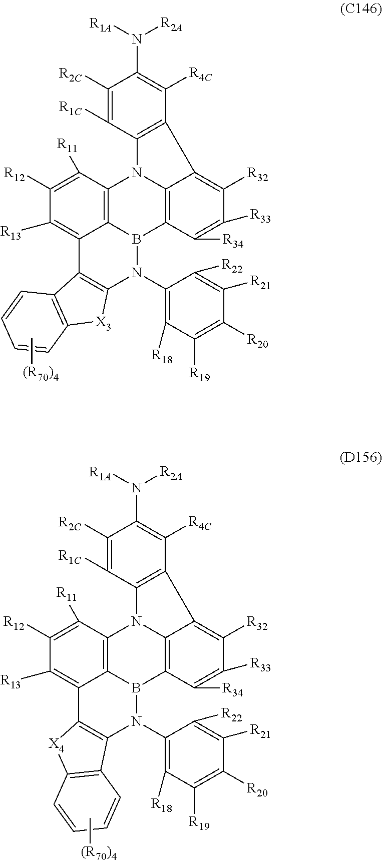 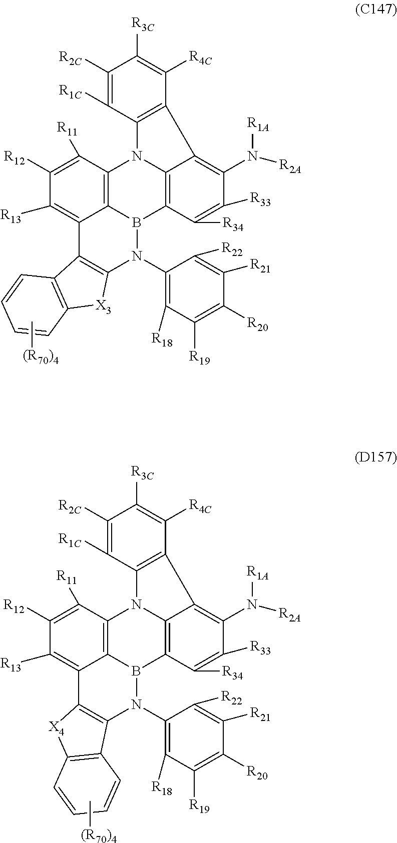
where, in the formulae (C146), (C147), (D156), and (D157):
X₃, X₄, R₁₁ to R₁₃, R₁₈ to R₂₂, R₃₂ to R₃₄, and R_{1C} to R_{4C} each independently represent the same as X₃, X₄, R₁ to R₁₃, R₁₈ to R₂₂, R₃₂ to R₃₄, and R_{1C} to R_{4C} in the formulae (141) and (151);
R_{1A} and R_{2A} each independently represent the same as R_{1A} and R_{2A} forming neither the substituted or unsubstituted monocyclic ring nor the substituted or unsubstituted fused ring in the formula (1);
at least one combination of adjacent two or more of R₇₀ are mutually bonded to form a substituted or unsubstituted monocyclic ring, mutually bonded to form a substituted or unsubstituted fused ring, or not mutually bonded;
a plurality of R₇₀ are mutually the same or different; and
R₇₀ forming neither the substituted or unsubstituted monocyclic ring nor the substituted or unsubstituted fused ring each independently represent the same as R₁₁ forming neither the substituted or unsubstituted monocyclic ring nor the substituted or unsubstituted fused ring in the formulae (141) and (151), 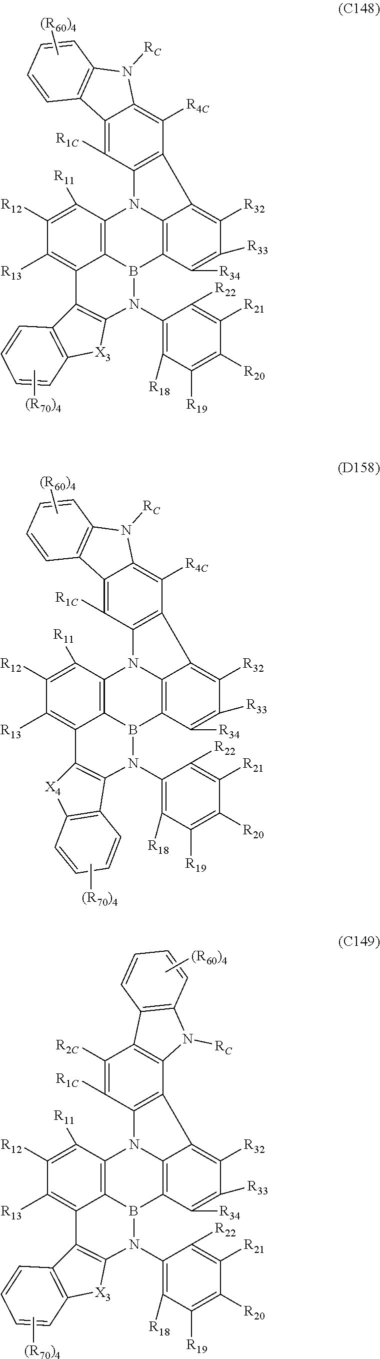 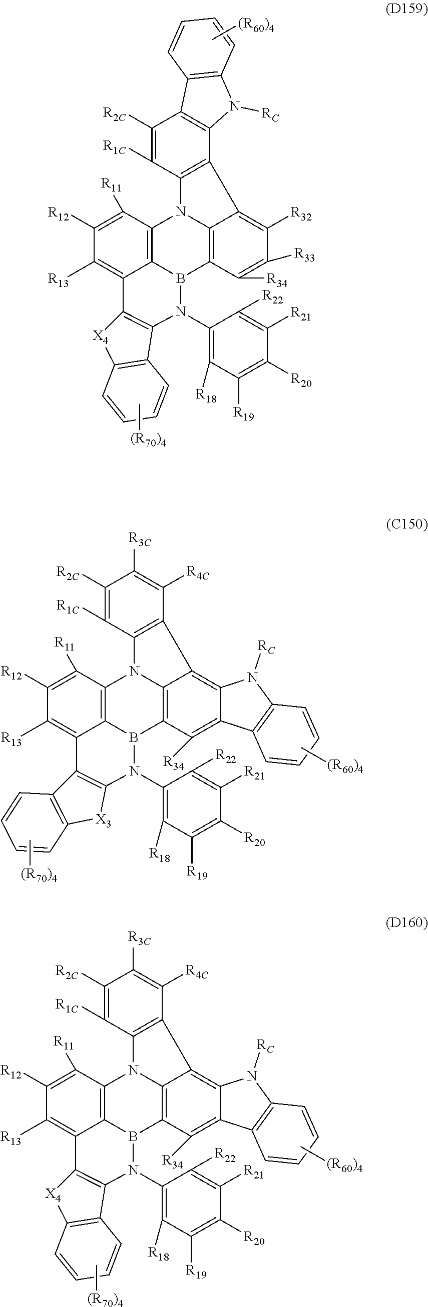
where, in the formulae (C148) to (C150) and (D158) to (D160):
X₃, X₄, R₁₁ to R₁₃, R₁₈ to R₂₂, R₃₂ to R₃₄, and R_{1C} to R_{4C} each independently represent the same as X₃, X₄, R₁ to R₁₃, R₁₈ to R₂₂, R₃₂ to R₃₄, and R_{1C} to R_{4C} in the formulae (141) and (151);
at least one combination of adjacent two or more of R₆₀ are mutually bonded to form a substituted or unsubstituted monocyclic ring, mutually bonded to form a substituted or unsubstituted fused ring, or not mutually bonded;
a plurality of R₆₀ are mutually the same or different;
at least one combination of adjacent two or more of R₇₀ are mutually bonded to form a substituted or unsubstituted monocyclic ring, mutually bonded to form a substituted or unsubstituted fused ring, or not mutually bonded;
a plurality of R₇₀ are mutually the same or different;
R_{C} is a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
R₆₀ and R₇₀ forming neither the substituted or unsubstituted monocyclic ring nor the substituted or unsubstituted fused ring each independently represent the same as R₁ forming neither the substituted or unsubstituted monocyclic ring nor the substituted or unsubstituted fused ring in the formulae (141) and (151).

21. An organic-electroluminescence-device material comprising the compound according to claim 1.

22. An organic electroluminescence device comprising a cathode;
an anode; and
an organic layer between the cathode and the anode, wherein
at least one layer of the organic layer comprises the compound according to claim 1.

23. The organic electroluminescence device according to claim 22, wherein
the organic layer comprises an emitting layer, and
the emitting layer comprises the compound.

24. The organic electroluminescence device according to claim 22, wherein the emitting layer comprises a compound represented by a formula (H10) below, 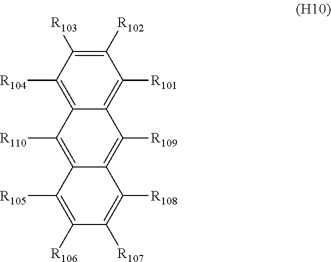
where, in the formula (H10):
at least one combination of adjacent two or more of R₁₀₁ to R₁₁₀ are mutually bonded to form a substituted or unsubstituted monocyclic ring, mutually bonded to form a substituted or unsubstituted fused ring, or not mutually bonded;
R₁₀₁ to R₁₁₀ forming neither the substituted or unsubstituted monocyclic ring nor the substituted or unsubstituted fused ring are each independently a hydrogen atom, a substituent R, or a group represented by a formula (H11) below;
at least one of R₁₀₁ to R₁₁₀ forming neither the substituted or unsubstituted monocyclic ring nor the substituted or unsubstituted fused ring is a group represented by the formula (H11) below; and
when two or more groups represented by the formula (H11) are present, the two or more groups represented by the formula (H11) are mutually the same or different,
-L₁₀₁-Ar₁₀₁ (H11)
where, in the formula (H11):
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms,
the substituent R is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
when two or more substituents R are present, the two or more substituents R are mutually the same or different;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

25. An electronic device comprising the organic electroluminescence device according to claim 22.
